(19) United States
(12) Patent Application Publication
(10) Pub. No.: US 2021/0139770 A1
(43) Pub. Date: May 13, 2021

(54) METASTABLE AGGREGATE AND USES THEREOF

(71) Applicant: NEXDOT, Romainville (FR)

(72) Inventors: Marc POUSTHOMIS, Deuil-La-Barre (FR); Michele D'AMICO, Romainville (FR); Alexis KUNTZMANN, Paris (FR); Edgar CAO, Paris (FR); Robin FAIDEAU, Houilles (FR); Yu-Pu LIN, Versailles (FR)

(73) Assignee: NEXDOT, Romainville (FR)

(21) Appl. No.: 16/618,412

(22) PCT Filed: Jun. 1, 2018
(86) PCT No.: PCT/EP2018/064441

§ 371 Date: Dec. 2, 2019

Related U.S. Application Data
(60) Provisional application No. 62/514,297, filed on Jun. 2, 2017.
(60) Provisional application No. 62/514,422, filed on Jun. 2, 2017.
(60) Provisional application No. 62/514,601, filed on Jun. 2, 2017.
(60) Provisional application No. 62/609,932, filed on Dec. 22, 2017.
(60) Provisional application No. 62/710,298, filed on Feb. 16, 2018.
(60) Provisional application No. 62/642,370, filed on Mar. 13, 2018.

(30) Foreign Application Priority Data
Sep. 22, 2017 (EP) 17306241.5
Sep. 22, 2017 (EP) 17306246.4
Sep. 22, 2017 (EP) 17306247.2
Sep. 22, 2017 (EP) 17306248.0
Sep. 22, 2017 (EP) 17306249.8
Dec. 11, 2017 (EP) 17206479.2

(51) Int. Cl. C09K 11/02; C09K 11/88; C09K 11/08; C09K 11/70; C09K 11/06; H01L 33/50

(52) U.S. Cl. CPC C09K 11/025; C09K 11/883; C09K 11/0883; G02F 1/133617; C09K 11/06; H01L 33/502; C09K 11/703

(57) ABSTRACT

An aggregate including a material; at least one particle dispersed in the material; wherein the aggregate is metastable. The present disclosure also relates to an optoelectronic device and a method.

### FIELD OF INVENTION

The present invention pertains to the field of aggregates and particles. In particular, the invention relates to metastable aggregates comprising particles.

### BACKGROUND OF INVENTION

To represent the colors in all their variety, one proceeds typically by additive synthesis of at least three complementary colors, especially red, green and blue. In a chromaticity diagram, the subset of available colors obtained by mixing different proportions of these three colors is represented by a triangle formed by the three coordinates associated with the three primary colors red, green and blue. This subset constitutes what is called a gamut. The majority of color display devices operate on this three-color principle: each pixel consists of three sub-pixels, one red, one green and one blue, whose mixture with different intensities can reproduce a colorful impression.

A luminescent or backlit display such as a computer LCD screen has to present the widest possible gamut for an accurate color reproduction. For this, the composing sub-pixels must be of the most saturated primary colors possible in order to describe the widest possible gamut. A sub-pixel has a saturated color if it is close to a monochromatic color. From a spectral point of view, this means that the light emitted by the source is comprised of a single narrow fluorescence band of wavelengths. A highly saturated shade has a vivid, intense color while a less saturated shade appears rather bland and gray.

It is therefore important to have sub-pixels whose emission spectra are narrow and with saturated primary colors.

Luminescent inorganic nanoparticles, especially semiconductor nanoparticles, commonly called “quantum dots”, are known as emissive material. Semiconductor nanoparticles have a narrow fluorescence spectrum, approximately 30 nm full width at half maximum of their fluorescence band, and offer the possibility to tune their emission peak in the entire visible spectrum as well as in the infrared with a single excitation source in the ultraviolet or in the blue region Luminescent inorganic nanoparticles, especially semiconductor nanoparticles, are currently used in display devices as phosphors.

However, to be used in such display devices and lighting devices, these materials have to exhibit a high stability in time and in temperature, under a high photon flux. In addition, there is a need for materials having a high stability for long term use when deposited on diodes, or Light Emitting Diodes (LED).

To ensure a high long term stability, further chemical reaction between the surface of nanoparticles and environmental deteriorating species such as water, oxygen or other harmful compounds, must be prevented during their use. However, the ligands commonly used to functionalize the surface of nanoparticles do not protect efficiently said surface against reactions with these deteriorating species or harmful compounds and thus do not enable the long-term performance required for display or lighting devices. It is known that coating nanoparticles with a protective shell, i.e. encpasulating said nanoparticles in another material, prevents deteriorating species or harmful compounds from reaching said nanoparticles surface.

Furthermore, adding nanoparticles in a material is known to improve the mechanical properties of said materials. For example, adding nanoparticles in a 3D printing resin improve its mechanical resistance and allow for a decrease of cracks and damages along the resin during its life cycle of use.

However, this is limited by the chemical compatibility of the nanoparticles with said material. When the nanoparticles and the material are not chemically compatible, a homogeneous mixture cannot be reached and the nanoparticles cannot be incorporated in the material.

Thus, there is a need for an encapsulation of nanoparticles that allow both for a good protection of said nanoparticles against environment variations and deteriorating species, and for a homogeneous dispersion into a material that can be chemically incompatible with said nanoparticles. Homogeneous films comprising said material and said nanoparticles can then be achieved.

It is therefore an object of the present invention to provide aggregates comprising at least one particle dispersed in a material; said aggregates having one or more of the following advantages: coupling the properties of different particles encapsulated in the same aggregate; preventing a degradation of the properties of encapsulated particles; enhanced stability over temperature, environment variations and deteriorating species like water and molecular oxygen, or other harmful compounds attacks; enhanced photoluminescence quantum yield, enhanced resistance to photobleaching and enhanced resistance to photon flux in the case of luminescent aggregates.

Furthermore, said aggregates are tailored to be metastable, i.e. encapsulated particles can be released from the aggregate upon a triggering stimulus.

### SUMMARY

The present invention relates to an aggregate comprising a material; at least one particle dispersed in said material; wherein the aggregate is metastable.

In one embodiment, the material is selected from inorganic, organic or hybrid materials.

In one embodiment, the inorganic material is selected from metals, metal oxides, halides, chalcogenides, phosphides, sulfides, metalloids, metallic alloys, ceramics such as for example oxides, carbides, nitrides, glasses, enamels, ceramics, stones, precious stones, pigments, cements and/or inorganic polymers; preferably the inorganic material is an inorganic polymer.

In one embodiment, the organic material is selected from polyacrylates; polymethacrylate; polyacrylamide; polyester; polyether; polyolefin (or polyalkene); polysaccharide; polyamide; or a mixture thereof; preferably the organic material is an organic polymer.

In one embodiment, the material limits or prevents the diffusion of outer molecular species or fluids (liquid or gas) into said first material.

In one embodiment, the material has a thermal conductivity at standard conditions of at least 0.1 W/(m·K).

In one embodiment, the at least one particle is selected from inorganic, organic or hybrid particles.

In one embodiment, the at least one particle is selected from luminescent particles, plasmonic particles, magnetic particles, catalytic particles, pyro-electric particles, ferro-electric particles, light scattering particles, electrically insulating particles, electrically conductive particles, thermally conductive particles, thermally insulating particles, local high temperature heating particles, dielectric particles, piezoelectric particles.

In one embodiment, the at least one particle is selected from metal particles, halide particles, chalcogenide particles, phosphide particles, sulfide particles, metalloid particles, metallic alloy particles, phosphor particles, perovskite particles, ceramic particles such as for example oxide particles, carbide particles, nitride particles, or a mixture thereof, preferably is a semiconductor nanocrystal.

In one embodiment, the at least one particle comprises a material and at least one nanoparticle, wherein said at least one nanoparticle is dispersed in the material.

The present invention also relates to an optoelectronic device comprising at least one aggregate of the invention.

The present invention also relates to a method for manufacturing a metastable aggregate of the invention, said method comprising the following steps:
(a) preparing a colloidal suspension by mixing a solution comprising at least one precursor of a material with a first colloidal suspension comprising at least one particle;
(b) forming droplets of said colloidal suspension;
(c) dispersing said droplets in a gas flow;
(d) heating said dispersed droplets at a temperature enough to obtain the aggregates by solvent evaporation;
(e) cooling of said aggregates; and
(f) separating and collecting said aggregates,

wherein said aggregates are metastable.

### DEFINITIONS

In the present invention, the following terms have the following meanings:
“Acidic function” refers to —COOH group.
“Activated acidic function” refers to an acidic function wherein the —OH part is replaced by a better leaving part.
“Activated alcoholic function” refers to an alcoholic group modified to be a better leaving group.
“Adjacent particle” refers to neighbouring particles in a space or a volume, without any other particle between said adjacent particles.
“Alkenyl” refers to any linear or branched hydrocarbon chain having at least one double bond, of 2 to 12 carbon atoms, and preferably 2 to 6 carbon atoms. The alkenyl group may be substituted. Examples of alkenyl groups are ethenyl, 2-propenyl, 2-butenyl, 3-butenyl, 2-pentenyl and its isomers, 2-hexenyl and its isomers, 2,4-pentadienyl and the like. The alkenyl group may be substituted by a saturated or unsaturated aryl group.
The terms “Alkenylene” means an alkenyl group as defined above having two single bonds as points of attachment to other groups.
“Alkoxy” refers to any O-alkyl group, preferably an O-alkyl group wherein the alkyl group has 1 to 6 carbon atoms.
“Alkyl” refers to any saturated linear or branched hydrocarbon chain, with 1 to 12 carbon atoms, preferably 1 to 6 carbon atoms, and more preferably methyl, ethyl, propyl, isopropyl, n-butyl, sec-butyl, isobutyl and tert-butyl. The alkyl group may be substituted by a saturated or unsaturated aryl group.
When the suffix “ene” (“alkylene”) is used in conjunction with an alkyl group, this is intended to mean the alkyl group as defined herein having two single bonds as points of attachment to other groups. The term “alkylene” includes methylene, ethylene, methylmethylene, propylene, ethylethylene, and 1,2-dimethylethylene.
“Alkynyl”, refers to any linear or branched hydrocarbon chain having at least one triple bond, of 2 to 12 carbon atoms, and preferably 2 to 6 carbon atoms.
“Amine” refers to any group derived from ammoniac NH₃ by substitution of one or more hydrogen atoms with an organic radical.
“Aqueous solvent” is defined as a unique-phase solvent wherein water is the main chemical species in terms of molar ratio and/or in terms of mass and/or in terms of volume in respect to the other chemical species contained in said aqueous solvent. The aqueous solvent includes but is not limited to: water, water mixed with an organic solvent miscible with water such as for example methanol, ethanol, acetone, tetrahydrofuran, n-methylformamide, n,n-dimethylformamide, dimethylsulfoxide or a mixture thereof.
“Array” refers to a series, a matrix, an assemblage, an organization, a succession, a collection or an arrangement of elements or items, wherein said elements or items are arranged in a particular way.
“Aryl” refers to a mono- or polycyclic system of 5 to 20, and preferably 6 to 12, carbon atoms having one or more aromatic rings (when there are two rings, it is called a biaryl) among which it is possible to cite the phenyl group, the biphenyl group, the 1-naphthyl group, the 2-naphthyl group, the tetrahydronaphthyl group, the indanyl group and the binaphthyl group. The term aryl also means any aromatic ring including at least one heteroatom chosen from an oxygen, nitrogen or sulfur atom. The aryl group can be substituted by 1 to 3 substituents chosen independently of one another, among a hydroxyl group, a linear or branched alkyl group comprising 1, 2, 3, 4, 5 or 6 carbon atoms, in particular methyl, ethyl, propyl, butyl, an alkoxy group or a halogen atom, in particular bromine, chlorine and iodine, a nitro group, a cyano group, an azido group, an adhehyde group, a boronato group, a phenyl, CF3, methylenedioxy, ethylenedioxy, SO2NRR′, NRR′, COOR (where R and R′ are each independently selected from the group consisting of H and alkyl), an second aryl group which may be substituted as above. Non-limiting examples of aryl comprise phenyl, biphenylyl, biphenylenyl, 5- or 6-tetralinyl, naphthalen-1- or -2-yl, 4-, 5-, 6 or 7-indenyl, 1-, 2-, 3-, 4- or 5-acenaphtylenyl, 3-, 4- or 5-acenaphtenyl, 1- or 2-pentalenyl, 4- or 5-indanyl, 5-, 6-, 7- or 8-tetrahydronaphthyl, 1,2,3,4-tetrahydronaphthyl, 1,4-dihydronaphthyl, 1-, 2-, 3-, 4- or 5-pyrenyl.
“Arylalkoxy” refers to an alkoxy group substituted by an aryl group.
“Arylalkyl” refers to an alkyl group substituted by an aryl group, such as for example the phenyl-methyl group.
The term “Arylene” as used herein is intended to include divalent carbocyclic aromatic ring systems such as phenylene, biphenylylene, naphthylene, indenylene, pentalenylene, azulenylene and the like.
“Aryloxy” refers to any O-aryl group.
“Azido” refers to N₃ group.
“Backlight unit” refers to a unit comprising at least one light source configured to emit primary light and a polarizer configured to polarize said primary light. Said “backlight unit” is configured to provide said polarized light to the liquid crystal layer, the color filter layer and the second polarizer. As said polarized light pass through the liquid crystal layer and the color filter layer, only the selected protion of the primary light will be transmitted through the second polarizer, such that an image can be viewed by the viewer. Said “backlight unit” is preferably located to the back of a LCD Panel, before the liquid crystal layer.
“Colloidal” refers to a substance in which particles are dispersed, suspended and do not settle or would take a very long time to settle appreciably, but are not soluble in said substance.
“Colloidal particles” refers to particles that may be dispersed, suspended and which would not settle or would take a very long time to settle appreciably in another substance, typically in an aqueous or organic solvent, and which are not soluble in said substance. “Colloidal particles” does not refer to particles grown on substrate.
“Core” refers to the innermost space within a particle.
“Curvature” refers to the reciprocal of the radius.
“Cycle” refers to a saturated, partially unsaturated or unsaturated cyclic group.
“Display apparatus” refers to an apparatus or a device that displays an image signal. Display devices or display apparatus include all devices that display an image, a succession of pictures or a video such as, non-limitatively, a LCD display, a television, a projector, a computer monitor, a personal digital assistant, a mobile phone, a laptop computer, a tablet PC, an MP3 player, a CD player, a DVD player, a Blu-Ray player, a head mounted display, glasses, a helmet, a headgear, a headwear, a smart watch, a watch phone or a smart device.
“Encapsulate” refers to a material that coats, surrounds, embeds, contains, comprises, wraps, packs, or encloses a plurality of particles.
The terms “Film”, “Layer” or “Sheet” are interchangeable in the present invention.
“Free of oxygen” refers to a formulation, a solution, a film, or a composition that is free of molecular oxygen, O₂, i.e. wherein molecular oxygen may be present in said formulation, solution, film, or composition in an amount of less than about 10 ppm, 5 ppm, 4 ppm, 3 ppm, 2 ppm, 1 ppm, 500 ppb, 300 ppb or in an amount of less than about 100 ppb in weight.
“Free of water” refers to a formulation, a solution, a film, or a composition that is free of molecular water, H₂O, i.e. wherein molecular water may be present in said formulation, solution, film, or composition in an amount of less than about 100 ppm, 50 ppm, 10 ppm, 5 ppm, 4 ppm, 3 ppm, 2 ppm, 1 ppm, 500 ppb, 300 ppb or in an amount of less than about 100 ppb in weight.
“Gas” refers to a substance in a gaseous state in standard conditions of pressure and temperature.
“Halogen” means fluoro, chloro, bromo, or iodo. Preferred halo groups are fluoro and chloro.
“Heterocycle” refers to a saturated, partially unsaturated or unsaturated cyclic group comprising at least on heteroatom.
“Hybrid material” refers to a material comprising at least one inorganic constituent and at least one organic constituent.
“Impermeable” refers to a material that limits or prevents the diffusion of outer molecular species or fluids (liquid or gas) into said material.
“Loading charge” refers to the mass ratio between the mass of an ensemble of objects comprised in a space and the mass of said space.
“Monodisperse” refers to particles or droplets, wherein the size difference is inferior than 20%, 15%, 10%, preferably 5%.
“Narrow size distribution” refers to a size distribution of a statistical set of particles less than 1%, 2%, 3%, 4%, 5%, 6%, 7%, 8%, 9%, 10%, 15%, 20%, 25%, 30%, 35%, or 40% of the average size.
“Nanoplatelet” refers to a 2D shaped nanoparticle, wherein the smallest dimension of said nanoplatelet is smaller than the largest dimension of said nanoplatelet by a factor (aspect ratio) of at least 1.5, at least 2, at least 2.5, at least 3, at least 3.5, at least 4, at least 4.5, at least 5, at least 5.5, at least 6, at least 6.5, at least 7, at least 7.5, at least 8, at least 8.5, at least 9, at least 9.5 or at least 10.
“Optically transparent” refers to a material that absorbs less than 10%, 5%, 2.5%, 1%, 0.99%, 0.98%, 0.97%, 0.96%, 0.95%, 0.94%, 0.93%, 0.92%, 0.91%, 0.9%, 0.89%, 0.88%, 0.87%, 0.86%, 0.85%, 0.84%, 0.83%, 0.82%, 0.81%, 0.8%, 0.79%, 0.78%, 0.77%, 0.76%, 0.75%, 0.74%, 0.73%, 0.72%, 0.71%, 0.7%, 0.69%, 0.68%, 0.67%, 0.66%, 0.65%, 0.64%, 0.63%, 0.62%, 0.61%, 0.6%, 0.59%, 0.58%, 0.57%, 0.56%, 0.55%, 0.54%, 0.53%, 0.52%, 0.51%, 0.5%, 0.49%, 0.48%, 0.47%, 0.46%, 0.45%, 0.44%, 0.43%, 0.42%, 0.41%, 0.4%, 0.39%, 0.38%, 0.37%, 0.36%, 0.35%, 0.34%, 0.33%, 0.32%, 0.31%, 0.3%, 0.29%, 0.28%, 0.27%, 0.26%, 0.25%, 0.24%, 0.23%, 0.22%, 0.21%, 0.2%, 0.19%, 0.18%, 0.17%, 0.16%, 0.15%, 0.14%, 0.13%, 0.12%, 0.11%, 0.1%, 0.09%, 0.08%, 0.07%, 0.06%, 0.05%, 0.04%, 0.03%, 0.02%, 0.01%, 0.009%, 0.008%, 0.007%, 0.006%, 0.005%, 0.004%, 0.003%, 0.002%, 0.001%, 0.0009%, 0.0008%, 0.0007%, 0.0006%, 0.0005%, 0.0004%, 0.0003%, 0.0002%, 0.0001%, or 0% of light at wavelengths between 200 nm and 50 μm, between 200 nm and 10 μm, between 200 nm and 2500 nm, between 200 nm and 2000 nm, between 200 nm and 1500 nm, between 200 nm and 1000 nm, between 200 nm and 800 nm, between 400 nm and 700 nm, between 400 nm and 600 nm, or between 400 nm and 470 nm.
“Packing fraction” refers to the volume ratio between the volume filled by an ensemble of objects into a space and the volume of said space. The terms packing fraction, packing density and packing factor are interchangeable in the present invention.
“Partially” means incomplete. In the case of a ligand exchange, partially means that 5%, 10%, 15%, 20%, 25%, 30%, 35%, 40%, 45%, 50%, 55%, 60%, 65%, 70%, 75%, 80%, 85%, 90%, 95% of the ligands at the surface of a particle have been successfully exchanged.
“Permeable” refers to a material that allows the diffusion of outer molecular species or fluids (liquid or gas) into said material.
“Outer molecular species or fluids (liquid or gas)” refers to molecular species or fluids (liquid or gas) coming from outside a material or a particle.
“Pixel pitch” refers to the distance from the center of a pixel to the center of the next pixel.
“Polydisperse” refers to particles or droplets of varied sizes, wherein the size difference is superior or equal to 20%.
“Population of particles” refers to a statistical set of particles having the same maximum emission wavelength.
“Primary light” refers to the light supplied by a light source. For example, primary light refers to the light supplied to the light emitting material by the light source.
“Resulting light” refers to the light supplied by a material after excitation by an incident light and emission of a secondary light. For example, resulting light refers to the light supplied by the luminescent particles, the light emitting material or the color conversion layer and is a combination of a part of the incident light and the secondary light.
“ROHS compliant” refers to a material compliant with Directive 2011/65/EU of the European Parliament and of the Council of 8 Jun. 2011 on the restriction of the use of certain hazardous substances in electrical and electronic equipment.
“Roughness” refers to a surface state of a particle. Surface irregularities can be present at the surface of particles and are defined as peaks or cavities depending on their relative position respect to the average particle surface. All said irregularities constitute the particle roughness. Said roughness is defined as the height difference between the highest peak and the deepest cavity on the surface. The surface of a particle is smooth if they are no irregularities on said surface, i.e. the roughness is equal to 0%, 0.0001%, 0.0002%, 0.0003%, 0.0004%, 0.0005%, 0.0006%, 0.0007%, 0.0008%, 0.0009%, 0.001%, 0.002%, 0.003%, 0.004%, 0.005%, 0.006%, 0.007%, 0.008%, 0.009%, 0.01%, 0.02%, 0.03%, 0.04%, 0.05%, 0.06%, 0.07%, 0.08%, 0.09%, 0.1%, 0.11%, 0.12%, 0.13%, 0.14%, 0.15%, 0.16%, 0.17%, 0.18%, 0.19%, 0.2%, 0.21%, 0.22%, 0.23%, 0.24%, 0.25%, 0.26%, 0.27%, 0.28%, 0.29%, 0.3%, 0.31%, 0.32%, 0.33%, 0.34%, 0.35%, 0.36%, 0.37%, 0.38%, 0.39%, 0.4%, 0.41%, 0.42%, 0.43%, 0.44%, 0.45%, 0.46%, 0.47%, 0.48%, 0.49%, 0.5%, 1%, 1.5%, 2%, 2.5% 3%, 3.5%, 4%, 4.5%, or 5% of the largest dimension of said particle.
“Secondary light” refers to the light emitted by a material in response to an excitation. Said excitation is generally provided by the light source, i.e. the excitation is the incident light. For example, secondary light refers to the light emitted by the luminescent particles, the light emitting material or the color conversion layer in response to an excitation of the particles comprised in said luminescent particles.
“Shell” refers to at least one monolayer of material coating partially or totally a core.
“Standard conditions” refers to the standard conditions of temperature and pressure, i.e. 273.15 K and 10⁵ Pa respectively.
“Statistical set” refers to a collection of at least 2, 3, 4, 5, 6, 7, 8, 9, 10, 11, 12, 13, 14, 15, 16, 17, 18, 19, 20, 30, 40, 50, 60, 70, 80, 90, 100, 150, 200, 250, 300, 350, 400, 450, 500, 550, 600, 650, 700, 750, 800, 850, 900, 950, or 1000 objects obtained by the strict same process. Such statistical set of objects allows determining average characteristics of said objects, for example their average size, their average size distribution or the average distance between them.
“Surfactant-free” refers to a particle that does not comprise any surfactant and was not synthesized by a method comprising the use of surfactants.
“Surrounding medium” refers to the medium in which the aggregates of the present invention are dispersed, or the medium which surrounds partially or totally said aggregates. It may be a fluid (liquid, gas) or a solid host material.
“Uniformly dispersed” refers to particles that are not aggregated, do not touch, are not in contact, and are separated by an inorganic material. Each particle is spaced from their adjacent particles by an average minimal distance.

### DETAILED DESCRIPTION

The following detailed description will be better understood when read in conjunction with the drawings. For the purpose of illustrating, the aggregate and device are shown in the preferred embodiments. It should be understood, however that the application is not limited to the precise arrangements, structures, features, embodiments, and aspect shown. The drawings are not drawn to scale and are not intended to limit the scope of the claims to the embodiments depicted.

Accordingly, it should be understood that where features mentioned in the appended claims are followed by reference signs, such signs are included solely for the purpose of enhancing the intelligibility of the claims and are in no way limiting on the scope of the claims.

This invention relates to an aggregate 1, as illustrated in FIGS. 1 and 2, comprising:
a material 11;
at least one particle 12 dispersed in said material 11;

wherein the aggregate is metastable.

A metastable system (illustrated in FIG. 19) refers herein to a system which for some physical and chemical conditions rests unperturbed in its local energetic minimum for a characteristic time to. After the typical time to, i.e. when said typical time to is overcome, or when an external stimulus like physical or chemical perturbations is strong enough, the system falls in a different and energetically more favored state.

The stimulus can be intrinsic; extrinsic; external, voluntary or involountary.

It is for example a system that is in an energetic state and can stay in said state for a long range of time. The transition rate from this state to a more stable state is very low, almost 0; the transition generally occurs upon an external stimulus.

Said metastable aggregate allows to keep particles in a medium that is normally chemically incompatible with said particles, freezing them in a non-stable thermodynamical state for some particular conditions. In standard chemical preparations, a homogeneous and stable mixture of said particles and said incompatible medium would be impossible to obtain.

For example, in a metastable system it is possible to keep hydrophobic particles in a hydrophilic medium, freezing them in a non-stable thermodynamical state for some particular conditions of temperature and pressure. In standard chemical preparations, a homogeneous and stable mixture of hydrophobic particles with a hydrophilic medium is impossible to obtain because of macroscopic segregation.

For example, a metastable system has the appearance of a stable system, regarding to the very low transition rate. An external stimulus can make the system transit to a more stable state. In the absence of a significant stimulus, the rate of the transition leading to a more stable state can be very low, almost zero. In response to a significant stimulus, the transition is triggered and can be very fast or almost instantaneous. The stability or metastability of a given system depends on its environment, for example temperature, pH, solvent, surrounding gas or pressure.

A metastable aggregate allows the dispersion of the material 11 and the release of at least one particle 12 upon an external stimulus for example. Hence, the aggregate 1 acts as a carrier and improves storage lifetime of particles 12.

The dispersion of the at least one particle 12 in the material 11 allows for an increased protection of said at least one particle 12 regarding the diffusion of outer molecular species or fluids (liquid or gas), especially deteriorating species like O₂ and H₂O to the surface of said particle 12. The material 11 acts as a supplementary barrier against outer molecular species or fluids that could impair the properties of the at least one particle 12. Outer molecular species or fluids refer to molecular species or fluids comprised outside of the particle 12.

Aggregates 1 of the invention are also particularly interesting as they can easily comply with ROHS requirements depending on the material (11, 121) selected. It is then possible to have ROHS compliant aggregates while preserving the properties of particles 12 that may not be ROHS compliant themselves.

According to one embodiment, the aggregate 1 is air processable. This embodiment is particularly advantageous for the manipulation or the transport of said aggregate 1 and for the use of said aggregate 1 in a device such as an optoelectronic device.

According to one embodiment, the aggregate 1 is compatible with standard lithography processes. This embodiment is particularly advantageous for the use of said aggregate in a device such as an optoelectronic device.

According to one embodiment, the aggregate 1 is dispersible in aqueous solvents, organic solvents and/or mixture thereof.

According to one embodiment, the aggregate 1 is dispersible in the liquid vehicle of an ink.

According to one embodiment, the material 11 is soluble in some liquids for releasing the particle 12 from the aggregate 1 and dispersing said particle 12 in said liquids.

According to one embodiment illustrated in FIG. 15, the material 11 can be dissolved by contact with some gas for releasing the particle 12 from the aggregate 1. For example, the aggregate 1 may be deposited onto a solid support, then exposed to a gas which dissolves the material 11, leading to the deposition of the particle 12 directly onto said support while the material 11 is removed by washing said support with a solvent in which the material 11 is soluble but the particle 12 cannot be dispersed.

According to one embodiment, the aggregate 1 is luminescent.

According to one embodiment, the aggregate 1 is fluorescent. According to one embodiment, the aggregate 1 is phosphorescent. According to one embodiment, the aggregate 1 is electroluminescent. According to one embodiment, the aggregate 1 is chemiluminescent. According to one embodiment, the aggregate 1 is triboluminescent.

According to one embodiment, the features of the light emission of aggregate 1 are sensible to external pressure variations. In this embodiment, “sensible” means that the features of the light emission can be modified by external pressure variations.

According to one embodiment, the wavelength emission peak of aggregate 1 is sensible to external pressure variations. In this embodiment, “sensible” means that the wavelength emission peak can be modified by external pressure variations, i.e. external pressure variations can induce a wavelength shift.

According to one embodiment, the FWHM of aggregate 1 is sensible to external pressure variations. In this embodiment, “sensible” means that the FWHM can be modified by external pressure variations, i.e. FWHM can be reduced or increased.

According to one embodiment, the PLQY of aggregate 1 is sensible to external pressure variations. In this embodiment, “sensible” means that the PLQY can be modified by external pressure variations, i.e. PLQY can be reduced or increased.

According to one embodiment, the features of the light emission of aggregate 1 are sensible to external temperature variations.

According to one embodiment, the wavelength emission peak of aggregate 1 is sensible to external temperature variations. In this embodiment, “sensible” means that the wavelength emission peak can be modified by external temperature variations, i.e. external temperature variations can induce a wavelength shift.

According to one embodiment, the FWHM of aggregate 1 is sensible to external temperature variations. In this embodiment, “sensible” means that the FWHM can be modified by external temperature variations, i.e. FWHM can be reduced or increased.

According to one embodiment, the PLQY of aggregate 1 is sensible to external temperature variations. In this embodiment, “sensible” means that the PLQY can be modified by external temperature variations, i.e. PLQY can be reduced or increased.

According to one embodiment, the features of the light emission of aggregate 1 are sensible to external variations of pH.

According to one embodiment, the wavelength emission peak of aggregate 1 is sensible to external variations of pH. In this embodiment, “sensible” means that the wavelength emission peak can be modified by external variations of pH, i.e. external variations of pH can induce a wavelength shift.

According to one embodiment, the FWHM of aggregate 1 is sensible to e external variations of pH. In this embodiment, “sensible” means that the FWHM can be modified by external variations of pH, i.e. FWHM can be reduced or increased.

According to one embodiment, the PLQY of aggregate 1 is sensible to external variations of pH. In this embodiment, “sensible” means that the PLQY can be modified by external variations of pH, i.e. PLQY can be reduced or increased.

According to one embodiment, the aggregate 1 comprise at least one particle 12 wherein the wavelength emission peak is sensible to external temperature variations; and at least one particle 12 wherein the wavelength emission peak is not or less sensible to external temperature variations. In this embodiment, “sensible” means that the wavelength emission peak can be modified by external temperature variations, i.e. wavelength emission peak can be reduced or increased. This embodiment is particularly advantageous for temperature sensor applications.

According to one embodiment, the aggregate 1 exhibits an emission spectrum with at least one emission peak, wherein said emission peak has a maximum emission wavelength ranging from 400 nm to 50 μm.

According to one embodiment, the aggregate 1 exhibits an emission spectrum with at least one emission peak, wherein said emission peak has a maximum emission wavelength ranging from 400 nm to 500 nm. In this embodiment, the aggregate 1 emits blue light.

According to one embodiment, the aggregate 1 exhibits an emission spectrum with at least one emission peak, wherein said emission peak has a maximum emission wavelength ranging from 500 nm to 560 nm, more preferably ranging from 515 nm to 545 nm. In this embodiment, the aggregate 1 emits green light.

According to one embodiment, the aggregate 1 exhibits an emission spectrum with at least one emission peak, wherein said emission peak has a maximum emission wavelength ranging from 560 nm to 590 nm. In this embodiment, the aggregate 1 emits yellow light.

According to one embodiment, the aggregate 1 exhibits an emission spectrum with at least one emission peak, wherein said emission peak has a maximum emission wavelength ranging from 590 nm to 750 nm, more preferably ranging from 610 nm to 650 nm. In this embodiment, the aggregate 1 emits red light.

According to one embodiment, the aggregate 1 exhibits an emission spectrum with at least one emission peak, wherein said emission peak has a maximum emission wavelength ranging from 750 nm to 50 μm. In this embodiment, the aggregate 1 emits near infra-red, mid-infra-red, or infra-red light.

According to one embodiment, the aggregate 1 exhibits emission spectra with at least one emission peak having a full width half maximum lower than 90 nm, 80 nm, 70 nm, 60 nm, 50 nm, 40 nm, 30 nm, 25 nm, 20 nm, 15 nm, or 10 nm.

According to one embodiment, the aggregate 1 exhibits emission spectra with at least one emission peak having a full width half maximum strictly lower than 40 nm, 30 nm, 25 nm, 20 nm, 15 nm, or 10 nm.

According to one embodiment, the aggregate 1 exhibits emission spectra with at least one emission peak having a full width at quarter maximum lower than 90 nm, 80 nm, 70 nm, 60 nm, 50 nm, 40 nm, 30 nm, 25 nm, 20 nm, 15 nm, or 10 nm.

According to one embodiment, the aggregate 1 exhibits emission spectra with at least one emission peak having a full width at quarter maximum strictly lower than 40 nm, 30 nm, 25 nm, 20 nm, 15 nm, or 10 nm.

According to one embodiment, the aggregate 1 has a photoluminescence quantum yield (PLQY) of at least 5%, 10%, 15%, 20%, 25%, 30%, 35%, 40%, 45%, 50%, 55%, 60%, 65%, 70%, 75%, 80%, 85%, 90%, 95%, 99% or 100%.

According to one embodiment, the aggregate 1 absorbs the incident light with wavelength lower than 50 μm, 40 μm, 30 μm, 20 μm, 10 μm, 1 μm, 950 nm, 900 nm, 850 nm, 800 nm, 750 nm, 700 nm, 650 nm, 600 nm, 550 nm, 500 nm, 450 nm, 400 nm, 350 nm, 300 nm, 250 nm, or lower than 200 nm.

According to one embodiment, the aggregate 1 has an average fluorescence lifetime of at least 0.1 nanosecond, 0.2 nanosecond, 0.3 nanosecond, 0.4 nanosecond, 0.5 nanosecond, 0.6 nanosecond, 0.7 nanosecond, 0.8 nanosecond, 0.9 nanosecond, 1 nanosecond, 2 nanoseconds, 3 nanoseconds, 4 nanoseconds, 5 nanoseconds, 6 nanoseconds, 7 nanoseconds, 8 nanoseconds, 9 nanoseconds, 10 nanoseconds, 11 nanoseconds, 12 nanoseconds, 13 nanoseconds, 14 nanoseconds, 15 nanoseconds, 16 nanoseconds, 17 nanoseconds, 18 nanoseconds, 19 nanoseconds, 20 nanoseconds, 21 nanoseconds, 22 nanoseconds, 23 nanoseconds, 24 nanoseconds, 25 nanoseconds, 26 nanoseconds, 27 nanoseconds, 28 nanoseconds, 29 nanoseconds, 30 nanoseconds, 31 nanoseconds, 32 nanoseconds, 33 nanoseconds, 34 nanoseconds, 35 nanoseconds, 36 nanoseconds, 37 nanoseconds, 38 nanoseconds, 39 nanoseconds, 40 nanoseconds, 41 nanoseconds, 42 nanoseconds, 43 nanoseconds, 44 nanoseconds, 45 nanoseconds, 46 nanoseconds, 47 nanoseconds, 48 nanoseconds, 49 nanoseconds, 50 nanoseconds, 100 nanoseconds, 150 nanoseconds, 200 nanoseconds, 250 nanoseconds, 300 nanoseconds, 350 nanoseconds, 400 nanoseconds, 450 nanoseconds, 500 nanoseconds, 550 nanoseconds, 600 nanoseconds, 650 nanoseconds, 700 nanoseconds, 750 nanoseconds, 800 nanoseconds, 850 nanoseconds, 900 nanoseconds, 950 nanoseconds, or 1 μsecond.

In one embodiment, the aggregate 1 exhibits photoluminescence quantum yield (PQLY) decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light with an average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm^{'12}, 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻². In this embodiment, the aggregate 1 preferably comprises quantum dots, semiconductor nanoparticles, semiconductor nanocrystals, or semiconductor nanoplatelets.

In one preferred embodiment, the aggregate 1 exhibits photoluminescence quantum yield (PQLY) decrease of less than 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light or continuous light with an average peak pulse power or photon flux of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the aggregate 1 exhibits FCE decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light with an average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻². In this embodiment, the aggregate 1 preferably comprises quantum dots, semiconductor nanoparticles, semiconductor nanocrystals, or semiconductor nanoplatelets.

In one preferred embodiment, the aggregate 1 exhibits FCE decrease of less than 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light or continuous light with an average peak pulse power or photon flux of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

According to one embodiment, the aggregate 1 is magnetic.

According to one embodiment, the aggregate 1 is ferromagnetic.

According to one embodiment, the aggregate 1 is paramagnetic.

According to one embodiment, the aggregate 1 is superparamagnetic.

According to one embodiment, the aggregate 1 is diamagnetic.

According to one embodiment, the aggregate 1 is plasmonic.

According to one embodiment, the aggregate 1 is piezo-electric.

According to one embodiment, the aggregate 1 is ferro-electric.

According to one embodiment, the aggregate 1 is pyro-electric.

According to one embodiment, the aggregate 1 is drug delivery featured.

According to one embodiment, the aggregate 1 is a light scatterer.

According to one embodiment, the aggregate 1 is a local high temperature heating system.

According to one embodiment, the aggregate 1 exhibits at least one property comprising one or more of the following: capacity of increasing local electromagnetic field, magnetization, magnetic coercivity, catalytic yield, catalytic properties, photovoltaic properties, photovoltaic yield, electrical polarization, thermal conductivity, electrical conductivity, permeability to molecular oxygen, permeability to molecular water, or any other properties.

According to one embodiment, the aggregate 1 is an electrical insulator. In this embodiment, the quenching of fluorescent properties for fluorescent particles 12 dispersed in the material 11 is prevented when it is due to electron transport. In this embodiment, the aggregate 1 may be used as an electrical insulator material exhibiting the same properties as the particles 12 dispersed in the material 11.

According to one embodiment, the aggregate 1 is an electrical conductor. This embodiment is particularly advantageous for an application of the aggregate 1 in photovoltaics or LEDs.

According to one embodiment, the aggregate 1 has an electrical conductivity at standard conditions ranging from 1×10⁻²⁰ to 10⁷ S/m, preferably from 1×10⁻¹⁵ to 5 S/m, more preferably from 1×10⁻⁷ to 1 S/m.

According to one embodiment, the aggregate 1 has an electrical conductivity at standard conditions of at least 1×10⁻²⁰ S/m, 0.5×10⁻¹⁹ S/m, 1×10⁻¹⁹ S/m, 0.5×10⁻¹⁸ S/m, 1×10⁻¹⁸ S/m, 0.5×10⁻¹⁷ S/m, 1×10⁻¹⁷ S/m, 0.5×10⁻¹⁶ S/m, 1×10⁻¹⁶ S/m, 0.5×10⁻¹⁵ S/m, 1×10⁻¹⁵ S/m, 0.5×10⁻¹⁴ S/m, 1×10⁻¹⁴ S/m, 0.5×10⁻¹³ S/m, 1×10⁻¹³ S/m, 0.5×10⁻¹²S/m, 1×10⁻¹² S/m, 0.5×10⁻¹¹ S/m, 1×10⁻¹¹ S/m, 0.5×10⁻¹⁰ S/m, 1×10⁻¹⁰ S/m, 0.5×10⁻⁹ S/m, 1×10⁻⁹ S/m, 0.5×10⁻⁸ S/m, 1×10⁻⁸ S/m, 0.5×10⁻⁷ S/m, 1×10⁻⁷ S/m, 0.5×10⁻⁶ S/m, 1×10⁻⁶ S/m, 0.5×10⁻⁵ S/m, 1×10⁻⁵ S/m, 0.5×10⁻⁴ S/m, 1×10⁻⁴ S/m, 0.5×10⁻³ S/m, 1×10⁻³ S/m, 0.5×10⁻² S/m, 1×10⁻² S/m, 0.5×10⁻¹ S/m, 1×10⁻¹ S/m, 0.5 S/m, 1 S/m, 1.5 S/m, 2 S/m, 2.5 S/m, 3 S/m, 3.5 S/m, 4 S/m, 4.5 S/m, 5 S/m, 5.5 S/m, 6 S/m, 6.5 S/m, 7 S/m, 7.5 S/m, 8 S/m, 8.5 S/m, 9 S/m, 9.5 S/m, 10 S/m, 50 S/m, 10² S/m, 5×10² S/m, 10³ S/m, 5×10³ S/m, 10⁴ S/m, 5×10⁴ S/m, 10⁵ S/m, 5×10⁵ S/m, 10⁶ S/m, 5×10⁶ S/m, or 10⁷ S/m.

According to one embodiment, the electrical conductivity of the aggregate 1 may be measured for example with an impedance spectrometer.

According to one embodiment, the aggregate 1 is a thermal insulator.

According to one embodiment, the aggregate 1 is a thermal conductor. In this embodiment, the aggregate 1 is capable of draining away the heat originating from the particles 12 dispersed the material 11 during light excitation, or from the environment.

According to one embodiment, the aggregate 1 has an electrical conductivity which could be controlled by external mechanical pressure.

According to one embodiment, the aggregate 1 has a thermal conductivity at standard conditions ranging from 0.1 to 450 W/(m·K), preferably from 1 to 200 W/(m·K), more preferably from 10 to 150 W/(m·K).

According to one embodiment, the aggregate 1 has a thermal conductivity at standard conditions of at least 0.1 W/(m·K), 0.2 W/(m·K), 0.3 W/(m·K), 0.4 W/(m·K), 0.5 W/(m·K), 0.6 W/(m·K), 0.7 W/(m·K), 0.8 W/(m·K), 0.9 W/(m·K), 1 W/(m·K), 1.1 W/(m·K), 1.2 W/(m·K), 1.3 W/(m·K), 1.4 W/(m·K), 1.5 W/(m·K), 1.6 W/(m·K), 1.7 W/(m·K), 1.8 W/(m·K), 1.9 W/(m·K), 2 W/(m·K), 2.1 W/(m·K), 2.2 W/(m·K), 2.3 W/(m·K), 2.4 W/(m·K), 2.5 W/(m·K), 2.6 W/(m·K), 2.7 W/(m·K), 2.8 W/(m·K), 2.9 W/(m·K), 3 W/(m·K), 3.1 W/(m·K), 3.2 W/(m·K), 3.3 W/(m·K), 3.4 W/(m·K), 3.5 W/(m·K), 3.6 W/(m·K), 3.7 W/(m·K), 3.8 W/(m·K), 3.9 W/(m·K), 4 W/(m·K), 4.1 W/(m·K), 4.2 W/(m·K), 4.3 W/(m·K), 4.4 W/(m·K), 4.5 W/(m·K), 4.6 W/(m·K), 4.7 W/(m·K), 4.8 W/(m·K), 4.9 W/(m·K), 5 W/(m·K), 5.1 W/(m·K), 5.2 W/(m·K), 5.3 W/(m·K), 5.4 W/(m·K), 5.5 W/(m·K), 5.6 W/(m·K), 5.7 W/(m·K), 5.8 W/(m·K), 5.9 W/(m·K), 6 W/(m·K), 6.1 W/(m·K), 6.2 W/(m·K), 6.3 W/(m·K), 6.4 W/(m·K), 6.5 W/(m·K), 6.6 W/(m·K), 6.7 W/(m·K), 6.8 W/(m·K), 6.9 W/(m·K), 7 W/(m·K), 7.1 W/(m·K), 7.2 W/(m·K), 7.3 W/(m·K), 7.4 W/(m·K), 7.5 W/(m·K), 7.6 W/(m·K), 7.7 W/(m·K), 7.8 W/(m·K), 7.9 W/(m·K), 8 W/(m·K), 8.1 W/(m·K), 8.2 W/(m·K), 8.3 W/(m·K), 8.4 W/(m·K), 8.5 W/(m·K), 8.6 W/(m·K), 8.7 W/(m·K), 8.8 W/(m·K), 8.9 W/(m·K), 9 W/(m·K), 9.1 W/(m·K), 9.2 W/(m·K), 9.3 W/(m·K), 9.4 W/(m·K), 9.5 W/(m·K), 9.6 W/(m·K), 9.7 W/(m·K), 9.8 W/(m·K), 9.9 W/(m·K), 10 W/(m·K), 10.1 W/(m·K), 10.2 W/(m·K), 10.3 W/(m·K), 10.4 W/(m·K), 10.5 W/(m·K), 10.6 W/(m·K), 10.7 W/(m·K), 10.8 W/(m·K), 10.9 W/(m·K), 11 W/(m·K), 11.1 W/(m·K), 11.2 W/(m·K), 11.3 W/(m·K), 11.4 W/(m·K), 11.5 W/(m·K), 11.6 W/(m·K), 11.7 W/(m·K), 11.8 W/(m·K), 11.9 W/(m·K), 12 W/(m·K), 12.1 W/(m·K), 12.2 W/(m·K), 12.3 W/(m·K), 12.4 W/(m·K), 12.5 W/(m·K), 12.6 W/(m·K), 12.7 W/(m·K), 12.8 W/(m·K), 12.9 W/(m·K), 13 W/(m·K), 13.1 W/(m·K), 13.2 W/(m·K), 13.3 W/(m·K), 13.4 W/(m·K), 13.5 W/(m·K), 13.6 W/(m·K), 13.7 W/(m·K), 13.8 W/(m·K), 13.9 W/(m·K), 14 W/(m·K), 14.1 W/(m·K), 14.2 W/(m·K), 14.3 W/(m·K), 14.4 W/(m·K), 14.5 W/(m·K), 14.6 W/(m·K), 14.7 W/(m·K), 14.8 W/(m·K), 14.9 W/(m·K), 15 W/(m·K), 15.1 W/(m·K), 15.2 W/(m·K), 15.3 W/(m·K), 15.4 W/(m·K), 15.5 W/(m·K), 15.6 W/(m·K), 15.7 W/(m·K), 15.8 W/(m·K), 15.9 W/(m·K), 16 W/(m·K), 16.1 W/(m·K), 16.2 W/(m·K), 16.3 W/(m·K), 16.4 W/(m·K), 16.5 W/(m·K), 16.6 W/(m·K), 16.7 W/(m·K), 16.8 W/(m·K), 16.9 W/(m·K), 17 W/(m·K), 17.1 W/(m·K), 17.2 W/(m·K), 17.3 W/(m·K), 17.4 W/(m·K), 17.5 W/(m·K), 17.6 W/(m·K), 17.7 W/(m·K), 17.8 W/(m·K), 17.9 W/(m·K), 18 W/(m·K), 18.1 W/(m·K), 18.2 W/(m·K), 18.3 W/(m·K), 18.4 W/(m·K), 18.5 W/(m·K), 18.6 W/(m·K), 18.7 W/(m·K), 18.8 W/(m·K), 18.9 W/(m·K), 19 W/(m·K), 19.1 W/(m·K), 19.2 W/(m·K), 19.3 W/(m·K), 19.4 W/(m·K), 19.5 W/(m·K), 19.6 W/(m·K), 19.7 W/(m·K), 19.8 W/(m·K), 19.9 W/(m·K), 20 W/(m·K), 20.1 W/(m·K), 20.2 W/(m·K), 20.3 W/(m·K), 20.4 W/(m·K), 20.5 W/(m·K), 20.6 W/(m·K), 20.7 W/(m·K), 20.8 W/(m·K), 20.9 W/(m·K), 21 W/(m·K), 21.1 W/(m·K), 21.2 W/(m·K), 21.3 W/(m·K), 21.4 W/(m·K), 21.5 W/(m·K), 21.6 W/(m·K), 21.7 W/(m·K), 21.8 W/(m·K), 21.9 W/(m·K), 22 W/(m·K), 22.1 W/(m·K), 22.2 W/(m·K), 22.3 W/(m·K), 22.4 W/(m·K), 22.5 W/(m·K), 22.6 W/(m·K), 22.7 W/(m·K), 22.8 W/(m·K), 22.9 W/(m·K), 23 W/(m·K), 23.1 W/(m·K), 23.2 W/(m·K), 23.3 W/(m·K), 23.4 W/(m·K), 23.5 W/(m·K), 23.6 W/(m·K), 23.7 W/(m·K), 23.8 W/(m·K), 23.9 W/(m·K), 24 W/(m·K), 24.1 W/(m·K), 24.2 W/(m·K), 24.3 W/(m·K), 24.4 W/(m·K), 24.5 W/(m·K), 24.6 W/(m·K), 24.7 W/(m·K), 24.8 W/(m·K), 24.9 W/(m·K), 25 W/(m·K), 30 W/(m·K), 40 W/(m·K), 50 W/(m·K), 60 W/(m·K), 70 W/(m·K), 80 W/(m·K), 90 W/(m·K), 100 W/(m·K), 110 W/(m·K), 120 W/(m·K), 130 W/(m·K), 140 W/(m·K), 150 W/(m·K), 160 W/(m·K), 170 W/(m·K), 180 W/(m·K), 190 W/(m·K), 200 W/(m·K), 210 W/(m·K), 220 W/(m·K), 230 W/(m·K), 240 W/(m·K), 250 W/(m·K), 260 W/(m·K), 270 W/(m·K), 280 W/(m·K), 290 W/(m·K), 300 W/(m·K), 310 W/(m·K), 320 W/(m·K), 330 W/(m·K), 340 W/(m·K), 350 W/(m·K), 360 W/(m·K), 370 W/(m·K), 380 W/(m·K), 390 W/(m·K), 400 W/(m·K), 410 W/(m·K), 420 W/(m·K), 430 W/(m·K), 440 W/(m·K), or 450 W/(m·K).

According to one embodiment, the thermal conductivity of the aggregate 1 may be measured for example by steady-state methods or transient methods.

According to one embodiment, the aggregate 1 is optically transparent, i.e. the aggregate 1 is transparent at wavelengths between 200 nm and 50 μm, between 200 nm and 10 μm, between 200 nm and 2500 nm, between 200 nm and 2000 nm, between 200 nm and 1500 nm, between 200 nm and 1000 nm, between 200 nm and 800 nm, between 400 nm and 700 nm, between 400 nm and 600 nm, or between 400 nm and 470 nm.

According to one embodiment, the aggregate 1 has a size of at least 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 um, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, a statistical set of aggregates 1 has an average size of at least 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12.5 μm, 13 μm, 13.5 μm, 14 μm, 14.5 μm, 15 μm, 15.5 μm, 16 μm, 16.5 μm, 17 μm, 17.5 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm , 70.5 μm, 71 μm, 71.5 μm, 72 μm, 72.5 μm, 73 μm , 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 82 m, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μ, 450 μm, 500 μm, 550 μm, 600 μm, 650 μm, 700 μm, 750 μm, 800 μm, 850 μm, 900 μm, 950 μm or 1 mm.

According to one embodiment, the aggregate 1 has a largest dimension of at least 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μ, 30.5 μm, 31 μm, 31.5 μm, 32 μm, 32.5 μm, 33 μm, 33.5 μm, 34 μm, 34.5 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, the aggregate 1 has a smallest dimension of at least 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μ, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52.5 μm, 53 μm, 53.5 μm, 54 μm, 54.5 μm, 55 μm, 55.5 μm, 56 μm, 56.5 μm, 57 μm, 57.5 μm , 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86.5 μm, 87 μm, 87.5 μm, 88 μm, 88.5 μm, 89 μm, 89.5 μm, 90 μm, 90.5 μm, 91 μm, 91.5 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, the smallest dimension of the aggregate 1 is smaller than the largest dimension of said aggregate 1 by a factor (aspect ratio) of at least 1.5; of at least 2; at least 2.5; at least 3; at least 3.5; at least 4; at least 4.5; at least 5; at least 5.5; at least 6; at least 6.5; at least 7; at least 7.5; at least 8; at least 8.5; at least 9; at least 9.5; at least 10; at least 10.5; at least 11; at least 11.5; at least 12; at least 12.5; at least 13; at least 13.5; at least 14; at least 14.5; at least 15; at least 15.5; at least 16; at least 16.5; at least 17; at least 17.5; at least 18; at least 18.5; at least 19; at least 19.5; at least 20; at least 25; at least 30; at least 35; at least 40; at least 45; at least 50; at least 55; at least 60; at least 65; at least 70; at least 75; at least 80; at least 85; at least 90; at least 95; at least 100; at least 150; at least 200; at least 250; at least 300; at least 350; at least 400; at least 450; at least 500; at least 550; at least 600; at least 650; at least 700; at least 750; at least 800; at least 850; at least 900; at least 950; or at least 1000.

According to one embodiment, the aggregate 1 have an average size of at least 5 nm, 10 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16.5 μm, 17 μm, 17.5 μm, 18 μm, 18.5 μm, 19 μm, 19.5 μm, 20 μm, 20.5 μm, 21 μm, 21.5 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 51.5 μm, 52 52.5 μm, 53 μm, 53.5 μm, 54 μm, 54.5 μm, 55 μm, 55.5 μm, 56μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, the aggregate 1 has a smallest curvature of at least 200 μm⁻¹, 100 μm⁻¹, 66.6 μm⁻¹, 50 μm⁻¹, 33.3 μm⁻¹, 28.6 μm⁻¹, 25 μm⁻¹, 20 μm⁻¹, 18.2 μm⁻¹, 16.7 μm⁻¹, 15.4 μm⁻¹, 14.3 μm⁻¹, 13.3 μm⁻¹, 12.5 μm⁻¹, 11.8 μm⁻¹, 11.1 μm⁻¹, 10.5 μm⁻¹, 10 μm⁻¹, 9.5 μm⁻¹, 9.1 μm⁻¹, 8.7 μm⁻¹, 8.3 μm⁻¹, 8 μm⁻, 7.7 μm⁻¹, 7.4 μm⁻¹, 7.1 μm⁻¹, 6.9 μm⁻¹, 6.7 μm⁻¹, 5.7 μm⁻¹, 5 μm⁻¹, 4.4 μm⁻¹, 3.6 μm⁻¹, 3.3 μm⁻¹, 3.1 μm⁻¹, 2.9 μm⁻¹, 2.7 μm⁻¹, 2.5 μm⁻¹, 2.4 μm⁻¹, 2.2 μm⁻¹, 2.1 μm⁻¹, 2 μm⁻¹, 1.3333 μm⁻¹, 0.8 μm⁻¹, 0.6666 μm⁻¹, 0.5714 μm⁻¹, 0.5 μm⁻¹, 0.4444 μm⁻¹, 0.4 μm⁻¹, 0.3636 μm⁻¹, 0.3333 μm⁻¹, 0.3080 μm⁻¹, 0.2857 μm⁻¹, 0.2667 μm⁻¹, 0.25 μm⁻¹, 0.2353 μm⁻¹, 0.2222 μm⁻¹, 0.2105 μm⁻¹, 0.2 μm⁻¹, 0.1905 μm⁻¹, 0.1818 μm⁻¹, 0.1739 μm⁻¹, 0.1667 μm⁻¹, 0.16 μm⁻¹, 0.1538 μm⁻¹, 0.1481 μm⁻¹, 0.1429 μm⁻¹, 0.1379 μm⁻¹, 0.1333 μm⁻¹, 0.1290 μm⁻¹, 0.125 μm⁻¹, 0.1212 μm⁻¹, 0.1176 μm⁻¹, 0.1176 μm⁻¹, 0.1143 μm⁻¹, 0.1111 μm⁻¹, 0.1881 μm⁻¹, 0.1053 μm⁻¹, 0.1026 μm⁻¹, 0.1 μm⁻¹, 0.0976 μm⁻¹, 0.9524 μm⁻¹, 0.0930 μm⁻¹, 0.0909 μm⁻¹, 0.0889 μm⁻¹, 0.870 μm⁻¹, 0.0851 μm⁻¹, 0.0833 μm⁻¹, 0.0816 μm⁻¹, 0.08 μm⁻¹, 0.0784 μm⁻¹, 0.0769 μm⁻¹, 0.0755 μm⁻¹, 0.0741 μm⁻¹, 0.0727 μm⁻¹, 0.0714 μm⁻¹, 0.0702 μm⁻¹, 0.0690 μm⁻¹, 0.0678 μm⁻¹, 0.0667 μm⁻¹, 0.0656 μm⁻¹, 0.0645 μm⁻¹, 0.0635 μm⁻¹, 0.0625 μm⁻¹, 0.0615 μm⁻¹, 0.0606 μm⁻¹, 0.0597 μm⁻¹, 0.0588 μm⁻¹, 0.0580 μm⁻¹, 0.0571 μm⁻¹, 0.0563 μm⁻¹, 0.0556 μm⁻¹, 0.0548 μm⁻¹, 0.0541 μm⁻¹, 0.0533 μm⁻¹, 0.0526 μm⁻¹, 0.0519 μm⁻¹, 0.0513 μm⁻¹, 0.0506 μm⁻¹, 0.05 μm⁻¹, 0.0494 μm⁻¹, 0.0488 μm⁻¹, 0.0482 μm⁻¹, 0.0476 μm⁻¹, 0.0471 μm⁻¹, 0.0465 μm⁻¹, 0.0460 μm⁻¹, 0.0455 μm⁻¹, 0.0450 μm⁻¹, 0.0444 μm⁻¹, 0.0440 μm⁻, 0.0435 μm⁻¹, 0.0430 μm⁻¹, 0.0426 μm⁻¹, 0.0421 μm⁻¹, 0.0417 μm⁻¹, 0.0412 μm⁻¹, 0.0408 μm⁻¹, 0.0404 μm⁻¹, 0.04 μm⁻¹, 0.0396 μm⁻¹, 0.0392 μm⁻¹, 0.0388 μm⁻¹, 0.0385 μm⁻¹; 0.0381 μm⁻¹, 0.0377 μm⁻¹, 0.0374 μm⁻¹, 0.037 μm⁻¹, 0.0367 82 m⁻¹, 0.0364 μm⁻¹, 0.0360 μm⁻¹, 0.0357 μm⁻¹, 0.0354 μm⁻¹, 0.0351 μm⁻¹, 0.0348 μm⁻¹, 0.0345 μm⁻¹, 0.0342 μm⁻¹, 0.0339 μm⁻¹, 0.0336 μm⁻¹, 0.0333 μm⁻¹, 0.0331 μm⁻¹, 0.0328 μm⁻¹, 0.0325 μm⁻¹ , 0.0323 μm⁻¹, 0.032 μm⁻¹, 0.0317 μm⁻¹, 0.0315 μm⁻¹, 0.0312 μm⁻¹, 0.031 μm⁻¹, 0.0308 μm⁻¹, 0.0305 μm⁻¹, 0.0303 μm⁻¹, 0.0301 μm⁻¹, 0.03 μm⁻¹, 0.0299 μm⁻¹, 0.0296 μm⁻¹, 0.0294 μm⁻¹, 0.0292 μm⁻¹, 0.029 82 m⁻¹, 0.0288 μm⁻¹, 0.0286 μm⁻¹, 0.0284 μm⁻¹, 0.0282 μm⁻¹, 0.028 μm⁻¹, 0.0278 μm⁻¹, 0.0276 μm⁻¹, 0.0274 μm⁻¹, 0.0272 μm⁻¹; 0.0270 μm⁻¹, 0.0268 μm⁻¹, 0.02667 μm⁻¹, 0.0265 μm⁻¹, 0.0263 μm⁻¹, 0.0261 μm⁻¹, 0.026 μm⁻¹, 0.0258 μm⁻¹, 0.0256 μm⁻¹, 0.0255 μm⁻¹, 0.0253 μm⁻¹, 0.0252 μm⁻¹, 0.025 μm⁻¹, 0.0248 μm⁻¹, 0.0247 μm⁻¹, 0.0245 μm⁻¹, 0.0244 μm⁻¹, 0.0242 μm⁻¹, 0.0241 μm⁻¹, 0.024 μm⁻¹, 0.0238 μm⁻¹, 0.0237 μm⁻¹, 0.0235 μm⁻¹, 0.0234 μm⁻¹, 0.0233 μm⁻¹, 0.231 μm⁻¹, 0.023 μm⁻¹, 0.0229 μm⁻¹, 0.0227 μm⁻¹, 0.0226 μm⁻¹, 0.0225 μm⁻¹, 0.0223 μm⁻¹, 0.0222 μm⁻¹, 0.0221 μm⁻¹, 0.022 μm⁻¹, 0.0219 μm⁻¹, 0.0217 μm⁻¹, 0.0216 μm⁻¹, 0.0215 μm⁻¹, 0.0214 μm⁻¹, 0.0213 μm⁻¹, 0.0212 μm⁻¹, 0.0211 μm⁻¹, 0.021 μm⁻¹, 0.0209 μm⁻¹, 0.0208 μm⁻¹, 0.0207 μm⁻¹, 0.0206 μm⁻¹, 0.0205 μm⁻¹, 0.0204 μm⁻¹, 0.0203 μm⁻¹, 0.0202 μm⁻¹, 0.0201 μm⁻¹, 0.02 μm⁻¹, or 0.002 μm⁻¹.

According to one embodiment, the aggregate 1 has a largest curvature of at least 200 μm⁻¹, 100 μm⁻¹, 66.6 μm⁻¹, 50 μm⁻¹, 33.3 μm⁻¹, 28.6 μm⁻¹, 25 μm⁻¹, 20 μm⁻¹, 18.2 μm⁻¹, 16.7 μm⁻¹, 15.4 μm⁻¹, 14.3 μm⁻¹, 13.3 μm⁻¹, 12.5 μm⁻¹, 11.8 μm⁻¹, 11.1 μm⁻¹, 10.5 μm⁻¹, 10 μm⁻¹, 9.5 μm⁻¹, 9.1 μm⁻¹, 8.7 μm⁻¹, 8.3 μm⁻¹, 8 μm⁻¹, 7.7 μm⁻¹, 7.4 μm⁻¹, 7.1 μm⁻¹, 6.9 um⁻¹, 6.7 μm⁻¹, 5.7 μm⁻¹, 5 μm⁻¹, 4.4 μm⁻¹, 4 μm⁻¹, 3.6 μm⁻¹, 3.3 μm⁻¹, 3.1 μm⁻¹, 2.9 μm⁻¹, 2.7 μm⁻¹, 2.5 μm⁻¹, 2.4 μm⁻¹, 2.2 μm⁻¹, 2.1 μm⁻¹, 2 μm⁻¹, 1.3333 μm⁻¹, 0.8 μm⁻¹, 0.6666 μm⁻¹, 0.5714 μm⁻¹, 0.5 μm⁻¹, 0.4444 μm⁻¹, 0.4 μm⁻¹, 0.3636 μm⁻¹, 0.3333 μm⁻¹, 0.3080 μm⁻¹, 0.2857 μm⁻¹, 0.2667 μm⁻¹, 0.25 μm⁻¹, 0.2353 μm⁻¹, 0.2222 μm⁻¹, 0.2105 μm⁻¹, 0.2 μm⁻¹, 0.1905 μm⁻¹, 0.1818 μm⁻¹, 0.1739 μm⁻¹, 0.1667 μm⁻¹, 0.16 μm⁻¹, 0.1538 μm⁻¹, 0.1481 μm⁻¹, 0.1429 μm⁻¹, 0.1379 μm⁻¹, 0.1333 μm⁻¹, 0.1290 μm⁻¹, 0.125 μm⁻¹, 0.1212 μm⁻¹, 0.1176 μm⁻¹, 0.1176 μm⁻¹, 0.1143 μm⁻¹, 0.1111 μm⁻¹, 0.1881 μm⁻¹, 0.1053 μm⁻¹, 0.1026 μm⁻¹, 0.1 μm⁻¹, 0.0976 μm⁻¹, 0.9524 μm⁻¹, 0.0930 μm⁻¹, 0.0909 μm⁻¹, 0.0889 μm⁻¹, 0.870 μm⁻¹, 0.0851 μm⁻¹, 0.0833 μm⁻¹, 0.0816 μm⁻¹, 0.08 μm⁻¹, 0.0784 μm⁻¹, 0.0769 μm⁻¹, 0.0755 μm⁻¹, 0.0741 μm⁻¹, 0.0727 μm⁻¹, 0.0714 μm⁻¹, 0.0702 μm⁻¹, 0.0690 μm⁻¹, 0.0678 μm⁻¹, 0.0667 μm⁻¹, 0.0656 μm⁻¹, 0.0645 μm⁻¹, 0.0635 μm⁻¹, 0.0625 μm⁻¹, 0.0615 μm⁻¹, 0.0606 μm⁻¹, 0.0597 μm⁻¹, 0.0588 μm⁻¹, 0.0580 μm⁻¹, 0.0571 μm⁻¹, 0.0563 μm⁻¹, 0.0556 μm⁻¹, 0.0548 μm⁻¹, 0.0541 μm⁻¹, 0.0533 μm⁻¹, 0.0526 μm⁻¹, 0.0519 μm⁻¹, 0.0513 μm⁻¹, 0.0506 μm⁻¹, 0.05 μm⁻¹, 0.0494 μm⁻¹, 0.0488 μm⁻¹, 0.0482 μm⁻¹, 0.0476 μm⁻¹, 0.0471 μm⁻¹, 0.0465 μm⁻¹, 0.0460 μm⁻¹, 0.0455 μm⁻¹, 0.0450 μm⁻¹, 0.0444 μm⁻¹, 0.0440 μm⁻¹, 0.0435 μm⁻¹, 0.0430 μm⁻¹, 0.0426 μm⁻¹, 0.0421 μm⁻¹, 0.0417 μm⁻¹, 0.0412 μm⁻¹, 0.0408 μm⁻¹, 0.0404 μm⁻¹, 0.04 μm⁻¹, 0.0396 μm⁻¹, 0.0392 μm⁻¹, 0.0388 μm⁻¹, 0.0385 μm⁻¹; 0.0381 μm⁻¹, 0.0377 μm⁻¹, 0.0374 μm⁻¹, 0.037 μm⁻¹, 0.0367 μm⁻¹, 0.0364 μm⁻¹, 0.0360 μm⁻¹, 0.0357 μm⁻¹, 0.0354 μm⁻¹, 0.0351 μm⁻¹, 0.0348 μm⁻¹, 0.0345 μm⁻¹, 0.0342 μm⁻¹, 0.0339 μm⁻¹, 0.0336 μm⁻¹, 0.0333 μm⁻¹, 0.0331 μm⁻¹, 0.0328 μm⁻¹, 0.0325 μm⁻¹, 0.0323 μm⁻¹, 0.032 μm⁻¹, 0.0317 μm⁻¹, 0.0315 μm⁻¹, 0.0312 μm⁻¹, 0.031 μm⁻¹, 0.0308 μm⁻¹, 0.0305 μm⁻¹, 0.0303 μm⁻¹, 0.0301 μm⁻¹, 0.03 μm⁻¹, 0.0299 μm⁻¹, 0.0296 μm⁻¹, 0.0294 μm⁻¹, 0.0292 μm⁻¹, 0.029 μm⁻¹, 0.0288 μm⁻¹, 0.0286 μm⁻¹, 0.0284 μm⁻¹, 0.0282 μm⁻¹, 0.028 μm⁻¹, 0.0278 μm⁻¹, 0.0276 μm⁻¹, 0.0274 μm⁻¹, 0.0272 μm⁻¹; 0.0270 μm⁻¹, 0.0268 μm⁻¹, 0.02667 μm⁻¹, 0.0265 μm⁻¹, 0.0263 μm⁻¹, 0.0261 μm⁻¹, 0.026 μm⁻¹, 0.0258 μm⁻¹, 0.0256 μm⁻¹, 0.0255 μm⁻¹, 0.0253 μm⁻¹, 0.0252 μm⁻¹, 0.025 μm⁻¹, 0.0248 μm⁻¹, 0.0247 μm⁻¹, 0.0245 μm⁻¹, 0.0244 μm⁻¹, 0.0242 μm⁻¹, 0.0241 μm⁻¹, 0.024 μm⁻¹, 0.0238 μm⁻¹, 0.0237 μm⁻¹, 0.0235 μm⁻¹, 0.0234 μm⁻¹, 0.0233 μm⁻¹, 0.231 μm⁻¹, 0.023 μm⁻, 0.0229 μm⁻¹, 0.0227 μm⁻¹, 0.0226 μm⁻¹, 0.0225 μm⁻¹, 0.0223 μm⁻¹, 0.0222 μm⁻¹, 0.0221 μm⁻¹, 0.022 μm⁻¹, 0.0219 μm⁻¹, 0.0217 μm⁻¹, 0.0216 μm⁻¹, 0.0215 μm⁻¹, 0.0214 μm⁻¹, 0.0213 μm⁻¹, 0.0212 μm⁻¹, 0.0211 μm⁻¹, 0.021 μm⁻¹, 0.0209 μm⁻¹, 0.0208 μm⁻¹, 0.0207 μm⁻¹, 0.0206 μm⁻¹, 0.0205 μm⁻¹, 0.0204 μm⁻¹, 0.0203 μm⁻¹, 0.0202 μm⁻¹, 0.0201 μm⁻¹, 0.02 μm⁻¹, or 0.002 ∥m⁻¹.

Aggregate 1 with an average size less than 1 μm have several advantages compared to bigger particles or aggregates comprising the same number of particles 12: i) increasing the light scattering compared to bigger particles or aggregates (only for aggregates 1 with a size superior to 100 nm); ii) obtaining more stable colloidal suspensions compared to bigger particles or aggregates, when they are dispersed in a solvent; iii) having a size compatible with pixels of at least 100 nm.

Aggregates 1 with an average size larger than 1 μm have several advantages compared to smaller particles comprising the same number of particles 12: i) reducing light scattering compared to smaller particles or aggregates; ii) having whispering-gallery wave modes; iii) having a size compatible with pixels larger than or equal to 1 um; iv) increasing the average distance between particles 12 comprised in one aggregate 1, resulting in a better heat draining; v) increasing the average distance between particles 12 comprised in one aggregate 1 and the surface of said aggregate 1, thus better protecting the particles 12 against oxidation, or delaying oxidation resulting from a chemical reaction with chemical species coming from the outer space of said aggregate 1; vi) increasing the mass ratio between the aggregate 1 and particle 12 comprised in one aggregate 1 compared to smaller particle or aggregate, thus reducing the mass concentration of chemical elements subject to ROHS standards, making it easier to comply with ROHS requirements.

According to one embodiment, in a statistical set of aggregates 1, said aggregates 1 are polydisperse.

According to one embodiment, in a statistical set of aggregates 1, said aggregates 1 are monodisperse.

According to one embodiment, in a statistical set of aggregates 1, said aggregates 1 have a narrow size distribution.

According to one embodiment, dispersed in a fluid (gas or liquid) such as for example a solvent or the liquid vehicle of an ink, the aggregates 1 are not aggregated to one another.

According to one embodiment, dispersed in a fluid (gas or liquid) such as for example a solvent or the liquid vehicle of an ink, the aggregates 1 are not in contact in the liquid vehicle.

According to one embodiment, dispersed in a fluid (gas or liquid) such as for example a solvent or the liquid vehicle of an ink, the aggregates 1 are individually dispersed in the liquid vehicle.

According to one embodiment, dispersed in a fluid (gas or liquid) such as for example a solvent or the liquid vehicle of an ink, the aggregates 1 are aggregated in the liquid vehicle.

According to one embodiment, dispersed in a fluid (gas or liquid) such as for example a solvent or the liquid vehicle of an ink, the aggregates 1 are in contact in the liquid vehicle.

According to one embodiment, the aggregate 1 has a spherical shape, an ovoid shape, a discoidal shape, a cylindrical shape, a faceted shape, a hexagonal shape, a triangular shape, a cubic shape, a raspberry shape, a prism shape, a polyhedron shape, a snowflake shape, a flower shape, a thorn shape, a hemisphere shape, a cone shape, a urchin shape, a filamentous shape, a biconcave discoid shape, a worm shape, a tree shape, a dendrite shape, a necklace shape, a chain shape, a bush shape or a platelet shape.

According to one embodiment, the surface roughness of the aggregate 1 is less or equal to 0%, 0.0001%, 0.0002%, 0.0003%, 0.0004%, 0.0005%, 0.0006%, 0.0007%, 0.0008%, 0.0009%, 0.001%, 0.002%, 0.003%, 0.004%, 0.005%, 0.006%, 0.007%, 0.008%, 0.009%, 0.01%, 0.02%, 0.03%, 0.04%, 0.05%, 0.06%, 0.07%, 0.08%, 0.09%, 0.1%, 0.11%, 0.12%, 0.13%, 0.14%, 0.15%, 0.16%, 0.17%, 0.18%, 0.19%, 0.2%, 0.21%, 0.22%, 0.23%, 0.24%, 0.25%, 0.26%, 0.27%, 0.28%, 0.29%, 0.3%, 0.31%, 0.32%, 0.33%, 0.34%, 0.35%, 0.36%, 0.37%, 0.38%, 0.39%, 0.4%, 0.41%, 0.42%, 0.43%, 0.44%, 0.45%, 0.46%, 0.47%, 0.48%, 0.49%, 0.5%, 1%, 1.5%, 2%, 2.5% 3%, 3.5%, 4%, 4.5%, or 5% of the largest dimension of said aggregate 1, meaning that the surface of said aggregate 1 is completely smooth.

According to one embodiment, the surface roughness of the aggregate 1 is less or equal to 0.5% of the largest dimension of said aggregate 1, meaning that the surface of said aggregate 1 is completely smooth.

According to one embodiment, the aggregate 1 has a spherical shape, or the aggregate 1 is a bead.

According to one embodiment, the aggregate 1 is hollow, i.e. the aggregate 1 is a hollow bead.

According to one embodiment, the aggregate 1 does not have a core/shell structure.

According to one embodiment, the aggregate 1 has a core/shell structure as described hereafter.

According to one embodiment, the aggregate 1 is not a fiber.

According to one embodiment, the aggregate 1 is not a matrix with undefined shape.

According to one embodiment, the aggregate 1 is not macroscopical piece of glass. In this embodiment, a piece of glass refers to glass obtained from a bigger glass entity for example by cutting it, or to glass obtained by using a mold. In one embodiment, a piece of glass has at least one dimension exceeding 1 mm.

According to one embodiment, the aggregate 1 is not obtained by reducing the size of the material 11. For example, aggregate 1 is not obtained by milling a piece of material 11, nor by cutting it, nor by firing it with projectiles like particles, atomes or electrons, or by any other method.

According to one embodiment, the aggregate 1 is not obtained by milling bigger particles or by spraying a powder.

According to one embodiment, the aggregate 1 is not a piece of nanometer pore glass doped with particles 12.

According to one embodiment, the aggregate 1 is not a glass monolith.

According to one embodiment, the spherical aggregate 1 has a diameter of at least 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35.5 μm, 36 μm, 36.5 μm, 37 μm, 37.5 μm, 38 μm, 38.5 μm, 39 μm, 39.5 μm, 40 μm, 40.5 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69.5 μm, 70 μm, 70.5 μm, 71 μm, 71.5 μm, 72 μm, 72.5 μm, 73 μm, 73.5 μm, 74 μm, 74.5 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86.5 μm, 87 μm, 87.5 μm, 88 μm, 88.5 μm, 89 μm, 89.5 μ, 90 μ, 90.5 μ, 91 μm, 91.5 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, a statistical set of spherical aggregates 1 has an average diameter of at least 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5.5 μm, 6 μm, 6.5 μm, 7 μm, 7.5 μm, 8 μm, 8.5 μm, 9 μm, 9.5 μm, 10 μm, 10.5 μm, 11.5 μ, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, the average diameter of a statistical set of spherical aggregates 1 may have a deviation less or equal to 0.01%, 0.02%, 0.03%, 0.04%, 0.05%, 0.06%, 0.07%, 0.08%, 0.09%, 0.1%, 0.2%, 0.3%, 0.4%, 0.5%, 0.6%, 0.7%, 0.8%, 0.9%, 1%, 1.1%, 1.2%, 1.3%, 1.4%, 1.5%, 1.6%, 1.7%, 1.8%, 1.9%, 2%, 2.1%, 2.2%, 2.3%, 2.4%, 2.5%, 2.6%, 2.7%, 2.8%, 2.9%, 3%, 3.1%, 3.2%, 3.3%, 3.4%, 3.5%, 3.6%, 3.7%, 3.8%, 3.9%, 4%, 4.1%, 4.2%, 4.3%, 4.4%, 4.5%, 4.6%, 4.7%, 4.8%, 4.9%, 5%, 5.1%, 5.2%, 5.3%, 5.4%, 5.5%, 5.6%, 5.7%, 5.8%, 5.9%, 6%, 6.1%, 6.2%, 6.3%, 6.4%, 6.5%, 6.6%, 6.7%, 6.8%, 6.9%, 7%, 7.1%, 7.2%, 7.3%, 7.4%, 7.5%, 7.6%, 7.7%, 7.8%, 7.9%, 8%, 8.1%, 8.2%, 8.3%, 8.4%, 8.5%, 8.6%, 8.7%, 8.8%, 8.9%, 9%, 9.1%, 9.2%, 9.3%, 9.4%, 9.5%, 9.6%, 9.7%, 9.8%, 9.9%, 10%, 20%, 30%, 40%, 50%, 60%, 70%, 80%, 85%, 90%, 95%, 100%, 105%, 110%, 115%, 120%, 125%, 130%, 135%, 140%, 145%, 150%, 155%, 160%, 165%, 170%, 175%, 180%, 185%, 190%, 195%, or 200%.

According to one embodiment, the spherical aggregate 1 has a unique curvature of at least 200 μm⁻¹, 100 μm⁻¹, 66.6 μm⁻¹, 50 μm⁻¹, 33.3 μm⁻¹, 28.6 μm⁻¹, 25 μm⁻¹, 20 μm⁻¹, 18.2 μm⁻¹, 16.7 μm⁻¹, 15.4 μm⁻¹, 14.3 μm⁻¹, 13.3 μm⁻¹, 12.5 μm⁻¹, 11.8 μm⁻¹, 11.1 μm⁻¹, 10.5 μm⁻¹, 10 μm⁻¹, 9.5 μm⁻¹, 9.1 μm⁻¹, 8.7 μm⁻¹, 8.3 μm⁻¹, 8 μm⁻¹, 7.7 μm⁻¹, 7.4 μm⁻¹, 7.1 μm⁻¹, 6.9 μm⁻¹, 6.7 μm⁻¹, 5.7 μm⁻¹, 5 μm⁻¹, 4.4 μm⁻¹, 3.3 μm⁻¹, 2.9 μm⁻¹, 2.7 μm⁻¹, 2.5 μm⁻¹, 2.4 μm⁻¹, 2.2 μm⁻¹, 2.1 μm⁻¹, 2 μm⁻¹, 1.3333 μm⁻¹, 0.8 μm⁻¹, 0.6666 μm⁻¹, 0.5714 μm⁻¹, 0.5 μm⁻¹, 0.4444 μm⁻¹, 0.4 μm⁻¹, 0.3636 μm⁻¹, 0.3333 μm⁻¹, 0.3080 μm⁻¹, 0.2857 μm⁻¹, 0.2667 μm⁻¹, 0.25 μm⁻¹, 0.2353 μm⁻¹, 0.2222 μm⁻¹, 0.2105 μm⁻¹, 0.2 μm⁻¹, 0.1905 μm⁻¹, 0.1818 μm⁻¹, 0.1739 μm⁻¹, 0.1667 μm⁻¹, 0.16 μm⁻¹, 0.1538 μm⁻¹, 0.1481 μm⁻¹, 0.1429 μm⁻¹, 0.1379 μm⁻¹, 0.1333 μm⁻¹, 0.1290 μm⁻¹, 0.125 μm⁻¹, 0.1212 μm⁻¹, 0.1176 μm⁻¹, 0.1176 μm⁻¹, 0.1143 μm⁻¹, 0.1111 μm⁻¹, 0.1881 μm⁻¹, 0.1053 μm⁻¹, 0.1026 μm⁻¹, 0.1 μm⁻¹, 0.0976 μm⁻¹, 0.9524 μm⁻¹, 0.0930 μm⁻¹, 0.0909 μm⁻¹, 0.0889 μm⁻¹, 0.870 μm⁻¹, 0.0851 μm⁻¹, 0.0833 μm⁻¹, 0.0816 μm⁻¹, 0.08 μm⁻¹, 0.0784 μm⁻¹, 0.0769 μm⁻¹, 0.0755 μm⁻¹, 0.0741 μm⁻¹, 0.0727 μm⁻¹, 0.0714 μm⁻¹, 0.0702 μm⁻¹, 0.0690 μm⁻¹, 0.0678 μm⁻¹, 0.0667 μm⁻¹, 0.0656 μm⁻¹, 0.0645 μm⁻¹, 0.0635 μm⁻¹, 0.0625 μm⁻¹, 0.0615 μm⁻¹, 0.0606 μm⁻¹, 0.0597 μm⁻¹, 0.0588 μm⁻¹, 0.0580 μm⁻¹, 0.0571 μm⁻¹, 0.0563 μm⁻¹, 0.0556 μm⁻¹, 0.0548 μm⁻¹, 0.0541 μm⁻¹, 0.0533 μm⁻¹, 0.0526 μm⁻¹, 0.0519 μm⁻¹, 0.0513 μm⁻¹, 0.0506 μm⁻¹, 0.05 μm⁻¹, 0.0494 μm⁻¹, 0.0488 μm⁻¹, 0.0482 μm⁻¹, 0.0476 μm⁻¹, 0.0471 μm⁻¹, 0.0465 μm⁻¹, 0.0460 μm⁻¹, 0.0455 μm⁻¹, 0.0450 μm⁻¹, 0.0444 μm⁻¹, 0.0440 μm⁻¹, 0.0435 μm⁻¹, 0.0430 μm⁻¹, 0.0426 μm⁻¹, 0.0421 μm⁻¹, 0.0417 μm⁻¹, 0.0412 μm⁻¹, 0.0408 μm⁻¹, 0.0404 μm⁻¹, 0.04 μm⁻¹, 0.0396 μm⁻¹, 0.0392 μm⁻¹, 0.0388 μm⁻¹, 0.0385 μm⁻¹; 0.0381 μm⁻¹, 0.0377 μm⁻¹, 0.0374 μm⁻¹, 0.037 μm⁻¹, 0.0367 μm⁻¹, 0.0364 μm⁻¹, 0.0360 μm⁻¹, 0.0357 μm⁻¹, 0.0354 μm⁻¹, 0.0351 μm⁻¹, 0.0348 μm⁻¹, 0.0345 μm⁻¹, 0.0342 μm⁻¹, 0.0339 μm⁻¹, 0.0336 μm⁻¹, 0.0333 μm⁻¹, 0.0331 μm⁻¹, 0.0328 μm⁻¹, 0.0325 μm⁻¹, 0.0323 μm⁻¹, 0.032 μm⁻¹, 0.0317 μm⁻¹, 0.0315 μm⁻¹, 0.0312 μm⁻¹, 0.031 μm⁻¹, 0.0308 μm⁻¹, 0.0305 μm⁻¹, 0.0303 μm⁻¹, 0.0301 μm⁻¹, 0.03 μm⁻¹, 0.0299 ∥m⁻¹, 0.0296 μm⁻¹, 0.0294 μm⁻¹, 0.0292 μm⁻¹, 0.029 μm⁻¹, 0.0288 μm⁻¹, 0.0286 μm⁻¹, 0.0284 μm⁻¹, 0.0282 μm⁻¹, 0.028 μm⁻¹, 0.0278 μm⁻¹, 0.0276 μm⁻¹, 0.0274 μm⁻¹, 0.0272 μm⁻¹; 0.0270 μm⁻¹, 0.0268 μm⁻¹, 0.02667 μm⁻¹, 0.0265 μm⁻¹, 0.0263 μm⁻¹, 0.0261 μm⁻¹, 0.026 μm⁻¹, 0.0258 μm⁻¹, 0.0256 μm⁻¹, 0.0255 μm⁻¹, 0.0253 μm⁻¹, 0.0252 μm⁻¹, 0.025 μm⁻¹, 0.0248 μm⁻¹, 0.0247 μm⁻¹, 0.0245 μm⁻¹, 0.0244 μm⁻¹, 0.0242 μm⁻¹, 0.0241 μm⁻¹, 0.024 μm⁻¹, 0.0238 μm⁻¹, 0.0237 μm⁻¹, 0.0235 μm⁻¹, 0.0234 μm⁻¹, 0.0233 μm⁻¹, 0.231 μm⁻¹, 0.023 μm⁻¹, 0.0229 μm⁻¹, 0.0227 μm⁻¹, 0.0226 μm⁻¹, 0.0225 μm⁻¹, 0.0223 μm⁻¹, 0.0222 μm⁻¹, 0.0221 μm⁻¹, 0.022 μm⁻¹, 0.0219 μm⁻¹, 0.0217 μm⁻¹, 0.0216 μm⁻¹, 0.0215 μm⁻¹, 0.0214 μm⁻¹, 0.0213 μm⁻, 0.0212 μm⁻¹, 0.0211 μm⁻¹, 0.021 μm⁻¹, 0.0209 μm⁻¹, 0.0208 μm⁻¹, 0.0207 μm⁻¹, 0.0206 μm⁻¹, 0.0205 μm⁻¹, 0.0204 μm⁻¹, 0.0203 μm⁻¹, 0.0202 μm⁻¹, 0.0201 μm⁻¹, 0.02 μm⁻¹, or 0.002 μm⁻¹.

According to one embodiment, a statistical set of the spherical aggregates 1 has an average unique curvature of at least 200 μm⁻¹, 100 μm⁻¹, 66.6 μm⁻¹, 50 μm⁻¹, 33.3 μm⁻¹, 28.6 μm⁻¹, 25 μm⁻¹, 20 μm⁻¹, 18.2 μm⁻¹, 16.7 μm⁻¹, 15.4 μm⁻, 14.3 μm⁻¹, 13.3 μm⁻¹, 12.5 μm⁻¹, 11.8 μm⁻¹, 11.1 μm⁻¹, 10.5 μm⁻¹, 9.5 μm⁻¹, 9.1 μm⁻¹, 8.7 μm⁻¹, 8.3 μm⁻¹, 8 μm⁻¹, 7.7 μm⁻¹, 7.4 μm⁻¹, 7.1 μm⁻¹, 6.9 μm⁻¹, 6.7 μm⁻¹, 5.7 μm⁻¹, 5 μm⁻¹, 4 μm⁻¹, 3.1 μm⁻¹, 2.7 μm⁻¹, 2.5 μm⁻¹, 2.4 μm⁻¹, 2.2 μm⁻¹, 2.1 μm⁻¹, 2 μm⁻¹, 1.3333 μm⁻¹, 0.8 μm⁻¹, 0.6666 μm⁻¹, 0.5714 μm⁻¹, 0.5 μm⁻¹, 0.4444 μm⁻¹, 0.4 μm⁻¹, 0.3636 μm⁻¹, 0.3333 μm⁻¹, 0.3080 μm⁻¹, 0.2857 μm⁻¹, 0.2667 μm⁻¹, 0.25 μm⁻¹, 0.2353 μm⁻¹, 0.2222 μm⁻¹, 0.2105 μm⁻¹, 0.2 μm⁻¹, 0.1905 μm⁻¹, 0.1818 μm⁻¹, 0.1739 μm⁻¹, 0.1667 μm⁻¹, 0.16 μm⁻¹, 0.1538 μm⁻¹, 0.1481 μm⁻¹, 0.1429 μm⁻¹, 0.1379 μm⁻¹, 0.1333 μm⁻¹, 0.1290 μm⁻¹, 0.125 μm⁻¹, 0.1212 μm⁻¹, 0.1176 μm⁻¹, 0.1176 μm⁻¹, 0.1143 μm⁻¹, 0.1111 μm⁻¹, 0.1881 μm⁻¹, 0.1053 μm⁻¹, 0.1026 μm⁻¹, 0.1 μm⁻¹, 0.0976 μm⁻¹, 0.9524 μm⁻¹, 0.0930 μm⁻¹, 0.0909 μm⁻¹, 0.0889 μm⁻¹, 0.870 μm⁻¹, 0.0851 μm⁻¹, 0.0833 μm⁻¹, 0.0816 μm⁻¹, 0.08 μm⁻¹, 0.0784 μm⁻¹, 0.0769 μm⁻¹, 0.0755 μm⁻¹, 0.0741 μm⁻¹, 0.0727 μm⁻¹, 0.0714 μm⁻¹, 0.0702 μm⁻¹, 0.0690 μm⁻¹, 0.0678 μm⁻¹, 0.0667 μm⁻¹, 0.0656 μm⁻¹, 0.0645 μm⁻¹, 0.0635 μm⁻¹, 0.0625 μm⁻¹, 0.0615 μm⁻¹, 0.0606 μm⁻¹, 0.0597 μm⁻¹, 0.0588 μm⁻¹, 0.0580 μm⁻¹, 0.0571 μm⁻¹, 0.0563 μm⁻¹, 0.0556 μm⁻¹, 0.0548 μm⁻¹, 0.0541 μm⁻¹, 0.0533 μm⁻¹, 0.0526 μm⁻¹, 0.0519 μm⁻¹, 0.0513 μm⁻¹, 0.0506 μm⁻¹, 0.05 μm⁻¹, 0.0494 μm⁻¹, 0.0488 μm⁻¹, 0.0482 μm⁻¹, 0.0476 μm⁻¹, 0.0471 μm⁻¹, 0.0465 μm⁻¹, 0.0460 μm⁻¹, 0.0455 μm⁻¹, 0.0450 μm⁻¹, 0.0444 μm⁻¹, 0.0440 μm⁻¹, 0.0435 μm⁻¹, 0.0430 μm⁻¹, 0.0426 μm⁻¹, 0.0421 μm⁻¹, 0.0417 μm⁻, 0.0412 μm⁻¹, 0.0408 μm⁻¹, 0.0404 μm⁻¹, 0.04 μm⁻¹, 0.0396 μm⁻¹, 0.0392 μm⁻¹, 0.0388 μm⁻¹, 0.0385 μm⁻¹; 0.0381 μm⁻¹, 0.0377 μm⁻¹, 0.0374 μm⁻¹, 0.037 μm⁻¹, 0.0367 μm⁻¹, 0.0364 μm⁻¹, 0.0360 μm⁻¹0.0357 μm⁻¹, 0.0354 μm⁻¹, 0.0351 μm⁻¹, 0.0348 μm⁻¹, 0.0345 μm⁻¹, 0.0342 μm⁻¹, 0.0339 μm⁻¹, 0.0336 μm⁻¹, 0.0333 μm⁻¹, 0.0331 μm⁻¹, 0.0328 μm⁻¹, 0.0325 μm⁻¹, 0.0323 μm⁻¹, 0.032 μm⁻¹, 0.0317 μm⁻¹, 0.0315 μm⁻¹, 0.0312 μm⁻¹, 0.031 μm⁻¹, 0.0308 μm⁻¹, 0.0305 μm⁻¹, 0.0303 μm⁻¹, 0.0301 μm⁻¹, 0.03 μm⁻¹, 0.0299 μm⁻¹, 0.0296 μm⁻¹, 0.0294 μm⁻¹, 0.0292 μm⁻¹, 0.029 μm⁻¹, 0.0288 μm⁻¹, 0.0286 μm⁻¹, 0.0284 μm⁻¹, 0.0282 μm⁻¹, 0.028 μm⁻¹, 0.0278 μm⁻¹, 0.0276 μm⁻¹, 0.0274 μm⁻¹, 0.0272 μm⁻¹; 0.0270 μm⁻¹, 0.0268 μm⁻¹, 0.02667 μm⁻¹, 0.0265 μm⁻¹, 0.0263 μm⁻¹, 0.0261 μm⁻¹, 0.026 μm⁻, 0.0258 μm⁻¹, 0.0256 μm⁻¹, 0.0255 μm⁻¹, 0.0253 μm⁻¹, 0.0252 μm⁻¹, 0.025 μm⁻¹, 0.0248 μm⁻¹, 0.0247 μm⁻¹, 0.0245 μm⁻¹, 0.0244 μm⁻¹, 0.0242 μm⁻¹, 0.0241 μm⁻¹, 0.024 μm⁻¹, 0.0238 μm⁻¹0.0237 μm⁻¹, 0.0235 μm⁻¹, 0.0234 μm⁻¹, 0.0233 μm⁻¹, 0.231 μm⁻¹, 0.023 μm⁻¹, 0.0229 μm⁻¹, 0.0227 μm⁻¹, 0.0226 μm⁻¹, 0.0225 μm⁻¹, 0.0223 μm⁻¹, 0.0222 μm⁻¹, 0.0221 μm⁻¹, 0.022 μm⁻¹, 0.0219 μm⁻¹, 0.0217 μm⁻¹, 0.0216 μm⁻¹, 0.0215 μm⁻¹, 0.0214 μm⁻¹, 0.0213 μm⁻¹, 0.0212 μm⁻¹, 0.0211 μm⁻¹, 0.021 μm⁻¹, 0.0209 μm⁻¹, 0.0208 μm⁻¹, 0.0207 μm⁻¹, 0.0206 μm⁻¹, 0.0205 μm⁻¹, 0.0204 μm⁻¹, 0.0203 μm⁻¹, 0.0202 μm⁻¹, 0.0201 μm⁻¹, 0.02 μm⁻¹ or 0.002 μm⁻¹.

According to one embodiment, the curvature of the spherical aggregate 1 has no deviation, meaning that said aggregate 1 has a perfect spherical shape. A perfect spherical shape prevents fluctuations of the intensity of the scattered light.

According to one embodiment, the unique curvature of the spherical aggregate 1 may have a deviation less or equal to 0.01%, 0.02%, 0.03%, 0.04%, 0.05%, 0.06%, 0.07%, 0.08%, 0.09%, 0.1%, 0.2%, 0.3%, 0.4%, 0.5%, 0.6%, 0.7%, 0.8%, 0.9%, 1%, 1.1%, 1.2%, 1.3%, 1.4%, 1.5%, 1.6%, 1.7%, 1.8%, 1.9%, 2%, 2.1%, 2.2%, 2.3%, 2.4%, 2.5%, 2.6%, 2.7%, 2.8%, 2.9%, 3%, 3.1%, 3.2%, 3.3%, 3.4%, 3.5%, 3.6%, 3.7%, 3.8%, 3.9%, 4%, 4.1%, 4.2%, 4.3%, 4.4%, 4.5%, 4.6%, 4.7%, 4.8%, 4.9%, 5%, 5.1%, 5.2%, 5.3%, 5.4%, 5.5%, 5.6%, 5.7%, 5.8%, 5.9%, 6%, 6.1%, 6.2%, 6.3%, 6.4%, 6.5%, 6.6%, 6.7%, 6.8%, 6.9%, 7%, 7.1%, 7.2%, 7.3%, 7.4%, 7.5%, 7.6%, 7.7%, 7.8%, 7.9%, 8%, 8.1%, 8.2%, 8.3%, 8.4%, 8.5%, 8.6%, 8.7%, 8.8%, 8.9%, 9%, 9.1%, 9.2%, 9.3%, 9.4%, 9.5%, 9.6%, 9.7%, 9.8%, 9.9%, or 10% along the surface of said aggregate 1.

According to one embodiment, the aggregate 1 is ROHS compliant.

According to one embodiment, the aggregate 1 comprises less than 10 ppm, less than 20 ppm, less than 30 ppm, less than 40 ppm, less than 50 ppm, less than 100 ppm, less than 150 ppm, less than 200 ppm, less than 250 ppm, less than 300 ppm, less than 350 ppm, less than 400 ppm, less than 450 ppm, less than 500 ppm, less than 550 ppm, less than 600 ppm, less than 650 ppm, less than 700 ppm, less than 750 ppm, less than 800 ppm, less than 850 ppm, less than 900 ppm, less than 950 ppm, less than 1000 ppm in weight of cadmium.

According to one embodiment, the aggregate 1 comprises less than 10 ppm, less than 20 ppm, less than 30 ppm, less than 40 ppm, less than 50 ppm, less than 100 ppm, less than 150 ppm, less than 200 ppm, less than 250 ppm, less than 300 ppm, less than 350 ppm, less than 400 ppm, less than 450 ppm, less than 500 ppm, less than 550 ppm, less than 600 ppm, less than 650 ppm, less than 700 ppm, less than 750 ppm, less than 800 ppm, less than 850 ppm, less than 900 ppm, less than 950 ppm, less than 1000 ppm, less than 2000 ppm, less than 3000 ppm, less than 4000 ppm, less than 5000 ppm, less than 6000 ppm, less than 7000 ppm, less than 8000 ppm, less than 9000 ppm, less than 10000 ppm in weight of lead.

According to one embodiment, the aggregate 1 comprises less than 10 ppm, less than 20 ppm, less than 30 ppm, less than 40 ppm, less than 50 ppm, less than 100 ppm, less than 150 ppm, less than 200 ppm, less than 250 ppm, less than 300 ppm, less than 350 ppm, less than 400 ppm, less than 450 ppm, less than 500 ppm, less than 550 ppm, less than 600 ppm, less than 650 ppm, less than 700 ppm, less than 750 ppm, less than 800 ppm, less than 850 ppm, less than 900 ppm, less than 950 ppm, less than 1000 ppm, less than 2000 ppm, less than 3000 ppm, less than 4000 ppm, less than 5000 ppm, less than 6000 ppm, less than 7000 ppm, less than 8000 ppm, less than 9000 ppm, less than 10000 ppm in weight of mercury.

According to one embodiment, the aggregate 1 comprises heavier chemical elements than the main chemical element present in the material 11. In this embodiment, said heavy chemical elements in the aggregate 1 will lower the mass concentration of chemical elements subject to ROHS standards, allowing said aggregate 1 to be ROHS compliant.

According to one embodiment, examples of heavy chemical elements include but are not limited to B, C, N, F, Na, Mg, Al, Si, P, S, Cl, K, Ca, Sc, Ti, V, Cr, Mn, Fe, Co, Ni, Cu, Zn, Ga, Ge, As, Se, Br, Rb, Sr, Y, Zr, Nb, Mo, Tc, Ru, Rh, Pd, Ag, Cd, In, Sn, Sb, Te, I, Cs, Ba, La, Hf, Ta, W, Re, Os, Ir, Pt, Au, Hg, Tl, Pb, Bi, Po, At, Ce, Pr, Nd, Pm, Sm, Eu, Gd, Tb, Dy, Ho, Er, Tm, Yb, Lu or a mixture of thereof.

According to one embodiment, the aggregate 1 is amorphous.

According to one embodiment, the aggregate 1 is crystalline.

According to one embodiment, the aggregate 1 is totally crystalline.

According to one embodiment, the aggregate 1 is partially crystalline.

According to one embodiment, the aggregate 1 is monocrystalline.

According to one embodiment, the aggregate 1 is polycrystalline.

According to one embodiment, the aggregate 1 is a polycrystalline particle. In this embodiment, the aggregate 1 comprises at least one grain boundary.

According to one embodiment, the aggregate 1 is porous.

According to one embodiment, the aggregate 1 is considered porous when the quantity adsorbed by the aggregate 1 determined by adsorption-desorption of nitrogen in the Brunauer-Emmett-Teller (BET) theory is more than 20 cm³/g, 15 cm³/g, 10 cm³/g, 5 cm³/g at a nitrogen pressure of 650 mmHg, preferably 700 mmHg.

According to one embodiment, the organization of the porosity of the aggregate 1 can be hexagonal, vermicular or cubic.

According to one embodiment, the organized porosity of the aggregate 1 has a pore size of at least 1 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, or 50 nm.

According to one embodiment, the aggregate 1 is not porous.

According to one embodiment, the aggregate 1 does not comprise pores or cavities.

According to one embodiment, the aggregate 1 is considered non-porous when the quantity adsorbed by the said aggregate 1 determined by adsorption-desorption of nitrogen in the Brunauer-Emmett-Teller (BET) theory is less than 20 cm³/g, 15 cm³/g, 10 cm³/g, 5 cm³/g at a nitrogen pressure of 650 mmHg, preferably 700 mmHg.

According to one embodiment, the aggregate 1 is permeable.

According to one embodiment, the permeable aggregate 1 has an intrinsic permeability to fluids higher or equal to 10⁻¹¹ cm², 10⁻¹⁰ cm², 10⁻⁹ cm², 10⁻⁸ cm², 10⁻⁷ cm², 10⁻⁶ cm², 10⁻⁵ cm², 10⁻⁴ cm², or 10⁻³ cm².

According to one embodiment, the aggregate 1 is impermeable to outer molecular species, gas or liquid. In this embodiment, outer molecular species, gas or liquid refers to molecular species, gas or liquid external to said aggregate 1.

According to one embodiment, the impermeable aggregate 1 has an intrinsic permeability to fluids less or equal to 10⁻¹¹ cm², 10⁻¹² cm², 10⁻¹³ cm², 10⁻¹⁴ cm², or 10⁻¹⁵ cm².

According to one embodiment, the aggregate 1 has an oxygen transmission rate ranging from 10⁻⁷ to 10 cm³.m⁻².day⁻¹, preferably from 10⁻⁷ to 1 cm³.m⁻².day⁻¹, more preferably from 10⁻⁷ to 10⁻¹ cm³.m⁻².day⁻¹, even more preferably from 10⁻⁷ to 10⁻⁴ cm³.m⁻².day⁻¹ at room temperature.

According to one embodiment, the aggregate 1 has a water vapor transmission rate ranging from 10⁻⁷ to 10 g·m⁻².day⁻¹, preferably from 10⁻⁷ to 1 g·m⁻².day⁻¹, more preferably from 10⁻⁷ to 10⁻¹ g·m⁻².day⁻¹, even more preferably from 10⁻⁷ to 10⁻⁴ g·m⁻².day⁻¹ at room temperature. A water vapor transmission rate of 10⁻⁶ g·m⁻².day⁻¹ is particularly adequate for a use on LED.

According to one embodiment, the aggregate 1 is a colloidal particle.

According to one embodiment, the aggregate 1 does not comprise a spherical porous bead, preferably the aggregate 1 does not comprise a central spherical porous bead.

According to one embodiment, the aggregate 1 does not comprise a spherical porous bead, wherein particles 12 are linked to the surface of said spherical porous bead.

According to one embodiment, the aggregate 1 does not comprise a bead and particles 12 having opposite electronic charges.

According to one embodiment, the aggregate 1 is hydrophobic.

According to one embodiment, the aggregate 1 is hydrophilic.

According to one embodiment, the aggregate 1 is surfactant-free. In this embodiment, the surface of the aggregate 1 will be easy to functionalize as said surface will not be blocked by any surfactant molecule.

According to one embodiment, the aggregate 1 is not surfactant-free.

According to one embodiment, the aggregate 1 is dispersible in aqueous solvents, organic solvents and/or mixture thereof.

According to one embodiment, the aggregate 1 is dispersible in the liquid vehicle of an ink.

According to one embodiment, the aggregate 1 does not coated by an organic layer comprising organic molecules or polymer chains.

According to one embodiment, the aggregate 1 is coated by an organic layer comprising organic molecules or polymer chains.

According to one embodiment, the aggregate 1 is coated by an organic layer comprising polymerizable groups. In this embodiment, polymerizable groups are capable of undergoing a polymerization reaction.

According to one embodiment, examples of polymerizable groups include but are not limited to: vinyl monomers, acrylate monomers, methacrylate monomers, ethylacrylate monomers, acrylamide monomers, methacrylamide monomers, ethyl acrylamide monomers, ethylene glycol monomers, epoxide monomers, glycidyl monomers, olefin monomers, norbornyl monomers, isocyanide monomers, and any of the above mention in di/tri functional group format, or a mixture thereof.

According to one embodiment, the aggregate 1 comprises at least one inorganic particle 12 and at least one organic particle 12 dispersed in the material 11. Said particles are described hereafter.

According to one embodiment, the aggregate 1 is not a core/shell particle wherein the core is an aggregate of particles and the shell comprises the material 11.

According to one embodiment, the aggregate 1 is not a core/shell particle wherein the core is an aggregate of metallic particles and the shell comprises the material 11.

According to one embodiment, the aggregate 1 does not comprise only one particle 12 dispersed in the material 11. In this embodiment, the aggregate 1 is not a core/shell particle wherein the at least one particle 12 is the core with a shell of the material 11.

According to one embodiment, the aggregate 1 comprises one particle 12 dispersed in the material 11.

According to one embodiment, the particle 12 is totally surrounded by or encapsulated in the material 11.

According to one embodiment, the particle 12 is partially surrounded by or encapsulated in the material 11.

According to one embodiment, the aggregate 1 does not comprise only one core/shell particle 12 dispersed in the material 11.

According to one embodiment, the aggregate 1 comprises at least two particles 12 dispersed in the material 11.

According to one embodiment, the aggregate 1 comprises a plurality of particles 12 dispersed in the material 11.

According to one embodiment, the aggregate 1 comprises at least 1, at least 2, at least 3, at least 4, at least 5, at least 6, at least 7, at least 8, at least 9, at least 10, at least 11, at least 12, at least 13, at least 14, at least 15, at least 16, at least 17, at least 18, at least 19, at least 20, at least 21, at least 22, at least 23, at least 24, at least 25, at least 26, at least 27, at least 28, at least 29, at least 30, at least 31, at least 32, at least 33, at least 34, at least 35, at least 36, at least 37, at least 38, at least 39, at least 40, at least 41, at least 42, at least 43, at least 44, at least 45, at least 46, at least 47, at least 48, at least 49, at least 50, at least 51, at least 52, at least 53, at least 54, at least 55, at least 56, at least 57, at least 58, at least 59, at least 60, at least 61, at least 62, at least 63, at least 64, at least 65, at least 66, at least 67, at least 68, at least 69, at least 70, at least 71, at least 72, at least 73, at least 74, at least 75, at least 76, at least 77, at least 78, at least 79, at least 80, at least 81, at least 82, at least 83, at least 84, at least 85, at least 86, at least 87, at least 88, at least 89, at least 90, at least 91, at least 92, at least 93, at least 94, at least 95, at least 96, at least 97, at least 98, at least 99, at least 100, at least 200, at least 300, at least 400, at least 500, at least 600, at least 700, at least 800, at least 900, at least 1000, at least 1500, at least 2000, at least 2500, at least 3000, at least 3500, at least 4000, at least 4500, at least 5000, at least 5500, at least 6000, at least 6500, at least 7000, at least 7500, at least 8000, at least 8500, at least 9000, at least 9500, at least 10000, at least 15000, at least 20000, at least 25000, at least 30000, at least 35000, at least 40000, at least 45000, at least 50000, at least 55000, at least 60000, at least 65000, at least 70000, at least 75000, at least 80000, at least 85000, at least 90000, at least 95000, or at least 100000 particles 12 dispersed in the material 11.

According to one embodiment, the particle 12 represents at least 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, 91%, 92%, 93%, 94%, 95%, 96%, 97%, 98%, or 99% by weight of the aggregate 1.

According to one embodiment, the loading charge of the particle 12 in the aggregate 1 is at least 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, 91%, 92%, 93%, 94%, 95%, 96%, 97%, 98%, or 99%.

According to one embodiment, the loading charge of the particle 12 in the aggregate 1 is less than 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, 91%, 92%, 93%, 94%, 95%, 96%, 97%, 98%, or 99%.

According to one embodiment, the particle 12 comprised in the aggregate 1 have a packing fraction of at least 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, or 95%.

According to one embodiment, the particles 12 are not encapsulated in aggregate 1 via physical entrapment or electrostatic attraction.

According to one embodiment, the particles 12 and the material 11 are not bonded or linked by electrostatic attraction or a functionalized silane based coupling agent

According to one embodiment, the particles 12 comprised in the same aggregate 1 are not aggregated.

According to one embodiment, the particles 12 comprised in the same aggregate 1 do not touch, are not in contact.

According to one embodiment, the particles 12 comprised in the same aggregate 1 are separated by material 11.

According to one embodiment, the particles 12 comprised in the same aggregate 1 are aggregated.

According to one embodiment, the particles 12 comprised in the same aggregate 1 touch, are in contact.

According to one embodiment, the particle 12 comprised in the same aggregate 1 can be individually evidenced.

According to one embodiment, the particle 12 comprised in the same aggregate 1 can be individually evidenced by transmission electron microscopy or fluorescence scanning microscopy, or any other characterization means known by the person skilled in the art.

According to one embodiment, a plurality of particles 12 is uniformly dispersed in the material 11.

The uniform dispersion of the plurality of particles 12 in the material 11 comprised in the aggregate 1 prevents the aggregation of said particles 12, thereby preventing the degradation of their properties. For example, in the case of inorganic fluorescent particles, a uniform dispersion will allow the optical properties of said particles to be preserved, and aggregation quenching can be avoided.

According to one embodiment, the particles 12 comprised in an aggregate 1 are uniformly dispersed within the material 11 comprised in said aggregate 1 .

According to one embodiment, the particles 12 comprised in an aggregate 1 are dispersed within the material 11 comprised in said aggregate 1.

According to one embodiment, the particles 12 comprised in an aggregate 1 are uniformly and evenly dispersed within the material 11 comprised in said aggregate 1.

According to one embodiment, the particles 12 comprised in an aggregate 1 are evenly dispersed within the material 11 comprised in said aggregate 1.

According to one embodiment, the particles 12 comprised in an aggregate 1 are homogeneously dispersed within the material 11 comprised in said aggregate 1.

According to one embodiment, the dispersion of particles 12 in the material 11 does not have the shape of a ring, or a monolayer.

According to one embodiment, each particle 12 of the plurality of particles 12 is spaced from its adjacent particle 12 by an average minimal distance.

According to one embodiment, the average minimal distance between two particles 12 is controlled.

According to one embodiment, the average minimal distance between two particles 12 in the same aggregate 1 is at least 1 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 15.5 nm, 16 nm, 16.5 nm, 17 nm, 17.5 nm, 18 nm, 18.5 nm, 19 nm, 19.5 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 300 μm, 400 μm, 500 μm, 600 μm, 700 μm, 800 μm, 900 μm, or 1 mm.

According to one embodiment, the average distance between two particles 12 in the same aggregate 1 is at least 1 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 15.5 nm, 16 nm, 16.5 nm, 17 nm, 17.5 nm, 18 nm, 18.5 nm, 19 nm, 19.5 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 300 μm, 400 μm, 500 μm, 600 μm, 700 μm, 800 μm, 900 μm, or 1 mm.

According to one embodiment, the average distance between two particles 12 in the same aggregate 1 may have a deviation less or equal to 0.01%, 0.02%, 0.03%, 0.04%, 0.05%, 0.06%, 0.07%, 0.08%, 0.09%, 0.1%, 0.2%, 0.3%, 0.4%, 0.5%, 0.6%, 0.7%, 0.8%, 0.9%, 1%, 1.1%, 1.2%, 1.3%, 1.4%, 1.5%, 1.6%, 1.7%, 1.8%, 1.9%, 2%, 2.1%, 2.2%, 2.3%, 2.4%, 2.5%, 2.6%, 2.7%, 2.8%, 2.9%, 3%, 3.1%, 3.2%, 3.3%, 3.4%, 3.5%, 3.6%, 3.7%, 3.8%, 3.9%, 4%, 4.1%, 4.2%, 4.3%, 4.4%, 4.5%, 4.6%, 4.7%, 4.8%, 4.9%, 5%, 5.1%, 5.2%, 5.3%, 5.4%, 5.5%, 5.6%, 5.7%, 5.8%, 5.9%, 6%, 6.1%, 6.2%, 6.3%, 6.4%, 6.5%, 6.6%, 6.7%, 6.8%, 6.9%, 7%, 7.1%, 7.2%, 7.3%, 7.4%, 7.5%, 7.6%, 7.7%, 7.8%, 7.9%, 8%, 8.1%, 8.2%, 8.3%, 8.4%, 8.5%, 8.6%, 8.7%, 8.8%, 8.9%, 9%, 9.1%, 9.2%, 9.3%, 9.4%, 9.5%, 9.6%, 9.7%, 9.8%, 9.9%, 10%, 15%, 20%, 25%, 30%, 35%, 40%, 45%, or 50%.

According to one embodiment, the aggregate 1 comprises a combination of at least two different particles 12. In this embodiment, the resulting aggregate 1 will exhibit different properties.

In one embodiment, the aggregate 1 comprises only one population of particles 12, wherein at least one particle 12 emits at a peak wavelength in the range from 500 to 560 nm. In this embodiment, the aggregate 1 comprises at least one particle 12 emitting in the green region of the visible spectrum.

In one embodiment, the aggregate 1 comprises only one population of particles 12, wherein at least one particle 12 emits at a peak wavelength in the range from 600 to 2500 nm. In this embodiment, the aggregate 1 comprises at least one particle 12 emitting in the red region of the visible spectrum.

In one embodiment, the aggregate 1 comprises only one population of particles 12, wherein at least one particle 12 emits at a peak wavelength in the range from 400 to 490 nm. In this embodiment, the aggregate 1 comprises at least one particle 12 emitting in the blue region of the visible spectrum.

In one embodiment illustrated in FIG. 5, the aggregate 1 comprises at least two different particles 12, wherein at least one particle 12 emits at a peak wavelength in the range from 500 to 560 nm, and at least one particle 12 emits at a peak wavelength in the range from 600 to 2500 nm. In this embodiment, the aggregate 1 comprises at least one particle 12 emitting in the green region of the visible spectrum and at least one particle 12 emitting in the red region of the visible spectrum, thus the aggregate 1 paired with a blue LED will be a white light emitter.

In one embodiment, the aggregate 1 comprises at least two different particles 12, wherein at least one particle 12 emits at a peak wavelength in the range from 400 to 490 nm, and at least one particle 12 emits at a peak wavelength in the range from 600 to 2500 nm. In this embodiment, the aggregate 1 comprises at least one particle 12 emitting in the blue region of the visible spectrum and at least one particle 12 emitting in the red region of the visible spectrum, thus the aggregate 1 will be a white light emitter.

In one embodiment, the aggregate 1 comprises at least two different particles 12, wherein at least one particle 12 emits at a peak wavelength in the range from 400 to 490 nm, and at least one particle 12 emits at a peak wavelength in the range from 500 to 560 nm. In this embodiment, the aggregate 1 comprises at least one particle 12 emitting in the blue region of the visible spectrum and at least one particle 12 emitting in the green region of the visible spectrum.

In one embodiment, the aggregate 1 comprises three different particles 12, wherein said particles 12 emit different emission wavelengths or colors.

In one embodiment, the aggregate 1 comprises at least three different particles 12, wherein at least one particle 12 emits at a peak wavelength in the range from 400 to 490 nm, at least one particle 12 emits at a peak wavelength in the range from 500 to 560 nm and at least one particle 12 emits at a peak wavelength in the range from 600 to 2500 nm. In this embodiment, the aggregate 1 comprises at least one particle 12 emitting in the blue region of the visible spectrum, at least one particle 12 emitting in the green region of the visible spectrum and at least one particle 12 emitting in the red region of the visible spectrum.

According to one embodiment, at least 100%, 95%, 90%, 85%, 80%, 75%, 70%, 65%, 60%, 55%, 50%, 45%, 40%, 35%, 30%, 25%, 20%, 15%, 10%, 5%, or 1% of particles 12 are comprised in the material 11. In this embodiment, each of said particles 12 is completely surrounded by the material 11.

In a preferred embodiment, the aggregate 1 does not comprise any particle 12 on its surface. In this embodiment, the at least particle 12 is completely surrounded by the material 11.

According to one embodiment, the aggregate 1 comprises at least one particle 12 located on the surface of said aggregate 1.

According to one embodiment, the aggregate 1 comprises at least 100%, 95%, 90%, 85%, 80%, 75%, 70%, 65%, 60%, 55%, 50%, 45%, 40%, 35%, 30%, 25%, 20%, 15%, 10%, 5%, 1% or 0% of particles 12 on its surface.

According to one embodiment, the aggregate 1 comprises particles 12 on its surface, wherein said particles 12 are aggregated.

According to one embodiment, the aggregate 1 comprises particles 12 on its surface, wherein said particles 12 comprises nanoparticles 122 dispersed in the material 11.

According to one embodiment, the at least one particle 12 is only located on the surface of said aggregate 1. This embodiment is advantageous as the at least one particle 12 will be better excited by the incident light than if said particle 12 was dispersed in the material 11.

According to one embodiment, the aggregate 1 comprises at least one particle 12 dispersed in the material 11, i.e. totally surrounded by said material 11; and at least one particle 12 located on the surface of said aggregate 1.

According to one embodiment, the at least one particle 12 located on the surface of said aggregate 1 may be chemically or physically adsorbed on said surface.

According to one embodiment, the at least one particle 12 located on the surface of said aggregate 1 may be adsorbed on said surface.

According to one embodiment, the at least one particle 12 located on the surface of said aggregate 1 may be adsorbed with a cement on said surface.

According to one embodiment, examples of cement include but are not limited to: polymers, silicone, oxides, or a mixture thereof.

According to one embodiment, the at least one particle 12 located on the surface of said aggregate 1 may have at least 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 95%, or 100% of its volume trapped in the material 11.

According to one embodiment, a plurality of particles 12 is uniformly spaced on the surface of the aggregate 1.

According to one embodiment, each particle 12 of the plurality of particles 12 is spaced from its adjacent particle 12 by an average minimal distance.

According to one embodiment, the average minimal distance between two particles 12 is controlled.

According to one embodiment, the average minimal distance between two particles 12 on the surface of the aggregate 1 is at least 1 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 15.5 nm, 16 nm, 16.5 nm, 17 nm, 17.5 nm, 18 nm, 18.5 nm, 19 nm, 19.5 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 300 μm, 400 μm, 500 μm, 600 μm, 700 μm, 800 μm, 900 μm, or 1 mm.

According to one embodiment, the average distance between two particles 12 on the surface of the aggregate 1 is at least 1 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 15.5 nm, 16 nm, 16.5 nm, 17 nm, 17.5 nm, 18 nm, 18.5 nm, 19 nm, 19.5 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48.5 μm, 49 μm, 49.5 μm, 50 μm, 50.5 μm, 51 μm, 51.5 μm, 52 μm, 52.5 μm, 53 μm, 53.5 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82.5 μm, 83 μm, 83.5 μm, 84 μm, 84.5 μm, 85 μm, 85.5 μm, 86 μm, 86.5 μm, 87 μm, 87.5 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 300 μm, 400 μm, 500 μm, 600 μm, 700 μm, 800 μm, 900 μm, or 1 mm.

According to one embodiment, the average distance between two particles 12 on the surface of the aggregate 1 may have a deviation less or equal to 0.01%, 0.02%, 0.03%, 0.04%, 0.05%, 0.06%, 0.07%, 0.08%, 0.09%, 0.1%, 0.2%, 0.3%, 0.4%, 0.5%, 0.6%, 0.7%, 0.8%, 0.9%, 1%, 1.1%, 1.2%, 1.3%, 1.4%, 1.5%, 1.6%, 1.7%, 1.8%, 1.9%, 2%, 2.1%, 2.2%, 2.3%, 2.4%, 2.5%, 2.6%, 2.7%, 2.8%, 2.9%, 3%, 3.1%, 3.2%, 3.3%, 3.4%, 3.5%, 3.6%, 3.7%, 3.8%, 3.9%, 4%, 4.1%, 4.2%, 4.3%, 4.4%, 4.5%, 4.6%, 4.7%, 4.8%, 4.9%, 5%, 5.1%, 5.2%, 5.3%, 5.4%, 5.5%, 5.6%, 5.7%, 5.8%, 5.9%, 6%, 6.1%, 6.2%, 6.3%, 6.4%, 6.5%, 6.6%, 6.7%, 6.8%, 6.9%, 7%, 7.1%, 7.2%, 7.3%, 7.4%, 7.5%, 7.6%, 7.7%, 7.8%, 7.9%, 8%, 8.1%, 8.2%, 8.3%, 8.4%, 8.5%, 8.6%, 8.7%, 8.8%, 8.9%, 9%, 9.1%, 9.2%, 9.3%, 9.4%, 9.5%, 9.6%, 9.7%, 9.8%, 9.9%, 10%, 15%, 20%, 25%, 30%, 35%, 40%, 45%, or 50%.

According to one embodiment, the aggregate 1 comprises at least one particle 12 dispersed in the material 11, wherein said at least one particle 12 emits at a peak wavelength in the range from 500 to 560 nm; and at least one particle 12 located on the surface of said aggregate 1, wherein said at least one particle 12 emits at a peak wavelength in the range from 600 to 2500 nm.

According to one embodiment, the aggregate 1 comprises at least one particle 12 dispersed in the material 11, wherein said at least one particle 12 emits at a peak wavelength in the range from 600 to 2500 nm; and at least one particle 12 located on the surface of said aggregate 1, wherein said at least one particle 12 emits at a peak wavelength in the range from 500 to 560 nm.

According to one embodiment, the aggregate 1 exhibits a shelf life of at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

According to one embodiment, the aggregate 1 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

Photoluminescence refers to fluorescence and/or phosphorescence.

According to one embodiment, the aggregate 1 exhibits a degradation of its photoluminescence of less than 90%, 80%, 70%, 60%, 50%, 40%, 30%, 25%, 20%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the aggregate 1 exhibits a degradation of its photoluminescence of less than 90%, 80%, 70%, 60%, 50%, 40%, 30%, 25%, 20%, 10%, 5%, 4%, 3%, 2%, 1%, or 0% under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its photoluminescence of less than 90%, 80%, 70%, 60%, 50%, 40%, 30%, 25%, 20%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the aggregate 1 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment.

According to one embodiment, the aggregate 1 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the aggregate 1 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

In one embodiment, the aggregate 1 exhibits photoluminescence quantum yield (PLQY) decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination.

According to one embodiment, the light illumination is provided by blue, green, red, or UV light source such as laser, diode, fluorescent lamp or Xenon Arc Lamp. According to one embodiment, the photon flux or average peak pulse power of the illumination is comprised between 1 mW·cm⁻² and 100 kW·cm⁻², more preferably between 10 mW·cm⁻² and 100 W·cm⁻², and even more preferably between 10 mW·cm⁻² and 30 W·cm⁻².

According to one embodiment, the photon flux or average peak pulse power of the illumination is at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

According to one embodiment, the light illumination described herein provides continuous lighting.

According to one embodiment, the light illumination described herein provides pulsed light. This embodiment is particularly advantageous as it allows the evacuation of heat and/or electrical charges from particles 12. This embodiment is also particularly advantageous as using pulsed light allow a longer lifespan of the particles 12, thus of the aggregates 1, indeed under continuous light, particles 12 degrade faster than under pulsed light.

According to one embodiment, the light illumination described herein provides pulsed light. In this embodiment, if a continuous light illuminates a material with regular periods during which said material is voluntary removed from the illumination, said light may be considered as pulsed light. This embodiment is particularly advantageous as it allows the evacuation of heat and/or electrical charges from particles 12.

According to one embodiment, said pulsed light has a time off (or time without illumination) of at least 1 μsecond, 2 μseconds, 3 μseconds, 4 μseconds, 5 μseconds, 6 μseconds, 7 μseconds, 8 μseconds, 9 μseconds, 10 μseconds, 11 μseconds, 12 μseconds, 13 μseconds, 14 μseconds, 15 μseconds, 16 μseconds, 17 μseconds, 18 μseconds, 19 μseconds, 20 μseconds, 21 μseconds, 22 μseconds, 23 μseconds, 24 μseconds, 25 μseconds, 26 μseconds, 27 μseconds, 28 μseconds, 29 μseconds, 30 μseconds, 31 μseconds, 32 μseconds, 33 μseconds, 34 μseconds, 35 μseconds, 36 μseconds, 37 μseconds, 38 μseconds, 39 μseconds, 40 μseconds, 41 μseconds, 42 μseconds, 43 μseconds, 44 μseconds, 45 μseconds, 46 μseconds, 47 μseconds, 48 μseconds, 49 μseconds, 50 μseconds, 100 μseconds, 150 μseconds, 200 μseconds, 250 μseconds, 300 μseconds, 350 μseconds, 400 μseconds, 450 μseconds, 500 μseconds, 550 μseconds, 600 μseconds, 650 μseconds, 700 μseconds, 750 μseconds, 800 μseconds, 850 μseconds, 900 μseconds, 950 μseconds, 1 msecond, 2 mseconds, 3 mseconds, 4 mseconds, 5 mseconds, 6 mseconds, 7 mseconds, 8 mseconds, 9 mseconds, 10 mseconds, 11 mseconds, 12 mseconds, 13 mseconds, 14 mseconds, 15 mseconds, 16 mseconds, 17 mseconds, 18 mseconds, 19 mseconds, 20 mseconds, 21 mseconds, 22 mseconds, 23 mseconds, 24 mseconds, 25 mseconds, 26 mseconds, 27 mseconds, 28 mseconds, 29 mseconds, 30 mseconds, 31 mseconds, 32 mseconds, 33 mseconds, 34 mseconds, 35 mseconds, 36 mseconds, 37 mseconds, 38 mseconds, 39 mseconds, 40 mseconds, 41 mseconds, 42 mseconds, 43 mseconds, 44 mseconds, 45 mseconds, 46 mseconds, 47 mseconds, 48 mseconds, 49 mseconds, or 50 mseconds.

According to one embodiment, said pulsed light has a time on (or illumination time) of at least 0.1 nanosecond, 0.2 nanosecond, 0.3 nanosecond, 0.4 nanosecond, 0.5 nanosecond, 0.6 nanosecond, 0.7 nanosecond, 0.8 nanosecond, 0.9 nanosecond, 1 nanosecond, 2 nanoseconds, 3 nanoseconds, 4 nanoseconds, 5 nanoseconds, 6 nanoseconds, 7 nanoseconds, 8 nanoseconds, 9 nanoseconds, 10 nanoseconds, 11 nanoseconds, 12 nanoseconds, 13 nanoseconds, 14 nanoseconds, 15 nanoseconds, 16 nanoseconds, 17 nanoseconds, 18 nanoseconds, 19 nanoseconds, 20 nanoseconds, 21 nanoseconds, 22 nanoseconds, 23 nanoseconds, 24 nanoseconds, 25 nanoseconds, 26 nanoseconds, 27 nanoseconds, 28 nanoseconds, 29 nanoseconds, 30 nanoseconds, 31 nanoseconds, 32 nanoseconds, 33 nanoseconds, 34 nanoseconds, 35 nanoseconds, 36 nanoseconds, 37 nanoseconds, 38 nanoseconds, 39 nanoseconds, 40 nanoseconds, 41 nanoseconds, 42 nanoseconds, 43 nanoseconds, 44 nanoseconds, 45 nanoseconds, 46 nanoseconds, 47 nanoseconds, 48 nanoseconds, 49 nanoseconds, 50 nanoseconds, 100 nanoseconds, 150 nanoseconds, 200 nanoseconds, 250 nanoseconds, 300 nanoseconds, 350 nanoseconds, 400 nanoseconds, 450 nanoseconds, 500 nanoseconds, 550 nanoseconds, 600 nanoseconds, 650 nanoseconds, 700 nanoseconds, 750 nanoseconds, 800 nanoseconds, 850 nanoseconds, 900 nanoseconds, 950 nanoseconds, 1 μsecond, 2 μseconds, 3 μseconds, 4 μseconds, 5 μseconds, 6 μseconds, 7 μseconds, 8 μseconds, 9 μseconds, 10 μseconds, 11 μseconds, 12 μseconds, 13 μseconds, 14 μseconds, 15 μseconds, 16 μseconds, 17 μseconds, 18 μseconds, 19 μseconds, 20 μseconds, 21 μseconds, 22 μseconds, 23 μseconds, 24 μseconds, 25 μseconds, 26 μseconds, 27 μseconds, 28 μseconds, 29 μseconds, 30 μseconds, 31 μseconds, 32 μseconds, 33 μseconds, 34 μseconds, 35 μseconds, 36 μseconds, 37 μseconds, 38 μseconds, 39 μseconds, 40 μseconds, 41 μseconds, 42 μseconds, 43 μseconds, 44 μseconds, 45 μseconds, 46 μseconds, 47 μseconds, 48 μseconds, 49 μseconds, or 50 μseconds.

According to one embodiment, said pulsed light has a frequency of at least 10 Hz, 11 Hz, 12 Hz, 13 Hz, 14 Hz, 15 Hz, 16 Hz, 17 Hz, 18 Hz, 19 Hz, 20 Hz, 21 Hz, 22 Hz, 23 Hz, 24 Hz, 25 Hz, 26 Hz, 27 Hz, 28 Hz, 29 Hz, 30 Hz, 31 Hz, 32 Hz, 33 Hz, 34 Hz, 35 Hz, 36 Hz, 37 Hz, 38 Hz, 39 Hz, 40 Hz, 41 Hz, 42 Hz, 43 Hz, 44 Hz, 45 Hz, 46 Hz, 47 Hz, 48 Hz, 49 Hz, 50 Hz, 100 Hz, 150 Hz, 200 Hz, 250 Hz, 300 Hz, 350 Hz, 400 Hz, 450 Hz, 500 Hz, 550 Hz, 600 Hz, 650 Hz, 700 Hz, 750 Hz, 800 Hz, 850 Hz, 900 Hz, 950 Hz, 1 kHz, 2 kHz, 3 kHz, 4 kHz, 5 kHz, 6 kHz, 7 kHz, 8 kHz, 9 kHz, 10 kHz, 11 kHz, 12 kHz, 13 kHz, 14 kHz, 15 kHz, 16 kHz, 17 kHz, 18 kHz, 19 kHz, 20 kHz, 21 kHz, 22 kHz, 23 kHz, 24 kHz, 25 kHz, 26 kHz, 27 kHz, 28 kHz, 29 kHz, 30 kHz, 31 kHz, 32 kHz, 33 kHz, 34 kHz, 35 kHz, 36 kHz, 37 kHz, 38 kHz, 39 kHz, 40 kHz, 41 kHz, 42 kHz, 43 kHz, 44 kHz, 45 kHz, 46 kHz, 47 kHz, 48 kHz, 49 kHz, 50 kHz, 100 kHz, 150 kHz, 200 kHz, 250 kHz, 300 kHz, 350 kHz, 400 kHz, 450 kHz, 500 kHz, 550 kHz, 600 kHz, 650 kHz, 700 kHz, 750 kHz, 800 kHz, 850 kHz, 900 kHz, 950 kHz, 1 MHz, 2 MHz, 3 MHz, 4 MHz, 5 MHz, 6 MHz, 7 MHz, 8 MHz, 9 MHz, 10 MHz, 11 MHz, 12 MHz, 13 MHz, 14 MHz, 15 MHz, 16 MHz, 17 MHz, 18 MHz, 19 MHz, 20 MHz, 21 MHz, 22 MHz, 23 MHz, 24 MHz, 25 MHz, 26 MHz, 27 MHz, 28 MHz, 29 MHz, 30 MHz, 31 MHz, 32 MHz, 33 MHz, 34 MHz, 35 MHz, 36 MHz, 37 MHz, 38

MHz, 39 MHz, 40 MHz, 41 MHz, 42 MHz, 43 MHz, 44 MHz, 45 MHz, 46 MHz, 47 MHz, 48 MHz, 49 MHz, 50 MHz, or 100 MHz.

According to one embodiment, the spot area of the light which illumminates the aggregate 1, the particles 12 and/or the light emitting material 7 is at least 10 μm², 20 μm², 30 μm², 40 μm², 50 μm², 60 μm², 70 μm², 80 μm², 90 μm², 100 μm², 200 μm², 300 μm², 400 μm², 500 μm², 600 μm², 700 μm², 800 μm², 900 μm², 10³ μm², 10⁴ μm², 10⁵ μm², 1 mm², 10 mm², 20 mm², 30 mm², 40 mm², 50 mm², 60 mm², 70 mm², 80 mm², 90 mm², 100 mm², 200 mm², 300 mm², 400 mm², 500 mm², 600 mm², 700 mm², 800 mm², 900 mm², 10³ mm², 10⁴ mm², 10⁵ mm², 1 m², 10 m², 20 m², 30 m², 40 m², 50 m², 60 m², 70 m², 80 m², 90 m², or 100 m².

According to one embodiment, the emission saturation of the aggregate 1, the particles 12 and/or the light emitting material 7 is reached under a pulsed light with a peak pulse power of at least 1 W·cm⁻², 5 W·cm⁻², 10 W·cm⁻², 20 W·cm⁻², 30 W·cm⁻², 40 W·cm², 50 W·cm⁻², 60 W·cm², 70 W·cm⁻², 80 W·cm⁻², 90 W·cm⁻², 100 W·cm⁻², 110 W·cm⁻², 120 W·cm⁻², 130 W·cm², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², 100 kW·cm⁻², 200 kW·cm⁻², 300 kW·cm⁻², 400 kW·cm⁻², 500 kW·cm⁻², 600 kW·cm⁻², 700 kW·cm⁻², 800 kW·cm⁻², 900 kW·cm⁻², or 1 MW·cm⁻².

According to one embodiment, the emission saturation of the aggregate 1, the particles 12 and/or the light emitting material 7 is reached under a continuous illummination with a peak pulse power of at least 1 W·cm⁻², 5 W·cm², 10 W·cm², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm², 600 W·cm⁻², 700 W·cm⁻², 800 W·cm⁻², 900 W·cm⁻², or 1 kW·cm⁻².

Emission saturation of particles under illummination with a given photon flux occurs when said particles cannot emit more photons. In other words, a higher photon flux doesn't lead to a higher nummber of photons emitted by said particles.

According to one embodiment, the FCE (Frequency Conversion Efficiency) of illuminated aggregate 1, particles 12 and/or light emitting material 7 is of at least 1%, 2%, 3%, 4%, 5%, 6%, 7%, 8%, 9%, 10%, 15%, 16%, 17%, 18%, 18%, 19%, 20%, 21%, 22%, 23%, 24%, 25%, 30%, 35%, 40%, 45%, 50%, 55%, 60%, 65%, 70%, 75%, 80%, 85%, 90%, 95%, or 100%. In this embodiment, the FCE was measured at 480 nm.

In one embodiment, the aggregate 1 exhibits photoluminescence quantum yield (PQLY) decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the aggregate 1 exhibits FCE decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

According to one embodiment, the aggregate 1 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

According to one embodiment, the aggregate 1 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the aggregate 1 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the aggregate 1 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment.

According to one embodiment, the aggregate 1 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the aggregate 1 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

According to one embodiment, the aggregate 1 exhibits a degradation of its FCE of less than 90%, 80%, 70%, 60%, 50%, 40%, 30%, 25%, 20%, 10%, 5%, 4%, 3%, 2%, 1%, or 0% under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the aggregate 1 exhibits a degradation of its FCE of less than 90%, 80%, 70%, 60%, 50%, 40%, 30%, 25%, 20%, 10%, 5%, 4%, 3%, 2%, 1%, or 0% under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its FCE of less than 90%, 80%, 70%, 60%, 50%, 40%, 30%, 25%, 20%, 10%, 5%, 4%, 3%, 2%, 1%, or 0% under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the aggregate 1 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular O₂.

According to one embodiment, the aggregate 1 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular O₂, under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the aggregate 1 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular O₂, under 0%, 10%, 20%, 30%, 40%, 50%, 55%, 60%, 65%, 70%, 75%, 80%, 85%, 90%, 95%, or 99% of humidity.

According to one embodiment, the aggregate 1 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular O₂, under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment illustrated in FIG. 18, the aggregate 1 further comprises at least one dense particle 2 dispersed in the material 11. In this embodiment, said at least one dense particle 2 comprises a dense material with a density superior to the density of the material 11.

According to one embodiment, the dense material has a bandgap superior or equal to 3 eV.

According to one embodiment, examples of dense material include but are not limited to: oxides such as for example tin oxide, silicon oxide, germanium oxide, aluminium oxide, gallium oxide, hafmium oxide, titanium oxide, tantalum oxide, ytterbium oxide, zirconium oxide, yttrium oxide, thorium oxide, zinc oxide, lanthanide oxides, actinide oxides, alkaline earth metal oxides, mixed oxides, mixed oxides thereof; metal sulfides; carbides; nitrides; or a mixture thereof.

According to one embodiment, the at least one dense particle 2 has a maximal packing fraction of 70%, 60%, 50%, 40%, 30%, 20%, 10% or 1%.

According to one embodiment, the at least one dense particle 2 has a density of at least 3, 4, 5, 6, 7, 8, 9 or 10 g/cm³.

According to one embodiment, the aggregate 1 is a homostructure.

According to one embodiment, the aggregate 1 is not a core/shell structure wherein the core does not comprise particles 12 and the shell comprises particles 12.

According to one embodiment as illustrated in FIG. 7A-B, the aggregate 1 is a heterostructure, comprising a core 13 and at least one shell 14.

According to one embodiment, the shell 14 of the core/shell aggregate 1 comprises a material that is the same or different than the material 11 comprised in the core 13 of the core/shell aggregate 1. In this embodiment, said material is an organic material, an inorganic material or a hybrid material as described hereabove.

According to one embodiment, the shell 14 of the core/shell aggregate 1 consists of a material that is the same or different than the material 11 comprised in the core 13 of the core/shell aggregate 1. In this embodiment, said material is an organic material, an inorganic material or a hybrid material as described hereabove.

According to one embodiment illustrated in FIG. 7A, the core 13 of the core/shell aggregate 1 comprises at least one particle 12 as described herein and the shell 14 of the core/shell aggregate 1 does not comprise particles 12.

According to one embodiment illustrated in FIG. 7B, the core 13 of the core/shell aggregate 1 comprises at least one particle 129 as described herein and the shell 14 of the core/shell aggregate 1 comprises at least one particle 128.

According to one embodiment, the at least one particle 12 comprised in the core 13 of the core/shell aggregate 1 is identical to the at least one particle 12 comprised in the shell 14 of the core/shell aggregate 1.

According to one embodiment, the at least one particle 12 comprised in the core 13 of the core/shell aggregate 1 is different to the at least one particle 12 comprised in the shell 14 of the core/shell aggregate 1. In this embodiment, the resulting core/shell aggregate 1 will exhibit different properties.

According to one embodiment, the core 13 of the core/shell aggregate 1 comprises at least one luminescent particle 12 and the shell 14 of the core/shell aggregate 1 comprises at least one particle 12 selected in the group of magnetic particle, plasmonic particle, dielectric particle, piezoelectric particle, pyro-electric particle, ferro-electric particle, light scattering particle, electrically insulating particle, thermally insulating particle, or catalytic particle.

According to one embodiment, the shell 14 of the core/shell aggregate 1 comprises at least one luminescent particle 12 and the core 13 of the core/shell aggregate 1 comprises at least one particle 12 selected in the group of magnetic particle, plasmonic particle, dielectric particle, piezoelectric particle, pyro-electric particle, ferro-electric particle, light scattering particle, electrically insulating particle, thermally insulating particle, or catalytic particle.

In a preferred embodiment, the core 13 of the core/shell aggregate 1 and the shell 14 of the core/shell aggregate 1 comprise at least two different luminescent particles 12, wherein said luminescent particles 12 emit at different emission wavelengths. This means that the core 13 comprises at least one luminescent particle and the shell 14 comprises at least one luminescent particle, said luminescent particles having different emission wavelengths.

In a preferred embodiment, the core 13 of the core/shell aggregate 1 and the shell 14 of the core/shell aggregate 1 comprise at least two different luminescent particles 12, wherein at least one luminescent particle 12 emits at a peak wavelength in the range from 500 to 560 nm, and at least one luminescent particle 12 emits at a peak wavelength in the range from 600 to 2500 nm. In this embodiment, the core 13 of the core/shell aggregate 1 and the shell 14 of the core/shell aggregate 1 comprise at least one luminescent particle 12 emitting in the green region of the visible spectrum and at least one luminescent particle 12 emitting in the red region of the visible spectrum, thus the aggregate 1 paired with a blue LED will be a white light emitter.

In a preferred embodiment, the core 13 of the core/shell aggregate 1 and the shell 14 of the core/shell aggregate 1 comprise at least two different luminescent particles 12, wherein at least one luminescent particle 12 emits at a peak wavelength in the range from 400 to 490 nm, and at least one luminescent particle 12 emits at a peak wavelength in the range from 600 to 2500 nm. In this embodiment, the core 13 of the core/shell aggregate 1 and the shell 14 of the core/shell aggregate 1 comprise at least one luminescent particle 12 emitting in the blue region of the visible spectrum and at least one luminescent particle 12 emitting in the red region of the visible spectrum, thus the aggregate 1 will be a white light emitter.

In a preferred embodiment, the core 13 of the core/shell aggregate 1 and the shell 14 of the core/shell aggregate 1 comprise comprises at least two different luminescent particles 12, wherein at least one luminescent particle 12 emits at a peak wavelength in the range from 400 to 490 nm, and at least one luminescent particle 12 emits at a peak wavelength in the range from 500 to 560 nm. In this embodiment, the core 13 of the core/shell aggregate 1 and the shell 14 of the core/shell aggregate 1 comprise at least one luminescent particle 12 emitting in the blue region of the visible spectrum and at least one luminescent particle 12 emitting in the green region of the visible spectrum.

According to one embodiment, the shell 14 of the aggregate 1 has a thickness of at least 0.1 nm, 0.2 nm, 0.3 nm, 0.4 nm, 0.5 nm, 1 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 15.5 nm, 16 nm, 16.5 nm, 17 nm, 17.5 nm, 18 nm, 18.5 nm, 19 nm, 19.5 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, the shell 14 of the aggregate 1 has a thickness homogeneous all along the core 13, i.e. the shell 14 of the aggregate 1 has a same thickness all along the core 13.

According to one embodiment, the shell 14 of the aggregate 1 has a thickness heterogeneous along the core 13, i.e. said thickness varies along the core 13.

According to one embodiment, the aggregate 1 is not a core/shell particle wherein the core is an aggregate of metallic particles and the shell comprises the material 11.

According to one embodiment, the aggregate 1 is a core/shell particle wherein the core is filled with solvent and the shell comprises particles 12 dispersed in a material 11, i.e. said aggregate 1 is a hollow bead with a solvent filled core.

According to one embodiment, the aggregate 1 does not comprise counterions.

According to one embodiment, the aggregate 1 does not comprise liquid crystal materials.

According to one embodiment, the aggregate 1 comprises at least one semiconductor nanoplatelet coated with grease and dispersed in Al₂O₃. In this embodiment, grease can refer to lipids as, for example, long apolar carbon chain molecules; phosphlipid molecules that possess a charged end group; polymers such as block copolymers or copolymers, wherein one portion of polymer has a domain of long apolar carbon chains, either part of the backbone or part of the polymeric sidechain; or long hydrocarbon chains that have a terminal functional group that includes carboxylates, sulfates, phosphonates or thiols.

According to one embodiment, the aggregate 1 comprises semiconductor nanoplatelets in an oxide material, a mixture of oxides or a mixed oxide, further dispersed in an oxide, a mixture of oxides or a mixed oxide. In this embodiment, semiconductor nanoplatelets may refer to CdSe/CdZnS, CdSe/CdS/ZnS; and oxide material may refer to Al₂O₃, SiO₂, SiₓCd_{y}Zn_{z}O_{w}, HfO₂, Si_{0.8}Hf_{0.2}O₂, Si_{0.8}Zr_{0.2}O₂.

According to one embodiment, the aggregate 1 comprises semiconductor nanoplatelets in polymer or a mixture of polymers, further dispersed in a polymer or a monomer. In this embodiment, semiconductor nanoplatelets may refer to CdSe/CdZnS, CdSe/CdS/ZnS; polymer may refer to PMMA, PS (polystyrene); monomer may refer to MMA, styrene.

According to one embodiment, the aggregate 1 comprises nanoparticles in an oxide material, a mixture of oxides or a mixed oxide, further dispersed in an oxide, a mixture of oxides or a mixed oxide. In this embodiment, nanoparticles may refer to CH₅N₂—PbBr₃ nanoparticles, gold nanoparticles, Fe₃O₄ nanoparticles, InP/ZnSe/ZnS nanoparticles, InP/GaP/ZnSe/ZnS nanoparticles, InP/ZnS/ZnSe/ZnS nanoparticles, InP/ZnS nanoparticles, SnO₂ particles, phosphor particles such as for example Yttrium aluminium garnet particles (YAG, Y₃Al₅O₁₂), (Ca,Y)-α-SiAlON:Eu particles, ((Y,Gd)₃(Al,Ga)₅O₁₂:Ce) particles, CaAlSiN₃:Eu particles, sulfide-based phosphor particles, PFS:Mn⁴⁺ particles (potassium fluorosilicate); and oxide material may refer to Al₂O₃, SiO₂, SiₓCd_{y}Zn_{z}O_{w}, HfO₂, Si_{0.8}Hf_{0.2}O₂, Si_{0.8}Zr_{0.2}O₂.

According to one embodiment, the aggregate 1 comprises nanoparticles in polymer or a mixture of polymers, further dispersed in a polymer or a monomer. In this embodiment, nanoparticles may refer to CH₅N₂—PbBr₃ nanoparticles, gold nanoparticles, Fe₃O₄ nanoparticles, InP/GaP/ZnSe/ZnS nanoparticles, InP/ZnS/ZnSe/ZnS nanoparticles, InP/ZnS, SnO₂ particles, phosphor particles such as for example Yttrium aluminium garnet particles (YAG, Y₃Al₅O₁₂), (Ca,Y)-α-SiAlON:Eu particles, ((Y,Gd)₃(Al,Ga)₅O₁₂:Ce) particles, CaAlSiN₃:Eu particles, sulfide-based phosphor particles, PFS:Mn⁴⁺ particles (potassium fluorosilicate); polymer may refer to PMMA, PS (polystyrene); monomer may refer to MMA, styrene.

According to one embodiment, the aggregate 1 comprises at least one semiconductor nanoplatelet dispersed in PMMA: semiconductor nanoplatelet @PMMA.

According to one embodiment, the aggregate 1 comprises at least one semiconductor nanoplatelet encapsulated in a PMMA particle further dispersed in Al₂O₃: semiconductor nanoplatelet@PMMA@Al₂O₃.

According to one embodiment, the aggregate 1 comprises at least one semiconductor nanoplatelet encapsulated in a PMMA particle further dispersed in MMA: semiconductor nanoplatelet@PMMA@MMA.

According to one embodiment, the aggregate 1 comprises CdSe/CdZnS nanoplatelets in SiO₂.

According to one embodiment, the aggregate 1 comprises CdSe/CdZnS nanoplatelets in SiₓCd_{y}Zn_{z}O_{w}.

According to one embodiment, the aggregate 1 comprises CdSe/CdZnS nanoplatelets in Al₂O₃.

According to one embodiment, the aggregate 1 comprises InP/ZnS nanoparticles in Al₂O₃.

According to one embodiment, the aggregate 1 comprises CH₅N₂—PbBr₃ nanoparticles in Al₂O₃.

According to one embodiment, the aggregate 1 comprises CdSe/CdZnS nanoplatelets and gold nanoparticles in SiO₂.

According to one embodiment, the aggregate 1 comprises a core of silica containing Fe₃O₄ nanoparticles and a shell of alumina containing CdSe/CdZnS nanoplatelets.

According to one embodiment, the aggregate 1 comprises InP/GaP/ZnSe/ZnS nanoparticles in Al₂O₃ and further dispersed in HfO₂.

According to one embodiment, the aggregate 1 comprises InP/ZnS/ZnSe/ZnS nanoparticles in Al₂O₃ and further dispersed in HfO₂.

According to one embodiment, the aggregate 1 comprises CdSe/CdZnS nanoplatelets in HfO₂ and further dispersed in Si_{0.8}Hf_{0.2}O₂.

According to one embodiment, the aggregate 1 comprises CdSe/CdZnS nanoplatelets in HfO₂ and further dispersed in Si_{0.8}Zr_{0.2}O₂.

According to one embodiment, the aggregate 1 comprises CdSe/CdZnS nanoplatelets in Al₂O₃ and further dispersed in HfO₂.

According to one embodiment, the aggregate 1 comprises CdSe/CdZnS nanoplatelets in HfO₂ and further dispersed in Al₂O₃.

According to one embodiment, the aggregate 1 comprises CdSe/CdZnS nanoplatelets in Al₂O₃ and SnO₂ particles, further dispersed in HfO₂.

According to one embodiment, the aggregate 1 comprises CdSe/CdZnS nanoplatelets in HfO₂ and SnO₂ particles, further dispersed in Al₂O₃.

According to one embodiment, the aggregate 1 comprises phosphor particles in Al₂O₃ and further dispersed in HfO₂. In this embodiment, phosphor particles may be Yttrium aluminium garnet particles (YAG, Y₃Al₅O₁₂), (Ca,Y)-α-SiAlON:Eu particles, ((Y,Gd)₃(Al,Ga)₅O₁₂:Ce) particles, CaAlSiN₃:Eu particles, sulfide-based phosphor particles, PFS:Mn⁴⁺ particles (potassium fluorosilicate).

According to one embodiment, the aggregate 1 comprises phosphor particles in HfO₂and further dispersed in Al₂O₃. In this embodiment, phosphor particles may be Yttrium aluminium garnet particles (YAG, Y₃Al₅O₁₂), (Ca,Y)-α-SiAlON:Eu particles, ((Y,Gd)₃(Al,Ga)₅O₁₂:Ce) particles, CaAlSiN₃:Eu particles, sulfide-based phosphor particles, PFS:Mn⁴⁺ particles (potassium fluorosilicate).

According to one embodiment, the aggregate 1 comprises CdSe/CdZnS nanoplatelets in HfO₂ further dispersed in SiO₂ and SnO₂ particles.

According to one embodiment, the aggregate 1 comprises semiconductor nanoplatelets in Al₂O₃ further dispersed in SiO₂.

According to one embodiment, the aggregate 1 comprises semiconductor nanoplatelets in HfO₂ further dispersed in SiO₂.

According to one embodiment, the aggregate 1 comprises CdSe/CdS/ZnS nanoplatelets in PMMA.

According to one embodiment, the aggregate 1 comprises CdSe/CdS/ZnS nanoplatelets in PS (polystyrene).

According to one embodiment, the aggregate 1 comprises CdSe/CdS/ZnS nanoplatelets in PS (polystyrene), the aggregates 1 being dispersed in styrene.

According to one embodiment, the aggregate 1 comprises CdSe/CdS/ZnS nanoplatelets in Al₂O₃ further dispersed in PMMA.

According to one embodiment, the aggregate 1 exhibits a transition upon a stimulus such as for example: mixing with a solvent, contacting with a gas, changing the temperature , changing the atmosphere pressure or the mechanical pressure exerted onto said aggregate 1, changing the pH, shining with a light with a selected wavelength, irradiating with an electromagnetic wave of selected frequency (IR, X, radio), putting under a static electric or magnetic fileds, sending ultrasound waves.

Upon the transition, the aggregate 1 breaks down to deliver the particle 12.

According to one embodiment, the aggregate 1 is solid at standard conditions.

According to one embodiment, the aggregate 1 is liquid at standard conditions.

According to one embodiment, the aggregate 1 is compact at standard conditions.

According to one embodiment, the aggregate 1 is not solid at standard conditions.

According to one embodiment, the aggregate 1 is mechanically hard at standard conditions.

According to one embodiment, the aggregate 1 is brittle at standard conditions.

According to one embodiment, the aggregate 1 is soft at standard conditions.

According to one embodiment, the metastable state is a contracted state, a shrunk state, a compact state, or a solid state for example.

According to one embodiment, the stable state is a swollen state, an expanded state, a dispersed state, a deaggregated state, a dissolved state or a liquid state for example.

According to one embodiment, the transition is a phase transition, dispersion, polymerization, first order phase transition, or second order phase transition for example.

According to one embodiment, the transition comprises the dispersion of the material 11 in a liquid, leading to the deaggregation of aggregate 1 thus the release of particles 12 from the aggregate 1.

According to one embodiment, the transition comprises a transition from a solid state to a dissolved state.

According to one embodiment, the transition comprises a transition from a solid state to a dissociated state.

According to one embodiment, the transition comprises a transition from an aggregated state to a deaggregated state.

According to one embodiment, the transition is the transition between a hard or brittle state and a soft or viscous state.

According to one embodiment, the deaggregated state can be reused to reform an aggregated state.

According to one embodiment, the transition is a glass transition or a change of viscosity.

According to one embodiment, the transition from the metastable state to a more stable state is triggered by a stimulus as described hereabove.

According to one embodiment, the transition from the metastable state to a more stable state depends on the material 11.

According to one embodiment, the material 11 has a bandgap superior or equal to 3 eV.

Having a bandgap superior or equal to 3 eV, the material 11 is optically transparent to UV and blue light.

According to one embodiment, the material 11 has a bandgap of at least 3.0 eV, 3.1 eV, 3.2 eV, 3.3 eV, 3.4 eV, 3.5 eV, 3.6 eV, 3.7 eV, 3.8 eV, 3.9 eV, 4.0 eV, 4.1 eV, 4.2 eV, 4.3 eV, 4.4 eV, 4.5 eV, 4.6 eV, 4.7 eV, 4.8 eV, 4.9 eV, 5.0 eV, 5.1 eV, 5.2 eV, 5.3 eV, 5.4 eV or 5.5 eV.

According to one embodiment, the material 11 has an extinction coefficient less or equal to 15×10⁻⁵ at 460 nm.

In one embodiment, the extinction coefficient is measured by an absorbance measuring technique such as absorbance spectroscopy or any other method known in the art.

In one embodiment, the extinction coefficient is measured by an absorbance measurement divided by the length of the path light passing through the sample.

According to one embodiment, the material 11 is optically transparent, i.e. the material 11 is transparent at wavelengths between 200 nm and 50 μm, between 200 nm and 10 μm, between 200 nm and 2500 nm, between 200 nm and 2000 nm, between 200 nm and 1500 nm, between 200 nm and 1000 nm, between 200 nm and 800 nm, between 400 nm and 700 nm, between 400 nm and 600 nm, or between 400 nm and 470 nm. In this embodiment, the material 11 does not absorb all incident light allowing the at least one particle 12 to absorb all the incident light; and/or the material 11 does not absorb the light emitted by the at least one particle 12 allowing to said light emitted to be transmitted through the material 11.

According to one embodiment, the material 11 is not optically transparent, i.e. the material 11 absorbs light at wavelengths between 200 nm and 50 μm, between 200 nm and 10 μm, between 200 nm and 2500 nm, between 200 nm and 2000 nm, between 200 nm and 1500 nm, between 200 nm and 1000 nm, between 200 nm and 800 nm, between 400 nm and 700 nm, between 400 nm and 600 nm, or between 400 nm and 470 nm. In this embodiment, the material 11 absorbs part of the incident light allowing the at least one particle 12 to absorb only a part of the incident light; and/or the material 11 absorbs part of the light emitted by the at least one particle 12 allowing said light emitted to be partially transmitted through the material 11.

According to one embodiment, the material 11 transmits at least 5%, 10%, 15%, 20%, 25%, 30%, 35%, 40%, 45%, 50%, 55%, 60%, 65%, 70%, 75%, 80%, 85%, 90%, 95%, or 100% of the incident light.

According to one embodiment, the material 11 transmits a part of the incident light and emits at least one secondary light. In this embodiment, the resulting light is a combination of the remaining transmitted incident light.

According to one embodiment, the material 11 absorbs the incident light with wavelength lower than 50 μm, 40 μm, 30 μm, 20 μm, 10 μm, 1 μm, 950 nm, 900 nm, 850 nm, 800 nm, 750 nm, 700 nm, 650 nm, 600 nm, 550 nm, 500 nm, 450 nm, 400 nm, 350 nm, 300 nm, 250 nm, or lower than 200 nm.

According to one embodiment, the material 11 absorbs the incident light with wavelength lower than 460 nm.

According to one embodiment, the material 11 has an extinction coefficient less or equal to 1×10⁻⁵, 1.1×10⁻⁵, 1.2×10⁻⁵, 1.3×10⁻⁵, 1.4×10⁻⁵, 1.5×10⁻⁵, 1.6×10⁻⁵, 1.7×10⁻⁵, 1.8×10⁻⁵, 1.9×10⁻⁵, 2×10⁻⁵, 3×10⁻⁵, 4×10⁻⁵, 5×10⁻⁵, 6×10⁻⁵, 7×10⁻⁵, 8×10⁻⁵, 9×10⁻⁵, 10×10⁻⁵, 11×10⁻⁵, 12×10⁻⁵, 13×10⁻⁵, 14×10⁻⁵, 15×10⁻⁵, 16×10⁻⁵, 17×10⁻⁵, 18×10⁻⁵, 19×10⁻⁵, 20×10⁻⁵, 21×10⁻⁵, 22×10⁻⁵, 23×10⁻⁵, 24×10⁻⁵, or 25×10⁻⁵ at 460 nm.

According to one embodiment, the material 11 has an attenuation coefficient less or equal to 1×10⁻² cm⁻¹, 1×10⁻¹ cm⁻¹, 0.5×10⁻¹ cm⁻¹, 0.1 cm⁻¹, 0.2 cm⁻¹, 0.3 cm⁻¹, 0.4 cm⁻¹, 0.5 cm⁻¹, 0.6 cm⁻¹, 0.7 cm⁻¹, 0.8 cm⁻¹, 0.9 cm⁻¹, 1 cm⁻¹, 1.1 cm⁻¹, 1.2 cm⁻¹, 1.3 cm⁻¹, 1.4 cm⁻¹, 1.5 cm⁻¹, 1.6 cm⁻¹, 1.7 cm⁻¹, 1.8 cm⁻¹, 1.9 cm⁻¹, 2.0 cm⁻¹, 2.5 cm⁻¹, 3.0 cm⁻¹, 3.5 cm⁻¹, 4.0 cm⁻¹, 4.5 cm⁻¹, 5.0 cm⁻¹, 5.5 cm⁻¹, 6.0 cm⁻¹, 6.5 cm⁻¹, 7.0 cm⁻¹, 7.5 cm⁻¹, 8.0 cm⁻¹, 8.5 cm⁻¹, 9.0 cm⁻¹, 9.5 cm⁻¹, 10 cm⁻¹, 15 cm⁻¹, 20 cm⁻¹, 25 cm⁻¹, or 30 cm⁻¹ at 460 nm.

According to one embodiment, the material 11 has an attenuation coefficient less or equal to 1×10⁻² cm⁻¹, 1×10⁻¹ cm⁻¹, 0.5×10⁻¹ cm⁻¹, 0.1 cm⁻¹, 0.2 cm⁻¹, 0.3 cm⁻¹, 0.4 cm⁻¹, 0.5 cm⁻¹, 0.6 cm⁻¹, 0.7 cm⁻¹, 0.8 cm⁻¹, 0.9 cm⁻¹, 1 cm⁻¹, 1.1 cm⁻¹, 1.2 cm⁻¹, 1.3 cm⁻¹, 1.4 cm⁻¹, 1.5 cm⁻¹, 1.6 cm⁻¹, 1.7 cm⁻¹, 1.8 cm⁻¹, 1.9 cm⁻¹, 2.0 cm⁻¹, 2.5 cm⁻¹, 3.0 cm⁻¹, 3.5 cm⁻¹, 4.0 cm⁻¹, 4.5 cm⁻¹, 5.0 cm⁻¹, 5.5 cm⁻¹, 6.0 cm⁻¹, 6.5 cm⁻¹, 7.0 cm⁻¹, 7.5 cm⁻¹, 8.0 cm⁻¹, 8.5 cm⁻¹, 9.0 cm⁻¹, 9.5 cm⁻¹, 10 cm⁻¹, 15 cm⁻¹, 20 cm⁻¹, 25 cm⁻¹, or 30 cm⁻¹ at 450 nm.

According to one embodiment, the material 11 has an optical absorption cross section less or equal to 1.10⁻³⁵ cm², 1.10⁻³⁴ cm², 1.10⁻³³ cm², 1.10⁻³² cm², 1.10⁻³¹ cm², 1.10⁻³⁰ cm², 1.10⁻²⁹ cm², 1.10⁻²⁸ cm², 1.10⁻²⁷ cm², 1.10⁻²⁶ cm², 1.10⁻²⁵ cm², 1.10⁻²⁴ cm², 1.10⁻²³ cm², 1.10⁻²² cm², 1.10⁻²¹ cm², 1.10⁻²⁹ cm², 1.10⁻¹⁹ cm², 1.10⁻¹⁸ cm², 1.10⁻¹⁷ cm², 1.10⁻¹⁶ cm², 1.10⁻¹⁵ cm², 1.10⁻¹⁴ cm², 1.10⁻¹³ cm², 1.10⁻¹² cm², 1.10⁻¹¹ cm², 1.10⁻¹⁰ cm², 1.10⁻⁹ cm², 1.10⁻⁸ cm², 1.10⁻⁷ cm², 1.10⁻⁶ cm², 1.10⁻⁵ cm², 1.10⁻⁴ cm², 1.10⁻³ cm², 1.10⁻² cm² or 1.10⁻¹ cm² at 460 nm.

According to one embodiment, the material 11 limits or prevents the diffusion of outer molecular species or fluids (liquid or gas) into said material 11.

According to one embodiment, the specific property of the particles 12 is preserved after encapsulation in the aggregate 1.

According to one embodiment, the photoluminescence of the particles 12 is preserved after encapsulation in the aggregate 1.

According to one embodiment, the material 11 has a density ranging from 1 to 10, preferably the material 11 has a density ranging from 3 to 10 g/cm³.

According to one embodiment, the material 11 acts as a barrier against oxidation of the at least one particle 12.

According to one embodiment, the refractive index of material 11 is tuned by the material 11 chosen.

According to one embodiment, the material 11 has a refractive index ranging from 1 to 5, from 1.2 to 2.6, from 1.4 to 2.0 at 450 nm.

According to one embodiment, the material 11 has a refractive index of at least 1.0, 1.1, 1.2, 1.3, 1.4, 1.5, 1.6, 1.7, 1.8, 1.9, 2.0, 2.1, 2.2, 2.3, 2.4, 2.5, 2.6, 2.7, 2.8, 2.9, or 3.0 at 450 nm.

According to one embodiment, the material 11 is thermally conductive.

According to one embodiment, the material 11 has a thermal conductivity at standard conditions ranging from 0.1 to 450 W/(m·K), preferably from 1 to 200 W/(m·K), more preferably from 10 to 150 W/(m·K).

According to one embodiment, the material 11 has a thermal conductivity at standard conditions of at least 0.1 W/(m·K), 0.2 W/(m·K), 0.3 W/(m·K), 0.4 W/(m·K), 0.5 W/(m·K), 0.6 W/(m·K), 0.7 W/(m·K), 0.8 W/(m·K), 0.9 W/(m·K), 1 W/(m·K), 1.1 W/(m·K), 1.2 W/(m·K), 1.3 W/(m·K), 1.4 W/(m·K), 1.5 W/(m·K), 1.6 W/(m·K), 1.7 W/(m·K), 1.8 W/(m·K), 1.9 W/(m·K), 2 W/(m·K), 2.1 W/(m·K), 2.2 W/(m·K), 2.3 W/(m·K), 2.4 W/(m·K), 2.5 W/(m·K), 2.6 W/(m·K), 2.7 W/(m·K), 2.8 W/(m·K), 2.9 W/(m·K), 3 W/(m·K), 3.1 W/(m·K), 3.2 W/(m·K), 3.3 W/(m·K), 3.4 W/(m·K), 3.5 W/(m·K), 3.6 W/(m·K), 3.7 W/(m·K), 3.8 W/(m·K), 3.9 W/(m·K), 4 W/(m·K), 4.1 W/(m·K), 4.2 W/(m·K), 4.3 W/(m·K), 4.4 W/(m·K), 4.5 W/(m·K), 4.6 W/(m·K), 4.7 W/(m·K), 4.8 W/(m·K), 4.9 W/(m·K), 5 W/(m·K), 5.1 W/(m·K), 5.2 W/(m·K), 5.3 W/(m·K), 5.4 W/(m·K), 5.5 W/(m·K), 5.6 W/(m·K), 5.7 W/(m·K), 5.8 W/(m·K), 5.9 W/(m·K), 6 W/(m·K), 6.1 W/(m·K), 6.2 W/(m·K), 6.3 W/(m·K), 6.4 W/(m·K), 6.5 W/(m·K), 6.6 W/(m·K), 6.7 W/(m·K), 6.8 W/(m·K), 6.9 W/(m·K), 7 W/(m·K), 7.1 W/(m·K), 7.2 W/(m·K), 7.3 W/(m·K), 7.4 W/(m·K), 7.5 W/(m·K), 7.6 W/(m·K), 7.7 W/(m·K), 7.8 W/(m·K), 7.9 W/(m·K), 8 W/(m·K), 8.1 W/(m·K), 8.2 W/(m·K), 8.3 W/(m·K), 8.4 W/(m·K), 8.5 W/(m·K), 8.6 W/(m·K), 8.7 W/(m·K), 8.8 W/(m·K), 8.9 W/(m·K), 9 W/(m·K), 9.1 W/(m·K), 9.2 W/(m·K), 9.3 W/(m·K), 9.4 W/(m·K), 9.5 W/(m·K), 9.6 W/(m·K), 9.7 W/(m·K), 9.8 W/(m·K), 9.9 W/(m·K), 10 W/(m·K), 10.1 W/(m·K), 10.2 W/(m·K), 10.3 W/(m·K), 10.4 W/(m·K), 10.5 W/(m·K), 10.6 W/(m·K), 10.7 W/(m·K), 10.8 W/(m·K), 10.9 W/(m·K), 11 W/(m·K), 11.1 W/(m·K), 11.2 W/(m·K), 11.3 W/(m·K), 11.4 W/(m·K), 11.5 W/(m·K), 11.6 W/(m·K), 11.7 W/(m·K), 11.8 W/(m·K), 11.9 W/(m·K), 12 W/(m·K), 12.1 W/(m·K), 12.2 W/(m·K), 12.3 W/(m·K), 12.4 W/(m·K), 12.5 W/(m·K), 12.6 W/(m·K), 12.7 W/(m·K), 12.8 W/(m·K), 12.9 W/(m·K), 13 W/(m·K), 13.1 W/(m·K), 13.2 W/(m·K), 13.3 W/(m·K), 13.4 W/(m·K), 13.5 W/(m·K), 13.6 W/(m·K), 13.7 W/(m·K), 13.8 W/(m·K), 13.9 W/(m·K), 14 W/(m·K), 14.1 W/(m·K), 14.2 W/(m·K), 14.3 W/(m·K), 14.4 W/(m·K), 14.5 W/(m·K), 14.6 W/(m·K), 14.7 W/(m·K), 14.8 W/(m·K), 14.9 W/(m·K), 15 W/(m·K), 15.1 W/(m·K), 15.2 W/(m·K), 15.3 W/(m·K), 15.4 W/(m·K), 15.5 W/(m·K), 15.6 W/(m·K), 15.7 W/(m·K), 15.8 W/(m·K), 15.9 W/(m·K), 16 W/(m·K), 16.1 W/(m·K), 16.2 W/(m·K), 16.3 W/(m·K), 16.4 W/(m·K), 16.5 W/(m·K), 16.6 W/(m·K), 16.7 W/(m·K), 16.8 W/(m·K), 16.9 W/(m·K), 17 W/(m·K), 17.1 W/(m·K), 17.2 W/(m·K), 17.3 W/(m·K), 17.4 W/(m·K), 17.5 W/(m·K), 17.6 W/(m·K), 17.7 W/(m·K), 17.8 W/(m·K), 17.9 W/(m·K), 18 W/(m·K), 18.1 W/(m·K), 18.2 W/(m·K), 18.3 W/(m·K), 18.4 W/(m·K), 18.5 W/(m·K), 18.6 W/(m·K), 18.7 W/(m·K), 18.8 W/(m·K), 18.9 W/(m·K), 19 W/(m·K), 19.1 W/(m·K), 19.2 W/(m·K), 19.3 W/(m·K), 19.4 W/(m·K), 19.5 W/(m·K), 19.6 W/(m·K), 19.7 W/(m·K), 19.8 W/(m·K), 19.9 W/(m·K), 20 W/(m·K), 20.1 W/(m·K), 20.2 W/(m·K), 20.3 W/(m·K), 20.4 W/(m·K), 20.5 W/(m·K), 20.6 W/(m·K), 20.7 W/(m·K), 20.8 W/(m·K), 20.9 W/(m·K), 21 W/(m·K), 21.1 W/(m·K), 21.2 W/(m·K), 21.3 W/(m·K), 21.4 W/(m·K), 21.5 W/(m·K), 21.6 W/(m·K), 21.7 W/(m·K), 21.8 W/(m·K), 21.9 W/(m·K), 22 W/(m·K), 22.1 W/(m·K), 22.2 W/(m·K), 22.3 W/(m·K), 22.4 W/(m·K), 22.5 W/(m·K), 22.6 W/(m·K), 22.7 W/(m·K), 22.8 W/(m·K), 22.9 W/(m·K), 23 W/(m·K), 23.1 W/(m·K), 23.2 W/(m·K), 23.3 W/(m·K), 23.4 W/(m·K), 23.5 W/(m·K), 23.6 W/(m·K), 23.7 W/(m·K), 23.8 W/(m·K), 23.9 W/(m·K), 24 W/(m·K), 24.1 W/(m·K), 24.2 W/(m·K), 24.3 W/(m·K), 24.4 W/(m·K), 24.5 W/(m·K), 24.6 W/(m·K), 24.7 W/(m·K), 24.8 W/(m·K), 24.9 W/(m·K), 25 W/(m·K), 30 W/(m·K), 40 W/(m·K), 50 W/(m·K), 60 W/(m·K), 70 W/(m·K), 80 W/(m·K), 90 W/(m·K), 100 W/(m·K), 110 W/(m·K), 120 W/(m·K), 130 W/(m·K), 140 W/(m·K), 150 W/(m·K), 160 W/(m·K), 170 W/(m·K), 180 W/(m·K), 190 W/(m·K), 200 W/(m·K), 210 W/(m·K), 220 W/(m·K), 230 W/(m·K), 240 W/(m·K), 250 W/(m·K), 260 W/(m·K), 270 W/(m·K), 280 W/(m·K), 290 W/(m·K), 300 W/(m·K), 310 W/(m·K), 320 W/(m·K), 330 W/(m·K), 340 W/(m·K), 350 W/(m·K), 360 W/(m·K), 370 W/(m·K), 380 W/(m·K), 390 W/(m·K), 400 W/(m·K), 410 W/(m·K), 420 W/(m·K), 430 W/(m·K), 440 W/(m·K), or 450 W/(m·K).

According to one embodiment, the thermal conductivity of the material 11 may be measured by for example by steady-state methods or transient methods.

According to one embodiment, the material 11 is not thermally conductive.

According to one embodiment, the material 11 comprises a refractory material.

According to one embodiment, the material 11 is electrically insulator. In this embodiment, the quenching of fluorescent properties for fluorescent particles dispersed in the material 11 is prevented when it is due to electron transport. In this embodiment, the aggregate 1 may be used as an electrical insulator material exhibiting the same properties as the particles 12 dispersed in the material 11.

According to one embodiment, the material 11 is electrically conductive. This embodiment is particularly advantageous for an application of the aggregate 1 in photovoltaics or LEDs.

According to one embodiment, the material 11 has an electrical conductivity at standard conditions ranging from 1×10⁻²⁰ to 10⁷ S/m, preferably from 1×10⁻¹⁵ to 5 S/m, more preferably from 1×10⁻⁷ to 1 S/m.

According to one embodiment, the material 11 has an electrical conductivity at standard conditions of at least 1×10⁻²⁰ S/m, 0.5×10⁻¹⁹ S/m, 1×10⁻¹⁹ S/m, 0.5×10⁻¹⁸ S/m, 1×10⁻¹⁸ S/m, 0.5×10⁻¹⁷ S/m, 1×10⁻¹⁷ S/m, 0.5×10⁻¹⁶S/m, 1×10⁻¹⁶ S/m, 0.5×10⁻¹⁵ S/m, 1×10⁻¹⁵ S/m, 0.5×10⁻¹⁴ S/m, 1×10⁻¹⁴ S/m, 0.5×10⁻¹³ S/m, 1×10⁻¹³ S/m, 0.5×10⁻¹² S/m, 1×10⁻¹² S/m, 0.5×10⁻¹¹ S/m, 1×10⁻¹¹ S/m, 0.5×10⁻¹⁰ S/m, 1×10⁻¹⁰ S/m, 0.5×10⁻⁹ S/m, 1×10⁻⁹ S/m, 0.5×10⁻⁸ S/m, 1×10⁻⁸ S/m, 0.5×10⁻⁷ S/m, 1×10⁻⁷ S/m, 0.5×10⁻⁶ S/m, 1×10⁻⁶ S/m, 0.5×10⁻⁵ S/m, 1×10⁻⁵ S/m, 0.5×10⁻⁴ S/m, 1×10⁻⁴ S/m, 0.5×10⁻³ S/m, 1×10⁻³ S/m, 0.5×10⁻² S/m, 1×10⁻² S/m, 0.5×10⁻¹ S/m, 1×10⁻¹ S/m, 0.5 S/m, 1 S/m, 1.5 S/m, 2 S/m, 2.5 S/m, 3 S/m, 3.5 S/m, 4 S/m, 4.5 S/m, 5 S/m, 5.5 S/m, 6 S/m, 6.5 S/m, 7 S/m, 7.5 S/m, 8 S/m, 8.5 S/m, 9 S/m, 9.5 S/m, 10 S/m, 50 S/m, 10² S/m, 5×10² S/m, 10³ S/m, 5×10³ S/m, 10⁴ S/m, 5×10⁴ S/m, 10⁵ S/m, 5×10⁵ S/m, 10⁶ S/m, 5×10⁶ S/m, or 10⁷ S/m.

According to one embodiment, the electrical conductivity of the material 11 may be measured for example with an impedance spectrometer.

According to one embodiment, the material 11 is amorphous.

According to one embodiment, the material 11 is crystalline.

According to one embodiment, the material 11 is totally crystalline.

According to one embodiment, the material 11 is partially crystalline.

According to one embodiment, the material 11 is monocrystalline.

According to one embodiment, the material 11 is polycrystalline. In this embodiment, the material 11 comprises at least one grain boundary.

According to one embodiment, the material 11 has a transition temperature ranging from −150° C. to 400° C., preferably from −130° C. to 370° C., from −140° C. to 400° C.; −130° C. to 400° C.; −120° C. to 400° C.; −110° C. to 400° C.; −100° C. to 400° C.; −90° C. to 400° C.; −80° C. to 400° C.; −70° C. to 400° C.; −60° C. to 400° C.; −50° C. to 400° C.; −40° C. to 400° C.; −30° C. to 400° C.; −20° C. to 400° C.; −10° C. to 400° C.; 0° C. to 400° C.; 10° C. to 400° C.; 20° C. to 400° C.; 30° C. to 400° C.; 40° C. to 400° C.; 50° C. to 400° C.; 60° C. to 400° C.; 70° C. to 400° C.; 80° C. to 400° C.; 90° C. to 400° C.; 100° C. to 400° C.; 150° C. to 400° C.; 200° C. to 400° C.; 250° C. to 400° C.; 300° C. to 400° C.; 350° C. to 400° C. According to one embodiment, the material 11 has a trantition temperature ranging from −150° C. to 350° C., from −150° C. to 300° C., from −150° C. to 250° C., from −150° C. to 200° C., from −150° C. to 150° C., from −150° C. to 100° C., from −150° C. to 90° C., from −150° C. to 80° C., from −150° C. to 70° C., from −150° C. to 60° C., from −150° C. to 50° C., from −150° C. to 40° C., from −150° C. to 30° C., from −150° C. to 20° C., from −150° C. to 10° C., from −150° C. to 0° C., from −150° C. to −10° C., from −150° C. to −20° C., from −150° C. to −30° C., from −150° C. to −40° C., from −150° C. to −50° C., from −150° C. to −60° C., from −150° C. to −70° C., from −150° C. to −80° C., from −150° C. to −90° C., from −150° C. to −100° C., from −150° C. to −110° C., from −150° C. to −120° C., from −150° C. to −130° C., or from −150° C. to −140° C.

According to one embodiment, the material 11 has a transition temperature ranging from −150° C. to 1500° C., preferably from −100° C. to 1500° C., preferably from −50° C. to 1500° C., preferably from 0° C. to 1500° C., preferably from 50° C. to 1500° C., preferably from 100° C. to 1500° C., preferably from 150° C. to 1500° C., preferably from 200° C. to 1500° C., preferably from 250° C. to 1500° C., preferably from 300° C. to 1500° C., preferably from 350° C. to 1500° C., preferably from 400° C. to 1500° C., preferably from 450° C. to 1500° C., preferably from 500° C. to 1500° C., preferably from 550° C. to 1500° C., preferably from 600° C. to 1500° C., preferably from 650° C. to 1500° C., preferably from 700° C. to 1500° C., preferably from 750° C. to 1500° C., preferably from 800° C. to 1500° C., preferably from 850° C. to 1500° C., preferably from 900° C. to 1500° C., preferably from 950° C. to 1500° C., preferably from 1000° C. to 1500° C., preferably from 1050° C. to 1500° C., preferably from 1100° C. to 1500° C., preferably from 1150° C. to 1500° C., preferably from 1200° C. to 1500° C., preferably from 1250° C. to 1500° C., preferably from 1300° C. to 1500° C., preferably from 1350° C. to 1500° C., preferably from 1400° C. to 1500° C., or preferably from 1450° C. to 1500° C. According to one embodiment, the material 11 has a trantition temperature ranging from −150° C. to 1500° C., from −150° C. to 1450° C., from −150° C. to 1400° C., from −150° C. to 1350° C., from −150° C. to 1300° C., from −150° C. to 1250° C., from −150° C. to 1200° C., from −150° C. to 1150° C., from −150° C. to 1100° C., from −150° C. to 1050° C., from −150° C. to 1000° C., from −150° C. to 950° C., from −150° C. to 900° C., from −150° C. to 850° C., from −150° C. to 800° C., from −150° C. to 750° C., from −150° C. to 700° C., from −150° C. to 650° C., from −150° C. to 600° C., from −150° C. to 550° C., from −150° C. to 500° C., from −150° C. to 450° C., from −150° C. to 400° C., from −150° C. to 350° C., from −150° C. to 300° C., from −150° C. to 250° C., from −150° C. to 200° C., from −150° C. to 150° C., from −150° C. to 100° C., from −150° C. to 50° C., from −150° C. to 0° C., from −150° C. to −50° C., or from −150° C. to −100° C.

According to one embodiment, the material 11 has a transition temperature which is a glass transition temperature (Tg) or a melting temperature (Tm). In the present invention, the expression “transition temperature” refers to the temperature for which the material goes from one state to another.

According to one embodiment, the material 11 is hydrophobic.

According to one embodiment, the material 11 is hydrophilic.

According to one embodiment, the material 11 is porous.

According to one embodiment, the material 11 is considered porous when the quantity adsorbed by the aggregate 1 determined by adsorption-desorption of nitrogen in the Brunauer-Emmett-Teller (BET) theory is more than 20 cm³/g, 15 cm³/g, 10 cm³/g, 5 cm³/g at a nitrogen pressure of 650 mmHg, preferably 700 mmHg

According to one embodiment, the organization of the porosity of the material 11 can be hexagonal, vermicular or cubic.

According to one embodiment, the organized porosity of the material 11 has a pore size of at least 1 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, or 50 nm.

According to one embodiment, the material 11 is not porous.

According to one embodiment, the material 11 does not comprise pores or cavities.

According to one embodiment, the material 11 is considered non-porous when the quantity adsorbed by the aggregate 1 determined by adsorption-desorption of nitrogen in the Brunauer-Emmett-Teller (BET) theory is less than 20 cm³/g, 15 cm³/g, 10 cm³/g, 5 cm³/g at a nitrogen pressure of 650 mmHg, preferably 700 mmHg.

According to one embodiment, the material 11 is permeable. In this embodiment, permeation of outer molecular species, gas or liquid in the material 11.

According to one embodiment, the permeable material 11 has an intrinsic permeability to fluids higher or equal to 10⁻²⁰ cm², 10⁻¹⁹ cm², 10⁻¹⁸ cm², 10⁻¹⁷ cm², 10⁻¹⁶ cm², 10⁻¹⁵ cm², 10⁻¹⁴ cm², 10⁻¹³ cm², 10⁻¹² cm², 10⁻¹¹ cm², 10⁻¹⁰ cm², 10⁻⁹ cm², 10⁻⁸ cm², 10⁻⁷ cm², 10⁻⁶ cm², 10⁻⁵ cm², 10⁻⁴ cm², or 10⁻³ cm².

According to one embodiment, the material 11 is impermeable to outer molecular species, gas or liquid. In this embodiment, the material 11 limits or prevents the degradation of the chemical and physical properties of the at least one particle 12 from molecular oxygen, ozone, water and/or high temperature.

According to one embodiment, the impermeable material 11 has an intrinsic permeability to fluids less or equal to 10⁻¹¹ cm², 10⁻¹² cm², 10⁻¹³ cm², 10⁻¹⁴ cm², 10⁻¹⁵ cm², 10⁻¹⁶ cm², 10⁻¹⁷ cm², 10⁻¹⁸ cm², 10⁻¹⁹ cm², or 10⁻²⁰ cm².

According to one embodiment, the material 11 is selected from inorganic, organic or hybrid materials.

According to one embodiment, the material 11 results from the polymerization from alpha-olefins, dienes such as butadiene and chloroprene; styrene, alpha-methyl styrene, and the like; heteroatom substituted alpha-olefins, for example, vinyl acetate, vinyl alkyl ethers for example, ethyl vinyl ether, vinyltrimethylsilane, vinyl chloride, tetrafluoroethylene, chlorotrifiuoroethylene, cyclic and polycyclic olefin compounds for example, cyclopentene, cyclohexene, cycloheptene, cyclooctene, and cyclic derivatives up to C20; polycyclic derivates for example, norbornene, and similar derivatives up to C20; cyclic vinyl ethers, 3-dihydrofuran, 3,4-dihydropyran, and similar derivatives; allylic alcohol derivatives for example, vinylethylene carbonate, disubstituted olefins such as maleic and fumaric compounds for example, maleic anhydride, diethylfumarate, and the like, and mixtures thereof.

According to one embodiment, the material 11 results from the polymerization of an alkyl methacrylates or an alkyl acrylates such as acrylic acid, methacrylic acid, crotonic acid, acrylonitrile, acrylic esters substituted with methoxy, ethoxy, propoxy, butoxy, and similar derivatives for example, methyl acrylate, ethyle acrylate, propyl acrylate, butyl acrylate, isobutyl acrylate, lauryl acrylate, norbornyl acrylate, 2-ethyl hexyl acrylate, 2-hydroxyethyl acrylate, 4-hydroxybutyl acrylate, benzyl acrylate, phenyl acrylate, isobornyle acrylate, hydroxypropyl acrylate, fluorinated acrylic monomers, chlorinated acrylic monomers, methacrylic acid, methyl methacrylate, nbutyl methacrylate, isobutyl methacrylate, 2-ethyl hexyl methacrylate, 2-hydroxyethyl methacrylate, 4-hydroxybutyl methacrylate, benzyl methacrylate, phenyl methacrylate, lauryl methacrylate, norbornyl methacrylate, isobornyle methacrylate, hydroxypropyl methacrylate, fluorinated methacrylic monomers, chlorinated methacrylic monomers, alkyl crotonates, allyl crotonates, glycidyl methacrylate and related esters.

According to one embodiment, the material 11 results from the polymerization of an alkyl acrylamide or alkyl methacrylamide such as acrylamide, Alkylacrylamide, Ntert-Butylacrylamide, Diacetone acrylamide, N,N-Diethylacrylamide, N-Isobutoxymethyl)acrylamide, N-(3-Methoxypropyl)acrylamide, NDiphenylmethylacrylamide, N-Ethylacrylamide, N-Hydroxyethyl acrylamide, N-(Isobutoxymethyl)acrylamide, N-Isopropylacrylamide, N-(3-Methoxypropyl)acrylamide, N-Phenylacrylamide, N-[Tris(hydroxymethyl)methyl]acrylamide, N,N-Diethylmethacrylamide, N,NDimethylacrylamide, N-[3-(Dimethylamino)propyl]methacrylamide, N-(Hydroxymethyl)acrylamide, 2-Hydroxypropyl methacrylamide, NIsopropylmethacrylamide, Methacrylamide, N-(Triphenylmethyl)methacrylamide, poly (3,4-ethylenedioxythiopene), poly(ethylene dioxythiophene)/poly(styrene sulfonic acid) (PEDOT/PSS), an aqueous solution of polyaniline/camphor sulfonic acid (PANI/CSA), PTPDES, Et-PIT-DEK, PPBA, and similar derivatives.

According to one embodiment, the material 11 is PMMA, Poly(lauryl methacrylate), glycolized poly(ethylene terephthalate), Poly(maleic anhydride altoctadecene), or mixtures thereof.

According to one embodiment, the material 11 is selected from silicone, PMMA, Polyethylene glycol/polyethylene oxide, Polyethylene Terephthalate, Polyimide, Polyetherimide, Polyamide, Polyetherimine, Poly amic acid, polyethers, polyester, polyacrylates, polymethacrylate, polycarbonates, polycaprolactone, polyvinyl alcohol, polydimethylsiloxane, polyvinylpyrrolidone, polyvinyl pyridine, polyvinylimidazole, polyimidazole, Polystyrene, Poly(vinyl acetate), poly(acrylonitrile), poly(propylene), poly(acrylic acid), polyoxazoline (poly-2-oxazoline), polylauryl methacrylate, polyglycolide, polylactic acid, poly(nucleotides), polysaccharides, block copolymers or copolymers such as polylactic-co-glycolic acid (PGLA), or a mixture thereof.

According to one embodiment, the material 11 is selected from silicone based polymers, polydimethylsiloxanes (PDMS), polyethylene terephthalate, polyesters, polyacrylates, polymethacrylates, polycarbonate, poly(vinyl alcohol), polyvinylpyrrolidone, polyvinylpyridine, polysaccharides, poly(ethylene glycol), melamine resins, a phenol resin, an alkyl resin, an epoxy resin, a polyurethane resin, a maleic resin, a polyamide resin, an alkyl resin, a maleic resin, terpenes resins, an acrylic resin or acrylate based resin such as PMMA, copolymers forming the resins, co-polymers, block co-polymers, polymerizable monomers comprising an UV initiator or thermic initiator, or a mixture thereof.

According to one embodiment, the material 11 results from the polymerization of an alkyl acrylamide or alkyl methacrylamide such as acrylamide, Alkylacrylamide, Ntert-Butylacrylamide, Diacetone acrylamide, N,N-Diethylacrylamide, N-Isobutoxymethyl)acrylamide, N-(3-Methoxypropyl)acrylamide, NDiphenylmethylacrylamide, N-Ethylacrylamide, N-Hydroxyethyl acrylamide, N-(Isobutoxymethyl)acrylamide, N-Isopropylacrylamide, N-(3-Methoxypropyl)acrylamide, N-Phenylacrylamide, N-[Tris(hydroxymethyl)methyl]acrylamide, N,N-Diethylmethacrylamide, N,NDimethylacrylamide, N-[3-(Dimethylamino)propyl]methacrylamide, N-(Hydroxymethyl)acrylamide, 2-Hydroxypropyl methacrylamide, NIsopropylmethacrylamide, Methacrylamide, N-(Triphenylmethyl)methacrylamide, poly (3,4-ethylenedioxythiopene), poly(ethylene dioxythiophene)/poly(styrene sulfonic acid) (PEDOT/PSS), an aqueous solution of polyaniline/camphor sulfonic acid (PANI/CSA), PTPDES, Et-PIT-DEK, PPBA, and similar derivatives.

According to one embodiment, the material 11 results from the polymerization of alpha-olefins, dienes such as butadiene and chloroprene; styrene, alpha-methyl styrene, and the like; heteroatom substituted alpha-olefins, for example, vinyl acetate, vinyl alkyl ethers for example, ethyl vinyl ether, vinyltrimethylsilane, vinyl chloride, tetrafluoroethylene, chlorotrifiuoroethylene, cyclic and polycyclic olefin compounds for example, cyclopentene, cyclohexene, cycloheptene, cyclooctene, and cyclic derivatives up to C20; polycyclic derivates for example, norbornene, and similar derivatives up to C20; cyclic vinyl ethers, 3-dihydrofuran, 3,4-dihydropyran, and similar derivatives; allylic alcohol derivatives for example, vinylethylene carbonate, disubstituted olefins such as maleic and fumaric compounds for example, maleic anhydride, diethylfumarate, and the like, and mixtures thereof.

According to one embodiment, the material 11 is a material adapted for 3D printing.

According to one embodiment, the material 11 is a 3D printing resin.

According to one embodiment, the material 11 is an inorganic material.

According to one embodiment, the inorganic material refers to any element and/or material containing no carbon except some simple carbon compounds such as oxides, carbonates. According to one embodiment, the inorganic material refers to any element and/or material containing no carbon.

According to one embodiment, the inorganic material is selected from metals, metal oxides, halides, chalcogenides, phosphides, sulfides, metalloids, metallic alloys, ceramics such as for example oxides, carbides, nitrides, glasses, enamels, ceramics, stones, precious stones, pigments, cements and/or inorganic polymers.

According to one embodiment, the inorganic material 11 is selected from metals, metal oxides, halides, chalcogenides, phosphides, sulfides, metalloids, metallic alloys, ceramics such as for example oxides, carbides, nitrides, glasses, enamels, ceramics, stones, precious stones, pigments, cements; preferably the inorganic material 11 is an inorganic polymer.

According to one embodiment, the aggregate 1 does not comprise organic molecules or polymer chains.

According to one embodiment, the material 11 does not comprise organic molecules.

According to one embodiment, the material 11 does not comprise polymers.

According to one embodiment, the material 11 comprises inorganic polymers.

According to one embodiment, the material 11 is selected from the group consisting of oxide materials, semiconductor materials, wide-bandgap semiconductor materials or a mixture thereof.

According to one embodiment, examples of semiconductor materials include but are not limited to: III-V semiconductors, II-VI semiconductors, or a mixture thereof.

According to one embodiment, examples of wide-bandgap semiconductor materials include but are not limited to: silicon carbide SiC, aluminium nitride AlN, gallium nitride GaN, boron nitride BN, or a mixture thereof.

According to one embodiment, examples of oxide materials include but are not limited to: SiO₂, Al₂O₃, TiO₂, ZrO₂, FeO, ZnO, MgO, SnO₂, Nb₂O₅, CeO₂, BeO, IrO₂, CaO, Sc₂O₃, Na₂O, BaO, K₂O, TeO₂, MnO, B₂O₃, GeO₂, As₂O₃, Ta₂O₅, Li₂O, SrO, Y₂O₃, HfO₂, MoO₂, Tc₂O₇, ReO₂, Co₃O₄, OsO, RhO₂, Rh₂O₃, CdO, HgO, Tl₂O, Ga₂O₃, In₂O₃, Bi₂O₃, Sb₂O₃, PoO₂, SeO₂, Cs₂O, La₂O₃, Pr₆O₁₁, Nd₂O₃, La₂O₃, Sm₂O₃, Eu₂O₃, Tb₄O₇, Dy₂O₃, Ho₂O₃, Er₂O₃, Tm₂O₃, Yb₂O₃, Lu₂O₃, Gd₂O₃, or a mixture thereof.

According to one embodiment, the metal oxide is selected from any compound having at least one linkage between an oxygen atom and a metal as defined above.

According to one embodiment, the material 11 is selected from the group consisting of silicon oxide, aluminium oxide, titanium oxide, iron oxide, calcium oxide, magnesium oxide, zinc oxide, tin oxide, beryllium oxide, zirconium oxide, niobium oxide, cerium oxide, iridium oxide, scandium oxide, sodium oxide, barium oxide, potassium oxide, tellurium oxide, manganese oxide, boron oxide, germanium oxide, osmium oxide, rhenium oxide, arsenic oxide, tantalum oxide, lithium oxide, strontium oxide, yttrium oxide, hafnium oxide, molybdenum oxide, technetium oxide, rhodium oxide, cobalt oxide, gallium oxide, indium oxide, antimony oxide, polonium oxide, selenium oxide, cesium oxide, lanthanum oxide, praseodymium oxide, neodymium oxide, samarium oxide, europium oxide, terbium oxide, dysprosium oxide, erbium oxide, holmium oxide, thulium oxide, ytterbium oxide, lutetium oxide, gadolinium oxide, silicon carbide SiC, aluminium nitride AlN, gallium nitride GaN, boron nitride BN, mixed oxides, mixed oxides thereof, or a mixture thereof.

According to one embodiment, examples of oxide materials include but are not limited to: SiO₂, Al₂O₃, TiO₂, ZrO₂, FeO, ZnO, MgO, SnO₂, PbO, Ag₂O, Nb₂O₅, CeO₂, BeO, IrO₂, CaO, Sc₂O₃, Na₂O, BaO, K₂O, TeO₂, MnO, B₂O₃, GeO₂, As₂O₃, Ta₂O₅, Li₂O, SrO, P₂O₅, P₂O₃, P₄O₇, P₄O₈, P₄O₉, P₂O₆, PO, Fe₂O₃, Fe₃O₄, WO₂, Cr₂O₃, RuO₂, PtO, PdO, CuO, Cu₂O, Y₂O₃, HfO₂, V₂O₅, MoO₂, Tc₂O₇, ReO₂, Co₃O₄, OsO, RhO₂, Rh₂O₃, CdO, HgO, Tl₂O, Ga₂O₃, In₂O₃, Bi₂O₃, Sb₂O₃, PoO₂, SeO₂, Cs₂O, La₂O₃, Pr₆O₁₁, Nd₂O₃, La₂O₃, Sm₂O₃, Eu₂O₃, Tb₄O₇, Dy₂O₃, Ho₂O₃, Er₂O₃, Tm₂O₃, Yb₂O₃, Lu₂O₃, Gd₂O₃, or a mixture thereof.

According to one embodiment, the material 11 is selected from the group consisting of silicon oxide, aluminium oxide, titanium oxide, copper oxide, iron oxide, silver oxide, lead oxide, calcium oxide, magnesium oxide, zinc oxide, tin oxide, beryllium oxide, zirconium oxide, niobium oxide, cerium oxide, iridium oxide, scandium oxide, nickel oxide, sodium oxide, barium oxide, potassium oxide, vanadium oxide, tellurium oxide, manganese oxide, boron oxide, phosphorus oxide, germanium oxide, osmium oxide, rhenium oxide, platinum oxide, arsenic oxide, tantalum oxide, lithium oxide, strontium oxide, yttrium oxide, hafnium oxide, tungsten oxide, molybdenum oxide, chromium oxide, technetium oxide, rhodium oxide, ruthenium oxide, cobalt oxide, palladium oxide, cadmium oxide, mercury oxide, thallium oxide, gallium oxide, indium oxide, bismuth oxide, antimony oxide, polonium oxide, selenium oxide, cesium oxide, lanthanum oxide, praseodymium oxide, neodymium oxide, samarium oxide, europium oxide, terbium oxide, dysprosium oxide, erbium oxide, holmium oxide, thulium oxide, ytterbium oxide, lutetium oxide, gadolinium oxide, mixed oxides, mixed oxides thereof or a mixture thereof.

According to one embodiment, the material 11 comprises or consists of a ZrO₂/SiO₂ mixture: SiₓZr₁₋ₓO₂, wherein 0≤x≤1. In this embodiment, the material 11 is able to resist to any pH in a range from 0 to 14. This allows for a better protection of the at least one particle 12.

According to one embodiment, the material 11 comprises or consists Si_{0.8}Zr_{0.2}O₂.

According to one embodiment, the material 11 comprises or consists of a HfO₂/SiO₂ mixture: SiₓHf₁₋ₓO₂, wherein 0≤x≤1.

According to one embodiment, the material 11 comprises or consists of Si_{0.8}Hf_{0.2}O₂.

According to one embodiment, the material 11 comprises or consists of mixture: SiₓZr₁₋ₓO_{z}, wherein 0<x≤1 and 0<z≤3.

According to one embodiment, the material 11 comprises or consists of a HfO₂/SiO₂ mixture: SiₓHf₁₋ₓO₂, wherein 0<x≤1 and 0<z≤3.

According to one embodiment, the material 11 comprises or consists of garnets.

According to one embodiment, examples of garnets include but are not limited to: Y₃Al₅O₁₂, Y₃Fe₂(FeO₄)₃, Y₃Fe₅O₁₂, Y₄Al₂O₉, YAlO₃, Fe₃Al₂(SiO₄)₃, Mg₃Al₂(SiO₄)₃, Mn₃Al₂(SiO₄)₃, Ca₃Fe₂(SiO₄)₃, Ca₃Al₂(SiO₄)₃, Ca₃Cr₂(SiO₄)₃, Al₅Lu₃O₁₂, GAL, GaYAG, or a mixture thereof.

According to one embodiment, the ceramic is crystalline or non-crystalline ceramics. According to one embodiment, the ceramic is selected from oxide ceramics and/or non-oxides ceramics, According to one embodiment, the ceramic is selected from pottery, bricks, tiles, cements and/glasses.

According to one embodiment, the stone is selected from agate, aquamarine, amazonite, amber, amethyst, ametrine, angelite, apatite, aragonite, silver, astrophylite, aventurine, azurite, beryk, silicified wood, bronzite, chalcedony, calcite, celestine, chakras, charoite, chiastolite, chrysocolla, chrysoprase , citrine, coral, cornalite, rock crystal, native copper, cyanite, damburite, diamond, dioptase, dolomite, dumorerite, emerald, fluorite, foliage, galene, garnet, heliotrope; hematite, hemimorphite, howlite, hypersthene, iolite, jades, jet, jasper, kunzite, labradorite, lazuli lazuli, larimar, lava, lepidolite, magnetist, magnetite, alachite, marcasite, meteorite, mokaite, moldavite, morganite, mother-of-pearl, obsidian, eye hawk, iron eye, bull's eye, tiger eye, onyx tree, black onyx, opal, gold, peridot, moonstone, star stone, sun stone, pietersite, prehnite, pyrite, blue quartz, smoky quartz , quartz, quatz hematoide, milky quartz, rose quartz, rutile quartz, rhodochrosite, rhodonite, rhyolite, ruby, sapphire, rock salt, selenite, seraphinite, serpentine, shattukite, shiva lingam, shungite, flint, smithsonite, sodalite, stealite, straumatolite sugilite, tanzanite, topaz, tourmaline watermelon, black tourmaline, turquoise, ulexite, unakite, variscite, zoizite.

According to one embodiment, the material 11 comprises or consists of a thermal conductive material wherein said thermal conductive material includes but is not limited to: Al_{y}Oₓ, Ag_{y}Oₓ, Cu_{y}Oₓ, Fe_{y}Oₓ, Si_{y}Oₓ, Pb_{y}Oₓ, Ca_{y}Oₓ, Mg_{y}Oₓ, Zn_{y}Oₓ, Sn_{y}Oₓ, Ti_{y}Oₓ, Be_{y}Oₓ, mixed oxides, mixed oxides thereof or a mixture thereof; x and y are independently a decimal number from 0 to 10, at the condition that x and y are not simultaneously equal to 0, and x≠0.

According to one embodiment, the material 11 comprises or consists of a thermal conductive material wherein said thermal conductive material includes but is not limited to: Al₂O₃, Ag₂O, Cu₂O, CuO, Fe₃O₄, FeO, SiO₂, PbO, CaO, MgO, ZnO, SnO₂, TiO₂, BeO, mixed oxides, mixed oxides thereof or a mixture thereof.

According to one embodiment, the material 11 comprises or consists of a thermal conductive material wherein said thermal conductive material includes but is not limited to: aluminium oxide, silver oxide, copper oxide, iron oxide, silicon oxide, lead oxide, calcium oxide, magnesium oxide, zinc oxide, tin oxide, titanium oxide, beryllium oxide, mixed oxides, mixed oxides thereof or a mixture thereof.

According to one embodiment, the material 11 comprises or consists of a material including but not limited to: silicon oxide, aluminium oxide, titanium oxide, copper oxide, iron oxide, silver oxide, lead oxide, calcium oxide, magnesium oxide, zinc oxide, tin oxide, beryllium oxide, zirconium oxide, niobium oxide, cerium oxide, iridium oxide, scandium oxide, nickel oxide, sodium oxide, barium oxide, potassium oxide, vanadium oxide, tellurium oxide, manganese oxide, boron oxide, phosphorus oxide, germanium oxide, osmium oxide, rhenium oxide, platinum oxide, arsenic oxide, tantalum oxide, lithium oxide, strontium oxide, yttrium oxide, hafnium oxide, tungsten oxide, molybdenum oxide, chromium oxide, technetium oxide, rhodium oxide, ruthenium oxide, cobalt oxide, palladium oxide, cadmium oxide, mercury oxide, thallium oxide, gallium oxide, indium oxide, bismuth oxide, antimony oxide, polonium oxide, selenium oxide, cesium oxide, lanthanum oxide, praseodymium oxide, neodymium oxide, samarium oxide, europium oxide, terbium oxide, dysprosium oxide, erbium oxide, holmium oxide, thulium oxide, ytterbium oxide, lutetium oxide, gadolinium oxide, mixed oxides, mixed oxides thereof, garnets such as for example Y₃Al₅O₁₂, Y₃Fe₂(FeO₄)₃, Y₃Fe₅O₁₂, Y₄Al₂O₉, YAlO₃, Fe₃Al₂(SiO₄)₃, Mg₃Al₂(SiO₄)₃, Mn₃Al₂(SiO₄)₃, Ca₃Fe₂(SiO₄)₃, Ca₃Al₂(SiO₄)₃, Ca₃Cr₂(SiO₄)₃, Al₅Lu₃O₁₂, GAL, GaYAG, or a mixture thereof.

According to one embodiment, the material 11 comprises or consists a material selected in the group of metals, halides, chalcogenides, phosphides, sulfides, metalloids, metallic alloys, ceramics such as for example oxides, carbides, or nitrides. Said material 11 is prepared using protocols known to the person skilled in the art.

According to one embodiment, a chalcogenide is a chemical compound consisting of at least one chalcogen anion selected in the group of O, S, Se, Te, Po, and at least one or more electropositive element.

According to one embodiment, the metallic material 11 are selected in the group of gold, silver, copper, vanadium, platinum, palladium, ruthenium, rhenium, yttrium, mercury, cadmium, osmium, chromium, tantalum, manganese, zinc, zirconium, niobium, molybdenum, rhodium, tungsten, iridium, nickel, iron, or cobalt.

According to one embodiment, examples of carbide material 11 include but are not limited to: SiC, WC, BC, MoC, TiC, Al₄C₃, LaC₂, FeC, CoC, HfC, SiₓC_{y}, WₓC_{y}, BₓC_{y}, MoₓC_{y}, TiₓC_{y}, AlₓC_{y}, LaₓC_{y}, FeₓC_{y}, CoₓC_{y}, HfₓC_{y}, or a mixture thereof; x and y are independently a decimal number from 0 to 5, at the condition that x and y are not simultaneously equal to 0, and x≠0.

According to one embodiment, examples of nitride material 11 include but are not limited to: TiN, Si₃N₄, MoN, VN, TaN, Zr₃N₄, HfN, FeN, NbN, GaN, CrN, AlN, InN, TiₓN_{y}, SiₓN_{y}, MoₓN_{y}, VₓN_{y}, TaₓN_{y}, ZrₓN_{y}, HfₓN_{y}, FeₓN_{y}, NbₓN_{y}, GaₓN_{y}, CrₓN_{y}, AlₓN_{y}, InₓN_{y}, or a mixture thereof; x and y are independently a decimal number from 0 to 5, at the condition that x and y are not simultaneously equal to 0, and x≠0.

According to one embodiment, examples of sulfide material 11 include but are not limited to: Si_{y}Sₓ, Al_{y}Sₓ, Ti_{y}Sₓ, Zr_{y}Sₓ, Zn_{y}Sₓ, Mg_{y}Sₓ, Sn_{y}Sₓ, Nb_{y}Sₓ, Ce_{y}Sₓ, Be_{y}Sₓ, Ir_{y}Sₓ, Ca_{y}Sₓ, Sc_{y}Sₓ, Ni_{y}Sₓ, Na_{y}Sₓ, Ba_{y}Sₓ, K_{y}Sₓ, Pb_{y}Sₓ, Ag_{y}Sₓ, V_{y}Sₓ, Te_{y}Sₓ, Mn_{y}Sₓ, B_{y}Sₓ, P_{y}Sₓ, Ge_{y}Sₓ, As_{y}Sₓ, Fe_{y}Sₓ, Ta_{y}Sₓ, Li_{y}Sₓ, Sr_{y}Sₓ, Y_{y}Sₓ, Hf_{y}Sₓ, W_{y}Sₓ, Mo_{y}Sₓ, Cr_{y}Sₓ, Tc_{y}Sₓ, Re_{y}Sₓ, Ru_{y}Sₓ, Co_{y}Sₓ, Os_{y}Sₓ, Rh_{y}Sₓ, Pt_{y}Sₓ, Pd_{y}Sₓ, Cu_{y}Sₓ, Au_{y}Sₓ, Cd_{y}Sₓ, Hg_{y}Sₓ, Tl_{y}Sₓ, Ga_{y}Sₓ, In_{y}Sₓ, Bi_{y}Sₓ, Sb_{y}Sₓ, Po_{y}Sₓ, Se_{y}Sₓ, Cs_{y}Sₓ, mixed sulfides, mixed sulfides thereof or a mixture thereof; x and y are independently a decimal number from 0 to 10, at the condition that x and y are not simultaneously equal to 0, and x≠0.

According to one embodiment, examples of halide material 11 include but are not limited to: BaF₂, LaF₃, CeF₃, YF₃, CaF₂, MgF₂, PrF₃, AgCl, MnCl₂, NiCl₂, Hg₂Cl₂, CaCl₂, CsPbCl₃, AgBr, PbBr₃, CsPbBr₃, AgI, CuI, PbI, HgI₂, BiI₃, CH₃NH₃PbI₃, CH₃NH₃PbCl₃, CH₃NH₃PbBr₃, CsPbI₃, FAPbBr₃ (with FA formamidinium), or a mixture thereof.

According to one embodiment, examples of chalcogenide material 11 include but are not limited to: CdO, CdS, CdSe, CdTe, ZnO, ZnS, ZnSe, ZnTe, HgO, HgS, HgSe, HgTe, CuO, Cu₂O, CuS, Cu₂S, CuSe, CuTe, Ag₂O, Ag₂S, Ag₂Se, Ag₂Te, Au₂S, PdO, PdS, Pd₄S, PdSe, PdTe, PtO, PtS, PtS₂, PtSe, PtTe, RhO₂, Rh₂O₃, RhS₂, Rh₂S₃, RhSe₂, Rh₂Se₃, RhTe₂, IrO₂, IrS₂, Ir₂S₃, IrSe₂, IrTe₂, RuO₂, RuS₂, OsO, OsS, OsSe, OsTe, MnO, MnS, MnSe, MnTe, ReO₂, ReS₂, Cr₂O₃, Cr₂S₃, MoO₂, MoS₂, MoSe₂, MoTe₂, WO₂, WS₂, WSe₂, V₂O₅, V₂S₃, Nb₂O₅, NbS₂, NbSe₂, HfO₂, HfS₂, TiO₂, ZrO₂, ZrS₂, ZrSe₂, ZrTe₂, Sc₂O₃, Y₂O₃, Y₂S₃, SiO₂, GeO₂, GeS, GeS₂, GeSe, GeSe₂, GeTe, SnO₂, SnS, SnS₂, SnSe, SnSe₂, SnTe, PbO, PbS, PbSe, PbTe, MgO, MgS, MgSe, MgTe, CaO, CaS, SrO, Al₂O₃, Ga₂O₃, Ga₂S₃, Ga₂Se₃, In₂O₃, In₂S₃, In₂Se₃, In₂Te₃, La₂O₃, La₂S₃, CeO₂, CeS₂, Pr₆O₁₁, Nd₂O₃, NdS₂, La₂O₃, Tl₂O, Sm₂O₃, SmS₂, Eu₂O₃, EuS₂, Bi₂O₃, Sb₂O₃, PoO₂, SeO₂, Cs₂O, Tb₄O₇, TbS₂, Dy₂O₃, Ho₂O₃, Er₂O₃, ErS₂, Tm₂O₃, Yb₂O₃, Lu₂O₃, CuInS₂, CuInSe₂, AgInS₂, AgInSe₂, Fe₂O₃, Fe₃O₄, FeS, FeS₂, Co₃S₄, CoSe, Co₃O₄, NiO, NiSe₂, NiSe, Ni₃Se₄, Gd₂O₃, BeO, TeO₂, Na₂O, BaO, K₂O, Ta₂O₅, Li₂O, Tc₂O₇, As₂O₃, B₂O₃, P₂O₅, P₂O₃, P₄O₇, P₄O₈, P₄O₉, P₂O₆, PO, or a mixture thereof.

According to one embodiment, examples of phosphide material 11 include but are not limited to: InP, Cd₃P₂, Zn₃P₂, AlP, GaP, TlP, or a mixture thereof.

According to one embodiment, examples of metalloid material 11 include but are not limited to: Si, B, Ge, As, Sb, Te, or a mixture thereof.

According to one embodiment, examples of metallic alloy material 11 include but are not limited to: Au—Pd, Au—Ag, Au—Cu, Pt—Pd, Pt—Ni, Cu—Ag, Cu—Sn, Ru—Pt, Rh—Pt, Cu—Pt, Ni—Au, Pt—Sn, Pd—V, Ir—Pt, Au—Pt, Pd—Ag, Cu—Zn, Cr—Ni, Fe—Co, Co—Ni, Fe—Ni or a mixture thereof.

According to one embodiment, the material 11 comprises organic molecules in small amounts of 0 mole %, 1 mole %, 5 mole %, 10 mole %, 15 mole %, 20 mole %, 25 mole %, 30 mole %, 35 mole %, 40 mole %, 45 mole %, 50 mole %, 55 mole %, 60 mole %, 65 mole %, 70 mole %, 75 mole %, 80 mole % relative to the majority element of said material 11.

According to one embodiment, the material 11 does not comprise inorganic polymers.

According to one embodiment, the material 11 does not comprise SiO₂.

According to one embodiment, the material 11 comprises at least 1% of SiO₂, 5% of SiO₂, 10% of SiO₂, 15% of SiO₂, 20% of SiO₂, 25% of SiO₂, 30% of SiO₂, 35% of SiO₂, 40% of SiO₂, 45% of SiO₂, 50% of SiO₂, 55% of SiO₂, 60% of SiO₂, 65% of SiO₂, 70% of SiO₂, 75% of SiO₂, 80% of SiO₂, 85% of SiO₂, 90% of SiO₂, 95% of SiO₂, or 100% SiO₂.

According to one embodiment, the material 11 comprises at least 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 95%, or 100% of SiO₂.

According to one embodiment, the material 11 comprises less than 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 95%, or 100% of SiO₂.

According to one embodiment, the material 11 comprises at least 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 95%, or 100% of SiO₂ precursors.

According to one embodiment, the material 11 comprises less than 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 95%, or 100% of SiO₂ precursors.

According to one embodiment, the material 11 comprises at least one precursor of SiO₂.

According to one embodiment, examples of precursors of SiO₂ include but are not limited to: tetramethyl orthosilicate, tetraethyl orthosilicate, polydiethyoxysilane, n-alkyltrimethoxylsilanes such as for example n-butyltrimethoxysilane, n-octyltrimethoxylsilane, n-dodecyltrimethoxysilane, n-octadecyltrimethoxysilane, 3-mercaptopropyltrimethoxysilane, 11-mercaptoundecyltrimethoxysilane, 3-aminopropyltrimethoxysilane, 11-aminoundecyltrimethoxysilane, 3-(2-(2-aminoethylamino)ethylamino)propyltrimethoxysilane, 3-(trimethoxysilyl)propyl methacrylate, 3-(aminopropyl)trimethoxysilane, or a mixture thereof.

According to one embodiment, the material 11 does not consist of pure SiO₂, i.e. 100% SiO₂.

According to one embodiment, the material 11 comprises at least 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 95%, or 100% of Al₂O₃.

According to one embodiment, the material 11 comprises less than 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 95%, or 100% of Al₂O₃.

According to one embodiment, the material 11 comprises at least 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 95%, or 100% of Al₂O₃ precursors.

According to one embodiment, the material 11 comprises less than 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 95%, or 100% of Al₂O₃ precursors.

According to one embodiment, the material 11 does not comprise TiO₂.

According to one embodiment, the material 11 does not consist of pure TiO₂, i.e. 100% TiO₂.

According to one embodiment, the material 11 does not comprise zeolite.

According to one embodiment, the material 11 does not consist of pure zeolite, i.e. 100% zeolite.

According to one embodiment, the material 11 does not comprise glass.

According to one embodiment, the material 11 does not comprise vitrified glass.

According to one embodiment, the inorganic polymer is a polymer not containing carbon.

According to one embodiment, the inorganic polymer is selected from polysilanes, polysiloxanes (or silicones), polythiazyles, polyaluminosilicates, polygermanes, polystannanes, polyborazylenes, polyphosphazenes, polydichlorophosphazenes, polysulfides, polysulfur and/or nitrides. According to one embodiment, the inorganic polymer is a liquid crystal polymer

According to one embodiment, the inorganic polymer is a natural or synthetic polymer.

According to one embodiment, the inorganic polymer is synthetized by inorganic reaction, radical polymerization, polycondensation, polyaddition, or ring opening polymerization (ROP).

According to one embodiment, the inorganic polymer is a homopolymer or a copolymer. According to one embodiment, the inorganic polymer is linear, branched, and/or cross-linked.

According to one embodiment, the inorganic polymer is amorphous, semi-crystalline or crystalline.

According to one embodiment, the inorganic polymer has an average molecular weight ranging from 2 000 g/mol to 5.10⁶ g/mol, preferably from 5 000 g/mol to 4.10⁶ g/mol; from 6 000 to 4.10⁶; from 7 000 to 4.10⁶; from 8 000 to 4.10⁶; from 9 000 to 4.10⁶; from 10 000 to 4.10⁶; from 15 000 to 4.10⁶; from 20 000 to 4.10⁶; from 25 000 to 4.10⁶; from 30 000 to 4.10⁶; from 35 000 to 4.10⁶; from 40 000 to 4.10⁶; from 45 000 to 4.10⁶; from 50 000 to 4.10⁶; from 55 000 to 4.10⁶; from 60 000 to 4.10⁶; from 65 000 to 4.10⁶; from 70 000 to 4.10⁶; from 75 000 to 4.10⁶; from 80 000 to 4.10⁶; from 85 000 to 4.10⁶; from 90 000 to 4.10⁶; from 95 000 to 4.10⁶; from 100 000 to 4.10⁶; from 200 000 to 4.10⁶; from 300 000 to 4.10⁶; from 400 000 to 4.10⁶; from 500 000 to 4.10⁶; from 600 000 to 4.10⁶; from 700 000 to 4.10⁶; from 800 000 to 4.10⁶; from 900 000 to 4.10⁶; from 1.10⁶ to 4.10⁶; from 2.10⁶ to 4.10⁶; from 3.10⁶ g/mol to 4.10⁶ g/mol.

According to one embodiment, the organic material refers to any element and/or material containing carbon, preferably any element and/or material containing at least one carbon-hydrogen bond.

According to one embodiment, the organic material may be natural or synthetic.

According to one embodiment, the organic material is a small organic compound or an organic polymer.

According to one embodiment, the organic polymer is selected from polyacrylates; polymethacrylates; polyacrylamides; polyamides; polyesters; polyethers ; polyoelfins; polysaccharides; polyurethanes (or polycarbamates), polystyrenes; polyacrylonitrile-butadiene-styrene (ABS); polycarbonate; poly(styrene acrylonitrile); vinyl polymers such as polyvinyl chloride; polyvinyl alcohol, polyvinyl acetate, polyvinylpyrrolidone, polyvinyl pyridine, polyvinylimidazole; poly(p-phenylene oxide); polysulfone; polyethersulfone; polyethylenimine; polyphenylsulfone; poly(acrylonitrile styrene acrylate); polyepoxides, polythiophenes, polypyrroles ; poly anilines ; poly aryletherketones ; polyfurans ; polyimides ; polyimidazoles ; polyetherimides ; polyketones ; polynucleotides; polystyrene sulfonates ; polyetherimines ; polyamic acid; or any combinations and/or derivatives and/or copolymers thereof.

According to one embodiment, the organic polymer is a polyacrylate, preferably selected from poly(methyl acrylate), poly(ethyl acrylate), poly(propyl acrylate), poly(butyl acrylate), poly(pentyl acrylate), and poly(hexyl acrylate).

According to one embodiment, the organic polymer is a polymethacrylate, preferably selected from poly(methyl methacrylate), poly(ethyl methacrylate), poly(propyl methacrylate), poly(butyl methacrylate), poly(pentyl methacrylate), and poly(hexyl methacrylate). According to one embodiment, the organic polymer is poly(methyl methacrylate) (PMMA).

According to one embodiment, the organic polymer is a polyacrylamide, preferably selected from poly(acrylamide); poly(methyl acrylamide), poly(dimethyl acrylamide), poly(ethyl acrylamide), poly(diethyl acrylamide), poly(propyl acrylamide), poly(isopropyl acrylamide); poly(butyl acrylamide); and poly(tert-butyl acrylamide).

According to one embodiment, the organic polymer is a polyester, preferably selected from poly(glycolic acid) (PGA), poly(lactic acid) (PLA), poly(caprolactone) (PCL), polyhydroxyalcanoate (PHA), polyhydroxybutyrate (PHB), polyethylene adipate, polybutylene succinate, poly(ethylene terephthalate), polybutylene terephthalate), poly(trimethylene terephthalate), polyarylate or any combination thereof.

According to one embodiment, the organic polymer is a polyether, preferably selected from aliphatic polyethers such as poly(glycol ether) or aromatic polyethers. According to one embodiment, the polyether is selected from poly(methylene oxide); poly(ethylene glycol)/poly(ethylene oxide), poly(propylene glycol) and poly(tetrahydrofuran).

According to one embodiment, the organic polymer is a polyolefin (or polyalkene), preferably selected from poly(ethylene), poly(propylene), poly(butadiene), poly(methylpentene), poly(butane) and poly(isobutylene).

According to one embodiment, the organic polymer is a polysaccharide selected from chitosan, dextran, hyaluronic acid, amylose, amylopectin, pullulan, heparin, chitin, cellulose, dextrin, starch, pectin, alginates, carrageenans, fucan, curdlan, xylan, polyguluronic acid, xanthan, arabinan, polymannuronic acid and their derivatives.

According to one embodiment, the organic polymer is a polyamide, preferably selected from polycaprolactame, poly auro amide, polyundecanamide, polytetramethylene adipamide, polyhexamethylene adipamide (also called nylon), polyhexamethylene nonanediamide, polyhexamethylene sebacamide, polyhexamethylene dodecanediamide; polydecamethylene sebacamide; Polyhexaméthylène isophtalamide; Polymétaxylylène adipamide; Polymétaphénylène isophtalamide; Polyparaphénylène téréphtalamide; polyphtalimides.

According to one embodiment, the organic polymer is a naturel or synthetic polymer.

According to one embodiment, the organic polymer is synthetized by organic reaction, radical polymerization, polycondensation, polyaddition, or ring opening polymerization (ROP).

According to one embodiment, the organic polymer is a homopolymer or a copolymer. According to one embodiment, the organic polymer is linear, branched, and/or cross-linked. According to one embodiment, the branched organic polymer is brush polymer (or also called comb polymer) or is a dendrimer.

According to one embodiment, the organic polymer is amorphous, semi-crystalline or crystalline.

According to one embodiment, the organic polymer is a thermoplastic polymer or an elastomer.

According to one embodiment, the organic polymer is not a polyelectrolyte.

According to one embodiment, the organic polymer is not a hydrophilic polymer.

According to one embodiment, the organic polymer has an average molecular weight ranging from 2 000 g/mol to 5.10⁶ g/mol, preferably from 5 000 g/mol to 4.10⁶ g/mol; from 6 000 to 4.10⁶; from 7 000 to 4.10⁶; from 8 000 to 4.10⁶; from 9 000 to 4.10⁶; from 10 000 to 4.10⁶; from 15 000 to 4.10⁶; from 20 000 to 4.10⁶; from 25 000 to 4.10⁶; from 30 000 to 4.10⁶; from 35 000 to 4.10⁶; from 40 000 to 4.10⁶; from 45 000 to 4.10⁶; from 50 000 to 4.10⁶; from 55 000 to 4.10⁶; from 60 000 to 4.10⁶; from 65 000 to 4.10⁶; from 70 000 to 4.10⁶; from 75 000 to 4.10⁶; from 80 000 to 4.10⁶; from 85 000 to 4.10⁶; from 90 000 to 4.10⁶; from 95 000 to 4.10⁶; from 100 000 to 4.10⁶; from 200 000 to 4.10⁶; from 300 000 to 4.10⁶; from 400 000 to 4.10⁶; from 500 000 to 4.10⁶; from 600 000 to 4.10⁶; from 700 000 to 4.10⁶; from 800 000 to 4.10⁶; from 900 000 to 4.10⁶; from 1.10⁶ to 4.10⁶; from 2.10⁶ to 4.10⁶; from 3.10⁶ g/mol to 4.10⁶ g/mol.

According to one embodiment, the organic material 11 is selected from polyacrylates; polymethacrylate; polyacrylamide; polyester; polyether; polyolefin (or polyalkene); polysaccharide; polyamide; or a mixture thereof; preferably the organic material 11 is an organic polymer.

According to one embodiment, the material 11 is a hybrid material comprising at least one inorganic constituent and at least one organic constituent. In this embodiment the inorganic constituent is an inorganic material as described hereabove and the organic constituent is an organic material as described hereabove.

According to one embodiment, the material is a hybrid material. In the present invention, “hybrid” refers to a material having at least one inorganic moiety and at least one organic moiety.

According to one embodiment, the hybrid material comprises an inorganic moiety and an organic moiety as defined above.

According to one preferred embodiment, the hybrid material comprises:
an inorganic moiety selected from metals, metal oxides, glasses, enamels, ceramics, stones, precious stones, pigments, cements and/or inorganic polymers; and
an organic moiety selected from a small organic compound or an organic polymer, said organic polymer being preferably selected from polyacrylates; polymethacrylates; polyacrylamides; polyamides; polyesters; polyethers; polyoelfins; polysaccharides; polyurethanes (or polycarbamates), polystyrenes; polyacrylonitrile-butadiene-styrene (ABS); polycarbonates; poly(styrene acrylonitrile); vinyl polymers such as polyvinyl chloride; polyvinyl alcohol, polyvinyl acetate, polyvinylpyrrolidone, polyvinyl pyridine, polyvinylimidazole; poly(p-phenylene oxide); polyacrylonitriles; polysulfones; polyethersulfones; polyethylenimines; polyphenylsulfones; poly(acrylonitrile styrene acrylate); polyepoxides, polythiophenes, polypyrroles; polyanilines; polyaryletherketones; polyfurans; polyimides; polyketones; polynucleotides, polystyrene sulfonates; polyetherimines; polyamic acid; or any combinations and/or derivatives and/or copolymers thereof.

According to one embodiment, the material 11 comprises additional heteroelements, wherein said additional heteroelements include but are not limited to: Cd, S, Se, Zn, In, Te, Hg, Sn, Cu, N, Ga, Sb, Tl, Mo, Pd, Ce, W, Co, Mn, Si, Ge, B, P, Al, As, Fe, Ti, Zr, Ni, Ca, Na, Ba, K, Mg, Pb, Ag, V, Be, Ir, Sc, Nb, Ta or a mixture thereof. In this embodiment, heteroelements can diffuse in the aggregate 1. They may form nanoclusters inside the aggregate 1. These elements can limit the degradation of the photoluminescence of said aggregate 1 and/or the particle 12, and/or drain away the heat if it is a good thermal conductor, and/or evacuate electrical charges.

According to one embodiment, the material 11 comprises additional heteroelements in small amounts of 0 mole %, 1 mole %, 5 mole %, 10 mole %, 15 mole %, 20 mole %, 25 mole %, 30 mole %, 35 mole %, 40 mole %, 45 mole %, 50 mole % relative to the majority element of said material 11.

According to one embodiment, the material 11 comprises Al₂O₃, SiO₂, MgO, ZnO, ZrO₂, TiO₂, IrO₂, SnO₂, BaO, BaSO₄, BeO, CaO, CeO₂, CuO, Cu₂O, DyO₃, Fe₂O₃, Fe₃O₄, GeO₂, HfO₂, Lu₂O₃, Nb₂O₅, Sc₂O₃, TaO₅, TeO₂, or Y₂O₃ additional nanoparticles. These additional nanoparticles can drain away the heat if it is a good thermal conductor, and/or evacuate electrical charges, and/or scatter an incident light.

According to one embodiment, the material 11 comprises said additional nanoparticles in small amounts at a level of at least 100 ppm, 200 ppm, 300 ppm, 400 ppm, 500 ppm, 600 ppm, 700 ppm, 800 ppm, 900 ppm, 1000 ppm, 1100 ppm, 1200 ppm, 1300 ppm, 1400 ppm, 1500 ppm, 1600 ppm, 1700 ppm, 1800 ppm, 1900 ppm, 2000 ppm, 2100 ppm, 2200 ppm, 2300 ppm, 2400 ppm, 2500 ppm, 2600 ppm, 2700 ppm, 2800 ppm, 2900 ppm, 3000 ppm, 3100 ppm, 3200 ppm, 3300 ppm, 3400 ppm, 3500 ppm, 3600 ppm, 3700 ppm, 3800 ppm, 3900 ppm, 4000 ppm, 4100 ppm, 4200 ppm, 4300 ppm, 4400 ppm, 4500 ppm, 4600 ppm, 4700 ppm, 4800 ppm, 4900 ppm, 5000 ppm, 5100 ppm, 5200 ppm, 5300 ppm, 5400 ppm, 5500 ppm, 5600 ppm, 5700 ppm, 5800 ppm, 5900 ppm, 6000 ppm, 6100 ppm, 6200 ppm, 6300 ppm, 6400 ppm, 6500 ppm, 6600 ppm, 6700 ppm, 6800 ppm, 6900 ppm, 7000 ppm, 7100 ppm, 7200 ppm, 7300 ppm, 7400 ppm, 7500 ppm, 7600 ppm, 7700 ppm, 7800 ppm, 7900 ppm, 8000 ppm, 8100 ppm, 8200 ppm, 8300 ppm, 8400 ppm, 8500 ppm, 8600 ppm, 8700 ppm, 8800 ppm, 8900 ppm, 9000 ppm, 9100 ppm, 9200 ppm, 9300 ppm, 9400 ppm, 9500 ppm, 9600 ppm, 9700 ppm, 9800 ppm, 9900 ppm, 10000 ppm, 10500 ppm, 11000 ppm, 11500 ppm, 12000 ppm, 12500 ppm, 13000 ppm, 13500 ppm, 14000 ppm, 14500 ppm, 15000 ppm, 15500 ppm, 16000 ppm, 16500 ppm, 17000 ppm, 17500 ppm, 18000 ppm, 18500 ppm, 19000 ppm, 19500 ppm, 20000 ppm, 30000 ppm, 40000 ppm, 50000 ppm, 60000 ppm, 70000 ppm, 80000 ppm, 90000 ppm, 100000 ppm, 110000 ppm, 120000 ppm, 130000 ppm, 140000 ppm, 150000 ppm, 160000 ppm, 170000 ppm, 180000 ppm, 190000 ppm, 200000 ppm, 210000 ppm, 220000 ppm, 230000 ppm, 240000 ppm, 250000 ppm, 260000 ppm, 270000 ppm, 280000 ppm, 290000 ppm, 300000 ppm, 310000 ppm, 320000 ppm, 330000 ppm, 340000 ppm, 350000 ppm, 360000 ppm, 370000 ppm, 380000 ppm, 390000 ppm, 400000 ppm, 410000 ppm, 420000 ppm, 430000 ppm, 440000 ppm, 450000 ppm, 460000 ppm, 470000 ppm, 480000 ppm, 490000 ppm, or 500 000 ppm in weight compared to the aggregate 1.

According to one embodiment, the material 11 is stable under acidic conditions, i.e. at pH inferior or equal to 7. In this embodiment, the material 11 is sufficiently robust to withstand acidic conditions, meaning that the properties of the aggregate 1 are preserved under said conditions.

According to one embodiment, the material 11 is stable under basic conditions, i.e. at pH superior to 7. In this embodiment, the material 11 is sufficiently robust to withstand basic conditions, meaning that the properties of the aggregate 1 are preserved under said conditions.

According to one embodiment, the material 11 is stable at pH 7. In this embodiment, the material 11 is sufficiently robust to withstand conditions with neutral pH, meaning that the properties of the aggregate 1 are preserved under said conditions.

According to one embodiment, the material 11 is physically and chemically stable under various conditions. In this embodiment, the material 11 is sufficiently robust to withstand the conditions to which the aggregate 1 will be subjected.

“Physically stable” refers to the stability of structure and physical properties such as for example mechanical properties, optical properties, magnetic properties; i.e. said structure and physical properties remain unchanged.

“Chemically stable” refers to the stability of chemical properties, surface chemistry, chemical composition; i.e. said chemical properties, surface chemistry, chemical composition remain unchanged.

“Withstand” means keeping physical and chemical properties unchanged.

According to one embodiment, the material 11 is physically and chemically stable at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C. for at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years. In this embodiment, the material 11 is sufficiently robust to withstand the conditions to which the aggregate 1 will be subjected.

According to one embodiment, the material 11 is physically and chemically stable under 0%, 10%, 20%, 30%, 40%, 50%, 55%, 60%, 65%, 70%, 75%, 80%, 85%, 90%, 95%, or 99% of humidity for at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years. In this embodiment, the material 11 is sufficiently robust to withstand the conditions to which the aggregate 1 will be subjected.

According to one embodiment, the material 11 is physically and chemically stable under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, for at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years. In this embodiment, the material 11 is sufficiently robust to withstand the conditions to which the aggregate 1 will be subjected.

According to one embodiment, the material 11 is physically and chemically stable at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C. and under 0%, 10%, 20%, 30%, 40%, 50%, 55%, 60%, 65%, 70%, 75%, 80%, 85%, 90%, 95%, or 99% of humidity for at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years. In this embodiment, the material 11 is sufficiently robust to withstand the conditions to which the aggregate 1 will be subjected.

According to one embodiment, the material 11 is physically and chemically stable under 0%, 10%, 20%, 30%, 40%, 50%, 55%, 60%, 65%, 70%, 75%, 80%, 85%, 90%, 95%, or 99% of humidity and under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment for at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years. In this embodiment, the material 11 is sufficiently robust to withstand the conditions to which the aggregate 1 will be subjected.

According to one embodiment, the material 11 is physically and chemically stable at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C. and under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment for at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

In this embodiment, the material 11 is sufficiently robust to withstand the conditions to which the aggregate 1 will be subjected.

According to one embodiment, the at least one particle 12 is selected from luminescent particles, plasmonic particles, magnetic particles, catalytic particles, pyro-electric particles, ferro-electric particles, light scattering particles, electrically insulating particles, electrically conductive particles, thermally conductive particles, thermally insulating particles, local high temperature heating particles, dielectric particles, piezoelectric particles.

According to one embodiment, the particle 12 is luminescent.

According to one embodiment, the particle 12 is fluorescent.

According to one embodiment, the particle 12 is phosphorescent.

According to one embodiment, the particle 12 is electroluminescent.

According to one embodiment, the particle 12 is chemiluminescent.

According to one embodiment, the particle 12 is triboluminescent.

According to one embodiment, the features of the light emission of particle 12 are sensible to external pressure variations. In this embodiment, “sensible” means that the features of the light emission can be modified by external pressure variations.

According to one embodiment, the wavelength emission peak of particle 12 is sensible to external pressure variations. In this embodiment, “sensible” means that the wavelength emission peak can be modified by external pressure variations, i.e. external pressure variations can induce a wavelength shift.

According to one embodiment, the FWHM of particle 12 is sensible to external pressure variations. In this embodiment, “sensible” means that the FWHM can be modified by external pressure variations, i.e. FWHM can be reduced or increased.

According to one embodiment, the PLQY of particle 12 is sensible to external pressure variations. In this embodiment, “sensible” means that the PLQY can be modified by external pressure variations, i.e. PLQY can be reduced or increased.

According to one embodiment, the features of the light emission of particle 12 are sensible to external temperature variations.

According to one embodiment, the wavelength emission peak of particle 12 is sensible to external temperature variations. In this embodiment, “sensible” means that the wavelength emission peak can be modified by external temperature variations, i.e. external temperature variations can induce a wavelength shift.

According to one embodiment, the FWHM of particle 12 is sensible to external temperature variations. In this embodiment, “sensible” means that the FWHM can be modified by external temperature variations, i.e. FWHM can be reduced or increased.

According to one embodiment, the PLQY of particle 12 is sensible to external temperature variations. In this embodiment, “sensible” means that the PLQY can be modified by external temperature variations, i.e. PLQY can be reduced or increased.

According to one embodiment, the features of the light emission of particle 12 are sensible to external variations of pH.

According to one embodiment, the wavelength emission peak of particle 12 is sensible to external variations of pH. In this embodiment, “sensible” means that the wavelength emission peak can be modified by external variations of pH, i.e. external variations of pH can induce a wavelength shift.

According to one embodiment, the FWHM of particle 12 is sensible to e external variations of pH. In this embodiment, “sensible” means that the FWHM can be modified by external variations of pH, i.e. FWHM can be reduced or increased.

According to one embodiment, the PLQY of particle 12 is sensible to external variations of pH. In this embodiment, “sensible” means that the PLQY can be modified by external variations of pH, i.e. PLQY can be reduced or increased.

According to one embodiment, the particle 12 exhibits an emission spectrum with at least one emission peak, wherein said emission peak has a maximum emission wavelength ranging from 400 nm to 50 um.

According to one embodiment, the particle 12 exhibits an emission spectrum with at least one emission peak, wherein said emission peak has a maximum emission wavelength ranging from 400 nm to 500 nm. In this embodiment, the particle 12 emits blue light.

According to one embodiment, the particle 12 exhibits an emission spectrum with at least one emission peak, wherein said emission peak has a maximum emission wavelength ranging from 500 nm to 560 nm, more preferably ranging from 515 nm to 545 nm. In this embodiment, the particle 12 emits green light.

According to one embodiment, the particle 12 exhibits an emission spectrum with at least one emission peak, wherein said emission peak has a maximum emission wavelength ranging from 560 nm to 590 nm. In this embodiment, the particle 12 emits yellow light.

According to one embodiment, the particle 12 exhibits an emission spectrum with at least one emission peak, wherein said emission peak has a maximum emission wavelength ranging from 590 nm to 750 nm, more preferably ranging from 610 nm to 650 nm. In this embodiment, the particle 12 emits red light.

According to one embodiment, the particle 12 exhibits an emission spectrum with at least one emission peak, wherein said emission peak has a maximum emission wavelength ranging from 750 nm to 50 um. In this embodiment, the particle 12 emits near infra-red, mid-infra-red, or infra-red light.

According to one embodiment, the particle 12 exhibits emission spectra with at least one emission peak having a full width half maximum lower than 90 nm, 80 nm, 70 nm, 60 nm, 50 nm, 40 nm, 30 nm, 25 nm, 20 nm, 15 nm, or 10 nm.

According to one embodiment, the particle 12 exhibits emission spectra with at least one emission peak having a full width half maximum strictly lower than 40 nm, 30 nm, 25 nm, 20 nm, 15 nm, or 10 nm.

According to one embodiment, the particle 12 exhibits emission spectra with at least one emission peak having a full width at quarter maximum lower than 90 nm, 80 nm, 70 nm, 60 nm, 50 nm, 40 nm, 30 nm, 25 nm, 20 nm, 15 nm, or 10 nm.

According to one embodiment, the particle 12 exhibits emission spectra with at least one emission peak having a full width at quarter maximum strictly lower than 40 nm, 30 nm, 25 nm, 20 nm, 15 nm, or 10 nm.

According to one embodiment, the particle 12 has a photoluminescence quantum yield (PLQY) of at least 5%, 10%, 15%, 20%, 25%, 30%, 35%, 40%, 45%, 50%, 55%, 60%, 65%, 70%, 75%, 80%, 85%, 90%, 95%, 99% or 100%.

According to one embodiment, the particle 12 absorbs the incident light with wavelength lower than 50 um, 40 um, 30 um, 20 um, 10 um, 1 um, 950 nm, 900 nm, 850 nm, 800 nm, 750 nm, 700 nm, 650 nm, 600 nm, 550 nm, 500 nm, 450 nm, 400 nm, 350 nm, 300 nm, 250 nm, or lower than 200 nm.

According to one embodiment, the particle 12 has an average fluorescence lifetime of at least 0.1 nanosecond, 0.2 nanosecond, 0.3 nanosecond, 0.4 nanosecond, 0.5 nanosecond, 0.6 nanosecond, 0.7 nanosecond, 0.8 nanosecond, 0.9 nanosecond, 1 nanosecond, 2 nanoseconds, 3 nanoseconds, 4 nanoseconds, 5 nanoseconds, 6 nanoseconds, 7 nanoseconds, 8 nanoseconds, 9 nanoseconds, 10 nanoseconds, 11 nanoseconds, 12 nanoseconds, 13 nanoseconds, 14 nanoseconds, 15 nanoseconds, 16 nanoseconds, 17 nanoseconds, 18 nanoseconds, 19 nanoseconds, 20 nanoseconds, 21 nanoseconds, 22 nanoseconds, 23 nanoseconds, 24 nanoseconds, 25 nanoseconds, 26 nanoseconds, 27 nanoseconds, 28 nanoseconds, 29 nanoseconds, 30 nanoseconds, 31 nanoseconds, 32 nanoseconds, 33 nanoseconds, 34 nanoseconds, 35 nanoseconds, 36 nanoseconds, 37 nanoseconds, 38 nanoseconds, 39 nanoseconds, 40 nanoseconds, 41 nanoseconds, 42 nanoseconds, 43 nanoseconds, 44 nanoseconds, 45 nanoseconds, 46 nanoseconds, 47 nanoseconds, 48 nanoseconds, 49 nanoseconds, 50 nanoseconds, 100 nanoseconds, 150 nanoseconds, 200 nanoseconds, 250 nanoseconds, 300 nanoseconds, 350 nanoseconds, 400 nanoseconds, 450 nanoseconds, 500 nanoseconds, 550 nanoseconds, 600 nanoseconds, 650 nanoseconds, 700 nanoseconds, 750 nanoseconds, 800 nanoseconds, 850 nanoseconds, 900 nanoseconds, 950 nanoseconds, or 1 μsecond.

In one embodiment, the particle 12 exhibits photoluminescence quantum yield (PQLY) decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light with an average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one preferred embodiment, the particle 12 exhibits photoluminescence quantum yield (PQLY) decrease of less than 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light or continuous light with an average peak pulse power or photon flux of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the particle 12 exhibits FCE decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light with an average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm ⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one preferred embodiment, the particle 12 exhibits FCE decrease of less than 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light or continuous light with an average peak pulse power or photon flux of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

According to one embodiment, the particle 12 is magnetic.

According to one embodiment, the particle 12 is ferromagnetic.

According to one embodiment, the particle 12 is paramagnetic.

According to one embodiment, the particle 12 is superparamagnetic.

According to one embodiment, the particle 12 is diamagnetic.

According to one embodiment, the particle 12 is plasmonic.

According to one embodiment, the particle 12 has catalytic properties.

According to one embodiment, the particle 12 has photovoltaic properties.

According to one embodiment, the particle 12 is piezo-electric.

According to one embodiment, the particle 12 is pyro-electric.

According to one embodiment, the particle 12 is ferro-electric.

According to one embodiment, the particle 12 is drug delivery featured.

According to one embodiment, the particle 12 is a light scatterer.

According to one embodiment, the particle 12 absorbs the incident light with wavelength lower than 50 um, 40 um, 30 um, 20 um, 10 um, 1 um, 950 nm, 900 nm, 850 nm, 800 nm, 750 nm, 700 nm, 650 nm, 600 nm, 550 nm, 500 nm, 450 nm, 400 nm, 350 nm, 300 nm, 250 nm, or lower than 200 nm.

According to one embodiment, the particle 12 is an electrical insulator.

According to one embodiment, the particle 12 is an electrical conductor. This embodiment is particularly advantageous for an application of the particle 12 in photovoltaics or LEDs.

According to one embodiment, the particle 12 has an electrical conductivity at standard conditions ranging from 1×10⁻²⁰ to 10⁷ S/m, preferably from 1×10⁻¹⁵ to 5 S/m, more preferably from 1×10⁻⁷ to 1 S/m.

According to one embodiment, the particle 12 has an electrical conductivity at standard conditions of at least 1×10⁻²⁰ S/m, 0.5×10⁻¹⁹ S/m, 1×10⁻¹⁹ S/m, 0.5×10⁻¹⁸ S/m, 1×10⁻¹⁸ S/m, 0.5×10⁻¹⁷ S/m, 1×10⁻¹⁷ S/m, 0.5×10⁻¹⁶ S/m, 1×10⁻¹⁶ S/m, 0.5×10⁻¹⁵ S/m, 1×10⁻¹⁵ S/m, 0.5×10⁻¹⁴ S/m, 1×10⁻¹⁴ S/m, 0.5×10⁻¹³ S/m, 1×10⁻¹³ S/m, 0.5×10⁻¹²S/m, 1×10⁻¹² S/m, 0.5×10⁻¹¹ S/m, 1×10⁻¹¹ S/m, 0.5×10⁻¹⁰ S/m, 1×10⁻¹⁰ S/m, 0.5×10⁻⁹ S/m, 1×10⁻⁹ S/m, 0.5×10⁻⁸ S/m, 1×10⁻⁸ S/m, 0.5×10⁻⁷ S/m, 1×10⁻⁷ S/m, 0.5×10⁻⁶ S/m, 1×10⁻⁶ S/m, 0.5×10⁻⁵ S/m, 1×10⁻⁵ S/m, 0.5×10⁻⁴ S/m, 1×10⁻⁴ S/m, 0.5×10⁻³ S/m, 1×10⁻³ S/m, 0.5×10⁻² S/m, 1×10⁻² S/m, 0.5×10⁻¹ S/m, 1×10⁻¹ S/m, 0.5 S/m, 1 S/m, 1.5 S/m, 2 S/m, 2.5 S/m, 3 S/m, 3.5 S/m, 4 S/m, 4.5 S/m, 5 S/m, 5.5 S/m, 6 S/m, 6.5 S/m, 7 S/m, 7.5 S/m, 8 S/m, 8.5 S/m, 9 S/m, 9.5 S/m, 10 S/m, 50 S/m, 10² S/m, 5×10² S/m, 10³ S/m, 5×10³ S/m, 10⁴ S/m, 5×10⁴ S/m, 10⁵ S/m, 5×10⁵ S/m, 10⁶ S/m, 5×10⁶ S/m, or 10⁷ S/m.

According to one embodiment, the electrical conductivity of the particle 12 may be measured for example with an impedance spectrometer.

According to one embodiment, the particle 12 is a thermal insulator.

According to one embodiment, the particle 12 is a thermal conductor. In this embodiment, the particle 12 is capable of draining away the heat from the environment.

According to one embodiment, the particle 12 has a thermal conductivity at standard conditions ranging from 0.1 to 450 W/(m·K), preferably from 1 to 200 W/(m·K), more preferably from 10 to 150 W/(m·K).

According to one embodiment, the particle 12 has a thermal conductivity at standard conditions of at least 0.1 W/(m·K), 0.2 W/(m·K), 0.3 W/(m·K), 0.4 W/(m·K), 0.5 W/(m·K), 0.6 W/(m·K), 0.7 W/(m·K), 0.8 W/(m·K), 0.9 W/(m·K), 1 W/(m·K), 1.1 W/(m·K), 1.2 W/(m·K), 1.3 W/(m·K), 1.4 W/(m·K), 1.5 W/(m·K), 1.6 W/(m·K), 1.7 W/(m·K), 1.8 W/(m·K), 1.9 W/(m·K), 2 W/(m·K), 2.1 W/(m·K), 2.2 W/(m·K), 2.3 W/(m·K), 2.4 W/(m·K), 2.5 W/(m·K), 2.6 W/(m·K), 2.7 W/(m·K), 2.8 W/(m·K), 2.9 W/(m·K), 3 W/(m·K), 3.1 W/(m·K), 3.2 W/(m·K), 3.3 W/(m·K), 3.4 W/(m·K), 3.5 W/(m·K), 3.6 W/(m·K), 3.7 W/(m·K), 3.8 W/(m·K), 3.9 W/(m·K), 4 W/(m·K), 4.1 W/(m·K), 4.2 W/(m·K), 4.3 W/(m·K), 4.4 W/(m·K), 4.5 W/(m·K), 4.6 W/(m·K), 4.7 W/(m·K), 4.8 W/(m·K), 4.9 W/(m·K), 5 W/(m·K), 5.1 W/(m·K), 5.2 W/(m·K), 5.3 W/(m·K), 5.4 W/(m·K), 5.5 W/(m·K), 5.6 W/(m·K), 5.7 W/(m·K), 5.8 W/(m·K), 5.9 W/(m·K), 6 W/(m·K), 6.1 W/(m·K), 6.2 W/(m·K), 6.3 W/(m·K), 6.4 W/(m·K), 6.5 W/(m·K), 6.6 W/(m·K), 6.7 W/(m·K), 6.8 W/(m·K), 6.9 W/(m·K), 7 W/(m·K), 7.1 W/(m·K), 7.2 W/(m·K), 7.3 W/(m·K), 7.4 W/(m·K), 7.5 W/(m·K), 7.6 W/(m·K), 7.7 W/(m·K), 7.8 W/(m·K), 7.9 W/(m·K), 8 W/(m·K), 8.1 W/(m·K), 8.2 W/(m·K), 8.3 W/(m·K), 8.4 W/(m·K), 8.5 W/(m·K), 8.6 W/(m·K), 8.7 W/(m·K), 8.8 W/(m·K), 8.9 W/(m·K), 9 W/(m·K), 9.1 W/(m·K), 9.2 W/(m·K), 9.3 W/(m·K), 9.4 W/(m·K), 9.5 W/(m·K), 9.6 W/(m·K), 9.7 W/(m·K), 9.8 W/(m·K), 9.9 W/(m·K), 10 W/(m·K), 10.1 W/(m·K), 10.2 W/(m·K), 10.3 W/(m·K), 10.4 W/(m·K), 10.5 W/(m·K), 10.6 W/(m·K), 10.7 W/(m·K), 10.8 W/(m·K), 10.9 W/(m·K), 11 W/(m·K), 11.1 W/(m·K), 11.2 W/(m·K), 11.3 W/(m·K), 11.4 W/(m·K), 11.5 W/(m·K), 11.6 W/(m·K), 11.7 W/(m·K), 11.8 W/(m·K), 11.9 W/(m·K), 12 W/(m·K), 12.1 W/(m·K), 12.2 W/(m·K), 12.3 W/(m·K), 12.4 W/(m·K), 12.5 W/(m·K), 12.6 W/(m·K), 12.7 W/(m·K), 12.8 W/(m·K), 12.9 W/(m·K), 13 W/(m·K), 13.1 W/(m·K), 13.2 W/(m·K), 13.3 W/(m·K), 13.4 W/(m·K), 13.5 W/(m·K), 13.6 W/(m·K), 13.7 W/(m·K), 13.8 W/(m·K), 13.9 W/(m·K), 14 W/(m·K), 14.1 W/(m·K), 14.2 W/(m·K), 14.3 W/(m·K), 14.4 W/(m·K), 14.5 W/(m·K), 14.6 W/(m·K), 14.7 W/(m·K), 14.8 W/(m·K), 14.9 W/(m·K), 15 W/(m·K), 15.1 W/(m·K), 15.2 W/(m·K), 15.3 W/(m·K), 15.4 W/(m·K), 15.5 W/(m·K), 15.6 W/(m·K), 15.7 W/(m·K), 15.8 W/(m·K), 15.9 W/(m·K), 16 W/(m·K), 16.1 W/(m·K), 16.2 W/(m·K), 16.3 W/(m·K), 16.4 W/(m·K), 16.5 W/(m·K), 16.6 W/(m·K), 16.7 W/(m·K), 16.8 W/(m·K), 16.9 W/(m·K), 17 W/(m·K), 17.1 W/(m·K), 17.2 W/(m·K), 17.3 W/(m·K), 17.4 W/(m·K), 17.5 W/(m·K), 17.6 W/(m·K), 17.7 W/(m·K), 17.8 W/(m·K), 17.9 W/(m·K), 18 W/(m·K), 18.1 W/(m·K), 18.2 W/(m·K), 18.3 W/(m·K), 18.4 W/(m·K), 18.5 W/(m·K), 18.6 W/(m·K), 18.7 W/(m·K), 18.8 W/(m·K), 18.9 W/(m·K), 19 W/(m·K), 19.1 W/(m·K), 19.2 W/(m·K), 19.3 W/(m·K), 19.4 W/(m·K), 19.5 W/(m·K), 19.6 W/(m·K), 19.7 W/(m·K), 19.8 W/(m·K), 19.9 W/(m·K), 20 W/(m·K), 20.1 W/(m·K), 20.2 W/(m·K), 20.3 W/(m·K), 20.4 W/(m·K), 20.5 W/(m·K), 20.6 W/(m·K), 20.7 W/(m·K), 20.8 W/(m·K), 20.9 W/(m·K), 21 W/(m·K), 21.1 W/(m·K), 21.2 W/(m·K), 21.3 W/(m·K), 21.4 W/(m·K), 21.5 W/(m·K), 21.6 W/(m·K), 21.7 W/(m·K), 21.8 W/(m·K), 21.9 W/(m·K), 22 W/(m·K), 22.1 W/(m·K), 22.2 W/(m·K), 22.3 W/(m·K), 22.4 W/(m·K), 22.5 W/(m·K), 22.6 W/(m·K), 22.7 W/(m·K), 22.8 W/(m·K), 22.9 W/(m·K), 23 W/(m·K), 23.1 W/(m·K), 23.2 W/(m·K), 23.3 W/(m·K), 23.4 W/(m·K), 23.5 W/(m·K), 23.6 W/(m·K), 23.7 W/(m·K), 23.8 W/(m·K), 23.9 W/(m·K), 24 W/(m·K), 24.1 W/(m·K), 24.2 W/(m·K), 24.3 W/(m·K), 24.4 W/(m·K), 24.5 W/(m·K), 24.6 W/(m·K), 24.7 W/(m·K), 24.8 W/(m·K), 24.9 W/(m·K), 25 W/(m·K), 30 W/(m·K), 40 W/(m·K), 50 W/(m·K), 60 W/(m·K), 70 W/(m·K), 80 W/(m·K), 90 W/(m·K), 100 W/(m·K), 110 W/(m·K), 120 W/(m·K), 130 W/(m·K), 140 W/(m·K), 150 W/(m·K), 160 W/(m·K), 170 W/(m·K), 180 W/(m·K), 190 W/(m·K), 200 W/(m·K), 210 W/(m·K), 220 W/(m·K), 230 W/(m·K), 240 W/(m·K), 250 W/(m·K), 260 W/(m·K), 270 W/(m·K), 280 W/(m·K), 290 W/(m·K), 300 W/(m·K), 310 W/(m·K), 320 W/(m·K), 330 W/(m·K), 340 W/(m·K), 350 W/(m·K), 360 W/(m·K), 370 W/(m·K), 380 W/(m·K), 390 W/(m·K), 400 W/(m·K), 410 W/(m·K), 420 W/(m·K), 430 W/(m·K), 440 W/(m·K), or 450 W/(m·K).

According to one embodiment, the thermal conductivity of the particle 12 may be measured for example by steady-state methods or transient methods.

According to one embodiment, the particle 12 is a local high temperature heating system.

According to one embodiment, the particle 12 is optically transparent, i.e. the particle 12 is transparent at wavelengths between 200 nm and 50 μm, between 200 nm and 10 μm, between 200 nm and 2500 nm, between 200 nm and 2000 nm, between 200 nm and 1500 nm, between 200 nm and 1000 nm, between 200 nm and 800 nm, between 400 nm and 700 nm, between 400 nm and 600 nm, or between 400 nm and 470 nm.

According to one embodiment, the particle 12 exhibits a shelf life of at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

According to one embodiment, the particle 12 is a nanoparticle.

According to one embodiment, the particle 12 is an aggregate as disclosed hereabove.

According to one embodiment, the particle 12 is a colloidal particle.

According to one embodiment, the particle 12 is a colloidal nanoparticle.

According to one embodiment, the particle 12 is amorphous.

According to one embodiment, the particle 12 is crystalline.

According to one embodiment, the particle 12 is totally crystalline.

According to one embodiment, the particle 12 is partially crystalline.

According to one embodiment, the particle 12 is monocrystalline.

According to one embodiment, the particle 12 is polycrystalline. In this embodiment, the particle 12 comprises at least one grain boundary.

According to one embodiment, the particle 12 is porous.

According to one embodiment, the particle 12 is considered porous when the quantity adsorbed by the particle 12 determined by adsorption-desorption of nitrogen in the Brunauer-Emmett-Teller (BET) theory is more than 20 cm³/g, 15 cm³/g, 10 cm³/g, 5 cm³/g at a nitrogen pressure of 650 mmHg, preferably 700 mmHg

According to one embodiment, the organization of the porosity of the particle 12 can be hexagonal, vermicular or cubic.

According to one embodiment, the organized porosity of the particle 12 has a pore size of at least 1 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, or 50 nm.

According to one embodiment, the particle 12 is not porous.

According to one embodiment, the particle 12 does not comprise pores or cavities.

According to one embodiment, the particle 12 is considered non-porous when the quantity adsorbed by the said particle 12 determined by adsorption-desorption of nitrogen in the Brunauer-Emmett-Teller (BET) theory is less than 20 cm³/g, 15 cm³/g, 10 cm³/g, 5 cm³/g at a nitrogen pressure of 650 mmHg, preferably 700 mmHg

According to one embodiment, the particle 12 is permeable.

According to one embodiment, the permeable particle 12 has an intrinsic permeability to fluids higher or equal to 10⁻¹¹ cm², 10⁻¹⁰ cm², 10⁻⁹ cm², 10⁻⁸ cm², 10⁻⁷ cm², 10⁻⁶ cm², 10⁻⁵ cm², 10⁻⁴ cm², or 10⁻³ cm².

According to one embodiment, the particle 12 is impermeable to outer molecular species, gas or liquid. In this embodiment, outer molecular species, gas or liquid refer to molecular species, gas or liquid from the outside of said particle 12.

According to one embodiment, the impermeable particle 12 has an intrinsic permeability to fluids less or equal to 10⁻¹¹ cm², 10⁻¹² cm², 10⁻¹³ cm², 10⁻¹⁴ cm², or 10⁻¹⁵ cm².

According to one embodiment, the particle 12 has an oxygen transmission rate ranging from 10⁻⁷ to 10 cm³.m⁻².day⁻¹, preferably from 10⁻⁷ to 1 cm³.m⁻².day⁻¹, more preferably from 10⁻⁷ to 10⁻¹ cm³.m⁻².day⁻¹, even more preferably from 10⁻⁷ to 10⁻⁴ cm³.m⁻².day⁻¹ at room temperature.

According to one embodiment, the particle 12 has a water vapor transmission rate ranging from 10⁻⁷ to 10 g·m⁻².day⁻¹, preferably from 10⁻⁷ to 1 g·m⁻².day⁻¹, more preferably from 10⁻⁷ to 10^{—1} g·m⁻².day⁻¹, even more preferably from 10⁻⁷ to 10⁻⁴ g·m⁻².day⁻¹ at room temperature. A water vapor transmission rate of 10⁻⁶ g·m⁻².day⁻¹ is particularly adequate for a use on LED.

According to one embodiment, the particle 12 is an electrically charged particle.

According to one embodiment, the particle 12 is not an electrically charged particle.

According to one embodiment, the particle 12 is not a positively charged particle.

According to one embodiment, the particle 12 is not a negatively charged particle.

According to one embodiment, the particle 12 is surfactant-free.

According to one embodiment, the particle 12 is not surfactant-free.

According to one embodiment, the ligands attached to the surface of a particle 12 is in contact with the material 11. In this embodiment, said particle 12 is linked to the material 11 and the electrical charges from said particle 12 can be evacuated. This prevents reactions at the surface of the particle 12 that can be due to electrical charges.

According to one embodiment, the particle 12 is hydrophobic.

According to one embodiment, the particle 12 is hydrophilic.

According to one embodiment, the particle 12 is dispersible in aqueous solvents, organic solvents and/or mixture thereof.

According to one embodiment, the particle 12 is dispersible in the liquid vehicle of an ink.

According to one embodiment, the particle 12 has a size above 20 nm.

According to one embodiment, the particle 12 has a size of at least 0.5 nm, 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 55 nm, 60 nm, 65 nm, 70 nm, 75 nm, 80 nm, 85 nm, 90 nm, 95 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80.5 μm, 81 μm, 81.5 μm, 82 μm, 82.5 μm, 83 μm, 83.5 μm, 84 μm, 84.5 μm, 85 μm, 85.5 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm or 1 mm.

According to one embodiment, a statistical set of particles 12 has an average size of at least 0.5 nm, 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 55 nm, 60 nm, 65 nm, 70 nm, 75 nm, 80 nm, 85 nm, 90 nm, 95 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μμm, 5 μm, 5.5 μm, 6 μm, 6.5 μm, 7 μm, 7.5 μm, 8 μm, 8.5 μm, 9 μm, 9.5 μm, 10 μm, 10.5 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm

According to one embodiment, the particle 12 has a largest dimension of at least 0.5 nm, 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 55 nm, 60 nm, 65 nm, 70 nm, 75 nm, 80 nm, 85 nm, 90 nm, 95 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm or 1 mm.

According to one embodiment, the particle 12 has a smallest dimension of at least 0.5 nm, 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 55 nm, 60 nm, 65 nm, 70 nm, 75 nm, 80 nm, 85 nm, 90 nm, 95 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17.5 μm, 18 μm, 18.5 μm, 19 μm, 19.5 μm, 20 μm, 20.5 μm, 21 μm, 21.5 μm, 22 μm, 22.5 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51.5 μm, 52 μm, 52.5 μm, 53 μm, 53.5 μm, 54 μm, 54.5 μm, 55 μm, 55.5 μm, 56 μm, 56.5 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68.5 μm, 69 μm, 69.5 μm, 70 μm, 70.5 μm, 71 μm, 71.5 μm, 72 μm, 72.5 μm, 73 μm, 73.5 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm or 1 mm.

According to one embodiment, the smallest dimension of the particle 12 smaller than the largest dimension of said particle 12 by a factor (aspect ratio) of at least 1.5; of at least 2; at least 2.5; at least 3; at least 3.5; at least 4; at least 4.5; at least 5; at least 5.5; at least 6; at least 6.5; at least 7; at least 7.5; at least 8; at least 8.5; at least 9; at least 9.5; at least 10; at least 10.5; at least 11; at least 11.5; at least 12; at least 12.5; at least 13; at least 13.5; at least 14; at least 14.5; at least 15; at least 15.5; at least 16; at least 16.5; at least 17; at least 17.5; at least 18; at least 18.5; at least 19; at least 19.5; at least 20; at least 25; at least 30; at least 35; at least 40; at least 45; at least 50; at least 55; at least 60; at least 65; at least 70; at least 75; at least 80; at least 85; at least 90; at least 95; at least 100; at least 150; at least 200; at least 250; at least 300; at least 350; at least 400; at least 450; at least 500; at least 550; at least 600; at least 650; at least 700; at least 750; at least 800; at least 850; at least 900; at least 950; or at least 1000.

According to one embodiment, the particle 12 has a smallest curvature of at least 200 μm⁻¹, 100 μm⁻¹, 66.6 μm⁻¹, 50 μm⁻¹, 33.3 μm⁻¹, 28.6 μm⁻¹, 25 μm⁻¹, 20 μm⁻¹, 18.2 μm⁻¹, 16.7 μm⁻¹, 15.4 μm⁻¹, 14.3 μm⁻¹, 13.3 μm⁻¹, 12.5 μm⁻¹, 11.8 μm⁻¹, 11.1 μm⁻¹, 10.5 μm⁻¹, 10 μm⁻¹, 9.5 μm⁻¹, 9.1 μm⁻¹, 8.7 μm⁻¹, 8.3 μm⁻¹, 8 μm⁻¹, 7.7 μm⁻¹, 7.4 μm⁻¹, 7.1 μm⁻¹, 6.9 μm⁻¹, 6.7 μm⁻¹, 5.7 μm⁻¹, 5 μm⁻¹, 4.4 μm⁻¹, 4 μm⁻¹, 3.6 μm⁻¹, 3.3 μm⁻¹, 3.1 μm⁻¹, 2.9 μm⁻¹, 2.7 μm⁻¹, 2.5 μm⁻¹, 1.3333 μm⁻¹, 0.8 μm⁻¹, 0.6666 μm⁻¹, 0.5714 μm⁻¹, 0.5 μm⁻¹, 0.4444 μm⁻¹, 0.4 μm⁻¹, 0.3636 μm⁻¹, 0.3333 μm⁻¹, 0.3080 μm⁻¹, 0.2857 μm⁻¹, 0.2667 μm⁻¹, 0.25 μm⁻¹, 0.2353 μm⁻¹, 0.2222 μm⁻¹, 0.2105 μm⁻¹, 0.2 μm⁻¹, 0.1905 μm⁻¹, 0.1818 μm⁻¹, 0.1739 μm⁻¹, 0.1667 μm⁻¹, 0.16 μm⁻¹, 0.1538 μm⁻¹, 0.1481 μm⁻¹, 0.1429 μm⁻¹, 0.1379 μm⁻¹, 0.1333 μm⁻¹, 0.1290 μm⁻¹, 0.125 μm⁻¹, 0.1212 μm⁻¹, 0.1176 μm⁻¹, 0.1176 μm⁻¹, 0.1143 μm⁻¹, 0.1111 μm⁻¹, 0.1881 μm⁻¹, 0.1053 μm⁻¹, 0.1026 μm⁻¹, 0.1 μm⁻¹, 0.0976 μm⁻¹, 0.9524 μm⁻¹, 0.0930 μm⁻¹, 0.0909 μm⁻¹, 0.0889 μm⁻¹, 0.870 μm⁻¹, 0.0851 μm⁻¹, 0.0833 μm⁻¹, 0.0816 μm⁻¹, 0.08 μm⁻¹, 0.0784 μm⁻¹, 0.0769 μm⁻¹, 0.0755 μm⁻¹, 0.0741 μm⁻¹, 0.0727 μm⁻¹, 0.0714 μm⁻¹, 0.0702 μm⁻¹, 0.0690 μm⁻¹, 0.0678 μm⁻¹, 0.0667 μm⁻¹, 0.0656 μm⁻¹, 0.0645 μm⁻¹, 0.0635 μm⁻¹, 0.0625 μm⁻¹, 0.0615 μm⁻¹, 0.0606 μm⁻¹, 0.0597 μm⁻¹, 0.0588 μm⁻¹, 0.0580 μm⁻¹, 0.0571 μm⁻¹, 0.0563 μm⁻¹, 0.0556 μm⁻¹, 0.0548 μm⁻¹, 0.0541 μm⁻¹, 0.0533 μm⁻¹, 0.0526 μm⁻¹, 0.0519 μm⁻¹, 0.0513 μm⁻¹, 0.0506 μm⁻¹, 0.05 μm⁻¹, 0.0494 μm⁻¹, 0.0488 μm⁻¹, 0.0482 μm⁻¹, 0.0476 μm⁻¹, 0.0471 μm⁻¹, 0.0465 μm⁻¹, 0.0460 μm⁻¹, 0.0455 μm⁻¹, 0.0450 μm⁻¹, 0.0444 μm⁻¹, 0.0440 μm⁻¹, 0.0435 μm⁻¹, 0.0430 μm⁻¹, 0.0426 μm⁻¹, 0.0421 μm⁻¹, 0.0417 μm⁻¹, 0.0412 μm⁻¹, 0.0408 μm⁻¹, 0.0404 μm⁻¹, 0.04 μm⁻¹, 0.0396 μm⁻¹, 0.0392 μm⁻¹, 0.0388 μm⁻¹, 0.0385 μm⁻¹; 0.0381 μm⁻¹, 0.0377 μm⁻¹, 0.0374 μm⁻¹, 0.037 μm⁻¹, 0.0367 μm⁻¹, 0.0364 μm⁻¹, 0.0360 μm⁻¹, 0.0357 μm⁻¹, 0.0354 μm⁻¹, 0.0351 μm⁻¹, 0.0348 μm⁻¹, 0.0345 μm⁻¹, 0.0342 μm⁻¹, 0.0339 μm⁻¹, 0.0336 μm⁻¹, 0.0333 μm⁻¹, 0.0331 μm⁻¹, 0.0328 μm⁻¹, 0.0325 μm⁻¹, 0.0323 μm⁻¹, 0.032 μm⁻¹, 0.0317 μm⁻¹, 0.0315 μm⁻¹, 0.0312 μm⁻¹, 0.031 μm⁻¹, 0.0308 μm⁻¹, 0.0305 μm⁻¹, 0.0303 μm⁻¹, 0.0301 μm⁻¹, 0.03 μm⁻¹, 0.0299 μm⁻¹, 0.0296 μm⁻¹, 0.0294 μm⁻¹, 0.0292 μm⁻¹, 0.029 μm⁻¹, 0.0288 μm⁻¹, 0.0286 μm⁻¹, 0.0284 μm⁻¹, 0.0282 μm⁻¹, 0.028 μm⁻¹, 0.0278 μm⁻¹, 0.0276 μm⁻¹, 0.0274 μm⁻¹, 0.0272 μm⁻¹; 0.0270 μm⁻¹, 0.0268 μm⁻¹, 0.02667 μm⁻¹, 0.0265 μm⁻¹, 0.0263 μm⁻¹, 0.0261 μm⁻¹, 0.026 μm⁻¹, 0.0258 μm⁻¹, 0.0256 μm⁻¹, 0.0255 μm⁻¹, 0.0253 μm⁻¹, 0.0252 μm⁻¹, 0.025 μm⁻¹, 0.0248 μm⁻¹, 0.0247 μm⁻¹, 0.0245 μm⁻¹, 0.0244 μm⁻¹, 0.0242 μm⁻¹, 0.0241 μm⁻¹, 0.024 μm⁻¹, 0.0238 μm⁻¹, 0.0237 μm⁻¹, 0.0235 μm⁻¹, 0.0234 μm⁻¹, 0.0233 μm⁻¹, 0.231 μm⁻¹, 0.023 μm⁻¹, 0.0229 μm⁻¹, 0.0227 μm⁻¹, 0.0226 μm⁻¹, 0.0225 μm⁻¹, 0.0223 μm⁻¹, 0.0222 μm⁻¹, 0.0221 μm⁻¹, 0.022 μm⁻¹, 0.0219 μm⁻¹, 0.0217 μm⁻¹, 0.0216 μm⁻¹, 0.0215 μm⁻¹, 0.0214 μm⁻¹, 0.0213 μm⁻¹, 0.0212 μm⁻¹, 0.0211 μm⁻¹, 0.021 μm⁻¹, 0.0209 μm⁻¹, 0.0208 μm⁻¹, 0.0207 μm⁻¹, 0.0206 μm⁻¹, 0.0205 μm⁻¹, 0.0204 μm⁻¹, 0.0203 μm⁻¹, 0.0202 μm⁻¹, 0.0201 μm⁻¹, 0.02 μm⁻¹, or 0.002 μm⁻¹.

According to one embodiment, the particle 12 has a largest curvature of at least 200 μm⁻¹, 100 μm ⁻¹, 66.6 μm⁻¹, 50 μm⁻¹, 33.3 μm⁻¹, 28.6 μm⁻¹, 25 μm⁻¹, 20 μm⁻¹, 18.2 μm⁻¹, 16.7 μm⁻¹, 15.4 μm⁻¹, 14.3 μm⁻¹, 13.3 μm⁻¹, 12.5 μm⁻¹, 11.8 μm⁻¹, 11.1 μm⁻¹, 10.5 μm⁻¹, 10 μm⁻¹, 9.5 μm⁻¹, 9.1 μm⁻¹, 8.7 μm⁻¹, 8.3 μm⁻¹, 8 μm⁻¹, 7.7 μm⁻¹, 7.4 μm⁻¹, 7.1 μm⁻¹, 6.9 μm⁻¹, 6.7 μm⁻¹, 5.7 μm¹, 5 μm⁻¹, 4.4 μm⁻¹, 4 μm⁻¹, 3.6 μm⁻¹, 3.3 μm⁻¹, 3.1 μm⁻¹, 2.9 μm⁻¹, 2.7 μm⁻¹, 2.5 μm⁻¹, 2.4 μm⁻¹, 2.2 μm⁻¹, 2.1 μm⁻¹, 2 μm⁻¹, 1.3333 μm⁻¹, 0.8 μm⁻¹, 0.6666 μm⁻¹, 0.5714 μm⁻¹, 0.5 μm⁻¹, 0.4444 μm⁻¹, 0.4 μm⁻¹, 0.3636 μm⁻¹, 0.3333 μm⁻¹, 0.3080 μm⁻¹, 0.2857 82 m⁻¹, 0.2667 μm⁻¹, 0.25 μm⁻¹, 0.2353 μm⁻¹, 0.2222 μm⁻¹, 0.2105 μm⁻¹, 0.2 μm⁻¹, 0.1905 μm⁻¹, 0.1818 μm⁻¹, 0.1739 μm⁻¹, 0.1667 μm⁻¹, 0.16 μm⁻¹, 0.1538 μm⁻¹, 0.1481 μm⁻¹, 0.1429 μm⁻¹, 0.1379 μm⁻¹, 0.1333 μm⁻¹, 0.1290 μm⁻¹, 0.125 μm⁻¹, 0.1212 μm⁻¹, 0.1176 μm⁻¹, 0.1176 μm⁻¹, 0.1143 μm⁻¹, 0.1111 μ⁻¹, 0.1881 μm⁻¹, 0.1053 μm⁻¹, 0.1026 μm⁻¹, 0.1 μm⁻¹, 0.0976 μm⁻¹, 0.9524 μm⁻¹, 0.0930 μm⁻¹, 0.0909 μm⁻¹, 0.0889 μm⁻¹, 0.870 μm⁻¹, 0.0851 μm⁻¹, 0.0833 μm⁻¹, 0.0816 μm⁻¹, 0.08 μm⁻¹, 0.0784 μm⁻¹, 0.0769 μm⁻¹, 0.0755 μm⁻¹, 0.0741 μm⁻¹, 0.0727 μm⁻¹, 0.0714 μm⁻¹, 0.0702 μm⁻¹, 0.0690 μm⁻¹, 0.0678 μm^{'1}, 0.0667 μm⁻¹, 0.0656 μm⁻¹, 0.0645 μm⁻¹, 0.0635 μm⁻¹, 0.0625 μm⁻¹, 0.0615 μm⁻¹, 0.0606 μm⁻¹, 0.0597 μm⁻¹, 0.0588 μm⁻¹, 0.0580 μm⁻¹, 0.0571 μm⁻¹, 0.0563 μm⁻¹, 0.0556 μm⁻¹, 0.0548 μm⁻¹, 0.0541 μm⁻¹, 0.0533 μm⁻¹, 0.0526 μm⁻¹, 0.0519 μm⁻¹, 0.0513 μm⁻¹, 0.0506 μm⁻¹, 0.05 μm⁻¹, 0.0494 μm⁻¹, 0.0488 μm⁻¹, 0.0482 μm⁻¹, 0.0476 μm⁻¹, 0.0471 μm⁻¹, 0.0465 μm⁻¹, 0.0460 μm⁻¹, 0.0455 μm^{31 1}, 0.0450 μm⁻¹, 0.0444 μm⁻¹, 0.0440 μm⁻¹, 0.0435 μm⁻¹, 0.0430 μm⁻¹, 0.0426 μm⁻¹, 0.0421 μm⁻¹, 0.0417 μm⁻¹, 0.0412 μm⁻¹, 0.0408 μm⁻¹, 0.0404 μm⁻¹, 0.04 μm⁻¹, 0.0396 μm⁻¹, 0.0392 μm⁻¹, 0.0388 μm⁻¹, 0.0385 μm⁻¹; 0.0381 μm⁻¹, 0.0377 μm⁻¹, 0.0374 μm⁻¹, 0.037 μm⁻¹, 0.0367 μm⁻¹, 0.0364 μm⁻¹, 0.0360 μm⁻¹, 0.0357 μm⁻¹, 0.0354 μm⁻¹, 0.0351 μm⁻¹, 0.0348 μm⁻¹, 0.0345 μm⁻¹, 0.0342 μm⁻¹, 0.0339 μm⁻¹, 0.0336 μm⁻¹, 0.0333 μm⁻¹, 0.0331 μm⁻¹, 0.0328 μm⁻¹, 0.0325 μm⁻¹, 0.0323 μm⁻¹, 0.032 μm⁻¹, 0.0317 μm⁻¹, 0.0315 μm⁻¹, 0.0312 μm⁻¹, 0.031 μm⁻¹, 0.0308 μm⁻¹, 0.0305 μm⁻¹, 0.0303 μm⁻¹, 0.0301 μm⁻¹, 0.03 μm⁻¹, 0.0299 μm⁻¹, 0.0296 μm⁻¹, 0.0294 μm⁻¹, 0.0292 μm⁻¹, 0.029 μm⁻¹, 0.0288 μm⁻¹, 0.0286 μm⁻¹, 0.0284 μm⁻¹, 0.0282 μm⁻¹, 0.028 μm⁻¹, 0.0278 μm⁻¹, 0.0276 μm⁻¹, 0.0274 μm⁻¹, 0.0272 μm⁻¹; 0.0270 μm⁻¹, 0.0268 μm⁻¹, 0.02667 μm⁻¹, 0.0265 μm⁻¹, 0.0263 μm⁻¹, 0.0261 μm⁻¹, 0.026 μm⁻¹, 0.0258 μm⁻¹, 0.0256 μm⁻¹, 0.0255 μm⁻¹, 0.0253 μm⁻¹, 0.0252 μm⁻¹, 0.025 μm⁻¹, 0.0248 μm⁻¹, 0.0247 μm⁻¹, 0.0245 μm⁻¹, 0.0244 μm⁻¹, 0.0242 μm⁻¹, 0.0241 μm⁻¹, 0.024 μm⁻¹, 0.0238 μm⁻¹, 0.0237 μm⁻¹, 0.0235 μm⁻¹, 0.0234 μm⁻¹, 0.0233 μm⁻¹, 0.231 μm⁻¹, 0.023 μm⁻¹, 0.0229 μm⁻¹, 0.0227 μm⁻¹, 0.0226 μm⁻¹, 0.0225 μm⁻¹, 0.0223 μm⁻¹, 0.0222 μm⁻¹, 0.0221 μm⁻¹, 0.022 μm⁻¹, 0.0219 μm⁻¹, 0.0217 μm⁻¹, 0.0216 μm⁻¹, 0.0215 μm⁻¹, 0.0214 μm⁻¹, 0.0213 μm⁻¹, 0.0212 μm⁻¹, 0.0211 μm⁻¹, 0.021 μm⁻¹, 0.0209 μm⁻¹, 0.0208 μm⁻¹, 0.0207 μm⁻¹, 0.0206 μm⁻¹, 0.0205 μm⁻¹, 0.0204 μm⁻¹, 0.0203 μm⁻¹, 0.0202 μm⁻¹, 0.0201 μm⁻¹, 0.02 μm⁻¹, or 0.002 μm⁻¹.

According to one embodiment, the surface roughness of the particle 12 is less or equal to 0%, 0.0001%, 0.0002%, 0.0003%, 0.0004%, 0.0005%, 0.0006%, 0.0007%, 0.0008%, 0.0009%, 0.001%, 0.002%, 0.003%, 0.004%, 0.005%, 0.006%, 0.007%, 0.008%, 0.009%, 0.01%, 0.02%, 0.03%, 0.04%, 0.05%, 0.06%, 0.07%, 0.08%, 0.09%, 0.1%, 0.11%, 0.12%, 0.13%, 0.14%, 0.15%, 0.16%, 0.17%, 0.18%, 0.19%, 0.2%, 0.21%, 0.22%, 0.23%, 0.24%, 0.25%, 0.26%, 0.27%, 0.28%, 0.29%, 0.3%, 0.31%, 0.32%, 0.33%, 0.34%, 0.35%, 0.36%, 0.37%, 0.38%, 0.39%, 0.4%, 0.41%, 0.42%, 0.43%, 0.44%, 0.45%, 0.46%, 0.47%, 0.48%, 0.49%, 0.5%, 1%, 1.5%, 2%, 2.5% 3%, 3.5%, 4%, 4.5%, or 5% of the largest dimension of said particle 12, meaning that the surface of said particle 12 is completely smooth.

According to one embodiment, the surface roughness of the particle 12 is less or equal to 0.5% of the largest dimension of said particle 12, meaning that the surface of said particle 12 is completely smooth.

According to one embodiment, in a statistical set of particles 12, said particles 12 are polydisperse.

According to one embodiment, in a statistical set of particles 12, said particles 12 are monodisperse.

According to one embodiment, in a statistical set of particles 12, said particles 12 have a narrow size distribution.

According to one embodiment, particles 12 in a same aggregate 1 are polydisperse.

According to one embodiment, particles 12 in a same aggregate 1 are monodisperse.

According to one embodiment, particles 12 in a same aggregate 1 have a narrow size distribution.

According to one embodiment, the size distribution for the smallest dimension of a statistical set of particles 12 is inferior than 1%, 2%, 3%, 4%, 5%, 6%, 7%, 8%, 9%, 10%, 15%, 20%, 25%, 30%, 35%, or 40% of said smallest dimension.

According to one embodiment, the size distribution for the largest dimension of a statistical set of particles 12 is inferior than 1%, 2%, 3%, 4%, 5%, 6%, 7%, 8%, 9%, 10%, 15%, 20%, 25%, 30%, 35%, or 40% of said largest dimension.

According to one embodiment, the size ratio between the aggregate 1 and the particle 12 ranges from 10 to 2 000, preferably from 10 to 1 500, more preferably from 10 to 1 000, even more preferably from 10 to 500.

According to one embodiment, the particle 12 is hollow.

According to one embodiment, the particle 12 is not hollow.

According to one embodiment, the particle 12 is isotropic.

According to one embodiment, examples of shape of isotropic particle 12 include but are not limited to: sphere 128 (as illustrated in FIG. 3), faceted bush, sphere, prism, polyhedron, or cubic shape.

According to one embodiment, the particle 12 is not spherical.

According to one embodiment, the particle 12 is anisotropic.

According to one embodiment, examples of shape of anisotropic particle 12 include but are not limited to: rod, wire, needle, bar, belt, cone, or polyhedron shape.

According to one embodiment, examples of branched shape of anisotropic particle 12 include but are not limited to: monopod, bipod, tripod, tetrapod, star, or octopod shape.

According to one embodiment, examples of complex shape of anisotropic particle 12 include but are not limited to: snowflake, flower, thorn, hemisphere, cone, urchin, filamentous particle, biconcave discoid, worm, tree, dendrite, necklace, or chain.

According to one embodiment, as illustrated in FIG. 4, the at least one particle 12 has a 2D shape 129.

According to one embodiment, examples of shape of 2D particle 129 include but are not limited to: sheet, platelet, plate, ribbon, wall, plate triangle, square, pentagon, hexagon, disk or ring.

According to one embodiment, a nanoplatelet is different from a disk or a nanodisk.

According to one embodiment, nanosheets and nanoplatelets are not disks or nanodisks. In this embodiment, the section along the other dimensions than the thickness (width, length) of said nanosheets or nanoplatelets is square or rectangular, while it is circular or ovoidal for disks or nanodisks.

According to one embodiment, nanosheets and nanoplatelets are not disks or nanodisks. In this embodiment, none of the dimensions of said nanosheets and nanoplatelets can be defined as a diameter nor the size of a semi-major axis and a semi-minor axis contrarily to disks or nanodisks.

According to one embodiment, nanosheets and nanoplatelets are not disks or nanodisks. In this embodiment, the curvature at all points along the other dimensions than the thickness (length, width) of said nanosheets or nanoplatelets is below 10 μm⁻¹, while the curvature for disks or nanodisks is superior than 10 μm⁻¹ on at least one point.

According to one embodiment, nanosheets and nanoplatelets are not disks or nanodisks. In this embodiment, the curvature at at least one point along the other dimensions than the thickness (length, width) of said nanosheets or nanoplatelets is below 10 μm⁻¹, while the curvature for disks or nanodisks is superior than 10 μm⁻¹ at all points.

According to one embodiment, a nanoplatelet is different from a quantum dot, or a spherical nanocrystal. A quantum dot is spherical, thus is has a 3D shape and allow confinement of excitons in all three spatial dimensions, whereas the nanoplatelet has a 2D shape and allow confinement of excitons in one dimension and allow free excitons propagation in the other two dimensions. This results in distinct electronic and optical properties, for example the typical photoluminescence decay time of semiconductor platelets is 1 order of magnitude faster than for spherical quantum dots, and the semiconductor platelets also show an exceptionally narrow optical feature with full width at half maximum (FWHM) much lower than for spherical quantum dots.

According to one embodiment, a nanoplatelet is different from a nanorod or nanowire. A nanorod (or nanowire) has a 1D shape and allow confinement of excitons two spatial dimensions, whereas the nanoplatelet has a 2D shape and allow confinement of excitons in one dimension and allow free propagation in the other two dimensions. This results in distinct electronic and optical properties.

According to one embodiment, to obtain a ROHS compliant aggregate 1, said aggregate 1 rather comprises semiconductor nanoplatelets than semiconductor quantum dots. Indeed, a same emission peak position is obtained for semiconductor quantum dots with a diameter d, and semiconductor nanoplatelets with a thickness d/2; thus for the same emission peak position, a semiconductor nanoplatelet comprises less cadmium in weight than a semiconductor quantum dot.

Furthermore, if a CdS core is comprised in a core/shell quantum dot or a core/shell (or core/crown) nanoplatelet, then there are more possibilities of shell layers without cadmium in the case of core/shell (or core/crown) nanoplatelet; thus a core/shell (or core/crown) nanoplatelet with a CdS core may comprise less cadmium in weight than a core/shell quantum dot with a CdS core. The lattice difference between CdS and nonCadmium shells is too important for the quantum dot to sustain. Finally, semiconductor nanoplatelets have better absorption properties than semiconductor quantum dots, thus resulting in less cadmium in weight needed in semiconductor nanoplatelets.

According to one embodiment, the particle 12 has a spherical shape.

According to one embodiment, the spherical particle 12 has a diameter of at least 0.5 nm, 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 55 nm, 60 nm, 65 nm, 70 nm, 75 nm, 80 nm, 85 nm, 90 nm, 95 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, a statistical set of spherical particles 12 has an average diameter of at least 0.5 nm, 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 55 nm, 60 nm, 65 nm, 70 nm, 75 nm, 80 nm, 85 nm, 90 nm, 95 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27.5 μm, 28 μm, 28.5 μm, 29 μm, 29.5 μm, 30 μm, 30.5 μm, 31 μm, 31.5 μm, 32 μm, 32.5 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44.5 μm, 45 μm, 45.5 μm, 46 μm, 46.5 μm, 47 μm, 47.5 μm, 48 μm, 48.5 μm, 49 μm, 49.5 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, the average diameter of a statistical set of spherical particles 12 may have a deviation less or equal to 0.01%, 0.02%, 0.03%, 0.04%, 0.05%, 0.06%, 0.07%, 0.08%, 0.09%, 0.1%, 0.2%, 0.3%, 0.4%, 0.5%, 0.6%, 0.7%, 0.8%, 0.9%, 1%, 1.1%, 1.2%, 1.3%, 1.4%, 1.5%, 1.6%, 1.7%, 1.8%, 1.9%, 2%, 2.1%, 2.2%, 2.3%, 2.4%, 2.5%, 2.6%, 2.7%, 2.8%, 2.9%, 3%, 3.1%, 3.2%, 3.3%, 3.4%, 3.5%, 3.6%, 3.7%, 3.8%, 3.9%, 4%, 4.1%, 4.2%, 4.3%, 4.4%, 4.5%, 4.6%, 4.7%, 4.8%, 4.9%, 5%, 5.1%, 5.2%, 5.3%, 5.4%, 5.5%, 5.6%, 5.7%, 5.8%, 5.9%, 6%, 6.1%, 6.2%, 6.3%, 6.4%, 6.5%, 6.6%, 6.7%, 6.8%, 6.9%, 7%, 7.1%, 7.2%, 7.3%, 7.4%, 7.5%, 7.6%, 7.7%, 7.8%, 7.9%, 8%, 8.1%, 8.2%, 8.3%, 8.4%, 8.5%, 8.6%, 8.7%, 8.8%, 8.9%, 9%, 9.1%, 9.2%, 9.3%, 9.4%, 9.5%, 9.6%, 9.7%, 9.8%, 9.9%, 10%, 20%, 30%, 40%, 50%, 60%, 70%, 80%, 85%, 90%, 95%, 100%, 105%, 110%, 115%, 120%, 125%, 130%, 135%, 140%, 145%, 150%, 155%, 160%, 165%, 170%, 175%, 180%, 185%, 190%, 195%, or 200%.

According to one embodiment, the spherical particle 12 has a unique curvature of at least 200 μm⁻¹, 100 μm⁻¹, 66.6 μm⁻¹, 50 μm⁻¹, 33.3 μm⁻¹, 28.6 μm⁻¹, 25 μm⁻¹, 20 μm⁻¹, 18.2 μm⁻¹, 16.7 μm⁻¹, 15.4 μm⁻¹, 14.3 μm⁻¹, 13.3 μm⁻¹, 12.5 μm⁻¹, 11.8 μm⁻¹, 11.1 μm⁻¹, 10.5 μm⁻¹, 10 μm⁻¹, 9.5 μm⁻¹, 9.1 μm⁻¹, 8.7 μm⁻¹, 8.3 μm⁻¹, 8 μm⁻¹, 7.7 μm⁻¹, 7.4 μm⁻¹, 7.1 μm⁻¹, 6.9 μm⁻¹, 6.7 μm⁻¹, 5.7 μm⁻¹, 5 μm⁻¹, 4.4 μm⁻¹, 4 μm⁻¹, 3.6 μm⁻¹, 3.3 μm⁻¹, 3.1 μm⁻¹, 2.9 μm⁻¹, 2.7 μm⁻¹, 2.5 μm⁻¹, 2.4 μm⁻¹, 2.2 μm⁻¹, 2.1 μm⁻¹, 2 μm⁻¹, 1.3333 μm⁻¹, 0.8 μm⁻¹, 0.6666 μm⁻¹, 0.5714 μm⁻¹, 0.5 μm⁻¹, 0.4444 μm⁻¹, 0.4 μm⁻¹, 0.3636 μm⁻¹, 0.3333 μm⁻¹, 0.3080 μm⁻¹, 0.2857 μm⁻¹, 0.2667 μm⁻¹, 0.25 μm⁻¹, 0.2353 μm⁻¹, 0.2222 μm⁻¹, 0.2105 μm⁻¹, 0.2 μm⁻¹, 0.1905 μm⁻¹, 0.1818 μm⁻¹, 0.1739 μm⁻¹, 0.1667 μm⁻¹, 0.16 μm⁻¹, 0.1538 μm⁻¹, 0.1481 μm⁻¹, 0.1429 μm⁻¹, 0.1379 μm⁻¹, 0.1333 μm⁻¹, 0.1290 μm⁻¹, 0.125 μm⁻¹, 0.1212 μm⁻¹, 0.1176 μm⁻¹, 0.1176 μm⁻¹, 0.1143 μm⁻¹, 0.1111 μm⁻¹, 0.1881 μm⁻¹, 0.1053 μm⁻¹, 0.1026 μm⁻¹, 0.1 μm⁻¹, 0.0976 μm⁻¹, 0.9524 μm⁻¹, 0.0930 μm⁻¹, 0.0909 μm⁻¹, 0.0889 μm⁻¹, 0.870 μm⁻¹, 0.0851 μm⁻¹, 0.0833 μm⁻¹, 0.0816 μm⁻¹, 0.08 μm⁻¹, 0.0784 μm⁻¹, 0.0769 μm⁻¹, 0.0755 μm⁻¹, 0.0741 μm⁻¹, 0.0727 μm⁻¹, 0.0714 μm⁻¹, 0.0702 μm⁻¹, 0.0690 μm⁻¹, 0.0678 μm⁻¹, 0.0667 μm⁻¹, 0.0656 μm⁻¹, 0.0645 μm⁻¹, 0.0635 μm⁻¹, 0.0625 μm⁻¹, 0.0615 μm⁻¹, 0.0606 μm⁻¹, 0.0597 μm⁻¹, 0.0588 μm⁻¹, 0.0580 μm⁻¹, 0.0571 μm⁻¹, 0.0563 μm⁻¹, 0.0556 μm⁻¹, 0.0548 μm⁻¹, 0.0541 μm⁻¹, 0.0533 μm⁻¹, 0.0526 μm⁻¹, 0.0519 μm⁻¹, 0.0513 μm⁻¹, 0.0506 μm⁻¹, 0.05 μm⁻¹, 0.0494 μm⁻¹, 0.0488 μm⁻¹, 0.0482 μm⁻¹, 0.0476 μm⁻¹, 0.0471 μm⁻¹, 0.0465 μm⁻¹, 0.0460 μm⁻¹, 0.0455 μm⁻¹, 0.0450 μm⁻¹, 0.0444 μm⁻¹, 0.0440 μm⁻¹, 0.0435 μm⁻¹, 0.0430 μm⁻¹, 0.0426 μm⁻¹, 0.0421 μm⁻¹, 0.0417 μm⁻¹, 0.0412 μm⁻¹, 0.0408 μm⁻¹, 0.0404 μm⁻¹, 0.04 μm⁻¹, 0.0396 μm⁻¹, 0.0392 μm⁻¹, 0.0388 μm⁻¹, 0.0385 μm⁻¹; 0.0381 μm⁻¹, 0.0377 μm⁻¹, 0.0374 μm⁻¹, 0.037 μm⁻¹, 0.0367 μm⁻¹, 0.0364 μm⁻¹, 0.0360 μm⁻¹, 0.0357 μm⁻¹, 0.0354 μm⁻¹, 0.0351 μm⁻¹, 0.0348 μm⁻¹, 0.0345 μm⁻¹, 0.0342 μm⁻¹, 0.0339 μm⁻¹, 0.0336 μm⁻¹, 0.0333 μm⁻¹, 0.0331 μm⁻¹, 0.0328 μm⁻¹, 0.0325 μm⁻¹, 0.0323 μm⁻¹, 0.032 μm⁻¹, 0.0317 μm⁻¹, 0.0315 μm⁻¹, 0.0312 μm⁻¹, 0.031 μm⁻¹, 0.0308 μm⁻¹, 0.0305 μm⁻¹, 0.0303 μm⁻¹, 0.0301 μm⁻¹, 0.03 μm⁻¹, 0.0299 μm⁻¹, 0.0296 μm⁻¹, 0.0294 μm⁻¹, 0.0292 μm⁻¹, 0.029 μm⁻¹, 0.0288 μm⁻¹, 0.0286 μm⁻¹, 0.0284 μm⁻¹, 0.0282 μm⁻¹, 0.028 μm⁻¹, 0.0278 μm⁻¹, 0.0276 μm⁻¹, 0.0274 μm⁻¹, 0.0272 μm⁻¹; 0.0270 μm⁻¹, 0.0268 μm⁻¹, 0.02667 μm⁻¹, 0.0265 μm⁻¹, 0.0263 μm⁻¹, 0.0261 μm⁻¹, 0.026 μm⁻¹, 0.0258 μm⁻¹, 0.0256 μm⁻¹, 0.0255 μm⁻¹, 0.0253 μm⁻¹, 0.0252 μm⁻¹, 0.025 μm⁻¹, 0.0248 μm⁻¹, 0.0247 μm⁻¹, 0.0245 μm⁻¹, 0.0244 μm⁻¹, 0.0242 μm⁻¹, 0.0241 μm⁻¹, 0.024 μm⁻¹, 0.0238 μm⁻¹, 0.0237 μm⁻¹, 0.0235 μm⁻¹, 0.0234 μm⁻¹, 0.0233 μm⁻¹, 0.231 μm⁻¹, 0.023 μm⁻¹, 0.0229 μm⁻¹, 0.0227 μm⁻¹, 0.0226 μm⁻¹, 0.0225 μm⁻¹, 0.0223 μm⁻¹, 0.0222 μm⁻¹, 0.0221 μm⁻¹, 0.022 μm⁻¹, 0.0219 μm⁻¹, 0.0217 μm⁻¹, 0.0216 μm⁻¹, 0.0215 μm⁻¹, 0.0214 μm⁻¹, 0.0213 μm⁻¹, 0.0212 μm⁻¹, 0.0211 μm⁻¹, 0.021 μm⁻¹, 0.0209 μm⁻¹, 0.0208 μm⁻¹, 0.0207 μm⁻¹, 0.0206 μm⁻¹, 0.0205 μm⁻¹, 0.0204 μm⁻¹, 0.0203 μm⁻¹, 0.0202 μm⁻¹, 0.0201 μm⁻¹, 0.02 μm⁻¹, or 0.002 μm⁻¹.

According to one embodiment, a statistical set of the spherical particles 12 has an average unique curvature of at least 200 μm⁻¹, 100 μm⁻¹, 66.6 μm⁻¹, 50 μm⁻¹, 33.3 μm⁻¹, 28.6 μm⁻¹, 25 μm⁻¹, 20 μm⁻¹, 18.2 μm⁻¹, 16.7 μm⁻¹, 15.4 μm⁻¹, 14.3 μm⁻¹, 13.3 μm⁻¹, 12.5 μm⁻¹, 11.8 μm⁻¹, 11.1 μm⁻¹, 10.5 μm⁻¹, 10 μm⁻¹, 9.5 μm⁻¹, 9.1 μm⁻¹, 8.7 μm⁻¹, 8.3 μm⁻¹, 8 μm⁻¹, 7.7 μm⁻¹, 7.4 μm⁻¹, 7.1 μm⁻¹, 6.9 μm⁻¹, 6.7 μm⁻¹, 5.7 μm⁻¹, 5 μm⁻¹, 4.4 μm⁻¹, 4 μm⁻¹, 3.6 μm⁻¹, 3.3 μm⁻¹, 3.1 μm⁻¹, 2.9 μm⁻¹, 2.7 μm⁻¹, 2.5 μm⁻¹, 2.4 μm⁻¹, 2.2 μm⁻¹, 2.1 μm⁻¹, 2 μm⁻¹, 1.3333 μm⁻¹, 0.8 μm⁻¹, 0.6666 μm⁻¹, 0.5714 μm⁻¹, 0.5 μm⁻¹, 0.4444 μm⁻¹, 0.4 μm⁻¹, 0.3636 μm⁻¹, 0.3333 μm⁻¹, 0.3080 μm⁻¹, 0.2857 μm⁻¹, 0.2667 μm⁻¹, 0.25 μm⁻¹, 0.2353 μm⁻¹, 0.2222 μm⁻¹, 0.2105 μm⁻¹, 0.2 μm⁻¹, 0.1905 μm⁻¹, 0.1818 μm⁻¹, 0.1739 μm⁻¹, 0.1667 μm⁻¹, 0.16 μm⁻¹, 0.1538 μm⁻¹, 0.1481 μm⁻¹, 0.1429 μm⁻¹, 0.1379 μm⁻¹, 0.1333 μm⁻¹, 0.1290 μm⁻¹, 0.125 μm⁻¹, 0.1212 μm⁻¹, 0.1176 μm⁻¹, 0.1176 μm⁻¹, 0.1143 μm⁻¹, 0.1111 μm⁻¹, 0.1881 μm⁻¹, 0.1053 μm⁻¹, 0.1026 μm⁻¹, 0.1 μm⁻¹, 0.0976 μm⁻¹, 0.9524 μm⁻¹, 0.0930 μm⁻¹, 0.0909 μm⁻¹, 0.0889 μm⁻¹, 0.870 μm⁻¹, 0.0851 μm⁻¹, 0.0833 μm⁻¹, 0.0816 μm⁻¹, 0.08 μm⁻¹, 0.0784 μm⁻¹, 0.0769 μm⁻¹, 0.0755 μm⁻¹, 0.0741 μm⁻¹, 0.0727 μm⁻¹, 0.0714 μm⁻¹, 0.0702 μm⁻¹, 0.0690 μm⁻¹, 0.0678 μm⁻¹, 0.0667 μm⁻¹, 0.0656 μm⁻¹, 0.0645 μm⁻¹, 0.0635 μm⁻¹, 0.0625 μm⁻¹, 0.0615 μm⁻¹, 0.0606 μm⁻¹, 0.0597 μm⁻¹, 0.0588 μm⁻¹, 0.0580 μm⁻¹, 0.0571 μm⁻¹, 0.0563 μm⁻¹, 0.0556 μm⁻¹, 0.0548 μm⁻¹, 0.0541 μm⁻¹, 0.0533 μm⁻¹, 0.0526 μm⁻¹, 0.0519 μm⁻¹, 0.0513 μm⁻¹, 0.0506 μm⁻¹, 0.05 μm⁻¹, 0.0494 μm⁻¹, 0.0488 μm⁻¹, 0.0482 μm⁻¹, 0.0476 μm⁻¹, 0.0471 μm⁻¹, 0.0465 μm⁻¹, 0.0460 μm⁻¹, 0.0455 μm⁻¹, 0.0450 μm⁻¹, 0.0444 μm⁻¹, 0.0440 μm⁻¹, 0.0435 μm⁻¹, 0.0430 μm⁻¹, 0.0426 μm⁻¹, 0.0421 μm⁻¹, 0.0417 μm⁻¹, 0.0412 μm⁻¹, 0.0408 μm⁻¹, 0.0404 μm⁻¹, 0.04 μm⁻¹, 0.0396 μm⁻¹, 0.0392 μm⁻¹, 0.0388 μm⁻¹, 0.0385 μm⁻¹; 0.0381 μm⁻¹, 0.0377 μm⁻¹, 0.0374 μm⁻¹, 0.037 μm⁻¹, 0.0367 μm⁻¹, 0.0364 μm⁻¹, 0.0360 μm⁻¹, 0.0357 μm⁻¹, 0.0354 μm⁻¹, 0.0351 μm⁻¹, 0.0348 μm⁻¹, 0.0345 μm⁻¹, 0.0342 μm⁻¹, 0.0339 μm⁻¹, 0.0336 μm⁻¹, 0.0333 μm⁻¹, 0.0331 μm⁻¹, 0.0328 μm⁻¹, 0.0325 μm⁻¹, 0.0323 μm⁻¹, 0.032 μm⁻¹, 0.0317 μm⁻¹, 0.0315 μm⁻¹, 0.0312 μm⁻¹, 0.031 μm⁻¹, 0.0308 μm⁻¹, 0.0305 μm⁻¹, 0.0303 μm⁻¹, 0.0301 μm⁻¹, 0.03 μm⁻¹, 0.0299 μm⁻¹, 0.0296 μm⁻¹, 0.0294 μm⁻¹, 0.0292 μm⁻¹, 0.029 μm⁻¹, 0.0288 μm⁻¹, 0.0286 μm⁻¹, 0.0284 μm⁻¹, 0.0282 μm⁻¹, 0.028 μm⁻¹, 0.0278 μm⁻¹, 0.0276 μm⁻¹, 0.0274 μm⁻¹, 0.0272 μm⁻¹; 0.0270 μm⁻¹, 0.0268 μm⁻¹, 0.02667 μm⁻¹, 0.0265 μm⁻¹, 0.0263 μm⁻¹, 0.0261 μm⁻¹, 0.026 μm⁻¹, 0.0258 μm⁻¹, 0.0256 μm⁻¹, 0.0255 μm⁻¹, 0.0253 μm⁻¹, 0.0252 μm⁻¹, 0.025 μm⁻¹, 0.0248 μm⁻¹, 0.0247 μm⁻¹, 0.0245 μm⁻¹, 0.0244 μm⁻¹, 0.0242 μm⁻¹, 0.0241 μm⁻¹, 0.024 μm⁻¹, 0.0238 μm⁻¹, 0.0237 μm⁻¹, 0.0235 μm⁻¹, 0.0234 μm⁻¹, 0.0233 μm⁻¹, 0.231 μm⁻¹, 0.023 μm⁻¹, 0.0229 μm⁻¹, 0.0227 μm⁻¹, 0.0226 μm⁻¹, 0.0225 μm⁻¹, 0.0223 μm⁻¹, 0.0222 μm⁻¹, 0.0221 μm⁻¹, 0.022 μm⁻¹, 0.0219 μm⁻¹, 0.0217 μm⁻¹, 0.0216 μm⁻¹, 0.0215 μm⁻¹, 0.0214 μm⁻¹, 0.0213 μm⁻¹, 0.0212 μm⁻¹, 0.0211 μm⁻¹, 0.021 μm⁻¹, 0.0209 μm⁻¹, 0.0208 μm⁻¹, 0.0207 μm⁻¹, 0.0206 μm⁻¹, 0.0205 μm⁻¹, 0.0204 μm⁻¹, 0.0203 μm⁻¹, 0.0202 μm⁻¹, 0.0201 μm⁻¹, 0.02 μm⁻¹, or 0.002 μm⁻¹.

According to one embodiment, the curvature of the spherical particle 12 has no deviation, meaning that said particle 12 has a perfect spherical shape. A perfect spherical shape prevents fluctuations of the intensity of the scattered light.

According to one embodiment, the unique curvature of the spherical particle 12 may have a deviation less or equal to 0.01%, 0.02%, 0.03%, 0.04%, 0.05%, 0.06%, 0.07%, 0.08%, 0.09%, 0.1%, 0.2%, 0.3%, 0.4%, 0.5%, 0.6%, 0.7%, 0.8%, 0.9%, 1%, 1.1%, 1.2%, 1.3%, 1.4%, 1.5%, 1.6%, 1.7%, 1.8%, 1.9%, 2%, 2.1%, 2.2%, 2.3%, 2.4%, 2.5%, 2.6%, 2.7%, 2.8%, 2.9%, 3%, 3.1%, 3.2%, 3.3%, 3.4%, 3.5%, 3.6%, 3.7%, 3.8%, 3.9%, 4%, 4.1%, 4.2%, 4.3%, 4.4%, 4.5%, 4.6%, 4.7%, 4.8%, 4.9%, 5%, 5.1%, 5.2%, 5.3%, 5.4%, 5.5%, 5.6%, 5.7%, 5.8%, 5.9%, 6%, 6.1%, 6.2%, 6.3%, 6.4%, 6.5%, 6.6%, 6.7%, 6.8%, 6.9%, 7%, 7.1%, 7.2%, 7.3%, 7.4%, 7.5%, 7.6%, 7.7%, 7.8%, 7.9%, 8%, 8.1%, 8.2%, 8.3%, 8.4%, 8.5%, 8.6%, 8.7%, 8.8%, 8.9%, 9%, 9.1%, 9.2%, 9.3%, 9.4%, 9.5%, 9.6%, 9.7%, 9.8%, 9.9%, or 10% along the surface of said particle 12.

According to one embodiment, the particle 12 is atomically flat. In this embodiment, the atomically flat particle 12 may be evidenced by transmission electron microscopy or fluorescence scanning microscopy, energy-dispersive X-ray spectroscopy (EDS), X-Ray photoelectron spectroscopy (XPS), UV photoelectron spectroscopy (UPS), electron energy loss spectroscopy (EELS), photoluminescence or any other characterization means known by the person skilled in the art.

According to one embodiment, the particle 12 comprises at least one atomically flat core. In this embodiment, the atomically flat core may be evidenced by transmission electron microscopy or fluorescence scanning microscopy, energy-dispersive X-ray spectroscopy (EDS), X-Ray photoelectron spectroscopy (XPS), UV photoelectron spectroscopy (UPS), electron energy loss spectroscopy (EELS), photoluminescence, or any other characterization means known by the person skilled in the art.

According to one embodiment, the particle 12 is ROHS compliant.

According to one embodiment, the particle 12 comprises less than 10 ppm, less than 20 ppm, less than 30 ppm, less than 40 ppm, less than 50 ppm, less than 100 ppm, less than 150 ppm, less than 200 ppm, less than 250 ppm, less than 300 ppm, less than 350 ppm, less than 400 ppm, less than 450 ppm, less than 500 ppm, less than 550 ppm, less than 600 ppm, less than 650 ppm, less than 700 ppm, less than 750 ppm, less than 800 ppm, less than 850 ppm, less than 900 ppm, less than 950 ppm, less than 1000 ppm in weight of cadmium.

According to one embodiment, the particle 12 comprises less than 10 ppm, less than 20 ppm, less than 30 ppm, less than 40 ppm, less than 50 ppm, less than 100 ppm, less than 150 ppm, less than 200 ppm, less than 250 ppm, less than 300 ppm, less than 350 ppm, less than 400 ppm, less than 450 ppm, less than 500 ppm, less than 550 ppm, less than 600 ppm, less than 650 ppm, less than 700 ppm, less than 750 ppm, less than 800 ppm, less than 850 ppm, less than 900 ppm, less than 950 ppm, less than 1000 ppm, less than 2000 ppm, less than 3000 ppm, less than 4000 ppm, less than 5000 ppm, less than 6000 ppm, less than 7000 ppm, less than 8000 ppm, less than 9000 ppm, less than 10000 ppm in weight of lead.

According to one embodiment, the particle 12 comprises less than 10 ppm, less than 20 ppm, less than 30 ppm, less than 40 ppm, less than 50 ppm, less than 100 ppm, less than 150 ppm, less than 200 ppm, less than 250 ppm, less than 300 ppm, less than 350 ppm, less than 400 ppm, less than 450 ppm, less than 500 ppm, less than 550 ppm, less than 600 ppm, less than 650 ppm, less than 700 ppm, less than 750 ppm, less than 800 ppm, less than 850 ppm, less than 900 ppm, less than 950 ppm, less than 1000 ppm, less than 2000 ppm, less than 3000 ppm, less than 4000 ppm, less than 5000 ppm, less than 6000 ppm, less than 7000 ppm, less than 8000 ppm, less than 9000 ppm, less than 10000 ppm in weight of mercury.

According to one embodiment, the particle 12 comprises heavier chemical elements than the main chemical element present in the particle 12. In this embodiment, said heavy chemical elements in the particle 12 will lower the mass concentration of chemical elements subject to ROHS standards, allowing said particle 12 to be ROHS compliant.

According to one embodiment, examples of heavy chemical elements include but are not limited to B, C, N, F, Na, Mg, Al, Si, P, S, Cl, K, Ca, Sc, Ti, V, Cr, Mn, Fe, Co, Ni, Cu, Zn, Ga, Ge, As, Se, Br, Rb, Sr, Y, Zr, Nb, Mo, Tc, Ru, Rh, Pd, Ag, Cd, In, Sn, Sb, Te, I, Cs, Ba, La, Hf, Ta, W, Re, Os, Ir, Pt, Au, Hg, Tl, Pb, Bi, Po, At, Ce, Pr, Nd, Pm, Sm, Eu, Gd, Tb, Dy, Ho, Er, Tm, Yb, Lu or a mixture of thereof.

According to one embodiment, the particle 12 is a colloidal nanoparticle.

According to one embodiment, the particle 12 is a nanoparticle.

According to one embodiment, the particle 12 is not an electrically charged nanoparticle.

According to one embodiment, the particle 12 is not a positively charged nanoparticle.

According to one embodiment, the particle 12 is not a negatively charged nanoparticle.

According to one embodiment, the at least one particle 12 is selected from inorganic, organic or hybrid particles.

According to one embodiment, the particle 12 comprises an organic material as described hereabove. Said organic material is the same or different from the material 11.

According to one embodiment, the particle 12 is an organic particle.

According to one embodiment, the organic particle is composed of a material selected in the group of carbon nanotube, graphene and its chemical derivatives, graphyne, fullerenes, nanodiamonds, boron nitride nanotubes, boron nitride nanosheets, phosphorene and Si₂BN.

According to one embodiment, the particle 12 comprises an inorganic material as described hereabove. Said inorganic material is the same or different from the material 11.

According to one embodiment, the aggregate 1 comprises at least one inorganic particle and at least one organic particle.

According to one embodiment, the particle 12 is an inorganic particle.

According to one embodiment, the particle 12 is not an organic particle.

According to one embodiment, the particle 12 is not a metallic particle.

According to one embodiment, the aggregate 1 does not comprise only metal particles 12.

According to one embodiment, the particle 12 is not a ZnO particle.

According to one embodiment, the aggregate 1 does not comprise only magnetic particles 12.

According to one embodiment, the particle 12 is a semiconductor particle.

According to one embodiment, the particle 12 is a semiconductor nanoparticle.

According to one embodiment, the particle 12 is a nanocrystal.

According to one embodiment, the particle 12 is a semiconductor nanocrystal.

According to one embodiment, the particle 12 is selected in the group of metal particles, halide particles, chalcogenide particles, phosphide particles, sulfide particles, metalloid particles, metallic alloy particles, phosphor particles, perovskite particles, ceramic particles such as for example oxide particles, carbide particles, nitride particles, or a mixture thereof. Said particles are prepared using protocols known to the person skilled in the art.

According to one embodiment, the particle 12 is selected from metal particles, halide particles, chalcogenide particles, phosphide particles, sulfide particles, metalloid particles, metallic alloy particles, phosphor particles, perovskite particles, ceramic particles such as for example oxide particles, carbide particles, nitride particles, or a mixture thereof, preferably is a semiconductor nanocrystal.

According to one embodiment, the particle 12 is composed of a material selected in the group of metals, halides, chalcogenides, phosphides, sulfides, metalloids, metallic alloys, ceramics such as for example oxides, carbides, or nitrides. Said particles are prepared using protocols known to the person skilled in the art.

According to one embodiment, a chalcogenide is a chemical compound consisting of at least one chalcogen anion selected in the group of O, S, Se, Te, Po, and at least one or more electropositive element.

According to one embodiment, the metallic particles are selected in the group of gold particles, silver particles, copper particles, vanadium particles, platinum particles, palladium particles, ruthenium particles, rhenium particles, yttrium particles, mercury particles, cadmium particles, osmium particles, chromium particles, tantalum particles, manganese particles, zinc particles, zirconium particles, niobium particles, molybdenum particles, rhodium particles, tungsten particles, iridium particles, nickel particles, iron particles, or cobalt particles.

According to one embodiment, examples of carbide particles include but are not limited to: SiC, WC, BC, MoC, TiC, Al₄C₃, LaC₂, FeC, CoC, HfC, SiₓC_{y}, WₓC_{y}, BₓC_{y}, MoₓC_{y}, TiₓC_{y}, AlₓC_{y}, LaₓC_{y}, FeₓC_{y}, CoₓC_{y}, HfₓC_{y}, or a mixture thereof; x and y are independently a decimal number from 0 to 5, at the condition that x and y are not simultaneously equal to 0, and x≠0.

According to one embodiment, examples of oxide particles include but are not limited to: SiO₂, Al₂O₃, TiO₂, ZrO₂, ZnO, MgO, SnO₂, Nb₂O₅, CeO₂, BeO, IrO₂, CaO, Sc₂O₃, NiO, Na₂O, BaO, K₂O, PbO, Ag₂O, V₂O₅, TeO₂, MnO, B₂O₃, P₂O₅, P₂O₃, P₄O₇, P₄O₈, P₄O₉, P₂O₆, PO, GeO₂, As₂O₃, Fe₂O₃, Fe₃O₄, Ta₂O₅, Li₂O, SrO, Y₂O₃, HfO₂, WO₂, MoO₂, Cr₂O₃, Tc₂O₇, ReO₂, RuO₂, Co₃O₄, OsO, RhO₂, Rh₂O₃, PtO, PdO, CuO, Cu₂O, CdO, HgO, Tl₂O, Ga₂O₃, In₂O₃, Bi₂O₃, Sb₂O₃, PoO₂, SeO₂, Cs₂O, La₂O₃, Pr₆O₁₁, Nd₂O₃, La₂O₃, Sm₂O₃, Eu₂O₃, Tb₄O₇, Dy₂O₃, Ho₂O₃, Er₂O₃, Tm₂O₃, Yb₂O₃, Lu₂O₃, Gd₂O₃, or a mixture thereof.

According to one embodiment, examples of oxide particles include but are not limited to: silicon oxide, aluminium oxide, titanium oxide, copper oxide, iron oxide, silver oxide, lead oxide, calcium oxide, magnesium oxide, zinc oxide, tin oxide, beryllium oxide, zirconium oxide, niobium oxide, cerium oxide, iridium oxide, scandium oxide, nickel oxide, sodium oxide, barium oxide, potassium oxide, vanadium oxide, tellurium oxide, manganese oxide, boron oxide, phosphorus oxide, germanium oxide, osmium oxide, rhenium oxide, platinum oxide, arsenic oxide, tantalum oxide, lithium oxide, strontium oxide, yttrium oxide, hafnium oxide, tungsten oxide, molybdenum oxide, chromium oxide, technetium oxide, rhodium oxide, ruthenium oxide, cobalt oxide, palladium oxide, cadmium oxide, mercury oxide, thallium oxide, gallium oxide, indium oxide, bismuth oxide, antimony oxide, polonium oxide, selenium oxide, cesium oxide, lanthanum oxide, praseodymium oxide, neodymium oxide, samarium oxide, europium oxide, terbium oxide, dysprosium oxide, erbium oxide, holmium oxide, thulium oxide, ytterbium oxide, lutetium oxide, gadolinium oxide, mixed oxides, mixed oxides thereof or a mixture thereof.

According to one embodiment, examples of nitride particles include but are not limited to: TiN, Si₃N₄, MoN, VN, TaN, Zr₃N₄, HfN, FeN, NbN, GaN, CrN, AlN, InN, TiₓN_{y}, SiₓN_{y}, MoₓN_{y}, VₓN_{y}, TaₓN_{y}, ZrₓN_{y}, HfₓN_{y}, FeₓN_{y}, NbₓN_{y}, GaₓN_{y}, CrₓN_{y}, AlₓN_{y}, InₓN_{y}, or a mixture thereof; x and y are independently a decimal number from 0 to 5, at the condition that x and y are not simultaneously equal to 0, and x≠0.

According to one embodiment, examples of sulfide particles include but are not limited to: Si_{y}Sₓ, Al_{y}Sₓ, Ti_{y}Sₓ, Zr_{y}Sₓ, Zn_{y}Sₓ, Mg_{y}Sₓ, Sn_{y}Sₓ, Nb_{y}Sₓ, Ce_{y}Sₓ, Be_{y}Sₓ, Ir_{y}Sₓ, Ca_{y}Sₓ, Sc_{y}Sₓ, Ni_{y}Sₓ, Na_{y}Sₓ, Ba_{y}Sₓ, K_{y}Sₓ, Pb_{y}Sₓ, Ag_{y}Sₓ, V_{y}Sₓ, Te_{y}Sₓ, Mn_{y}Sₓ, B_{y}Sₓ, P_{y}Sₓ, Ge_{y}Sₓ, As_{y}Sₓ, Fe_{y}Sₓ, Ta_{y}Sₓ, Li_{y}Sₓ, Sr_{y}Sₓ, Y_{y}Sₓ, Hf_{y}Sₓ, W_{y}Sₓ, Mo_{y}Sₓ, Cr_{y}Sₓ, Tc_{y}Sₓ, Re_{y}Sₓ, Ru_{y}Sₓ, Co_{y}Sₓ, Os_{y}Sₓ, Rh_{y}Sₓ, Pt_{y}Sₓ, Pd_{y}Sₓ, Cu_{y}Sₓ, Au_{y}Sₓ, Cd_{y}Sₓ, Hg_{y}Sₓ, Tl_{y}Sₓ, Ga_{y}Sₓ, In_{y}Sₓ, Bi_{y}Sₓ, Sb_{y}Sₓ, Po_{y}Sₓ, Se_{y}Sₓ, Cs_{y}Sₓ, mixed sulfides, mixed sulfides thereof or a mixture thereof; x and y are independently a decimal number from 0 to 10, at the condition that x and y are not simultaneously equal to 0, and x≠0.

According to one embodiment, examples of halide particles include but are not limited to: BaF₂, LaF₃, CeF₃, YF₃, CaF₂, MgF₂, PrF₃, AgCl, MnCl₂, NiCl₂, Hg₂Cl₂, CaCl₂, CsPbCl₃, AgBr, PbBr₃, CsPbBr₃, AgI, CuI, PbI, HgI₂, BiI₃, CH₃NH₃PbI₃, CH₃NH₃PbCl₃, CH₃NH₃PbBr₃, CsPbI₃, FAPbBr₃ (with FA formamidinium), or a mixture thereof.

According to one embodiment, examples of chalcogenide particles include but are not limited to: CdO, CdS, CdSe, CdTe, ZnO, ZnS, ZnSe, ZnTe, HgO, HgS, HgSe, HgTe, CuO, Cu₂O, CuS, Cu₂S, CuSe, CuTe, Ag₂O, Ag₂S, Ag₂Se, Ag₂Te, Au₂S, PdO, PdS, Pd₄S, PdSe, PdTe, PtO, PtS, PtS₂, PtSe, PtTe, RhO₂, Rh₂O₃, RhS₂, Rh₂S₃, RhSe₂, Rh₂Se₃, RhTe₂, IrO₂, IrS₂, Ir₂S₃, IrSe₂, IrTe₂, RuO₂, RuS₂, OsO, OsS, OsSe, OsTe, MnO, MnS, MnSe, MnTe, ReO₂, ReS₂, Cr₂O₃, Cr₂S₃, MoO₂, MoS₂, MoSe₂, MoTe₂, WO₂, WS₂, WSe₂, V₂O₅, V₂S₃, Nb₂O₅, NbS₂, NbSe₂, HfO₂, HfS₂, TiO₂, ZrO₂, ZrS₂, ZrSe₂, ZrTe₂, Sc₂O₃, Y₂O₃, Y₂S₃, SiO₂, GeO₂, GeS, GeS₂, GeSe, GeSe₂, GeTe, SnO₂, SnS, SnS₂, SnSe, SnSe₂, SnTe, PbO, PbS, PbSe, PbTe, MgO, MgS, MgSe, MgTe, CaO, CaS, SrO, Al₂O₃, Ga₂O₃, Ga₂S₃, Ga₂Se₃, In₂O₃, In₂S₃, In₂Se₃, In₂Te₃, La₂O₃, La₂S₃, CeO₂, CeS₂, Pr₆O₁₁, Nd₂O₃, NdS₂, La₂O₃, Tl₂O, Sm₂O₃, SmS₂, Eu₂O₃, EuS₂, Bi₂O₃, Sb₂O₃, PoO₂, SeO₂, Cs₂O, Tb₄O₇, TbS₂, Dy₂O₃, Ho₂O₃, Er₂O₃, ErS₂, Tm₂O₃, Yb₂O₃, Lu₂O₃, CuInS₂, CuInSe₂, AgInS₂, AgInSe₂, Fe₂O₃, Fe₃O₄, FeS, FeS₂, Co₃S₄, CoSe, Co₃O₄, NiO, NiSe₂, NiSe, Ni₃Se₄, Gd₂O₃, BeO, TeO₂, Na₂O, BaO, K₂O, Ta₂O₅, Li₂O, Tc₂O₇, As₂O₃, B₂O₃, P₂O₅, P₂O₃, P₄O₇, P₄O₈, P₄O₉, P₂O₆, PO, or a mixture thereof.

According to one embodiment, examples of phosphide particles include but are not limited to: InP, Cd₃P₂, Zn₃P₂, AlP, GaP, TlP, or a mixture thereof.

According to one embodiment, examples of metalloid particles include but are not limited to: Si, B, Ge, As, Sb, Te, or a mixture thereof.

According to one embodiment, examples of metallic alloy particles include but are not limited to: Au—Pd, Au—Ag, Au—Cu, Pt—Pd, Pt—Ni, Cu—Ag, Cu—Sn, Ru—Pt, Rh—Pt, Cu—Pt, Ni—Au, Pt—Sn, Pd—V, Ir—Pt, Au—Pt, Pd—Ag, Cu—Zn, Cr—Ni, Fe—Co, Co—Ni, Fe—Ni or a mixture thereof.

According to one embodiment, the particle 12 is a nanoparticle comprising hygroscopic materials such as for example phosphor materials or scintillator materials.

According to one embodiment, the particle 12 is a perovskite particle.

According to one embodiment, perovskites comprise a material AₘBₙX₃ₚ, wherein A is selected from the group consisting of Ba, B, K, Pb, Cs, Ca, Ce, Na, La, Sr, Th, FA (formamidinium CN₂H₅⁺), or a mixture thereof; B is selected from the group consisting of Fe, Nb, Ti, Pb, Sn, Ge, Bi, Zr, or a mixture thereof; X is selected from the group consisting of O, CI, Br, I, cyanide, thiocyanate, or a mixture thereof; m, n and p are independently a decimal number from 0 to 5; m, n and p are not simultaneously equal to 0; m and n are not simultaneously equal to 0.

According to one embodiment, m, n and p are not equal to 0.

According to one embodiment, examples of perovskites include but are not limited to: Cs₃Bi₂I₉, Cs₃Bi₂Cl₉, Cs₃Bi₂Br₉, BFeO₃, KNbO₃, BaTiO₃, CH₃NH₃PbI₃, CH₃NH₃PbCl₃, CH₃NH₃PbBr₃, FAPbBr₃ (with FA formamidinium), FAPbCl₃, FAPbI₃, CsPbCl₃, CsPbBr₃, CsPbI₃, CsSnI₃, CsSnCl₃, CsSnBr₃, CsGeCl₃, CsGeBr₃, CsGeI₃, FAPbClₓBr_{y}I_{z} (with x, y and z independent decimal number from 0 to 5 and not simultaneously equal to 0).

According to one embodiment, the particle 12 is a metal particle (gold, silver, aluminum, magnesium, or copper, alloys).

According to one embodiment, the particle 12 is an inorganic semiconductor or insulator which can be coated with organic compounds.

According to one embodiment, the inorganic semiconductor or insulator can be, for instance, group IV semiconductors (for instance, Carbon, Silicon, Germanium), group III-V compound semiconductors (for instance, Gallium Nitride, Indium Phosphide, Gallium Arsenide), II-VI compound semiconductors (for instance, Cadmium Selenide, Zinc Selenide, Cadmium Sulfide, Mercury Telluride), inorganic oxides (for instance, Indium Tin Oxide, Aluminum Oxide, Titanium Oxide, Silicon Oxide), and other chalcogenides.

According to one embodiment, the particle 12 is a phosphor particle.

According to one embodiment, examples of phosphor particles include but are not limited to:
rare earth doped garnets or garnets such as for example Y₃Al₅O₁₂, Y₃Ga₅O₁₂, Y₃Fe₂(FeO₄)₃, Y₃Fe₅O₁₂, Y₄Al₂O₉, YAlO₃, RE₃₋ₙAl₅O₁₂:Ceₙ (RE=Y, Gd, Tb, Lu), Gd₃Al₅O₁₂, Gd₃Ga₅O₁₂, Lu₃Al₅O₁₂, Fe₃Al₂(SiO₄)₃, (Lu_{(1-x-y)}AₓCe_{y})₃B_{z}Al₅O₁₂C_{2z} with A=at least one of Sc, La, Gd, Tb or mixture thereof, B at least one of Mg, Sr, Ca, Ba or mixture thereof, C at least one of F, C, Br, I or mixture thereof, 0≤x≤0.5, 0.001≤y≤0.2, and 0.001≤z≤0.5, (Lu_{0.90}Gd_{0.07}Ce_{0.03})₃Sr_{0.34}Al₅O₁₂F_{0.68}, Mg₃Al₂(SiO₄)₃, Mn₃Al₂(SiO₄)₃, Ca₃Fe₂(SiO₄)₃, Ca₃Al₂(SiO₄)₃, Ca₃Cr₂(SiO₄)₃, Al₅Lu₃O₁₂, GAL, GaYAG, TAG, GAL, LuAG, YAG;
doped nitridres such as europium doped CaAlSiN₃, Sr(LiAl₃N₄):Eu, SrMg₃SiN₄:Eu, La₃Si₆N₁₁:Ce, (Ca,Sr)AlSiN₃:Eu, (Ca_{0.2}Sr_{0.8})AlSiN₃, (Ca, Sr, Ba)₂Si₅N₈:Eu;
sulfide-based phosphors such as for example CaS:Eu, SrS:Eu;
A₂(MF₆): Mn⁴⁺ wherein A comprises Na, K, Rb, Cs, or NH₄ and M comprises Si, Ti, Zr, or Mn, such as for example Mn⁴⁺ doped potassium fluorosilicate (PFS), K₂(SiF₆):Mn⁴⁺ or K₂(TiF₆):Mn⁴⁺, Na₂SnF₆:Mn⁴⁺, Cs₂SnF₆:Mn⁴⁺, Na₂SiF₆:Mn⁴⁺, Na₂GeF₆:Mn⁴⁺;
oxinitrides such as for example europium doped (Li, Mg, Ca, Y)-α-SiAlON, SrAl₂Si₃ON₆:Eu, EuₓSi_{6-z}Al_{z}O_{y}N_{8-y} (y=z−2x), Eu_{0.018}Si_{5.77}Al_{0.23}O_{0.194}N_{7.806}, SrSi₂O₂N₂:Eu, Pr³⁺ activated β-SiAlON:Eu;
silicates such as for example A₂Si(OD)₄:Eu with A=Sr, Ba, Ca, Mg, Zn or mixture thereof and D=F, Cl, S, N, Br or mixture thereof, (SrBaCa)₂SiO₄:Eu, Ba₂MgSi₂O₇:Eu, Ba₂SiO₄:Eu, Sr₃SiO_{5′} (Ca,Ce)₃(Sc,Mg)₂Si₃O₁₂;
carbonitrides such as for example Y₂Si₄N₆C, CsLnSi(CN₂)₄:Eu with Ln=Y, La or Gd;
oxycarbonitrides such as for example Sr₂Si₅N_{8-[(4x/3)+z]}CₓO_{3z/2} where 0<x≤5.0, 0.06≤x≤0.1 and x≠3z/2;
europium aluminates such as for example EuAl₆O₁₀, EuAl₂O₄;
barium oxides such as for example Ba_{0.93}Eu_{0.07}Al₂O₄;
halogenated garnets such as for example (Lu_{1-a-b-c}YₐTb_{b}A_{c})₃(Al_{1-d}B_{d})₅(O_{1-c}Cₑ)₁₂: Eu, where A is selected from the group consisting of Mg, Sr, Ca, Ba or mixture thereof; B is selected from the group consisting of Ga, In or mixture thereof; C is selected from the group consisting of F, Cl, Br or mixture thereof; and 0≤a≤1; 0≤b≤1; 0<c≤0.5; 0≤d≤1; and 0<e≤0.2;
((Sr_{3-z}M_{z})_{1-(x+w)}A_{w}Ceₓ)₃(Al_{1-y}Si_{y})O_{4+y+3(x-w)}F_{1-y-3}(x−w)′ wherein 0<x≤0.10, 0≤y≤0.5, 0≤z≤0.5, 0≤w≤x, A comprises Li, Na, K, Rb or mixture thereof; and M comprises Ca, Ba, Mg, Zn, Sn or mixture thereof, (Sr_{0.98}Na_{0.01}Ce_{0.01})₃(Al_{0.9}Si_{0.1})O_{4.1}F_{0.9}, (Sr_{0.595}Ca_{0.4}Ce_{0.005})₃(Al_{0.6}Si_{0.4})O_{4.415}F_{0.585};
BaMgAl₁₀O₁₇:Eu, Sr₅(PO₄)₃Cl:Eu, AlN:Eu, LaSi₃N₅:Ce, SrSi₉Al₁₉ON₃₁:Eu, SrSi₆₋ₓAlₓO₁₊ₓN₈₋ₓ:Eu;
rare earth doped particles;
doped particles;
any phosphors known by the skilled artisan;
or a mixture thereof.

According to one embodiment, examples of phosphor particles include but are not limited to:
blue phosphors such as for example BaMgAl₁₀O₁₇:Eu²⁺ or Co²⁺, Sr₅(PO₄)₃Cl:Eu²⁺, AlN:Eu²⁺, LaSi₃N₅:Ce³⁺, SrSi₉Al₁₉ON₃₁:Eu²⁺, SrSi₆₋ₓAlₓO₁₊ₓN₈₋ₓEu²⁺;
red phosphors such as for example Mn⁴⁺ doped potassium fluorosilicate (PFS), carbidonitrides, nitrides, sulfides (CaS), CaAlSiN₃:Eu³⁺, (Ca,Sr)AlSiN₃:Eu³⁺, (Ca, Sr, Ba)₂Si₅N₈:Eu³⁺, SrLiAl₃N₄:Eu³⁺, SrMg₃SiN₄:Eu³⁺, red emitting silicates;
orange phosphors such as for example orange emitting silicates, Li, Mg, Ca, or Y doped α-SiAlON;
green phosphors such as for example oxynitrides, carbidonitrides, green emitting silicates, LuAG, green GAL, green YAG, green GaYAG, β-SiAlON:Eu²⁺, SrSi₂O₂N₂:Eu²⁺; and
yellow phosphors such as for example yellow emitting silicates, TAG, yellow YAG, La₃Si₆N₁₁:Ce³⁺ (LSN), yellow GAL.

According to one embodiment, examples of phosphor particles include but are not limited to: blue phosphors; red phosphors; orange phosphors; green phosphors; and yellow phosphors.

According to one embodiment, the phosphor particle has an average size ranging from 0.1 μm to 50 μm.

According to one embodiment, the phosphor particle has an average size of at least 0.5 nm, 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 55 nm, 60 nm, 65 nm, 70 nm, 75 nm, 80 nm, 85 nm, 90 nm, 95 nm, 100 nm, 105 nm, 110 nm, 115 nm, 120 nm, 125 nm, 130 nm, 135 nm, 140 nm, 145 nm, 150 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, the aggregate 1 comprises one phosphor particle.

According to one embodiment, the particle 12 is a scintillator nanoparticle.

According to one embodiment, examples of scintillator nanoparticles include but are not limited to: NaI(Tl) (thallium-doped sodium iodide), CsI(Tl), CsI(Na), CsI(pure), CsF, KI(Tl), LiI(Eu), BaF₂, CaF₂(Eu), ZnS(Ag), CaWO₄, CdWO₄, YAG(Ce) (Y₃Al₅O₁₂(Ce)), GSO, LSO, LaCl₃(Ce) (lanthanum chloride doped with cerium), LaBr₃(Ce) (cerium-doped lanthanum bromide), LYSO (Lu_{1.8}Y_{0.2}SiO₅(Ce)), or a mixture thereof.

According to one embodiment, the particle 12 is a metal nanoparticle (gold, silver, aluminum, magnesium, or copper, alloys).

According to one embodiment, the particle 12 is an inorganic semiconductor or insulator which can be coated with organic compounds.

According to one embodiment, the inorganic semiconductor or insulator can be, for instance, group IV semiconductors (for instance, Carbon, Silicon, Germanium), group III-V compound semiconductors (for instance, Gallium Nitride, Indium Phosphide, Gallium Arsenide), II-VI compound semiconductors (for instance, Cadmium Selenide, Zinc Selenide, Cadmium Sulfide, Mercury Telluride), inorganic oxides (for instance, Indium Tin Oxide, Aluminum Oxide, Titanium Oxide, Silicon Oxide), and other chalcogenides.

According to one embodiment, the semiconductor nanocrystal comprises a material of formula MₓN_{y}E_{z}A_{w}, wherein: M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; N is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; E is selected from the group consisting of O, S, Se, Te, C, N, P, As, Sb, F, Cl, Br, I, or a mixture thereof; A is selected from the group consisting of O, S, Se, Te, C, N, P, As, Sb, F, Cl, Br, I, or a mixture thereof; x, y, z and w are independently a decimal number from 0 to 5; x, y, z and w are not simultaneously equal to 0; x and y are not simultaneously equal to 0; z and w may not be simultaneously equal to 0.

According to one embodiment, the semiconductor nanocrystal comprises a core comprising a material of formula MₓN_{y}E_{z}A_{w}, wherein: M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; N is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; E is selected from the group consisting of O, S, Se, Te, C, N, P, As, Sb, F, Cl, Br, I, or a mixture thereof; A is selected from the group consisting of O, S, Se, Te, C, N, P, As, Sb, F, Cl, Br, I, or a mixture thereof; x, y, z and w are independently a decimal number from 0 to 5; x, y, z and w are not simultaneously equal to 0; x and y are not simultaneously equal to 0; z and w may not be simultaneously equal to 0.

According to one embodiment, the semiconductor nanocrystal comprises a material of formula MₓN_{y}E_{z}A_{w}, wherein M and/or N is selected from the group consisting of Ib, IIa, IIb, IIIa, IIIb, IVa, IVb, Va, Vb, VIb, VIIb, VIII, or mixtures thereof; E and/or A is selected from the group consisting of Va, VIa, VIIa, or mixtures thereof; x, y, z and w are independently a decimal number from 0 to 5; x, y, z and w are not simultaneously equal to 0; x and y are not simultaneously equal to 0; z and w may not be simultaneously equal to 0.

According to one embodiment, the semiconductor nanocrystal comprises a material of formula MₓE_{y}, wherein M is selected from group consisting of Cd, Zn, Hg, Ge, Sn, Pb, Cu, Ag, Fe, In, Al, Ti, Mg, Ga, Tl, Mo, Pd, W, Cs, Pb, or a mixture thereof; x and y are independently a decimal number from 0 to 5, x and y are not simultaneously equal to 0.

According to one embodiment, the semiconductor nanocrystal comprises a material of formula MₓE_{y}, wherein E is selected from group consisting of S, Se, Te, O, P, C, N, As, Sb, F, Cl, Br, I, or a mixture thereof; x and y are independently a decimal number from 0 to 5, x and y are not simultaneously equal to 0.

According to one embodiment, the semiconductor nanocrystal is selected from the group consisting of a IIb-VIa, IVa-VIa, Ib-IIIa-VIa, IIb-IVa-Va, Ib-VIa, VIII-VIa, IIb-Va, IIIa-VIa, IVb-VIa, IIa-VIa, IIIa-Va, IIIa-VIa, VIb-VIa, and Va-VIa semiconductor.

According to one embodiment, the semiconductor nanocrystal comprises a material MₓN_{y}E_{z}A_{w} selected from the group consisting of CdS, CdSe, CdTe, ZnS, ZnSe, ZnTe, HgS, HgSe, HgTe, HgO, GeS, GeSe, GeTe, SnS, SnSe, SnTe, PbS, PbSe, PbTe, GeS₂, GeSe₂, SnS₂, SnSe₂, CuInS₂, CuInSe₂, AgInS₂, AgInSe₂, CuS, Cu₂S, Ag₂S, Ag₂Se, Ag₂Te, FeS, FeS₂, InP, Cd₃P₂, Zn₃P₂, CdO, ZnO, FeO, Fe₂O₃, Fe₃O₄, Al₂O₃, TiO₂, MgO, MgS, MgSe, MgTe, AlN, AlP, AlAs, AlSb, GaN, GaP, GaAs, GaSb, InN, InP, InAs, InSb, TlN, TlP, TlAs, TlSb, MoS₂, PdS, Pd₄S, WS₂, CsPbCl₃, PbBr₃, CsPbBr₃, CH₃NH₃PbI₃, CH₃NH₃PbCl₃, CH₃NH₃PbBr₃, CsPbI₃, FAPbBr₃ (with FA formamidinium), or a mixture thereof.

According to one embodiment, the particle 12 is a semiconductor nanoplatelet, nanosheet, nanoribbon, nanowire, nanodisk, nanocube, nanoring, magic size cluster, or sphere such as for example quantum dot.

According to one embodiment, the inorganic nanoparticle comprises an initial nanocrystal.

According to one embodiment, the inorganic nanoparticle comprises an initial colloidal nanocrystal.

According to one embodiment, the inorganic nanoparticle comprises an initial nanoplatelet.

According to one embodiment, the inorganic nanoparticle comprises an initial colloidal nanoplatelet.

According to one embodiment, the particle 12 is a semiconductor nanoplatelet, nanosheet, nanoribbon, nanowire, nanodisk, nanocube, magic size cluster, or nanoring.

According to one embodiment, the particle 12 is a core nanocrystal, wherein the core is not partially or totally covered with a shell comprising at least one layer of inorganic material and/or organic material.

According to one embodiment, the particle 12 is a core 123/shell 124 nanocrystal, wherein the core 123 is partially or totally covered with at least one shell 124 comprising at least one layer of inorganic material and/or organic material.

According to one embodiment, the core/shell semiconductor nanocrystal comprises at least one shell 124 comprising a material of formula MₓN_{y}E_{z}A_{w}, wherein: M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; N is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; E is selected from the group consisting of O, S, Se, Te, C, N, P, As, Sb, F, Cl, Br, I, or a mixture thereof; A is selected from the group consisting of O, S, Se, Te, C, N, P, As, Sb, F, Cl, Br, I, or a mixture thereof; and x, y, z and w are independently a decimal number from 0 to 5; x, y, z and w are not simultaneously equal to 0; x and y are not simultaneously equal to 0; z and w may not be simultaneously equal to 0.

According to one embodiment, the core/shell semiconductor nanocrystal comprises two shells (124, 125) comprising a material of formula MₓN_{y}E_{z}A_{w}, wherein: M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; N is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; E is selected from the group consisting of O, S, Se, Te, C, N, P, As, Sb, F, Cl, Br, I, or a mixture thereof; A is selected from the group consisting of O, S, Se, Te, C, N, P, As, Sb, F, Cl, Br, I, or a mixture thereof; and x, y, z and w are independently a decimal number from 0 to 5; x, y, z and w are not simultaneously equal to 0; x and y are not simultaneously equal to 0; z and w may not be simultaneously equal to 0.

According to one embodiment, the shell 124 comprises a different material than the material of core 123.

According to one embodiment, the shell 124 comprises the same material than the material of core 123.

According to one embodiment, the shells (124, 125) comprise different materials.

According to one embodiment, the shells (124, 125) comprise the same material.

According to one embodiment, the core/shell semiconductor nanocrystal comprises at least one shell comprising a material of formula MₓN_{y}E_{z}A_{w}, wherein M, N, E and A are as described hereabove.

According to one embodiment, examples of core/shell semiconductor nanocrystals include but are not limited to: CdSe/CdS, CdSe/CdₓZn₁₋ₓS, CdSe/CdS/ZnS, CdSe/ZnS/CdS, CdSe/ZnS, CdSe/CdₓZn₁₋ₓS/ZnS , CdSe/ZnS/CdₓZn₁₋ₓS, CdSe/CdS/CdₓZn₁₋ₓS, CdSe/ZnSe/ZnS, CdSe/ZnSe/CdₓZn₁₋ₓS, CdSeₓS₁₋ₓ/CdS, CdSeₓSi₁₋ₓ/CdZnS, CdSeₓSi₁₋ₓ/CdS/ZnS, CdSeₓSi₁₋ₓ/ZnS/CdS, CdSeₓSi₁₋ₓ/ZnS, CdSeₓSi₁₋ₓ/CdₓZn₁₋ₓS/ZnS, CdSeₓSi₁₋ₓ/ZnS/CdₓZn₁₋ₓS, CdSeₓSi₁₋ₓ/CdS/CdₓZn₁₋ₓS, CdSeₓS₁₋ₓ/ZnSe/ZnS, CdSeₓS₁₋ₓ/ZnSe/CdₓZn₁₋ₓS, InP/CdS, InP/CdS/ZnSe/ZnS, InP/CdₓZn₁₋ₓS, InP/CdS/ZnS, InP/ZnS/CdS, InP/ZnS, InP/CdₓZn₁₋ₓS/ZnS, InP/ZnS/CdₓZn₁₋ₓS, InP/CdS/CdₓZn₁₋ₓS, InP/ZnSe, InP/ZnSe/ZnS, InP/ZnSe/CdₓZn₁₋ₓS, InP/ZnSeₓS₁₋ₓ, InP/GaP/ZnS, InₓZn₁₋ₓP/ZnS, InₓZn₁₋ₓP/ZnS, InP/GaP/ZnSe, InP/ZnS/ZnSe, InP/GaP/ZnSe/ZnS, InP/ZnS/ZnSe/ZnS, wherein x is a decimal number from 0 to 1.

According to one embodiment, the core/shell semiconductor nanocrystal is ZnS rich, i.e. the last monolayer of the shell is a ZnS monolayer.

According to one embodiment, the core/shell semiconductor nanocrystal is CdS rich, i.e. the last monolayer of the shell is a CdS monolayer.

According to one embodiment, the core/shell semiconductor nanocrystal is CdₓZn₁₋ₓS rich, i.e. the last monolayer of the shell is a CdₓZn₁₋ₓS monolayer, wherein x is a decimal number from 0 to 1.

According to one embodiment, the last atomic layer of the semiconductor nanocrystal is a cation-rich monolayer of cadmium, zinc or indium.

According to one embodiment, the last atomic layer of the semiconductor nanocrystal is an anion-rich monolayer of sulfur, selenium or phosphorus.

According to one embodiment, the particle 12 is a core/crown semiconductor nanocrystal.

According to one embodiment, the core/crown semiconductor nanocrystal comprises at least one crown 127 comprising a material of formula MₓN_{y}E_{z}A_{w}, wherein: M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; N is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; E is selected from the group consisting of O, S, Se, Te, C, N, P, As, Sb, F, Cl, Br, I, or a mixture thereof; A is selected from the group consisting of O, S, Se, Te, C, N, P, As, Sb, F, Cl, Br, I, or a mixture thereof; and x, y, z and w are independently a decimal number from 0 to 5; x, y, z and w are not simultaneously equal to 0; x and y are not simultaneously equal to 0; z and w may not be simultaneously equal to 0.

According to one embodiment, the core/crown semiconductor nanocrystal comprises at least one crown 127 comprising a material of formula MₓN_{y}E_{z}A_{w}, wherein M, N, E and A are as described hereabove.

According to one embodiment, the crown 127 comprises a different material than the material of core 123.

According to one embodiment, the crown 127 comprises the same material than the material of core 123.

According to one embodiment, the semiconductor nanocrystal is atomically flat. In this embodiment, the atomically flat semiconductor nanocrystal may be evidenced by transmission electron microscopy or fluorescence scanning microscopy, energy-dispersive X-ray spectroscopy (EDS), X-Ray photoelectron spectroscopy (XPS), UV photoelectron spectroscopy (UPS), electron energy loss spectroscopy (EELS), photoluminescence or any other characterization means known by the person skilled in the art.

According to one embodiment, the semiconductor nanocrystal comprises an atomically flat core. In this embodiment, the atomically flat core may be evidenced by transmission electron microscopy or fluorescence scanning microscopy, energy-dispersive X-ray spectroscopy (EDS),

X-Ray photoelectron spectroscopy (XPS), UV photoelectron spectroscopy (UPS), electron energy loss spectroscopy (EELS), photoluminescence or any other characterization means known by the person skilled in the art.

According to one embodiment, the semiconductor nanocrystal is a semiconductor nanoplatelet.

According to one embodiment, the aggregate 1 comprises at least 1%, 5%, 10%, 15%, 20%, 25%, 30%, 35%, 40%, 45%, 50%, 55%, 60%, 65%, 70%, 75%, 80%, 85%, 90%, 95%, or 100% of semiconductor nanoplatelets.

According to one embodiment, the particle 12 comprises at least 1%, 5%, 10%, 15%, 20%, 25%, 30%, 35%, 40%, 45%, 50%, 55%, 60%, 65%, 70%, 75%, 80%, 85%, 90%, 95%, or 100% of semiconductor nanoplatelets.

According to one embodiment, the inorganic nanoparticle comprises at least 1%, 5%, 10%, 15%, 20%, 25%, 30%, 35%, 40%, 45%, 50%, 55%, 60%, 65%, 70%, 75%, 80%, 85%, 90%, 95%, or 100% of semiconductor nanoplatelets.

According to one embodiment, the semiconductor nanocrystal comprises at least 1%, 5%, 10%, 15%, 20%, 25%, 30%, 35%, 40%, 45%, 50%, 55%, 60%, 65%, 70%, 75%, 80%, 85%, 90%, 95%, or 100% of semiconductor nanoplatelets.

According to one embodiment, the semiconductor nanocrystal comprises an initial nanoplatelet.

According to one embodiment, the semiconductor nanocrystal comprises an initial colloidal nanoplatelet.

According to one embodiment, the semiconductor nanoplatelet is atomically flat. In this embodiment, the atomically flat nanoplatelet may be evidenced by transmission electron microscopy or fluorescence scanning microscopy, energy-dispersive X-ray spectroscopy (EDS), X-Ray photoelectron spectroscopy (XPS), UV photoelectron spectroscopy (UPS), electron energy loss spectroscopy (EELS), photoluminescence or any other characterization means known by the person skilled in the art.

According to one embodiment, the semiconductor nanoplatelet comprises an initial nanocrystal.

According to one embodiment, the semiconductor nanoplatelet comprises an initial colloidal nanocrystal.

According to one embodiment, the semiconductor nanoplatelet comprises an initial nanoplatelet.

According to one embodiment, the semiconductor nanoplatelet comprises an initial colloidal nanoplatelet.

According to one embodiment, the semiconductor nanoplatelet is quasi-2D.

According to one embodiment, the semiconductor nanoplatelet comprises an atomically flat core. In this embodiment, the atomically flat core may be evidenced by transmission electron microscopy or fluorescence scanning microscopy, energy-dispersive X-ray spectroscopy (EDS), X-Ray photoelectron spectroscopy (XPS), UV photoelectron spectroscopy (UPS), electron energy loss spectroscopy (EELS), photoluminescence, or any other characterization means known by the person skilled in the art.

According to one embodiment, the semiconductor nanoplatelet is 2D-shaped.

According to one embodiment, the semiconductor nanoplatelet has a thickness tuned at the atomic level.

According to one embodiment, the core 123 of the semiconductor nanoplatelet is an initial nanoplatelet.

According to one embodiment, the initial nanoplatelet comprises a material of formula MₓN_{y}E_{z}A_{w}, wherein M, N, E and A are as described hereabove.

According to one embodiment, the thickness of the initial nanoplatelet comprises an alternate of atomic layers of M and E.

According to one embodiment, the thickness of the initial nanoplatelet comprises an alternate of atomic layers of M, N, A and E.

According to one embodiment, a semiconductor nanoplatelet comprises an initial nanoplatelet partially or completely covered with at least one layer of additional material.

According to one embodiment, the at least one layer of additional material comprises a material of formula MₓN_{y}E_{z}A_{w}, wherein M, N, E and A are as described hereabove.

According to one embodiment, a semiconductor nanoplatelet comprises an initial nanoplatelet partially or completely covered on a least one facet by at least one layer of additional material.

In one embodiment wherein several layers cover all or part of the initial nanoplatelet, these layers can be composed of the same material or composed of different materials.

In one embodiment wherein several layers cover all or part of the initial nanoplatelet, these layers can be composed such as to form a gradient of materials.

In one embodiment, the initial nanoplatelet is an inorganic colloidal nanoplatelet.

In one embodiment, the initial nanoplatelet comprised in the semiconductor nanoplatelet has preserved its 2D structure.

In one embodiment, the material covering the initial nanoplatelet is inorganic.

In one embodiment, at least one part of the semiconductor nanoplatelet has a thickness greater than the thickness of the initial nanoplatelet.

In one embodiment, the semiconductor nanoplatelet comprises the initial nanoplatelet totally covered with at least one layer of material.

In one embodiment, the semiconductor nanoplatelet comprises the initial nanoplatelet totally covered with a first layer of material, said first layer being partially or completely covered with at least a second layer of material.

In one embodiment, the initial nanoplatelet has a thickness of at least 0.3 nm, 0.4 nm, 0.5 nm, 0.6 nm, 0.7 nm, 0.8 nm, 0.9 nm, 1.0 nm, 1.1 nm, 1.2 nm, 1.3 nm, 1.4 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 15.5 nm, 16 nm, 16.5 nm, 17 nm, 17.5 nm, 18 nm, 18.5 nm, 19 nm, 19.5 nm, 20 nm, 30 nm, 40 nm, 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, or 500 nm.

According to one embodiment, the thickness of the initial nanoplatelet is smaller than at least one of the lateral dimensions (length or width) of the initial nanoplatelet by a factor (aspect ratio) of at least 1.5; of at least 2; at least 2.5; at least 3; at least 3.5; at least 4; at least 4.5; at least 5; at least 5.5; at least 6; at least 6.5; at least 7; at least 7.5; at least 8; at least 8.5; at least 9; at least 9.5; at least 10; at least 10.5; at least 11; at least 11.5; at least 12; at least 12.5; at least 13; at least 13.5; at least 14; at least 14.5; at least 15; at least 15.5; at least 16; at least 16.5; at least 17; at least 17.5; at least 18; at least 18.5; at least 19; at least 19.5; at least 20; at least 25; at least 30; at least 35; at least 40; at least 45; at least 50; at least 55; at least 60; at least 65; at least 70; at least 75; at least 80; at least 85; at least 90; at least 95; at least 100; at least 150; at least 200; at least 250; at least 300; at least 350; at least 400; at least 450; at least 500; at least 550; at least 600; at least 650; at least 700; at least 750; at least 800; at least 850; at least 900; at least 950; or at least 1000.

In one embodiment, the initial nanoplatelet has lateral dimensions of at least 2 nm, 3 nm, 4 nm, 5 nm, 6 nm, 7 nm, 8 nm, 9 nm, 10 nm, 15 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 105 nm, 110 nm, 115 nm, 120 nm, 125 nm, 130 nm, 135 nm, 140 nm, 145 nm, 150 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, the semiconductor nanoplatelet has a thickness of at least 0.3 nm, 0.4 nm, 0.5 nm, 0.6 nm, 0.7 nm, 0.8 nm, 0.9 nm, 1.0 nm, 1.1 nm, 1.2 nm, 1.3 nm, 1.4 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 15.5 nm, 16 nm, 16.5 nm, 17 nm, 17.5 nm, 18 nm, 18.5 nm, 19 nm, 19.5 nm, 20 nm, 30 nm, 40 nm, 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, or 500 nm.

According to one embodiment, the semiconductor nanoplatelet has lateral dimensions of at least 2 nm, 3 nm, 4 nm, 5 nm, 6 nm, 7 nm, 8 nm, 9 nm, 10 nm, 15 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 105 nm, 110 nm, 115 nm, 120 nm, 125 nm, 130 nm, 135 nm, 140 nm, 145 nm, 150 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, the thickness of the semiconductor nanoplatelet is smaller than at least one of the lateral dimensions (length or width) of the semiconductor nanoplatelet by a factor (aspect ratio) of at least 1.5; of at least 2; at least 2.5; at least 3; at least 3.5; at least 4; at least 4.5; at least 5; at least 5.5; at least 6; at least 6.5; at least 7; at least 7.5; at least 8; at least 8.5; at least 9; at least 9.5; at least 10; at least 10.5; at least 11; at least 11.5; at least 12; at least 12.5; at least 13; at least 13.5; at least 14; at least 14.5; at least 15; at least 15.5; at least 16; at least 16.5; at least 17; at least 17.5; at least 18; at least 18.5; at least 19; at least 19.5; at least 20; at least 25; at least 30; at least 35; at least 40; at least 45; at least 50; at least 55; at least 60; at least 65; at least 70; at least 75; at least 80; at least 85; at least 90; at least 95; at least 100; at least 150; at least 200; at least 250; at least 300; at least 350; at least 400; at least 450; at least 500; at least 550; at least 600; at least 650; at least 700; at least 750; at least 800; at least 850; at least 900; at least 950; or at least 1000.

According to one embodiment, the semiconductor nanoplatelet is obtained by a process of growth in the thickness of at least one face of at least one initial nanoplatelet by deposition of a film or a layer of material on the surface of the at least one initial nanoplatelet; or a process lateral growth of at least one face of at least one initial nanoplatelet by deposition of a film or a layer of material on the surface of the at least one initial nanoplatelet; or any methods known by the person skilled in the art.

In one embodiment, the semiconductor nanoplatelet can comprise the initial nanoplatelet and 1, 2, 3, 4, 5 or more layers covering all or part of the initial nanoplatelet, said layers begin of same composition as the initial nanoplatelet or being of different composition than the initial nanoplatelet or being of different composition one another.

In one embodiment, the semiconductor nanoplatelet can comprise the initial nanoplatelet and at least 1, 2, 3, 4, 5 or more layers in which the first deposited layer covers all or part of the initial nanoplatelet and the at least second deposited layer covers all or part of the previously deposited layer, said layers being of same composition as the initial nanoplatelet or being of different composition than the initial nanoplatelet and possibly of different compositions one another.

According to one embodiment, the semiconductor nanoplatelet has a thickness quantified by a MₓN_{y}E_{z}A_{w} monolayer, wherein M, N, E and A are as described hereabove.

According to one embodiment, the core 123 of the semiconductor nanoplatelet has a thickness of at least 1 MₓN_{y}E_{z}A_{w} monolayer, at least 2 MₓN_{y}E_{z}A_{w} monolayers, at least 3 MₓN_{y}E_{z}A_{w} monolayers, at least 4 MₓN_{y}E_{z}A_{w} monolayers, at least 5 MₓN_{y}E_{z}A_{w} monolayers, wherein M, N, E and A are as described hereabove.

According to one embodiment, the shell 124 of the semiconductor nanoplatelet has a thickness quantified by a MₓN_{y}E_{z}A_{w} monolayer, wherein M, N, E and A are as described hereabove, wherein M, N, E and A are as described hereabove.

According to one embodiment, the particle 12 is a hybrid particle comprising a hybrid material as described hereabove.

According to one embodiment, the at least one particle 12 is selected from metal particles, halide particles, chalcogenide particles, phosphide particles, sulfide particles, metalloid particles, metallic alloy particles, phosphor particles, perovskite particles, ceramic particles such as for example oxide particles, carbide particles, nitride particles, or a mixture thereof, preferably is a semiconductor nanocrystal.

According to one embodiment, the at least one particle 12 and the material 11 are not chemically compatible. In this embodiment, the at least one particle 12 and the material 11 are homogeneously mixed together during the formation of the aggregate 1.

According to one embodiment, the at least one particle 12 and the material 11 are chemically compatible. In this embodiment, the at least one particle 12 and the material 11 are homogeneously mixed together during the formation of the aggregate 1.

According to one embodiment, the particle 12 is a homostructure. In this embodiment, the particle 12 does not comprise a shell or a layer of a material surrounding (partially or totally) said particle 12.

According to one embodiment, as illustrated in FIG. 6A, the particle 12 is a core particle 123 without a shell.

According to one embodiment, the particle 12 does not comprise an organic shell or an organic layer. In this embodiment, the particle 12 is not covered by any organic ligand or polymer shell.

According to one embodiment illustrated in FIG. 6B, the particle 12 is a heterostructure, comprising a core 123 and at least one shell 124.

According to one embodiment, the shell 124 is not an organic shell. In this embodiment, the particle 12 is not covered by any organic ligand or by a polymeric shell.

According to one embodiment, the particle 12 is coated by an organic layer or shell comprising an organic material as described hereabove

According to one embodiment, the particle 12 is coated by an organic layer comprising organic molecules or polymer chains.

According to one embodiment, the particle 12 and/or the nanoparticle 122 comprise ligands on its surface.

According to one embodiment, the particle 12 is coated by an organic layer comprising polymerizable groups. In this embodiment, polymerizable groups are capable of undergoing a polymerization reaction. Polymerizable groups are as described hereabove.

According to one embodiment, examples of polymerizable groups include but are not limited to: vinyl monomers, acrylate monomers, methacrylate monomers, ethylacrylate monomers, acrylamide monomers, methacrylamide monomers, ethyl acrylamide monomers, ethylene glycol monomers, epoxide monomers, glycidyl monomers, olefin monomers, norbornyl monomers, isocyanide monomers, and any of the above mention in di/tri functional group format, or a mixture thereof.

According to one embodiment, the particle 12 is coated by an inorganic layer or shell comprising an inorganic material as described hereabove

According to one embodiment, the particle 12 is coated by a hybrid layer or shell comprising a hybrid material as described hereabove

According to one embodiment, the particle 12 is a core 123/shell 124 particle, wherein the core 123 is partially or totally covered with at least one shell 124 comprising at least one layer of material.

According to one embodiment, as illustrated in FIG. 6B-C and FIG. 6F-G, the particle 12 is a core 123/shell 124 particle, wherein the core 123 is covered with at least one shell (124, 125).

According to one embodiment, the at least one shell (124, 125) has a thickness of at least 0.1 nm, 0.2 nm, 0.3 nm, 0.4 nm, 0.5 nm, 1 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 15.5 nm, 16 nm, 16.5 nm, 17 nm, 17.5 nm, 18 nm, 18.5 nm, 19 nm, 19.5 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, the shell 124 of the particle 12 has a thickness homogeneous all along the core 123, i.e. the shell 124 of the particle 12 has a same thickness all along the core 123.

According to one embodiment, the shell 124 of the particle 12 has a thickness heterogeneous along the core 123, i.e. said thickness varies along the core 123.

According to one embodiment, the particle 12 is a core 123/shell 124 particle, wherein the core 123 and the shell 124 are composed of the same material.

According to one embodiment, the particle 12 is a core 123/shell 124 particle, wherein the core 123 and the shell 124 are composed of at least two different materials.

According to one embodiment, the shell 124 of the core/shell particle 12 comprises an inorganic material. In this embodiment, said inorganic material is the same or different than the material comprised in the core 123 of the core/shell particle 12.

According to one embodiment, the shell 124 of the core/shell particle 12 comprises an organic material. In this embodiment, said organic material is the same or different than the material comprised in the core 123 of the core/shell particle 12.

According to one embodiment, the shell 124 of the core/shell particle 12 comprises a hybrid material. In this embodiment, said hybrid material is the same or different than the material comprised in the core 123 of the core/shell particle 12.

According to one embodiment, the shell 124 of the core/shell particle 12 consists of an inorganic material. In this embodiment, said inorganic material is the same or different than the material comprised in the core 123 of the core/shell particle 12.

According to one embodiment, the shell 124 of the core/shell particle 12 consists of an organic material. In this embodiment, said organic material is the same or different than the material comprised in the core 123 of the core/shell particle 12.

According to one embodiment, the shell 124 of the core/shell particle 12 consists of a hybrid material. In this embodiment, said hybrid material is the same or different than the material comprised in the core 123 of the core/shell particle 12.

According to one embodiment, the particle 12 is a core 123/shell 124 particle, wherein the core 123 is a luminescent core covered with at least one shell 124 selected in the group of magnetic material, plasmonic material, dielectric material, piezoelectric material, pyro-electric material, ferro-electric material, light scattering material, electrically insulating material, thermally insulating material or catalytic material.

According to one embodiment, the particle 12 is a core 123/shell 124 particle, wherein the core 123 is a magnetic core covered with at least one shell 124 selected in the group of luminescent material, plasmonic material, dielectric material, piezoelectric material, pyro-electric material, ferro-electric material, light scattering material, electrically insulating material, thermally insulating material or catalytic material.

According to one embodiment, the particle 12 is a core 123/shell 124 particle, wherein the core 123 is a plasmonic core covered with at least one shell 124 selected in the group of magnetic material, luminescent material, dielectric material, piezoelectric material, pyro-electric material, ferro-electric material, light scattering material, electrically insulating material, thermally insulating material or catalytic material.

According to one embodiment, the particle 12 is a core 123/shell 124 particle, wherein the core 123 is a dielectric core covered with at least one shell 124 selected in the group of magnetic material, plasmonic material, luminescent material, piezoelectric material, pyro-electric material, ferro-electric material, light scattering material, electrically insulating material, thermally insulating material or catalytic material.

According to one embodiment, the particle 12 is a core 123/shell 124 particle, wherein the core 123 is a piezoelectric core covered with at least one shell 124 selected in the group of magnetic material, plasmonic material, dielectric material, luminescent material, pyro-electric material, ferro-electric material, light scattering material, electrically insulating material, thermally insulating material or catalytic material.

According to one embodiment, the particle 12 is a core 123/shell 124 particle, wherein the core 123 is a pyro-electric core covered with at least one shell 124 selected in the group of magnetic material, plasmonic material, dielectric material, luminescent material, piezoelectric material, ferro-electric material, light scattering material, electrically insulating material, thermally insulating material or catalytic material.

According to one embodiment, the particle 12 is a core 123/shell 124 particle, wherein the core 123 is a ferro-electric core covered with at least one shell 124 selected in the group of magnetic material, plasmonic material, dielectric material, luminescent material, piezoelectric material, pyro-electric material, light scattering material, electrically insulating material, thermally insulating material or catalytic material.

According to one embodiment, the particle 12 is a core 123/shell 124 particle, wherein the core 123 is a light scattering core covered with at least one shell 124 selected in the group of magnetic material, plasmonic material, dielectric material, luminescent material, piezoelectric material, pyro-electric material, ferro-electric material, electrically insulating material, thermally insulating material or catalytic material.

According to one embodiment, the particle 12 is a core 123/shell 124 particle, wherein the core 123 is an electrically insulating core covered with at least one shell 124 selected in the group of magnetic material, plasmonic material, dielectric material, luminescent material, piezoelectric material, pyro-electric material, ferro-electric material, light scattering material, thermally insulating material or catalytic material.

According to one embodiment, the particle 12 is a core 123/shell 124 particle, wherein the core 123 is a thermally insulating core covered with at least one shell 124 selected in the group of magnetic material, plasmonic material, dielectric material, luminescent material, piezoelectric material, pyro-electric material, ferro-electric material, light scattering material, electrically insulating material or catalytic material.

According to one embodiment, the particle 12 is a core 123/shell 124 particle, wherein the core 123 is a catalytic core covered with at least one shell 124 selected in the group of magnetic material, plasmonic material, dielectric material, luminescent material, piezoelectric material, pyro-electric material, ferro-electric material, light scattering material, electrically insulating material or thermally insulating material.

According to one embodiment, the particle 12 is a core 123/shell 126 particle, wherein the core 123 is covered with an insulator shell 126. In this embodiment, the insulator shell 126 prevents the aggregation of the cores 123.

According to one embodiment, the insulator shell 126 has a thickness of at least 0.1 nm, 0.2 nm, 0.3 nm, 0.4 nm, 0.5 nm, 1 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 15.5 nm, 16 nm, 16.5 nm, 17 nm, 17.5 nm, 18 nm, 18.5 nm, 19 nm, 19.5 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, as illustrated in 6D and FIG. 6H, the particle 12 is a core 123/shell (124, 125, 126) particle, wherein the core 123 is covered with at least one shell (124, 125) and an insulator shell 126.

According to one embodiment, the shells (124, 125, 126) covering the core 123 of the particle 12 may be composed of the same material.

According to one embodiment, the shells (124, 125, 126) covering the core 123 of the particle 12 may be composed of at least two different materials.

According to one embodiment, the shells (124, 125, 126) covering the core 123 of the particle 12 may have the same thickness.

According to one embodiment, the shells(124, 125, 126) covering the core 123 of the particle 12 may have different thickness.

According to one embodiment, the particle 12 is a core 123/insulator shell 126 particle, wherein examples of insulator shell 126 include but are not limited to: non-porous SiO₂, mesoporous SiO₂, non-porous MgO, mesoporous MgO, non-porous ZnO, mesoporous ZnO, non-porous Al₂O₃, mesoporous Al₂O₃, non-porous ZrO₂, mesoporous ZrO₂, non-porous TiO₂, mesoporous TiO₂, non-porous SnO₂, mesoporous SnO₂, or a mixture thereof. Said insulator shell 126 acts as a supplementary barrier against oxidation and can drain away the heat if it is a good thermal conductor.

According to one embodiment, as illustrated in FIG. 6E, the particle 12 is a core 123/crown 127 particle with a 2D structure, wherein the core 123 is covered with at least one crown 127.

According to one embodiment, the particle 12 is a core 123/crown 127 particle, wherein the core 123 is covered with a crown 127 comprising at least one layer of material.

According to one embodiment, the particle 12 is a core 123/crown 127 particle, wherein the core 123 and the crown 127 are composed of the same material.

According to one embodiment, the particle 12 is a core 123/crown 127 particle, wherein the core 123 and the crown 127 are composed of at least two different materials.

According to one embodiment, the particle 12 is a core 123/crown 127 particle, wherein the core 123 is a lumminescent core covered with at least one crown 127 selected in the group of magnetic material, plasmonic material, dielectric material, piezoelectric material, pyro-electric material, ferro-electric material, light scattering material, electrically insulating material, thermally insulating material, or catalytic material.

According to one embodiment, the particle 12 is a core 123/crown 127 particle, wherein the core 123 is a magnetic core covered with at least one crown 127 selected in the group of luminescent material, plasmonic material, dielectric material, piezoelectric material, pyro-electric material, ferro-electric material, light scattering material, electrically insulating material, thermally insulating material, or catalytic material.

According to one embodiment, the particle 12 is a core 123/crown 127 particle, wherein the core 123 is a plasmonic core covered with at least one crown 127 selected in the group of magnetic material, luminescent material, dielectric material, piezoelectric material, pyro-electric material, ferro-electric material, light scattering material, electrically insulating material, thermally insulating material, or catalytic material.

According to one embodiment, the particle 12 is a core 123/crown 127 particle, wherein the core 123 is a dielectric core covered with at least one crown 127 selected in the group of magnetic material, plasmonic material, luminescent material, piezoelectric material, pyro-electric material, ferro-electric material, light scattering material, electrically insulating material, thermally insulating material, or catalytic material.

According to one embodiment, the particle 12 is a core 123/crown 127 particle, wherein the core 123 is a piezoelectric core covered with at least one crown 127 selected in the group of magnetic material, plasmonic material, dielectric material, luminescent material, pyro-electric material, ferro-electric material, light scattering material, electrically insulating material, thermally insulating material, or catalytic material.

According to one embodiment, the particle 12 is a core 123/crown 127 particle, wherein the core 123 is a pyro-electric core covered with at least one crown 127 selected in the group of magnetic material, plasmonic material, dielectric material, luminescent material, piezoelectric material, ferro-electric material, light scattering material, electrically insulating material, thermally insulating material, or catalytic material.

According to one embodiment, the particle 12 is a core 123/crown 127 particle, wherein the core 123 is a ferro-electric core covered with at least one crown 127 selected in the group of magnetic material, plasmonic material, dielectric material, luminescent material, piezoelectric material, pyro-electric material, light scattering material, electrically insulating material, thermally insulating material, or catalytic material.

According to one embodiment, the particle 12 is a core 123/crown 127 particle, wherein the core 123 is a light scattering core covered with at least one crown 127 selected in the group of magnetic material, plasmonic material, dielectric material, luminescent material, piezoelectric material, pyro-electric material, ferro-electric material, electrically insulating material, thermally insulating material, or catalytic material.

According to one embodiment, the particle 12 is a core 123/crown 127 particle, wherein the core 123 is an electrically insulating core covered with at least one crown 127 selected in the group of magnetic material, plasmonic material, dielectric material, luminescent material, piezoelectric material, pyro-electric material, ferro-electric material, light scattering material, thermally insulating material, or catalytic material.

According to one embodiment, the particle 12 is a core 123/crown 127 particle, wherein the core 123 is a thermally insulating core covered with at least one crown 127 selected in the group of magnetic material, plasmonic material, dielectric material, luminescent material, piezoelectric material, pyro-electric material, ferro-electric material, light scattering material, electrically insulating material, or catalytic material.

According to one embodiment, the particle 12 is a core 123/crown 127 particle, wherein the core 123 is a catalytic core covered with at least one crown 127 selected in the group of magnetic material, plasmonic material, dielectric material, luminescent material, piezoelectric material, pyro-electric material, ferro-electric material, light scattering material, electrically insulating material, or thermally insulating material.

According to one embodiment, the particle 12 is a core 123/crown 127 particle, wherein the core 123 is covered with an insulator crown. In this embodiment, the insulator crown prevents the aggregation of the cores 123.

According to one embodiment illustrated in FIG. 8, the particle 12 comprises a material 121 and at least one nanoparticle 122, wherein said at least one nanoparticle 122 is dispersed in the material 121.

The “double encapsulation” of nanoparticle 122 have several advantages: i) it allows a passivation of nanoparticle 122 surface, thus a better protection of said nanoparticle 122 from temperature, environment variations and deteriorating species like water and oxygen molecules therefore preventing the degradation of said nanoparticles 122; ii) in the case of luminescent nanoparticle 122 it helps preventing photoluminescence quantum yield decrease and photoluminescence decrease due to interaction with the environment; iii) it allows the scattering of the light emitted by a light source and the light resulting from the excitation of said nanoparticle 122.

According to one embodiment, the material 121 is an organic material as described hereabove.

According to one embodiment, the material 121 is an inorganic material as described hereabove.

According to one embodiment, the material 121 is a hybrid material as described hereabove.

According to one embodiment, the material 121 is the same as the material 11 as described hereabove.

According to one embodiment, the material 121 is different from the material 11 as described hereabove.

According to one embodiment, the size ratio between the aggregate 1 and the at least one nanoparticle 122 ranges from 12 to 100 000, preferably from 50 to 50 000, more preferably from 100 to 10 000, even more preferably from 200 to 1 000.

According to one embodiment, the size ratio between the particle 12 and the at least one nanoparticle 122 ranges from 1.25 to 1 000, preferably from 2 to 500, more preferably from 5 to 250, even more preferably from 5 to 100.

According to one embodiment, the volume ratio between the aggregate 1 and the at least one nanoparticle 122 ranges from 12 to 100 000, preferably from 50 to 50 000, more preferably from 100 to 10 000, even more preferably from 200 to 1 000.

According to one embodiment, the volume ratio between the particle 12 and the at least one nanoparticle 122 ranges from 1.25 to 1 000, preferably from 2 to 500, more preferably from 5 to 250, even more preferably from 5 to 100.

According to one embodiment, the nanoparticle 122 is a particle as described hereabove.

According to one embodiment, the nanoparticle 122 is an organic particle as described hereabove.

According to one embodiment, the nanoparticle 122 is an inorganic particle as described hereabove.

According to one embodiment, the nanoparticle 122 is a hybrid particle as described hereabove.

According to one embodiment, the nanoparticle 122 is an aggregate particle as described hereabove.

According to one embodiment, the particle 12 comprises at least two nanoparticles 122 dispersed in the material 121.

According to one embodiment, the particle 12 comprises a plurality of nanoparticles 122 dispersed in the material 121.

According to one embodiment, the particle 12 comprises at least 1, at least 2, at least 3, at least 4, at least 5, at least 6, at least 7, at least 8, at least 9, at least 10, at least 11, at least 12, at least 13, at least 14, at least 15, at least 16, at least 17, at least 18, at least 19, at least 20, at least 21, at least 22, at least 23, at least 24, at least 25, at least 26, at least 27, at least 28, at least 29, at least 30, at least 31, at least 32, at least 33, at least 34, at least 35, at least 36, at least 37, at least 38, at least 39, at least 40, at least 41, at least 42, at least 43, at least 44, at least 45, at least 46, at least 47, at least 48, at least 49, at least 50, at least 51, at least 52, at least 53, at least 54, at least 55, at least 56, at least 57, at least 58, at least 59, at least 60, at least 61, at least 62, at least 63, at least 64, at least 65, at least 66, at least 67, at least 68, at least 69, at least 70, at least 71, at least 72, at least 73, at least 74, at least 75, at least 76, at least 77, at least 78, at least 79, at least 80, at least 81, at least 82, at least 83, at least 84, at least 85, at least 86, at least 87, at least 88, at least 89, at least 90, at least 91, at least 92, at least 93, at least 94, at least 95, at least 96, at least 97, at least 98, at least 99, at least 100, at least 200, at least 300, at least 400, at least 500, at least 600, at least 700, at least 800, at least 900, at least 1000, at least 1500, at least 2000, at least 2500, at least 3000, at least 3500, at least 4000, at least 4500, at least 5000, at least 5500, at least 6000, at least 6500, at least 7000, at least 7500, at least 8000, at least 8500, at least 9000, at least 9500, at least 10000, at least 15000, at least 20000, at least 25000, at least 30000, at least 35000, at least 40000, at least 45000, at least 50000, at least 55000, at least 60000, at least 65000, at least 70000, at least 75000, at least 80000, at least 85000, at least 90000, at least 95000, or at least 100000 nanoparticles 122 dispersed in the material 121.

According to one embodiment, the particle 12 comprises a combination of at least two different nanoparticles 122. In this embodiment, the resulting particle 12 will exhibit different properties.

In a preferred embodiment, the particle 12 comprises at least two different nanoparticles 122, wherein at least one nanoparticle 122 emits at a peak wavelength in the range from 500 to 560 nm, and at least one nanoparticle 122 emits at a peak wavelength in the range from 600 to 2500 nm. In this embodiment, the particle 12 comprises at least one nanoparticle 122 emitting in the green region of the visible spectrum and at least one nanoparticle 122 emitting in the red region of the visible spectrum, thus the particle 12 paired with a blue LED will be a white light emitter.

In a preferred embodiment, the particle 12 comprises at least two different nanoparticles 122, wherein at least one nanoparticle 122 emits at a peak wavelength in the range from 400 to 490 nm, and at least one nanoparticle 122 emits at a peak wavelength in the range from 600 to 2500 nm. In this embodiment, the particle 12 comprises at least one nanoparticle 122 emitting in the blue region of the visible spectrum and at least one nanoparticle 122 emitting in the red region of the visible spectrum, thus the particle 12 will be a white light emitter.

In a preferred embodiment, the particle 12 comprises at least two different nanoparticles 122, wherein at least one nanoparticle 122 emits at a peak wavelength in the range from 400 to 490 nm, and at least one nanoparticle 122 emits at a peak wavelength in the range from 500 to 560 nm. In this embodiment, the particle 12 comprises at least one nanoparticle 122 emitting in the blue region of the visible spectrum and at least one nanoparticle 122 emitting in the green region of the visible spectrum.

In a preferred embodiment, the particle 12 comprises three different nanoparticles 122, wherein said nanoparticles 122 emit different emission wavelengths or colors.

In a preferred embodiment, the particle 12 comprises at least three different nanoparticles 122, wherein at least one nanoparticle 122 emits at a peak wavelength in the range from 400 to 490 nm, at least one nanoparticle 122 emits at a peak wavelength in the range from 500 to 560 nm and at least one nanoparticle 122 emits at a peak wavelength in the range from 600 to 2500 nm. In this embodiment, the particle 12 comprises at least one nanoparticle 122 emitting in the blue region of the visible spectrum, at least one nanoparticle 122 emitting in the green region of the visible spectrum and at least one nanoparticle 122 emitting in the red region of the visible spectrum.

In a preferred embodiment, the particle 12 does not comprise any nanoparticle 122 on its surface. In this embodiment, the at least one nanoparticle 122 is completely surrounded by the material 121.

According to one embodiment, at least 100%, 95%, 90%, 85%, 80%, 75%, 70%, 65%, 60%, 55%, 50%, 45%, 40%, 35%, 30%, 25%, 20%, 15%, 10%, 5%, or 1% of nanoparticles 122 are comprised in the material 121. In this embodiment, each of said nanoparticles 122 is completely surrounded by the material 121.

According to one embodiment, the particle 12 comprises at least 100%, 95%, 90%, 85%, 80%, 75%, 70%, 65%, 60%, 55%, 50%, 45%, 40%, 35%, 30%, 25%, 20%, 15%, 10%, 5%, 1% or 0% of nanoparticles 122 on its surface.

In a preferred embodiment, the particle 12 comprises nanoparticles 122 on its surface; wherein said nanoparticles 122 are aggregated.

According to one embodiment, the particle 12 comprises at least one nanoparticle 122 located on the surface of said particle 12.

According to one embodiment, the particle 12 comprises at least one nanoparticle 122 dispersed in the material 121, i.e. totally surrounded by said material 121; and at least one nanoparticle 122 located on the surface of said particle 12.

According to one embodiment, the particle 12 comprises at least one nanoparticle 122 dispersed in the material 121, wherein said at least one nanoparticle 122 emits at a peak wavelength in the range from 500 to 560 nm; and at least one nanoparticle 122 located on the surface of said particle 12, wherein said at least one nanoparticle 122 emits at a peak wavelength in the range from 600 to 2500 nm.

According to one embodiment, the particle 12 comprises at least one nanoparticle 122 dispersed in the material 121, wherein said at least one nanoparticle 122 emits at a peak wavelength in the range from 600 to 2500 nm; and at least one nanoparticle 122 located on the surface of said particle 12, wherein said at least one nanoparticle 122 emits at a peak wavelength in the range from 500 to 560 nm.

According to one embodiment, the at least one nanoparticle 122 is only located on the surface of said particle 12. This embodiment is advantageous as the at least one nanoparticle 122 will be better excited by the incident light than if said nanoparticle 122 was dispersed in the material 121.

According to one embodiment, the at least one nanoparticle 122 located on the surface of said particle 12 may be chemically or physically adsorbed on said surface.

According to one embodiment, the at least one nanoparticle 122 located on the surface of said particle 12 may be adsorbed on said surface.

According to one embodiment, the at least one nanoparticle 122 located on the surface of said particle 12 may be adsorbed with a cement on said surface.

According to one embodiment, examples of cement include but are not limited to: polymers, silicone, oxides, or a mixture thereof.

According to one embodiment, the at least one nanoparticle 122 located on the surface of said particle 12 may have at least 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 95%, or 100% of its volume trapped in the material 121.

According to one embodiment, the plurality of nanoparticles 122 is uniformly spaced on the surface of the particle 12.

According to one embodiment, each nanoparticle 122 of the plurality of nanoparticles 122 is spaced from its adjacent nanoparticle 122 by an average minimal distance. In this embodiment, the average minimal distance is as described hereabove.

According to one embodiment, a plurality of nanoparticles 122 is uniformly dispersed in the material 121.

The uniform dispersion of the plurality of nanoparticles 122 in the material 121 comprised in the particle 12 prevents the aggregation of said nanoparticles 122, thereby preventing the degradation of their properties. For example, in the case of inorganic fluorescent particles, a uniform dispersion will allow the optical properties of said particles to be preserved, and aggregation quenching can be avoided.

According to one embodiment, each nanoparticle 122 of the plurality of nanoparticles 122 is spaced from its adjacent nanoparticle 122 by an average minimal distance. In this embodiment, the average minimal distance is as described hereabove.

According to one embodiment, the at least one nanoparticle 122 is encapsulated into the material 121 during the formation of said material 121. For example, said nanoparticle 122 are not inserted in nor put in contact with the material 121 which have been previously obtained.

In a preferred embodiment, the particle 12 comprises at least one luminescent nanoparticle and at least one plasmonic nanoparticle.

According to one embodiment, the number of nanoparticles 122 comprised in the particle 12 depends mainly on the molar ratio or the mass ratio between the chemical species allowing to produce the material 121 and the at least one nanoparticle 122.

According to one embodiment, the at least one nanoparticle 122 represents at least 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, 91%, 92%, 93%, 94%, 95%, 96%, 97%, 98%, or 99% by weight of the particle 12.

According to one embodiment, the loading charge of the at least one nanoparticle 122 in the particle 12 is at least 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, 91%, 92%, 93%, 94%, 95%, 96%, 97%, 98%, or 99%.

According to one embodiment, the loading charge of the at least one nanoparticle 122 in the particle 12 is less than 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, 91%, 92%, 93%, 94%, 95%, 96%, 97%, 98%, or 99%.

According to one embodiment, the at least one nanoparticle 122 comprised in the particle 12 have a packing fraction of at least 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, or 95%.

According to one embodiment, the nanoparticles 122 comprised in the particle 12 are not aggregated.

According to one embodiment, the nanoparticles 122 comprised in the particle 12 do not touch, are not in contact.

According to one embodiment, the nanoparticles 122 comprised in the particle 12 are separated by material 121.

According to one embodiment, the at least one nanoparticle 122 comprised in the particle 12 can be individually evidenced.

According to one embodiment, the at least one nanoparticle 122 comprised in the particle 12 can be individually evidenced by transmission electron microscopy or fluorescence scanning microscopy, or any other characterization means known by the person skilled in the art.

According to one embodiment, the particle 12 comprises a combination of at least two different nanoparticles. In this embodiment, the particle 12, thus the resulting aggregate 1 will exhibit different properties.

According to one embodiment, the particle 12 comprises at least one luminescent nanoparticle and at least one nanoparticle 122 selected in the group of magnetic nanoparticle, plasmonic nanoparticle, dielectric nanoparticle, piezoelectric nanoparticle, pyro-electric nanoparticle, ferro-electric nanoparticle, light scattering nanoparticle, electrically insulating nanoparticle, thermally insulating nanoparticle, or catalytic nanoparticle.

In a preferred embodiment, the particle 12 comprises at least two different luminescent nanoparticles, wherein said luminescent nanoparticles emit different emission wavelengths.

In a preferred embodiment, the particle 12 comprises at least two different luminescent nanoparticles, wherein at least one luminescent nanoparticle emits at a peak wavelength in the range from 500 to 560 nm, and at least one luminescent nanoparticle emits at a peak wavelength in the range from 600 to 2500 nm. In this embodiment, the particle 12 comprises at least one luminescent nanoparticle emitting in the green region of the visible spectrum and at least one luminescent nanoparticle emitting in the red region of the visible spectrum, thus the aggregate 1 paired with a blue LED will be a white light emitter.

In a preferred embodiment, the particle 12 comprises at least two different luminescent nanoparticles, wherein at least one luminescent nanoparticle emits at a peak wavelength in the range from 400 to 490 nm, and at least one luminescent nanoparticle emits at a peak wavelength in the range from 600 to 2500 nm. In this embodiment, the particle 12 comprises at least one luminescent nanoparticle emitting in the blue region of the visible spectrum and at least one luminescent nanoparticle emitting in the red region of the visible spectrum, thus the aggregate 1 will be a white light emitter.

In a preferred embodiment, the particle 12 comprises at least two different luminescent nanoparticles, wherein at least one luminescent nanoparticle emits at a peak wavelength in the range from 400 to 490 nm, and at least one luminescent nanoparticle emits at a peak wavelength in the range from 500 to 560 nm. In this embodiment, the particle 12 comprises at least one luminescent nanoparticle emitting in the blue region of the visible spectrum and at least one luminescent nanoparticle emitting in the green region of the visible spectrum.

In a preferred embodiment, the particle 12 comprises three different luminescent nanoparticles, wherein said luminescent nanoparticles emit at different emission wavelengths.

In a preferred embodiment, the particle 12 comprises at least three different luminescent nanoparticles, wherein at least one luminescent nanoparticle emits at a peak wavelength in the range from 400 to 490 nm, at least one luminescent nanoparticle emits at a peak wavelength in the range from 500 to 560 nm and at least one luminescent nanoparticle emits at a peak wavelength in the range from 600 to 2500 nm. In this embodiment, the particle 12 comprises at least one luminescent nanoparticle emitting in the blue region of the visible spectrum, at least one luminescent nanoparticle emitting in the green region of the visible spectrum and at least one luminescent nanoparticle emitting in the red region of the visible spectrum.

According to one embodiment, the particle 12 comprises at least one magnetic nanoparticle and at least one nanoparticle 122 selected in the group of luminescent nanoparticle, plasmonic nanoparticle, dielectric nanoparticle, piezoelectric nanoparticle, pyro-electric nanoparticle, ferro-electric nanoparticle, light scattering nanoparticle, electrically insulating nanoparticle, thermally insulating nanoparticle, or catalytic nanoparticle.

According to one embodiment, the particle 12 comprises at least one plasmonic nanoparticle and at least one nanoparticle 122 selected in the group of luminescent nanoparticle, magnetic nanoparticle, dielectric nanoparticle, piezoelectric nanoparticle, pyro-electric nanoparticle, ferro-electric nanoparticle, light scattering nanoparticle, electrically insulating nanoparticle, thermally insulating nanoparticle, or catalytic nanoparticle.

According to one embodiment, the particle 12 comprises at least one dielectric nanoparticle and at least one nanoparticle 122 selected in the group of luminescent nanoparticle, magnetic nanoparticle, plasmonic nanoparticle, piezoelectric nanoparticle, pyro-electric nanoparticle, ferro-electric nanoparticle, light scattering nanoparticle, electrically insulating nanoparticle, thermally insulating nanoparticle, or catalytic nanoparticle.

According to one embodiment, the particle 12 comprises at least one piezoelectric nanoparticle and at least one nanoparticle 122 selected in the group of luminescent nanoparticle, magnetic nanoparticle, dielectric nanoparticle, plasmonic nanoparticle, pyro-electric nanoparticle, ferro-electric nanoparticle, light scattering nanoparticle, electrically insulating nanoparticle, thermally insulating nanoparticle, or catalytic nanoparticle.

According to one embodiment, the particle 12 comprises at least one pyro-electric nanoparticle and at least one nanoparticle 122 selected in the group of luminescent nanoparticle, magnetic nanoparticle, dielectric nanoparticle, plasmonic nanoparticle, piezoelectric nanoparticle, ferro-electric nanoparticle, light scattering nanoparticle, electrically insulating nanoparticle, thermally insulating nanoparticle, or catalytic nanoparticle.

According to one embodiment, the particle 12 comprises at least one ferro-electric nanoparticle and at least one nanoparticle 122 selected in the group of luminescent nanoparticle, magnetic nanoparticle, dielectric nanoparticle, plasmonic nanoparticle, piezoelectric nanoparticle, pyro-electric nanoparticle, light scattering nanoparticle, electrically insulating nanoparticle, thermally insulating nanoparticle, or catalytic nanoparticle.

According to one embodiment, the particle 12 comprises at least one light scattering nanoparticle and at least one nanoparticle 122 selected in the group of luminescent nanoparticle, magnetic nanoparticle, dielectric nanoparticle, plasmonic nanoparticle, piezoelectric nanoparticle, pyro-electric nanoparticle, ferro-electric nanoparticle, electrically insulating nanoparticle, thermally insulating nanoparticle, or catalytic nanoparticle.

According to one embodiment, the particle 12 comprises at least one electrically insulating nanoparticle and at least one nanoparticle 122 selected in the group of luminescent nanoparticle, magnetic nanoparticle, dielectric nanoparticle, plasmonic nanoparticle, piezoelectric nanoparticle, pyro-electric nanoparticle, ferro-electric nanoparticle, light scattering nanoparticle, thermally insulating nanoparticle, or catalytic nanoparticle.

According to one embodiment, the particle 12 comprises at least one thermally insulating nanoparticle and at least one nanoparticle 122 selected in the group of luminescent nanoparticle, magnetic nanoparticle, dielectric nanoparticle, plasmonic nanoparticle, piezoelectric nanoparticle, pyro-electric nanoparticle, ferro-electric nanoparticle, light scattering nanoparticle, electrically insulating nanoparticle, or catalytic nanoparticle.

According to one embodiment, the particle 12 comprises at least one catalytic nanoparticle and at least one nanoparticle 122 selected in the group of luminescent nanoparticle, magnetic nanoparticle, dielectric nanoparticle, plasmonic nanoparticle, piezoelectric nanoparticle, pyro-electric nanoparticle, ferro-electric nanoparticle, light scattering nanoparticle, electrically insulating nanoparticle, or thermally insulating nanoparticle.

According to one embodiment, the particle 12 comprises at least one nanoparticle 122 without a shell and at least one nanoparticle 122 selected in the group of core/shell nanoparticles 122 and core/insulator shell nanoparticles 122.

According to one embodiment, the particle 12 comprises at least one core/shell nanoparticle 122 and at least one nanoparticle 122 selected in the group of nanoparticles 122 without a shell and core/insulator shell nanoparticles 122.

According to one embodiment, the particle 12 comprises at least one core/insulator shell nanoparticle 122 and at least one nanoparticle 122 selected in the group of 122 without a shell and core/shell nanoparticles 122.

According to one embodiment, the core 123 of the core/shell particle 12 comprises at least one nanoparticle 122 as described herein and the shell 124 of the core/shell particle 12 does not comprise nanoparticles 122.

According to one embodiment, the core 123 of the core/shell particle 12 comprises at least one nanoparticle 122 as described herein and the shell 124 of the core/shell particle 12 comprises at least one nanoparticle 122.

According to one embodiment, the at least one nanoparticle 122 comprised in the core 123 of the core/shell particle 12 is identical to the at least one nanoparticle 122 comprised in the shell 124 of the core/shell particle 12.

According to one embodiment, the at least one nanoparticle 122 comprised in the core 123 of the core/shell particle 12 is different to the at least one nanoparticle 122 comprised in the shell 124 of the core/shell particle 12. In this embodiment, the resulting core/shell particle 12 will exhibit different properties.

According to one embodiment, the core 123 of the core/shell particle 12 comprises at least one luminescent nanoparticle and the shell 124 of the core/shell particle 12 comprises at least one nanoparticle 122 selected in the group of magnetic nanoparticle, plasmonic nanoparticle, dielectric nanoparticle, piezoelectric nanoparticle, pyro-electric nanoparticle, ferro-electric nanoparticle, light scattering nanoparticle, electrically insulating nanoparticle, thermally insulating nanoparticle, or catalytic nanoparticle.

According to one embodiment, the shell 124 of the core/shell particle 12 comprises at least one luminescent nanoparticle and the core 123 of the core/shell particle 12 comprises at least one nanoparticle 122 selected in the group of magnetic nanoparticle, plasmonic nanoparticle, dielectric nanoparticle, piezoelectric nanoparticle, pyro-electric nanoparticle, ferro-electric nanoparticle, light scattering nanoparticle, electrically insulating nanoparticle, thermally insulating nanoparticle, or catalytic nanoparticle.

In a preferred embodiment, the core 123 of the core/shell particle 12 and the shell 124 of the core/shell particle 12 comprise at least two different luminescent nanoparticles, wherein said luminescent nanoparticles emit at different emission wavelengths.

In a preferred embodiment, the core 123 of the core/shell particle 12 and the shell 124 of the core/shell particle 12 comprise at least two different luminescent nanoparticles, wherein at least one luminescent nanoparticle emits at a peak wavelength in the range from 500 to 560 nm, and at least one luminescent nanoparticle emits at a peak wavelength in the range from 600 to 2500 nm. In this embodiment, the core 123 of the core/shell particle 12 and the shell 124 of the core/shell particle 12 comprise at least one luminescent nanoparticle emitting in the green region of the visible spectrum and at least one luminescent nanoparticle emitting in the red region of the visible spectrum, thus the particle 12 paired with a blue LED will be a white light emitter.

In a preferred embodiment, the core 123 of the core/shell particle 12 and the shell 124 of the core/shell particle 12 comprise at least two different luminescent nanoparticles, wherein at least one luminescent nanoparticle emits at a peak wavelength in the range from 400 to 490 nm, and at least one luminescent nanoparticle emits at a peak wavelength in the range from 600 to 2500 nm. In this embodiment, the core 123 of the core/shell particle 12 and the shell 124 of the core/shell particle 12 comprise at least one luminescent nanoparticle emitting in the blue region of the visible spectrum and at least one luminescent nanoparticle emitting in the red region of the visible spectrum, thus the particle 12 will be a white light emitter.

In a preferred embodiment, the core 123 of the core/shell particle 12 and the shell 124 of the core/shell particle 12 comprise comprises at least two different luminescent nanoparticles, wherein at least one luminescent nanoparticle emits at a peak wavelength in the range from 400 to 490 nm, and at least one luminescent nanoparticle emits at a peak wavelength in the range from 500 to 560 nm. In this embodiment, the core 123 of the core/shell particle 12 and the shell 124 of the core/shell particle 12 comprise at least one luminescent nanoparticle emitting in the blue region of the visible spectrum and at least one luminescent nanoparticle emitting in the green region of the visible spectrum.

According to one embodiment, the core 123 of the core/shell particle 12 comprises at least one magnetic nanoparticle and the shell 124 of the core/shell particle 12 comprises at least one nanoparticle 122 selected in the group of luminescent nanoparticle, plasmonic nanoparticle, dielectric nanoparticle, piezoelectric nanoparticle, pyro-electric nanoparticle, ferro-electric nanoparticle, light scattering nanoparticle, electrically insulating nanoparticle, thermally insulating nanoparticle, or catalytic nanoparticle.

According to one embodiment, the core 123 of the core/shell particle 12 comprises at least one plasmonic nanoparticle and the shell 124 of the core/shell particle 12 comprises at least one nanoparticle 122 selected in the group of luminescent nanoparticle, magnetic nanoparticle, dielectric nanoparticle, piezoelectric nanoparticle, pyro-electric nanoparticle, ferro-electric nanoparticle, light scattering nanoparticle, electrically insulating nanoparticle, thermally insulating nanoparticle, or catalytic nanoparticle.

According to one embodiment, the core 123 of the core/shell particle 12 comprises at least one dielectric nanoparticle and the shell 124 of the core/shell particle 12 comprises at least one nanoparticle 122 selected in the group of luminescent nanoparticle, magnetic nanoparticle, plasmonic nanoparticle, piezoelectric nanoparticle, pyro-electric nanoparticle, ferro-electric nanoparticle, light scattering nanoparticle, electrically insulating nanoparticle, thermally insulating nanoparticle, or catalytic nanoparticle.

According to one embodiment, the core 123 of the core/shell particle 12 comprises at least one piezoelectric nanoparticle and the shell 124 of the core/shell particle 12 comprises at least one nanoparticle 122 selected in the group of luminescent nanoparticle, magnetic nanoparticle, dielectric nanoparticle, plasmonic nanoparticle, pyro-electric nanoparticle, ferro-electric nanoparticle, light scattering nanoparticle, electrically insulating nanoparticle, thermally insulating nanoparticle, or catalytic nanoparticle.

According to one embodiment, the core 123 of the core/shell particle 12 comprises at least one pyro-electric nanoparticle and the shell 124 of the core/shell particle 12 comprises at least one nanoparticle 122 selected in the group of luminescent nanoparticle, magnetic nanoparticle, dielectric nanoparticle, plasmonic nanoparticle, piezoelectric nanoparticle, ferro-electric nanoparticle, light scattering nanoparticle, electrically insulating nanoparticle, thermally insulating nanoparticle, or catalytic nanoparticle.

According to one embodiment, the core 123 of the core/shell particle 12 comprises at least one ferro-electric nanoparticle and the shell 124 of the core/shell particle 12 comprises at least one nanoparticle 122 selected in the group of luminescent nanoparticle, magnetic nanoparticle, dielectric nanoparticle, plasmonic nanoparticle, piezoelectric nanoparticle, pyro-electric nanoparticle, light scattering nanoparticle, electrically insulating nanoparticle, thermally insulating nanoparticle, or catalytic nanoparticle.

According to one embodiment, the core 123 of the core/shell particle 12 comprises at least one light scattering nanoparticle and the shell 124 of the core/shell particle 12 comprises at least one nanoparticle 122 selected in the group of luminescent nanoparticle, magnetic nanoparticle, dielectric nanoparticle, plasmonic nanoparticle, piezoelectric nanoparticle, pyro-electric nanoparticle, ferro-electric nanoparticle, electrically insulating nanoparticle, thermally insulating nanoparticle, or catalytic nanoparticle.

According to one embodiment, the core 123 of the core/shell particle 12 comprises at least one electrically insulating nanoparticle and the shell 124 of the core/shell particle 12 comprises at least one nanoparticle 122 selected in the group of luminescent nanoparticle, magnetic nanoparticle, dielectric nanoparticle, plasmonic nanoparticle, piezoelectric nanoparticle, pyro-electric nanoparticle, ferro-electric nanoparticle, light scattering nanoparticle, thermally insulating nanoparticle, or catalytic nanoparticle.

According to one embodiment, the core 123 of the core/shell particle 12 comprises at least one thermally insulating nanoparticle and the shell 124 of the core/shell particle 12 comprises at least one nanoparticle 122 selected in the group of luminescent nanoparticle, magnetic nanoparticle, dielectric nanoparticle, plasmonic nanoparticle, piezoelectric nanoparticle, pyro-electric nanoparticle, ferro-electric nanoparticle, light scattering nanoparticle, electrically insulating nanoparticle, or catalytic nanoparticle.

According to one embodiment, the core 123 of the core/shell particle 12 comprises at least one catalytic nanoparticle and the shell 124 of the core/shell particle 12 comprises at least one nanoparticle 122 selected in the group of luminescent nanoparticle, magnetic nanoparticle, dielectric nanoparticle, plasmonic nanoparticle, piezoelectric nanoparticle, pyro-electric nanoparticle, ferro-electric nanoparticle, light scattering nanoparticle, electrically insulating nanoparticle, or thermally insulating nanoparticle.

According to one embodiment, the particle 12 exhibits a degradation of its specific property of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

According to one embodiment, the specific property of the particle 12 comprises one or more of the following: fluorescence, phosphorescence, chemiluminescence, capacity of increasing local electromagnetic field, absorbance, magnetization, magnetic coercivity, catalytic yield, photovoltaic yield, electrical polarization, thermal conductivity, electrical conductivity, permeability to molecular oxygen, permeability to molecular water, or any other properties.

According to one embodiment, the particle 12 exhibits a degradation of its specific property of less than 90%, 80%, 70%, 60%, 50%, 40%, 30%, 25%, 20%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the particle 12 exhibits a degradation of its specific property of less than 90%, 80%, 70%, 60%, 50%, 40%, 30%, 25%, 20%, 10%, 5%, 4%, 3%, 2%, 1%, or 0% under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its specific property of less than 90%, 80%, 70%, 60%, 50%, 40%, 30%, 25%, 20%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its specific property of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its specific property of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the particle 12 exhibits a degradation of its specific property of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its specific property of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment.

According to one embodiment, the particle 12 exhibits a degradation of its specific property of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the particle 12 exhibits a degradation of its specific property of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its specific property of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

Photoluminescence refers to fluorescence and/or phosphorescence.

According to one embodiment, the particle 12 exhibits a degradation of its photoluminescence of less than 90%, 80%, 70%, 60%, 50%, 40%, 30%, 25%, 20%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the particle 12 exhibits a degradation of its photoluminescence of less than 90%, 80%, 70%, 60%, 50%, 40%, 30%, 25%, 20%, 10%, 5%, 4%, 3%, 2%, 1%, or 0% under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its photoluminescence of less than 90%, 80%, 70%, 60%, 50%, 40%, 30%, 25%, 20%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the particle 12 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment.

According to one embodiment, the particle 12 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the particle 12 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

In one embodiment, the particle 12 exhibits photoluminescence quantum yield (PLQY) decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination.

According to one embodiment, the light illumination is provided by blue, green, red, or UV light source such as laser, diode, fluorescent lamp or Xenon Arc Lamp. According to one embodiment, the photon flux or average peak pulse power of the illumination is comprised between 1 mW·cm⁻² and 100 kW·cm⁻², more preferably between 10 mW·cm⁻² and 100 W·cm⁻², and even more preferably between 10 mW·cm⁻² and 30 W·cm⁻².

According to one embodiment, the photon flux or average peak pulse power of the illumination is at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the particle 12 exhibits photoluminescence quantum yield (PQLY) decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the particle 12 exhibits FCE decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm^{—2}, 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

According to one embodiment, the particle 12 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

According to one embodiment, the particle 12 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the particle 12 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the particle 12 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment.

According to one embodiment, the particle 12 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the particle 12 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days,20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years,4 years, 4.5 years, 5 years, 5.5 years, 6 years, 6.5 years, 7 years, 7.5 years, 8 years, 8.5 years,9 years, 9.5 years, or 10 years.

According to one embodiment, the particle 12 exhibits a degradation of its FCE of less than 90%, 80%, 70%, 60%, 50%, 40%, 30%, 25%, 20%, 10%, 5%, 4%, 3%, 2%, 1%, or 0% under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the particle 12 exhibits a degradation of its FCE of less than 90%, 80%, 70%, 60%, 50%, 40%, 30%, 25%, 20%, 10%, 5%, 4%, 3%, 2%, 1%, or 0% under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its FCE of less than 90%, 80%, 70%, 60%, 50%, 40%, 30%, 25%, 20%, 10%, 5%, 4%, 3%, 2%, 1%, or 0% under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days,20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years,4 years, 4.5 years, 5 years, 5.5 years, 6 years, 6.5 years, 7 years, 7.5 years, 8 years, 8.5 years,9 years, 9.5 years, or 10 years, under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days,20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years,4 years, 4.5 years, 5 years, 5.5 years, 6 years, 6.5 years, 7 years, 7.5 years, 8 years, 8.5 years,9 years, 9.5 years, or 10 years, under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the particle 12 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days,20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years,4 years, 4.5 years, 5 years, 5.5 years, 6 years, 6.5 years, 7 years, 7.5 years, 8 years, 8.5 years,9 years, 9.5 years, or 10 years, under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days,20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years,4 years, 4.5 years, 5 years, 5.5 years, 6 years, 6.5 years, 7 years, 7.5 years, 8 years, 8.5 years,9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular O₂.

According to one embodiment, the particle 12 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days,20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years,4 years, 4.5 years, 5 years, 5.5 years, 6 years, 6.5 years, 7 years, 7.5 years, 8 years, 8.5 years,9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular O₂, under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the particle 12 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular O₂, under 0%, 10%, 20%, 30%, 40%, 50%, 55%, 60%, 65%, 70%, 75%, 80%, 85%, 90%, 95%, or 99% of humidity.

According to one embodiment, the particle 12 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular O₂, under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the photoluminescence of the particle 12 is preserved after dispersion in the material 11.

According to one embodiment, the aggregate 1 does not comprise quantum dots encapsulated in TiO₂, semiconductor nanocrystals encapsulated in TiO₂, or semiconductor nanoplatelet encapsulated in TiO₂.

According to one embodiment, the aggregate 1 does not comprise a spacer layer between the particles 12 and the material 11.

According to one embodiment, the aggregate 1 does not comprise one core/shell nanoparticle wherein the core is luminescent and emits red light, and the shell is a spacer layer between the particles 12 and the material 11.

According to one embodiment, the aggregate 1 does not comprise a core/shell nanoparticle and a plurality of particles 12, wherein the core is luminescent and emits red light, and the shell is a spacer layer between the particles 12 and the material 11.

According to one embodiment, the aggregate 1 does not comprise at least one luminescent core, a spacer layer, an encapsulation layer and a plurality of quantum dots, wherein the luminescent core emits red light, and the spacer layer is situated between said luminescent core and the material 11.

According to one embodiment, the aggregate 1 does not comprise a luminescent core sourrounded by a spacer layer and emitting red light.

According to one embodiment, the aggregate 1 does not comprise nanoparticles covering or surrounding a luminescent core.

According to one embodiment, the aggregate 1 does not comprise nanoparticles covering or surrounding a luminescent core emitting red light.

According to one embodiment, the aggregate 1 does not comprise a luminescent core made by a specific material selected from the group consisting of silicate phosphor, aluminate phosphor, phosphate phosphor, sulfide phosphor, nitride phosphor, nitrogen oxide phosphor, and combination of aforesaid two or more materials; wherein said luminescent core is covered by a spacer layer.

According to a preferred embodiment, examples of aggregates 1 include but are not limited to: CdSe/CdZnS@SiO₂; CdSe/CdZnS@SiO₂; CdSe/CdZnS@SiₓCd_{y}Zn_{z}O_{w}; CdSe/CdZnS@Al₂O₃; InP/ZnS@Al₂O₃; CH₅N₂—PbBr₃@Al₂O₃; CdSe/CdZnS—Au@SiO₂; Fe₃O₄@Al₂O₃—CdSe/CdZnS@SiO₂; CdSe/CdS/ZnS@PMMA; CdSe/CdS/ZnS@PS; CdSe/CdS/ZnS@PMMA; InP/ZnSe/ZnS@PMMA; CdSe/CdS/ZnS@Al₂O₃@PMMA; CdSe/CdS/ZnS@SiO₂; CdSe/CdS/ZnS@SiO₂; CdSe/CdS/ZnS@Al₂O₃@SiO₂; CdSe/CdS/ZnS@Al₂O₃@PMMA@SiO₂; CdSe/CdS/ZnS@PMMA@SiO₂; CdSe/CdS/ZnS@PMMA@SiO₂; CdSe/CdS/ZnS@PMMA@SiO₂@PMMA; FAPbBr₃@PMMA@SiO₂@PMMA; InP/ZnS@PMMA@SiO₂@PMMA; CdSe/CdS/ZnS@PMMA@Al₂O₃; CdSe/CdS/ZnS@PMMA@Al₂O₃@PMMA; FAPbBr₃@PMMA@Al₂O₃@PMMA; InP/ZnS@PMMA@Al₂O₃@PMMA; InP/ZnSe/ZnS@PMMA@SiO₂; CdSe/CdS/ZnS@Al₂O₃; Phosphor particles@PMMA; CdSe/CdS/ZnS@PMMA; InP/ZnSeS/ZnS@PMMA; CdSe/CdS/ZnS@PMMA-PS (80/20); CdSe/CdS/ZnS@PMMA-PS (50/50); CdSe/CdS/ZnS@PMMA-Poly(ethylene oxide)-b-Poly(propylene oxide)-b-Poly(ethylene oxide); CdSe/CdS/ZnS @PS-Poly(ethylene oxide)-b-Poly(propylene oxide)-b-Poly(ethylene oxide); CH₅N₂—PbBr₃@PMMA; CdSe/CdS/ZnS@Al₂O₃@PMMA; CdSe/CdS/ZnS@PMMA@Al₂O₃; CdSe/CdS/ZnS@PMMA/Poly(ethylene oxide)-block-Poly(propylene oxide)-block-Poly(ethylene oxide)@SiO₂; CdSe/CdS/ZnS@PS@PMMA; or CdSe/CdS/ZnS@PMMA@PS.

According to a preferred embodiment, examples of material 11 include but are not limited to: Al₂O₃, ZnTe, SiO₂, HfO₂, ZnSe, ZnO, ZnS, MgO, PS (Poly(Styrene)), PMMA (Poly(methyl methacrylate)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.or a mixture thereof.

According to a preferred embodiment, examples of particles 12 include but are not limited to: CdSe/CdZnS, CdSe, CdS, CdTe, CdSe/CdS, CdSe/ZnS, CdSe/CdZnS, CdS/ZnS, CdS/CdZnS, CdTe/ZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots; CdSe/CdZnS@SiO₂, CdSe/CdZnS@SiₓCd_{y}Zn_{z}O_{w}, CdSe/CdZnS@Al₂O₃, InP/ZnS@Al₂O₃, CH₅N₂—PbBr₃@Al₂O₃, CdSe/CdZnS—Au@SiO₂, Fe₃O₄@Al₂O₃—CdSe/CdZnS@SiO₂, CdS/ZnS@Al₂O₃, CdSeS/CdZnS@Al₂O₃, CdSe/CdS/ZnS@Al₂O₃, InP/ZnSe/ZnS@Al₂O₃, CuInS₂/ZnS@Al₂O₃, CuInSe₂/ZnS@Al₂O₃, CdSe/CdS/ZnS@SiO₂, CdSeS/ZnS@Al₂O₃, CdSeS/CdZnS@SiO₂, InP/ZnS@SiO₂, CdSeS/CdZnS@SiO₂, InP/ZnSe/ZnS@SiO₂, Fe₃O₄@Al₂O₃, CdSe/CdZnS@ZnO, CdSe/CdZnS@ZnO, CdSe/CdZnS@Al₂O₃@MgO, CdSe/CdZnS—Fe₃O₄@SiO₂, phosphor nanoparticles@Al₂O₃, phosphor nanoparticles@ZnO, phosphor nanoparticles@SiO₂, phosphor nanoparticles@HfO₂, CdSe/CdZnS@HfO₂, CdSeS/CdZnS@HfO₂, InP/ZnS@HfO₂, CdSeS/CdZnS@HfO₂, InP/ZnSe/ZnS@HfO₂, CdSe/CdZnS—Fe₃O₄@HfO₂, CdSe/CdS/ZnS@SiO₂, or a mixture thereof; wherein phosphor nanoparticles include but are not limited to: Yttrium aluminium garnet particles (YAG, Y₃Al₅O₁₂), (Ca,Y)-α-SiAlON:Eu particles, ((Y,Gd)₃(Al,Ga)₅O₁₂:Ce) particles, CaAlSiN₃:Eu particles, sulfide-based phosphor particles, PFS:Mn⁴⁺ particles (potassium fluorosilicate).

According to a preferred embodiment, examples of dispersion of aggregates include but are not limited to: CdSe/CdS/ZnS@PMMA in MMA; CdSe/CdS/ZnS@PS in styrene; CdSe/CdS/ZnS@PMMA in PMMA; CdSe/CdS/ZnS@PS in PolyStyrene; CdSe/CdS/ZnS@PMMA in Silicone; CdSe/CdS/ZnS@PS in Silicone; InP/ZnSeS/ZnS@PS in Silicone; InP/ZnSeS/ZnS@PMMA in Silicone; dispersion of aggregates in a silicone; dispersion of aggregates in a ZnO matrix; dispersion of aggregates in PMMA; dispersion of aggregates in Polystyrene.

According to one embodiment, the aggregate 1 and/or the particle 12 are functionalized.

A functionalized aggregate 1 and/or the particle 12 can then be dispersed in a host material or a liquid vehicle of an ink for further use.

Some applications, for example biological applications, require particles to be functionalized with a biocompatible agent for example.

According to one embodiment, the aggregate 1 and/or the particle 12 are functionalized with a specific-binding component, wherein said specific-binding component includes but is not limited to: antigens, steroids, vitamins, drugs, haptens, metabolites, toxins, environmental pollutants, amino acids, peptides, proteins, antibodies, polysaccharides, nucleotides, nucleosides, oligonucleotides, psoralens, hormones, nucleic acids, nucleic acid polymers, carbohydrates, lipids, phospholipids, lipoproteins, lipopolysaccharides, liposomes, lipophilic polymers, synthetic polymers, polymeric microparticles, biological cells, virus and combinations thereof. Preferred peptides include, but are not limited to: neuropeptides, cytokines, toxins, protease substrates, and protein kinase substrates. Preferred protein conjugates include enzymes, antibodies, lectins, glycoproteins, histones, albumins, lipoproteins, avidin, streptavidin, protein A, protein G, phycobiliproteins and other fluorescent proteins, hormones, toxins and growth factors. Preferred nucleic acid polymers are single- or multi-stranded, natural or synthetic DNA or RNA oligonucleotides, or DNA/RNA hybrids, or incorporating an unusual linker such as morpholine derivatized phosphides, or peptide nucleic acids such as N-(2-aminoethyl)glycine units, where the nucleic acid contains fewer than 50 nucleotides, more typically fewer than 25 nucleotides. The functionalization of the aggregate 1 and/or the particle 12 can be made using techniques known in the art.

According to one embodiment illustrated in FIG. 17, the aggregate 1 is encapsulated in a bigger particle or a bead 3, wherein said bead 3 comprises a material 31 and the aggregate 1 is dispersed in said material 31.

According to one embodiment, the bead 3 is air processable. This embodiment is particularly advantageous for the manipulation or the transport of said bead 3 and for the use of said bead 3 in a device such as an optoelectronic device.

According to one embodiment, the bead 3 is compatible with standard lithography processes. This embodiment is particularly advantageous for the use of said bead 3 in a device such as an optoelectronic device.

According to one embodiment, the bead 3 is an aggregate as described hereabove.

According to one embodiment, the bead 3 is a colloidal particle.

According to one embodiment, the bead 3 is fluorescent.

According to one embodiment, the bead 3 is phosphorescent.

According to one embodiment, the bead 3 is electroluminescent.

According to one embodiment, the bead 3 is chemiluminescent.

According to one embodiment, the bead 3 is triboluminescent.

According to one embodiment, the bead 3 exhibits an emission spectrum with at least one emission peak, wherein said emission peak has a maximum emission wavelength ranging from 400 nm to 50 um.

According to one embodiment, the bead 3 exhibits an emission spectrum with at least one emission peak, wherein said emission peak has a maximum emission wavelength ranging from 400 nm to 500 nm. In this embodiment, the bead 3 emits blue light.

According to one embodiment, the bead 3 exhibits an emission spectrum with at least one emission peak, wherein said emission peak has a maximum emission wavelength ranging from 500 nm to 560 nm, more preferably ranging from 515 nm to 545 nm. In this embodiment, the bead 3 emits green light.

According to one embodiment, the bead 3 exhibits an emission spectrum with at least one emission peak, wherein said emission peak has a maximum emission wavelength ranging from 560 nm to 590 nm. In this embodiment, the bead 3 emits yellow light.

According to one embodiment, the bead 3 exhibits an emission spectrum with at least one emission peak, wherein said emission peak has a maximum emission wavelength ranging from 590 nm to 750 nm, more preferably ranging from 610 nm to 650 nm. In this embodiment, the bead 3 emits red light.

According to one embodiment, the bead 3 exhibits an emission spectrum with at least one emission peak, wherein said emission peak has a maximum emission wavelength ranging from 750 nm to 50 um. In this embodiment, the bead 3 emits near infra-red, mid-infra-red, or infra-red light.

According to one embodiment, the bead 3 exhibits emission spectra with at least one emission peak having a full width half maximum lower than 90 nm, 80 nm, 70 nm, 60 nm, 50 nm, 40 nm, 30 nm, 25 nm, 20 nm, 15 nm, or 10 nm.

According to one embodiment, the bead 3 exhibits emission spectra with at least one emission peak having a full width half maximum strictly lower than 40 nm, 30 nm, 25 nm, 20 nm, 15 nm, or 10 nm.

According to one embodiment, the bead 3 exhibits emission spectra with at least one emission peak having a full width at quarter maximum lower than 90 nm, 80 nm, 70 nm, 60 nm, 50 nm, 40 nm, 30 nm, 25 nm, 20 nm, 15 nm, or 10 nm.

According to one embodiment, the bead 3 exhibits emission spectra with at least one emission peak having a full width at quarter maximum strictly lower than 40 nm, 30 nm, 25 nm, 20 nm, 15 nm, or 10 nm.

According to one embodiment, the bead 3 has a photoluminescence quantum yield (PLQY) of at least 5%, 10%, 15%, 20%, 25%, 30%, 35%, 40%, 45%, 50%, 55%, 60%, 65%, 70%, 75%, 80%, 85%, 90%, 95%, 99% or 100%.

According to one embodiment, the bead 3 absorbs the incident light with wavelength lower than 50 um, 40 um, 30 um, 20 um, 10 um, 1 um, 950 nm, 900 nm, 850 nm, 800 nm, 750 nm, 700 nm, 650 nm, 600 nm, 550 nm, 500 nm, 450 nm, 400 nm, 350 nm, 300 nm, 250 nm, or lower than 200 nm.

According to one embodiment, the bead 3 has an average fluorescence lifetime of at least 0.1 nanosecond, 0.2 nanosecond, 0.3 nanosecond, 0.4 nanosecond, 0.5 nanosecond, 0.6 nanosecond, 0.7 nanosecond, 0.8 nanosecond, 0.9 nanosecond, 1 nanosecond, 2 nanoseconds, 3 nanoseconds, 4 nanoseconds, 5 nanoseconds, 6 nanoseconds, 7 nanoseconds, 8 nanoseconds, 9 nanoseconds, 10 nanoseconds, 11 nanoseconds, 12 nanoseconds, 13 nanoseconds, 14 nanoseconds, 15 nanoseconds, 16 nanoseconds, 17 nanoseconds, 18 nanoseconds, 19 nanoseconds, 20 nanoseconds, 21 nanoseconds, 22 nanoseconds, 23 nanoseconds, 24 nanoseconds, 25 nanoseconds, 26 nanoseconds, 27 nanoseconds, 28 nanoseconds, 29 nanoseconds, 30 nanoseconds, 31 nanoseconds, 32 nanoseconds, 33 nanoseconds, 34 nanoseconds, 35 nanoseconds, 36 nanoseconds, 37 nanoseconds, 38 nanoseconds, 39 nanoseconds, 40 nanoseconds, 41 nanoseconds, 42 nanoseconds, 43 nanoseconds, 44 nanoseconds, 45 nanoseconds, 46 nanoseconds, 47 nanoseconds, 48 nanoseconds, 49 nanoseconds, 50 nanoseconds, 100 nanoseconds, 150 nanoseconds, 200 nanoseconds, 250 nanoseconds, 300 nanoseconds, 350 nanoseconds, 400 nanoseconds, 450 nanoseconds, 500 nanoseconds, 550 nanoseconds, 600 nanoseconds, 650 nanoseconds, 700 nanoseconds, 750 nanoseconds, 800 nanoseconds, 850 nanoseconds, 900 nanoseconds, 950 nanoseconds, or 1 μsecond.

In one embodiment, the bead 3 exhibits photoluminescence quantum yield (PQLY) decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light with an average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one preferred embodiment, the bead 3 exhibits photoluminescence quantum yield (PQLY) decrease of less than 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light or continuous light with an average peak pulse power or photon flux of at least 1 mW·cm⁻², 50 mW·cm⁻², 100 mW·cm⁻², 500 mW·cm⁻², 1 W·cm⁻², 5 W·cm⁻², 10 W·cm^{—2}, 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the bead 3 exhibits FCE decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light with an average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one preferred embodiment, the bead 3 exhibits FCE decrease of less than 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light or continuous light with an average peak pulse power or photon flux of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

According to one embodiment, the bead 3 has a size above 50 nm.

According to one embodiment, the bead 3 has a size of at least 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, a statistical set of bead 3 has an average size of at least 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, the bead 3 has a largest dimension of at least 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, the bead 3 has a smallest dimension of at least 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, the smallest dimension of the bead 3 is smaller than the largest dimension of said bead 3 by a factor (aspect ratio) of at least 1.5; of at least 2; at least 2.5; at least 3; at least 3.5; at least 4; at least 4.5; at least 5; at least 5.5; at least 6; at least 6.5; at least 7; at least 7.5; at least 8; at least 8.5; at least 9; at least 9.5; at least 10; at least 10.5; at least 11; at least 11.5; at least 12; at least 12.5; at least 13; at least 13.5; at least 14; at least 14.5; at least 15; at least 15.5; at least 16; at least 16.5; at least 17; at least 17.5; at least 18; at least 18.5; at least 19; at least 19.5; at least 20; at least 25; at least 30; at least 35; at least 40; at least 45; at least 50; at least 55; at least 60; at least 65; at least 70; at least 75; at least 80; at least 85; at least 90; at least 95; at least 100; at least 150; at least 200; at least 250; at least 300; at least 350; at least 400; at least 450; at least 500; at least 550; at least 600; at least 650; at least 700; at least 750; at least 800; at least 850; at least 900; at least 950; or at least 1000.

According to one embodiment, the bead 3 has a smallest curvature of at least 200 μm⁻¹, 100 μm⁻¹, 66.6 μm⁻¹, 50 μm⁻¹, 33.3 μm⁻¹, 28.6 μm⁻¹, 25 μm⁻¹, 20 μm⁻¹, 18.2 μm⁻¹, 16.7 μm⁻¹, 15.4 μm⁻¹, 14.3 μm⁻¹, 13.3 μm⁻¹, 12.5 μm⁻¹, 11.8 μm⁻¹, 11.1 μm⁻¹, 10.5 μm⁻¹, 10 μm⁻¹, 9.5 μm⁻¹, 9.1 μm⁻¹, 8.7 μm⁻¹, 8.3 μm⁻¹, 8 μm⁻¹, 7.7 μm⁻¹, 7.4 μm⁻¹, 7.1 μm⁻¹, 6.9 μm⁻¹, 6.7 m⁻¹, 5.7 μm⁻¹, 5 μm⁻¹, 4.4 μm⁻¹, 4 μm⁻¹, 3.6 μm⁻¹, 3.3 μm⁻¹, 3.1 μm⁻¹, 2.9 μm⁻¹, 2.7 μm⁻¹, 2.5 μm⁻¹, 2.4 μm⁻¹, 2.2 μm^{—1}, 2.1 μm⁻¹, 2 μm⁻¹, 1.3333 μm⁻¹, 0.8 μm⁻¹, 0.6666 μm⁻¹, 0.5714 μm⁻¹, 0.5 μm⁻¹, 0.4444 μm⁻¹, 0.4 μm⁻¹, 0.3636 μm⁻¹, 0.3333 μm⁻¹, 0.3080 μm⁻¹, 0.2857 μm⁻¹, 0.2667 μm⁻¹, 0.25 μm⁻¹, 0.2353 μm⁻¹, 0.2222 μm⁻¹, 0.2105 μm⁻¹, 0.2 μm⁻¹, 0.1905 μm⁻¹, 0.1818 μm⁻¹, 0.1739 μm⁻¹, 0.1667 μm⁻¹, 0.16 μm⁻¹, 0.1538 μm⁻¹, 0.1481 μm⁻¹, 0.1429 μm⁻¹, 0.1379 μm⁻¹, 0.1333 μm⁻¹, 0.1290 μm⁻¹, 0.125 μm⁻¹, 0.1212 μm⁻¹, 0.1176 μm⁻¹, 0.1176 μm⁻¹, 0.1143 μm⁻¹, 0.1111 μm⁻¹, 0.1881 μm⁻¹, 0.1053 μm⁻¹, 0.1026 μm⁻¹, 0.1 μm⁻¹, 0.0976 μm⁻¹, 0.9524 μm⁻¹, 0.0930 μm⁻¹, 0.0909 μm⁻¹, 0.0889 μm⁻¹, 0.870 μm⁻¹, 0.0851 μm⁻¹, 0.0833 μm⁻¹, 0.0816 μm⁻¹, 0.08 μm⁻¹, 0.0784 μm⁻¹, 0.0769 μm⁻¹, 0.0755 μm⁻¹, 0.0741 μm⁻¹, 0.0727 μm⁻¹, 0.0714 μm⁻¹, 0.0702 μm⁻¹, 0.0690 μm⁻¹, 0.0678 μm⁻¹, 0.0667 μm⁻¹, 0.0656 μm⁻¹, 0.0645 μm⁻¹, 0.0635 μm⁻¹, 0.0625 μm⁻¹, 0.0615 μm⁻¹, 0.0606 μm⁻¹, 0.0597 μm⁻¹, 0.0588 μm⁻¹, 0.0580 μm⁻¹, 0.0571 μm⁻¹, 0.0563 μm⁻¹, 0.0556 μm⁻¹, 0.0548 μm⁻¹, 0.0541 μm⁻¹, 0.0533 μm⁻¹, 0.0526 μm⁻¹, 0.0519 μm⁻¹, 0.0513 μm⁻¹, 0.0506 μm⁻¹, 0.05 μm⁻¹, 0.0494 μm⁻¹, 0.0488 μm⁻¹, 0.0482 μm⁻¹, 0.0476 μm⁻¹, 0.0471 μm⁻¹, 0.0465 μm⁻¹, 0.0460 μm⁻¹, 0.0455 μm⁻¹, 0.0450 μm⁻¹, 0.0444 μm⁻¹, 0.0440 μm⁻¹, 0.0435 μm⁻¹, 0.0430 μm⁻¹, 0.0426 μm⁻¹, 0.0421 μm⁻¹, 0.0417 μm⁻¹, 0.0412 μm⁻¹, 0.0408 μm⁻¹, 0.0404 μm⁻¹, 0.04 μm⁻¹, 0.0396 μm⁻¹, 0.0392 μm⁻¹, 0.0388 μm⁻¹, 0.0385 μm⁻¹; 0.0381 μm⁻¹, 0.0377 μm⁻¹, 0.0374 μm⁻¹, 0.037 μm⁻¹, 0.0367 μm⁻¹, 0.0364 μm⁻¹, 0.0360 μm⁻¹, 0.0357 μm⁻¹, 0.0354 μm⁻¹, 0.0351 μm⁻¹, 0.0348 μm⁻¹, 0.0345 μm⁻¹, 0.0342 μm⁻¹, 0.0339 μm⁻¹, 0.0336 μm⁻¹, 0.0333 μm⁻¹, 0.0331 μm⁻¹, 0.0328 μm⁻¹, 0.0325 μm⁻¹, 0.0323 μm⁻¹, 0.032 μm⁻¹, 0.0317 μm⁻¹, 0.0315 μm⁻¹, 0.0312 μm⁻¹, 0.031 μm⁻¹, 0.0308 μm⁻¹, 0.0305 μm⁻¹, 0.0303 μm⁻¹, 0.0301 μm⁻¹, 0.03 μm⁻¹, 0.0299 μm⁻¹, 0.0296 μm⁻¹, 0.0294 μm⁻¹, 0.0292 μm⁻¹, 0.029 μm⁻¹, 0.0288 μm⁻¹, 0.0286 μm⁻¹, 0.0284 μm⁻¹, 0.0282 μm⁻¹, 0.028 μm⁻¹, 0.0278 μm⁻¹, 0.0276 μm⁻¹, 0.0274 μm⁻¹, 0.0272 μm⁻¹; 0.0270 μm⁻¹, 0.0268 μm⁻¹, 0.02667 μm⁻¹, 0.0265 μm⁻¹, 0.0263 μm⁻¹, 0.0261 μm⁻¹, 0.026 μm⁻¹, 0.0258 μm⁻¹, 0.0256 μm⁻¹, 0.0255 μm⁻¹, 0.0253 μm⁻¹, 0.0252 μm⁻¹, 0.025 μm⁻¹, 0.0248 μm⁻¹, 0.0247 μm⁻¹, 0.0245 μm⁻¹, 0.0244 μm⁻¹, 0.0242 μm⁻¹, 0.0241 μm⁻¹, 0.024 μm⁻¹, 0.0238 μm⁻¹, 0.0237 μm⁻¹, 0.0235 μm⁻¹, 0.0234 μm⁻¹, 0.0233 μm⁻¹, 0.231 μm⁻¹, 0.023 μm⁻¹, 0.0229 μm⁻¹, 0.0227 μm⁻¹, 0.0226 μm⁻¹, 0.0225 μm⁻¹, 0.0223 μm⁻¹, 0.0222 μm⁻¹, 0.0221 μm⁻¹, 0.022 μm⁻¹, 0.0219 μm⁻¹, 0.0217 μm⁻¹, 0.0216 μm⁻¹, 0.0215 μm⁻¹, 0.0214 μm⁻¹, 0.0213 μm⁻¹, 0.0212 μm⁻¹, 0.0211 μm⁻¹, 0.021 μm⁻¹, 0.0209 μm⁻¹, 0.0208 μm⁻¹, 0.0207 μm⁻¹, 0.0206 μm⁻¹, 0.0205 μm⁻¹, 0.0204 μm⁻¹, 0.0203 μm⁻¹, 0.0202 μm⁻¹, 0.0201 μm⁻¹, 0.02 μm⁻¹, or 0.002 μm⁻¹.

According to one embodiment, the bead 3 has a largest curvature of at least 200 μm⁻¹, 100 μm⁻¹, 66.6 μm⁻¹, 50 μm⁻¹, 33.3 μm⁻¹, 28.6 μm⁻¹, 25 μm⁻¹, 20 μm⁻¹, 18.2 μm⁻¹, 16.7 μm⁻¹, 15.4 μm⁻¹, 14.3 μm⁻¹, 13.3 μm⁻¹, 12.5 μm⁻¹, 11.8 μm⁻¹, 11.1 μm⁻¹, 10.5 μm⁻¹, 10 μm⁻¹, 9.5 μm⁻¹, 9.1 μm⁻¹, 8.7 μm⁻¹, 8.3 μm⁻¹, 8 μm⁻¹, 7.7 μm⁻¹, 7.4 μm⁻¹, 7.1 μm⁻¹, 6.9 μm⁻¹, 6.7 μm⁻¹, 5.7 μm⁻¹, 5μm⁻¹, 4.4 μm⁻¹, 4 μm⁻¹, 3.6 μm⁻¹, 3.3 μm⁻, 2.9 μm⁻¹, 2.7 μm⁻¹, 2.5 μm⁻, 2.4 μm⁻¹, 2.2 μm⁻¹, 2.1 μm⁻¹, 2 μm⁻¹, 1.3333 μm⁻¹, 0.8 μm⁻¹, 0.6666 μm⁻¹, 0.5714 μm⁻¹, 0.5 μm⁻¹, 0.4444 μm⁻¹, 0.4 μm⁻¹, 0.3636 μm⁻¹, 0.3333 μm⁻¹, 0.3080 μm⁻¹, 0.2857 μm⁻¹, 0.2667 μm⁻¹, 0.25 μm⁻¹, 0.2353 μm⁻¹, 0.2222 μm⁻¹, 0.2105 μm⁻¹, 0.2 μm⁻¹, 0.1905 μm⁻¹, 0.1818 μm⁻¹, 0.1739 μm⁻¹, 0.1667 μm⁻¹, 0.16 μm⁻¹, 0.1538 μm⁻¹, 0.1481 μm⁻¹, 0.1429 μm⁻¹, 0.1379 μm⁻¹, 0.1333 μm⁻¹, 0.1290 μm⁻¹, 0.125 μm⁻¹, 0.1212 μm⁻¹, 0.1176 μm⁻¹, 0.1176 μm⁻¹, 0.1143 μm⁻¹, 0.1111 μm⁻¹, 0.1881 μm⁻¹, 0.1053 μm⁻¹, 0.1026 μm⁻¹, 0.1 μm⁻¹, 0.0976 μm⁻¹, 0.9524 μm⁻¹, 0.0930 μm⁻¹, 0.0909 μm⁻¹, 0.0889 μm⁻¹, 0.870 μm⁻¹, 0.0851 μm⁻¹, 0.0833 μm⁻¹, 0.0816 μm⁻¹, 0.08 μm⁻¹, 0.0784 μm⁻¹, 0.0769 μm⁻¹, 0.0755 μm⁻¹, 0.0741 μm⁻¹, 0.0727 μm⁻¹, 0.0714 μm⁻¹, 0.0702 μm⁻¹, 0.0690 μm⁻¹, 0.0678 μm⁻¹, 0.0667 μm⁻¹, 0.0656 μm⁻¹, 0.0645 μm⁻¹, 0.0635 μm⁻¹, 0.0625 μm⁻¹, 0.0615 μm⁻¹, 0.0606 μm⁻¹, 0.0597 μm⁻¹, 0.0588 μm⁻¹, 0.0580 μm⁻¹, 0.0571 μm⁻¹, 0.0563 μm⁻¹, 0.0556 μm⁻¹, 0.0548 μm⁻¹, 0.0541 μm⁻¹, 0.0533 μm⁻¹, 0.0526 μm⁻¹, 0.0519 μm⁻¹, 0.0513 μm⁻¹, 0.0506 μm⁻¹, 0.05 μm⁻¹, 0.0494 μm⁻¹, 0.0488 μm⁻¹, 0.0482 μm⁻¹, 0.0476 μm⁻¹, 0.0471 μm⁻¹, 0.0465 μm⁻¹, 0.0460 μm⁻¹, 0.0455 μm⁻¹, 0.0450 μm⁻¹, 0.0444 μm⁻¹, 0.0440 μm⁻¹, 0.0435 μm⁻¹, 0.0430 μm⁻¹, 0.0426 μm⁻¹, 0.0421 μm⁻¹, 0.0417 μm⁻¹, 0.0412 μm⁻¹, 0.0408 μm⁻¹, 0.0404 μm⁻¹, 0.04 μm⁻¹, 0.0396 μm⁻¹, 0.0392 0.0388 μm⁻¹, 0.0385 μm⁻¹; 0.0381 μm⁻¹, 0.0377 0.0374 μm⁻¹, 0.037 μm⁻¹, 0.0367 μm⁻¹, 0.0364 0.0360 μm⁻¹, 0.0357 μm⁻¹, 0.0354 0.0351 μm⁻¹, 0.0348 μm⁻¹, 0.0345 μm⁻¹, 0.0342 μm⁻¹, 0.0339 μm⁻¹, 0.0336 0.0333 μm⁻¹, 0.0331 μm⁻¹, 0.0328 μm⁻¹, 0.0325 μm⁻¹, 0.0323 μm⁻¹, 0.032 μm⁻¹, 0.0317 μm⁻¹, 0.0315 μm⁻¹, 0.0312 μm⁻¹, 0.031 μm⁻¹, 0.0308 μm⁻¹, 0.0305 μm⁻¹, 0.0303 μm⁻¹, 0.0301 μm⁻¹, 0.03 μm⁻¹, 0.0299 μm⁻¹, 0.0296 μm⁻¹, 0.0294 μm⁻¹, 0.0292 μm⁻¹, 0.029 μm⁻¹, 0.0288 μm⁻¹, 0.0286 μm⁻¹, 0.0284 μm⁻¹, 0.0282 μm⁻¹, 0.028 μm⁻¹, 0.0278 μm⁻¹, 0.0276 μm⁻¹, 0.0274 μm⁻¹, 0.0272 μm⁻¹; 0.0270 μm⁻¹, 0.0268 μm⁻¹, 0.02667 μm⁻¹, 0.0265 μm⁻¹, 0.0263 μm⁻¹, 0.0261 μm⁻¹, 0.026 μm⁻¹, 0.0258 μm⁻¹, 0.0256 μm⁻¹, 0.0255 μm⁻¹, 0.0253 μm⁻¹, 0.0252 μm⁻¹, 0.025 μm⁻¹, 0.0248 0.0247 μm⁻¹, 0.0245 μm⁻¹, 0.0244 μm⁻¹, 0.0242 μm⁻¹, 0.0241 μm⁻¹, 0.024 μm⁻¹, 0.0238 μm⁻¹, 0.0237 μm⁻¹, 0.0235 μm⁻¹, 0.0234 μm⁻¹, 0.0233 μm⁻¹, 0.231 μm⁻¹, 0.023 μm⁻¹, 0.0229 μm⁻¹, 0.0227 μm⁻¹, 0.0226 μm⁻¹, 0.0225 μm⁻¹, 0.0223 μm⁻¹, 0.0222 μm⁻¹, 0.0221 μm⁻¹, 0.022 μm⁻¹, 0.0219 μm⁻¹, 0.0217 μm⁻¹, 0.0216 μm⁻¹, 0.0215 μm⁻¹, 0.0214 μm⁻¹, 0.0213 μm⁻¹, 0.0212 μm⁻¹, 0.0211 μm⁻¹, 0.021 μm⁻¹, 0.0209 μm⁻¹, 0.0208 μm⁻¹, 0.0207 μm⁻¹, 0.0206 μm⁻¹, 0.0205 μm⁻¹, 0.0204 μm⁻¹, 0.0203 μm⁻¹, 0.0202 μm⁻¹, 0.0201 μm⁻¹, 0.02 μm⁻¹, or 0.002 μm⁻¹.

According to one embodiment, in a statistical set of beads 3, said beads 3 are polydisperse.

According to one embodiment, in a statistical set of beads 3, said beads 3 are monodisperse.

According to one embodiment, in a statistical set of beads 3, said beads 3 have a narrow size distribution.

According to one embodiment, in a statistical set of beads 3, said beads 3 are not aggregated.

According to one embodiment, the surface roughness of the bead 3 is less or equal to 0%, 0.0001%, 0.0002%, 0.0003%, 0.0004%, 0.0005%, 0.0006%, 0.0007%, 0.0008%, 0.0009%, 0.001%, 0.002%, 0.003%, 0.004%, 0.005%, 0.006%, 0.007%, 0.008%, 0.009%, 0.01%, 0.02%, 0.03%, 0.04%, 0.05%, 0.06%, 0.07%, 0.08%, 0.09%, 0.1%, 0.11%, 0.12%, 0.13%, 0.14%, 0.15%, 0.16%, 0.17%, 0.18%, 0.19%, 0.2%, 0.21%, 0.22%, 0.23%, 0.24%, 0.25%, 0.26%, 0.27%, 0.28%, 0.29%, 0.3%, 0.31%, 0.32%, 0.33%, 0.34%, 0.35%, 0.36%, 0.37%, 0.38%, 0.39%, 0.4%, 0.41%, 0.42%, 0.43%, 0.44%, 0.45%, 0.46%, 0.47%, 0.48%, 0.49%, 0.5%, 1%, 1.5%, 2%, 2.5% 3%, 3.5%, 4%, 4.5%, or 5% of the largest dimension of said bead 3, meaning that the surface of said bead 3 is completely smooth.

According to one embodiment, the surface roughness of the bead 3 is less or equal to 0.5% of the largest dimension of said bead 3, meaning that the surface of said bead 3 is completely smooth.

According to one embodiment, the bead 3 has a spherical shape, an ovoid shape, a discoidal shape, a cylindrical shape, a faceted shape, a hexagonal shape, a triangular shape, a cubic shape, or a platelet shape.

According to one embodiment, the bead 3 has a spherical shape.

According to one embodiment, the spherical bead 3 has a diameter of at least 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, a statistical set of spherical bead 3 has an average diameter of at least 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 0.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm.

According to one embodiment, the average diameter of a statistical set of spherical beads 3 may have a deviation less or equal to 0.01%, 0.02%, 0.03%, 0.04%, 0.05%, 0.06%, 0.07%, 0.08%, 0.09%, 0.1%, 0.2%, 0.3%, 0.4%, 0.5%, 0.6%, 0.7%, 0.8%, 0.9%, 1%, 1.1%, 1.2%, 1.3%, 1.4%, 1.5%, 1.6%, 1.7%, 1.8%, 1.9%, 2%, 2.1%, 2.2%, 2.3%, 2.4%, 2.5%, 2.6%, 2.7%, 2.8%, 2.9%, 3%, 3.1%, 3.2%, 3.3%, 3.4%, 3.5%, 3.6%, 3.7%, 3.8%, 3.9%, 4%, 4.1%, 4.2%, 4.3%, 4.4%, 4.5%, 4.6%, 4.7%, 4.8%, 4.9%, 5%, 5.1%, 5.2%, 5.3%, 5.4%, 5.5%, 5.6%, 5.7%, 5.8%, 5.9%, 6%, 6.1%, 6.2%, 6.3%, 6.4%, 6.5%, 6.6%, 6.7%, 6.8%, 6.9%, 7%, 7.1%, 7.2%, 7.3%, 7.4%, 7.5%, 7.6%, 7.7%, 7.8%, 7.9%, 8%, 8.1%, 8.2%, 8.3%, 8.4%, 8.5%, 8.6%, 8.7%, 8.8%, 8.9%, 9%, 9.1%, 9.2%, 9.3%, 9.4%, 9.5%, 9.6%, 9.7%, 9.8%, 9.9%, 10%, 20%, 30%, 40%, 50%, 60%, 70%, 80%, 85%, 90%, 95%, 100%, 105%, 110%, 115%, 120%, 125%, 130%, 135%, 140%, 145%, 150%, 155%, 160%, 165%, 170%, 175%, 180%, 185%, 190%, 195%, or 200%.

According to one embodiment, the spherical bead 3 has a unique curvature of at least 200 μm⁻¹, 100 μm⁻¹, 66.6 μm⁻¹, 50 μm⁻¹, 33.3 μm⁻¹, 28.6 μm⁻¹, 25 μm⁻¹, 20 μm⁻¹, 18.2 μm⁻¹, 16.7 μm⁻¹, 15.4 μm⁻¹, 14.3 μm⁻¹, 13.3 μm⁻¹, 12.5 μm⁻¹, 11.8 μm⁻¹, 11.1 μm⁻¹, 10.5 μm⁻¹, 10 μm⁻¹, 9.5 μm⁻¹, 9.1 μm⁻¹, 8.7 μm⁻¹, 8.3 μm⁻¹, 8 μm⁻¹, 7.7 μm⁻¹, 7.4 μm⁻¹, 7.1 μm⁻¹, 6.9 μm⁻¹, 6.7 μm⁻¹, 5.7 μm⁻¹, 4.4 μm⁻¹, 3.6 μm⁻¹, 3.3 μm⁻¹, 3.1 μm⁻¹, 2.9 μm⁻¹, 2.7 μm⁻¹, 2.5 μm⁻¹, 2.4 μm⁻¹, 2.2 μm⁻¹, 2.1 μm⁻¹, 2 μm⁻¹, 1.3333 μm⁻¹, 0.8 μm⁻¹, 0.6666 μm⁻¹, 0.5714 μm⁻¹, 0.5 μm⁻¹, 0.4444 μm⁻¹, 0.4 μm⁻¹, 0.3636 μm⁻¹, 0.3333 μm⁻¹, 0.3080 μm⁻¹, 0.2857 μm⁻¹, 0.2667 μm⁻¹, 0.25 μm⁻¹, 0.2353 μm⁻¹, 0.2222 μm⁻¹, 0.2105 μm⁻¹, 0.2 μm⁻¹, 0.1905 μm⁻¹, 0.1818 μm⁻¹, 0.1739 μm⁻¹, 0.1667 μm⁻¹, 0.16 μm⁻¹, 0.1538 μm⁻¹, 0.1481 μm⁻¹, 0.1429 μm⁻¹, 0.1379 μm⁻¹, 0.1333 μm⁻¹, 0.1290 μm⁻¹, 0.125 μm⁻¹, 0.1212 μm⁻¹, 0.1176 μm⁻¹, 0.1176 μm⁻¹, 0.1143 μm⁻¹, 0.1111 μm⁻¹, 0.1881 μm⁻¹, 0.1053 μm⁻¹, 0.1026 μm⁻¹, 0.1 μm⁻¹, 0.0976 μm⁻¹, 0.9524 μm⁻¹, 0.0930 μm⁻¹, 0.0909 μm⁻¹, 0.0889 μm⁻¹, 0.870 μm⁻¹, 0.0851 μm⁻¹, 0.0833 μm⁻¹, 0.0816 μm⁻¹, 0.08 μm⁻¹, 0.0784 μm⁻¹, 0.0769 μm⁻¹, 0.0755 μm⁻¹, 0.0741 μm⁻¹, 0.0727 μm⁻¹, 0.0714 μm⁻¹, 0.0702 μm⁻¹, 0.0690 μm⁻¹, 0.0678 μm⁻¹, 0.0667 μm⁻¹, 0.0656 μm⁻¹, 0.0645 μm⁻¹, 0.0635 μm⁻¹, 0.0625 μm⁻¹, 0.0615 μm⁻¹, 0.0606 μm⁻¹, 0.0597 μm⁻¹, 0.0588 μm⁻¹, 0.0580 μm⁻¹, 0.0571 μm⁻¹, 0.0563 μm⁻¹, 0.0556 μm⁻¹, 0.0548 μm⁻¹, 0.0541 μm⁻¹, 0.0533 μm⁻¹, 0.0526 μm⁻¹, 0.0519 μm⁻¹, 0.0513 μm⁻¹, 0.0506 μm⁻¹, 0.05 μm⁻¹, 0.0494 μm⁻¹, 0.0488 μm⁻¹, 0.0482 μm⁻¹, 0.0476 μm⁻¹, 0.0471 μm⁻¹, 0.0465 μm⁻¹, 0.0460 μm⁻¹, 0.0455 μm⁻¹, 0.0450 μm⁻¹, 0.0444 μm⁻¹, 0.0440 μm⁻¹, 0.0435 μm⁻¹, 0.0430 μm⁻¹, 0.0426 μm⁻¹, 0.0421 μm⁻¹, 0.0417 μm⁻¹, 0.0412 μm⁻¹, 0.0408 μm⁻¹, 0.0404 μm⁻¹, 0.04 μm⁻¹, 0.0396 μm⁻¹, 0.0392 μm⁻¹, 0.0388 μm⁻¹, 0.0385 μm⁻¹; 0.0381 μm⁻¹, 0.0377 μm⁻¹, 0.0374 μm⁻¹, 0.037 μm⁻¹, 0.0367 μm⁻¹, 0.0364 μm⁻¹, 0.0360 μm⁻¹, 0.0357 μm⁻¹, 0.0354 μm⁻¹, 0.0351 μm⁻¹, 0.0348 μm⁻¹, 0.0345 μm⁻¹, 0.0342 μm⁻¹, 0.0339 μm⁻¹, 0.0336 μm⁻¹, 0.0333 μm⁻¹, 0.0331 μm⁻¹, 0.0328 μm⁻¹, 0.0325 μm⁻¹, 0.0323 μm⁻¹, 0.032 μm⁻¹, 0.0317 μm⁻¹, 0.0315 μm⁻¹, 0.0312 μm⁻¹, 0.031 μm⁻¹, 0.0308 μm⁻¹, 0.0305 μm⁻¹, 0.0303 μm⁻¹, 0.0301 μm⁻¹, 0.03 μm⁻¹, 0.0299 μm⁻¹, 0.0296 μm⁻¹, 0.0294 μm⁻¹, 0.0292 μm⁻¹, 0.029 μm⁻¹, 0.0288 μm⁻¹, 0.0286 μm⁻¹, 0.0284 μm⁻¹, 0.0282 μm⁻¹, 0.028 μm⁻¹, 0.0278 μm⁻¹, 0.0276 μm⁻¹, 0.0274 μm⁻¹, 0.0272 μm⁻¹, 0.0270 μm⁻¹, 0.0268 μm⁻¹, 0.02667 μm⁻¹, 0.0265 μm⁻¹, 0.0263 μm⁻¹, 0.0261 μm⁻¹, 0.026 μm⁻¹, 0.0258 μm⁻¹, 0.0256 μm⁻¹, 0.0255 μm⁻¹, 0.0253 μm⁻¹, 0.0252 μm⁻¹, 0.025 μm⁻¹, 0.0248 μm⁻¹, 0.0247 μm⁻¹, 0.0245 μm⁻¹, 0.0244 μm⁻¹, 0.0242 μm⁻¹, 0.0241 μm⁻¹, 0.024 μm⁻¹, 0.0238 μm⁻¹, 0.0237 μm⁻¹, 0.0235 μm⁻¹, 0.0234 μm⁻¹, 0.0233 μm⁻¹, 0.231 μm⁻¹, 0.023 μm⁻¹, 0.0229 μm⁻¹, 0.0227 μm⁻¹, 0.0226 μm⁻¹, 0.0225 μm⁻¹, 0.0223 μm⁻¹, 0.0222 μm⁻¹, 0.0221 μm⁻¹, 0.022 μm⁻¹, 0.0219 μm⁻¹, 0.0217 μm⁻¹, 0.0216 μm⁻¹, 0.0215 μm⁻¹, 0.0214 μm⁻¹, 0.0213 μm⁻¹, 0.0212 μm⁻¹, 0.0211 μm⁻¹, 0.021 μm⁻¹, 0.0209 μm⁻¹, 0.0208 μm⁻¹, 0.0207 μm⁻¹, 0.0206 μm⁻¹, 0.0205 μm⁻¹, 0.0204 μm⁻¹, 0.0203 μm⁻¹, 0.0202 μm⁻¹, 0.0201 μm⁻¹, 0.02 μm⁻¹, or 0.002 μm⁻¹.

According to one embodiment, a statistical set of the spherical beads 3 has an average unique curvature of at least 200 μm⁻¹, 100 μm⁻¹, 66.6 μm⁻¹, 50 μm⁻¹, 33.3 μm⁻¹, 28.6 μm⁻¹, 25 μm⁻¹, 20 μm⁻¹, 18.2 μm⁻¹, 16.7 μm⁻¹, 15.4 μm⁻¹, 14.3 μm⁻¹, 13.3 μm⁻¹, 12.5 μm⁻¹, 11.8 μm⁻¹, 11.1 μm⁻¹, 10.5 μm⁻¹, 10 μm⁻¹, 9.5 μm⁻¹, 9.1 μm⁻¹, 8.7 μm⁻¹, 8.3 μm⁻¹, 8 μm⁻¹, 7.7 μm⁻¹, 7.4 μm⁻¹, 7.1 μm⁻¹, 6.9 μm⁻¹, 6.7 μm⁻¹, 5.7 μm⁻¹, 5 μm⁻¹, 4.4 μm⁻¹, 4 μm⁻¹, 3.6 3.3 μm⁻¹, 3.1 μm⁻¹, 2.9 μm⁻¹, 2.7 μm⁻¹, 2.5 μm⁻¹, 2.4 μm⁻¹, 2.2 μm⁻¹, 2.1 μm⁻¹, 2 μm⁻¹, 1.1 μm⁻¹, 1.3333 μm⁻¹, 0.8 μm⁻¹, 0.6666 μm⁻¹, 0.5714 μm⁻¹, 0.5 μm⁻¹, 0.4444 μm⁻¹, 0.4 μm⁻¹, 0.3636 μm⁻¹, 1.1 μm⁻¹, 0.3333 μm⁻¹, 0.3080 μm⁻¹, 0.2857 μm⁻¹, 0.2667 μm⁻¹, 0.25 μm⁻¹, 0.2353 μm⁻¹, 0.2222 μm⁻¹, 0.2105 μm⁻¹, 0.2 μm⁻¹, 0.1905 μm⁻¹, 0.1818 μm⁻¹, 0.1739 μm⁻¹, 0.1667 μm⁻¹, 0.16 μm⁻¹, 0.1538 μm⁻¹, 0.1481 μm⁻¹, 0.1429 μm⁻¹, 0.1379 μm⁻¹, 0.1333 μm⁻¹, 0.1290 μm⁻¹, 0.125 μm⁻¹, 0.1212 μm⁻¹, 0.1176 μm⁻¹, 0.1176 μm⁻¹, 0.1143 μm⁻¹, 0.1111 μm⁻¹, 0.1881 μm⁻¹, 0.1053 μm⁻¹, 0.1026 μm⁻¹, 0.1 μm⁻¹, 0.0976 μm⁻¹, 0.9524 μm⁻¹, 0.0930 μm⁻¹, 0.0909 μm⁻¹, 0.0889 μm⁻¹, 0.870 μm⁻¹, 0.0851 μm⁻¹, 0.0833 μm⁻¹, 0.0816 μm⁻¹, 0.08 μm⁻¹, 0.0784 μm⁻¹, 0.0769 μm⁻¹, 0.0755 μm⁻¹, 0.0741 μm⁻¹, 0.0727 μm⁻¹, 0.0714 μm⁻¹, 0.0702 μm⁻¹, 0.0690 μm⁻¹, 0.0678 μm⁻¹, 0.0667 μm⁻¹, 0.0656 μm⁻¹, 0.0645 μm⁻¹, 0.0635 μm⁻¹, 0.0625 μm⁻¹, 0.0615 μm⁻¹, 0.0606 μm⁻¹, 0.0597 μm⁻¹, 0.0588 μm⁻¹, 0.0580 μm⁻¹, 0.0571 μm⁻¹, 0.0563 μm⁻¹, 0.0556 μm⁻¹, 0.0548 μm⁻¹, 0.0541 μm⁻¹, 0.0533 μm⁻¹, 0.0526 μm⁻¹, 0.0519 μm⁻¹, 0.0513 μm⁻¹, 0.0506 μm⁻¹, 0.05 μm⁻¹, 0.0494 μm⁻¹, 0.0488 μm⁻¹, 0.0482 μm⁻¹, 0.0476 μm⁻¹, 0.0471 μm⁻¹, 0.0465 μm⁻¹, 0.0460 μm⁻¹, 0.0455 μm⁻¹, 0.0450 μm⁻¹, 0.0444 μm⁻¹, 0.0440 μm⁻¹, 0.0435 μm⁻¹, 0.0430 μm⁻¹, 0.0426 μm⁻¹, 0.0421 μm⁻¹, 0.0417 μm⁻¹, 0.0412 μm⁻¹, 0.0408 μm⁻¹, 0.0404 μm⁻¹, 0.04 μm⁻¹, 0.0396 μm⁻¹, 0.0392 μm⁻¹, 0.0388 μm⁻¹, 0.0385 μm⁻¹, 0.0381 μm⁻¹, 0.0377 μm⁻¹, 0.0374 μm⁻¹, 0.037 μm⁻¹, 0.0367 μm⁻¹, 0.0364 μm⁻¹, 0.0360 μm⁻¹, 0.0357 μm⁻¹, 0.0354 μm⁻¹, 0.0351 μm⁻¹, 0.0348 μm⁻¹, 0.0345 μm⁻¹, 0.0342 μm⁻¹, 0.0339 μm⁻¹, 0.0336 μm⁻¹, 0.0333 μm⁻¹, 0.0331 μm⁻¹, 0.0328 μm⁻¹, 0.0325 μm⁻¹, 0.0323 μm⁻¹, 0.032 μm⁻¹, 0.0317 μm⁻¹, 0.0315 μm⁻¹, 0.0312 μm⁻¹, 0.031 μm⁻¹, 0.0308 μm⁻¹, 0.0305 μm⁻¹, 0.0303 μm⁻¹, 0.0301 μm⁻¹, 0.03 μm⁻¹, 0.0299 μm⁻¹, 0.0296 μm⁻¹, 0.0294 μm⁻¹, 0.0292 μm⁻¹, 0.029 μm⁻¹, 0.0288 μm⁻¹, 0.0286 μm⁻¹, 0.0284 μm⁻¹, 0.0282 μm⁻¹, 0.028 μm⁻¹, 0.0278 μm⁻¹, 0.0276 μm⁻¹, 0.0274 μm⁻¹, 0.0272 μm⁻¹; 0.0270 μm⁻¹, 0.0268 μm⁻¹, 0.02667 μm⁻¹, 0.0265 μm⁻¹, 0.0263 μm⁻¹, 0.0261 μm⁻¹, 0.026 μm⁻¹, 0.0258 μm⁻¹, 0.0256 μm⁻¹, 0.0255 μm⁻¹, 0.0253 μm⁻¹, 0.0252 μm⁻¹, 0.025 μm⁻¹, 0.0248 μm⁻¹, 0.0247 μm⁻¹, 0.0245 μm⁻¹, 0.0244 μm⁻¹, 0.0242 μm⁻¹, 0.0241 μm⁻¹, 0.024 μm⁻¹, 0.0238 μm⁻¹, 0.0237 μm⁻¹, 0.0235 μm⁻¹, 0.0234 μm⁻¹, 0.0233 μm⁻¹, 0.231 μm⁻¹, 0.023 μm⁻¹, 0.0229 μm⁻¹, 0.0227 μm⁻¹, 0.0226 μm⁻¹, 0.0225 μm⁻¹, 0.0223 μm⁻¹, 0.0222 μm⁻¹, 0.0221 μm⁻¹, 0.022 μm⁻¹, 0.0219μm⁻¹, 0.0217 μm⁻¹, 0.0216 μm⁻¹, 0.0215 μm⁻¹, 0.0214 μm⁻¹, 0.0213μm⁻¹, 0.0212 μm⁻¹, 0.0211 μm⁻¹, 0.021 μm⁻¹, 0.0209 μm⁻¹, 0.0208 μm⁻¹, 0.0207 μm⁻¹, 0.0206 μm⁻¹, 0.0205 μm⁻¹, 0.0204 μm⁻¹, 0.0203 μm⁻¹, 0.0202 μm⁻¹, 0.0201 μm⁻¹, 0.02 μm⁻¹, or 0.002 μm⁻¹.

According to one embodiment, the curvature of the spherical bead 3 has no deviation, meaning that said bead 3 has a perfect spherical shape. A perfect spherical shape prevents fluctuations of the intensity of the scattered light.

According to one embodiment, the unique curvature of the spherical bead 3 may have a deviation less or equal to 0.01%, 0.02%, 0.03%, 0.04%, 0.05%, 0.06%, 0.07%, 0.08%, 0.09%, 0.1%, 0.2%, 0.3%, 0.4%, 0.5%, 0.6%, 0.7%, 0.8%, 0.9%, 1%, 1.1%, 1.2%, 1.3%, 1.4%, 1.5%, 1.6%, 1.7%, 1.8%, 1.9%, 2%, 2.1%, 2.2%, 2.3%, 2.4%, 2.5%, 2.6%, 2.7%, 2.8%, 2.9%, 3%, 3.1%, 3.2%, 3.3%, 3.4%, 3.5%, 3.6%, 3.7%, 3.8%, 3.9%, 4%, 4.1%, 4.2%, 4.3%, 4.4%, 4.5%, 4.6%, 4.7%, 4.8%, 4.9%, 5%, 5.1%, 5.2%, 5.3%, 5.4%, 5.5%, 5.6%, 5.7%, 5.8%, 5.9%, 6%, 6.1%, 6.2%, 6.3%, 6.4%, 6.5%, 6.6%, 6.7%, 6.8%, 6.9%, 7%, 7.1%, 7.2%, 7.3%, 7.4%, 7.5%, 7.6%, 7.7%, 7.8%, 7.9%, 8%, 8.1%, 8.2%, 8.3%, 8.4%, 8.5%, 8.6%, 8.7%, 8.8%, 8.9%, 9%, 9.1%, 9.2%, 9.3%, 9.4%, 9.5%, 9.6%, 9.7%, 9.8%, 9.9%, or 10% along the surface of said bead 3.

Bead 3 with an average size less than 1 μm have several advantages compared to bigger particles comprising the same number of aggregates 1: i) increasing the light scattering compared to bigger particles (only for beads 3 with a size superior to 100 nm); ii) obtaining more stable colloidal suspensions compared to bigger particles, when they are dispersed in a solvent; iii) having a size compatible with pixels of at least 100 nm.

Bead 3 with an average size larger than 1 μm have several advantages compared to smaller particles comprising the same number of aggregates 1: i) reducing light scattering compared to smaller particles; ii) having whispering-gallery wave modes; iii) having a size compatible with pixels larger than or equal to 1 μm; iv) increasing the average distance between particles 12 comprised in the aggregate 1, resulting in a better heat draining; v) increasing the average distance between particles 12 comprised in the aggregate 1 and the surface of said aggregate 1, thus better protecting the particles 12 against oxidation, or delaying oxidation resulting from a chemical reaction with chemical species coming from the outer space of said aggregate 1; vi) increasing the mass ratio between the aggregate 1 and particles 12 comprised in the aggregate 1 compared to smaller aggregates 1, thus reducing the mass concentration of chemical elements subject to ROHS standards, making it easier to comply with ROHS requirements.

According to one embodiment, the bead 3 is ROHS compliant.

According to one embodiment, the bead 3 comprises less than 10 ppm, less than 20 ppm, less than 30 ppm, less than 40 ppm, less than 50 ppm, less than 100 ppm, less than 150 ppm, less than 200 ppm, less than 250 ppm, less than 300 ppm, less than 350 ppm, less than 400 ppm, less than 450 ppm, less than 500 ppm, less than 550 ppm, less than 600 ppm, less than 650 ppm, less than 700 ppm, less than 750 ppm, less than 800 ppm, less than 850 ppm, less than 900 ppm, less than 950 ppm, less than 1000 ppm in weight of cadmium.

According to one embodiment, the bead 3 comprises less than 10 ppm, less than 20 ppm, less than 30 ppm, less than 40 ppm, less than 50 ppm, less than 100 ppm, less than 150 ppm, less than 200 ppm, less than 250 ppm, less than 300 ppm, less than 350 ppm, less than 400 ppm, less than 450 ppm, less than 500 ppm, less than 550 ppm, less than 600 ppm, less than 650 ppm, less than 700 ppm, less than 750 ppm, less than 800 ppm, less than 850 ppm, less than 900 ppm, less than 950 ppm, less than 1000 ppm, less than 2000 ppm, less than 3000 ppm, less than 4000 ppm, less than 5000 ppm, less than 6000 ppm, less than 7000 ppm, less than 8000 ppm, less than 9000 ppm, less than 10000 ppm in weight of lead.

According to one embodiment, the bead 3 comprises less than 10 ppm, less than 20 ppm, less than 30 ppm, less than 40 ppm, less than 50 ppm, less than 100 ppm, less than 150 ppm, less than 200 ppm, less than 250 ppm, less than 300 ppm, less than 350 ppm, less than 400 ppm, less than 450 ppm, less than 500 ppm, less than 550 ppm, less than 600 ppm, less than 650 ppm, less than 700 ppm, less than 750 ppm, less than 800 ppm, less than 850 ppm, less than 900 ppm, less than 950 ppm, less than 1000 ppm, less than 2000 ppm, less than 3000 ppm, less than 4000 ppm, less than 5000 ppm, less than 6000 ppm, less than 7000 ppm, less than 8000 ppm, less than 9000 ppm, less than 10000 ppm in weight of mercury.

According to one embodiment, the bead 3 comprises heavier chemical elements than the main chemical element present in the material 31. In this embodiment, said heavy chemical elements in the bead 3 will lower the mass concentration of chemical elements subject to ROHS standards, allowing said bead 3 to be ROHS compliant.

According to one embodiment, examples of heavy chemical elements include but are not limited to B, C, N, F, Na, Mg, Al, Si, P, S, Cl, K, Ca, Sc, Ti, V, Cr, Mn, Fe, Co, Ni, Cu, Zn, Ga, Ge, As, Se, Br, Rb, Sr, Y, Zr, Nb, Mo, Tc, Ru, Rh, Pd, Ag, Cd, In, Sn, Sb, Te, I, Cs, Ba, La, Hf, Ta, W, Re, Os, Ir, Pt, Au, Hg, Tl, Pb, Bi, Po, At, Ce, Pr, Nd, Pm, Sm, Eu, Gd, Tb, Dy, Ho, Er, Tm, Yb, Lu or a mixture of thereof.

According to one embodiment, the bead 3 exhibits at least one property so that the bead 3 is: magnetic; ferromagnetic; paramagnetic; superparamagnetic; diamagnetic; plasmonic; piezo-electric; pyro-electric; ferro-electric; drug delivery featured; a light scatterer; an electrical insulator; an electrical conductor; a thermal insulator; a thermal conductor; and/or a local high temperature heating system.

According to one embodiment, the bead 3 exhibits at least one property comprising one or more of the following: capacity of increasing local electromagnetic field, magnetization, magnetic coercivity, catalytic yield, catalytic properties, photovoltaic properties, photovoltaic yield, electrical polarization, thermal conductivity, electrical conductivity, permeability to molecular oxygen, permeability to molecular water, or any other properties.

According to one embodiment, the bead 3 is an electrical insulator. In this embodiment, the quenching of fluorescent properties for fluorescent particles 12 comprised in the aggregate 1 is prevented when it is due to electron transport. In this embodiment, the bead 3 may be used as an electrical insulator material exhibiting the same properties as the particles 12 comprised in the aggregate 1.

According to one embodiment, the bead 3 is an electrical conductor. This embodiment is particularly advantageous for an application of the aggregate 1 in photovoltaics or LEDs.

According to one embodiment, the bead 3 has an electrical conductivity at standard conditions ranging from 1×10⁻²⁰ to 10⁷ S/m, preferably from 1×10⁻¹⁵ to 5 S/m, more preferably from 1×10⁻⁷ to 1 S/m.

According to one embodiment, the bead 3 has an electrical conductivity at standard conditions of at least 1×10⁻²⁰ S/m, 0.5×10⁻¹⁹ S/m, 1×10⁻¹⁹ S/m, 0.5×10⁻¹⁸ S/m, 1×10⁻¹⁸ S/m, 0.5×10⁻¹⁷ S/m, 1×10⁻¹⁷ S/m, 0.5×10⁻¹⁶ S/m, 1×10⁻¹⁶ S/m, 0.5×10⁻¹⁵ S/m, 1×10⁻¹⁵ S/m, 0.5×10⁻¹⁴ S/m, 1×10⁻¹⁴ S/m, 0.5×10⁻¹³ S/m, 1×10⁻¹³ S/m, 0.5×10⁻¹²S/m, 1×10⁻¹²S/m, 0.5×10⁻¹¹ S/m, 1×10⁻¹¹ S/m, 0.5×10⁻¹⁰ S/m, 1×10⁻¹⁰ S/m, 0.5×10⁻⁹ S/m, 1×10⁻⁹ S/m, 0.5×10⁻⁸ S/m, 1×10⁻⁸ S/m, 0.5×10⁻⁷ S/m, 1×10⁻⁷ S/m, 0.5×10⁻⁶ S/m, 1×10⁻⁶ S/m, 0.5×10⁻⁵ S/m, 1×10⁻⁵ S/m, 0.5×10⁻⁴ S/m, 1×10⁻⁴ S/m, 0.5×10⁻³ S/m, 1×10⁻³ S/m, 0.5×10⁻² S/m, 1×10⁻² S/m, 0.5×10⁻¹ S/m, 1×10⁻¹ S/m, 0.5 S/m, 1 S/m, 1.5 S/m, 2 S/m, 2.5 S/m, 3 S/m, 3.5 S/m, 4 S/m, 4.5 S/m, 5 S/m, 5.5 S/m, 6 S/m, 6.5 S/m, 7 S/m, 7.5 S/m, 8 S/m, 8.5 S/m, 9 S/m, 9.5 S/m, 10 S/m, 50 S/m, 10² S/m, 5×10² S/m, 10³ S/m, 5×10³ S/m, 10⁴ S/m, 5×10⁴ S/m, 10⁵ S/m, 5×10⁵ S/m, 10⁶ S/m, 5×10⁶ S/m, or 10⁷ S/m.

According to one embodiment, the electrical conductivity of the bead 3 may be measured for example with an impedance spectrometer.

According to one embodiment, the bead 3 is a thermal insulator.

According to one embodiment, the bead 3 is a thermal conductor. In this embodiment, the bead 3 is capable of draining away the heat originating from the aggregate 1 during light excitation, or from the environment.

According to one embodiment, the bead 3 has a thermal conductivity at standard conditions ranging from 0.1 to 450 W/(m·K), preferably from 1 to 200 W/(m·K), more preferably from 10 to 150 W/(m·K).

According to one embodiment, the bead 3 has a thermal conductivity at standard conditions of at least 0.1 W/(m·K), 0.2 W/(m·K), 0.3 W/(m·K), 0.4 W/(m·K), 0.5 W/(m·K), 0.6 W/(m·K), 0.7 W/(m·K), 0.8 W/(m·K), 0.9 W/(m·K), 1 W/(m·K), 1.1 W/(m·K), 1.2 W/(m·K), 1.3 W/(m·K), 1.4 W/(m·K), 1.5 W/(m·K), 1.6 W/(m·K), 1.7 W/(m·K), 1.8 W/(m·K), 1.9 W/(m·K), 2 W/(m·K), 2.1 W/(m·K), 2.2 W/(m·K), 2.3 W/(m·K), 2.4 W/(m·K), 2.5 W/(m·K), 2.6 W/(m·K), 2.7 W/(m·K), 2.8 W/(m·K), 2.9 W/(m·K), 3 W/(m·K), 3.1 W/(m·K), 3.2 W/(m·K), 3.3 W/(m·K), 3.4 W/(m·K), 3.5 W/(m·K), 3.6 W/(m·K), 3.7 W/(m·K), 3.8 W/(m·K), 3.9 W/(m·K), 4 W/(m·K), 4.1 W/(m·K), 4.2 W/(m·K), 4.3 W/(m·K), 4.4 W/(m·K), 4.5 W/(m·K), 4.6 W/(m·K), 4.7 W/(m·K), 4.8 W/(m·K), 4.9 W/(m·K), 5 W/(m·K), 5.1 W/(m·K), 5.2 W/(m·K), 5.3 W/(m·K), 5.4 W/(m·K), 5.5 W/(m·K), 5.6 W/(m·K), 5.7 W/(m·K), 5.8 W/(m·K), 5.9 W/(m·K), 6 W/(m·K), 6.1 W/(m·K), 6.2 W/(m·K), 6.3 W/(m·K), 6.4 W/(m·K), 6.5 W/(m·K), 6.6 W/(m·K), 6.7 W/(m·K), 6.8 W/(m·K), 6.9 W/(m·K), 7 W/(m·K), 7.1 W/(m·K), 7.2 W/(m·K), 7.3 W/(m·K), 7.4 W/(m·K), 7.5 W/(m·K), 7.6 W/(m·K), 7.7 W/(m·K), 7.8 W/(m·K), 7.9 W/(m·K), 8 W/(m·K), 8.1 W/(m·K), 8.2 W/(m·K), 8.3 W/(m·K), 8.4 W/(m·K), 8.5 W/(m·K), 8.6 W/(m·K), 8.7 W/(m·K), 8.8 W/(m·K), 8.9 W/(m·K), 9 W/(m·K), 9.1 W/(m·K), 9.2 W/(m·K), 9.3 W/(m·K), 9.4 W/(m·K), 9.5 W/(m·K), 9.6 W/(m·K), 9.7 W/(m·K), 9.8 W/(m·K), 9.9 W/(m·K), 10 W/(m·K), 10.1 W/(m·K), 10.2 W/(m·K), 10.3 W/(m·K), 10.4 W/(m·K), 10.5 W/(m·K), 10.6 W/(m·K), 10.7 W/(m·K), 10.8 W/(m·K), 10.9 W/(m·K), 11 W/(m·K), 11.1 W/(m·K), 11.2 W/(m·K), 11.3 W/(m·K), 11.4 W/(m·K), 11.5 W/(m·K), 11.6 W/(m·K), 11.7 W/(m·K), 11.8 W/(m·K), 11.9 W/(m·K), 12 W/(m·K), 12.1 W/(m·K), 12.2 W/(m·K), 12.3 W/(m·K), 12.4 W/(m·K), 12.5 W/(m·K), 12.6 W/(m·K), 12.7 W/(m·K), 12.8 W/(m·K), 12.9 W/(m·K), 13 W/(m·K), 13.1 W/(m·K), 13.2 W/(m·K), 13.3 W/(m·K), 13.4 W/(m·K), 13.5 W/(m·K), 13.6 W/(m·K), 13.7 W/(m·K), 13.8 W/(m·K), 13.9 W/(m·K), 14 W/(m·K), 14.1 W/(m·K), 14.2 W/(m·K), 14.3 W/(m·K), 14.4 W/(m·K), 14.5 W/(m·K), 14.6 W/(m·K), 14.7 W/(m·K), 14.8 W/(m·K), 14.9 W/(m·K), 15 W/(m·K), 15.1 W/(m·K), 15.2 W/(m·K), 15.3 W/(m·K), 15.4 W/(m·K), 15.5 W/(m·K), 15.6 W/(m·K), 15.7 W/(m·K), 15.8 W/(m·K), 15.9 W/(m·K), 16 W/(m·K), 16.1 W/(m·K), 16.2 W/(m·K), 16.3 W/(m·K), 16.4 W/(m·K), 16.5 W/(m·K), 16.6 W/(m·K), 16.7 W/(m·K), 16.8 W/(m·K), 16.9 W/(m·K), 17 W/(m·K), 17.1 W/(m·K), 17.2 W/(m·K), 17.3 W/(m·K), 17.4 W/(m·K), 17.5 W/(m·K), 17.6 W/(m·K), 17.7 W/(m·K), 17.8 W/(m·K), 17.9 W/(m·K), 18 W/(m·K), 18.1 W/(m·K), 18.2 W/(m·K), 18.3 W/(m·K), 18.4 W/(m·K), 18.5 W/(m·K), 18.6 W/(m·K), 18.7 W/(m·K), 18.8 W/(m·K), 18.9 W/(m·K), 19 W/(m·K), 19.1 W/(m·K), 19.2 W/(m·K), 19.3 W/(m·K), 19.4 W/(m·K), 19.5 W/(m·K), 19.6 W/(m·K), 19.7 W/(m·K), 19.8 W/(m·K), 19.9 W/(m·K), 20 W/(m·K), 20.1 W/(m·K), 20.2 W/(m·K), 20.3 W/(m·K), 20.4 W/(m·K), 20.5 W/(m·K), 20.6 W/(m·K), 20.7 W/(m·K), 20.8 W/(m·K), 20.9 W/(m·K), 21 W/(m·K), 21.1 W/(m·K), 21.2 W/(m·K), 21.3 W/(m·K), 21.4 W/(m·K), 21.5 W/(m·K), 21.6 W/(m·K), 21.7 W/(m·K), 21.8 W/(m·K), 21.9 W/(m·K), 22 W/(m·K), 22.1 W/(m·K), 22.2 W/(m·K), 22.3 W/(m·K), 22.4 W/(m·K), 22.5 W/(m·K), 22.6 W/(m·K), 22.7 W/(m·K), 22.8 W/(m·K), 22.9 W/(m·K), 23 W/(m·K), 23.1 W/(m·K), 23.2 W/(m·K), 23.3 W/(m·K), 23.4 W/(m·K), 23.5 W/(m·K), 23.6 W/(m·K), 23.7 W/(m·K), 23.8 W/(m·K), 23.9 W/(m·K), 24 W/(m·K), 24.1 W/(m·K), 24.2 W/(m·K), 24.3 W/(m·K), 24.4 W/(m·K), 24.5 W/(m·K), 24.6 W/(m·K), 24.7 W/(m·K), 24.8 W/(m·K), 24.9 W/(m·K), 25 W/(m·K), 30 W/(m·K), 40 W/(m·K), 50 W/(m·K), 60 W/(m·K), 70 W/(m·K), 80 W/(m·K), 90 W/(m·K), 100 W/(m·K), 110 W/(m·K), 120 W/(m·K), 130 W/(m·K), 140 W/(m·K), 150 W/(m·K), 160 W/(m·K), 170 W/(m·K), 180 W/(m·K), 190 W/(m·K), 200 W/(m·K), 210 W/(m·K), 220 W/(m·K), 230 W/(m·K), 240 W/(m·K), 250 W/(m·K), 260 W/(m·K), 270 W/(m·K), 280 W/(m·K), 290 W/(m·K), 300 W/(m·K), 310 W/(m·K), 320 W/(m·K), 330 W/(m·K), 340 W/(m·K), 350 W/(m·K), 360 W/(m·K), 370 W/(m·K), 380 W/(m·K), 390 W/(m·K), 400 W/(m·K), 410 W/(m·K), 420 W/(m·K), 430 W/(m·K), 440 W/(m·K), or 450 W/(m·K).

According to one embodiment, the thermal conductivity of the bead 3 may be measured for example by steady-state methods or transient methods.

According to one embodiment, the bead 3 is hydrophobic.

According to one embodiment, the bead 3 is hydrophilic.

According to one embodiment, the bead 3 is surfactant-free. In this embodiment, the surface of the bead 3 will be easy to functionalize as said surface will not be blocked by any surfactant molecule.

According to one embodiment, the bead 3 is not surfactant-free.

According to one embodiment, the bead 3 is amorphous.

According to one embodiment, the bead 3 is crystalline.

According to one embodiment, the bead 3 is totally crystalline.

According to one embodiment, the bead 3 is partially crystalline.

According to one embodiment, the bead 3 is monocrystalline.

According to one embodiment, the bead 3 is polycrystalline. In this embodiment, the bead 3 comprises at least one grain boundary.

According to one embodiment, the bead 3 is porous.

According to one embodiment, the bead 3 is considered porous when the quantity adsorbed by the bead 3 determined by adsorption-desorption of nitrogen in the Brunauer-Emmett-Teller (BET) theory is more than 20 cm³/g, 15 cm³/g, 10 cm³/g, 5 cm³/g at a nitrogen pressure of 650 mmHg, preferably 700 mmHg

According to one embodiment, the organization of the porosity of the bead 3 can be hexagonal, vermicular or cubic.

According to one embodiment, the organized porosity of the bead 3 has a pore size of at least 1 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, or 50 nm.

According to one embodiment, the bead 3 is not porous.

According to one embodiment, the bead 3 does not comprise pores or cavities.

According to one embodiment, the bead 3 is considered non-porous when the quantity adsorbed by said bead 3 determined by adsorption-desorption of nitrogen in the Brunauer-Emmett-Teller (BET) theory is less than 20 cm³/g, 15 cm³/g, 10 cm³/g, 5 cm³/g at a nitrogen pressure of 650 mmHg, preferably 700 mmHg

According to one embodiment, the bead 3 is permeable.

According to one embodiment, the permeable bead 3 has an intrinsic permeability to fluids higher or equal to 10⁻¹¹ cm², 10⁻¹⁰ cm², 10⁻⁹ cm², 10⁻⁸ cm², 10⁻⁷ cm², 10⁻⁶ cm², 10⁻⁵ cm², 10⁻⁴ cm², or 10⁻³ cm².

According to one embodiment, the bead 3 is impermeable to outer molecular species, gas or liquid.

According to one embodiment, the impermeable bead 3 has an intrinsic permeability to fluids less or equal to 10⁻¹¹ cm², 10⁻¹² cm², 10⁻¹³ cm², 10⁻¹⁴ cm², or 10⁻¹⁵ cm².

According to one embodiment, the bead 3 has an oxygen transmission rate ranging from 10⁻⁷ to 10 cm³.m⁻².day⁻¹, preferably from 10⁻⁷ to 1 cm³.m⁻².day⁻¹, more preferably from 10⁻⁷ to 10⁻¹ cm³.m⁻².day⁻¹, even more preferably from 10⁻⁷ to 10⁻⁴ cm³.m⁻².day⁻¹ at room temperature.

According to one embodiment, the bead 3 has a water vapor transmission rate ranging from 10⁻⁷ to 10 g·m⁻².day⁻¹, preferably from 10⁻⁷ to 1 g·m⁻².day⁻¹, more preferably from 10⁻⁷ to 10⁻¹ g·m⁻².day⁻¹, even more preferably from 10⁻⁷ to 10⁻⁴ g·m⁻².day⁻¹ at room temperature. A water vapor transmission rate of 10⁻⁶ g·m⁻².day⁻¹ is particularly adequate for a use on LED.

According to one embodiment, the bead 3 is optically transparent, i.e. the bead 3 is transparent at wavelengths between 200 nm and 50 μm, between 200 nm and 10 μm, between 200 nm and 2500 nm, between 200 nm and 2000 nm, between 200 nm and 1500 nm, between 200 nm and 1000 nm, between 200 nm and 800 nm, between 400 nm and 700 nm, between 400 nm and 600 nm, or between 400 nm and 470 nm.

According to one embodiment, the bead 3 comprises at least one aggregate 1 dispersed in the material 31.

According to one embodiment, the bead 3 does not comprise only one aggregate 1 dispersed in the material 31. In this embodiment, the bead 3 is not a core/shell particle wherein the aggregate 1 is the core with a shell of the material 31.

According to one embodiment, the bead 3 comprises at least two aggregates 1 dispersed in the material 31.

According to one embodiment, the bead 3 comprises a plurality of aggregates 1 dispersed in the material 31.

According to one embodiment, the bead 3 comprises at least 1, at least 2, at least 3, at least 4, at least 5, at least 6, at least 7, at least 8, at least 9, at least 10, at least 11, at least 12, at least 13, at least 14, at least 15, at least 16, at least 17, at least 18, at least 19, at least 20, at least 21, at least 22, at least 23, at least 24, at least 25, at least 26, at least 27, at least 28, at least 29, at least 30, at least 31, at least 32, at least 33, at least 34, at least 35, at least 36, at least 37, at least 38, at least 39, at least 40, at least 41, at least 42, at least 43, at least 44, at least 45, at least 46, at least 47, at least 48, at least 49, at least 50, at least 51, at least 52, at least 53, at least 54, at least 55, at least 56, at least 57, at least 58, at least 59, at least 60, at least 61, at least 62, at least 63, at least 64, at least 65, at least 66, at least 67, at least 68, at least 69, at least 70, at least 71, at least 72, at least 73, at least 74, at least 75, at least 76, at least 77, at least 78, at least 79, at least 80, at least 81, at least 82, at least 83, at least 84, at least 85, at least 86, at least 87, at least 88, at least 89, at least 90, at least 91, at least 92, at least 93, at least 94, at least 95, at least 96, at least 97, at least 98, at least 99, at least 100, at least 200, at least 300, at least 400, at least 500, at least 600, at least 700, at least 800, at least 900, at least 1000, at least 1500, at least 2000, at least 2500, at least 3000, at least 3500, at least 4000, at least 4500, at least 5000, at least 5500, at least 6000, at least 6500, at least 7000, at least 7500, at least 8000, at least 8500, at least 9000, at least 9500, at least 10000, at least 15000, at least 20000, at least 25000, at least 30000, at least 35000, at least 40000, at least 45000, at least 50000, at least 55000, at least 60000, at least 65000, at least 70000, at least 75000, at least 80000, at least 85000, at least 90000, at least 95000, or at least 100000 aggregates 1 dispersed in the material 31.

According to one embodiment, the aggregate 1 is totally surrounded by or encapsulated in the material 31.

According to one embodiment, the aggregate 1 is partially surrounded by or encapsulated in the material 31.

According to one embodiment, the aggregate 1 represents at least 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, 91%, 92%, 93%, 94%, 95%, 96%, 97%, 98%, or 99% by weight of the bead 3.

According to one embodiment, the loading charge of the aggregate 1 in the bead 3 is at least 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, 91%, 92%, 93%, 94%, 95%, 96%, 97%, 98%, or 99%.

According to one embodiment, the loading charge of the aggregate 1 in the bead 3 is less than 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, 91%, 92%, 93%, 94%, 95%, 96%, 97%, 98%, or 99%.

According to one embodiment, the aggregate 1 comprised in the bead 3 have a packing fraction of at least 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, or 95%.

According to one embodiment, the aggregates 1 comprised in the same bead 3 are not aggregated.

According to one embodiment, the aggregates 1 comprised in the same bead 3 do not touch, are not in contact.

According to one embodiment, the aggregates 1 comprised in the same bead 3 are separated by the material 31.

According to one embodiment, the aggregates 1 comprised in the same bead 3 are aggregated.

According to one embodiment, the aggregates 1 comprised in the same bead 3 touch, are in contact.

According to one embodiment, the aggregate 1 comprised in the same bead 3 can be individually evidenced.

According to one embodiment, the aggregate 1 comprised in the same bead 3 can be individually evidenced by transmission electron microscopy or fluorescence scanning microscopy, or any other characterization means known by the person skilled in the art.

According to one embodiment, the plurality of aggregates 1 is uniformly dispersed in the material 31.

The uniform dispersion of the plurality of aggregates 1 in the material 31 comprised in the bead 3 prevents the aggregation of said aggregates 1, thereby preventing the degradation of their properties. For example, in the case of inorganic fluorescent particles, a uniform dispersion will allow the optical properties of said particles to be preserved, and aggregation quenching can be avoided.

According to one embodiment, each aggregate 1 of the plurality of aggregates 1 is spaced from its adjacent aggregate 1 by an average minimal distance. In this embodiment, the average minimal distance is as described hereabove.

According to one embodiment, the bead 3 comprises a combination of at least two different aggregates 1. In this embodiment, the resulting bead 3 will exhibit different properties.

In a preferred embodiment, the bead 3 comprises at least two different aggregates 1, wherein at least one aggregate 1 emits at a peak wavelength in the range from 500 to 560 nm, and at least one aggregate 1 emits at a peak wavelength in the range from 600 to 2500 nm. In this embodiment, the bead 3 comprises at least one aggregate 1 emitting in the green region of the visible spectrum and at least one aggregate 1 emitting in the red region of the visible spectrum, thus the bead 3 paired with a blue LED will be a white light emitter.

In a preferred embodiment, the bead 3 comprises at least two different aggregates 1, wherein at least one aggregate 1 emits at a peak wavelength in the range from 400 to 490 nm, and at least one aggregate 1 emits at a peak wavelength in the range from 600 to 2500 nm. In this embodiment, the bead 3 comprises at least one aggregate 1 emitting in the blue region of the visible spectrum and at least one aggregate 1 emitting in the red region of the visible spectrum, thus the bead 3 will be a white light emitter.

In a preferred embodiment, the bead 3 comprises at least two luminescent different aggregates 1, wherein at least one aggregate 1 emits at a peak wavelength in the range from 400 to 490 nm, and at least one aggregate 1 emits at a peak wavelength in the range from 500 to 560 nm. In this embodiment, the bead 3 comprises at least one aggregate 1 emitting in the blue region of the visible spectrum and at least one aggregate 1 emitting in the green region of the visible spectrum.

In a preferred embodiment, the bead 3 comprises three different aggregates 1, wherein said aggregates 1 emit different emission wavelengths or colors.

In a preferred embodiment, the bead 3 comprises at least three different aggregates 1, wherein at least one aggregate 1 emits at a peak wavelength in the range from 400 to 490 nm, at least one aggregate 1 emits at a peak wavelength in the range from 500 to 560 nm and at least one aggregate 1 emits at a peak wavelength in the range from 600 to 2500 nm. In this embodiment, the bead 3 comprises at least one aggregate 1 emitting in the blue region of the visible spectrum, at least one aggregate 1 emitting in the green region of the visible spectrum and at least one aggregate 1 emitting in the red region of the visible spectrum.

In a preferred embodiment, the bead 3 does not comprise any aggregate 1 on its surface. In this embodiment, the at least one aggregate 1 is completely surrounded by the material 31.

According to one embodiment, at least 100%, 95%, 90%, 85%, 80%, 75%, 70%, 65%, 60%, 55%, 50%, 45%, 40%, 35%, 30%, 25%, 20%, 15%, 10%, 5%, or 1% of aggregates 1 are comprised in the material 31. In this embodiment, each of said aggregates 1 is completely surrounded by the material 31.

According to one embodiment, the bead 3 comprises at least 100%, 95%, 90%, 85%, 80%, 75%, 70%, 65%, 60%, 55%, 50%, 45%, 40%, 35%, 30%, 25%, 20%, 15%, 10%, 5%, 1% or 0% of aggregates 1 on its surface.

According to one embodiment, the bead 3 comprises at least one aggregate 1 dispersed in the material 31, i.e. totally surrounded by said material 31; and at least one aggregate 1 located on the surface of said bead 3.

According to one embodiment, the aggregate 1 is only located on the surface of said bead 3. This embodiment is advantageous as the aggregate 1 will be better excited by the incident light than if said aggregate 1 was dispersed in the material 31.

According to one embodiment, the aggregate 1 located on the surface of said bead 3 may be chemically or physically adsorbed on said surface.

According to one embodiment, the aggregate 1 located on the surface of said bead 3 may be adsorbed on said surface.

According to one embodiment, the aggregate 1 located on the surface of said bead 3 may be adsorbed with a cement on said surface.

According to one embodiment, examples of cement include but are not limited to: polymers, silicon, oxides, or a mixture thereof.

According to one embodiment, the aggregate 1 located on the surface of said bead 3 may have at least 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 95%, or 100% of its volume trapped in the material 31.

According to one embodiment, the plurality of aggregates 1 is uniformly spaced on the surface of the bead 3.

According to one embodiment, each aggregate 1 of the plurality of aggregates 1 is spaced from its adjacent aggregate 1 by an average minimal distance. In this embodiment, the average minimal distance is as described hereabove.

According to one embodiment, the bead 3 exhibits a shelf life of at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

According to one embodiment, the bead 3 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

Photoluminescence refers to fluorescence and/or phosphorescence.

According to one embodiment, the bead 3 exhibits a degradation of its photoluminescence of less than 90%, 80%, 70%, 60%, 50%, 40%, 30%, 25%, 20%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the bead 3 exhibits a degradation of its photoluminescence of less than 90%, 80%, 70%, 60%, 50%, 40%, 30%, 25%, 20%, 10%, 5%, 4%, 3%, 2%, 1%, or 0% under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its photoluminescence of less than 90%, 80%, 70%, 60%, 50%, 40%, 30%, 25%, 20%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its photoluminescence photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the bead 3 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment.

According to one embodiment, the bead 3 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the bead 3 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its photoluminescence of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

In one embodiment, the bead 3 exhibits photoluminescence quantum yield (PLQY) decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination.

According to one embodiment, the light illumination is provided by blue, green, red, or UV light source such as laser, diode, fluorescent lamp or Xenon Arc Lamp. According to one embodiment, the photon flux or average peak pulse power of the illumination is comprised between 1 mW·cm⁻² and 100 kW·cm⁻², more preferably between 10 mW·cm⁻² and 100 W·cm⁻², and even more preferably between 10 mW·cm⁻² and 30 W·cm⁻².

According to one embodiment, the photon flux or average peak pulse power of the illumination is at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the bead 3 exhibits photoluminescence quantum yield (PQLY) decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the bead 3 exhibits FCE decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

According to one embodiment, the bead 3 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

According to one embodiment, the bead 3 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the bead 3 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the bead 3 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment.

According to one embodiment, the bead 3 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the bead 3 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its photoluminescence quantum yield (PLQY) of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

According to one embodiment, the bead 3 exhibits a degradation of its FCE of less than 90%, 80%, 70%, 60%, 50%, 40%, 30%, 25%, 20%, 10%, 5%, 4%, 3%, 2%, 1%, or 0% under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the bead 3 exhibits a degradation of its FCE of less than 90%, 80%, 70%, 60%, 50%, 40%, 30%, 25%, 20%, 10%, 5%, 4%, 3%, 2%, 1%, or 0% under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its FCE of less than 90%, 80%, 70%, 60%, 50%, 40%, 30%, 25%, 20%, 10%, 5%, 4%, 3%, 2%, 1%, or 0% under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the bead 3 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular O₂.

According to one embodiment, the bead 3 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular O₂, under 0° C., 10° C., 20° C., 30° C., 40° C., 50° C., 60° C., 70° C., 80° C., 90° C. 100° C., 125° C., 150° C., 175° C., 200° C., 225° C., 250° C., 275° C., or 300° C.

According to one embodiment, the bead 3 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular O₂, under 0%, 10%, 20%, 30%, 40%, 50%, 55%, 60%, 65%, 70%, 75%, 80%, 85%, 90%, 95%, or 99% of humidity.

According to one embodiment, the bead 3 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular 02, under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the material 31 is an organic material as described hereabove.

According to one embodiment, the material 31 is an inorganic material as described hereabove.

According to one embodiment, the material 31 is a hybrid material as described hereabove.

According to one embodiment, the material 31 is the same or different from the material 11.

According to one embodiment, the material 31 is different from the material 11.

According to one embodiment, the material 31 has a density superior or equal to the density of the material 11.

According to one embodiment, the material 31 has a refractive index ranging from 1 to 5, from 1.2 to 2.6, from 1.4 to 2.0 at 450 nm.

According to one embodiment, the material 31 has the same refractive index than the material 11.

According to one embodiment, the material 31 has a refractive index distinct from the refractive index of the material 11. This embodiment allows for a wider scattering of light. This embodiment also allows to have a difference in light scattering as a function of the wavelength, in particular to increase the scattering of the excitation light with respect to the scattering of the emitted light, as the wavelength of the excitation light is lower than the wavelength of the emitted light.

According to one embodiment, the material 31 has a refractive index superior or equal to the refractive index of the material 11.

According to one embodiment, the material 31 has a refractive index inferior to the refractive index of the material 11.

According to one embodiment, the material 31 has a difference of refractive index with the refractive index of the material 11 of at least 0.02, 0.025, 0.03, 0.035, 0.04, 0.045, 0.05, 0.055, 0.06, 0.065, 0.07, 0.075, 0.08, 0.085, 0.09, 0.095, 0.1, 0.11, 0.115, 0.12, 0.125, 0.13, 0.135, 0.14, 0.145, 0.15, 0.155, 0.16, 0.165, 0.17, 0.175, 0.18, 0.185, 0.19, 0.195, 0.2, 0.25, 0.3, 0.35, 0.4, 0.45, 0.5, 0.55, 0.6, 0.65, 0.7, 0.75, 0.8, 0.85, 0.9, 0.95, 1, 1.1, 1.15, 1.2, 1.25, 1.3, 1.35, 1.4, 1.45, 1.5, 1.55, 1.6, 1.65, 1.7, 1.75, 1.8, 1.85, 1.9, 1.95, or 2 at 450 nm.

According to one embodiment, the material 31 has a difference of refractive index with the refractive index of the material 11 of 0.02 at 450 nm.

According to one embodiment, the material 31 is optically transparent, i.e. the material 31 is transparent at wavelengths between 200 nm and 50 um, between 200 nm and 10 um, between 200 nm and 2500 nm, between 200 nm and 2000 nm, between 200 nm and 1500 nm, between 200 nm and 1000 nm, between 200 nm and 800 nm, between 400 nm and 700 nm, between 400 nm and 600 nm, or between 400 nm and 470 nm. In this embodiment, the material 31 does not absorb all incident light allowing the at least one aggregate 1 to absorb all the incident light; and/or material 31 does not absorb the light emitted by the at least one aggregate 1 allowing to said light emitted to be transmitted through the material 31.

According to one embodiment, the material 31 is not optically transparent, i.e. the material 31 absorbs light at wavelengths between 200 nm and 50 um, between 200 nm and 10 um, between 200 nm and 2500 nm, between 200 nm and 2000 nm, between 200 nm and 1500 nm, between 200 nm and 1000 nm, between 200 nm and 800 nm, between 400 nm and 700 nm, between 400 nm and 600 nm, or between 400 nm and 470 nm. In this embodiment, the material 31 absorbs part of the incident light allowing the at least one aggregate 1 to absorb only a part of the incident light; and/or the material 31 absorbs part of the light emitted by the at least one aggregate 1 allowing said light emitted to be partially transmitted through the material 31.

In a preferred embodiment, examples of aggregates 1 include but are not limited to: PMMA aggregates comprising semiconductor nanoplatelets aggregated on their surface; aggregates comprising semiconductor nanoplatelets uniformly dispersed in PMMA; PMMA aggregates comprising beads on their surface, wherein said beads comprise semiconductor nanoplatelets; PMMA aggregates comprising semiconductor nanoplatelets aggregated on their surface, wherein said PMMA aggregates are encapsulated in a bigger bead.

Another object of the invention relates to a light emitting material 7 comprising at least one host material 71 and at least one aggregate 1 of the invention, wherein said at least one aggregate 1 is dispersed in the at least one host material 71 (as illustrated in FIG. 9A).

The light emitting material 7 allows the protection of the aggregate 1 from molecular oxygen, ozone, water and/or high temperature by the at least one host material 71. Therefore, deposition of a supplementary protective layer on top of said light emitting material 7 is not compulsory, which can save time, money and loss of luminescence.

Encapsulating the particles 12 in the aggregate 1 allow for a good dispersion of said particles 12 in a host material 71 that would otherwise chemically incompatible with said particles 12.

According to one embodiment, the at least one aggregate 1 in the host material 71 is configured to scatter light.

According to one embodiment, the at least one aggregate 1 in the host material 71 is configured to serve as a waveguide. In this embodiment, the refractive index of the at least one aggregate 1 is higher than the refractive index of the host material 71.

According to one embodiment, the aggregate 1 has a spherical shape. The spherical shape may permit to the light to circulate in the aggregate 1 without leaving said luminescent particle such as to operate as a waveguide. The spherical shape may permit to the light to have whispering-gallery wave modes. Furthermore, a perfect spherical shape prevents fluctuations of the intensity of the scattered light.

According to one embodiment, the at least one aggregate 1 in the host material 71 is configured to generate multiple reflections of light inside said aggregate 1.

According to one embodiment, the host material 71 surrounds, encapsulates and/or covers partially or totally at least one aggregate 1.

According to one embodiment, the light emitting material 7 further comprises a plurality of aggregates 1.

According to one embodiment, the plurality of aggregates 1 is uniformly dispersed in the host material 71.

According to one embodiment, the loading charge of aggregates 1 in the host material 71 is at least 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, 91%, 92%, 93%, 94%, 95%, 96%, 97%, 98%, or 99%.

According to one embodiment, the loading charge of aggregates 1 in the host material 71 is less than 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, 91%, 92%, 93%, 94%, 95%, 96%, 97%, 98%, or 99%.

According to one embodiment, the aggregates 1 dispersed in the host material 71 have a packing fraction of at least 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, or 95%.

According to one embodiment, the aggregates 1 dispersed in the host material 71 have a packing fraction of less than 0.01%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, or 95%.

According to one embodiment, the aggregates 1 are adjoigning, are in contact.

According to one embodiment, in the same host material 71, the aggregates 1 are not aggregated.

According to one embodiment in the same host material 71, the aggregates 1 do not touch, are not in contact.

According to one embodiment, the aggregates 1 do not touch, are not in contact.

According to one embodiment, the aggregates 1 are separated by the host material 71.

According to one embodiment, the aggregates 1 can be individually evidenced for example by conventional microscopy, transmission electron microscopy, scanning transmission electron microscopy, scanning electron microscopy, or fluorescence scanning microscopy.

According to one embodiment, each aggregate 1 of the plurality of aggregates 1 is spaced from its adjacent aggregate 1 by an average minimal distance. In this embodiment, the average minimal distance is as described hereabove.

In one embodiment, the light emitting material 7 of the invention comprises at least one population of aggregates 1. In one embodiment, a population of aggregates 1 is defined by the maximum emission wavelength.

In one embodiment, the light emitting material 7 comprises two populations of aggregates 1 emitting different colors or wavelengths.

In one embodiment, the concentration of the at least two populations of aggregates 1 comprised in the light emitting material 7 and emitting different colors or wavelengths, is controlled to predetermine the light intensity of each secondary light emitted by each of the least two populations of aggregates 1, after excitation by an incident light.

In one embodiment, the light emitting material 7 comprises aggregates 1 which emit green light and red light upon downconversion of a blue light source. In this embodiment, the light emitting material 7 is configured to transmit a predetermined intensity of the blue light from the light source and to emit a predetermined intensity of secondary green and red lights, allowing to emit a resulting tri-chromatic white light.

According to one embodiment, the light emitting material 7 comprises at least one aggregate 1 comprising at least one particle 12 that emits green light upon downconversion of a blue light source.

According to one embodiment, the light emitting material 7 comprises at least one aggregate 1 comprising at least one particle 12 that emits orange light upon downconversion of a blue light source.

According to one embodiment, the light emitting material 7 comprises at least one aggregate 1 comprising at least one particle 12 that emits yellow light upon downconversion of a blue light source.

According to one embodiment, the light emitting material 7 comprises at least one aggregate 1 comprising at least one particle 12 that emits purple light upon downconversion of a blue light source.

In one embodiment, the light emitting material 7 comprises two populations of aggregates 1, a first population with a maximum emission wavelength between 500 nm and 560 nm, more preferably between 515 nm and 545 nm and a second population with a maximum emission wavelength between 600 nm and 2500 nm, more preferably between 610 nm and 650 nm.

In one embodiment, the light emitting material 7 comprises three populations of aggregates 1, a first population of aggregates 1 with a maximum emission wavelength between 440 and 499 nm, more preferably between 450 and 495 nm, a second population of aggregates 1 with a maximum emission wavelength between 500 nm and 560 nm, more preferably between 515 nm and 545 nm and a third population of aggregates 1 with a maximum emission wavelength between 600 nm and 2500 nm, more preferably between 610 nm and 650 nm.

According to one embodiment, aggregates 1 of the invention are incorporated in the host material 71 at a level ranging from 100 ppm to 500 000 ppm in weight.

According to one embodiment, aggregates 1 of the invention are incorporated in the host material 71 at a level of at least 100 ppm, 200 ppm, 300 ppm, 400 ppm, 500 ppm, 600 ppm, 700 ppm, 800 ppm, 900 ppm, 1000 ppm, 1100 ppm, 1200 ppm, 1300 ppm, 1400 ppm, 1500 ppm, 1600 ppm, 1700 ppm, 1800 ppm, 1900 ppm, 2000 ppm, 2100 ppm, 2200 ppm, 2300 ppm, 2400 ppm, 2500 ppm, 2600 ppm, 2700 ppm, 2800 ppm, 2900 ppm, 3000 ppm, 3100 ppm, 3200 ppm, 3300 ppm, 3400 ppm, 3500 ppm, 3600 ppm, 3700 ppm, 3800 ppm, 3900 ppm, 4000 ppm, 4100 ppm, 4200 ppm, 4300 ppm, 4400 ppm, 4500 ppm, 4600 ppm, 4700 ppm, 4800 ppm, 4900 ppm, 5000 ppm, 5100 ppm, 5200 ppm, 5300 ppm, 5400 ppm, 5500 ppm, 5600 ppm, 5700 ppm, 5800 ppm, 5900 ppm, 6000 ppm, 6100 ppm, 6200 ppm, 6300 ppm, 6400 ppm, 6500 ppm, 6600 ppm, 6700 ppm, 6800 ppm, 6900 ppm, 7000 ppm, 7100 ppm, 7200 ppm, 7300 ppm, 7400 ppm, 7500 ppm, 7600 ppm, 7700 ppm, 7800 ppm, 7900 ppm, 8000 ppm, 8100 ppm, 8200 ppm, 8300 ppm, 8400 ppm, 8500 ppm, 8600 ppm, 8700 ppm, 8800 ppm, 8900 ppm, 9000 ppm, 9100 ppm, 9200 ppm, 9300 ppm, 9400 ppm, 9500 ppm, 9600 ppm, 9700 ppm, 9800 ppm, 9900 ppm, 10000 ppm, 10500 ppm, 11000 ppm, 11500 ppm, 12000 ppm, 12500 ppm, 13000 ppm, 13500 ppm, 14000 ppm, 14500 ppm, 15000 ppm, 15500 ppm, 16000 ppm, 16500 ppm, 17000 ppm, 17500 ppm, 18000 ppm, 18500 ppm, 19000 ppm, 19500 ppm, 20000 ppm, 30000 ppm, 40000 ppm, 50000 ppm, 60000 ppm, 70000 ppm, 80000 ppm, 90000 ppm, 100000 ppm, 110000 ppm, 120000 ppm, 130000 ppm, 140000 ppm, 150000 ppm, 160000 ppm, 170000 ppm, 180000 ppm, 190000 ppm, 200000 ppm, 210000 ppm, 220000 ppm, 230000 ppm, 240000 ppm, 250000 ppm, 260000 ppm, 270000 ppm, 280000 ppm, 290000 ppm, 300000 ppm, 310000 ppm, 320000 ppm, 330000 ppm, 340000 ppm, 350000 ppm, 360000 ppm, 370000 ppm, 380000 ppm, 390000 ppm, 400000 ppm, 410000 ppm, 420000 ppm, 430000 ppm, 440000 ppm, 450000 ppm, 460000 ppm, 470000 ppm, 480000 ppm, 490000 ppm, or 500 000 ppm in weight.

According to one embodiment, the light emitting material 7 comprises less than 95%, 90%, 80%, 70%, 60%, 50%, 40%, 30%, 20%, preferably 10% in weight of aggregates 1 of the invention.

The haze factor is calculated by the ratio between the intensity of light scattered by the material beyond the viewing angle and the total intensity transmitted by the material when illuminated with a light source.

According to one embodiment, the light emitting material 7 has a haze factor ranging from 1% to 100%.

According to one embodiment, the light emitting material 7 has a haze factor of at least 1%, 2%, 3%, 4%, 5%, 10%, 15%, 20%, 25%, 30%, 35%, 40%, 45%, 50%, 55%, 60%, 65%, 70%, 75%, 80%, 85%, 90%, 95%, or 100%.

According to one embodiment, the viewing angle used to measure the haze factor ranges from 0° to 20°.

According to one embodiment, the viewing angle used to measure the haze factor is at least 0°, 1°, 2°, 3°, 4°, 5°, 6°, 7°, 8°, 9°, 10°, 11°, 12°, 13°, 14°, 15°, 16°, 17°, 18°, 19°, or 20°.

According to one embodiment, the light emitting material 7 does not comprise optically transparent void regions.

According to one embodiment, the light emitting material 7 does not comprise void regions surrounding the at least one aggregate 1.

According to one embodiment, the light emitting material 7 is free of oxygen.

According to one embodiment, the light emitting material 7 is free of water.

In another embodiment, the light emitting material 7 may further comprise at least one solvent.

In another embodiment, the light emitting material 7 does not comprise a solvent.

In another embodiment, the light emitting material 7 may further comprise a liquid including but not limited to: 1-methoxy-2-propanol, 2-pyrrolidinone, C4 to C8 1,2-alkanediol, aliphatic or alicycle ketone, methyl ethyl ketone, C1-C4 alkanol such as for example methanol, ethanol, methanol propanol, or isopropanol, ketones, esters, ether of ethylene glycol or propylene glycol, acetals, acrylic resin, polyvinyl acetate, polyvinyl alcohol, polyamide resin, polyurethane resin, epoxy resin, alkyd ester, nitrated cellulose, ethyl cellulose, sodium carboxymethyl cellulose, alkyds, maleics, cellulose derivatives, formaldehyde, rubber resin, phenolics, propyl acetate, glycol ether, aliphatic hydrocarbon, acetate, ester. acrylic, cellulose ester, nitrocellulose, modified resin, alkoxylated alcohol, 2-pyrrolidone, a homolog of 2-pyrrolidone, glycol, water, or a mixture thereof.

According to one embodiment, the light emitting material 7 comprises a liquid at a level of at least 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, or 95% in weight compared to the total weight of the light emitting material 7.

According to one embodiment, the light emitting material 7 further comprises scattering particles dispersed in the host material 71. Examples of scattering particles include but are not limited to: SiO₂, ZrO₂, ZnO, MgO, SnO₂, TiO₂, Ag, Au, alumina, barium sulfate, PTFE, barium titanate and the like. Said scattering particles can help increasing light scattering in the interior of the light emitting material 7, so that there are more interactions between the photons and the scattering particles and, therefore, more light absorption by the particles.

According to one embodiment, the light emitting material 7 comprises scattering particles and does not comprise aggregates 1 in the at least one host material 71.

In one embodiment, the light emitting material 7 further comprises thermal conductor particles dispersed in the host material 71. Examples of thermal conductor particles include but are not limited to: SiO₂, ZrO₂, ZnO, MgO, SnO₂, TiO₂, CaO, alumina, barium sulfate, PTFE, barium titanate and the like. In this embodiment, the thermal conductivity of the host material 71 is increased.

According to one embodiment, the light emitting material 7 exhibits an emission spectrum with at least one emission peak, wherein said emission peak has a maximum emission wavelength ranging from 400 nm to 50 μm.

According to one embodiment, the light emitting material 7 exhibits an emission spectrum with at least one emission peak, wherein said emission peak has a maximum emission wavelength ranging from 400 nm to 500 nm. In this embodiment, the light emitting material 7 emits blue light.

According to one embodiment, the light emitting material 7 exhibits an emission spectrum with at least one emission peak, wherein said emission peak has a maximum emission wavelength ranging from 500 nm to 560 nm, more preferably ranging from 515 nm to 545 nm. In this embodiment, the light emitting material 7 emits green light.

According to one embodiment, the light emitting material 7 exhibits an emission spectrum with at least one emission peak, wherein said emission peak has a maximum emission wavelength ranging from 560 nm to 590 nm. In this embodiment, the light emitting material 7 emits yellow light.

According to one embodiment, the light emitting material 7 exhibits an emission spectrum with at least one emission peak, wherein said emission peak has a maximum emission wavelength ranging from 590 nm to 750 nm, more preferably ranging from 610 nm to 650 nm. In this embodiment, the light emitting material 7 emits red light.

According to one embodiment, the light emitting material 7 exhibits an emission spectrum with at least one emission peak, wherein said emission peak has a maximum emission wavelength ranging from 750 nm to 50 μm. In this embodiment, the light emitting material 7 emits near infra-red, mid-infra-red, or infra-red light.

According to one embodiment, the light emitting material 7 exhibits emission spectra with at least one emission peak having a full width half maximum lower than 90 nm, 80 nm, 70 nm, 60 nm, 50 nm, 40 nm, 30 nm, 25 nm, 20 nm, 15 nm, or 10 nm.

According to one embodiment, the light emitting material 7 exhibits emission spectra with at least one emission peak having a full width at quarter maximum lower than 90 nm, 80 nm, 70 nm, 60 nm, 50 nm, 40 nm, 30 nm, 25 nm, 20 nm, 15 nm, or 10 nm.

According to one embodiment, the light emitting material 7 has a photoluminescence quantum yield (PLQY) of at least 5%, 10%, 15%, 20%, 25%, 30%, 35%, 40%, 45%, 50%, 55%, 60%, 65%, 70%, 75%, 80%, 85%, 90%, 95%, 99% or 100%.

According to one embodiment, the light emitting material 7 absorbs at least 5%, 10%, 15%, 20%, 25%, 30%, 35%, 40%, 45%, 50%, 55%, 60%, 65%, 70%, 75%, 80%, 85%, 90%, 95%, or 100% of the incident light.

According to one embodiment, the light emitting material 7 absorbs the incident light with wavelength lower than 50 μm, 40 μm, 30 μm, 20 μm, 10 μm, 1 μm, 950 nm, 900 nm, 850 nm, 800 nm, 750 nm, 700 nm, 650 nm, 600 nm, 550 nm, 500 nm, 450 nm, 400 nm, 350 nm, 300 nm, 250 nm, or lower than 200 nm.

According to one embodiment, the light emitting material 7 transmits at least 5%, 10%, 15%, 20%, 25%, 30%, 35%, 40%, 45%, 50%, 55%, 60%, 65%, 70%, 75%, 80%, 85%, 90%, 95%, or 100% of the incident light.

According to one embodiment, the light emitting material 7 scatters at least 5%, 10%, 15%, 20%, 25%, 30%, 35%, 40%, 45%, 50%, 55%, 60%, 65%, 70%, 75%, 80%, 85%, 90%, 95%, or 100% of the incident light.

According to one embodiment, the light emitting material 7 backscatters at least 5%, 10%, 15%, 20%, 25%, 30%, 35%, 40%, 45%, 50%, 55%, 60%, 65%, 70%, 75%, 80%, 85%, 90%, 95%, or 100% of the incident light.

According to one embodiment, the light emitting material 7 transmits a part of the incident light and emits at least one secondary light. In this embodiment, the resulting light is a combination of the remaining transmitted incident light.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 300 nm, 350 nm, 400 nm, 450 nm, 455 nm, 460 nm, 470 nm, 480 nm, 490 nm, 500 nm, 510 nm, 520 nm, 530 nm, 540 nm, 550 nm, 560 nm, 570 nm, 580 nm, 590 nm, or 600 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 300 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 350 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 400 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 450 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 455 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 460 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 470 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 480 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 490 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 500 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 510 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 520 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 530 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 540 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 550 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 560 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 570 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 580 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 590 nm.

According to one embodiment, the light emitting material 7 has an absorbance value of at least 0.1, 0.2, 0.3, 0.4, 0.5, 0.6, 0.7, 0.8, 0.9, 1.0, 1.2, 1.4, 1.6, 1.8, 2.0, 2.5, 3.0, 4.0, 5.0 at 600 nm.

According to one embodiment, the increase in absorption efficiency of incident light by the light emitting material 7 is at least of 1%, 2%, 3%, 4%, 5%, 6%, 7%, 8%, 9%, 10%, 20%, 30%, 40%, 50%, 55%, 60%, 65%, 70%, 75%, 80%, 85%, 90%, 95%, or 100% compared to bare particles 12.

Bare particles 12 refers here to particles 12 that are not encapsulated in a material 11.

According to one embodiment, the increase in emission efficiency of secondary light by the light emitting material 7 is less than 1%, 2%, 3%, 4%, 5%, 6%, 7%, 8%, 9%, 10%, 20%, 30%, 40%, 50%, 55%, 60%, 65%, 70%, 75%, 80%, 85%, 90%, 95%, or 100% compared to bare particles 12.

In one embodiment, the light emitting material 7 exhibits photolumminescence quantum yield (PLQY) decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination.

According to one embodiment, the light illumination is provided by blue, green, red, or UV light source such as laser, diode, fluorescent lamp or Xenon Arc Lamp. According to one embodiment, the photon flux or average peak pulse power of the illumination is comprised between 1 mW·cm⁻² and 100 kW·cm⁻² and more preferably between 10 mW·cm⁻² and 100 W·cm⁻², and even more preferably between 10 mW·cm⁻² and 30 W·cm⁻².

According to one embodiment, the photon flux or average peak pulse power of the illumination is at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the light emitting material 7 exhibits photoluminescence quantum yield (PQLY) decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the light emitting material 7 exhibits FCE decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the light emitting material 7 exhibits FCE decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the light emitting material 7 exhibits photoluminescence quantum yield (PQLY) decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light with an average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one preferred embodiment, the light emitting material 7 exhibits photoluminescence quantum yield (PQLY) decrease of less than 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light or continuous light with an average peak pulse power or photon flux of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the light emitting material 7 exhibits FCE decrease of less than 80%, 70%, 60%, 50%, 40%, 30%, 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light with an average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one preferred embodiment, the light emitting material 7 exhibits FCE decrease of less than 25%, 20%, 15%, 10%, 5%, 4%, 3%, 2%, 1%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under pulsed light or continuous light with an average peak pulse power or photon flux of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

According to one embodiment, the light emitting material 7 exhibits a degradation of its photoluminescence of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

According to one embodiment, the light emitting material 7 exhibits a degradation of its photoluminescence of less than 90%, 80%, 70%, 60%, 50%, 40%, 30%, 25%, 20%, 15%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the light emitting material 7 exhibits a degradation of its photoluminescence of less than 90%, 80%, 70%, 60%, 50%, 40%, 30%, 25%, 20%, 15%, 10%, 5%, 4%, 3%, 2%, 1%, or 0% under 0%, 10%, 20%, 30%, 40%, 50%, 55%, 60%, 65%, 70%, 75%, 80%, 85%, 90%, 95%, or 99% of humidity.

According to one embodiment, the light emitting material 7 exhibits a degradation of its photoluminescence of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0%, 10%, 20%, 30%, 40%, 50%, 55%, 60%, 65%, 70%, 75%, 80%, 85%, 90%, 95%, or 99% of humidity.

According to one embodiment, the light emitting material 7 exhibits a degradation of its photoluminescence of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the light emitting material 7 exhibits a degradation of its photoluminescence of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the light emitting material 7 exhibits a degradation of its photoluminescence of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment.

According to one embodiment, the light emitting material 7 exhibits a degradation of its photoluminescence of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the light emitting material 7 exhibits a degradation of its photoluminescence of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, under 0%, 10%, 20%, 30%, 40%, 50%, 55%, 60%, 65%, 70%, 75%, 80%, 85%, 90%, 95%, or 99% of humidity.

According to one embodiment, the light emitting material 7 exhibits a degradation of its photoluminescence of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the light emitting material 7 exhibits a degradation of its photoluminescence quantum yield (PLQY) of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

According to one embodiment, the light emitting material 7 exhibits a degradation of its photoluminescence quantum yield (PLQY) of less than 90%, 80%, 70%, 60%, 50%, 40%, 30%, 25%, 20%, 15%, 10%, 5%, 4%, 3%, 2%, 1%, or 0% at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the light emitting material 7 exhibits a degradation of its photoluminescence quantum yield (PLQY) of less than 90%, 80%, 70%, 60%, 50%, 40%, 30%, 25%, 20%, 15%, 10%, 5%, 4%, 3%, 2%, 1%, or 0% under 0%, 10%, 20%, 30%, 40%, 50%, 55%, 60%, 65%, 70%, 75%, 80%, 85%, 90%, 95%, or 99% of humidity.

According to one embodiment, the light emitting material 7 exhibits a degradation of its photoluminescence quantum yield (PLQY) of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0%, 10%, 20%, 30%, 40%, 50%, 55%, 60%, 65%, 70%, 75%, 80%, 85%, 90%, 95%, or 99% of humidity.

According to one embodiment, the light emitting material 7 exhibits a degradation of its photoluminescence quantum yield (PLQY) of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the light emitting material 7 exhibits a degradation of its photoluminescence quantum yield (PLQY) of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the light emitting material 7 exhibits a degradation of its photoluminescence quantum yield (PLQY) of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment.

According to one embodiment, the light emitting material 7 exhibits a degradation of its photoluminescence quantum yield (PLQY) of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the light emitting material 7 exhibits a degradation of its photoluminescence quantum yield (PLQY) of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, under 0%, 10%, 20%, 30%, 40%, 50%, 55%, 60%, 65%, 70%, 75%, 80%, 85%, 90%, 95%, or 99% of humidity.

According to one embodiment, the light emitting material 7 exhibits a degradation of its photoluminescence quantum yield (PLQY) of less than 90%, 80%, 70%, 60%, 50%, 40%, 30%, 25%, 20%, 15%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular oxygen with respect to its local environment, at 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the light emitting material 7 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years.

According to one embodiment, the light emitting material 7 exhibits a degradation of its FCE of less than 90%, 80%, 70%, 60%, 50%, 40%, 30%, 25%, 20%, 10%, 5%, 4%, 3%, 2%, 1%, or 0% under 0° C., 10° C., 20° C., 30° C., 40° C., 50° C., 60° C., 70° C., 80° C., 90° C. 100° C., 125° C., 150° C., 175° C., 200° C., 225° C., 250° C., 275° C., or 300° C.

According to one embodiment, the light emitting material 7 exhibits a degradation of its FCE of less than 90%, 80%, 70%, 60%, 50%, 40%, 30%, 25%, 20%, 10%, 5%, 4%, 3%, 2%, 1%, or 0% under 0%, 10%, 20%, 30%, 40%, 50%, 55%, 60%, 65%, 70%, 75%, 80%, 85%, 90%, 95%, or 99% of humidity.

According to one embodiment, the light emitting material 7 exhibits a degradation of its FCE of less than 90%, 80%, 70%, 60%, 50%, 40%, 30%, 25%, 20%, 10%, 5%, 4%, 3%, 2%, 1%, or 0% under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the light emitting material 7 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0%, 10%, 20%, 30%, 40%, 50%, 55%, 60%, 65%, 70%, 75%, 80%, 85%, 90%, 95%, or 99% of humidity.

According to one embodiment, the light emitting material 7 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the light emitting material 7 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years, under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the light emitting material 7 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular O₂.

According to one embodiment, the light emitting material 7 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular 02, under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

According to one embodiment, the light emitting material 7 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular 02, under 0%, 10%, 20%, 30%, 40%, 50%, 55%, 60%, 65%, 70%, 75%, 80%, 85%, 90%, 95%, or 99% of humidity.

According to one embodiment, the light emitting material 7 exhibits a degradation of its FCE of less than 90%, 80%, 70%, 60%, 50%, 40%, 30%, 25%, 20%, 10%, 5%, 4%, 3%, 2%, 1%, or 0% after at least 1 day, 5 days, 10 days, 15 days, 20 days, 25 days, 1 month, 2 months, 3 months, 4 months, 5 months, 6 months, 7 months, 8 months, 9 months, 10 months, 11 months, 12 months, 18 months, 2 years, 2.5 years, 3 years, 3.5 years, 4 years, 4.5 years, 5 years, 5.5 years, 6 years, 6.5 years, 7 years, 7.5 years, 8 years, 8.5 years, 9 years, 9.5 years, or 10 years under 0%, 5%, 10%, 15%, 20%, 25%, 30%, 35%, 40%, 45%, 50%, 55%, 60%, 65%, 70%, 75%, 80%, 85%, 90%, 95%, or 100% of molecular O₂, under 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under 0%, 10%, 20%, 30%, 40%, 50%, 55%, 60%, 65%, 70%, 75%, 80%, 85%, 90%, 95%, or 99% of humidity.

According to one embodiment, the light emitting material 7 is ROHS compliant.

According to one embodiment, the light emitting material 7 comprises less than 10 ppm, less than 20 ppm, less than 30 ppm, less than 40 ppm, less than 50 ppm, less than 100 ppm, less than 150 ppm, less than 200 ppm, less than 250 ppm, less than 300 ppm, less than 350 ppm, less than 400 ppm, less than 450 ppm, less than 500 ppm, less than 550 ppm, less than 600 ppm, less than 650 ppm, less than 700 ppm, less than 750 ppm, less than 800 ppm, less than 850 ppm, less than 900 ppm, less than 950 ppm, less than 1000 ppm in weight of cadmium.

According to one embodiment, the light emitting material 7 comprises less than 10 ppm, less than 20 ppm, less than 30 ppm, less than 40 ppm, less than 50 ppm, less than 100 ppm, less than 150 ppm, less than 200 ppm, less than 250 ppm, less than 300 ppm, less than 350 ppm, less than 400 ppm, less than 450 ppm, less than 500 ppm, less than 550 ppm, less than 600 ppm, less than 650 ppm, less than 700 ppm, less than 750 ppm, less than 800 ppm, less than 850 ppm, less than 900 ppm, less than 950 ppm, less than 1000 ppm, less than 2000 ppm, less than 3000 ppm, less than 4000 ppm, less than 5000 ppm, less than 6000 ppm, less than 7000 ppm, less than 8000 ppm, less than 9000 ppm, less than 10000 ppm in weight of lead.

According to one embodiment, the light emitting material 7 comprises less than 10 ppm, less than 20 ppm, less than 30 ppm, less than 40 ppm, less than 50 ppm, less than 100 ppm, less than 150 ppm, less than 200 ppm, less than 250 ppm, less than 300 ppm, less than 350 ppm, less than 400 ppm, less than 450 ppm, less than 500 ppm, less than 550 ppm, less than 600 ppm, less than 650 ppm, less than 700 ppm, less than 750 ppm, less than 800 ppm, less than 850 ppm, less than 900 ppm, less than 950 ppm, less than 1000 ppm, less than 2000 ppm, less than 3000 ppm, less than 4000 ppm, less than 5000 ppm, less than 6000 ppm, less than 7000 ppm, less than 8000 ppm, less than 9000 ppm, less than 10000 ppm in weight of mercury.

According to one embodiment, the light emitting material 7 comprise heavier chemical elements or materials based on heavier chemical elements than the main chemical element present in the host material 71 and/or the material 11. In this embodiment, said heavy chemical elements in the light emitting material 7 will lower the mass concentration of chemical elements subject to ROHS standards, allowing said light emitting material 7 to be ROHS compliant.

According to one embodiment, examples of heavy elements include but are not limited to B, C, N, F, Na, Mg, Al, Si, P, S, Cl, K, Ca, Sc, Ti, V, Cr, Mn, Fe, Co, Ni, Cu, Zn, Ga, Ge, As, Se, Br, Rb, Sr, Y, Zr, Nb, Mo, Tc, Ru, Rh, Pd, Ag, Cd, In, Sn, Sb, Te, I, Cs, Ba, La, Hf, Ta, W, Re, Os, Ir, Pt, Au, Hg, Tl, Pb, Bi, Po, At, Ce, Pr, Nd, Pm, Sm, Eu, Gd, Tb, Dy, Ho, Er, Tm, Yb, Lu or a mixture of thereof.

According to one embodiment, the light emitting material 7 comprises one or more materials useful in forming at least one of a hole transport layer, a hole injection layer, an electron transport layer, an electron injection layer, and an emissive layer, of a light-emitting device.

According to one embodiment, the light emitting material 7 comprises a material that is cured or otherwise processed to form a layer on a support.

According to one embodiment, the light emitting material 7 comprises a binder that is an organic material as described herein, an inorganic material as described herein, or a mixture thereof.

According to one embodiment, examples of binders include but are not limited to: a crosslinked body of an inorganic material as described herein such as, for example, a silicic acid such as sodium silicate, potassium silicate, or silicate soda.

According to one embodiment, the binder is a liquid in which SiO₂ (anhydrous silicate) and Na₂O (soda oxide) or K₂O (potassium oxide) are mixed with a predetermined ratio. In this embodiment, the molecular formula is represented by Na₂O.nSiO₂.

According to one embodiment, the binder comprised in the light emitting material 7 has a difference of linear expansion coefficient with the support on which is deposited said light emitting material 7. In this embodiment, the difference of linear expansion coefficient between the binder and the support is less than 8 ppm/K. This embodiment is particularly advantageous as it prevents peeling between the support and the light emitting material 7. This is because that the stress inside the light emitting material 7, accompanied by heat generation, is sufficiently eased even though the light emitting material 7 generates heat by irradiation with the excitation light.

According to a preferred embodiment, examples of light emitting material 7 include but are not limited to: aggregate 1 dispersed in sol gel materials, silicone, polymers such as for example PMMA, PS, or a mixture thereof.

According to one embodiment, the light emitting material 7 is an ink.

According to one embodiment, the light emitting material 7 further comprises a variety of components such as those typically used in inkjet liquid vehicles, such as, but not limited to solvents, cosolvents, surface tension adjusting agents, spreading modifier, charge-transporting agents, surfactants, biocides, buffers, viscosity modifiers, sequestering agents, crosslinking photoinitiator, crosslinking agent, colorants, pigments, stabilizing agents, humectants, scatterers, fillers, extenders, water, and mixtures thereof.

According to one embodiment, examples of the surfactant include but are not limited to: carboxylic acids such as for example oleic acid, acetic acid, octanoic acid; thiols such as octanethiol, hexanethiol, butanethiol; 4-mercaptobenzoic acid; Triton X100, amines such as for example oleylamine, 1,6-hexanediamine, octylamine; phosphonic acids; antibodies; or a mixture thereof.

According to one embodiment, the spreading modifier comprises an alkoxylated aliphatic diacrylate monomer, an alkoxylated aliphatic dimethacrylate monomer, or a mixture thereof.

According to one embodiment, the spreading modifier has a viscosity in the range from about 10 to about 25 centipoise at 25° C. and a surface tension in the range from about 25 to about 45 dynes/cm at 25° C.

According to one embodiment, the light emitting material 7 comprises from 10 wt % to 80 wt % of a spreading modifier.

According to one embodiment, the light emitting material 7 comprises 4-10 wt % of pentaerythritol tetraacrylate, pentaerythritol tetramethacrylate, or a combination thereof.

According to one embodiment, the light emitting material 7 comprises polyethylene glycol.

According to one embodiment, the light emitting material 7 comprises dimethacrylate monomer, monoacrylate monomer, polyethylene glycol diacrylate monomer, diacrylate monomer, or a mixture thereof.

According to one embodiment, the monomer has a number average molecular weight in the range from about 100 g/mol to about 1000 g/mol; from about 150 g/mol to about 800 g/mol; from about 200 g/mol to about 600 g/mol; from about 200 g/mol to about 500 g/mol; from about 250 g/mol to about 450 g/mol.

According to one embodiment, the light emitting material 7 comprises a multifunctional methacrylate crosslinking agent, multifunctional acrylate crosslinking agent, or a mixture thereof.

According to one embodiment, the light emitting material 7 comprises 0.5 wt % to 20 wt % of a multifunctional methacrylate crosslinking agent, multifunctional acrylate crosslinking agent.

According to one embodiment, the light emitting material 7 comprises a crosslinking photoinitiator.

According to one embodiment, the light emitting material 7 comprises 0.05 wt % to 20 wt % of crosslinking photoinitiator.

According to one embodiment, the light emitting material 7 comprises at least one pigment.

According to one embodiment, the pigment has an average size ranging from 10 nm to 1 μm.

According to one embodiment, the light emitting material 7 comprises at least 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 15%, 20%, 25%, 30%, 35%, 40%, 45%, or 50% of a pigment.

According to one embodiment, the pigment substantially insoluble in the host material 71.

According to one embodiment, the pigment substantially soluble in the host material 71.

According to one embodiment, the light emitting material 7 has a viscosity and a surface tension at inkjet jetting temperatures that enable reliable delivery from an inkjet printhead while leaving little or no residue on the printhead.

According to one embodiment, the light emitting material 7 has a density of at least 0.90, 0.95, 1.00, 1.05, 1.10, 1.15, 1.20, 1.25, 1.30, 1.35, 1.40, 1.45, 1.50, 1.55, 1.60, 1.65, 1.70, 1.75, 1.80, 1.85, 1.90 1.95, or 2.00 g/cm³.

According to one embodiment, the density of the light emitting material 7 is tuned to obtaine a homogeneous layer and a desired thickness when the light emitting material 7 is deposited on a support.

According to one embodiment, the light emitting material 7 exhibits a viscosity of at least 0.5 mPa·s, 1.0 mPa·s, 2.0 mPa·s, 3.0 mPa·s, 4.0 mPa·s, 5.0 mPa·s, 6.0 mPa·s, 7.0 mPa·s, 8.0 mPa·s, 9.0 mPa·s, 10.0 mPa·s, 11.0 mPa·s, 12.0 mPa·s, 13.0 mPa·s, 14.0 mPa·s, 15.0 mPa·s, 16.0 mPa·s, 17.0 mPa·s, 18.0 mPa·s, 19.0 mPa·s, 20.0 mPa·s, 21.0 mPa·s, 22.0 mPa·s, 23.0 mPa·s, 24.0 mPa·s, 25.0 mPa·s, 26.0 mPa·s, 27.0 mPa·s, 28.0 mPa·s, 29.0 mPa·s, or 30.0 mPa·s, at 25° C.

According to one embodiment, the light emitting material 7 exhibits a viscosity of at least 0.5 mPa·s, 1.0 mPa·s, 2.0 mPa·s, 3.0 mPa·s, 4.0 mPa·s, 5.0 mPa·s, 6.0 mPa·s, 7.0 mPa·s, 8.0 mPa·s, 9.0 mPa·s, 10.0 mPa·s, 11.0 mPa·s, 12.0 mPa·s, 13.0 mPa·s, 14.0 mPa·s, 15.0 mPa·s, 16.0 mPa·s, 17.0 mPa·s, 18.0 mPa·s, 19.0 mPa·s, 20.0 mPa·s, 21.0 mPa·s, 22.0 mPa·s, 23.0 mPa·s, 24.0 mPa·s, 25.0 mPa·s, 26.0 mPa·s, 27.0 mPa·s, 28.0 mPa·s, 29.0 mPa·s, or 30.0 mPa·s.

According to one embodiment, the light emitting material 7 exhibits a viscosity of at least 0.5 centipoise, 1.0 centipoise, 2.0 centipoise, 3.0 centipoise, 4.0 centipoise, 5.0 centipoise, 6.0 centipoise, 7.0 centipoise, 8.0 centipoise, 9.0 centipoise, 10.0 centipoise, 11.0 centipoise, 12.0 centipoise, 13.0 centipoise, 14.0 centipoise, 15.0 centipoise, 16.0 centipoise, 17.0 centipoise, 18.0 centipoise, 19.0 centipoise, 20.0 centipoise, 21.0 centipoise, 22.0 centipoise, 23.0 centipoise, 24.0 centipoise, 25.0 centipoise, 26.0 centipoise, 27.0 centipoise, 28.0 centipoise, 29.0 centipoise, or 30.0 centipoise, at 25° C.

According to one embodiment, the light emitting material 7 exhibits a viscosity of at least 0.5 centipoise, 1.0 centipoise, 2.0 centipoise, 3.0 centipoise, 4.0 centipoise, 5.0 centipoise, 6.0 centipoise, 7.0 centipoise, 8.0 centipoise, 9.0 centipoise, 10.0 centipoise, 11.0 centipoise, 12.0 centipoise, 13.0 centipoise, 14.0 centipoise, 15.0 centipoise, 16.0 centipoise, 17.0 centipoise, 18.0 centipoise, 19.0 centipoise, 20.0 centipoise, 21.0 centipoise, 22.0 centipoise, 23.0 centipoise, 24.0 centipoise, 25.0 centipoise, 26.0 centipoise, 27.0 centipoise, 28.0 centipoise, 29.0 centipoise, or 30.0 centipoise.

According to one embodiment, the light emitting material 7 exhibits a Reynolds number of at least 1, 2, 3, 4, 5, 6, 7, 8, 9, 10, 11, 12, 13, 14, 15, 16, 17, 18, 19, 20, 30, 40, 50, 60, 70, 80, 90, 100, 110, 120, 130, 140, 150, 160, 170, 180, 190, 200, 300, 400, 500, 600, 700, 800, 900, or 1000.

According to one embodiment, the light emitting material 7 flow exhibits a Reynolds number of at least 1, 2, 3, 4, 5, 6, 7, 8, 9, 10, 11, 12, 13, 14, 15, 16, 17, 18, 19, 20, 30, 40, 50, 60, 70, 80, 90, 100, 110, 120, 130, 140, 150, 160, 170, 180, 190, 200, 300, 400, 500, 600, 700, 800, 900, or 1000.

According to one embodiment, the light emitting material 7 exhibits an Ohnesorge number of at least 0.01, 0.02, 0.03, 0.04, 0.05, 0.06, 0.07, 0.08, 0.09, 0.1, 0.15, 0.2, 0.25, 0.3, 0.35, 0.4, 0.45, 0.5, 0.55, 0.6, 0.65, 0.7, 0.75, 0.8, 0.85, 0.9, 0.95, 1, 2, 3, 4, 5, 6, 7, 8, 9, 10.

According to one embodiment, the light emitting material 7 drops exhibit an Ohnesorge number of at least 0.01, 0.02, 0.03, 0.04, 0.05, 0.06, 0.07, 0.08, 0.09, 0.1, 0.15, 0.2, 0.25, 0.3, 0.35, 0.4, 0.45, 0.5, 0.55, 0.6, 0.65, 0.7, 0.75, 0.8, 0.85, 0.9, 0.95, 1, 2, 3, 4, 5, 6, 7, 8, 9, 10.

According to one embodiment, the viscosity of the light emitting material 7 is tuned to obtaine a homogeneous layer and a desired thickness when the light emitting material 7 is deposited on a support.

According to one embodiment, the light emitting material 7 has a viscosity and a surface tension at inkjet jetting temperatures, for example, at 25° C., that enable delivery from an inkjet printhead.

According to one embodiment, the host material 71 can exhibit properties that provide a substantially uniformly thick film of the light emitting material 7.

According to one embodiment, the light emitting material 7 exhibits a surface tension of at least 20 dynes/cm, 25 dynes/cm, 30 dynes/cm, 35 dynes/cm, 40 dynes/cm, 45 dynes/cm, 50 dynes/cm, 55 dynes/cm, or 60 dynes/cm, at 25° C.

According to one embodiment, the host material 71 is miscible with water.

According to one embodiment, the host material 71 is miscible with at least one organic solvent.

According to one embodiment, the host material 71 comprises water.

According to one embodiment, the host material 71 comprises at least one surfactant.

According to one embodiment, the light emitting material 7 comprises at least 1 wt %, 2 wt %, 3 wt %, 4 wt %, 5 wt %, 6 wt %, 7 wt %, 8 wt %, 9 wt %, 10 wt %, 15 wt %, 20 wt %, 25 wt %, 30 wt %, 35 wt %, 40 wt %, 45 wt %, 50 wt %, 55 wt %, 60 wt %, 65 wt %, 70 wt %, 75 wt %, 80 wt %, 85 wt %, 90 wt %, 95 wt %, or 99 wt % of solvent as described hereabove.

According to one embodiment, the light emitting material 7 comprises at least 1 wt %, 2 wt %, 3 wt %, 4 wt %, 5 wt %, 6 wt %, 7 wt %, 8 wt %, 9 wt %, 10 wt %, 15 wt %, 20 wt %, 25 wt %, 30 wt %, 35 wt %, 40 wt %, 45 wt %, 50 wt %, 55 wt %, 60 wt %, 65 wt %, 70 wt %, 75 wt %, 80 wt %, 85 wt %, 90 wt %, 95 wt %, or 99 wt % of host material 71 as described hereabove.

According to one embodiment, the light emitting material 7 comprises at least 0.01 wt %, 0.02 wt %, 0.03 wt %, 0.04 wt %, 0.05 wt %, 0.06 wt %, 0.07 wt %, 0.08 wt %, 0.09 wt %, 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, 5 wt %, 6 wt %, 7 wt %, 8 wt %, 9 wt %, 10 wt %, 15 wt %, 20 wt %, 25 wt %, 30 wt %, 35 wt %, 40 wt %, 45 wt %, 50 wt %, 55 wt %, 60 wt %, 65 wt %, 70 wt %, 75 wt %, 80 wt %, 85 wt %, 90 wt %, 95 wt %, or 99 wt % of aggregate 1.

According to one embodiment, in the light emitting material 7, the weight ratio between the host material 71 and the aggregate 1 is at least 0.01%, 0.02%, 0.03%, 0.04%, 0.05%, 0.06%, 0.07%, 0.08%, 0.09%, 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, or 50%.

According to one embodiment, the light emitting material 7 comprises aggregates 1, polyethylene glycol dimethacrylate monomer, monoacrylate monomer, a multifunctional methacrylate crosslinking agent and a crosslinking photoinitiator.

According to one embodiment, the light emitting material 7 comprises aggregates 1, water and 1,2-hexanediol.

According to one embodiment, the light emitting material 7 comprises aggregates 1, polyethylene glycol diacrylate monomer, multifunctional acrylate crosslinking agent, spreading modifier comprising an alkoxylated aliphatic diacrylate monomer.

According to one embodiment, the light emitting material 7 comprises a host material 71 consisting essentially of up to 16 wt % of 1,2-hexanediol or 1,5-pentanediol; a balance of water;

and from about 0.01 wt % to about 10 wt % of aggregates 1.

According to one embodiment, the light emitting material 7 comprises aggregates 1, a mixed solvent of chlorobenzene and cyclohexane, Triton X-100 as an additive.

According to one embodiment, the light emitting material 7 comprises aggregates 1, Ebecyl, TiO₂.

According to one embodiment, the light emitting material 7 comprises aggregates 1; 40 wt % to 60 wt % polyethylene glycol dimethacrylate monomer, polyethylene glycol diacrylate monomer, or a combination thereof, wherein the polyethylene glycol dimethacrylate monomer and the polyethylene glycol diacrylate monomer have number average molecular weights in the range from about 230 g/mol to about 430 g/mol; 25 wt % to 50 wt % monoacrylate monomer, monomethacrylate monomer, or a combination thereof, having a viscosity in the range from about 10 cps to about 27 cps at 22° C.; 4 wt % to 10 wt % multifunctional acrylate crosslinking agent, a multifunctional methacrylate crosslinking agent, or a combination thereof; and 0.1 wt % to 10 wt % cros slinking photoinitiator.

According to one embodiment, the light emitting material 7 comprises aggregates 1; 40 wt % to 60 wt % polyethylene glycol dimethacrylate monomer, polyethylene glycol diacrylate monomer, or a combination thereof, wherein the polyethylene glycol dimethacrylate monomer and the polyethylene glycol diacrylate monomer have number average molecular weights in the range from about 230 g/mol to about 430 g/mol; 25 wt % to 50 wt % monoacrylate monomer, monomethacrylate monomer, or a combination thereof, having a viscosity in the range from about 10 cps to about 27 cps at 22° C.; 4 wt % to 10 wt % multifunctional acrylate crosslinking agent, a multifunctional methacrylate crosslinking agent, or a combination thereof; and 0.1 wt % to 10 wt % crosslinking photoinitiator, the light emitting material 7 composition having a surface tension of between about 32 dynes/cm and about 45 dynes/cm at 22° C.

According to one embodiment, the light emitting material 7 comprises aggregates 1; from 30 wt % to 50 wt % of a polyethylene glycol dimethacrylate monomer, a polyethylene glycol diacrylate monomer, or a combination thereof, wherein the polyethylene glycol dimethacrylate monomer and the polyethylene glycol diacrylate monomer have number average molecular weights in the range from 230 g/mol to 430 g/mol; from 4 wt % to 10 wt % of a multifunctional acrylate crosslinking agent, a multifunctional methacrylate crosslinking agent, or a combination thereof; and from 40 wt % to 60 wt % of a spreading modifier comprising an alkoxylated aliphatic diacrylate monomer, an alkoxylated aliphatic dimethacrylate monomer, or a combination thereof, and having a viscosity in the range from 14 cps to 18 cps at 22° C. and a surface tension in the range from 35 dynes/cm to 39 dynes/cm at 22° C.

According to one embodiment, from 30 wt % to 50 wt % of the light emitting material 7 comprises a monomer selected from the group consisting of a polyethylene glycol dimethacrylate monomer, a polyethylene glycol diacrylate monomer, and a combination thereof, wherein the polyethylene glycol dimethacrylate monomer and the polyethylene glycol diacrylate monomer have number average molecular weights in the range from 230 g/mol to 430 g/mol; from 4 wt % to 10 wt % of the light emitting material 7 comprises a crosslinking agent selected from the group consisting of a multifunctional acrylate crosslinking agent, a multifunctional methacrylate crosslinking agent, and a combination thereof; and from 40 wt % to 60 wt % of the light emitting material 7 comprises a spreading modifier selected from the group consisting of an alkoxylated aliphatic diacrylate monomer, an alkoxylated aliphatic dimethacrylate monomer, and a combination thereof.

According to one embodiment, from 30 wt % to 50 wt % of the light emitting material 7 comprises a monomer selected from the group consisting of a polyethylene glycol dimethacrylate monomer, a polyethylene glycol diacrylate monomer, and a combination thereof, wherein the polyethylene glycol dimethacrylate monomer and the polyethylene glycol diacrylate monomer have number average molecular weights in the range from 230 g/mol to 430 g/mol; from 4 wt % to 10 wt % of the light emitting material 7 comprises a crosslinking agent selected from the group consisting of a multifunctional acrylate crosslinking agent, a multifunctional methacrylate crosslinking agent, and a combination thereof; and from 40 wt % to 60 wt % of the light emitting material 7 comprises a spreading modifier selected from the group consisting of an alkoxylated aliphatic diacrylate monomer, an alkoxylated aliphatic dimethacrylate monomer, and a combination thereof, the light emitting material 7 having a viscosity in the range from 14 cps to 18 cps at 22° C. and a surface tension in the range from 35 dynes/cm to 39 dynes/cm at 22° C.

According to one embodiment, the light emitting material 7 comprises aggregates 1; 75-95 wt % of a polyethylene glycol dimethacrylate monomer, a polyethylene glycol diacrylate monomer, or a combination thereof, wherein the polyethylene glycol dimethacrylate monomer and the polyethylene glycol diacrylate monomer have number average molecular weights in the range from about 230 g/mol to about 430 g/mol; 4-10 wt % of pentaerythritol tetraacrylate, pentaerythritol tetramethacrylate, or a combination thereof; and 1-15 wt % of a spreading modifier having a viscosity in the range from about 14 to about 18 cps at 22° C. and a surface tension in the range from about 35 to about 39 dynes/cm at 22° C.

According to one embodiment, the light emitting material 7 comprises materials configured to limit or prevent the coffee-ring effect.

According to one embodiment, the light emitting material 7 is formulated to leave little or no residue in the pores of a thermal printing printhead that comprises pores. In this embodiment at least 50000 cycles of printing can be performed without clogging the pores of said printhead. Microscopic examination, for example, at 20× magnification, can be used to visually inspect for residue and/or residue build-up on the printhead.

According to one embodiment, the light emitting material 7 is deposited on a support by drop-casting, spin coating, dip coating, inkjet printing, lithography, spray, plating, electroplating, or any other means known by the person skilled in the art.

According to one embodiment, the light emitting material 7 is deposited on a support by inkjet printing: thermal, piezoelectric or other inkjet printing methods.

According to one embodiment, the light emitting material 7 can be cured into a shape of a film, thereby generating a film.

In one embodiment, the light emitting material 7 is splitted in several areas, each of them comprises a different population of aggregates 1 emitting different colors or wavelengths.

In one embodiment, the light emitting material 7 has a shape of a film.

In one embodiment, the light emitting material 7 is a film.

In one embodiment, the light emitting material 7 is processed by extrusion.

In one embodiment, the light emitting material 7 is an optical pattern. In this embodiment, said pattern may be formed on a support as described herein.

In one embodiment, the light emitting material 7 is a light collection pattern. In this embodiment, said pattern may be formed on a support as described herein.

In one embodiment, the light emitting material 7 is a light diffusion pattern. In this embodiment, said pattern may be formed on a support as described herein.

In one embodiment, the support as described herein can be heated or cooled down by an external system.

In one embodiment, the light emitting material 7 is made of a stack of two films, each of them comprises a different population of aggregates 1 emitting different colors or wavelengths.

In one embodiment, the light emitting material 7 is made of a stack of a plurality of films, each of them comprises a different population of aggregates 1 emitting different colors or wavelengths.

According to one embodiment, the light emitting material 7 has a thickness between 30 nm and 10 cm, more preferably between 100 nm and 1 cm, even more preferably between 100 nm and 1 mm

According to one embodiment, the light emitting material 7 has a thickness less than 200 μm. This embodiment is particularly advantageous as that the light conversion efficiency is greatly improved when the surface roughness value is approximately 10 nm. For example, in this embodiment, the light conversion efficiency can be 80% or more.

According to one embodiment, the light emitting material 7 has a thickness ranging from 30 μm to 120 μm. This embodiment is particularly advantageous the light conversion efficiency is improved when the surface roughness value is in a range from 10 nm to 300 nm. For example, in this embodiment, the light conversion efficiency can be 80% or more.

According to one embodiment, the light emitting material 7 has a thickness of at least 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.1 μm, 4.2 μm, 4.3 μm, 4.4 μm, 4.5 μm, 4.6 μm, 4.7 μm, 4.8 μm, 4.9 μm, 5 μm, 5.1 μm, 5.2 μm, 5.3 μm, 5.4 μm, 5.5 μm, 5.5 μm, 5.6 μm, 5.7 μm, 5.8 μm, 5.9 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, 1 mm, 1.1 mm, 1.2 mm, 1 3 mm, 1.4 mm, 1.5 mm, 1 6 mm, 1.7 mm, 1 8 mm, 1.9 mm, 2 mm, 2.1 mm, 2.2 mm, 2.3 mm, 2.4 mm, 2 5 mm, 2 6 mm, 2.7 mm, 2.8 mm, 2 9 mm, 3 mm, 3 1 mm, 3.2 mm, 3.3 mm, 3.4 mm, 3.5 mm, 3.6 mm, 3.7 mm, 38 mm, 39 mm, 4 mm, 4 1 mm, 4 2 mm, 4.3 mm, 4.4 mm, 4.5 mm, 4.6 mm, 4.7 mm, 4.8 mm, 4 9 mm, 5 mm, 5 1 mm, 5.2 mm, 5.3 mm, 5.4 mm, 5.5 mm, 5.6 mm, 5 7 mm, 5 8 mm, 5 9 mm, 6 mm, 6.1 mm, 6.2 mm, 6 3 mm, 6 4 mm, 6.5 mm, 6.6 mm, 6.7 mm, 6 8 mm, 6 9 mm, 7 mm, 7.1 mm, 7.2 mm, 7.3 mm, 7 4 mm, 7 5 mm, 7.6 mm, 7.7 mm, 7.8 mm, 7 9 mm, 8 mm, 8.1 mm, 8 2 mm, 8 3 mm, 8 4 mm, 8.5 mm, 8.6 mm, 8.7 mm, 8.8 mm, 8.9 mm, 9 mm, 9.1 mm, 9.2 mm, 9 3 mm, 9 4 mm, 9 5 mm, 9.6 mm, 9.7 mm, 9.8 mm, 9.9 mm, 1 cm, 1.1 cm, 1.2 cm, 1.3 cm, 1.4 cm, 1.5 cm, 1.6 cm, 1.7 cm, 1.8 cm, 1.9 cm, 2 cm, 2.1 cm, 2.2 cm, 2.3 cm, 2.4 cm, 2.5 cm, 2.6 cm, 2.7 cm, 2.8 cm, 2.9 cm, 3 cm, 3.1 cm, 3.2 cm, 3.3 cm, 3.4 cm, 3.5 cm, 3.6 cm, 3.7 cm, 3.8 cm, 3.9 cm, 4 cm, 4.1 cm, 4.2 cm, 4.3 cm, 4.4 cm, 4.5 cm, 4.6 cm, 4.7 cm, 4.8 cm, 4.9 cm, 5 cm, 5.1 cm, 5.2 cm, 5.3 cm, 5.4 cm, 5.5 cm, 5.6 cm, 5.7 cm, 5.8 cm, 5.9 cm, 6 cm, 6.1 cm, 6.2 cm, 6.3 cm, 6.4 cm, 6.5 cm, 6.6 cm, 6.7 cm, 6.8 cm, 6.9 cm, 7 cm, 7.1 cm, 7.2 cm, 7.3 cm, 7.4 cm, 7.5 cm, 7.6 cm, 7.7 cm, 7.8 cm, 7.9 cm, 8 cm, 8.1 cm, 8.2 cm, 8.3 cm, 8.4 cm, 8.5 cm, 8.6 cm, 8.7 cm, 8.8 cm, 8.9 cm, 9 cm, 9.1 cm, 9.2 cm, 9.3 cm, 9.4 cm, 9.5 cm, 9.6 cm, 9.7 cm, 9.8 cm, 9.9 cm, or 10 cm.

According to one embodiment illustrated in FIG. 20C-D, the light emitting material 7 comprises at least two host materials (71, 72). In this embodiment, the host materials may be different or identical.

According to one embodiment, the light emitting material 7 comprises a plurality of host materials 71. In this embodiment, the host materials can be identical or different from each other.

According to one embodiment, the host material 71 is free of oxygen.

According to one embodiment, the host material 71 is free of water.

According to one embodiment, the host material 71 limits or prevents the degradation of the chemical and physical properties of the at least one aggregate 1 from molecular oxygen, ozone, water and/or high temperature.

According to one embodiment, the host material 71 is optically transparent at wavelengths between 200 nm and 50 um, between 200 nm and 10 um, between 200 nm and 2500 nm, between 200 nm and 2000 nm, between 200 nm and 1500 nm, between 200 nm and 1000 nm, between 200 nm and 800 nm, between 400 nm and 700 nm, between 400 nm and 600 nm, or between 400 nm and 470 nm.

According to one embodiment, the host material 71 has a refractive index ranging from 1.0 to 3.0, from 1.2 to 2.6, from 1.4 to 2.0 at 450 nm.

According to one embodiment, the host material 71 has a refractive index of at least 1.0, 1.1, 1.2, 1.3, 1.4, 1.5, 1.6, 1.7, 1.8, 1.9, 2.0, 2.1, 2.2, 2.3, 2.4, 2.5, 2.6, 2.7, 2.8, 2.9, or 3.0 at 450 nm.

According to one embodiment, the host material 71 has a refractive index distinct from the refractive index of the material 11 or from the refractive index of the aggregate 1. This embodiment allows for a wider scattering of light. This embodiment also allows to have a difference in light scattering as a function of the wavelength, in particular to increase the scattering of the excitation light with respect to the scattering of the emitted light, as the wavelength of the excitation light is lower than the wavelength of the emitted light.

According to one embodiment, the host material 71 has a difference of refractive index with the refractive index of the material 11 or with the refractive index of the aggregate 1 of at least 0.02, 0.025, 0.03, 0.035, 0.04, 0.045, 0.05, 0.055, 0.06, 0.065, 0.07, 0.075, 0.08, 0.085, 0.09, 0.095, 0.1, 0.11, 0.115, 0.12, 0.125, 0.13, 0.135, 0.14, 0.145, 0.15, 0.155, 0.16, 0.165, 0.17, 0.175, 0.18, 0.185, 0.19, 0.195, 0.2, 0.25, 0.3, 0.35, 0.4, 0.45, 0.5, 0.55, 0.6, 0.65, 0.7, 0.75, 0.8, 0.85, 0.9, 0.95, 1, 1.1, 1.15, 1.2, 1.25, 1.3, 1.35, 1.4, 1.45, 1.5, 1.55, 1.6, 1.65, 1.7, 1.75, 1.8, 1.85, 1.9, 1.95, or 2.

According to one embodiment, the host material 71 has a difference of refractive index with the material 11 comprised in the at least one aggregate 1 ranging from 0.02 to 2, ranging from 0.02 to 1.5, ranging from 0.03 to 1.5, ranging from 0.04 to 1.5, ranging from 0.05 to 1.5, ranging from 0.02 to 1.2, ranging from 0.03 to 1.2, ranging from 0.04 to 1.2, ranging from 0.05 to 1.2, ranging from 0.05 to 1, ranging from 0.1 to 1, ranging from 0.2 to 1, ranging from 0.3 to 1, ranging from 0.5 to 1, ranging from 0.05 to 2, ranging from 0.1 to 2, ranging from 0.2 to 2, ranging from 0.3 to 2, or ranging from 0.5 to 2.

The difference of refractive index was measured at 450 nm.

According to one embodiment, the host material 71 is a thermal insulator.

According to one embodiment, the host material 71 is a thermal conductor.

According to one embodiment, the host material 71 has a thermal conductivity at standard conditions ranging from 0.1 to 450 W/(m·K), preferably from 1 to 200 W/(m·K), more preferably from 10 to 150 W/(m·K).

According to one embodiment, the host material 71 has a thermal conductivity at standard conditions of at least 0.1 W/(m·K), 0.2 W/(m·K), 0.3 W/(m·K), 0.4 W/(m·K), 0.5 W/(m·K), 0.6 W/(m·K), 0.7 W/(m·K), 0.8 W/(m·K), 0.9 W/(m·K), 1 W/(m·K), 1.1 W/(m·K), 1.2 W/(m·K), 1.3 W/(m·K), 1.4 W/(m·K), 1.5 W/(m·K), 1.6 W/(m·K), 1.7 W/(m·K), 1.8 W/(m·K), 1.9 W/(m·K), 2 W/(m·K), 2.1 W/(m·K), 2.2 W/(m·K), 2.3 W/(m·K), 2.4 W/(m·K), 2.5 W/(m·K), 2.6 W/(m·K), 2.7 W/(m·K), 2.8 W/(m·K), 2.9 W/(m·K), 3 W/(m·K), 3.1 W/(m·K), 3.2 W/(m·K), 3.3 W/(m·K), 3.4 W/(m·K), 3.5 W/(m·K), 3.6 W/(m·K), 3.7 W/(m·K), 3.8 W/(m·K), 3.9 W/(m·K), 4 W/(m·K), 4.1 W/(m·K), 4.2 W/(m·K), 4.3 W/(m·K), 4.4 W/(m·K), 4.5 W/(m·K), 4.6 W/(m·K), 4.7 W/(m·K), 4.8 W/(m·K), 4.9 W/(m·K), 5 W/(m·K), 5.1 W/(m·K), 5.2 W/(m·K), 5.3 W/(m·K), 5.4 W/(m·K), 5.5 W/(m·K), 5.6 W/(m·K), 5.7 W/(m·K), 5.8 W/(m·K), 5.9 W/(m·K), 6 W/(m·K), 6.1 W/(m·K), 6.2 W/(m·K), 6.3 W/(m·K), 6.4 W/(m·K), 6.5 W/(m·K), 6.6 W/(m·K), 6.7 W/(m·K), 6.8 W/(m·K), 6.9 W/(m·K), 7 W/(m·K), 7.1 W/(m·K), 7.2 W/(m·K), 7.3 W/(m·K), 7.4 W/(m·K), 7.5 W/(m·K), 7.6 W/(m·K), 7.7 W/(m·K), 7.8 W/(m·K), 7.9 W/(m·K), 8 W/(m·K), 8.1 W/(m·K), 8.2 W/(m·K), 8.3 W/(m·K), 8.4 W/(m·K), 8.5 W/(m·K), 8.6 W/(m·K), 8.7 W/(m·K), 8.8 W/(m·K), 8.9 W/(m·K), 9 W/(m·K), 9.1 W/(m·K), 9.2 W/(m·K), 9.3 W/(m·K), 9.4 W/(m·K), 9.5 W/(m·K), 9.6 W/(m·K), 9.7 W/(m·K), 9.8 W/(m·K), 9.9 W/(m·K), 10 W/(m·K), 10.1 W/(m·K), 10.2 W/(m·K), 10.3 W/(m·K), 10.4 W/(m·K), 10.5 W/(m·K), 10.6 W/(m·K), 10.7 W/(m·K), 10.8 W/(m·K), 10.9 W/(m·K), 11 W/(m·K), 11.1 W/(m·K), 11.2 W/(m·K), 11.3 W/(m·K), 11.4 W/(m·K), 11.5 W/(m·K), 11.6 W/(m·K), 11.7 W/(m·K), 11.8 W/(m·K), 11.9 W/(m·K), 12 W/(m·K), 12.1 W/(m·K), 12.2 W/(m·K), 12.3 W/(m·K), 12.4 W/(m·K), 12.5 W/(m·K), 12.6 W/(m·K), 12.7 W/(m·K), 12.8 W/(m·K), 12.9 W/(m·K), 13 W/(m·K), 13.1 W/(m·K), 13.2 W/(m·K), 13.3 W/(m·K), 13.4 W/(m·K), 13.5 W/(m·K), 13.6 W/(m·K), 13.7 W/(m·K), 13.8 W/(m·K), 13.9 W/(m·K), 14 W/(m·K), 14.1 W/(m·K), 14.2 W/(m·K), 14.3 W/(m·K), 14.4 W/(m·K), 14.5 W/(m·K), 14.6 W/(m·K), 14.7 W/(m·K), 14.8 W/(m·K), 14.9 W/(m·K), 15 W/(m·K), 15.1 W/(m·K), 15.2 W/(m·K), 15.3 W/(m·K), 15.4 W/(m·K), 15.5 W/(m·K), 15.6 W/(m·K), 15.7 W/(m·K), 15.8 W/(m·K), 15.9 W/(m·K), 16 W/(m·K), 16.1 W/(m·K), 16.2 W/(m·K), 16.3 W/(m·K), 16.4 W/(m·K), 16.5 W/(m·K), 16.6 W/(m·K), 16.7 W/(m·K), 16.8 W/(m·K), 16.9 W/(m·K), 17 W/(m·K), 17.1 W/(m·K), 17.2 W/(m·K), 17.3 W/(m·K), 17.4 W/(m·K), 17.5 W/(m·K), 17.6 W/(m·K), 17.7 W/(m·K), 17.8 W/(m·K), 17.9 W/(m·K), 18 W/(m·K), 18.1 W/(m·K), 18.2 W/(m·K), 18.3 W/(m·K), 18.4 W/(m·K), 18.5 W/(m·K), 18.6 W/(m·K), 18.7 W/(m·K), 18.8 W/(m·K), 18.9 W/(m·K), 19 W/(m·K), 19.1 W/(m·K), 19.2 W/(m·K), 19.3 W/(m·K), 19.4 W/(m·K), 19.5 W/(m·K), 19.6 W/(m·K), 19.7 W/(m·K), 19.8 W/(m·K), 19.9 W/(m·K), 20 W/(m·K), 20.1 W/(m·K), 20.2 W/(m·K), 20.3 W/(m·K), 20.4 W/(m·K), 20.5 W/(m·K), 20.6 W/(m·K), 20.7 W/(m·K), 20.8 W/(m·K), 20.9 W/(m·K), 21 W/(m·K), 21.1 W/(m·K), 21.2 W/(m·K), 21.3 W/(m·K), 21.4 W/(m·K), 21.5 W/(m·K), 21.6 W/(m·K), 21.7 W/(m·K), 21.8 W/(m·K), 21.9 W/(m·K), 22 W/(m·K), 22.1 W/(m·K), 22.2 W/(m·K), 22.3 W/(m·K), 22.4 W/(m·K), 22.5 W/(m·K), 22.6 W/(m·K), 22.7 W/(m·K), 22.8 W/(m·K), 22.9 W/(m·K), 23 W/(m·K), 23.1 W/(m·K), 23.2 W/(m·K), 23.3 W/(m·K), 23.4 W/(m·K), 23.5 W/(m·K), 23.6 W/(m·K), 23.7 W/(m·K), 23.8 W/(m·K), 23.9 W/(m·K), 24 W/(m·K), 24.1 W/(m·K), 24.2 W/(m·K), 24.3 W/(m·K), 24.4 W/(m·K), 24.5 W/(m·K), 24.6 W/(m·K), 24.7 W/(m·K), 24.8 W/(m·K), 24.9 W/(m·K), 25 W/(m·K), 30 W/(m·K), 40 W/(m·K), 50 W/(m·K), 60 W/(m·K), 70 W/(m·K), 80 W/(m·K), 90 W/(m·K), 100 W/(m·K), 110 W/(m·K), 120 W/(m·K), 130 W/(m·K), 140 W/(m·K), 150 W/(m·K), 160 W/(m·K), 170 W/(m·K), 180 W/(m·K), 190 W/(m·K), 200 W/(m·K), 210 W/(m·K), 220 W/(m·K), 230 W/(m·K), 240 W/(m·K), 250 W/(m·K), 260 W/(m·K), 270 W/(m·K), 280 W/(m·K), 290 W/(m·K), 300 W/(m·K), 310 W/(m·K), 320 W/(m·K), 330 W/(m·K), 340 W/(m·K), 350 W/(m·K), 360 W/(m·K), 370 W/(m·K), 380 W/(m·K), 390 W/(m·K), 400 W/(m·K), 410 W/(m·K), 420 W/(m·K), 430 W/(m·K), 440 W/(m·K), or 450 W/(m·K).

According to one embodiment, the host material 71 is electrically insulator.

According to one embodiment, the host material 71 is electrically conductive.

According to one embodiment, the host material 71 has an electrical conductivity at standard conditions ranging from 1×10⁻²⁰ to 10⁷ S/m, preferably from 1×10⁻¹⁵ to 5 S/m, more preferably from 1×10⁻⁷ to 1 S/m.

According to one embodiment, the host material 71 has an electrical conductivity at standard conditions of at least 1×10⁻²⁰ S/m, 0.5×10⁻¹⁹ S/m, 1×10⁻¹⁹ S/m, 0.5×10⁻¹⁸ S/m, 1×10⁻¹⁸ S/m, 0.5×10⁻¹⁷ S/m, 1×10⁻¹⁷ S/m, 0.5×10⁻¹⁶ S/m, 1×10⁻¹⁶ S/m, 0.5×10⁻¹⁵ S/m, 1×10⁻¹⁵ S/m, 0.5×10⁻¹⁴ S/m, 1×10⁻¹⁴ S/m, 0.5×10⁻¹³ S/m, 1×10⁻¹³ S/m, 0.5×10⁻¹² S/m, 1×10⁻¹² S/m, 0.5×10⁻¹¹ S/m, 1×10⁻¹¹ S/m, 0.5×10⁻¹⁰ S/m, 1×10⁻¹⁰ S/m, 0.5×10⁻⁹ S/m, 1×10⁻⁹ S/m, 0.5×10⁻⁸ S/m, 1×10⁻⁸ S/m, 0.5×10⁻⁷ S/m, 1×10⁻⁷ S/m, 0.5×10⁻⁶ S/m, 1×10⁻⁶ S/m, 0.5×10⁻⁵ S/m, 1×10⁻⁵ S/m, 0.5×10⁻⁴ S/m, 1×10⁻⁴ S/m, 0.5×10⁻³ S/m, 1×10⁻³ S/m, 0.5×10⁻² S/m, 1×10⁻² S/m, 0.5×10⁻¹ S/m, 1×10⁻¹ S/m, 0.5 S/m, 1 S/m, 1.5 S/m, 2 S/m, 2.5 S/m, 3 S/m, 3.5 S/m, 4 S/m, 4.5 S/m, 5 S/m, 5.5 S/m, 6 S/m, 6.5 S/m, 7 S/m, 7.5 S/m, 8 S/m, 8.5 S/m, 9 S/m, 9.5 S/m, 10 S/m, 50 S/m, 10² S/m, 5×10² S/m, 10³ S/m, 5×10³ S/m, 10⁴ S/m, 5×10⁴ S/m, 10⁵ S/m, 5×10⁵ S/m, 10⁶ S/m, 5×10⁶ S/m, or 10⁷ S/m.

According to one embodiment, the electrical conductivity of the host material 71 may be measured for example with an impedance spectrometer.

According to one embodiment, the host material 71 is the liquid vehicle of an ink. “Liquid vehicle” or “ink vehicle,” as used herein, refers to the vehicle in which the aggregates 1 of the invention are placed to form the ink.

According to one embodiment, the host material 71 is an inorganic material as described hereabove.

According to one embodiment, the host material 71 is a hybrid material as described hereabove.

According to one embodiment, the host material 71 is an organic material as described hereabove.

According to one embodiment, the host material 71 is polymeric.

According to one embodiment, the host material 71 comprises an organic material as described hereafter.

According to one embodiment, the host material 71 comprises an organic polymer as described hereafter.

According to one embodiment, the host material 71 can polymerize by heating it and/or by exposing it to UV light.

According to one embodiment, the polymeric host material 71 includes but is not limited to: silicone based polymers, polydimethylsiloxanes (PDMS), polyethylene terephthalate, polyesters, polyacrylates, polymethacrylates, polycarbonate, poly(vinyl alcohol), polyvinylpyrrolidone, polyvinylpyridine, polysaccharides, poly(ethylene glycol), melamine resins, a phenol resin, an alkyl resin, an epoxy resin, a polyurethane resin, a maleic resin, a polyamide resin, an alkyl resin, a maleic resin, terpenes resins, an acrylic resin or acrylate based resin such as PMMA, copolymers forming the resins, co-polymers, block co-polymers, polymerizable monomers comprising an UV initiator or thermic initiator, or a mixture thereof.

According to one embodiment, the polymeric host material 71 includes but is not limited to: thermosetting resin, photoresist resin, photosensitive resin, photocurable resin, or dry-curable resin. The thermosetting resin and the photocurable resin are cured using heat and light, respectively. For the use of the dry hard resin, the resin is cured by applying heat to a solvent in which the at least one aggregate 1 is dispersed.

When a thermosetting resin or a photocurable resin is used, the composition of the resulting light emitting material 7 is equal to the composition of the raw material of the light emitting material 7. However, when a dry-curable resin is used, the composition of the resulting light emitting material 7 may be different from the composition of the raw material of the light emitting material 7. During the dry-curing by heat, the solvent is partially evaporated. Thus, the volume ratio of aggregate 1 in the raw material of the light emitting material 7 may be lower than the volume ratio of aggregate 1 in the resulting light emitting material 7.

Upon curing of the resin, a volume contraction is caused. According to one embodiment, a least 2%, 3%, 4%, 5%, 6%, 7%, 8%, 9%, 10%, 15%, or 20%, of contraction are aroused from a thermosetting resin or a photocurable resin. According to one embodiment, a dry-curable resin is contracted by at least 0.1%, 0.2%, 0.3%, 0.4%, 0.5%, 0.6%, 0.7%, 0.8%, 0.9%, 1%, 1.5%, 2%, 2.5%, 3%, 3.5%, 4%, 4.5%, 5%, 5.5%, 6%, 6.5%, 7%, 7.5%, 8%, 8.5%, 9%, 9.5%, 10%, 15%, or 20%. The contraction of the resin may cause movement of the aggregates 1, which may be lower the degree of dispersion of the aggregates 1 in the light emitting material 7. However, embodiments of the present invention can maintain high dispersibility by preventing the movement of the aggregates 1 by introducing other particles in said light emitting material 7.

In one embodiment, the host material 71 may be a polymerizable formulation which can include monomers, oligomers, polymers, or mixture thereof.

In one embodiment, the polymerizable formulation may further comprise a crosslinking agent, a scattering agent, a photo initiator or a thermal initiator.

In one embodiment, the polymerizable formulation includes but is not limited to: monomers, oligomers or polymers made from an alkyl methacrylates or an alkyl acrylates such as acrylic acid, methacrylic acid, crotonic acid, acrylonitrile, acrylic esters substituted with methoxy, ethoxy, propoxy, butoxy, and similar derivatives for example, methyl acrylate, ethyle acrylate, propyl acrylate, butyl acrylate, isobutyl acrylate, lauryl acrylate, norbornyl acrylate, 2-ethyl hexyl acrylate, 2-hydroxyethyl acrylate, 4-hydroxybutyl acrylate, benzyl acrylate, phenyl acrylate, isobornyle acrylate, hydroxypropyl acrylate, fluorinated acrylic monomers, chlorinated acrylic monomers, methacrylic acid, methyl methacrylate, n-butyl methacrylate, isobutyl methacrylate, 2-ethyl hexyl methacrylate, 2-hydroxyethyl methacrylate, 4-hydroxybutyl methacrylate, benzyl methacrylate, phenyl methacrylate, lauryl methacrylate, norbornyl methacrylate, isobornyle methacrylate, hydroxypropyl methacrylate, fluorinated methacrylic monomers, chlorinated methacrylic monomers, alkyl crotonates, allyl crotonates, glycidyl methacrylate and related esters.

In another embodiment, the polymerizable formulation includes but is not limited to: monomers, oligomers or polymers made from an alkyl acrylamide or alkyl methacrylamide such as acrylamide, Alkylacrylamide, N-tert-Butylacrylamide, Diacetone acrylamide, N,N-Diethylacrylamide, N-(Isobutoxymethyl)acrylamide, N-(3-Methoxypropyl)acrylamide, N-Diphenylmethylacrylamide, N-Ethylacrylamide, N-Hydroxyethyl acrylamide, N-(Isobutoxymethyl)acrylamide, N-Isopropylacrylamide, N-(3-Methoxypropyl) acrylamide, N-Phenylacrylamide, N-[Tris(hydroxymethyl)methyl]acrylamide, N,N-Diethylmethacrylamide, N,NDimethylacrylamide, N-[3-(Dimethylamino)propyl]methacrylamide, N-(Hydroxymethyl)acrylamide, 2-Hydroxypropyl methacrylamide, N-Isopropylmethacrylamide, Methacrylamide, N-(Triphenylmethyl)methacrylamide, poly (3,4-ethylenedioxythiopene) , poly(ethylene dioxythiophene)/poly(styrene sulfonic acid) (PEDOT/PSS), an aqueous solution of polyaniline/camphor sulfonic acid (PANI/CSA), PTPDES, Et-PIT-DEK, PPBA, and similar derivatives.

In one embodiment, the polymerizable formulation includes but is not limited to: monomers, oligomers or polymers made from alpha-olefins, dienes such as butadiene and chloroprene; styrene, alpha-methyl styrene, and the like; heteroatom substituted alpha-olefins, for example, vinyl acetate, vinyl alkyl ethers for example, ethyl vinyl ether, vinyltrimethylsilane, vinyl chloride, tetrafluoroethylene, chlorotrifiuoroethylene, cyclic and polycyclic olefin compounds for example, cyclopentene, cyclohexene, cycloheptene, cyclooctene, and cyclic derivatives up to C20; polycyclic derivates for example, norbornene, and similar derivatives up to C20; cyclic vinyl ethers for example, 2, 3-dihydrofuran, 3,4-dihydropyran, and similar derivatives; allylic alcohol derivatives for example, vinylethylene carbonate, disubstituted olefins such as maleic and fumaric compounds for example, maleic anhydride, diethylfumarate, and the like, and mixtures thereof.

In one embodiment, examples of crosslinking agent include but are not limited to: di-acrylate, tri-acrylate, tetra-acrylate, di-methacrylate, tri-methacrylate and tetra-methacrylate monomers derivatives and the like. Another example of crosslinking agent includes but is not limited to:

monomers, oligomers or polymers made from di- or trifunctional monomers such as allyl methacrylate, diallyl maleate, 1,3-butanediol dimethacrylate, 1,4-butanediol dimethacrylate, 1,6-hexanediol dimethacrylate, pentaerythritol triacrylate, trimethylolpropane triacrylate, Ethylene glycol dimethacrylate, Triethylene glycol dimethacrylate, N,N-methylenebis(acrylamide), N,N′-Hexamethylenebis(methacrylamide), and divinyl benzene.

In one embodiment, the polymerizable formulation may further comprise scattering particles. Examples of scattering particles include but are not limited to: SiO₂, ZrO₂, ZnO, MgO, SnO₂, TiO₂, Ag, Au, alumina, barium sulfate, PTFE, barium titanate and the like.

In one embodiment, the polymerizable formulation may further comprise a thermal conductor. Examples of thermal conductor include but are not limited to: SiO₂, ZrO₂, ZnO, MgO, SnO₂, TiO₂, CaO, alumina, barium sulfate, PTFE, barium titanate and the like. In this embodiment, the thermal conductivity of the host material 71 is increased.

In one embodiment, the polymerizable formulation may further comprise a photo initiator. Examples of photo initiator include but are not limited to: α-hydroxyketone, phenylglyoxylate, benzyldimethyl-ketal, α-aminoketone, monoacylphosphine oxides, bisacylphosphine oxides, phosphine oxide, benzophenone and derivatives, polyvinyl cinnamate, metallocene or iodonium salt derivatives and the like. Another example of photo initiator includes Irgacure® photoinitiator and Esacure® photoinitiator and the like.

In one embodiment, the polymerizable formulation may further comprise a thermal initiator. Examples of thermal initiator include but are limited to: peroxide compounds, azo compounds such as azobisisobutyronitrile (AIBN) and 4,4-Azobis(4-cyanovaleric acid), potassium and ammonium persulfate, tert-Butyl peroxide, benzoyl peroxide and the like.

In one embodiment, the polymeric host material 71 may be a polymerized solid made from an alkyl methacrylates or an alkyl acrylates such as acrylic acid, methacrylic acid, crotonic acid, acrylonitrile, acrylic esters substituted with methoxy, ethoxy, propoxy, butoxy, and similar derivatives for example, methyl acrylate, ethyle acrylate, propyl acrylate, butyl acrylate, isobutyl acrylate, lauryl acrylate, norbornyl acrylate, 2-ethyl hexyl acrylate, 2-hydroxyethyl acrylate, 4-hydroxybutyl acrylate, benzyl acrylate, phenyl acrylate, isobornyle acrylate, hydroxypropyl acrylate, fluorinated acrylic monomers, chlorinated acrylic monomers, methacrylic acid, methyl methacrylate, nbutyl methacrylate, isobutyl methacrylate, 2-ethyl hexyl methacrylate, 2-hydroxyethyl methacrylate, 4-hydroxybutyl methacrylate, benzyl methacrylate, phenyl methacrylate, lauryl methacrylate, norbornyl methacrylate, isobornyle methacrylate, hydroxypropyl methacrylate, fluorinated methacrylic monomers, chlorinated methacrylic monomers, alkyl crotonates, allyl crotonates, glycidyl methacrylate and related esters.

In one embodiment, the polymeric host material 71 may be a polymerized solid made from an alkyl acrylamide or alkyl methacrylamide such as acrylamide, Alkylacrylamide, Ntert-Butylacrylamide, Diacetone acrylamide, N,N-Diethylacrylamide, N-Isobutoxymethyl)acrylamide, N-(3-Methoxypropyl)acrylamide, NDiphenylmethylacrylamide, N-Ethylacrylamide, N-Hydroxyethyl acrylamide, N-(Isobutoxymethyl)acrylamide, N-Isopropylacrylamide, N-(3-Methoxypropyl)acrylamide, N-Phenylacrylamide, N-[Tris(hydroxymethyl)methyl]acrylamide, N,N-Diethylmethacrylamide, N,NDimethylacrylamide, N-[3-(Dimethylamino)propyl]methacrylamide, N-(Hydroxymethyl)acrylamide, 2-Hydroxypropyl methacrylamide, NIsopropylmethacrylamide, Methacryl amide, N-(Triphenylmethyl)methacrylamide, poly (3,4-ethylenedioxythiopene), poly(ethylene dioxythiophene)/poly(styrene sulfonic acid) (PEDOT/PSS), an aqueous solution of polyaniline/camphor sulfonic acid (PANI/CSA), PTPDES, Et-PIT-DEK, PPBA, and similar derivatives.

In one embodiment, the polymeric host material 71 may be a polymerized solid made from alpha-olefins, dienes such as butadiene and chloroprene; styrene, alpha-methyl styrene, and the like; heteroatom substituted alpha-olefins, for example, vinyl acetate, vinyl alkyl ethers for example, ethyl vinyl ether, vinyltrimethylsilane, vinyl chloride, tetrafluoroethylene, chlorotrifiuoroethylene, cyclic and polycyclic olefin compounds for example, cyclopentene, cyclohexene, cycloheptene, cyclooctene, and cyclic derivatives up to C20; polycyclic derivates for example, norbornene, and similar derivatives up to C20; cyclic vinyl ethers for example, 2,3-dihydrofuran, 3,4-dihydropyran, and similar derivatives; allylic alcohol derivatives for example, vinylethylene carbonate, disubstituted olefins such as maleic and fumaric compounds for example, maleic anhydride, diethylfumarate, and the like, and mixtures thereof.

In one embodiment, the polymeric host material 71 may be PMMA, Poly(lauryl methacrylate), glycolized poly(ethylene terephthalate), Poly(maleic anhydride-altoctadecene), or mixtures thereof.

In another embodiment, the light emitting material 7 may further comprise at least one solvent. According to this embodiment, the solvent is one that allows the solubilization of the aggregates 1 of the invention and polymeric host material 71 such as for example, pentane, hexane, heptane, 1,2-hexanediol, 1,5-pentanediol, cyclohexane, petroleum ether, toluene, benzene, xylene, chlorobenzene, carbon tetrachloride, chloroform, dichloromethane, 1,2-dichloroethane, THF (tetrahydrofuran), acetonitrile, acetone, ethanol, methanol, ethyl acetate, ethylene glycol, diglyme (diethylene glycol dimethyl ether), diethyl ether, DME (1,2-dimethoxy-ethane, glyme), DMF (dimethylformamide), NMF (N-methylformamide), FA (Formamide), DMSO (dimethyl sulfoxide), 1,4-Dioxane, triethyl amine, alkoxy alcohol, alkyl alcohol, alkyl benzene, alkyl benzoate, alkyl naphthalene, amyl octanoate, anisole, aryl alcohol, benzyl alcohol, butyl benzene, butyrophenon, cis-decalin, dipropylene glycol methyl ether, dodecyl benzene, mesitylene, methoxy propanol, methylbenzoate, methyl naphthalene, methyl pyrrolidinone, phenoxy ethanol, 1,3-propanediol, pyrrolidinone, trans-decalin, valerophenone, or mixture thereof.

According to one embodiment, the light emitting material 7 comprises at least two solvents as described hereabove. In this embodiment, the solvents are miscible together.

According to one embodiment, the light emitting material 7 comprises a blend of solvents as described hereabove. In this embodiment, the solvents are miscible together.

According to one embodiment, the light emitting material 7 comprises a plurality of solvents as described hereabove. In this embodiment, the solvents are miscible together.

According to one embodiment, the solvent comprised in the light emitting material 7 is miscible with water.

In another embodiment, the light emitting material 7 comprises a blend of solvents such as for example: a blend of benzyl alcohol and butyl benzene, a blend of benzyl alcohol and anisole, a blend of benzyl alcohol and mesitylene, a blend of butyl benzene and anisole, a blend of butyl benzene and mesitylene, a blend of anisole and mesitylene, a blend of dodecyl benzene and cis-decalin, a blend of dodecyl benzene and benzyl alcohol, a blend of dodecyl benzene and butyl benzene, a blend of dodecyl benzene and anisole, a blend of dodecyl benzene and mesitylene, a blend of cis-decalin and benzyl alcohol, a blend of cis-decalin and butyl benzene, a blend of cis-decalin and anisole, a blend of cis-decalin and mesitylene, a blend of trans-decalin and benzyl alcohol, a blend of trans-decalin and butyl benzene, a blend of trans-decalin and anisole, a blend of trans-decalin and mesitylene, a blend of methyl pyrrolidinone and anisole, a blend of methylbenzoate and anisole, a blend of methyl pyrrolidinone and methyl naphthalene, a blend of methyl pyrrolidinone and methoxy propanol, a blend of methyl pyrrolidinone and phenoxy ethanol, a blend of methyl pyrrolidinone and amyl octanoate, a blend of methyl pyrrolidinone and trans-decalin, a blend of methyl pyrrolidinone and mesitylene, a blend of methyl pyrrolidinone and butyl benzene, a blend of methyl pyrrolidinone and dodecyl benzene, a blend of methyl pyrrolidinone and benzyl alcohol, a blend of anisole and methyl naphthalene, a blend of anisole and methoxy propanol, a blend of anisole and phenoxy ethanol, a blend of anisole and amyl octanoate, a blend of methylbenzoate and methyl naphthalene, a blend of methylbenzoate and methoxy propanol, a blend of methylbenzoate and phenoxy ethanol, a blend of methylbenzoate and amyl octanoate, a blend of methylbenzoate and cis-decalin, a blend of methylbenzoate and trans-decalin, a blend of methylbenzoate and mesitylene, a blend of methylbenzoate and butyl benzene, a blend of methylbenzoate and dodecyl benzene, a blend of methylbenzoate and benzyl alcohol, a blend of methyl naphthalene and methoxy propanol, a blend of methyl naphthalene and phenoxy ethanol, a blend of methyl naphthalene and amyl octanoate, a blend of methyl naphthalene and cis-decalin, a blend of methyl naphthalene and trans-decalin, a blend of methyl naphthalene and mesitylene, a blend of methyl naphthalene and butyl benzene, a blend of methyl naphthalene and dodecyl benzene, a blend of methyl naphthalene and benzyl alcohol, a blend of methoxy propanol and phenoxy ethanol, a blend of methoxy propanol and amyl octanoate, a blend of methoxy propanol and cis-decalin, a blend of methoxy propanol and trans-decalin, a blend of methoxy propanol and mesitylene, a blend of methoxy propanol and butyl benzene, a blend of methoxy propanol and dodecyl benzene, a blend of methoxy propanol and benzyl alcohol, a blend of phenoxy ethanol and amyl octanoate, a blend of phenoxy propanol and mesitylene, a blend of phenoxy propanol and butyl benzene, a blend of phenoxy propanol and dodecyl benzene, a blend of phenoxy propanol and benzyl alcohol, a blend of amyl octanoate and cis-decalin, a blend of amyl octanoate and trans-decalin, a blend of amyl octanoate and mesitylene, a blend of amyl octanoate and butyl benzene, a blend of amyl octanoate and dodecyl benzene, a blend of amyl octanoate and benzyl alcohol, or a combination thereof.

According to one embodiment, the light emitting material 7 comprises a blend of valerophenon and dipropyleneglycol methyl ether, a blend of valerophenon and butyrophenon, a blend of dipropyleneglycol methyl ether and butyrophenon, a blend of dipropyleneglycol methyl ether and 1,3-propanediol, a blend of butyrophenon and 1,3-propanediol, a blend of dipropyleneglycol methyl ether, 1,3-propanediol, and water, or a combination thereof.

According to one embodiment, the light emitting material 7 comprises a blend of three, four, five, or more solvents can be used for the vehicle. For example, the vehicle can comprise a blend of three, four, five, or more solvents selected from pyrrolidinone, methyl pyrrolidinone, anisole, alkyl benzoate, methylbenzoate, alkyl naphthalene, methyl naphthalene, alkoxy alcohol, methoxy propanol, phenoxy ethanol, amyl octanoate, cis-decalin, trans-decalin, mesitylene, alkyl benzene, butyl benzene, dodecyl benzene, alkyl alcohol, aryl alcohol, benzyl alcohol, butyrophenon, dipropylene glycol methyl ether, valerophenon, and 1,3-propanediol. According to one embodiment, the light emitting material 7 comprises three or more solvents selected from cis-decalin, trans-decalin, benzyl alcohol, butyl benzene, anisole, mesitylene, and dodecyl benzene.

In some embodiments, each of the solvents in each of the blends listed above is present in an amount of at least 5% by weight based on the total weight of the host material 71, for example, at least 10% by weight, at least 15% by weight, at least 20% by weight, at least 25% by weight, at least 30% by weight, at least 35% by weight, or at least 40% by weight. In some embodiments, each of the solvents in each of the blends listed can comprise 50% by weight of the light emitting material 7 based on the total weight of the light emitting material 7.

According to one embodiment, the host material 71 comprises a film-forming material. In this embodiment, the film-forming material is a polymer or an inorganic material as described hereabove.

According to one embodiment, the host material 71 comprises at least 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 95%, or 100% by weight of a film-forming material.

According to one embodiment, the film-forming material is polymeric, i.e. comprises or consists of polymers and/or monomers as described hereabove.

According to one embodiment, the film-forming material is inorganic, i.e. it comprises or consists of an inorganic material as described hereafter.

In another embodiment, the light emitting material 7 comprises the aggregates 1 of the invention and a polymeric host material 71, and does not comprise a solvent. In this embodiment, the aggregates 1 and host material 71 can be mixed by extrusion.

According to another embodiment, the host material 71 is a monomer.

According to another embodiment, the host material 71 is methylmetacrylate.

According to one embodiment, the host material 71 does not comprise glass.

According to one embodiment, the host material 71 does not comprise vitrified glass.

According to one embodiment, the host material 71 comprises or consists of a thermal conductive material wherein said thermal conductive material includes but is not limited to: Al₂O₃, Ag₂O, Cu₂O, CuO, Fe₃O₄, FeO, SiO₂, PbO, CaO, MgO, ZnO, SnO₂, TiO₂, BeO, CdS, ZnS, ZnSe, CdZnS, CdZnSe, Au, Na, Fe, Cu, Al, Ag, Mg, mixed oxides, mixed oxides thereof or a mixture thereof.

According to one embodiment, the host material 71 comprises or consists of a thermal conductive material wherein said thermal conductive material includes but is not limited to: aluminium oxide, silver oxide, copper oxide, iron oxide, silicon oxide, lead oxide, calcium oxide, magnesium oxide, zinc oxide, tin oxide, titanium oxide, beryllium oxide, zinc sulfide, cadmium sulfide, zinc selenium, cadmium zinc selenium, cadmium zinc sulfide, gold, sodium, iron, copper, aluminium, silver, magnesium, mixed oxides, mixed oxides thereof or a mixture thereof.

According to one embodiment, the host material 71 comprises organic molecules in small amounts of 0 mole %, 1 mole %, 5 mole %, 10 mole %, 15 mole %, 20 mole %, 25 mole %, 30 mole %, 35 mole %, 40 mole %, 45 mole %, 50 mole %, 55 mole %, 60 mole %, 65 mole %, 70 mole %, 75 mole %, 80 mole % relative to the majority element of said host material 71.

According to one embodiment, the host material 71 comprises a liquid including but not limited to: 1-methoxy-2-propanol, 2-pyrrolidinone, C4 to C8 1,2-alkanediol, aliphatic or alicycle ketone, methyl ethyl ketone, C1-C4 alkanol such as for example methanol, ethanol, methanol propanol, or isopropanol, ketones, esters, ether of ethylene glycol or propylene glycol, acetals, acrylic resin, polyvinyl acetate, polyvinyl alcohol, polyamide resin, polyurethane resin, epoxy resin, alkyd ester, nitrated cellulose, ethyl cellulose, sodium carboxymethyl cellulose, alkyds, maleics, cellulose derivatives, formaldehyde, rubber resin, phenolics, propyl acetate, glycol ether, aliphatic hydrocarbon, acetate, ester. acrylic, cellulose ester, nitrocellulose, modified resin, alkoxylated alcohol, 2-pyrrolidone, a homolog of 2-pyrrolidone, glycol, water, or a mixture thereof.

In an embodiment, the host material 71 includes water and effective amounts of one or more of: derivatized 2-pyrrolidinone(s), glycerol polyoxyethyl ether(s), diol(s), or combinations thereof. In one non-limiting example, the host material 71 includes water and a derivatized 2-pyrrolidinone (e.g., 1-(2-hydroxyethyl)-2-pyrrolidinone). In another non-limiting example, the host material 71 includes derivatized 2-pyrrolidinone(s), glycerol polyoxyethyl ether(s), diol(s), and non-ionic and/or anionic surfactants.

In one embodiment, the host material 71 may also include water soluble polymers, buffers, biocides, sequestering agents, viscosity modifiers, surface-active agents, chelating agents, pH adjusting agents, resins, and/or combinations thereof.

According to one embodiment, the host material 71 comprises a liquid at a level of at least 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, or 95% in weight compared to the total weight of the host material 71.

According to one embodiment, the host material 71 comprises a film-forming material. In this embodiment, the film-forming material is a polymer or an inorganic material as described hereabove.

According to one embodiment, the host material 71 comprises at least 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 95%, or 100% of a film-forming material.

According to one embodiment, the film-forming material is stable in the host material 71.

According to one embodiment, the film-forming material is dispersed or dissolved in the host material 71.

According to one embodiment, the film-forming material is present in an amount of from about 0.1% by weight to about 10.0% by weight based on the total weight of the host material 71.

According to one embodiment, the host material 71 comprises a material that is cured or otherwise processed to form a layer on a support.

According to one embodiment, the host material 71 has a maximum boiling point that is substantially lower than the evaporation or sublimation temperature of the film-forming material.

According to one embodiment, the host material 71 has a maximum boiling point that is at least 70° C., 65° C., 60° C., 55° C., 50° C., 45° C., 40° C., 35° C., 30° C., 25° C., 20° C., 15° C., or 10° C. lower than the evaporation or sublimation temperature of the film-forming material.

According to one embodiment, the host material 71 has high purity and the maximum boiling point and purity are such that when heated to a temperature below or equal to the maximum boiling point of the host material 71, the host material 71 substantially completely and rapidly evaporates while the film-forming material remains stable.

According to one embodiment, the host material 71 is highly pure such that it contains 2000 ppm or less in impurities, by weight, based on the total weight of the host material 71.

According to one embodiment, the host material 71 is inert with respect to inkjet and/or thermal printing printhead materials.

According to one embodiment, the host material 71 comprises a polymeric host material as described hereabove, an inorganic host material as described hereabove, or a mixture thereof.

According to one embodiment, the host material 71 can be cured into a shape of a film, thereby generating a film.

According to one embodiment, as illustrated in FIG. 9B, the light emitting material 7 further comprises at least one particle comprising a material 121; and a plurality of nanoparticles, wherein said material 121 is an organic material, an inorganic material or a hybrid material as described hereabove. Said material 121 may be the same or different from the material 11 comprised in the aggregate 1 of the invention. In this embodiment, said at least one particle comprising an inorganic material 121 is empty, i.e. does not comprise any nanoparticle. In this embodiment, said nanoparticles are particles as described hereabove.

According to one embodiment, the light emitting material 7 further comprises at least one particle comprising a material 121, wherein said material 121 is an organic material, an inorganic material or a hybrid material as described hereabove. Said material 121 may be the same or different from the material 11 comprised in the aggregate 1 of the invention. In this embodiment, said at least one particle comprising an inorganic material 121 is empty, i.e. does not comprise any nanoparticle.

According to one embodiment, the light emitting material 7 further comprises at least 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, or 95% in weight of particle comprising a material 121.

According to one embodiment, the particle comprising a material 121 has a different size than the at least one aggregate 1.

According to one embodiment, the particle comprising a material 121 has the same size as the at least one aggregate 1.

According to one embodiment, the light emitting material 7 further comprises a plurality of nanoparticles. In this embodiment, said nanoparticles are particles as described hereabove. In this embodiment, said nanoparticles are different from the particles 12 comprised in the at least one aggregate 1.

According to one embodiment, the light emitting material 7 further comprises a plurality of nanoparticles. In this embodiment, said nanoparticles are particles as described hereabove. In this embodiment, said nanoparticles are the same as the particles 12 comprised in the at least one aggregate 1.

According to one embodiment, the light emitting material 7 further comprises at least 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, or 95% in weight of nanoparticles, wherein said nanoparticles are not comprised in the at least one aggregate 1.

In another embodiment, the light emitting material 7 comprising at least one population of aggregates 1, may further comprise at least one population of converters having phosphor properties. Examples of converter having phosphor properties include, but are not limited to: garnets (LuAG, GAL, YAG, GaYAG), silicates, oxynitrides/oxycarbidonitrides, nintrides/carbidonitrides, Mn⁴⁺ red phosphors (PFS/KFS), quantum dots.

According to one embodiment, the light emitting material 7 may be used as a light source.

According to one embodiment, the light emitting material 7 may be used in a light source.

According to one embodiment, the light emitting material 7 may be used as a color filter.

According to one embodiment, the light emitting material 7 may be used in a color filter.

According to one embodiment, the light emitting material 7 may be used in addition to a color filter.

According to one embodiment illustrated in FIG. 20A-B, the light emitting material 7 forms a color conversion layer 73. In this embodiment, said color conversion layer 73 comprises at least one light emitting material 7, i.e. said color conversion layer 73 can comprise one light emitting material 7 or a plurality of light emitting materials 7.

According to one embodiment, said color conversion layer 73 comprises at least one light emitting material 7 comprising at least one aggregate 1 surrounded partially or totally by at least one host material 71; wherein said at least one light emitting material 7 is configured to emit a secondary light in response to an excitation; and wherein the first material 11 has a difference of refractive index compared to the at least one host material 71 superior or equal to 0.02 at 450 nm.

According to one embodiment, the color conversion layer 73 has a thickness between 0 nm and 10 cm, more preferably between 100 nm and 1 cm, even more preferably between 100 nm and 1 mm.

According to one embodiment, the color conversion layer 73 has a thickness less than 200 μm. This embodiment is particularly advantageous as that the light conversion efficiency is greatly improved when the surface roughness value is approximately 10 nm. For example, in this embodiment, the light conversion efficiency can be 80% or more.

According to one embodiment, the color conversion layer 73 has a thickness ranging from 30 μm to 120 μm. This embodiment is particularly advantageous the light conversion efficiency is improved when the surface roughness Ra value is in a range from 10 nm to 300 nm. For example, in this embodiment, the light conversion efficiency can be 80% or more.

According to one embodiment, the color conversion layer 73 comprises a binder as described herein.

According to one embodiment, the binder comprised in the color conversion layer 73 has a difference of linear expansion coefficient with the support on which is deposited said color conversion layer 73. In this embodiment, the difference of linear expansion coefficient between the binder and the support is less than 8 ppm/K. This embodiment is particularly advantageous as it prevents peeling between the support and the color conversion layer 73. This is because that the stress inside the color conversion layer 73, accompanied by heat generation, is sufficiently eased even though the color conversion layer 73 generates heat by irradiation with the excitation light.

Another object of the invention relates to a support supporting at least one aggregate 1 of the invention and/or at least one light emitting material 7 as described here above.

In one embodiment, the at least one aggregate 1 of the invention and/or at least one light emitting material 7 are deposited on the support by drop-casting, spin coating, dip coating, inkjet printing, lithography, spray, plating, electroplating, or any other means known by the person skilled in the art.

According to one embodiment, the at least one aggregate 1 and/or at least one light emitting material 7 deposited onto the support is placed in the presence of a gas which can dissolve the material 11 and/or the host material 71. This leads to the dissolution of the material and/or the host material and thus the deposition of the aggregate 1 and/or particle 12 directly onto said support. For example, the aggregate 1 and/or at least one light emitting material 7 may be deposited onto a solid support, then exposed to a gas which dissolves the material 11 and/or the host material 71, leading to the deposition of the aggregate 1 and/or particle 12 directly onto said support while the material 11 and/or the host material 71 is removed by washing said support with a solvent in which the material 11 and/or the host material 71 is soluble but the aggregate 1 and/or particle 12 cannot be dispersed.

According to one embodiment, the at least one light emitting material 7 deposited onto the support is placed in the presence of a gas which can dissolve the host material 71. This leads to the dissolution of said host material 71 and thus the deposition of the aggregate 1 directly onto said support. For example, the at least one light emitting material 7 may be deposited onto a solid support, then exposed to a gas which dissolves the host material 71, leading to the deposition of the aggregate 1 directly onto said support while the host material 71 is removed by washing said support with a solvent in which the host material 71 is soluble but the aggregate 1 cannot be dispersed.

According to one embodiment, the at least one aggregate 1 and the at least one light emitting material 7 deposited onto the support is placed in the presence of a gas which can dissolve the material 11 and the host material 71. This leads to the dissolution of the material 11 and/or the host material 71 and thus the deposition of the particle 12 directly onto said support. For example, the aggregate 1 and the at least one light emitting material 7 may be deposited onto a solid support, then exposed to a gas which dissolves the material 11 and the host material 71, leading to the deposition of the aggregate 1 and particle 12 directly onto said support while the material 11 and the host material 71 is removed by washing said support with a solvent in which the material 11 and the host material 71 is soluble but the particle 12 cannot be dispersed.

According to one embodiment, the at least one aggregate 1 deposited onto the support is placed in the presence of a gas which can dissolve the material 11, leading to the dissolution of said material 11 and thus the deposition of the particle 12 directly onto said support. For example, the aggregate 1 may be deposited onto a solid support, then exposed to a gas which dissolves the material 11, leading to the deposition of the particle 12 directly onto said support while the material 11 is removed by washing said support with a solvent in which the material 11 is soluble but the particle 12 cannot be dispersed.

In one embodiment, the support supports at least one population of aggregates 1. In one embodiment, the support supports at least one light emitting material 7 comprising at least one population of aggregates 1. In the present application, a population of aggregates 1 is defined by the maximum emission wavelength.

In one embodiment, the support supports two populations of aggregates 1 emitting different colors or wavelengths. In one embodiment, the support supports at least one light emitting material 7 comprising two populations of aggregates 1 emitting different colors or wavelengths. In one embodiment, the support supports two light emitting materials 7 each comprising one population of aggregates 1, the populations comprised in each light emitting material 7 emitting different colors or wavelengths.

In one embodiment, the support supports aggregates 1 which emit green light and red light upon downconversion of a blue light source. Thus, the blue light from the light source(s) pass through the aggregate 1, where predetermined amounts of green and red light are mixed with the remaining blue light to create the tri-chromatic white light. In one embodiment, the support supports at least one light emitting material 7 comprising aggregates 1 which emit green light and red light upon downconversion of a blue light source. In this embodiment, the at least one light emitting material 7 is configured to transmit a predetermined intensity of the incident blue light and to emit a predetermined intensity of secondary green and red lights, allowing to emit a resulting tri-chromatic white light. In one embodiment, the support supports at least one light emitting material 7 comprising at least one aggregate 1 which emits green light, and at least one light emitting material 7 comprising at least one aggregate 1 which emits red light upon downconversion of a blue light source. In this embodiment, the at least one light emitting material 7 is configured to transmit a predetermined intensity of the incident blue light and to emit a predetermined intensity of secondary green and red lights, allowing to emit a resulting tri-chromatic white light.

In one embodiment, the support supports two populations of aggregates 1, a first population with a maximum emission wavelength between 500 nm and 560 nm, more preferably between 515 nm and 545 nm and a second population with a maximum emission wavelength between 600 nm and 2500 nm, more preferably between 610 nm and 650 nm. In one embodiment, the support supports at least one light emitting material 7 comprising two populations of aggregates 1, a first population with a maximum emission wavelength between 500 nm and 560 nm, more preferably between 515 nm and 545 nm and a second population with a maximum emission wavelength between 600 nm and 2500 nm, more preferably between 610 nm and 650 nm. In one embodiment, the support supports two light emitting material 7 each comprising at least one population of aggregates 1, a first light emitting material 7 comprising a first population with a maximum emission wavelength between 500 nm and 560 nm, more preferably between 515 nm and 545 nm and a second light emitting material 7 comprising a second population with a maximum emission wavelength between 600 nm and 2500 nm, more preferably between 610 nm and 650 nm.

In one embodiment, the support supports two populations of aggregates 1, a first population with at least one emission peak having a full width half maximum lower than 90 nm, 80 nm, 70 nm, 60 nm, 50 nm, 40 nm, 30 nm, 25 nm, 20 nm, 15 nm, or 10 nm and a second population with at least one emission peak having a full width half maximum lower than 90 nm, 80 nm, 70 nm, 60 nm, 50 nm, 40 nm, 30 nm, 25 nm, 20 nm, 15 nm, or 10 nm. In one embodiment, the support supports at least one light emitting material 7 comprising two populations of aggregates 1, a first population with at least one emission peak having a full width half maximum lower than 90 nm, 80 nm, 70 nm, 60 nm, 50 nm, 40 nm, 30 nm, 25 nm, 20 nm, 15 nm, or 10 nm and a second population with at least one emission peak having a full width half maximum lower than 90 nm, 80 nm, 70 nm, 60 nm, 50 nm, 40 nm, 30 nm, 25 nm, 20 nm, 15 nm, or 10 nm. In one embodiment, the support supports two light emitting material 7 each comprising at least one population of aggregates 1, a first light emitting material 7 comprising a first population with at least one emission peak having a full width half maximum lower than 90 nm, 80 nm, 70 nm, 60 nm, 50 nm, 40 nm, 30 nm, 25 nm, 20 nm, 15 nm, or 10 nm and a second light emitting material 7 comprising a second population with at least one emission peak having a full width half maximum lower than 90 nm, 80 nm, 70 nm, 60 nm, 50 nm, 40 nm, 30 nm, 25 nm, 20 nm, 15 nm, or 10 nm.

In one embodiment, the support supports two populations of aggregates 1, a first population with at least one emission peak having a full width at quarter maximum lower than 90 nm, 80 nm, 70 nm, 60 nm, 50 nm, 40 nm, 30 nm, 25 nm, 20 nm, 15 nm, or 10 nm and a second population with at least one emission peak having a full width at quarter maximum lower than 90 nm, 80 nm, 70 nm, 60 nm, 50 nm, 40 nm, 30 nm, 25 nm, 20 nm, 15 nm, or 10 nm. In one embodiment, the support supports at least one light emitting material 7 comprising two populations of aggregates 1, a first population with at least one emission peak having a full width at quarter maximum lower than 90 nm, 80 nm, 70 nm, 60 nm, 50 nm, 40 nm, 30 nm, 25 nm, 20 nm, 15 nm, or 10 nm and a second population with at least one emission peak having a full width at quarter maximum lower than 90 nm, 80 nm, 70 nm, 60 nm, 50 nm, 40 nm, 30 nm, 25 nm, 20 nm, 15 nm, or 10 nm. In one embodiment, the support supports two light emitting material 7 each comprising at least one population of aggregates 1, a first light emitting material 7 comprising a first population with at least one emission peak having a full width at quarter maximum lower than 90 nm, 80 nm, 70 nm, 60 nm, 50 nm, 40 nm, 30 nm, 25 nm, 20 nm, 15 nm, or 10 nm and a second light emitting material 7 comprising a second population with at least one emission peak having a full width at quarter maximum lower than 90 nm, 80 nm, 70 nm, 60 nm, 50 nm, 40 nm, 30 nm, 25 nm, 20 nm, 15 nm, or 10 nm.

In one embodiment, the at least one aggregate 1 and/or the at least one light emitting material 7 on a support is encapsulated into a multilayered system. In one embodiment, the multilayer system comprises at least two, at least three layers.

In one embodiment, the multilayered system may further comprise at least one auxiliary layer.

According to one embodiment, the auxiliary layer is optically transparent at wavelengths between 200 nm and 50 um, between 200 nm and 10 um, between 200 nm and 2500 nm, between 200 nm and 2000 nm, between 200 nm and 1500 nm, between 200 nm and 1000 nm, between 200 nm and 800 nm, between 400 nm and 700 nm, between 400 nm and 600 nm, or between 400 nm and 470 nm. In this embodiment, the auxiliary layer does not absorb any light allowing the aggregate 1 and/or the light emitting material 7 to absorb all the incident light.

According to one embodiment, the auxiliary layer limits or prevents the degradation of the chemical and physical properties of the at least one aggregate 1 from molecular oxygen, ozone, water and/or high temperature. According to one embodiment, the auxiliary layer protects the at least one light emitting material 7 from molecular oxygen, ozone, water and/or high temperature.

According to one embodiment, the auxiliary layer is thermally conductive.

According to one embodiment, the auxiliary layer has a thermal conductivity at standard conditions ranging from 0.1 to 450 W/(m·K), preferably from 1 to 200 W/(m·K), more preferably from 10 to 150 W/(m·K).

According to one embodiment, the auxiliary layer has a thermal conductivity at standard conditions of at least 0.1 W/(m·K), 0.2 W/(m·K), 0.3 W/(m·K), 0.4 W/(m·K), 0.5 W/(m·K), 0.6 W/(m·K), 0.7 W/(m·K), 0.8 W/(m·K), 0.9 W/(m·K), 1 W/(m·K), 1.1 W/(m·K), 1.2 W/(m·K), 1.3 W/(m·K), 1.4 W/(m·K), 1.5 W/(m·K), 1.6 W/(m·K), 1.7 W/(m·K), 1.8 W/(m·K), 1.9 W/(m·K), 2 W/(m·K), 2.1 W/(m·K), 2.2 W/(m·K), 2.3 W/(m·K), 2.4 W/(m·K), 2.5 W/(m·K), 2.6 W/(m·K), 2.7 W/(m·K), 2.8 W/(m·K), 2.9 W/(m·K), 3 W/(m·K), 3.1 W/(m·K), 3.2 W/(m·K), 3.3 W/(m·K), 3.4 W/(m·K), 3.5 W/(m·K), 3.6 W/(m·K), 3.7 W/(m·K), 3.8 W/(m·K), 3.9 W/(m·K), 4 W/(m·K), 4.1 W/(m·K), 4.2 W/(m·K), 4.3 W/(m·K), 4.4 W/(m·K), 4.5 W/(m·K), 4.6 W/(m·K), 4.7 W/(m·K), 4.8 W/(m·K), 4.9 W/(m·K), 5 W/(m·K), 5.1 W/(m·K), 5.2 W/(m·K), 5.3 W/(m·K), 5.4 W/(m·K), 5.5 W/(m·K), 5.6 W/(m·K), 5.7 W/(m·K), 5.8 W/(m·K), 5.9 W/(m·K), 6 W/(m·K), 6.1 W/(m·K), 6.2 W/(m·K), 6.3 W/(m·K), 6.4 W/(m·K), 6.5 W/(m·K), 6.6 W/(m·K), 6.7 W/(m·K), 6.8 W/(m·K), 6.9 W/(m·K), 7 W/(m·K), 7.1 W/(m·K), 7.2 W/(m·K), 7.3 W/(m·K), 7.4 W/(m·K), 7.5 W/(m·K), 7.6 W/(m·K), 7.7 W/(m·K), 7.8 W/(m·K), 7.9 W/(m·K), 8 W/(m·K), 8.1 W/(m·K), 8.2 W/(m·K), 8.3 W/(m·K), 8.4 W/(m·K), 8.5 W/(m·K), 8.6 W/(m·K), 8.7 W/(m·K), 8.8 W/(m·K), 8.9 W/(m·K), 9 W/(m·K), 9.1 W/(m·K), 9.2 W/(m·K), 9.3 W/(m·K), 9.4 W/(m·K), 9.5 W/(m·K), 9.6 W/(m·K), 9.7 W/(m·K), 9.8 W/(m·K), 9.9 W/(m·K), 10 W/(m·K), 10.1 W/(m·K), 10.2 W/(m·K), 10.3 W/(m·K), 10.4 W/(m·K), 10.5 W/(m·K), 10.6 W/(m·K), 10.7 W/(m·K), 10.8 W/(m·K), 10.9 W/(m·K), 11 W/(m·K), 11.1 W/(m·K), 11.2 W/(m·K), 11.3 W/(m·K), 11.4 W/(m·K), 11.5 W/(m·K), 11.6 W/(m·K), 11.7 W/(m·K), 11.8 W/(m·K), 11.9 W/(m·K), 12 W/(m·K), 12.1 W/(m·K), 12.2 W/(m·K), 12.3 W/(m·K), 12.4 W/(m·K), 12.5 W/(m·K), 12.6 W/(m·K), 12.7 W/(m·K), 12.8 W/(m·K), 12.9 W/(m·K), 13 W/(m·K), 13.1 W/(m·K), 13.2 W/(m·K), 13.3 W/(m·K), 13.4 W/(m·K), 13.5 W/(m·K), 13.6 W/(m·K), 13.7 W/(m·K), 13.8 W/(m·K), 13.9 W/(m·K), 14 W/(m·K), 14.1 W/(m·K), 14.2 W/(m·K), 14.3 W/(m·K), 14.4 W/(m·K), 14.5 W/(m·K), 14.6 W/(m·K), 14.7 W/(m·K), 14.8 W/(m·K), 14.9 W/(m·K), 15 W/(m·K), 15.1 W/(m·K), 15.2 W/(m·K), 15.3 W/(m·K), 15.4 W/(m·K), 15.5 W/(m·K), 15.6 W/(m·K), 15.7 W/(m·K), 15.8 W/(m·K), 15.9 W/(m·K), 16 W/(m·K), 16.1 W/(m·K), 16.2 W/(m·K), 16.3 W/(m·K), 16.4 W/(m·K), 16.5 W/(m·K), 16.6 W/(m·K), 16.7 W/(m·K), 16.8 W/(m·K), 16.9 W/(m·K), 17 W/(m·K), 17.1 W/(m·K), 17.2 W/(m·K), 17.3 W/(m·K), 17.4 W/(m·K), 17.5 W/(m·K), 17.6 W/(m·K), 17.7 W/(m·K), 17.8 W/(m·K), 17.9 W/(m·K), 18 W/(m·K), 18.1 W/(m·K), 18.2 W/(m·K), 18.3 W/(m·K), 18.4 W/(m·K), 18.5 W/(m·K), 18.6 W/(m·K), 18.7 W/(m·K), 18.8 W/(m·K), 18.9 W/(m·K), 19 W/(m·K), 19.1 W/(m·K), 19.2 W/(m·K), 19.3 W/(m·K), 19.4 W/(m·K), 19.5 W/(m·K), 19.6 W/(m·K), 19.7 W/(m·K), 19.8 W/(m·K), 19.9 W/(m·K), 20 W/(m·K), 20.1 W/(m·K), 20.2 W/(m·K), 20.3 W/(m·K), 20.4 W/(m·K), 20.5 W/(m·K), 20.6 W/(m·K), 20.7 W/(m·K), 20.8 W/(m·K), 20.9 W/(m·K), 21 W/(m·K), 21.1 W/(m·K), 21.2 W/(m·K), 21.3 W/(m·K), 21.4 W/(m·K), 21.5 W/(m·K), 21.6 W/(m·K), 21.7 W/(m·K), 21.8 W/(m·K), 21.9 W/(m·K), 22 W/(m·K), 22.1 W/(m·K), 22.2 W/(m·K), 22.3 W/(m·K), 22.4 W/(m·K), 22.5 W/(m·K), 22.6 W/(m·K), 22.7 W/(m·K), 22.8 W/(m·K), 22.9 W/(m·K), 23 W/(m·K), 23.1 W/(m·K), 23.2 W/(m·K), 23.3 W/(m·K), 23.4 W/(m·K), 23.5 W/(m·K), 23.6 W/(m·K), 23.7 W/(m·K), 23.8 W/(m·K), 23.9 W/(m·K), 24 W/(m·K), 24.1 W/(m·K), 24.2 W/(m·K), 24.3 W/(m·K), 24.4 W/(m·K), 24.5 W/(m·K), 24.6 W/(m·K), 24.7 W/(m·K), 24.8 W/(m·K), 24.9 W/(m·K), 25 W/(m·K), 30 W/(m·K), 40 W/(m·K), 50 W/(m·K), 60 W/(m·K), 70 W/(m·K), 80 W/(m·K), 90 W/(m·K), 100 W/(m·K), 110 W/(m·K), 120 W/(m·K), 130 W/(m·K), 140 W/(m·K), 150 W/(m·K), 160 W/(m·K), 170 W/(m·K), 180 W/(m·K), 190 W/(m·K), 200 W/(m·K), 210 W/(m·K), 220 W/(m·K), 230 W/(m·K), 240 W/(m·K), 250 W/(m·K), 260 W/(m·K), 270 W/(m·K), 280 W/(m·K), 290 W/(m·K), 300 W/(m·K), 310 W/(m·K), 320 W/(m·K), 330 W/(m·K), 340 W/(m·K), 350 W/(m·K), 360 W/(m·K), 370 W/(m·K), 380 W/(m·K), 390 W/(m·K), 400 W/(m·K), 410 W/(m·K), 420 W/(m·K), 430 W/(m·K), 440 W/(m·K), or 450 W/(m·K).

According to one embodiment, the auxiliary layer is a polymeric auxiliary layer.

According to one embodiment, the one or more components of the auxiliary layer can include a polymerizable component, a crosslinking agent, a scattering agent, a rheology modifier, a filler, a photoinitiator, or a thermal initiator as described here after or above.

According to one embodiment, the auxiliary layer comprises scattering particles. Examples of scattering particles include but are not limited to: SiO₂, ZrO₂, ZnO, MgO, SnO₂, TiO₂, Ag, Au, alumina, barium sulfate, PTFE, barium titanate and the like.

In one embodiment, the auxiliary layer further comprises thermal conductor particles. Examples of thermal conductor particles include but are not limited to: SiO₂, ZrO₂, ZnO, MgO, SnO₂, TiO₂, CaO, alumina, barium sulfate, PTFE, barium titanate and the like. In this embodiment, the thermal conductivity of the auxiliary layer is increased.

According to one embodiment, the auxiliary layer comprises a polymeric host material 71 as described here above.

According to one embodiment, the auxiliary layer comprises an inorganic host material 71 as described here above.

In one embodiment, the auxiliary layer has a thickness between 30 nm and 1 cm, between 100 nm and 1 mm, preferably between 100 nm and 500 μm.

According to one embodiment, the auxiliary layer has a thickness of at least 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.1 μm, 4.2 μm, 4.3 μm, 4.4 μm, 4.5 μm, 4.6 μm, 4.7 μm, 4.8 μm, 4.9 μm, 5 μm, 5.1 μm, 5.2 μm, 5.3 μm, 5.4 μm, 5.5 μm, 5.5 μm, 5.6 μm, 5.7 μm, 5.8 μm, 5.9 μm, 6 μm, 6.5 μm, 7 μm, 7.5 μm, 8 μm, 8.5 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm or 1 cm.

According to one embodiment, the at least one aggregate 1 or the multilayered system comprising at least one aggregate 1 is covered by at least one protective layer. According to one embodiment, the at least one light emitting material 7 or the multilayered system comprising at least one light emitting material 7 is covered by at least one protective layer.

In one embodiment, the at least one aggregate 1 or the multilayered system comprising at least one aggregate 1 is surrounded by at least one protective layer. In one embodiment, the at least one light emitting material 7 or the multilayered system comprising at least one light emitting material 7 is surrounded by at least one protective layer.

In one embodiment, the at least one aggregate 1 or the multilayered system comprising at least one aggregate 1 is covered by at least one auxiliary layer, both being then surrounded by at least one protective layer. In one embodiment, the at least one light emitting material 7 or the multilayered system comprising at least one light emitting material 7 is covered by at least one auxiliary layer, both being then surrounded by at least one protective layer.

In one embodiment, the at least one aggregate 1 or the multilayered system comprising at least one aggregate 1 is covered at least one auxiliary layer and/or at least one protective layer. In one embodiment, the at least one light emitting material 7 or the multilayered system comprising at least one light emitting material 7 is covered at least one auxiliary layer and/or at least one protective layer.

In one embodiment, the protective layer is a planarization layer.

In one embodiment, the protective layer is an oxygen and/or water impermeable layer. In this embodiment, the protective layer is a barrier against oxidation, and limits or prevents the degradation of the chemical and physical properties of the at least one aggregates 1 and/or the at least one emitting material from oxygen and/or water.

In one embodiment, the protective layer is an oxygen and/or water non-permeable layer. In this embodiment, the protective layer is a barrier against oxidation, and limits or prevents the degradation of the chemical and physical properties of the at least one aggregates 1 and/or the at least one emitting material from oxygen and/or water.

According to one embodiment, the protective layer is thermally conductive.

According to one embodiment, the protective layer has a thermal conductivity at standard conditions ranging from 0.1 to 450 W/(m·K), preferably from 1 to 200 W/(m·K), more preferably from 10 to 150 W/(m·K).

According to one embodiment, the protective layer has a thermal conductivity at standard conditions of at least 0.1 W/(m·K), 0.2 W/(m·K), 0.3 W/(m·K), 0.4 W/(m·K), 0.5 W/(m·K), 0.6 W/(m·K), 0.7 W/(m·K), 0.8 W/(m·K), 0.9 W/(m·K), 1 W/(m·K), 1.1 W/(m·K), 1.2 W/(m·K), 1.3 W/(m·K), 1.4 W/(m·K), 1.5 W/(m·K), 1.6 W/(m·K), 1.7 W/(m·K), 1.8 W/(m·K), 1.9 W/(m·K), 2 W/(m·K), 2.1 W/(m·K), 2.2 W/(m·K), 2.3 W/(m·K), 2.4 W/(m·K), 2.5 W/(m·K), 2.6 W/(m·K), 2.7 W/(m·K), 2.8 W/(m·K), 2.9 W/(m·K), 3 W/(m·K), 3.1 W/(m·K), 3.2 W/(m·K), 3.3 W/(m·K), 3.4 W/(m·K), 3.5 W/(m·K), 3.6 W/(m·K), 3.7 W/(m·K), 3.8 W/(m·K), 3.9 W/(m·K), 4 W/(m·K), 4.1 W/(m·K), 4.2 W/(m·K), 4.3 W/(m·K), 4.4 W/(m·K), 4.5 W/(m·K), 4.6 W/(m·K), 4.7 W/(m·K), 4.8 W/(m·K), 4.9 W/(m·K), 5 W/(m·K), 5.1 W/(m·K), 5.2 W/(m·K), 5.3 W/(m·K), 5.4 W/(m·K), 5.5 W/(m·K), 5.6 W/(m·K), 5.7 W/(m·K), 5.8 W/(m·K), 5.9 W/(m·K), 6 W/(m·K), 6.1 W/(m·K), 6.2 W/(m·K), 6.3 W/(m·K), 6.4 W/(m·K), 6.5 W/(m·K), 6.6 W/(m·K), 6.7 W/(m·K), 6.8 W/(m·K), 6.9 W/(m·K), 7 W/(m·K), 7.1 W/(m·K), 7.2 W/(m·K), 7.3 W/(m·K), 7.4 W/(m·K), 7.5 W/(m·K), 7.6 W/(m·K), 7.7 W/(m·K), 7.8 W/(m·K), 7.9 W/(m·K), 8 W/(m·K), 8.1 W/(m·K), 8.2 W/(m·K), 8.3 W/(m·K), 8.4 W/(m·K), 8.5 W/(m·K), 8.6 W/(m·K), 8.7 W/(m·K), 8.8 W/(m·K), 8.9 W/(m·K), 9 W/(m·K), 9.1 W/(m·K), 9.2 W/(m·K), 9.3 W/(m·K), 9.4 W/(m·K), 9.5 W/(m·K), 9.6 W/(m·K), 9.7 W/(m·K), 9.8 W/(m·K), 9.9 W/(m·K), 10 W/(m·K), 10.1 W/(m·K), 10.2 W/(m·K), 10.3 W/(m·K), 10.4 W/(m·K), 10.5 W/(m·K), 10.6 W/(m·K), 10.7 W/(m·K), 10.8 W/(m·K), 10.9 W/(m·K), 11 W/(m·K), 11.1 W/(m·K), 11.2 W/(m·K), 11.3 W/(m·K), 11.4 W/(m·K), 11.5 W/(m·K), 11.6 W/(m·K), 11.7 W/(m·K), 11.8 W/(m·K), 11.9 W/(m·K), 12 W/(m·K), 12.1 W/(m·K), 12.2 W/(m·K), 12.3 W/(m·K), 12.4 W/(m·K), 12.5 W/(m·K), 12.6 W/(m·K), 12.7 W/(m·K), 12.8 W/(m·K), 12.9 W/(m·K), 13 W/(m·K), 13.1 W/(m·K), 13.2 W/(m·K), 13.3 W/(m·K), 13.4 W/(m·K), 13.5 W/(m·K), 13.6 W/(m·K), 13.7 W/(m·K), 13.8 W/(m·K), 13.9 W/(m·K), 14 W/(m·K), 14.1 W/(m·K), 14.2 W/(m·K), 14.3 W/(m·K), 14.4 W/(m·K), 14.5 W/(m·K), 14.6 W/(m·K), 14.7 W/(m·K), 14.8 W/(m·K), 14.9 W/(m·K), 15 W/(m·K), 15.1 W/(m·K), 15.2 W/(m·K), 15.3 W/(m·K), 15.4 W/(m·K), 15.5 W/(m·K), 15.6 W/(m·K), 15.7 W/(m·K), 15.8 W/(m·K), 15.9 W/(m·K), 16 W/(m·K), 16.1 W/(m·K), 16.2 W/(m·K), 16.3 W/(m·K), 16.4 W/(m·K), 16.5 W/(m·K), 16.6 W/(m·K), 16.7 W/(m·K), 16.8 W/(m·K), 16.9 W/(m·K), 17 W/(m·K), 17.1 W/(m·K), 17.2 W/(m·K), 17.3 W/(m·K), 17.4 W/(m·K), 17.5 W/(m·K), 17.6 W/(m·K), 17.7 W/(m·K), 17.8 W/(m·K), 17.9 W/(m·K), 18 W/(m·K), 18.1 W/(m·K), 18.2 W/(m·K), 18.3 W/(m·K), 18.4 W/(m·K), 18.5 W/(m·K), 18.6 W/(m·K), 18.7 W/(m·K), 18.8 W/(m·K), 18.9 W/(m·K), 19 W/(m·K), 19.1 W/(m·K), 19.2 W/(m·K), 19.3 W/(m·K), 19.4 W/(m·K), 19.5 W/(m·K), 19.6 W/(m·K), 19.7 W/(m·K), 19.8 W/(m·K), 19.9 W/(m·K), 20 W/(m·K), 20.1 W/(m·K), 20.2 W/(m·K), 20.3 W/(m·K), 20.4 W/(m·K), 20.5 W/(m·K), 20.6 W/(m·K), 20.7 W/(m·K), 20.8 W/(m·K), 20.9 W/(m·K), 21 W/(m·K), 21.1 W/(m·K), 21.2 W/(m·K), 21.3 W/(m·K), 21.4 W/(m·K), 21.5 W/(m·K), 21.6 W/(m·K), 21.7 W/(m·K), 21.8 W/(m·K), 21.9 W/(m·K), 22 W/(m·K), 22.1 W/(m·K), 22.2 W/(m·K), 22.3 W/(m·K), 22.4 W/(m·K), 22.5 W/(m·K), 22.6 W/(m·K), 22.7 W/(m·K), 22.8 W/(m·K), 22.9 W/(m·K), 23 W/(m·K), 23.1 W/(m·K), 23.2 W/(m·K), 23.3 W/(m·K), 23.4 W/(m·K), 23.5 W/(m·K), 23.6 W/(m·K), 23.7 W/(m·K), 23.8 W/(m·K), 23.9 W/(m·K), 24 W/(m·K), 24.1 W/(m·K), 24.2 W/(m·K), 24.3 W/(m·K), 24.4 W/(m·K), 24.5 W/(m·K), 24.6 W/(m·K), 24.7 W/(m·K), 24.8 W/(m·K), 24.9 W/(m·K), 25 W/(m·K), 30 W/(m·K), 40 W/(m·K), 50 W/(m·K), 60 W/(m·K), 70 W/(m·K), 80 W/(m·K), 90 W/(m·K), 100 W/(m·K), 110 W/(m·K), 120 W/(m·K), 130 W/(m·K), 140 W/(m·K), 150 W/(m·K), 160 W/(m·K), 170 W/(m·K), 180 W/(m·K), 190 W/(m·K), 200 W/(m·K), 210 W/(m·K), 220 W/(m·K), 230 W/(m·K), 240 W/(m·K), 250 W/(m·K), 260 W/(m·K), 270 W/(m·K), 280 W/(m·K), 290 W/(m·K), 300 W/(m·K), 310 W/(m·K), 320 W/(m·K), 330 W/(m·K), 340 W/(m·K), 350 W/(m·K), 360 W/(m·K), 370 W/(m·K), 380 W/(m·K), 390 W/(m·K), 400 W/(m·K), 410 W/(m·K), 420 W/(m·K), 430 W/(m·K), 440 W/(m·K), or 450 W/(m·K).

In one embodiment, the protective layer can be made of glass, PET (Polyethylene terephthalate), PDMS (Polydimethylsiloxane), PES (Polyethersulfone), PEN (Polyethylene naphthalate), PC (Polycarbonate), PI (Polyimide), PNB (Polynorbornene), PAR (Polyarylate), PEEK (Polyetheretherketone), PCO (Polycyclic olefins), PVDC (Polyvinylidene chloride), Nylon, ITO (Indium tin oxide), FTO (Fluorine doped tin oxide), cellulose, Al₂O₃, AlOₓN_{y}, SiOₓC_{y}, SiO₂, SiOₓ, SiNₓ, SiCₓ, ZrO₂, TiO₂, MgO, ZnO, SnO₂, ceramic, organic modified ceramic, or mixture thereof.

In one embodiment, the protective layer can be deposited by PECVD (Plasma Enhanced Chemical Vapor Deposition), ALD (Atomic Layer Deposition), CVD (Chemical Vapor Deposition), iCVD (Initiator Chemical Vapor Deposition), Cat-CVD (Catalytic Chemical Vapor Deposition).

According to one embodiment, the protective layer may comprise scattering particles. Examples of scattering particles include but are not limited to: SiO₂, ZrO₂, ZnO, MgO, SnO₂, TiO₂, Ag, Au, alumina, barium sulfate, PTFE, barium titanate and the like.

In one embodiment, the protective layer further comprises thermal conductor particles. Examples of thermal conductor particles include but are not limited to: SiO₂, ZrO₂, ZnO, MgO, SnO₂, TiO₂, CaO, alumina, barium sulfate, PTFE, barium titanate and the like. In this embodiment, the thermal conductivity of the protective layer is increased.

In one embodiment, the support can be a substrate, a LED, a LED array, a vessel, a tube, a solar panel, a panel, or a container. Preferably the support is optically transparent at wavelengths between 200 nm and 50 μm, between 200 nm and 10 μm, between 200 nm and 2500 nm, between 200 nm and 2000 nm, between 200 nm and 1500 nm, between 200 nm and 1000 nm, between 200 nm and 800 nm, between 400 nm and 700 nm, between 400 nm and 600 nm, or between 400 nm and 470 nm.

LED used herein includes LED, LED chip 5 and microsized LED 6.

According to one embodiment, the support is a solar panel, or a panel.

In one embodiment, the support can be a fabric, a piece of clothes, wood, plastic, ceramic, glass, steel, metal, or any active surfaces.

In one embodiment, active surfaces are interactive surfaces.

In one embodiment, active surfaces are surfaces destined to be included in an optoelectronic device, or a display device.

In one embodiment, the support is reflective.

In one embodiment, the support comprises a material allowing to reflect the light such as for example a metal like aluminium, silver, a glass, a polymer or a plastic.

In one embodiment, the support is thermally conductive.

According to one embodiment, the support has a thermal conductivity at standard conditions ranging from 0.5 to 450 W/(m·K), preferably from 1 to 200 W/(m·K), more preferably from 10 to 150 W/(m·K).

According to one embodiment, the support has a thermal conductivity at standard conditions of at least 0.1 W/(m·K), 0.2 W/(m·K), 0.3 W/(m·K), 0.4 W/(m·K), 0.5 W/(m·K), 0.6 W/(m·K), 0.7 W/(m·K), 0.8 W/(m·K), 0.9 W/(m·K), 1 W/(m·K), 1.1 W/(m·K), 1.2 W/(m·K), 1.3 W/(m·K), 1.4 W/(m·K), 1.5 W/(m·K), 1.6 W/(m·K), 1.7 W/(m·K), 1.8 W/(m·K), 1.9 W/(m·K), 2 W/(m·K), 2.1 W/(m·K), 2.2 W/(m·K), 2.3 W/(m·K), 2.4 W/(m·K), 2.5 W/(m·K), 2.6 W/(m·K), 2.7 W/(m·K), 2.8 W/(m·K), 2.9 W/(m·K), 3 W/(m·K), 3.1 W/(m·K), 3.2 W/(m·K), 3.3 W/(m·K), 3.4 W/(m·K), 3.5 W/(m·K), 3.6 W/(m·K), 3.7 W/(m·K), 3.8 W/(m·K), 3.9 W/(m·K), 4 W/(m·K), 4.1 W/(m·K), 4.2 W/(m·K), 4.3 W/(m·K), 4.4 W/(m·K), 4.5 W/(m·K), 4.6 W/(m·K), 4.7 W/(m·K), 4.8 W/(m·K), 4.9 W/(m·K), 5 W/(m·K), 5.1 W/(m·K), 5.2 W/(m·K), 5.3 W/(m·K), 5.4 W/(m·K), 5.5 W/(m·K), 5.6 W/(m·K), 5.7 W/(m·K), 5.8 W/(m·K), 5.9 W/(m·K), 6 W/(m·K), 6.1 W/(m·K), 6.2 W/(m·K), 6.3 W/(m·K), 6.4 W/(m·K), 6.5 W/(m·K), 6.6 W/(m·K), 6.7 W/(m·K), 6.8 W/(m·K), 6.9 W/(m·K), 7 W/(m·K), 7.1 W/(m·K), 7.2 W/(m·K), 7.3 W/(m·K), 7.4 W/(m·K), 7.5 W/(m·K), 7.6 W/(m·K), 7.7 W/(m·K), 7.8 W/(m·K), 7.9 W/(m·K), 8 W/(m·K), 8.1 W/(m·K), 8.2 W/(m·K), 8.3 W/(m·K), 8.4 W/(m·K), 8.5 W/(m·K), 8.6 W/(m·K), 8.7 W/(m·K), 8.8 W/(m·K), 8.9 W/(m·K), 9 W/(m·K), 9.1 W/(m·K), 9.2 W/(m·K), 9.3 W/(m·K), 9.4 W/(m·K), 9.5 W/(m·K), 9.6 W/(m·K), 9.7 W/(m·K), 9.8 W/(m·K), 9.9 W/(m·K), 10 W/(m·K), 10.1 W/(m·K), 10.2 W/(m·K), 10.3 W/(m·K), 10.4 W/(m·K), 10.5 W/(m·K), 10.6 W/(m·K), 10.7 W/(m·K), 10.8 W/(m·K), 10.9 W/(m·K), 11 W/(m·K), 11.1 W/(m·K), 11.2 W/(m·K), 11.3 W/(m·K), 11.4 W/(m·K), 11.5 W/(m·K), 11.6 W/(m·K), 11.7 W/(m·K), 11.8 W/(m·K), 11.9 W/(m·K), 12 W/(m·K), 12.1 W/(m·K), 12.2 W/(m·K), 12.3 W/(m·K), 12.4 W/(m·K), 12.5 W/(m·K), 12.6 W/(m·K), 12.7 W/(m·K), 12.8 W/(m·K), 12.9 W/(m·K), 13 W/(m·K), 13.1 W/(m·K), 13.2 W/(m·K), 13.3 W/(m·K), 13.4 W/(m·K), 13.5 W/(m·K), 13.6 W/(m·K), 13.7 W/(m·K), 13.8 W/(m·K), 13.9 W/(m·K), 14 W/(m·K), 14.1 W/(m·K), 14.2 W/(m·K), 14.3 W/(m·K), 14.4 W/(m·K), 14.5 W/(m·K), 14.6 W/(m·K), 14.7 W/(m·K), 14.8 W/(m·K), 14.9 W/(m·K), 15 W/(m·K), 15.1 W/(m·K), 15.2 W/(m·K), 15.3 W/(m·K), 15.4 W/(m·K), 15.5 W/(m·K), 15.6 W/(m·K), 15.7 W/(m·K), 15.8 W/(m·K), 15.9 W/(m·K), 16 W/(m·K), 16.1 W/(m·K), 16.2 W/(m·K), 16.3 W/(m·K), 16.4 W/(m·K), 16.5 W/(m·K), 16.6 W/(m·K), 16.7 W/(m·K), 16.8 W/(m·K), 16.9 W/(m·K), 17 W/(m·K), 17.1 W/(m·K), 17.2 W/(m·K), 17.3 W/(m·K), 17.4 W/(m·K), 17.5 W/(m·K), 17.6 W/(m·K), 17.7 W/(m·K), 17.8 W/(m·K), 17.9 W/(m·K), 18 W/(m·K), 18.1 W/(m·K), 18.2 W/(m·K), 18.3 W/(m·K), 18.4 W/(m·K), 18.5 W/(m·K), 18.6 W/(m·K), 18.7 W/(m·K), 18.8 W/(m·K), 18.9 W/(m·K), 19 W/(m·K), 19.1 W/(m·K), 19.2 W/(m·K), 19.3 W/(m·K), 19.4 W/(m·K), 19.5 W/(m·K), 19.6 W/(m·K), 19.7 W/(m·K), 19.8 W/(m·K), 19.9 W/(m·K), 20 W/(m·K), 20.1 W/(m·K), 20.2 W/(m·K), 20.3 W/(m·K), 20.4 W/(m·K), 20.5 W/(m·K), 20.6 W/(m·K), 20.7 W/(m·K), 20.8 W/(m·K), 20.9 W/(m·K), 21 W/(m·K), 21.1 W/(m·K), 21.2 W/(m·K), 21.3 W/(m·K), 21.4 W/(m·K), 21.5 W/(m·K), 21.6 W/(m·K), 21.7 W/(m·K), 21.8 W/(m·K), 21.9 W/(m·K), 22 W/(m·K), 22.1 W/(m·K), 22.2 W/(m·K), 22.3 W/(m·K), 22.4 W/(m·K), 22.5 W/(m·K), 22.6 W/(m·K), 22.7 W/(m·K), 22.8 W/(m·K), 22.9 W/(m·K), 23 W/(m·K), 23.1 W/(m·K), 23.2 W/(m·K), 23.3 W/(m·K), 23.4 W/(m·K), 23.5 W/(m·K), 23.6 W/(m·K), 23.7 W/(m·K), 23.8 W/(m·K), 23.9 W/(m·K), 24 W/(m·K), 24.1 W/(m·K), 24.2 W/(m·K), 24.3 W/(m·K), 24.4 W/(m·K), 24.5 W/(m·K), 24.6 W/(m·K), 24.7 W/(m·K), 24.8 W/(m·K), 24.9 W/(m·K), 25 W/(m·K), 30 W/(m·K), 40 W/(m·K), 50 W/(m·K), 60 W/(m·K), 70 W/(m·K), 80 W/(m·K), 90 W/(m·K), 100 W/(m·K), 110 W/(m·K), 120 W/(m·K), 130 W/(m·K), 140 W/(m·K), 150 W/(m·K), 160 W/(m·K), 170 W/(m·K), 180 W/(m·K), 190 W/(m·K), 200 W/(m·K), 210 W/(m·K), 220 W/(m·K), 230 W/(m·K), 240 W/(m·K), 250 W/(m·K), 260 W/(m·K), 270 W/(m·K), 280 W/(m·K), 290 W/(m·K), 300 W/(m·K), 310 W/(m·K), 320 W/(m·K), 330 W/(m·K), 340 W/(m·K), 350 W/(m·K), 360 W/(m·K), 370 W/(m·K), 380 W/(m·K), 390 W/(m·K), 400 W/(m·K), 410 W/(m·K), 420 W/(m·K), 430 W/(m·K), 440 W/(m·K), or 450 W/(m·K).

According to one embodiment, the substrate comprises GaN, GaSb, GaAs, GaAsP, GaP, InP, SiGe, InGaN, GaAlN, GaAlPN, AlN, AlGaAs, AlGaP, AlGaInP, AlGaN, AlGaInN, ZnSe, Si, SiC, diamond, boron nitride.

According to one embodiment, the substrate comprises Au, Ag, Pt, Ru, Ni, Co, Cr, Cu, Sn, Rh Pd, Mn, Ti or a mixture thereof.

According to one embodiment, the substrate comprises silicon oxide, aluminium oxide, titanium oxide, copper oxide, iron oxide, silver oxide, lead oxide, calcium oxide, magnesium oxide, zinc oxide, tin oxide, beryllium oxide, zirconium oxide, niobium oxide, cerium oxide, iridium oxide, scandium oxide, nickel oxide, sodium oxide, barium oxide, potassium oxide, vanadium oxide, tellurium oxide, manganese oxide, boron oxide, phosphorus oxide, germanium oxide, osmium oxide, rhenium oxide, platinum oxide, arsenic oxide, tantalum oxide, lithium oxide, strontium oxide, yttrium oxide, hafnium oxide, tungsten oxide, molybdenum oxide, chromium oxide, technetium oxide, rhodium oxide, ruthenium oxide, cobalt oxide, palladium oxide, cadmium oxide, mercury oxide, thallium oxide, gallium oxide, indium oxide, bismuth oxide, antimony oxide, polonium oxide, selenium oxide, cesium oxide, lanthanum oxide, praseodymium oxide, neodymium oxide, samarium oxide, europium oxide, terbium oxide, dysprosium oxide, erbium oxide, holmium oxide, thulium oxide, ytterbium oxide, lutetium oxide, gadolinium oxide, mixed oxides, mixed oxides thereof or a mixture thereof.

Another object of the invention relates to an optoelectronic device comprising at least one metastable aggregate 1 of the invention and/or at least one light emitting material 7 as described here above.

According to one embodiment, the optoelectronic device is a display device, a diode, a light emitting diode (LED), a laser, a photodetector, a transistor, a supercapacitor, a barcode, a LED, a microLED, an array of LED, an array of microLED, or an IR camera.

LED used herein includes LED, LED chip 5 and microsized LED 6.

According to one embodiment, the optoelectronic device comprises at least one LED and at least one aggregate 1 and/or at least one light emitting material 7 as described here above.

According to one embodiment, a pixel comprises at least one LED.

According to one embodiment, a pixel comprises at least 1, 2, 3, 4, 5, 10, 20, 30, 40, 50, 60, 70, 80, 90, 100, 500, 1000, 5000, 10000, 50000, 100000, 150000, 200000, 250000, 300000, 350000, 400000, 450000, 500000, 550000, 600000, 650000, 750000, 800000, 850000, 900000, 950000, 10⁶, 10⁷, 10⁸, 10⁹, 10¹⁰, 10¹¹, or 10¹² LEDs.

According to one embodiment, the at least one aggregate 1 or the at least one light emitting material 7 is on top of a LED chip 5 or a microsized LED 6.

According to one embodiment, the at least one aggregate 1 or the at least one light emitting material 7 is on top of at least one LED of a LED array or a microsized LED 6 array.

According to one embodiment, the at least one aggregate 1 or the at least one light emitting material 7 is deposited and patterned on top of at least one LED of a LED array or a microsized LED 6 array.

According to one embodiment, the at least one aggregate 1 or the at least one light emitting material 7 is deposited and patterned on top of a LED, at least one LED of a LED array, a microsized LED 6 or at least one LED of a microsized LED 6 array using a lift-off technique, lithography, or a direct etching of the at least one aggregate 1 or the at least one light emitting material 7.

In one embodiment, the at least one aggregate 1 covers the LED chip 5.

In one embodiment, the at least one aggregate 1 covers and surrounds partially or totally the LED chip 5.

In one embodiment as illustrated in FIG. 10A, the at least one light emitting material 7 as described above covers the LED chip 5.

In one embodiment as illustrated in FIG. 10B, the at least one light emitting material 7 as described above covers and surrounds partially or totally the LED chip 5.

In one embodiment, as illustrated in FIG. 12A, the at least one aggregate 1 or the at least one light emitting material 7 covers a pixel of a microsized LED 6 array without overlapping between the pixels of said microsized LED 6 array.

In one embodiment, the at least one aggregate 1 or the at least one light emitting material 7 covers partially a pixel of a microsized LED 6 array without overlapping between the pixels of said microsized LED 6 array.

In one embodiment, as illustrated in FIG. 12B, the at least one aggregate 1 or the at least one light emitting material 7 covers and surrounds partially or totally a pixel of a microsized LED 6 array without overlapping between the pixels of said microsized LED 6 array.

In one embodiment, the at least one aggregate 1 or the at least one light emitting material 7 covers a microsized LED 6 array without overlapping between the pixels of said microsized LED 6 array.

In one embodiment, the at least one aggregate 1 or the at least one light emitting material 7 covers partially a microsized LED 6 array without overlapping between the pixels of said microsized LED 6 array.

In one embodiment, the at least one aggregate 1 or the at least one light emitting material 7 covers and surrounds partially or totally a microsized LED 6 array without overlapping between the pixels of said microsized LED 6 array.

In one embodiment, one population of aggregates 1 is deposited on a microsized LED 6 array. In one embodiment, a population of aggregates 1 is defined by the maximum emission wavelength.

In one embodiment, at least one population of aggregates 1 is deposited on a pixel of a microsized LED 6 array.

In one embodiment, aggregates 1 and/or light emitting material 7 as described here is deposited on a pixel, a microsized LED, a LED, or an array of LEDs by drop-casting, spin coating, dip coating, inkjet printing, lithography, spray, plating, electroplating, or any other means known by the person skilled in the art.

In one embodiment, two populations of aggregates 1 emitting different colors or wavelengths are deposited on a microsized LED 6 array.

In one embodiment, two populations of aggregates 1 which emit green light and red light upon downconversion of a blue light source are deposited on a microsized LED 6 array.

In one embodiment, the two populations of aggregates 1 comprise a first population with a maximum emission wavelength between 500 nm and 560 nm, more preferably between 515 nm and 545 nm and a second population with a maximum emission wavelength between 600 nm and 2500 nm, more preferably between 610 nm and 650 nm.

In one embodiment, a light emitting material 7 as described here above comprising one population of aggregates 1 is deposited on a microsized LED 6 array.

In one embodiment, a light emitting material 7 as described here above comprising at least one population of aggregates 1 is deposited a microsized LED 6 array.

In one embodiment, a light emitting material 7 as described here above comprising two populations of aggregates 1 emitting different colors or wavelengths is deposited on a microsized LED 6 array.

In one embodiment, the light emitting material 7 comprises two populations of aggregates 1, a first population with a maximum emission wavelength between 500 nm and 560 nm, more preferably between 515 nm and 545 nm and a second population with a maximum emission wavelength between 600 nm and 2500 nm, more preferably between 610 nm and 650 nm.

In one embodiment, two light emitting materials 7 as described here above each comprising one population of aggregates 1 emitting different colors or wavelengths are deposited on a microsized LED 6 array.

In one embodiment, the two light emitting materials 7 each comprise one population of aggregates 1, a first population with a maximum emission wavelength between 500 nm and 560 nm, more preferably between 515 nm and 545 nm and a second population with a maximum emission wavelength between 600 nm and 2500 nm, more preferably between 610 nm and 650 nm.

According to one embodiment, the primary light is a blue light with an emission wavelength ranging from 400 nm to 470 nm, preferably at about 450 nm.

According to one embodiment, the primary light is a UV light with an emission wavelength ranging from 200 nm to 400 nm, preferably at about 390 nm.

In one embodiment, the LED chip 5 or the microsized LED 6 is a blue LED with a wavelength ranging from 400 nm to 470 nm such as for instance a gallium nitride based diode.

In one embodiment, the LED chip 5 or the microsized LED 6 is a blue LED with a wavelength ranging from 400 nm to 470 nm. In one embodiment, the LED chip 5 or the microsized LED 6 has an emission peak at about 405 nm. In one embodiment, the LED chip 5 or the microsized LED 6 has an emission peak at about 447 nm. In one embodiment, the LED chip 5 or the microsized LED 6 has an emission peak at about 455 nm.

In one embodiment, the LED chip 5 or the microsized LED 6 is a UV LED with a wavelength ranging from 200 nm to 400 nm. In one embodiment, the LED chip 5 or the microsized LED 6 has an emission peak at about 253 nm. In one embodiment, the LED chip 5 or the microsized LED 6 has an emission peak at about 365 nm. In one embodiment, the LED chip 5 or the microsized LED 6 has an emission peak at about 395 nm.

In one embodiment, the LED chip 5 or the microsized LED 6 is a green LED with a wavelength ranging from 500 nm to 560 nm. In one embodiment, the LED chip 5 or the microsized LED 6 has an emission peak at about 515 nm. In one embodiment, the LED chip 5 or the microsized LED 6 has an emission peak at about 525 nm. In one embodiment, the LED chip 5 or the microsized LED 6 has an emission peak at about 540 nm.

In one embodiment, the LED chip 5 or the microsized LED 6 is a red LED with a wavelength ranging from 750 to 850 nm. In one embodiment, the LED chip 5 or the microsized LED 6 has an emission peak at about 755 nm. In one embodiment, the LED chip 5 or the microsized LED 6 has an emission peak at about 800 nm. In one embodiment, the LED chip 5 or the microsized LED 6 has an emission peak at about 850 nm.

In one embodiment, the LED chip 5 or the microsized LED 6 has a photon flux or average peak pulse power between 1 μW·cm⁻² and 1 kW·cm⁻² and more preferably between 1 mW·cm⁻² and 100 W·cm⁻², and even more preferably between 1 mW·cm⁻² and 30 W·cm⁻².

In one embodiment, the LED chip 5 or the microsized LED 6 has a photon flux or average peak pulse power of at least 1 μW·cm⁻², 10 μW·cm⁻², 100 μW·cm⁻², 500 μW·cm⁻², 1 mW·cm⁻², 10 mW·cm⁻², 100 mW·cm⁻², 500 mW·cm⁻², 1 W·cm⁻², 10 W·cm⁻², 100 W·cm⁻², 500 W·cm⁻², or 1 kW·cm⁻².

In one embodiment, the LED chip 5 is a GaN, GaSb, GaAs, GaAsP, GaP, InP, SiGe, InGaN, GaAlN, GaAlPN, AlN, AlGaAs, AlGaP, AlGaInP, AlGaN, AlGaInN, ZnSe, Si, SiC, diamond, boron nitride diode.

In one embodiment, the microsized LED 6 is a GaN, GaSb, GaAs, GaAsP, GaP, InP, SiGe, InGaN, GaAlN, GaAlPN, AlN, AlGaAs, AlGaP, AlGaInP, AlGaN, AlGaInN, ZnSe, Si, SiC, diamond, boron nitride diode.

In one embodiment, a LED array comprises an array of GaN diodes, GaSb diodes, GaAs diodes, GaAsP diodes, GaP diodes, InP diodes, SiGe diodes, InGaN diodes, GaAlN diodes, GaAlPN diodes, AlN diodes, AlGaAs diodes, AlGaP diodes, AlGaInP diodes, AlGaN diodes, AlGaInN diodes, ZnSe diodes, Si diodes, SiC diodes, diamond diodes, boron nitride diodes or a mixture thereof.

According to one embodiment, a pixel comprises at least one microsized LED 6.

According to one embodiment, at least one pixel comprises a unique microsized LED 6.

According to one embodiment, at least one pixel comprises one microsized LED 6. In this embodiment, the microsized LED 6 and the one pixel are combined.

According to one embodiment, as illustrated in FIG. 11, the pixel pitch D is at least 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, 30 μm, 31 μm, 32 μm, 33 μm, 34 μm, 35 μm, 36 μm, 37 μm, 38 μm, 39 μm, 40 μm, 41 μm, 42 μm, 43 μm, 44 μm, 45 μm, 46 μm, 47 μm, 48 μm, 49 μm, 50 μm, 51 μm, 52 μm, 53 μm, 54 μm, 55 μm, 56 μm, 57 μm, 58 μm, 59 μm, 60 μm, 61 μm, 62 μm, 63 μm, 64 μm, 65 μm, 66 μm, 67 μm, 68 μm, 69 μm, 70 μm, 71 μm, 72 μm, 73 μm, 74 μm, 75 μm, 76 μm, 77 μm, 78 μm, 79 μm, 80 μm, 81 μm, 82 μm, 83 μm, 84 μm, 85 μm, 86 μm, 87 μm, 88 μm, 89 μm, 90 μm, 91 μm, 92 μm, 93 μm, 94 μm, 95 μm, 96 μm, 97 μm, 98 μm, 99 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, 1 mm, 1.1 mm, 1.2 mm, 1 3 mm, 1.4 mm, 1.5 mm, 1 6 mm, 1.7 mm, 1 8 mm, 1.9 mm, 2 mm, 2.1 mm, 2.2 mm, 2.3 mm, 2.4 mm, 2 5 mm, 2 6 mm, 2.7 mm, 2.8 mm, 2 9 mm, 3 mm, 3 1 mm, 3.2 mm, 3.3 mm, 3.4 mm, 3.5 mm, 3.6 mm, 3.7 mm, 38 mm, 39 mm, 4 mm, 4 1 mm, 4 2 mm, 4.3 mm, 4.4 mm, 4.5 mm, 4.6 mm, 4.7 mm, 4.8 mm, 4 9 mm, 5 mm, 5 1 mm, 5.2 mm, 5.3 mm, 5.4 mm, 5.5 mm, 5.6 mm, 5 7 mm, 5.8 mm, 5.9 mm, 6 mm, 6 1 mm, 6.2 mm, 6.3 mm, 6 4 mm, 6.5 mm, 6 6 mm, 6.7 mm, 6 8 mm, 6.9 mm, 7 mm, 7.1 mm, 7 2 mm, 7.3 mm, 7.4 mm, 7 5 mm, 7.6 mm, 7.7 mm, 7.8 mm, 7 9 mm, 8 mm, 8.1 mm, 8 2 mm, 8 3 mm, 8 4 mm, 8.5 mm, 8.6 mm, 8.7 mm, 8.8 mm, 8.9 mm, 9 mm, 9.1 mm, 9.2 mm, 9 3 mm, 9 4 mm, 9 5 mm, 9.6 mm, 9.7 mm, 9.8 mm, 9.9 mm, 1 cm, 1.1 cm, 1.2 cm, 1.3 cm, 1.4 cm, 1.5 cm, 1.6 cm, 1.7 cm, 1.8 cm, 1.9 cm, 2 cm, 2.1 cm, 2.2 cm, 2.3 cm, 2.4 cm, 2.5 cm, 2.6 cm, 2.7 cm, 2.8 cm, 2.9 cm, 3 cm, 3.1 cm, 3.2 cm, 3.3 cm, 3.4 cm, 3.5 cm, 3.6 cm, 3.7 cm, 3.8 cm, 3.9 cm, 4 cm, 4.1 cm, 4.2 cm, 4.3 cm, 4.4 cm, 4.5 cm, 4.6 cm, 4.7 cm, 4.8 cm, 4.9 cm, 5 cm, 5.1 cm, 5.2 cm, 5.3 cm, 5.4 cm, 5.5 cm, 5.6 cm, 5.7 cm, 5.8 cm, 5.9 cm, 6 cm, 6.1 cm, 6.2 cm, 6.3 cm, 6.4 cm, 6.5 cm, 6.6 cm, 6.7 cm, 6.8 cm, 6.9 cm, 7 cm, 7.1 cm, 7.2 cm, 7.3 cm, 7.4 cm, 7.5 cm, 7.6 cm, 7.7 cm, 7.8 cm, 7.9 cm, 8 cm, 8.1 cm, 8.2 cm, 8.3 cm, 8.4 cm, 8.5 cm, 8.6 cm, 8.7 cm, 8.8 cm, 8.9 cm, 9 cm, 9.1 cm, 9.2 cm, 9.3 cm, 9.4 cm, 9.5 cm, 9.6 cm, 9.7 cm, 9.8 cm, 9.9 cm, or 10 cm.

According to one embodiment, the pixel pitch D is smaller than 10 μm.

According to one embodiment, the pixel size is at least 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, 30 μm, 31 μm, 32 μm, 33 μm, 34 μm, 35 μm, 36 μm, 37 μm, 38 μm, 39 μm, 40 μm, 41 μm, 42 μm, 43 μm, 44 μm, 45 Inn, 46 μm, 47 μm, 48 μm, 49 μm, 50 μm, 51 μm, 52 μm, 53 μm, 54 μm, 55 μm, 56 μm, 57 μm, 58 μm, 59 μm, 60 μm, 61 μm, 62 63 μm, 64 μm, 65 μm, 66 μm, 67 μm, 68 μm, 69 μm, 70 μm, 71 μm, 72 μm, 73 μm, 74 μm, 75 μm, 76 μm, 77 μm, 78 μm, 79 μm, 80 μm, 81 μm, 82 μm, 83 μm, 84 μm, 85 μm, 86 μm, 87 μm, 88 μm, 89 μm, 90 μm, 91 92 μm, 93 μm, 94 μm, 95 μm, 96 μm, 97 μm, 98 μm, 99 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, 1 mm, 1.1 mm, 1.2 mm, 1.3 mm, 1.4 mm, 1.5 mm, 1.6 mm, 1.7 mm, 1.8 mm, 1.9 mm, 2 mm, 2.1 mm, 2.2 mm, 2.3 mm, 2.4 mm, 2.5 mm, 2.6 mm, 2.7 mm, 2.8 mm, 2.9 mm, 3 mm, 3.1 mm, 3.2 mm, 3.3 mm, 3.4 mm, 3.5 mm, 3.6 mm, 3.7 mm, 38 mm, 39 mm, 4 mm, 4.1 mm, 4.2 mm, 4.3 mm, 4.4 mm, 4.5 mm, 4.6 mm, 4.7 mm, 4.8 mm, 4 9 mm, 5 mm, 5.1 mm, 5.2 mm, 5.3 mm, 5.4 mm, 5.5 mm, 5.6 mm, 5.7 mm, 5 8 mm, 5.9 mm, 6 mm, 6.1 mm, 6.2 mm, 6.3 mm, 6.4 mm, 6.5 mm, 6.6 mm, 6.7 mm, 6.8 mm, 6.9 mm, 7 mm, 7.1 mm, 7.2 mm, 7.3 mm, 7.4 mm, 7.5 mm, 7.6 mm, 7.7 mm, 7.8 mm, 7.9 mm, 8 mm, 8.1 mm, 8.2 mm, 8.3 mm, 8.4 mm, 8.5 mm, 8.6 mm, 8.7 mm, 8.8 mm, 8.9 mm, 9 mm, 9.1 mm, 9.2 mm, 9.3 mm, 9.4 mm, 9.5 mm, 9 6 mm, 9 7 mm, 9.8 mm, 9.9 mm, 1 cm, 1.1 cm, 1.2 cm, 1.3 cm, 1.4 cm, 1.5 cm, 1.6 cm, 1.7 cm, 1.8 cm, 1.9 cm, 2 cm, 2.1 cm, 2.2 cm, 2.3 cm, 2.4 cm, 2.5 cm, 2.6 cm, 2.7 cm, 2.8 cm, 2.9 cm, 3 cm, 3.1 cm, 3.2 cm, 3.3 cm, 3.4 cm, 3.5 cm, 3.6 cm, 3.7 cm, 3.8 cm, 3.9 cm, 4 cm, 4.1 cm, 4.2 cm, 4.3 cm, 4.4 cm, 4.5 cm, 4.6 cm, 4.7 cm, 4.8 cm, 4.9 cm, 5 cm, 5.1 cm, 5.2 cm, 5.3 cm, 5.4 cm, 5.5 cm, 5.6 cm, 5.7 cm, 5.8 cm, 5.9 cm, 6 cm, 6.1 cm, 6.2 cm, 6.3 cm, 6.4 cm, 6.5 cm, 6.6 cm, 6.7 cm, 6.8 cm, 6.9 cm, 7 cm, 7.1 cm, 7.2 cm, 7.3 cm, 7.4 cm, 7.5 cm, 7.6 cm, 7.7 cm, 7.8 cm, 7.9 cm, 8 cm, 8.1 cm, 8.2 cm, 8.3 cm, 8.4 cm, 8.5 cm, 8.6 cm, 8.7 cm, 8.8 cm, 8.9 cm, 9 cm, 9.1 cm, 9.2 cm, 9.3 cm, 9.4 cm, 9.5 cm, 9.6 cm, 9.7 cm, 9.8 cm, 9.9 cm, or 10 cm.

According to one embodiment, the optoelectronic device comprises LEDs, microLEDs, at least one array of LED or at least one array of microLED, on which at least one aggregate 1 and/or at least one light emitting material 7 is deposited. According to one embodiment, red emitting aggregate 1 and/or light emitting material 7, and green emitting aggregate 1 and/or light emitting material 7 are deposited alternatively on LEDs, microLEDs, at least one array of LED or at least one array of microLED, preferably blue LEDs, microLEDs, at least one array of LED or at least one array of microLED thus creating an alternance of red-green emitting pixels. According to one embodiment, red emitting aggregate 1 and/or light emitting material 7, green emitting aggregate 1 and/or light emitting material 7, no aggregate 1 and/or light emitting material 7 are deposited alternatively on LEDs, microLEDs, at least one array of LED or at least one array of microLED, preferably blue LEDs, microLEDs, at least one array of LED or at least one array of microLED, thus creating an alternance of blue-red-green emitting pixels.

According to one embodiment, the aggregate 1 and/or light emitting material 7 deposited on LEDs, microLEDs, at least one array of LED or at least one array of microLED is covered with an auxiliary layer as described herein, preferably a blue absorbing resin so that only red and green secondary light can be emitted.

According to one embodiment, the optoelectronic device comprises at least one film of aggregate 1 and/or at least one light emitting material 7 deposited on at least one array of LED, at least one array of microLED, or a pixel.

According to one embodiment, after deposition, the at least one aggregate 1 or the at least one light emitting material 7 is coated with an auxiliary layer as described here above. In this embodiment, the auxiliary layer limits or prevents the degradation of the chemical and physical properties of the at least one aggregate 1 or the at least one light emitting material 7 from molecular oxygen, ozone, water and/or high temperature.

According to one embodiment, after deposition, the at least one aggregate 1 or the at least one light emitting material 7 is coated with a protective layer as described here above. In this embodiment, the protective layer limits or prevents the degradation of the chemical and physical properties of the at least one aggregate 1 or the at least one light emitting material 7 from molecular oxygen, ozone, water and/or high temperature.

In one embodiment, the at least one aggregate 1 or the at least one light emitting material 7 exhibits photoluminescence quantum yield (PLQY) decrease of less than 90%, 80%, 70%, 60%, 50%, 40%, 30%, 25%, 20%, 15%, 10%, 5%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination.

According to one embodiment, the light illumination is provided by blue, green, red, or UV light source such as laser, diode, fluorescent lamp or Xenon Arc Lamp. According to one embodiment, the photon flux or average peak pulse power of the illumination is comprised between 1 mW·cm⁻² and 100 kW·cm⁻² and more preferably between 10 mW·cm⁻² and 100 W·cm⁻², and even more preferably between 10 mW·cm⁻² and 30 W·cm⁻².

According to one embodiment, the photon flux or average peak pulse power of the illumination is at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the at least one aggregate 1 or the at least one light emitting material 7 exhibits photoluminescence quantum yield (PQLY) decrease of less than 90%, 80%, 70%, 60%, 50%, 40%, 30%, 25%, 20%, 15%, 10%, 5%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the at least one aggregate 1 or the at least one light emitting material 7 exhibits FCE decrease of less than 90%, 80%, 70%, 60%, 50%, 40%, 30%, 25%, 20%, 15%, 10%, 5%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the optoelectronic device exhibits a decrease of the intensity of at least one emission peak of less than 90%, 80%, 70%, 60%, 50%, 40%, 30%, 25%, 20%, 15%, 10%, 5%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination.

In one embodiment, the optoelectronic device exhibits a decrease of the intensity of at least one emission peak of less than 90%, 80%, 70%, 60%, 50%, 40%, 30%, 25%, 20%, 15%, 10%, 5%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the optoelectronic device exhibits a decrease of the intensity of at least one emission peak of less than 90%, 80%, 70%, 60%, 50%, 40%, 30%, 25%, 20%, 15%, 10%, 5%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

In one embodiment, the optoelectronic device exhibits a decrease of the intensity of at least one emission peak of less than 90%, 80%, 70%, 60%, 50%, 40%, 30%, 25%, 20%, 15%, 10%, 5%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under a humidity of at least 0%, 10%, 20%, 30%, 40%, 50%, 55%, 60%, 65%, 70%, 75%, 80%, 85%, 90%, 95%, or 100%.

In one embodiment, the optoelectronic device exhibits a decrease of the intensity of at least one emission peak of less than 90%, 80%, 70%, 60%, 50%, 40%, 30%, 25%, 20%, 15%, 10%, 5%, or 0% under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the optoelectronic device exhibits a decrease of the intensity of at least one emission peak of less than 90%, 80%, 70%, 60%, 50%, 40%, 30%, 25%, 20%, 15%, 10%, 5%, or 0% under a humidity of at least 0%, 10%, 20%, 30%, 40%, 50%, 55%, 60%, 65%, 70%, 75%, 80%, 85%, 90%, 95%, or 100%, under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the optoelectronic device exhibits a decrease of the intensity of at least one emission peak of less than 90%, 80%, 70%, 60%, 50%, 40%, 30%, 25%, 20%, 15%, 10%, 5%, or 0% under a humidity of at least 0%, 10%, 20%, 30%, 40%, 50%, 55%, 60%, 65%, 70%, 75%, 80%, 85%, 90%, 95%, or 100%, under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

In one embodiment, the optoelectronic device exhibits a decrease of the intensity of at least one emission peak of less than 90%, 80%, 70%, 60%, 50%, 40%, 30%, 25%, 20%, 15%, 10%, 5%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 90 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻², under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

In one embodiment, the optoelectronic device exhibits a decrease of the intensity of at least one emission peak of less than 90%, 80%, 70%, 60%, 50%, 40%, 30%, 25%, 20%, 15%, 10%, 5%, or 0% under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻², under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under a humidity of at least 0%, 10%, 20%, 30%, 40%, 50%, 55%, 60%, 65%, 70%, 75%, 80%, 85%, 90%, 95%, or 100%.

In one embodiment, the optoelectronic device exhibits a decrease of the intensity of at least one emission peak of less than 90%, 80%, 70%, 60%, 50%, 40%, 30%, 25%, 20%, 15%, 10%, 5%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under a humidity of at least 0%, 10%, 20%, 30%, 40%, 50%, 55%, 60%, 65%, 70%, 75%, 80%, 85%, 90%, 95%, or 100%.

In one embodiment, the optoelectronic device exhibits a decrease of the intensity of at least one emission peak of less than 90%, 80%, 70%, 60%, 50%, 40%, 30%, 25%, 20%, 15%, 10%, 5%, or 0% after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻², and under a humidity of at least 0%, 10%, 20%, 30%, 40%, 50%, 55%, 60%, 65%, 70%, 75%, 80%, 85%, 90%, 95%, or 100%.

In one embodiment, the optoelectronic device exhibits a shift of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination.

In one embodiment, the optoelectronic device exhibits a shift of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the optoelectronic device exhibits a shift of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

In one embodiment, the optoelectronic device exhibits a shift of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under a humidity of at least 0%, 10%, 20%, 30%, 40%, 50%, 55%, 60%, 65%, 70%, 75%, 80%, 85%, 90%, 95%, or 100%.

In one embodiment, the optoelectronic device exhibits a shift of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the optoelectronic device exhibits a shift of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm under a humidity of at least 0%, 10%, 20%, 30%, 40%, 50%, 55%, 60%, 65%, 70%, 75%, 80%, 85%, 90%, 95%, or 100%, under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the optoelectronic device exhibits a shift of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm under a humidity of at least 0%, 10%, 20%, 30%, 40%, 50%, 55%, 60%, 65%, 70%, 75%, 80%, 85%, 90%, 95%, or 100%, under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

In one embodiment, the optoelectronic device exhibits a shift of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻², under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

In one embodiment, the optoelectronic device exhibits a shift of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻², under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under a humidity of at least 0%, 10%, 20%, 30%, 40%, 50%, 55%, 60%, 65%, 70%, 75%, 80%, 85%, 90%, 95%, or 100%.

In one embodiment, the optoelectronic device exhibits a shift of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under a humidity of at least 0%, 10%, 20%, 30%, 40%, 50%, 55%, 60%, 65%, 70%, 75%, 80%, 85%, 90%, 95%, or 100%.

In one embodiment, the optoelectronic device exhibits a shift of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻², and under a humidity of at least 0%, 10%, 20%, 30%, 40%, 50%, 55%, 60%, 65%, 70%, 75%, 80%, 85%, 90%, 95%, or 100%.

In one embodiment, the optoelectronic device exhibits an increase of the full width half maximum of at least one emission peak of less than 60 nm, 55 nm, 50 nm, 45 nm, 40 nm, 35 nm, 30 nm, 25 nm, 20 nm, 15 nm, 10 nm, 5 nm, 4 nm, 3 nm, 2 nm, or 1 nm after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination.

In one embodiment, the optoelectronic device exhibits an increase of the full width half maximum of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the optoelectronic device exhibits an increase of the full width half maximum of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

In one embodiment, the optoelectronic device exhibits an increase of the full width half maximum of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under a humidity of at least 0%, 10%, 20%, 30%, 40%, 50%, 55%, 60%, 65%, 70%, 75%, 80%, 85%, 90%, 95%, or 100%.

In one embodiment, the optoelectronic device exhibits an increase of the full width half maximum of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the optoelectronic device exhibits an increase of the full width half maximum of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm under a humidity of at least 0%, 10%, 20%, 30%, 40%, 50%, 55%, 60%, 65%, 70%, 75%, 80%, 85%, 90%, 95%, or 100%, under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the optoelectronic device exhibits an increase of the full width half maximum of at least one emission peak of less than 90%, 80%, 70%, 60%, 50%, 40%, 30%, 25%, 20%, 15%, 10%, 5%, or 0% under a humidity of at least 0%, 10%, 20%, 30%, 40%, 50%, 55%, 60%, 65%, 70%, 75%, 80%, 85%, 90%, 95%, or 100%, under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

In one embodiment, the optoelectronic device exhibits an increase of the full width half maximum of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻², under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C.

In one embodiment, the optoelectronic device exhibits an increase of the full width half maximum of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm^{-2,} or 100 kW·cm⁻², under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C., and under a humidity of at least 0%, 10%, 20%, 30%, 40%, 50%, 55%, 60%, 65%, 70%, 75%, 80%, 85%, 90%, 95%, or 100%.

In one embodiment, the optoelectronic device exhibits an increase of the full width half maximum of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under a temperature of at least 0° C., 10° C., 20° C., 30° C., 40° C., 50° C., 60° C., 70° C., 80° C., 90° C., 100° C., 125° C., 150° C., 175° C., 200° C., 225° C., 250° C., 275° C., or 300° C. and under a humidity of at least 0%, 10%, 20%, 30%, 40%, 50%, 55%, 60%, 65%, 70%, 75%, 80%, 85%, 90%, 95%, or 100%.

In one embodiment, the optoelectronic device exhibits an increase of the full width half maximum of at least one emission peak of less than 50 nm, 45 nm, 40 nm, 35 nm, 30 nm, 25 nm, 20 nm, 15 nm, 10 nm, 5 nm, 4 nm, 3 nm, 2 nm, or 1 nm after at least 300, 400, 500, 600, 700, 800, 900, 1000, 2000, 3000, 4000, 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, or 50000 hours under light illumination with a photon flux or average peak pulse power of at least 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W˜cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻² and under a humidity of at least 0%, 10%, 20%, 30%, 40%, 50%, 55%, 60%, 65%, 70%, 75%, 80%, 85%, 90%, 95%, or 100%.

Another object of the invention relates to the use of aggregate 1 of the invention.

According to one embodiment, the aggregate 1 of the invention is used in paints.

According to one embodiment, the aggregate 1 of the invention is used in inks.

According to one embodiment, the aggregate 1 of the present invention and/or the light emitting material 7 as described above is used for optoelectronics. In this embodiment, the aggregate 1 of the present invention and/or the light emitting material 7 as described above is comprised in an optoelectronic device. Examples of optoelectronic devices include but are not limited to: a display device, a diode, a light emitting diode (LED), a laser, a transistor, or a supercapacitor or an IR camera or a barcode.

According to one embodiment, the aggregate 1 of the present invention and/or the light emitting material 7 as described above is used in lighting applications. In this embodiment, examples of lighting applications include but are not limited to: lighting for farming and/or horticulture applications or installations such as for example greenhouses, or indoor plant growing; specialized lighting such as for example retail lighting such as for example lighting in clothing stores, grocery stores, retail stores, or malls; street lighting; commercial lighting; entertainment lighting such as for example concert lighting, studio TV lighting, movie lighting, stage lighting, club lighting, photography lighting, or architecture lighting; airfield lighting; healthcare lighting such as for example lighting in hospitals, clinics, or medical offices; hospitality lighting such as for example lighting in hotels and resorts, casinos, restaurants, bars and nightclubs, convention centers, spas and wellness centers; industrial lighting such as for example lighting in warehouses, manufacturing, distribution centers, transportation, parking facilities, or public utilities; medical and examination lighting; sport lighting such as for example lighting in sports Facilities, theme parks, museums, parks, art installations, theaters, or entertainment complexes; or eco-friendly lighting. The aggregate 1 of the present invention and/or the light emitting material 7 of the invention can improve the appeal and/or the preservation of the items sold in stores when used in the lighting installations of said sotres.

According to one embodiment, the aggregate 1 of the present invention is used in Quantum Dot Enhanced Films (QDEF) to replace regular quantum dots. In particular, an aggregate 1 comprising quantum dots, semiconductor nanoplatelets, or a mixture of at least one quantum dot and at least one semiconductor nanoplatelet is used in QDEF.

According to one embodiment, the aggregate 1 of the present invention and/or the light emitting material 7 of the invention is used on chip: on microLEDs, LEDs, an array of microLEDs, or an array of LEDs. In particular, an aggregate 1 comprising quantum dots emitting red light, semiconductor nanoplatelets emitting red light, or a mixture of at least one quantum dot and at least one semiconductor nanoplatelet emitting red light is used on chip.

According to one embodiment, the aggregate 1 of the present invention and/or the light emitting material 7 of the invention is used in a color filter, or as a color filter.

According to one embodiment, the aggregate 1 of the present invention and/or the light emitting material 7 of the invention is used in microLED, LED, or large LED videowalls.

According to one embodiment, the aggregate 1 of the invention is used as an electroluminescent quantum dot at the subpixel level, i.e. said aggregate 1 is used inside individual subpixels within a pixel array being charged by electrical current to create refined patterns and colors.

According to one embodiment, the aggregate 1 of the present invention and/or the light emitting material 7 of the invention is used for videoprojection, i.e. it is used in videoprojection devices.

According to one embodiment, the aggregate 1 and/or the light emitting material 7 of the invention is used in a display apparatus comprising at least one light source and a rotating wheel, wherein said at least one light source is configured to provide an illumination and/or an excitation for the aggregate 1 and/or the light emitting material 7. The light of the light sourcemeet the rotating wheel comprising the aggregate 1 and/or the light emitting material 7. the rotating wheel comprises several zones including at least one zone comprising the aggregate 1 and/or the light emitting material 7 or including at least two zones each comprising the aggregate 1 and/or the light emitting material 7 able to emit secondary lights at different wavelengths. At least one zone may be free of the aggregate 1 and/or the light emitting material 7, empty or optically transparent in order to permit the primary light to be transmitted through the rotating wheel without emission of any secondary light.

According to one embodiment, the aggregate 1 of the invention is used for the optical calibration of optical instruments such as spectrophotometers. Indeed, as the optical properties of said aggregate 1 are stable in time and temperature, it is possible to keep them for a long period of time and use them during the calibration procedure of spectrophotometers.

According to one embodiment, the optoelectronic device is a display device, a diode, a light emitting diode (LED), a laser, a photodetector, a transistor, a supercapacitor, a barcode, a LED, a microLED, an array of LED, an array of microLED, or an IR camera.

According to one embodiment, the aggregate 1 of the present invention and/or the light emitting material 7 is used for luminescence detection.

According to one embodiment, the aggregate 1 of the present invention and/or the light emitting material 7 is used for bioimaging, biotargeting, biosensing, medical imaging, diagnostic, therapy, or theranostics.

According to one embodiment, the aggregate 1 of the invention and/or the light emitting material 7 is used for catalysis.

According to one embodiment, the aggregate 1 of the invention is used in drug delivery.

According to one embodiment, the aggregate 1 of the invention and/or the light emitting material 7 is used in energy storage devices.

According to one embodiment, the aggregate 1 of the invention and/or the light emitting material 7 is used in energy production devices.

According to one embodiment, the aggregate 1 of the invention and/or the light emitting material 7 is used in enery conversion devices.

According to one embodiment, the aggregate 1 of the invention and/or the light emitting material 7 is used in enery transport devices.

According to one embodiment, the aggregate 1 of the invention and/or the light emitting material 7 is used in photovoltaic cells.

According to one embodiment, the aggregate 1 of the invention and/or the light emitting material 7 is used in lighting devices.

According to one embodiment, the aggregate 1 of the invention and/or the light emitting material 7 is used in sensor devices.

According to one embodiment, the aggregate 1 of the invention comprising fluorescent particles is used in pressure sensor devices. In this embodiment, a pressure exerted on said aggregate 1 (and therefore on the fluorescent particles) induces a shift in the emission wavelength.

Another object of the invention relates to a method for manufacturing a metastable aggregate 1 of the invention.

In one embodiment, the method comprises the following steps:
(a) preparing a colloidal suspension by mixing a solution comprising at least one precursor of a material 11 with a first colloidal suspension comprising at least one particle 12;
(b) forming droplets of said colloidal suspension;
(c) dispersing said droplets in a gas flow;
(d) heating said dispersed droplets at a temperature enough to obtain the aggregates 1 by solvent evaporation;
(e) cooling of said aggregates 1; and
(f) separating and collecting said aggregates 1.

wherein said aggregates are metastable.

The material 11 and the particle 12 are as described hereabove.

According to one embodiment, the solution comprising at least one precursor of material 11 is subjected to hydrolysis at acidic pH prior step (a).

According to one embodiment, the solution comprising at least one precursor of material 11 is subjected to hydrolysis at basic pH prior step (a).

According to one embodiment, the solution comprising at least one precursor of material 11 is subjected to hydrolysis at neutral pH prior step (a).

According to one embodiment, the colloidal suspension comprising at least one particle 12 is transferred in an aqueous solution prior step (a).

According to one embodiment, the colloidal suspension comprising at least one particle 12 is transferred in an acidic aqueous solution prior step (a).

According to one embodiment, the colloidal suspension comprising at least one particle 12 is transferred in a basic aqueous solution prior step (a).

According to one embodiment, the colloidal suspension comprising at least one particle 12 is transferred in a neutral pH aqueous solution prior step (a).

According to one embodiment, the colloidal suspension comprising at least one particle 12 is transferred in an organic solvent prior step (a).

According to one embodiment, at least one precursor of at least one heteroelement selected from the group constituted by cadmium, sulfur, selenium, indium, tellurium, mercury, tin, copper, nitrogen, gallium, antimony, thallium, molybdenum, palladium, cerium, tungsten, cobalt, manganese, silicon, boron, phosphorus, germanium, arsenic, aluminium, iron, titanium, zirconium, nickel, zinc, calcium, sodium, barium, potassium, magnesium, lead, vanadium, silver, beryllium, iridium, scandium, niobium, or tantalum is added to the mixing solution at step (a).

In one embodiment, water, at least one acid, at least one base, at least one organic solvent, at least one aqueous solvent, or at least one surfactant is added in step (a) and/or step (b).

According to one embodiment, at least one solution comprising additional nanoparticles selected in the group of Al₂O₃, SiO₂, MgO, ZnO, ZrO₂, IrO₂, SnO₂, TiO₂, BaO, BaSO₄, BeO, CaO, CeO₂, CuO, Cu₂O, DyO₃, Fe₂O₃, Fe₃O₄, GeO₂, HfO₂, Lu₂O₃, Nb₂O₅, Sc₂O₃, TaO₅, TeO₂, Y₂O₃, or a mixture thereof is added to the mixing solution at step (a). In this embodiment, Al₂O₃, SiO₂, MgO, ZnO, ZrO₂, TiO₂, IrO₂, SnO₂, BaO, BaSO₄, BeO, CaO, CeO₂, CuO, Cu₂O, DyO₃, Fe₂O₃, Fe₃O₄, GeO₂, HfO₂, Lu₂O₃, Nb₂O₅, Sc₂O₃, TaO₅, TeO₂, or Y₂O₃ additional nanoparticles can drain away the heat if it is a good thermal conductor.

According to one embodiment, droplets of a solution A are added in the gas flow during step (c).

According to one embodiment, solution A may comprise: at least one aqueous solvent; at least one organic solvent; water; a base; an acid; at least one surfactant; at least one precursor of a material 31; a second colloidal suspension comprising at least one particle 12; at least one solution comprising additional nanoparticles; at least one precursor of at least one heteroelement selected from the group constituted by cadmium, sulfur, selenium, indium, tellurium, mercury, tin, copper, nitrogen, gallium, antimony, thallium, molybdenum, palladium, cerium, tungsten, cobalt, manganese, silicon, boron, phosphorus, germanium, arsenic, aluminium, iron, titanium, zirconium, nickel, zinc, calcium, sodium, barium, potassium, magnesium, lead, vanadium, silver, beryllium, iridium, scandium, niobium, or tantalum.

According to one embodiment, solution A comprises at least one reactive species.

According to one embodiment, solution A and the solution prepared at step (a) are miscible.

According to one embodiment, solution A and the solution prepared at step (a) are not miscible.

According to one embodiment, solution A and the solution prepared at step (a) are immiscible.

According to one embodiment, the droplets of solution A are replaced by vapors of solution A. In this embodiment, said means for forming droplets do not form droplets but uses the vapors of the solution comprised in a container.

According to one embodiment, the droplets of solution A are replaced by a gas such as for example air, nitrogen, argon, dihydrogen, dioxygen, helium, carbon dioxide, carbon monoxide, NO, NO₂, N₂O, F₂, Cl₂, H₂Se, CH₄, PH₃, NH₃, SO₂, H₂S or a mixture thereof.

According to one embodiment, vapors of a solution are obtained by heating said solution with an external heating system.

According to one embodiment, examples for the solution capable of producing reactive vapors include but are not limited to water, a volatile acid such as for example HCl or HNO₃, a base such as for example ammonia, ammonium hydroxide, or tetramethylammonium hydroxide, or a metal alkoxide such as for example an alkoxide of silicon or aluminium such as for example tetramethyl orthosilicate or tetraethyl orthosilicate.

According to one embodiment, the droplets of solution A and of solution prepared at step (a) are formed simultaneously.

According to one embodiment, the droplets of solution A are formed prior to the formation of droplets of the solution prepared at step (a).

According to one embodiment, the droplets of solution A are formed prior to or after the formation of droplets of the solution prepared at step (a).

According to one embodiment, the droplets of the solution prepared at step (a) are formed prior to the formation of droplets of solution A.

According to one embodiment, the method of the invention may comprise steps involving methods such as for example reverse micellar (or emulsion) method, micellar (or emulsion) method, Stober method.

According to one embodiment, the method of the invention further comprises a step of preparing aggregates 1 comprising at least one particle 12 dispersed in a material 11, wherein said step involves reverse micellar (or emulsion) method.

According to one embodiment, the method of the invention further comprises a step of preparing particles 12 comprising at least one nanoparticle 3 dispersed in a material 21, wherein said step involves reverse micellar (or emulsion) method.

According to one embodiment, the method of the invention may comprise steps involving methods such as for example reverse micellar (or emulsion) method, micellar (or emulsion) method, Stober method.

Herein, reverse micellar (or emulsion) method may refer to inverse micellar (or emulsion) method, reverse micellar (or microemulsion) method, inverse micellar (or microemulsion) method, and/or inverse microemulsion micelles method.

According to one embodiment, the step of preparing particles 12 using reverse micellar (or emulsion) method comprises:
adding an aqueous suspension of nanoparticles 3 in a solution comprising at least one organic solvent and at least one surfactant;
optionnaly adding at least one base, and/or at least one acid;
adding to the previously obtained solution a solution comprising at least one precursor of the material 21 to form a microemulsion, said solution may comprise at least one base, and/or at least one acid, said solution can be added in several times;
hydrolyzing the obtained microemulsion; and
separating and collecting particles 12.

According to one embodiment, the step of preparing aggregates 1 using reverse micellar (or emulsion) method comprises:
adding an aqueous suspension of particles 12 in a solution comprising at least one organic solvent and at least one surfactant;
optionnaly adding at least one base, and/or at least one acid;
adding to the previously obtained solution a solution comprising at least one precursor of the material 11 to form a microemulsion, said solution may comprise at least one base, and/or at least one acid, said solution can be added in several times;
hydrolyzing the obtained microemulsion; and
separating and collecting aggregates 1.

According to one embodiment, the method of the invention does not comprise ALD steps (Atomic Layer Deposition), especially to encapsulate the at least one particle 12 in an aggregate 1.

According to one embodiment, the solution comprising at least one precursor of a material 11 and the colloidal suspension comprising at least one particle 12 are miscible.

According to one embodiment, the solution comprising at least one precursor of a material 11 and the colloidal suspension comprising at least one particle 12 are not miscible.

According to one embodiment, the solution comprising at least one precursor of a material 11 and the colloidal suspension comprising at least one particle 12 are immiscible.

According to one embodiment, the aqueous solution comprises at least one aqueous solvent.

According to one embodiment, the organic solvent includes but is not limited to: pentane, hexane, 1,2-hexanediol, 1,5-pentanediol, heptane, octane, decane, dodecane, toluene, tetrahydrofuran, chloroform, acetone, acetic acid, n-methylformamide, n,n-dimethylformamide, dimethylsulfoxide, octadecene, squalene, amines such as for example tri-n-octylamine, 1,3-diaminopropane, oleylamine, hexadecylamine, octadecylamine, squalene, alcohols such as for example ethanol, methanol, isopropanol, 1-butanol, 1-hexanol, 1-decanol, propane-2-ol, ethanediol, 1,2-propanediol, alkoxy alcohol, alkyl alcohol, alkyl benzene, alkyl benzoate, alkyl naphthalene, amyl octanoate, anisole, aryl alcohol, benzyl alcohol, butyl benzene, butyrophenon, cis-decalin, dipropylene glycol methyl ether, dodecyl benzene, mesitylene, methoxy propanol, methylbenzoate, methyl naphthalene, methyl pyrrolidinone, phenoxy ethanol, 1,3-propanediol, pyrrolidinone, trans-decalin, valerophenone, or a mixture thereof.

According to one embodiment, the at least one precursor of a material 11 comprises at least one element of said material 11 and is capable of liberating said element in solution.

The term “the at least one precursor of a material 11” refers to the at least one precursor of an organic material, an inorganic material and/or a hybrid material.

According to one embodiment, the at least one precursor of a material 11 is an alkoxide precursor of formula XMₐ(OR)_{b}, wherein:
M is said element;
R is a linear alkyl chain comprising a range of 1 to 25 carbon atoms, R includes but is not limited to: methyl, ethyl, isopropyl, n-butyl, or octyl;
X is optional and is a linear alkyl chain that can comprise an alcohol group, a thiol group, an amino group, or a carboxylic group, comprising a range of 1 to 25 carbon atoms; and
a and b are independently a decimal number from 0 to 5.

According to one embodiment, the alkoxide precursor of formula XMₐ(OR)_{b} includes but is not limited to: tetramethyl orthosilicate, tetraethyl orthosilicate, polydiethyoxysilane, n-alkyltrimethoxylsilanes such as for example n-butyltrimethoxysilane, n-octyltrimethoxylsilane, n-dodecyltrimethoxysilane, n-octadecyltrimethoxysilane, 3-mercaptopropyltrimethoxysilane, 11-mercaptoundecyltrimethoxysilane, 3-aminopropyltrimethoxysilane, 11-aminoundecyltrimethoxysilane, 3-(2-(2-aminoethylamino)ethylamino)propyltrimethoxysilane, 3-(trimethoxysilyl)propyl methacrylate, 3-(aminopropyl)trimethoxysilane, aluminium tri-sec butoxide, aluminium isopropxide, aluminium ethoxide, aluminium tert-butoxide, titanium butoxide, isopropxide, aluminium ethoxide, aluminium tert-butoxide, or a mixture thereof.

According to one embodiment, the at least one precursor of a material 11 is an inorganic halide precursor.

According to one embodiment, the halide precursor includes but is not limited to: halide silicates such as for example ammonium fluorosilicate, sodium fluorosilicate, or a mixture thereof.

According to one embodiment, the at least one precursor of a material 11 is a pure solid precursor.

According to one embodiment, the pure solid precursor includes but is not limited to: pure solid silicon, boron, phosphorus, germanium, arsenic, aluminium, iron, titanium, zirconium, nickel, zinc, calcium, sodium, barium, potassium, magnesium, lead, silver, vanadium, tellurium, manganese, iridium, scandium, niobium, tin, cerium, beryllium, tantalum, sulfur, selenium, or a mixture thereof.

According to one embodiment, theat least one precursor of a material 11 is an inorganic oxide precursor.

According to one embodiment, the at least one precursor of a material 11 is an inorganic hydroxide precursor.

According to one embodiment, the at least one precursor of a material 11 is an inorganic salt.

According to one embodiment, the at least one precursor of a material 11 is an inorganic complex.

According to one embodiment, the at least one precursor of a material 11 is an inorganic cluster.

According to one embodiment, the at least one precursor of a material 11 is an organometallic compound Mₐ(Y_{c}R_{b})_{d}, wherein:
M is said element;
Y is an halogenide, or a amide;
R is an alkyl chain or alkenyl chain or alkinyl chain comprising a range of 1 to 25 carbon atoms, R includes but is not limited to: methyl, ethyl, isopropyl, n-butyl, or octyl;
a, b, c and d are independently a decimal number from 0 to 5.

According to one embodiment, examples of the organometallic compound Mₐ(Y_{c}R_{b})_{d} include but are not limited to: Grignard reagents; metallocenes; metal amidinates; metal alkyl halides; metal alkyls such as for example dimethylzinc, diethylzinc, dimethylcadmium, diethylcadmium, dimethylindium or diethylindium; metal and metalloid amides such as Al[N(SiMe₃)₂]₃, Cd[N(SiMe₃)₂]₂, Hf[NMe₂]₄, In[N(SiMe₃)₂]₃, Sn(NMe₂)₂, Sn[N(SiMe₃)₂]₂, zinc diethylthiocarbamate, Zn[N(SiMe₃)₂]₂ or Zn[(NiBu₂)₂]₂, dineopentylcadmium, bis(3-diethylaminopropyl)cadmium, (2,2′-bipyridine)dimethylcadmium, cadmium ethylxanthate; trimethyl aluminium, triisobutylaluminum, trioctylaluminum, triphenylaluminum, dimethyl aluminium, trimethyl zinc, dimethyl zinc, diethylzinc, Zn[(N(TMS)₂]₂, Zn[(CF₃SO₂)₂N]₂, Zn(Ph)₂, Zn(C₆F₅)₂, Zn(TMHD)₂ (β-diketonate), Ht[C₅H₄(CH₃)]₂(CH₃)₂, HfCH₃(OCH₃)[C₅H₄(CH₃)]₂, [[(CH₃)₃Si]₂N]₂HfCl₂, (C₅H₅)₂Hf(CH₃)₂, [(CH₂CH₃)₂N]₄Hf, [(CH₃)₂N]₄Hf, [(CH₃)₂N]₄Hf, [(CH₃)(C₂H₅)N]₄Hf, [(CH₃)(C₂H₅)N]₄Hf, 2,2′,6,6′-tetramethyl-3,5-heptanedione zirconium (Zr(THD)₄), C₁₀H₁₂Zr, Zr(CH₃C₅H₄)₂CH₃OCH₃, C₂₂H₃₆Zr, [(C₂H₅)₂N]₄Zr, [(CH₃)₂N]₄Zr, [(CH₃)₂N]₄Zr, Zr(NCH₃C₂H₅)₄, Zr(NCH₃C₂H₅)₄, C₁₈H₃₂O₆Zr, Zr(C₈H₁₅O₂)₄, Zr(OCC(CH₃)₃CHCOC(CH₃)₃)₄, Mg(C₅H₅)₂, C₂₀H₃₀Mg; or a mixture thereof.

According to one embodiment, the at least one precursor of a material 11 includes but is not limited to: carboxylates, carbonates, thiolates, alkoxides, oxides, phosphates, sulfates, nitrates, acetates, chlorides, bromides, acetylacetonate or a mixture thereof.

According to one embodiment, the at least one precursor of cadmium includes but is not limited to: cadmium carboxylates Cd(R—COO)₂, wherein R is a linear alkyl chain comprising a range of 1 to 25 carbon atoms; cadmium oxide CdO; cadmium sulfate Cd(SO₄); cadmium nitrate Cd(NO₃)₂.4H₂O; cadmium acetate (CH₃COO)₂Cd.2H₂O; cadmium chloride CdCl₂.2.5H₂O; dimethylcadmium; dineopentylcadmium; bis(3-diethylaminopropyl)cadmium; (2,2′-bipyridine)dimethylcadmium; cadmium ethylxanthate; cysteine or a mixture thereof.

According to one embodiment, the at least one precursor of selenium includes but is not limited to: solid selenium; tri-n-alkylphosphine selenide such as for example tri-n-butylphosphine selenide or tri-n-octylphosphine selenide; selenium oxide SeO₂; hydrogen selenide H₂Se; diethylselenide; methylallylselenide; salts such as for example magnesium selenide, calcium selenide, sodium selenide, potassium selenide; or a mixture thereof.

According to one embodiment, the at least one precursor of zinc includes but is not limited to: zinc carboxylates Zn(R—COO)₂, wherein R is a linear alkyl chain comprising a range of 1 to 25 carbon atoms; zinc oxide ZnO; zinc sulfate Zn(SO₄),xH₂O where x is from 1 to 7; zinc nitrate Zn(NO₃)₂,xH₂O where x is from 1 to 4; zinc acetate (CH₃COO)₂Zn.2H₂O; zinc chloride ZnCl₂; diethylzinc (Et₂Zn); chloro(ethoxycarbonylmethyl)zinc; or a mixture thereof.

According to one embodiment, the at least one precursor of sulfur includes but is not limited to: solid sulfur; sulfur oxides; tri-n-alkylphosphine sulfide such as for example tri-n-butylphosphine sulfide or tri-n-octylphosphine sulfide; hydrogen sulfide H₂S; thiols such as for example n-butanethiol, n-octanethiol or n-dodecanethiol; diethylsulfide; methylallylsulfide; salts such as for example magnesium sulfide, calcium sulfide, sodium sulfide, potassium sulfide; or a mixture thereof.

According to one embodiment, the at least one precursor of phosphorus includes but is not limited to: solid phosphorus; phosphine; tri-n-alkylphosphine sulfide such as for example tri-n-butylphosphine sulfide or tri-n-octylphosphine sulfide; tri-n-alkylphosphine selenide such as for example tri-n-butylphosphine selenide or tri-n-octylphosphine selenide; or a mixture thereof.

According to one embodiment, the at least one precursor of a material 11 is an organic complex.

According to one embodiment, exemples of organic complex include but are not limited to: organic polymers, sugars such as polysaccharides, coupled enzymes with polymers, and or organometallic structures stabilized with primary, secondary or tertiary amines, metal-carbon bonds, or metal phosphor bonds.

According to one embodiment, the at least one precursor of a material 11 is a monomeric precursor.

According to one embodiment, exemples of a monomeric precursor include but are not limited to: acrylates including methyl acrylates, ethyl acrylates, propyl acrylates, butyl acrylates, acrylamides including methyl acrylamides, ethyl acrylamide, propyl acrylamides, butyl acrlyamides, epoxides, ethylene oxides, glycidyl acrylates or methacrylates, methyl methacrylates, any monomer corresponding the polymers described herein or a mixture thereof.

According to one embodiment, the at least one precursor of a material 11 is a polymer. In this embodiment, the polymer is as described herein.

According to one embodiment, molecular oxygen and/or molecular water are removed from the solution and/or suspension prior to step (a).

According to one embodiment, molecular oxygen and/or molecular water are removed from the solvent prior to step (a).

According to one embodiment, molecular oxygen and/or molecular water are removed from the aqueous solvent prior to step (a).

According to one embodiment, molecular oxygen and/or molecular water are removed from the organic solvent prior to step (a).

According to one embodiment, methods to remove molecular oxygen and/or molecular water known to those of skill in the art may be used to remove molecular oxygen and/or molecular water from solvents, such as for example distilling or degassing said solvent.

According to one embodiment, the neutral aqueous solution has a pH of 7.

According to one embodiment, the neutral pH is 7.

According to one embodiment, the basic aqueous solution has a pH higher than 7.

According to one embodiment, the basic pH is higher than 7.

According to one embodiment, the basic aqueous solution has a pH of at least 7.1, 7.2, 7.3, 7.4, 7.5, 7.6, 7.7, 7.8, 7.9, 8, 8.1, 8.2, 8.3, 8.4, 8.5, 8.6, 8.7, 8.8, 8.9, 9, 9.1, 9.2, 9.3, 9.4, 9.5, 9.6, 9.7, 9.8, 9.9, 10, 10.1, 10.2, 10.3, 10.4, 10.5, 10.6, 10.7, 10.8, 10.9, 11, 11.1, 11.2, 11.3, 11.4, 11.5, 11.6, 11.7, 11.8, 11.9, 12, 12.1, 12.2, 12.3, 12.4, 12.5, 12.6, 12.7, 12.8, 12.9, 13, 13.1, 13.2, 13.3, 13.4, 13.5, 13.6, 13.7, 13.8, 13.9, or 14.

According to one embodiment, the basic pH is at least 7.1, 7.2, 7.3, 7.4, 7.5, 7.6, 7.7, 7.8, 7.9, 8, 8.1, 8.2, 8.3, 8.4, 8.5, 8.6, 8.7, 8.8, 8.9, 9, 9.1, 9.2, 9.3, 9.4, 9.5, 9.6, 9.7, 9.8, 9.9, 10, 10.1, 10.2, 10.3, 10.4, 10.5, 10.6, 10.7, 10.8, 10.9, 11, 11.1, 11.2, 11.3, 11.4, 11.5, 11.6, 11.7, 11.8, 11.9, 12, 12.1, 12.2, 12.3, 12.4, 12.5, 12.6, 12.7, 12.8, 12.9, 13, 13.1, 13.2, 13.3, 13.4, 13.5, 13.6, 13.7, 13.8, 13.9, or 14.

According to one embodiment, the base includes but is not limited to: sodium hydroxide, potassium hydroxide, ammonium hydroxide, sodium tetraborate decahydrated, sodium ethoxide, lithium hydroxide, rubidium hydroxide, cesium hydroxide, magnesium hydroxide, calcium hydroxide, strontium hydroxide, barium hydroxide, imidazole, methylamine, potassium tert-butoxide, ammonium pyridine, a tetra-alkylammonium hydroxide such as for example tetramethylammonium hydroxide, tetraethylammonium hydroxide, tetrapropylammonium hydroxide and tetrabutylammonium hydroxide, or a mixture thereof.

According to one embodiment, the acidic aqueous solution has a pH lower than 7.

According to one embodiment, the acidic pH is lower than 7.

According to one embodiment, the acidic aqueous solution has a pH of at least 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, 2.9, 3, 3.1, 3.2, 3.3, 3.4, 3.5, 3.6, 3.7, 3.8, 3.9, 4, 4.1, 4.2, 4.3, 4.4, 4.5, 4.6, 4.7, 4.8, 4.9, 5, 5.1, 5.2, 5.3, 5.4, 5.5, 5.6, 5.7, 5.8, 5.9, 6, 6.1, 6.2, 6.3, 6.4, 6.5, 6.6, 6.7, 6.8, or 6.9.

According to one embodiment, the acidic pH is at least 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, 2.9, 3, 3.1, 3.2, 3.3, 3.4, 3.5, 3.6, 3.7, 3.8, 3.9, 4, 4.1, 4.2, 4.3, 4.4, 4.5, 4.6, 4.7, 4.8, 4.9, 5, 5.1, 5.2, 5.3, 5.4, 5.5, 5.6, 5.7, 5.8, 5.9, 6, 6.1, 6.2, 6.3, 6.4, 6.5, 6.6, 6.7, 6.8, or 6.9.

According to one embodiment, the acid includes but is not limited to: acetic acid, hydrochloric acid, hydrobromic acid, hydroiodic acid, hydrofluoric acid, sulfuric acid, nitric acid, boric acid, oxalic acid, maleic acid, lipoic acid, urocanic acid, 3-mercaptopropionic acid, phosphonic acid such as for example butylphosphonic acid, octylphosphonic acid and dodecylphosphonic acid, or a mixture thereof.

According to one embodiment, the particles 12 may be aligned under a magnetic field or an electrical field prior or during the method of the invention. In this embodiment, the particles 12 can act as magnets if said particles are ferromagnetic; or the resulting aggregates 1 can emit a polarized light if the particles 12 are luminescent.

According to one embodiment, the hydrolysis is controlled to the extent that the quantity of water present in the reaction medium is solely due to the addition of water which is introduced voluntarily.

According to one embodiment, the hydrolysis is partial or complete.

According to one embodiment, the hydrolysis is performed in a humid atmosphere.

According to one embodiment, the hydrolysis is performed in an anhydrous atmosphere. In this embodiment, the atmosphere of hydrolysis comprises no humidity.

According to one embodiment, the temperature of hydrolysis is at least −50° C., −40° C., −30° C., −20° C., −10° C., 0° C., 10° C., 20° C., 30° C., 40° C., 50° C., 60° C., 70° C., 80° C., 90° C., 100° C., 110° C., 120° C., 130° C., 140° C., 150° C., 160° C., 170° C., 180° C., 190° C., or 200° C.

According to one embodiment, the time of hydrolysis is at least 1 sec, 2 sec, 3 sec, 4 sec, 5 sec, 6 sec, 7 sec, 8 sec, 9 sec, 10 sec, 15 sec, 20 sec, 25 sec, 30 sec, 35 sec, 40 sec, 45 sec, 50 sec, 55 sec, 60 sec, 1.5 min, 2 min, 2.5 min, 3 min, 3.5 min, 4 min, 4.5 min, 5 min, 5.5 min, 6 min, 6.5 min, 7 min, 7.5 min, 8 min, 8.5 min, 9 min, 9.5 min, 10 min, 11 min, 12 min, 13 min, 14 min, 15 min, 16 min, 17 min, 18 min, 19 min, 20 min, 21 min, 22 min, 23 min, 24 min, 25 min, 26 min, 27 min, 28 min, 29 min, 30 min, 31 min, 32 min, 33 min, 34 min, 35 min, 36 min, 37 min, 38 min, 39 min, 40 min, 41 min, 42 min, 43 min, 44 min, 45 min, 46 min, 47 min, 48 min, 49 min, 50 min, 51 min, 52 min, 53 min, 54 min, 55 min, 56 min, 57 min, 58 min, 59 min, 1 h, 6 h, 12 h, 18 h, 24 h, 30 h, 36 h, 42 h, 48 h, 54 h, 60 h, 66 h, 72 h, 78 h, 84 h, 90 h, 96 h, 102 h, 108 h, 114 h, 120 h, 126 h, 132 h, 138 h, 144 h, 150 h, 156 h, 162 h, 168 h, 8 days, 9 days, 10 days, 11 days, 12 days, 13 days, 14 days, 15 days, 16 days, 17 days, 18 days, 19 days, 20 days, 21 days, 22 days, 23 days, 24 days, 25 days, 26 days, 27 days, 28 days, 29 days, or 30 days.

According to one embodiment, the particle 12 is suspended in an organic solvent, wherein said organic solvent includes but is not limited to: hexane, heptane, pentane, octane, decane, dodecane, toluene, tetrahydrofuran, chloroform, acetone, acetic acid, n-methylformamide, n,n-dimethylformamide, dimethylsulfoxide, octadecene, squalene, amines such as for example tri-n-octylamine, 1,3-diaminopropane, oleylamine, hexadecylamine, octadecylamine, squalene, alcohols such as for example ethanol, methanol, isopropanol, 1-butanol, 1-hexanol, 1-decanol, propane-2-ol, ethanediol, 1,2-propanediol or a mixture thereof.

According to one embodiment, the particle 12 is suspended in water.

According to one embodiment, the particle 12 is transferred in an aqueous solution by exchanging the ligands at the surface of the particle 12. In this embodiment, the exchanging ligands include but are not limited to: 2-mercaptoacetic acid, 3-mercaptopropionic acid, 12-mercaptododecanoic acid, 11-mercaptol -undecanol, 2-mercaptoehtyltrimethoxysilane, 3-mercaptopropyltrimethoxysilane, 12-mercaptododecyltrimethoxysilane, 16-hydroxyhexadecanoic acid, ricinoleic acid, cysteamine, or a mixture thereof.

According to one embodiment, the ligands at the surface of the particle 12 are exchanged with at least one exchanging ligand comprising at least one atom of Si, Al, Ti, B, P, Ge, As, Fe, T, Z, Ni, Zn, Ca, Na, K, Mg, Pb, Ag, V, P, Te, Mn, Ir, Sc, Nb, or Sn. In this embodiment, the at least one exchanging ligand comprises at least one atom of at least one precursor of material 11 allowing the particles 12 to be uniformly dispersed in the aggregate 1. In the case of at least one exchanging ligand comprising at least one atom of Si, the surface of the particle 12 can be silanized before mixing step with the precursor solution.

According to one embodiment, at least one exchanging ligand comprising at least one atom of Si, Al, Ti, B, P, Ge, As, Fe, T, Z, Ni, Zn, Ca, Na, K, Mg, Pb, Ag, V, P, Te, Mn, Ir, Sc, Nb, or Sn. includes but is not limited to: mercapto-functional silanes such as for example 2-mercaptoethyltrimethoxysilane, 3-mercaptopropyltrimethoxysilane, 12-mercaptododecyltrimethoxysilane; 2-aminooehtyltrimethoxysilane; 3-aminopropyltrimethoxysilane, 12-aminododecyltrimethoxysilane; or a mixture thereof.

According to one embodiment, the ligands at the surface of the particle 12 are partially exchanged with at least one exchanging ligand comprising at least one atom of Si, Al, Ti, B, P, Ge, As, Fe, T, Z, Ni, Zn, Ca, Na, K, Mg, Pb, Ag, V, P, Te, Mn, Ir, Sc, Nb, or Sn. In this embodiment, the at least one exchanging ligand comprising at least one atom of Si, Al, Ti, B, P, Ge, As, Fe, T, Z, Ni, Zn, Ca, Na, K, Mg, Pb, Ag, V, P, Te, Mn, Ir, Sc, Nb, or Sn includes but is not limited to: n-alkyltrimethoxylsilanes such as for example n-butyltrimethoxysilane, n-octyltrimethoxylsilane, n-dodecyltrimethoxysilane, n-octadecyltrimethoxysilane; 2-aminooehtyltrimethoxysilane; 3-aminopropyltrimethoxysilane; 12-aminododecyltrimethoxysilane.

According to one embodiment, at least one ligand comprising at least one atom of silicon, aluminium or titanium is added to the at least one colloidal suspension comprising at least one particle 12. In this embodiment, the at least one ligand comprising at least one atom of silicon, aluminium or titanium includes but is not limited to: n-alkyltrimethoxylsilanes such as for example n-butyltrimethoxysilane, n-octyltrimethoxylsilane, n-dodecyltrimethoxysilane, n-octadecyltrimethoxysilane; 2-aminooehtyltrimethoxysilane; 3-aminopropyltrimethoxysilane; 12-aminododecyltrimethoxysilane. In this embodiment, the ligands at the surface of the particle 12 and the at least one ligand comprising at least one atom of silicon, aluminium or titanium are interdigitated at the surface of the particle 12, allowing the particles 12 to be uniformly dispersed in the aggregate 1.

According to one embodiment, the ligands at the surface of the particles 12 are C3 to C20 alkanethiol ligands such as for example propanethiol, butanethiol, pentanethiol, hexanethiol, heptanethiol, octanethiol, nonanethiol, decanethiol, undecanethiol, dodecanethiol, tridecanethiol, tetradecanethiol, pentadecanethiol, hexadecanethiol, heptadecanethiol, octadecanethiol, or a mixture thereof. In this embodiment, C3 to C20 alkanethiol ligands help control the hydrophobicity of the nanoparticles surface.

According to one embodiment, the ligands at the surface of the particle 12 are exchanged with at least one exchanging ligand which is a copolymer, block copolymer and/or a multidendate ligand.

In one embodiment of the invention, said at least one exchanging ligand which is a copolymer comprises at least 2 monomers, said monomers being:
one anchoring monomer comprising a first moiety MA having affinity for the surface of the particle 12, and
one hydrophilic monomer comprising a second moiety M_{B} having a high water solubility.

In one embodiment of the invention, said at least one exchanging ligand which is a copolymer has the following formula I:

(A)x(B)y

wherein

A comprising at least one anchoring monomer comprising a first moiety M_{A} having affinity for the surface of the particle 12 as described here above,

B comprising at least one hydrophilic monomer comprising a second moiety M_{B} having a high water solubility, and

each of x and y is independently a positive integer, preferably an integer ranging from 1 to 499, from 1 to 249, from 1 to 99, or from 1 to 24.

In one embodiment of the invention, the at least one exchanging ligand which is a copolymer has the following formula II:

[chemical structure]

wherein

R_{A} represents a group comprising the first moiety M_{A} having affinity for the surface of the particle 12 as described here above,

R_{B} represents a group comprising the second moiety M_{B} having a high water solubility,

R₁, R₂, R₃, R₄, R₅, R₆ can be independently H, or a group selected from an alkyl, alkenyl, aryl, hydroxyle, halogen, alkoxy, carboxylate,

each of x and y is independently a positive integer, preferably an integer ranging from 1 to 499.

In another embodiment of the invention, the at least one exchanging ligand which is a copolymer comprising at least 2 monomers has the following formula II′:

[chemical structure]

wherein

R_{A}′ and R_{A}″ represent respectively a group comprising the first moiety M_{A}′ and M_{A}″ having affinity for the surface of the particle 12,

RB′ and RB″ represent respectively a group comprising the second moiety MB′ and MB″ having a high water solubility,

R₁′, R₂′, R₃′, R₁″, R₂″, R₃″, R₄′, R₅′, R₆′, R₄″, R₅″, R₆″ can be independently H, or a group selected from an alkyl, alkenyl, aryl, hydroxyle, halogen, alkoxy, carboxylate,

each of x′ and x″ is independently a positive integer, preferably an integer ranging from 0 to 499, with the condition that at least one of x′ and x″ is not 0,

each of y′ and y″ is independently a positive integer, preferably an integer ranging from 0 to 499, with the condition that at least one of y′ and y″ is not 0.

In one embodiment of the invention, said at least one exchanging ligand which is a copolymer is synthesized from at least 2 monomers, said monomers being:
one anchoring monomer wherein M_{A} is a dithiol group,
one hydrophilic monomer wherein M_{B} is a sulfobetaine group.

In another embodiment of the invention, said at least one exchanging ligand which is a copolymer is synthesized from at least 3 monomers, said monomers being:
one anchoring monomer as defined here above,
one hydrophilic monomer as defined here above, and
one functionalizable monomer comprising a reactive function M_{C}.

In one embodiment of the invention, said at least one exchanging ligand which is a copolymer has the following formula III:

(A)ₓ(B)_{y}(C)_{z}

wherein

A comprises at least one anchoring monomer comprising a first moiety M_{A} having affinity for the surface of a nanocrystal as described here above,

B comprises at least one hydrophilic monomer comprising a second moiety M_{B} having a high water solubility,

C comprises at least one functionalizable monomer comprising a third moiety M_{C} having a reactive function, and

each of x, y and z is independently a positive integer, preferably an integer ranging from 1 to 498.

In said embodiment, the at least one exchanging ligand which is a copolymer has the following formula IV:

[chemical structure]

wherein

R_{A}, R_{B}, R₁, R₂, R₃, R₄, R₅ and R₆ are defined here above,

R_{C} represents a group comprising the third moiety M_{C}, and

R₈, R₉ and R₁₀ can be independently H, or a group selected from an alkyl, alkenyl, aryl, hydroxyl, halogen, alcoxy, carboxylate,

each of x, y and z is independently a positive integer, preferably an integer ranging from 1 to 498.

In another embodiment of the invention, said at least one exchanging ligand which is a copolymer comprising at least 2 monomers has the following formula IV′:

[chemical structure]

wherein

R_{A}′, R_{A}″, R_{B}′, R_{B}″, R₁′, R₂′, R₃′, R₁″, R₂″, R₃″, R₄′, R₅′, R₆′, R₄″, R₅″, and R₆″ are defined here above,

R_{C}′ and R_{C}″ represent respectively a group comprising the third moiety M_{C}′ and M_{C}″, and

R₈′, R₉′, R₁₀′, R₈″, R₉″, and R₁₀″ can be independently H, or a group selected from an alkyl, alkenyl, aryl, hydroxyl, halogen, alcoxy, carboxylate,

each of x′ and x″ is independently a positive integer, preferably an integer ranging from 0 to 499, with the condition that at least one of x′ and x″ is not 0,

each of y′ and y″ is independently a positive integer, preferably an integer ranging from 0 to 499, with the condition that at least one of y′ and y″ is not 0,

each of z′ and z″ is independently a positive integer, preferably an integer ranging from 0 to 499, with the condition that at least one of z′ and z″ is not 0.

According to one embodiment, the at least one exchanging ligand which is a copolymer is obtained from at least 2 monomers, said monomers being:
one anchoring monomer M_{A} having a side-chain comprising a first moiety M_{A} having affinity for the surface of the particle 12; and
one hydrophilic monomer M_{B} having a side-chain comprising a second moiety M_{B} being hydrophilic;

and wherein one end of copolymer is H and the other end comprises a functional group or a bioactive group.

According to one embodiment, the at least one exchanging ligand which is a copolymer is of general formula (V):

H-P[(A)x-co-(B)y]n-L-R
wherein
A represents an anchoring monomer having a side-chain comprising a first moiety M_{A} having affinity for the surface of the particle 12;
B represents a hydrophilic monomer having a side-chain comprising a second moiety M_{B} being hydrophilic;
n represents a positive integer, preferably an integer ranging from 1 to 1000, preferably from 1 to 499, from 1 to 249 or from 1 to 99;
x and y represent each independently a percentage of n, wherein x and y are different from 0% of n and different from 100% of n, preferably ranging from more than 0% to less than 100% of n, preferably from more than 0% to 80% of n, from more than 0% to 50% of n; wherein x+y is equal to 100% of n;
R represents:
   a functional group selected from the group comprising —NH₂, —COOH, —OH, —SH, —CHO, ketone, halide; activated ester such as for example N-hydroxysuccinimide ester, N-hydroxyglutarimide ester or maleimide ester; activated carboxylic acid such as for example acid anhydride or acid halide; isothiocyanate; isocyanate; alkyne; azide; glutaric anhydride, succinic anhydride, maleic anhydride; hydrazide; chloroformate, maleimide, alkene,silane, hydrazone, oxime and furan; and
   a bioactive group selected from the group comprising avidin or streptavidin; antibody such as a monoclonal antibody or a single chain antibody; sugars; a protein or peptide sequence having a specific binding affinity for an affinity target, such as for example an avimer or an affibody (the affinity target may be for example a protein, a nucleic acid, a peptide, a metabolite or a small molecule), antigens, steroids, vitamins, drugs, haptens, metabolites, toxins, environmental pollutants, amino acids, peptides, proteins, aptamers, nucleic acids, nucleotides, peptide nucleic acid (PNA), folates, carbohydrates, lipids, phospholipid, lipoprotein, lipopolysaccharide, liposome hormone, polysaccharide, polymers, polyhistidine tags, fluorophores; and
L represents a bound or a spacer selected from the group comprising alkylene, alkenylene, arylene or arylalkyl linking groups having 1 to 50 chain atoms, wherein the linking group can be optionally interrupted or terminated by —O—, —S—, —NR₇—, wherein R₇ is H or alkyl, —CO—, —NHCO—, —CONH— or a combination thereof; or a spacer selected from the group comprising DNA, RNA, peptide nucleic acid (PNA), polysaccharide, peptide.

In a specific embodiment, the at least one exchanging ligand which is a copolymer is of formula (V-a):

[chemical structure]

wherein n, x, y, L, R, M_{A} and M_{B} are as defined above;

wherein q is an integer ranging from 1 to 20, preferably from 1 to 10, preferably from 1 to 5, preferably 2, 3, 4, m is an integer ranging from 1 to 20, preferably from 1 to 10, preferably from 1 to 5, preferably 2, 3, 4 and p is an integer ranging from 1 to 20, preferably from 1 to 10, preferably from 1 to 6, preferably 3, 4, 5.

In a specific embodiment, the at least one exchanging ligand which is a copolymer is of formula (V-b):

[chemical structure]

wherein n, x, y, L and R are as defined in formula (V) above; or a reduced form thereof.

In another specific embodiment, the at least one exchanging ligand which is a copolymer is of formula (V-c):

[chemical structure]

wherein n, x, y and L are as defined in formula (V) above; or a reduced form thereof.

In another specific embodiment, the at least one exchanging ligand which is a copolymer is of formula (V-d):

[chemical structure]

wherein n, x, y and L are as defined in formula (V) above; or a reduced form thereof.

In another specific embodiment, the at least one exchanging ligand which is a copolymer is of formula (V-e):

[chemical structure]

wherein n, x, y and L are as defined in formula (V) above; or a reduced form thereof.

According to one embodiment, the at least one exchanging ligand which is a copolymer is of general formula (VI):

[chemical structure]

wherein
n, x, y, L and R are as defined in formula (V);
R_{A} represents a group comprising the first moiety M_{A} having affinity for the surface of the particle 12;
R_{B} represents a group comprising the second moiety M_{B} being hydrophilic;
R¹, R², R³, R⁴, R⁵ and R⁶ represent each independently H or a group selected from the alkyl, alkenyl, aryl, hydroxyl, halogen, alkoxy and carboxylate, amide.

According to one embodiment, the at least one exchanging ligand which is a copolymer is of general formula (VII):

[chemical structure]

wherein
L and R are as defined in formula (V);

R_{A}′ and R_{A}″ represent respectively a group comprising a first moiety M_{A}′ and a group comprising a first moiety M_{A}″, said moieties M_{A}′ and M_{A}″ having affinity for the surface of the particle 12;
R_{B}′ and R_{B}″ represent respectively a group comprising a second moiety M_{B}′ and a group comprising a second moiety M_{B}″, said moieties M_{B}′ and M_{B}″ being hydrophilic;
R^{1′}, R^{2′}, R^{3′}, R^{4′}, R^{5′}, R^{6′}, R^{1″}, R^{2″}, R^{3″}, R^{4″}, R^{5″} and R^{6″} represent each independently H or a group selected from the alkyl, alkenyl, aryl, hydroxyl, halogen, alkoxy and carboxylate, amide;
n represents a positive integer, preferably an integer ranging from 1 to 1000, preferably from 1 to 499, from 1 to 249 or from 1 to 99;
x′ and x″ represent each independently a percentage of n, wherein at least one of x′ and x″ is different from 0% of n; wherein x′ and x″ are different from 100% of n, preferably x′ and x″ are ranging from more than 0% to less than 100% of n, preferably from more than 0% to 50% of n, from more than 0% to 50% of n;
y′ and y″ represent each independently a percentage of n, wherein at least one of y′ and y″ is different from 0% of n; wherein y′ and y″ are different from 100% of n, preferably y′ and y″ are from more than 0% to less than 100% of n, preferably from more than 0% to 50% of n, from more than 0% to 50% of n;
wherein x′+x″+y′+y″ is equal to 100% of n.

In another embodiment, of the invention, the at least one exchanging ligand which is a copolymer is synthesized from at least 3 monomers, said monomers being:
one anchoring monomer A as defined above,
one hydrophilic monomer B as defined above,
one hydrophobic monomer C having a side-chain comprising a hydrophobic function M_{C}, and wherein one end of copolymer is H and the other end comprises a functional group or a bioactive group.

According to one embodiment, the at least one exchanging ligand which is a copolymer is of general formula (VIII):

H-P[(A)ₓ-co-(B)_{y}-co-(C)_{z}]ₙ-L-R
wherein
A, B, L, R and n are as defined above;
C represents an hydrophobic monomer having a side-chain comprising a moiety M_{C} being hydrophobic;
x, y and z represent each independently a percentage of n, wherein x and y are different from 0% of n and different from 100% of n, preferably x, y and z are ranging from more than 0% to less than 100% of n, preferably from more than 0% to 80% of n, from more than 0% to 50% of n and wherein x+y+z is equal to 100% of n.

According to one embodiment, the at least one exchanging ligand which is a copolymer is of general formula (IX):

[chemical structure]

wherein
n, L, R, R_{A}, R_{B}, R¹, R², R³, R⁴, R⁵ and R⁶ are as defined above;
R_{C} represents a group comprising the third moiety M_{C} being hydrophobic;
R⁸, R⁹, and R¹⁹ represent each independently H or a group selected from the alkyl, alkenyl, aryl, hydroxyl, halogen, alkoxy and carboxylate, amide;
x, y and z represent each independently a percentage of n, wherein x and y are different from 0% of n and different from 100% of n, preferably x, y and z are ranging from more than 0% to less than 100% of n, preferably from more than 0% to 80% of n, from more than 0% to 50% of n; and wherein x+y+z is equal to 100% of n.

In one embodiment of the invention, x+y is ranging from 5 to 500, from 5 to 250, from 5 to 100, from 5 to 75, from 5 to 50, from 10 to 50, from 10 to 30, from 5 to 35, from 5 to 25, from 15 to 25. In one embodiment of the invention, x+y+z is ranging from 5 to 750, 5 to 500, 5 to 150, 5 to 100, 10 to 75, 10 to 50, 5 to 50, 15 to 25, 5 to 25. In one embodiment of the invention, x′+x″+y′+y″ is ranging from 5 to 500, from 5 to 250, from 5 to 100, from 5 to 75, from 5 to 50, from 10 to 50, from 10 to 30, from 5 to 35, from 5 to 25, from 15 to 25. In one embodiment of the invention, said x is equal to x′+x″. In one embodiment of the invention, said y is equal to y′+y″. In one embodiment of the invention, x′+x″+y′+y″+z′+z″ is ranging from 5 to 750, 5 to 500, 5 to 150, 5 to 100, 10 to 75, 10 to 50, 5 to 50, 15 to 25, 5 to 25. In one embodiment of the invention, said z is equal to z′+z″.

In one embodiment, the first moiety M_{A} having affinity for the surface of the particle 12 has preferably affinity for a metal present at the surface of the particle 12 or for a material present at the surface of the particle 12 and selected in the group of O, S, Se, Te, N, P, As, and mixture thereof.

In one embodiment of the invention, said at least one exchanging ligand which is a copolymer comprising at least 2 monomers has a plurality of monomers including the monomer A and the monomer B. In one embodiment, said ligand is a random or block copolymer. In another embodiment, said ligand is a random or block copolymer consisting essentially of monomer A and monomer B. In one embodiment of the invention, said ligand is a multi-dentate ligand.

In one embodiment of the invention, said first moiety M_{A} having affinity for the surface of the particle 12 and in particular affinity for a metal present at the surface of the particle 12 includes, but is not limited to, a thiol moiety, a dithiol moiety, an imidazole moiety, a catechol moiety, a pyridine moiety, a pyrrole moiety, a thiophene moiety, a thiazole moiety, a pyrazine moiety, a carboxylic acid or carboxylate moiety, a naphthyridine moiety, a phosphine moiety, a phosphine oxide moiety, a phenol moiety, a primary amine moiety, a secondary amine moiety, a tertiary amine moiety, a quaternary amine moiety, an aromatic amine moiety, or a combination thereof.

In one embodiment of the invention, said first moiety M_{A} having affinity for the surface of the particle 12 and in particular affinity for a material selected in the group of O, S, Se, Te, N, P, As, and mixture thereof, includes, but is not limited to, an imidazole moiety, a pyridine moiety, a pyrrole moiety, a thiazole moiety, a pyrazine moiety, a naphthyridine moiety, a phosphine moiety, a phosphine oxide moiety, a primary amine moiety, a secondary amine moiety, a tertiary amine moiety, a quaternary amine moiety, an aromatic amine moiety, or a combination thereof.

In one embodiment of the invention, said first moiety M_{A} is not a dihydrolipoic acid (DHLA) moiety.

In another embodiment of the invention, said first moiety M_{A} is not an imidazole moiety.

In one embodiment, monomers A and B are methacrylamide monomers.

In one embodiment of the invention, said second moiety M_{B} having a high water solubility includes, but is not limited to, a zwitterionic moiety (i.e. any compound having both a negative charge and a positive charge, preferably a group with both an ammonium group and a sulfonate group or a group with both an ammonium group and a carboxylate group) such as for example an aminocarboxylate, an aminosulfonate, a carboxybetaine moiety wherein the ammonium group may be included in an aliphatic chain, a five-membered cycle, a five-membered heterocycle comprising 1, 2 or 3 further nitrogen atoms, a six-membered cycle, a six-membered heterocycle comprising 1, 2, 3 or 4 further nitrogen atoms, a sulfobetaine moiety wherein the ammonium group may be included in an aliphatic chain, a five-membered cycle, a five-membered heterocycle comprising 1, 2 or 3 further nitrogen atoms, a six-membered cycle, a six-membered heterocycle comprising 1, 2, 3 or 4 further nitrogen atoms, a phosphobetaine wherein the ammonium group may be included in an aliphatic chain, a five-membered cycle, a five-membered heterocycle comprising 1, 2 or 3 further nitrogen atoms, a six-membered cycle, a six-membered heterocycle comprising 1, 2, 3 or 4 further nitrogen atoms, a phosphorylcholine, a phosphocholine moiety, and combinations thereof or a PEG moiety.

An example of a suitable PEG moiety is —[O—CH₂—CHR′]ₙ—R″, wherein R′ can be H or C₁-C₃ alkyl, R″ can be H, —OH, C₁-C₆ alkyl, C₁-C₆ alkoxy, aryl, aryloxy, arylalkyl, or arylalkoxy and n can be an integer in the range of 1 to 120, preferably of 1 to 60, more preferably of 1 to 30.

In one embodiment, when B comprises a monomer comprising a second moiety M_{B} which is a PEG moiety, then B further comprises at least one monomer comprising a second moiety M_{B} which is not a PEG moiety.

In another embodiment of the invention, said second moiety M_{B} having a high water solubility is not a PEG moiety.

In one embodiment of the invention, said moiety M_{A} comprises said moieties M_{A}′ and M_{A}″.

In one embodiment of the invention, said moiety M_{B} comprises said moieties M_{B}′ and M_{B}″.

In one embodiment of the invention, said first moieties M_{A}′ and M_{A}″ having affinity for the surface of the particle 12 and in particular affinity for a metal present at the surface of the particle 12 include, but is not limited to, a thiol moiety, a dithiol moiety, an imidazole moiety, a catechol moiety, a pyridine moiety, a pyrrole moiety, a thiophene moiety, a thiazole moiety, a pyrazine moiety, a carboxylic acid or carboxylate moiety, a naphthyridine moiety, a phosphine moiety, a phosphine oxide moiety, a phenol moiety, a primary amine moiety, a secondary amine moiety, a tertiary amine moiety, a quaternary amine moiety, an aromatic amine moiety, or a combination thereof.

In one embodiment of the invention, said first moieties M_{A}′ and M_{A}″ having affinity for the surface of the particle 12 and in particular affinity for a material selected in the group of O, S, Se, Te, N, P, As, and mixture thereof, include, but is not limited to, an imidazole moiety, a pyridine moiety, a pyrrole moiety, a thiazole moiety, a pyrazine moiety, a naphthyridine moiety, a phosphine moiety, a phosphine oxide moiety, a primary amine moiety, a secondary amine moiety, a tertiary amine moiety, a quaternary amine moiety, an aromatic amine moiety, or a combination thereof.

In one embodiment of the invention, said first moiety M_{A}′ having affinity for the surface of the particle 12 is a dithiol moiety and said first moiety M_{A}″ having affinity for the surface of the particle 12 is an imidazole moiety.

In one embodiment of the invention, said second moieties M_{B}′ and M_{B}″ having a high water solubility include, but is not limited to, a zwitterionic moiety (i.e. any compound having both a negative charge and a positive charge, preferably a group with both an ammonium group and a sulfonate group or a group with both an ammonium group and a carboxylate group) such as for example an aminocarboxylate, an aminosulfonate, a carboxybetaine moiety wherein the ammonium group may be included in an aliphatic chain, a five-membered cycle, a five-membered heterocycle comprising 1, 2 or 3 further nitrogen atoms, a six-membered cycle, a six-membered heterocycle comprising 1, 2, 3 or 4 further nitrogen atoms, a sulfobetaine moiety wherein the ammonium group may be included in an aliphatic chain, a five-membered cycle, a five-membered heterocycle comprising 1, 2 or 3 further nitrogen atoms, a six-membered cycle, a six-membered heterocycle comprising 1, 2, 3 or 4 further nitrogen atoms, a phosphobetaine wherein the ammonium group may be included in an aliphatic chain, a five-membered cycle, a five-membered heterocycle comprising 1, 2 or 3 further nitrogen atoms, a six-membered cycle, a six-membered heterocycle comprising 1, 2, 3 or 4 further nitrogen atoms, a phosphorylcholine, a phosphocholine moiety, and combinations thereof or a PEG moiety, or a poly(ether)glycol moiety, wherein if M_{B}′ is a PEG moiety, then M_{B}″ is not a PEG moiety and inversely.

In one embodiment of the invention, said second moiety M_{B}′ having a high water solubility is a sulfobetaine group and said second moiety M_{B}″ having a high water solubility is a PEG moiety.

In one embodiment of the invention, said third moiety M_{C} having a reactive function can form a covalent bond with a selected agent under selected conditions and includes, but is not limited to, any moiety having an amine group such as a primary amine group, any moiety having an azido group, any moiety having an halogen group, any moiety having an alkenyl group, any moiety having an alkynyl group, any moiety having an acidic function, any moiety having an activated acidic function, any moiety having an alcoholic group, any moiety having an activated alcoholic group, any moiety having a thiol group. It can also be a small molecule, such as biotin, that can bind with high affinity to a macromolecule, such as a protein or an antibody.

According to one embodiment, the reactive function of Me may be protected by any suitable protective group commonly used in the chemical practice. Protection and deprotection may be performed by any suitable method known in the art and adapted to the structure of the molecule to be protected. The reactive function of M_{c} may be protected during the synthesis of the ligand and removed after the polymerization step. The reactive group of M_{C} may alternatively be introduced in the ligand after the polymerization step.

In another embodiment of the invention, said third moiety M_{C} having a reactive function can form a non covalent bond with a selective binding counterpart and said third moiety M_{C} having a reactive function includes, but is not limited to, biotin that binds its counterpart streptavidin, a nucleic acid that binds its counterpart a sequence-complementary nucleic acid, FK506 that binds its counterpart FKBP, an antibody that binds its counterpart the corresponding antigen.

In one embodiment of the invention, R_{C} comprising the third moiety M_{C} can have the formula L_{C}-M_{C}, wherein L_{C} can be a bond or an alkylene, alkenylene, a PEG moiety, or arylene linking group having 1 to 8 chain atoms and can be optionally interrupted or terminated by —O—, —S—, —NR₇—, wherein R₇ is H or alkyl, —CO—, —NHCO—, —CONH— or a combination thereof and M_{C} corresponds to the third moiety as described here above.

An example of a suitable PEG moiety is —[O—CH₂—CHR′]ₙ—, wherein R′ can be H or C₁-C₃ alkyl, and n can be an integer in the range of 0 to 30.

According to one embodiment, the functional group is selected from the group comprising —NH₂, —COOH, —OH, —SH, —CHO, ketone, halide; activated ester such as for example N-hydroxysuccinimide ester, N-hydroxyglutarimide ester or maleimide ester; activated carboxylic acid such as for example acid anhydride or acid halide; isothiocyanate; isocyanate; alkyne; azide; glutaric anhydride, succinic anhydride, maleic anhydride; hydrazide; chloroformate, maleimide, alkene,silane, hydrazone, oxime and furan.

According to one embodiment, the bioactive group is selected from the group comprising avidin or streptavidin; antibody such as a monoclonal antibody or a single chain antibody; sugars; a protein or peptide sequence having a specific binding affinity for an affinity target, such as for example an avimer or an affibody (the affinity target may be for example a protein, a nucleic acid, a peptide, a metabolite or a small molecule), antigens, steroids, vitamins, drugs, haptens, metabolites, toxins, environmental pollutants, amino acids, peptides, proteins, aptamers, nucleic acids, nucleotides, peptide nucleic acid (PNA), folates, carbohydrates, lipids, phospholipid, lipoprotein, lipopolysaccharide, liposome hormone, polysaccharide, polymers, polyhistidine tags, fluorophores.

In one embodiment of the invention, R_{A} comprising the first moiety M_{A} can have the formula -L_{A}-M_{A}, wherein L_{A} can be a bond or an alkylene, alkenylene, or arylene linking group having 1 to 8 chain atoms and can be optionally interrupted or terminated by —O—, —S—, —NR₇—, wherein R₇ is H or alkyl, —CO—, —NHCO—, —CONH— or a combination thereof and M_{A} corresponds to the first moiety as described here above.

In one embodiment of the invention, R_{B} comprising the second moiety M_{B} can have the formula -L_{B}-M_{B}, wherein L_{B} can be a bond or an alkylene, alkenylene, or arylene linking group having 1 to 8 chain atoms and can be optionally interrupted or terminated by —O—, —S—, —NR₇—, wherein R₇ is H or alkyl, —CO—, —NHCO—, —CONH— or a combination thereof and M_{B} corresponds to the second moiety as described here above.

According to one embodiment, the at least one colloidal suspension comprising at least one particle 12 has a concentration in said particle 12 of at least 0.001%, 0.002%, 0.003%, 0.004%, 0.005%, 0.006%, 0.007%, 0.008%, 0.009%, 0.01%, 0.02%, 0.03%, 0.04%, 0.05%, 0.1%, 0.15%, 0.2%, 0.25%, 0.3%, 0.35%, 0.4%, 0.45%, 0.5%, 0.55%, 0.6%, 0.65%, 0.7%, 0.75%, 0.8%, 0.85%, 0.9%, 0.95%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, or 95% by weight.

According to one embodiment, the particle 12 is not synthetized in an aggregate 1 in situ during the method.

According to one embodiment, the particle 12 is are encapsulated into the material 11 during the formation of said material 11. For example, said particle 12 is not inserted in nor put in contact with the material 11 which have been previously obtained.

According to one embodiment, the particle 12 is not encapsulated in the aggregate 1 via physical entrapment. In this embodiment, the aggregate 1 is not a preformed particle in which particle 12 is inserted via physical entrapment.

According to one embodiment, examples of the surfactant include but are not limited to: carboxylic acids such as for example oleic acid, acetic acid, octanoic acid; thiols such as octanethiol, hexanethiol, butanethiol; 4-mercaptobenzoic acid; amines such as for example oleylamine, 1,6-hexanediamine, octylamine; phosphonic acids; antibodies; or a mixture thereof.

According to one embodiment, the method for obtaining the aggregate 1 of the invention is not surfactant-free. In this embodiment, the particles may be better stabilized in solution during the method allowing to limit or prevent any degradation of their chemical or physical properties during the method. Furthermore, the colloidal stability of aggregates 1 may be enhanced, especially it may be easier to disperse the aggregates 1 in solution at the end of the method.

According to one embodiment, the method for obtaining the aggregate 1 of the invention is surfactant-free. In this embodiment, the surface of the aggregate 1 obtained or obtainable by the method of the invention will be easy to functionalize as said surface will not be blocked by any surfactant molecule.

According to one embodiment, the means for forming droplets is a droplets former.

According to one embodiment, the means for forming droplets is configured to produce droplets.

According to one embodiment, the means for forming droplets comprises an atomizer.

According to one embodiment, the means for forming droplets is spray-drying or spray-pyrolysis.

According to one embodiment, the means for forming droplets is not spray-drying or spray-pyrolysis.

According to one embodiment, the means for forming droplets comprises an ultrasound dispenser, or a drop by drop delivering system using gravity, centrifuge force or static electricity.

According to one embodiment, the means for forming droplets comprises a tube or a cylinder.

According to one embodiment, the solution comprising at least one precursor of a material 11 and the colloidal suspension comprising at least one particle 12 are homogeneously mixed.

According to one embodiment, the solution comprising at least one precursor of a material 11 and the colloidal suspension comprising at least one particle 12 are not miscible.

According to one embodiment, the droplets are spherical.

According to one embodiment, the droplets are polydisperse.

According to one embodiment, the droplets are monodisperse.

According to one embodiment, the size of the aggregates 1 is correlated to the diameter of the droplets. The smaller the size of the droplets, the smaller the size of the resulting aggregates 1.

According to one embodiment, the size of the aggregates 1 is smaller than the diameter of the droplets.

According to one embodiment, the droplets have a diameter of at least 10 nm, 50 nm, 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 50 μm, 100 μm, 150 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, 1 mm, 1.1 mm, 1.2 mm, 1 3 mm, 1 4 mm, 1.5 mm, 1.6 mm, 1.7 mm, 1 8 mm, 1 9 mm, 2 mm, 2 1 mm, 2 2 mm, 2.3 mm, 2 4 mm, 2.5 mm, 2.6 mm, 2 7 mm, 2.8 mm, 29 mm, 3 mm, 31 mm, 32 mm, 33 mm, 3.4 mm, 35 mm, 3.6 mm, 3.7 mm, 3.8 mm, 3.9 mm, 4 mm, 4 1 mm, 4.2 mm, 4 3 mm, 4 4 mm, 4 5 mm, 4 6 mm, 4.7 mm, 4.8 mm, 4.9 mm, 5 mm, 5.1 mm, 5.2 mm, 5.3 mm, 5.4 mm, 5 5 mm, 5 6 mm, 5 7 mm, 5.8 mm, 5.9 mm, 6 mm, 6.1 mm, 6.2 mm, 6.3 mm, 6.4 mm, 6.5 mm, 6 6 mm, 6 7 mm, 6 8 mm, 6.9 mm, 7 mm, 7.1 mm, 7.2 mm, 7.3 mm, 7.4 mm, 7.5 mm, 7.6 mm, 7 7 mm, 7 8 mm, 7.9 mm, 8 mm, 8.1 mm, 8.2 mm, 8.3 mm, 8.4 mm, 8.5 mm, 8.6 mm, 8.7 mm, 8 8 mm, 8 9 mm, 9 mm, 9.1 mm, 9.2 mm, 9.3 mm, 9.4 mm, 9.5 mm, 9 6 mm, 9 7 mm, 9 8 mm, 9.9 mm, 1 cm, 1.5 cm, or 2 cm.

According to one embodiment, the droplets are dispersed in a gas flow, wherein the gas includes but is not limited to: air, nitrogen, argon, dihydrogen, dioxygen, helium, carbon dioxide, carbon monoxide, NO, NO₂, N₂O, F₂, Cl₂, H₂Se, CH₄, PH₃, NH₃, SO₂, H₂S or a mixture thereof.

According to one embodiment, the gas flow has a rate ranging from 0.01 to 1×10¹⁰ cm³/s.

According to one embodiment, the gas flow has a rate of at least 0.01 cm³/s, 0.02 cm³/s, 0.03 cm³/s, 0.04 cm³/s, 0.05 cm³/s, 0.06 cm³/s, 0.07 cm³/s, 0.08 cm³/s, 0.09 cm³/s, 0.1 cm³/s, 0.15 cm³/s, 0.25 cm³/s, 0.3 cm³/s, 0.35 cm³/s, 0.4 cm³/s, 0.45 cm³/s, 0.5 cm³/s, 0.55 cm³/s, 0.6 cm³/s, 0.65 cm³/s, 0.7 cm³/s, 0.75 cm³/s, 0.8 cm³/s, 0.85 cm³/s, 0.9 cm³/s, 0.95 cm³/s, 1 cm³/s, 1.5 cm³/s, 2 cm³/s, 2.5 cm³/s, 3 cm³/s, 3.5 cm³/s, 4 cm³/s, 4.5 cm³/s, 5 cm³/s, 5.5 cm³/s, 6 cm³/s, 6.5 cm³/s, 7 cm³/s, 7.5 cm³/s, 8 cm³/s, 8.5 cm³/s, 9 cm³/s, 9.5 cm³/s, 10 cm³/s, 15 cm³/s, 20 cm³/s, 25 cm³/s, 30 cm³/s, 35 cm³/s, 40 cm³/s, 45 cm³/s, 50 cm³/s, 55 cm³/s, 60 cm³/s, 65 cm³/s, 70 cm³/s, 75 cm³/s, 80 cm³/s, 85 cm³/s, 90 cm³/s, 95 cm³/s, 100 cm³/s, 5×10² cm³/s, 1×10³ cm³/s, 5×10³ cm³/s, 1×10⁴cm³/s, 5×10⁴cm³/s, 1×10⁵ cm³/s, 5×10⁵ cm³/s, or 1×10⁶ cm³/s.

According to one embodiment, the gas inlet pressure is at least 0, 0.5, 1, 1.5, 2, 2.5, 3, 3.5, 4, 4.5, 5, 5.5, 6, 6.5, 7, 7.5, 8, 8.5, 9, 9.5, or 10 bar.

According to one embodiment, the feed rate of mixing solution, i.e. the flow of mixing solution sprayed into the device, is in the range from 1 mL/h to 10000 mL/h, from 5 mL/h to 5000 mL/h, from 10 mL/h to 2000 mL/h, from 30 mL/h to 1000 mL/h.

According to one embodiment, the feed rate of mixing solution is at least 1 mL/h, 1.5 mL/h, 2.5 mL/h, 3 mL/h, 3.5 mL/h, 4 mL/h, 4.5 mL/h, 5 mL/h, 5.5 mL/h, 6 mL/h, 6.5 mL/h, 7 mL/h, 7.5 mL/h, 8 mL/h, 8.5 mL/h, 9 mL/h, 9.5 mL/h, 10 mL/h, 10.5 mL/h, 11 mL/h, 11.5 mL/h, 12 mL/h, 12.5 mL/h, 13 mL/h, 13.5 mL/h, 14 mL/h, 14.5 mL/h, 15 mL/h, 15.5 mL/h, 16 mL/h, 16.5 mL/h, 17 mL/h, 17.5 mL/h, 18 mL/h, 18.5 mL/h, 19 mL/h, 19.5 mL/h, 20 mL/h, 20.5 mL/h, 21 mL/h, 21.5 mL/h, 22 mL/h, 22.5 mL/h, 23 mL/h, 23.5 mL/h, 24 mL/h, 24.5 mL/h, 25 mL/h, 25.5 mL/h, 26 mL/h, 26.5 mL/h, 27 mL/h, 27.5 mL/h, 28 mL/h, 28.5 mL/h, 29 mL/h, 29.5 mL/h, 30 mL/h, 30.5 mL/h, 31 mL/h, 31.5 mL/h, 32 mL/h, 32.5 mL/h, 33 mL/h, 33.5 mL/h, 34 mL/h, 34.5 mL/h, 35 mL/h, 35.5 mL/h, 36 mL/h, 36.5 mL/h, 37 mL/h, 37.5 mL/h, 38 mL/h, 38.5 mL/h, 39 mL/h, 39.5 mL/h, 40 mL/h, 40.5 mL/h, 41 mL/h, 41.5 mL/h, 42 mL/h, 42.5 mL/h, 43 mL/h, 43.5 mL/h, 44 mL/h, 44.5 mL/h, 45 mL/h, 45.5 mL/h, 46 mL/h, 46.5 mL/h, 47 mL/h, 47.5 mL/h, 48 mL/h, 48.5 mL/h, 49 mL/h, 49.5 mL/h, 50 mL/h, 50.5 mL/h, 51 mL/h, 51.5 mL/h, 52 mL/h, 52.5 mL/h, 53 mL/h, 53.5 mL/h, 54 mL/h, 54.5 mL/h, 55 mL/h, 55.5 mL/h, 56 mL/h, 56.5 mL/h, 57 mL/h, 57.5 mL/h, 58 mL/h, 58.5 mL/h, 59 mL/h, 59.5 mL/h, 60 mL/h, 60.5 mL/h, 61 mL/h, 61.5 mL/h, 62 mL/h, 62.5 mL/h, 63 mL/h, 63.5 mL/h, 64 mL/h, 64.5 mL/h, 65 mL/h, 65.5 mL/h, 66 mL/h, 66.5 mL/h, 67 mL/h, 67.5 mL/h, 68 mL/h, 68.5 mL/h, 69 mL/h, 69.5 mL/h, 70 mL/h, 70.5 mL/h, 71 mL/h, 71.5 mL/h, 72 mL/h, 72.5 mL/h, 73 mL/h, 73.5 mL/h, 74 mL/h, 74.5 mL/h, 75 mL/h, 75.5 mL/h, 76 mL/h, 76.5 mL/h, 77 mL/h, 77.5 mL/h, 78 mL/h, 78.5 mL/h, 79 mL/h, 79.5 mL/h, 80 mL/h, 80.5 mL/h, 81 mL/h, 81.5 mL/h, 82 mL/h, 82.5 mL/h, 83 mL/h, 83.5 mL/h, 84 mL/h, 84.5 mL/h, 85 mL/h, 85.5 mL/h, 86 mL/h, 86.5 mL/h, 87 mL/h, 87.5 mL/h, 88 mL/h, 88.5 mL/h, 89 mL/h, 89.5 mL/h, 90 mL/h, 90.5 mL/h, 91 mL/h, 91.5 mL/h, 92 mL/h, 92.5 mL/h, 93 mL/h, 93.5 mL/h, 94 mL/h, 94.5 mL/h, 95 mL/h, 95.5 mL/h, 96 mL/h, 96.5 mL/h, 97 mL/h, 97.5 mL/h, 98 mL/h, 98.5 mL/h, 99 mL/h, 99.5 mL/h, 100 mL/h, 200 mL/h, 250 mL/h, 300 mL/h, 350 mL/h, 400 mL/h, 450 mL/h, 500 mL/h, 550 mL/h, 600 mL/h, 650 mL/h, 700 mL/h, 750 mL/h, 800 mL/h, 850 mL/h, 900 mL/h, 950 mL/h, 1000 mL/h, 1500 mL/h, 2000 mL/h, 2500 mL/h, 3000 mL/h, 3500 mL/h, 4000 mL/h, 4500 mL/h, 5000 mL/h, 5500 mL/h, 6000 mL/h, 6500 mL/h, 7000 mL/h, 7500 mL/h, 8000 mL/h, 8500 mL/h, 9000 mL/h, 9500 mL/h, or 10000 mL/h.

According to one embodiment, the droplets are heated at a temperature sufficient to evaporate the solvent from the said droplets.

According to one embodiment, the droplets are heated at least at 0° C., 10° C., 15° C., 20° C., 25° C., 50° C., 100° C., 150° C., 200° C., 250° C., 300° C., 350° C., 400° C., 450° C., 500° C., 550° C., 600° C., 650° C., 700° C., 750° C., 800° C., 850° C., 900° C., 950° C., 1000° C., 1050° C., 1100° C., 1150° C., 1200° C., 1250° C., 1300° C., 1350° C., or 1400° C.

According to one embodiment, the droplets are heated at less than 0° C., 10° C., 15° C., 20° C., 25° C., 50° C., 100° C., 150° C., 200° C., 250° C., 300° C., 350° C., 400° C., 450° C., 500° C., 550° C., 600° C., 650° C., 700° C., 750° C., 800° C., 850° C., 900° C., 950° C., 1000° C., 1050° C., 1100° C., 1150° C., 1200° C., 1250° C., 1300° C., 1350° C., or 1400° C.

According to one embodiment, the droplets are dried at least at 0° C., 25° C., 50° C., 100° C., 150° C., 200° C., 250° C., 300° C., 350° C., 400° C., 450° C., 500° C., 550° C., 600° C., 650° C., 700° C., 750° C., 800° C., 850° C., 900° C., 950° C., 1000° C., 1050° C., 1100° C., 1150° C., 1200° C., 1250° C., 1300° C., 1350° C., or 1400° C.

According to one embodiment, the droplets are dried at less than 0° C., 25° C., 50° C., 100° C., 150° C., 200° C., 250° C., 300° C., 350° C., 400° C., 450° C., 500° C., 550° C., 600° C., 650° C., 700° C., 750° C., 800° C., 850° C., 900° C., 950° C., 1000° C., 1050° C., 1100° C., 1150° C., 1200° C., 1250° C., 1300° C., 1350° C., or 1400° C.

According to one embodiment, the droplets are not heated.

According to one embodiment, the time of heating step is at least 0.1 seconds, 0.2 seconds, 0.3 seconds, 0.4 seconds, 0.5 seconds, 1 second, 1.5 seconds, 2 seconds, 2.5 seconds, 3 seconds, 3.5 seconds, 4 seconds, 4.5 seconds, 5 seconds, 5.5 seconds, 6 seconds, 6.5 seconds, 7 seconds, 7.5 seconds, 8 seconds, 8.5 seconds, 9 seconds, 9.5 seconds, 10 seconds, 10.5 seconds, 11 seconds, 11.5 seconds, 12 seconds, 12.5 seconds, 13 seconds, 13.5 seconds, 14 seconds, 14.5 seconds, 15 seconds, 15.5 seconds, 16 seconds, 16.5 seconds, 17 seconds, 17.5 seconds, 18 seconds, 18.5 seconds, 19 seconds, 19.5 seconds, 20 seconds, 21 seconds, 22 seconds, 23 seconds, 24 seconds, 25 seconds, 26 seconds, 27 seconds, 28 seconds, 29 seconds, 30 seconds, 31 seconds, 32 seconds, 33 seconds, 34 seconds, 35 seconds, 36 seconds, 37 seconds, 38 seconds, 39 seconds, 40 seconds, 41 seconds, 42 seconds, 43 seconds, 44 seconds, 45 seconds, 46 seconds, 47 seconds, 48 seconds, 49 seconds, 50 seconds, 51 seconds, 52 seconds, 53 seconds, 54 seconds, 55 seconds, 56 seconds, 57 seconds, 58 seconds, 59 seconds, or 60 seconds.

According to one embodiment, the droplets are heated using a flame.

According to one embodiment, the droplets are heated using a heat gun.

According to one embodiment, the heating step takes place in a tubular furnace.

According to one embodiment, the droplets are heated by convection as heat transfer.

According to one embodiment, the droplets are heated by infra-red radiation.

According to one embodiment, the droplets are heated by micro-waves.

According to one embodiment, the aggregates 1 are cooled down at a temperature inferior to the heating temperature.

According to one embodiment, the aggregates 1 are cooled down at a temperature of at least −200° C., −180° C., −160° C., −140° C., −120° C., −100° C., −80° C., −60° C., −40° C., −20° C., 0° C., 20° C., 40° C., 60° C., 80° C., or 100° C.

According to one embodiment, the cooling step is fact and the time of cooling step is at least 0.1° C./s, 1° C./s, 10° C./sec, 50° C./sec, 100° C./sec, 150° C./sec, 200° C./sec, 250° C./sec, 300° C./sec, 350° C./sec, 400° C./sec, 450° C./sec, 500° C./sec, 550° C./sec, 600° C./sec, 650° C./sec, 700° C./sec, 750° C./sec, 800° C./sec, 850° C./sec, 900° C./sec, 950° C./sec, or 1000° C./sec.

According to one embodiment, the aggregates 1 are not separated depending on their size and are collected using a unique membrane filter with a pore size ranging from 1 nm to 300 μm.

According to one embodiment, the aggregates 1 are not separated depending on their size and are collected using at least two membrane filters with a pore size ranging from 1 nm to 300 μm.

According to one embodiment, the aggregates 1 are separated and collected depending on their size using at least two successive membrane filters with different pore sizes ranging from 1 nm to 300 μm.

According to one embodiment, the membrane filter includes but is not limited to: hydrophobic polytetrafluoroethylene, hydrophilic polytetrafluoroethylene, polyethersulfone, nylon, cellulose, glass fibers, polycarbonate, polypropylene, polyvinyl chloride, polyvinylidene fluoride, silver, polyolefin, polypropylene prefilter, or a mixture thereof.

According to one embodiment, the aggregates 1 are collected as powder from the membrane filter by scrubbing the membrane filter.

According to one embodiment, the aggregates 1 are collected as powder on a conveyor belt used as membrane filter. In this embodiment, said conveyor belt is activated to collect the powder continueously during the method by scrubbing said conveyor belt.

According to one embodiment, the conveyor belt used as membrane filter has a pore size ranging from 1 nm to 300 μm.

According to one embodiment, the aggregates 1 are collected from the membrane filter by sonicating said membrane filter in an organic solvent.

According to one embodiment, the aggregates 1 are collected from the membrane filter by sonicating said membrane filter in an aqueous solvent.

According to one embodiment, the aggregates 1 are collected from the membrane filter by sonicating said membrane filter in a polar solvent.

According to one embodiment, the aggregates 1 are collected from the membrane filter by sonicating said membrane filter in an apolar solvent.

According to one embodiment, the aggregates 1 are separated and collected depending on their size.

According to one embodiment, the aggregates 1 are separated and collected depending on their loading charge.

According to one embodiment, the aggregates 1 are separated and collected depending on their packing fraction.

According to one embodiment, the aggregates 1 are separated and collected depending on their chemical composition.

According to one embodiment, the aggregates 1 are separated and collected depending on their specific property.

According to one embodiment, the aggregates 1 are separated and collected depending on their size using a temperature induced separation, or magnetic induced separation.

According to one embodiment, the aggregates 1 are separated and collected depending on their size using an electrostatic precipitator.

According to one embodiment, the aggregates 1 are separated and collected depending on their size using a sonic or gravitational dust collector.

According to one embodiment, the aggregates 1 are separated depending on their size by using a cyclonic separation.

According to one embodiment, the aggregates 1 are collected in a spiral-shaped tube. In this embodiment, the aggregates 1 will deposit on the inner walls of said tube, then the aggregates 1 can be recovered by the introduction of an organic or aqueous solvent into said tube.

According to one embodiment, the aggregates 1 are collected in an aqueous solution containing potassium ions.

According to one embodiment, the aggregates 1 are collected in an aqueous solution.

According to one embodiment, the aggregates 1 are collected in an organic solution.

According to one embodiment, the aggregates 1 are collected in a polar solvent.

According to one embodiment, the aggregates 1 are collected in an apolar solvent.

According to one embodiment, the aggregates 1 are collected onto a support comprising a material such as for example silica, quartz, silicon, gold, copper, Al₂O₃, ZnO, SnO₂, MgO, GaN, GaSb, GaAs, GaAsP, GaP, InP, SiGe, InGaN, GaAlN, GaAlPN, AlN, AlGaAs, AlGaP, AlGaInP, AlGaN, AlGaInN, ZnSe, Si, SiC, diamond, boron nitride.

In one embodiment, the support is reflective.

In one embodiment, the support comprises a material allowing to reflect the light such as for example a metal like aluminium or silver, a glass, a polymer.

In one embodiment, the support is as described hereabove.

According to one embodiment, the substrate comprises Au, Ag, Pt, Ru, Ni, Co, Cr, Cu, Sn, Rh Pd, Mn, Ti or a mixture thereof.

According to one embodiment, the substrate comprises silicon oxide, aluminium oxide, titanium oxide, copper oxide, iron oxide, silver oxide, lead oxide, calcium oxide, magnesium oxide, zinc oxide, tin oxide, beryllium oxide, zirconium oxide, niobium oxide, cerium oxide, iridium oxide, scandium oxide, nickel oxide, sodium oxide, barium oxide, potassium oxide, vanadium oxide, tellurium oxide, manganese oxide, boron oxide, phosphorus oxide, germanium oxide, osmium oxide, rhenium oxide, platinum oxide, arsenic oxide, tantalum oxide, lithium oxide, strontium oxide, yttrium oxide, hafnium oxide, tungsten oxide, molybdenum oxide, chromium oxide, technetium oxide, rhodium oxide, ruthenium oxide, cobalt oxide, palladium oxide, cadmium oxide, mercury oxide, thallium oxide, gallium oxide, indium oxide, bismuth oxide, antimony oxide, polonium oxide, selenium oxide, cesium oxide, lanthanum oxide, praseodymium oxide, neodymium oxide, samarium oxide, europium oxide, terbium oxide, dysprosium oxide, erbium oxide, holmium oxide, thulium oxide, ytterbium oxide, lutetium oxide, gadolinium oxide, mixed oxides, mixed oxides thereof or a mixture thereof.

According to one embodiment, the aggregates 1 are suspended in an inert gas such as He, Ne, Ar, Kr, Xe or N₂.

According to one embodiment, the aggregates 1 are collected onto a functionalized support.

According to one embodiment, the functionalized support is functionalized with a specific-binding component, wherein said specific-binding component includes but is not limited to: antigens, steroids, vitamins, drugs, haptens, metabolites, toxins, environmental pollutants, amino acids, peptides, proteins, antibodies, polysaccharides, nucleotides, nucleosides, oligonucleotides, psoralens, hormones, nucleic acids, nucleic acid polymers, carbohydrates, lipids, phospholipids, lipoproteins, lipopolysaccharides, liposomes, lipophilic polymers, synthetic polymers, polymeric microparticles, biological cells, virus and combinations thereof. Preferred peptides include, but are not limited to: neuropeptides, cytokines, toxins, protease substrates, and protein kinase substrates. Preferred protein conjugates include enzymes, antibodies, lectins, glycoproteins, histones, albumins, lipoproteins, avidin, streptavidin, protein A, protein G, phycobiliproteins and other fluorescent proteins, hormones, toxins and growth factors. Preferred nucleic acid polymers are single- or multi-stranded, natural or synthetic DNA or RNA oligonucleotides, or DNA/RNA hybrids, or incorporating an unusual linker such as morpholine derivatized phosphides, or peptide nucleic acids such as N-(2-aminoethyl)glycine units, where the nucleic acid contains fewer than 50 nucleotides, more typically fewer than 25 nucleotides. The functionalization of the functionalized support can be made using techniques known in the art.According to one embodiment, the aggregates 1 are dispersed in water.

According to one embodiment, the aggregates 1 are dispersed in an organic solvent, wherein said organic solvent includes but is not limited to: hexane, heptane, pentane, octane, decane, dodecane, toluene, tetrahydrofuran, chloroform, acetone, acetic acid, n-methylformamide, n,n-dimethylformamide, dimethylsulfoxide, octadecene, squalene, amines such as for example tri-n-octylamine, 1,3-diaminopropane, oleylamine, hexadecylamine, octadecylamine, squalene, alcohols such as for example ethanol, methanol, isopropanol, 1-butanol, 1-hexanol, 1-decanol, propane-2-ol, ethanediol, 1,2-propanediol or a mixture thereof.

According to one embodiment, the aggregates 1 are sonicated in a solution. This embodiment allows dispersion of said aggregates 1 in solution.

According to one embodiment, the aggregates 1 are dispersed in a solution comprising at least one surfactant described here above. This embodiment prevents the aggregation of said aggregates 1 in solution.

According to one embodiment, the method for obtaining the aggregate 1 of the invention does not comprise an additional heating step to heat the aggregate 1 after the final step of the method of the invention, the temperature of this additional heating step being at least 100° C., 150° C., 200° C., 250° C., 300° C., 350° C., 400° C., 450° C., 500° C., 550° C., 600° C., 650° C., 700° C., 750° C., 800° C., 850° C., 900° C., 950° C., 1000° C., 1050° C., 1100° C., 1150° C., 1200° C., 1250° C., 1300° C., 1350° C., 1400° C., 1450° C., or 1500° C. Indeed, an additional heating step, especially at high temperature, may cause the degradation of the specific property of the particle 12, for example it may cause the quenching of the fluorescence for fluorescent particles comprised in aggregates 1.

According to one embodiment, the method for obtaining the aggregate 1 of the invention further comprises an additional heating step to heat the aggregate 1. In this embodiment, said additional heating step takes place after the final step of the method of the invention.

According to one embodiment, the temperature of the additional heating step is at least 50° C., 100° C., 150° C., 200° C., 250° C., 300° C., 350° C., 400° C., 450° C., 500° C., 550° C., 600° C., 650° C., 700° C., 750° C., 800° C., 850° C., 900° C., 950° C., 1000° C., 1050° C., 1100° C., 1150° C., 1200° C., 1250° C., 1300° C., 1350° C., 1400° C., 1450° C., or 1500° C.

According to one embodiment, the time of the additional heating step is at least 5 min, 10 min, 15 min, 20 min, 25 min, 30 min, 35 min, 40 min, 45 min, 50 min, 55 min, 60 min, 1.5 hours, 2 hours, 2.5 hours, 3 hours, 3.5 hours, 4 hours, 4.5 hours, 5 hours, 5.5 hours, 6 hours, 6.5 hours, 7 hours, 7.5 hours, 8 hours, 8.5 hours, 9 hours, 9.5 hours, 10 hours, 11 hours, 12 hours, 13 hours, 14 hours, 15 hours, 16 hours, 17 hours, 18 hours, 19 hours, 20 hours, 21 hours, 22 hours, 23 hours, 24 hours, 30 hours, 36 hours, 42 hours, 48 hours, 54 hours, 60 hours, 66 hours, 72 hours, 78 hours, 84 hours, 90 hours, 96 hours, 102 hours, 108 hours, 114 hours, 120 hours, 126 hours, 132 hours, 138 hours, 144 hours, 150 hours, 156 hours, 162 hours or 168 hours.

According to one embodiment, the method for obtaining the aggregate 1 of the invention further comprises a step of functionalization of said aggregate 1.

According to one embodiment, the aggregate 1 is functionalized as described hereabove.

According to one embodiment, the method further comprises a step of forming a shell on the aggregate 1, hereafter referred as “shell forming step”.

According to one embodiment, the method further comprises a step of encapsulating the aggregate 1 in a bead 3, hereafter referred as “encapsulating step”.

According to one embodiment, prior the shell forming step and/or the encapsulating step, said aggregates 1 are separated, collected, dispersed and/or suspended as described hereabove.

According to one embodiment, prior the shell forming step and/or the encapsulating step, said aggregates 1 are not separated, collected, dispersed and/or suspended.

According to one embodiment, the shell forming step and/or the encapsulating step comprises directing the aggregates 1 suspended in a gas flow to a tube wherein droplets of a solution A are added in said gas flow during step (c). The resulting particles and/or aggregates are collected as described hereabove.

According to one embodiment, the shell forming step and/or the encapsulating step comprises directing the aggregates 1 suspended in a gas to a tube wherein they are placed in the presence of at least one molecule comprising silicon, boron, phosphorus, germanium, arsenic, aluminium, iron, titanium, zirconium, nickel, zinc, calcium, sodium, barium, potassium, magnesium, lead, silver, vanadium, tellurium, manganese, iridium, scandium, niobium, tin, cerium, beryllium, tantalum, sulfur, selenium, nitrogen, fluorine, chlorine cadmium, sulfur, selenium, indium, tellurium, mercury, tin, copper, nitrogen, gallium, antimony, thallium, molybdenum, palladium, cerium, tungsten, cobalt, manganese, or a mixture thereof; and molecular oxygen to form a shell or a bead of the corresponding oxide, mixed oxides, mixed oxides thereof or a mixture thereof.

According to one embodiment, the shell forming step and/or the encapsulating step comprises directing the aggregates 1 suspended in a gas to a tube wherein they are alternatively placed in the presence of molecules comprising silicon, boron, phosphorus, germanium, arsenic, aluminium, iron, titanium, zirconium, nickel, zinc, calcium, sodium, barium, potassium, magnesium, lead, silver, vanadium, tellurium, manganese, iridium, scandium, niobium, tin, cerium, beryllium, tantalum, sulfur, selenium, nitrogen, fluorine, chlorine cadmium, sulfur, selenium, indium, tellurium, mercury, tin, copper, nitrogen, gallium, antimony, thallium, molybdenum, palladium, cerium, tungsten, cobalt, manganese, or a mixture thereof; and molecular oxygen to form a shell or a bead of the corresponding oxide, mixed oxides, mixed oxides thereof or a mixture thereof.

According to one embodiment, the shell forming step and/or the encapsulating step may be repeated at least twice using different or same molecules comprising silicon, boron, phosphorus, germanium, arsenic, aluminium, iron, titanium, zirconium, nickel, zinc, calcium, sodium, barium, potassium, magnesium, lead, silver, vanadium, tellurium, manganese, iridium, scandium, niobium, tin, cerium, beryllium, tantalum, sulfur, selenium, nitrogen, fluorine, chlorine cadmium, sulfur, selenium, indium, tellurium, mercury, tin, copper, nitrogen, gallium, antimony, thallium, molybdenum, palladium, cerium, tungsten, cobalt, manganese, or a mixture thereof. In this embodiment, the thickness of the shell is increased.

According to one embodiment, the shell forming step and/or the encapsulating step comprises directing the aggregates 1 suspended in a gas to a tube wherein they are subjected to an Atomic Layer Deposition (ALD) process to form a shell and/or a bead on aggregates 1, said shell and/or bead comprising silicon oxide, aluminium oxide, titanium oxide, copper oxide, iron oxide, silver oxide, lead oxide, calcium oxide, magnesium oxide, zinc oxide, tin oxide, beryllium oxide, zirconium oxide, niobium oxide, cerium oxide, iridium oxide, scandium oxide, nickel oxide, sodium oxide, barium oxide, potassium oxide, vanadium oxide, tellurium oxide, manganese oxide, boron oxide, phosphorus oxide, germanium oxide, osmium oxide, rhenium oxide, platinum oxide, arsenic oxide, tantalum oxide, lithium oxide, strontium oxide, yttrium oxide, hafnium oxide, tungsten oxide, molybdenum oxide, chromium oxide, technetium oxide, rhodium oxide, ruthenium oxide, cobalt oxide, palladium oxide, cadmium oxide, mercury oxide, thallium oxide, gallium oxide, indium oxide, bismuth oxide, antimony oxide, polonium oxide, selenium oxide, cesium oxide, lanthanum oxide, praseodymium oxide, neodymium oxide, samarium oxide, europium oxide, terbium oxide, dysprosium oxide, erbium oxide, holmium oxide, thulium oxide, ytterbium oxide, lutetium oxide, gadolinium oxide, mixed oxides, mixed oxides thereof or a mixture thereof.

According to one embodiment, the shell forming step and/or the encapsulating step by ALD may be repeated at least twice using different or same shell and/or bead precursors. In this embodiment, the thickness of the shell is increased.

According to one embodiment, the tube for the shell forming step and/or the encapsulating step may be straight, spiral or ring-shaped.

According to one embodiment, during the shell forming step and/or the encapsulating step, the aggregates 1 may be deposited on a support as described hereabove. In this embodiment, said support is in the tube, or is the tube itself.

According to one embodiment, the shell forming step and/or the encapsulating step comprises dispersing the aggregates 1 in a solvent and subjecting them to a heating step as described hereabove.

According to one embodiment, the shell forming step and/or the encapsulating step comprises dispersing the aggregates 1 in a solvent and subjecting them to the method of the invention. In this embodiment, the method of the invention can be repeated with the aggregates 1 at least once, or several times to obtain at least one or several shells respectively.

According to one embodiment, after the shell forming step and/or the encapsulating step, the aggregates 1 are separated, collected, dispersed and/or suspended as described hereabove.

According to one embodiment, the size of the aggregates 1 can be controlled by the heating temperature, the heating time, the cooling temperature, the quantity of solution comprising at least one precursor of a material 11 and/or colloidal suspension comprising at least one particle 12, the concentration of solution comprising at least one precursor of a material 11 and/or colloidal suspension comprising at least one particle 12, the hydrolysis time, the hydrolysis temperature, the particle 12 concentration in the colloidal suspension of particle 12, the nature of the acid and/or the base in solution comprising at least one precursor of a material 11 and/or colloidal suspension comprising at least one particle 12, the nature of the organic solvent, the nature of the gases injected into the system, or the geometry and the dimensions of the various elements of the device implementing the method.

According to one embodiment, the size distribution of the aggregates 1 can be controlled by the heating temperature, the heating time, the cooling temperature, the quantity of solution comprising at least one precursor of a material 11 and/or colloidal suspension comprising at least one particle 12, the concentration of solution comprising at least one precursor of a material 11 and/or colloidal suspension comprising at least one particle 12, the hydrolysis time, the hydrolysis temperature, the particle 12 concentration in the colloidal suspension of particle 12, the nature of the acid and/or the base in solution comprising at least one precursor of a material 11 and/or colloidal suspension comprising at least one particle 12, the nature of the organic solvent, the nature of the gases injected into the system, or the geometry and the dimensions of the various elements of the device implementing the method.

According to one embodiment, the degree of filling of the aggregates 1 by the particle 12 can be controlled by the heating temperature, the heating time, the cooling temperature, the quantity of solution comprising at least one precursor of a material 11 and/or colloidal suspension comprising at least one particle 12, the concentration of solution comprising at least one precursor of a material 11 and/or colloidal suspension comprising at least one particle 12, the hydrolysis time, the hydrolysis temperature, the particle 12 concentration in the colloidal suspension of particle 12, the nature of the acid and/or the base in solution comprising at least one precursor of a material 11 and/or colloidal suspension comprising at least one particle 12, the nature of the organic solvent, the nature of the gases injected into the system, or the geometry and the dimensions of the various elements of the device implementing the method.

According to one embodiment, the density of the aggregates 1 can be controlled by the heating temperature, the heating time, the cooling temperature, the quantity of solution comprising at least one precursor of a material 11 and/or colloidal suspension comprising at least one particle 12, the concentration of solution comprising at least one precursor of a material 11 and/or colloidal suspension comprising at least one partice 12, the hydrolysis time, the hydrolysis temperature, the particle 12 concentration in the colloidal suspension of partice 12, the nature of the acid and/or the base in solution comprising at least one precursor of a material 11 and/or colloidal suspension comprising at least one partice 12, the nature of the organic solvent, the nature of the gases injected into the system, or the geometry and the dimensions of the various elements of the device implementing the method.

According to one embodiment, the porosity of the aggregates 1 can be controlled by the heating temperature, the heating time, the cooling temperature, the quantity of solution comprising at least one precursor of a material 11 and/or colloidal suspension comprising at least one partice 12, the concentration of solution comprising at least one precursor of a material 11 and/or colloidal suspension comprising at least one partice 12, the hydrolysis time, the hydrolysis temperature, the particle 12 concentration in the colloidal suspension of partice 12, the nature of the acid and/or the base in solution comprising at least one precursor of a material 11 and/or colloidal suspension comprising at least one partice 12, the nature of the organic solvent, the nature of the gases injected into the system, or the geometry and the dimensions of the various elements of the device implementing the method.

According to one embodiment, the permeability of the aggregates 1 can be controlled by the heating temperature, the heating time, the cooling temperature, the quantity of solution comprising at least one precursor of a material 11 and/or colloidal suspension comprising at least one particle 12, the concentration of solution comprising at least one precursor of a material 11 and/or colloidal suspension comprising at least one partice 12, the hydrolysis time, the hydrolysis temperature, the particle 12 concentration in the colloidal suspension of partice 12, the nature of the acid and/or the base in solution comprising at least one precursor of a material 11 and/or colloidal suspension comprising at least one partice 12, the nature of the organic solvent, the nature of the gases injected into the system, or the geometry and the dimensions of the various elements of the device implementing the method.

According to one embodiment, the transition from a metastable state to a more stable state of the aggregates 1 an/or the height of the energetic barrier between the metastable state and the more stable state can be tuned by the heating temperature, the heating time, the cooling temperature, the quantity of solution comprising at least one precursor of a material 11 and/or colloidal suspension comprising at least one partice 12, the concentration of solution comprising at least one precursor of a material 11 and/or colloidal suspension comprising at least one partice 12, the hydrolysis time, the hydrolysis temperature, the particle 12 concentration in the colloidal suspension of partice 12, the nature of the acid and/or the base in solution comprising at least one precursor of a material 11 and/or colloidal suspension comprising at least one partice 12, the nature of the organic solvent, the nature of the gases injected into the system, or the geometry and the dimensions of the various elements of the device implementing the method.

According to one embodiment, the method of the invention does not comprises the following steps: preparing an aqueous or organic solution of particles 12, immersing a nanometer pore glass in said solution for at least ten minutes, taking the immersed nanometer pore glass out of the solution and drying it in the air, wrapping and packaging the nanometer pore glass with resin, and solidifying said resin.

According to one embodiment, the method further comprises the dispersion of the as-obtained particles in a H₂ gas flow. In this embodiment, said H₂ gas flow will allow the passivation of defects in the particles 12, the material 11 and/or aggregate 1.

Another object of the invention relates to an aggregate 1 or a population of aggregates 1 obtainable or obtained by the method of the invention. In the present application, a population of aggregates 1 is defined by the maximum emission wavelength.

According to one embodiment, the aggregate 1 or the population of aggregates 1 obtainable or obtained by the method of the invention is functionalized as described hereabove.

According to one embodiment, at least 0%, 5%, 10%, 15%, 20%, 25%, 30%, 35%, 40%, 45%, 50%, 55%, 60%, 65%, 70%, 75%, 80%, 85%, 90%, or 95% of the aggregates 1 obtainable or obtained by the method of the invention are empty, i.e. they do not comprise any particle 12.

In another aspect, the invention further relates to a display apparatus 61 comprising a backlight unit and a least one color conversion layer 73 and or at least one light emitting material 7. The backlight unit comprises a light source 6111 and a light guide configured to provide an excitation to the at least one light emitting material 7 and is well known by the skilled artisan.

According to one embodiment, the light source 6111 is configured to supply at least one primary light.

According to one embodiment, the at least one primary light is monochromatic.

According to one embodiment, the at least one primary light is polychromatic.

According to one embodiment, the at least one primary light emitted by the light source 6111 has a wavelength ranging from 200 nm to 50 um, from 200 nm to 800 nm, from 400 nm to 470 nm, from 400 nm to 500 nm, from 400 nm to 600 nm, from 400 nm to 700 nm, from 400 nm to 800 nm, from 800 nm to 1200 nm, from 1200 nm to 1500 nm, from 1500 nm to 1800 nm, from 1800 nm to 2200 nm, from 2200 nm to 2500 nm, or from 2500 nm to 50 μm.

According to one embodiment, the light source 6111 comprises at least one light-emitting diode (LED).

According to one embodiment, the light source 6111 is a blue, green, red, or UV light source such as for example a laser, a diode, a light-emitting diode (LED), a LED chip, a LED package including at least one LED chip, a fluorescent lamp or a Xenon Arc Lamp.,

According to one embodiment, the light source 6111 comprises an array of light source pixels or an array of light source sub-pixels.

According to one embodiment, each light source pixel comprises at least one light source sub-pixel which may comprise a light emitting material 7 emitting a secondary light with a wavelength ranging from 200 nm to 50 μm, from 200 nm to 800 nm, from 400 nm to 470 nm, from 400 nm to 500 nm, from 400 nm to 600 nm, from 400 nm to 700 nm, from 400 nm to 800 nm, from 800 nm to 1200 nm, from 1200 nm to 1500 nm, from 1500 nm to 1800 nm, from 1800 nm to 2200 nm, from 2200 nm to 2500 nm, or from 2500 nm to 50 μm.

According to one embodiment, the light source pixel pitch is at least 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, 30 μm, 31 μm, 32 μm, 33 μm, 34 μm, 35 μm, 36 μm, 37 μm, 38 μm, 39 μm, 40 μm, 41 μm, 42 μm, 43 μm, 44 μm, 45 μm, 46 μm, 47 μm, 48 μm, 49 μm, 50 μm, 51 μm, 52 μm, 53 μm, 54 μm, 55 μm, 56 μm, 57 μm, 58 μm, 59 μm, 60 μm, 61 μm, 62 μm, 63 μm, 64 μm, 65 μm, 66 μm, 67 μm, 68 μm, 69 μm, 70 μm, 71 μm, 72 μm, 73 μm, 74 μm, 75 μm, 76 μm, 77 μm, 78 μm, 79 μm, 80 μm, 81 μm, 82 μm, 83 μm, 84 μm, 85 μm, 86 μm, 87 μm, 88 μm, 89 μm, 90 μm, 91 μm, 92 μm, 93 μm, 94 μm, 95 μm, 96 μm, 97 μm, 98 μm, 99 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, 1 mm, 1.1 mm, 1.2 mm, 1 3 mm, 1.4 mm, 1.5 mm, 1.6 mm, 1.7 mm, 1.8 mm, 1.9 mm, 2 mm, 2.1 mm, 2.2 mm, 2.3 mm, 2.4 mm, 2.5 mm, 2.6 mm, 2.7 mm, 2.8 mm, 2.9 mm, 3 mm, 3.1 mm, 3.2 mm, 3.3 mm, 3.4 mm, 3.5 mm, 3.6 mm, 3.7 mm, 3.8 mm, 3.9 mm, 4 mm, 4 1 mm, 4.2 mm, 4.3 mm, 4.4 mm, 4.5 mm, 4.6 mm, 4.7 mm, 4.8 mm, 4.9 mm, 5 mm, 5.1 mm, 5.2 mm, 5.3 mm, 5.4 mm, 5.5 mm, 5.6 mm, 5.7 mm, 5.8 mm, 5.9 mm, 6 mm, 6.1 mm, 6.2 mm, 6.3 mm, 6.4 mm, 6.5 mm, 6.6 mm, 6.7 mm, 6.8 mm, 6.9 mm, 7 mm, 7.1 mm, 7.2 mm, 7.3 mm, 7.4 mm, 7.5 mm, 7.6 mm, 7.7 mm, 7.8 mm, 7.9 mm, 8 mm, 8.1 mm, 8.2 mm, 8.3 mm, 8.4 mm, 8.5 mm, 8.6 mm, 8.7 mm, 8.8 mm, 8.9 mm, 9 mm, 9.1 mm, 9.2 mm, 9.3 mm, 9.4 mm, 9.5 mm, 9.6 mm, 9.7 mm, 9 8 mm, 9.9 mm, 1 cm, 1.1 cm, 1.2 cm, 1.3 cm, 1.4 cm, 1.5 cm, 1.6 cm, 1.7 cm, 1.8 cm, 1.9 cm, 2 cm, 2.1 cm, 2.2 cm, 2.3 cm, 2.4 cm, 2.5 cm, 2.6 cm, 2.7 cm, 2.8 cm, 2.9 cm, 3 cm, 3.1 cm, 3.2 cm, 3.3 cm, 3.4 cm, 3.5 cm, 3.6 cm, 3.7 cm, 3.8 cm, 3.9 cm, 4 cm, 4.1 cm, 4.2 cm, 4.3 cm, 4.4 cm, 4.5 cm, 4.6 cm, 4.7 cm, 4.8 cm, 4.9 cm, 5 cm, 5.1 cm, 5.2 cm, 5.3 cm, 5.4 cm, 5.5 cm, 5.6 cm, 5.7 cm, 5.8 cm, 5.9 cm, 6 cm, 6.1 cm, 6.2 cm, 6.3 cm, 6.4 cm, 6.5 cm, 6.6 cm, 6.7 cm, 6.8 cm, 6.9 cm, 7 cm, 7.1 cm, 7.2 cm, 7.3 cm, 7.4 cm, 7.5 cm, 7.6 cm, 7.7 cm, 7.8 cm, 7.9 cm, 8 cm, 8.1 cm, 8.2 cm, 8.3 cm, 8.4 cm, 8.5 cm, 8.6 cm, 8.7 cm, 8.8 cm, 8.9 cm, 9 cm, 9.1 cm, 9.2 cm, 9.3 cm, 9.4 cm, 9.5 cm, 9.6 cm, 9.7 cm, 9.8 cm, 9.9 cm, or 10 cm.

According to one embodiment, the light source pixel size is at least 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, 30 μm, 31 μm, 32 μm, 33 μm, 34 μm, 35 μm, 36 μm, 37 μm, 38 μm, 39 μm, 40 μm, 41 μm, 42 μm, 43 μm, 44 μm, 45 μm, 46 μm, 47 μm, 48 μm, 49 μm, 50 μm, 51 μm, 52 μm, 53 μm, 54 μm, 55 μm, 56 μm, 57 μm, 58 μm, 59 μm, 60 μm, 61 μm, 62 μm, 63 μm, 64 μm, 65 μm, 66 μm, 67 μm, 68 μm, 69 μm, 70 μm, 71 μm, 72 μm, 73 μm, 74 μm, 75 μm, 76 μm, 77 μm, 78 μm, 79 μm, 80 μm, 81 μm, 82 μm, 83 μm, 84 μm, 85 μm, 86 μm, 87 μm, 88 μm, 89 μm, 90 μm, 91 μm, 92 μm, 93 μm, 94 μm, 95 μm, 96 μm, 97 μm, 98 μm, 99 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, 1 mm, 1.1 mm, 1.2 mm, 1.3 mm, 1 4 mm, 1.5 mm, 1.6 mm, 1.7 mm, 1.8 mm, 1.9 mm, 2 mm, 2.1 mm, 2.2 mm, 2.3 mm, 2.4 mm, 2.5 mm, 2.6 mm, 2.7 mm, 2.8 mm, 2.9 mm, 3 mm, 3.1 mm, 3.2 mm, 3.3 mm, 3.4 mm, 3.5 mm, 3.6 mm, 3.7 mm, 3.8 mm, 3.9 mm, 4 mm, 4.1 mm, 4.2 mm, 4.3 mm, 4.4 mm, 4.5 mm, 4.6 mm, 4.7 mm, 4.8 mm, 4.9 mm, 5 mm, 5.1 mm, 5.2 mm, 5.3 mm, 5.4 mm, 5.5 mm, 5.6 mm, 5.7 mm, 5.8 mm, 5.9 mm, 6 mm, 6.1 mm, 6 2 mm, 6 3 mm, 6.4 mm, 6.5 mm, 6.6 mm, 6.7 mm, 6.8 mm, 6.9 mm, 7 mm, 7.1 mm, 7.2 mm, 7 3 mm, 7 4 mm, 7.5 mm, 7.6 mm, 7.7 mm, 7.8 mm, 7.9 mm, 8 mm, 8.1 mm, 8.2 mm, 8.3 mm, 8 4 mm, 8 5 mm, 8.6 mm, 8.7 mm, 8.8 mm, 8.9 mm, 9 mm, 9.1 mm, 9.2 mm, 9.3 mm, 9.4 mm, 9.5 mm, 9.6 mm, 9.7 mm, 9.8 mm, 9.9 mm, 1 cm, 1.1 cm, 1.2 cm, 1.3 cm, 1.4 cm, 1.5 cm, 1.6 cm, 1.7 cm, 1.8 cm, 1.9 cm, 2 cm, 2.1 cm, 2.2 cm, 2.3 cm, 2.4 cm, 2.5 cm, 2.6 cm, 2.7 cm, 2.8 cm, 2.9 cm, 3 cm, 3.1 cm, 3.2 cm, 3.3 cm, 3.4 cm, 3.5 cm, 3.6 cm, 3.7 cm, 3.8 cm, 3.9 cm, 4 cm, 4.1 cm, 4.2 cm, 4.3 cm, 4.4 cm, 4.5 cm, 4.6 cm, 4.7 cm, 4.8 cm, 4.9 cm, 5 cm, 5.1 cm, 5.2 cm, 5.3 cm, 5.4 cm, 5.5 cm, 5.6 cm, 5.7 cm, 5.8 cm, 5.9 cm, 6 cm, 6.1 cm, 6.2 cm, 6.3 cm, 6.4 cm, 6.5 cm, 6.6 cm, 6.7 cm, 6.8 cm, 6.9 cm, 7 cm, 7.1 cm, 7.2 cm, 7.3 cm, 7.4 cm, 7.5 cm, 7.6 cm, 7.7 cm, 7.8 cm, 7.9 cm, 8 cm, 8.1 cm, 8.2 cm, 8.3 cm, 8.4 cm, 8.5 cm, 8.6 cm, 8.7 cm, 8.8 cm, 8.9 cm, 9 cm, 9.1 cm, 9.2 cm, 9.3 cm, 9.4 cm, 9.5 cm, 9.6 cm, 9.7 cm, 9.8 cm, 9.9 cm, or 10 cm.

According to one embodiment, the light source 6111 may further comprise inorganic phosphors as described herein.

According to one embodiment, the light source 6111 comprises at least one LED and light-emitting inorganic phosphors, all well known by the skilled artisan. Therefore, the light source 6111 can emit a combination of lights with different wavelengths, i.e. a polychromatic light, as primary light.

In one embodiment, the light source 6111 is a blue LED with a wavelength ranging from 400 nm to 470 nm such as for instance a gallium nitride based diode.

In one embodiment, the light source 6111 is a blue LED with a wavelength ranging from 400 nm to 470 nm. In one embodiment, the light source 6111 has an emission peak at about 405 nm. In one embodiment, the light source 6111 has an emission peak at about 447 nm. In one embodiment, the light source 6111 has an emission peak at about 455 nm.

In one embodiment, the light source 6111 is a UV LED with a wavelength ranging from 200 nm to 400 nm. In one embodiment, the light source 6111 has an emission peak at about 253 nm. In one embodiment, the light source 6111 has an emission peak at about 365 nm. In one embodiment, the light source 6111 has an emission peak at about 395 nm.

In one embodiment, the light source 6111 is a green LED with a wavelength ranging from 500 nm to 560 nm. In one embodiment, the light source 6111 has an emission peak at about 515 nm. In one embodiment, the light source 6111 has an emission peak at about 525 nm. In one embodiment, the light source 6111 has an emission peak at about 540 nm.

In one embodiment, the light source 6111 is a red LED with a wavelength ranging from 750 to 850 nm. In one embodiment, the light source 6111 has an emission peak at about 755 nm. In one embodiment, the light source 6111 has an emission peak at about 800 nm. In one embodiment, the light source 6111 has an emission peak at about 850 nm.

In one embodiment, the light source 6111 has a photon flux or average peak pulse power between 1 nW·cm⁻² and 100 kW·cm⁻² and more preferably between 1 mW·cm⁻² and 100 W·cm², and even more preferably between 1 mW·cm⁻² and 30 W·cm⁻².

In one embodiment, the light source 6111 has a photon flux or average peak pulse power of at least 1 nW·cm⁻², 50 nW·cm⁻², 100 nW·cm⁻², 200 nW·cm⁻², 300 nW·cm⁻², 400 nW·cm⁻², 500 nW·cm⁻², 600 nW·cm⁻², 700 nW·cm⁻², 800 nW·cm⁻², 900 nW·cm⁻², 1 μW·cm⁻², 10 μW·cm⁻², 100 μW·cm⁻², 500 μW·cm⁻², 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the incident light exciting the light emitting material 7 has a photon flux or average peak pulse power of at least 1 nW·cm⁻², 50 nW·cm⁻², 100 nW·cm⁻², 200 nW·cm⁻², 300 nW·cm⁻², 400 nW·cm⁻², 500 nW·cm⁻², 600 nW·cm⁻², 700 nW·cm⁻², 800 nW·cm⁻², 900 nW·cm⁻², 1 μW·cm⁻², 10 μW·cm⁻², 100 μW·cm⁻², 500 μW·cm⁻², 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

In one embodiment, the light source 6111 is a GaN, GaSb, GaAs, GaAsP, GaP, InP, SiGe, InGaN, GaAlN, GaAlPN, AlN, AlGaAs, AlGaP, AlGaInP, AlGaN, AlGaInN, ZnSe, Si, SiC, diamond, boron nitride diode.

In one embodiment, the LED may be located on one surface of a printed circuit board. A reflector may be disposed on one surface of the printed circuit board, and the LED may be located on the reflector. The reflector reflects light which has failed to go toward the light emitting material 7, back to the light emitting material 7.

According to one embodiment, the reflector guides the wasted light from the light source 6111 back toward the light emitting material 7. Wasted light refers to the light emitted from the light source 6111 that is not directed to the light emitting material 7.

According to one embodiment, the color conversion layer 73 is an array of light emitting materials 7.

In one embodiment illustrated in FIG. 27A-B, the color conversion layer 73 comprises an array of light emitting materials 7 partially or totally surrounded and/or covered by a surrounding medium 72.

According to one embodiment, the color conversion layer 73 is a superposition of light emitting materials 7.

According to one embodiment, the light guide distributes the primary light towards the at least one light emitting material 7.

According to one embodiment, the color conversion layer 73 comprises an array of pixels.

According to one embodiment, pixels of the array of pixels comprised in the color conversion layer 73 are separated by a pixel pitch D.

According to one embodiment, the color conversion layer 73 comprises an array of pixels and each pixel comprises at least one light emitting material 7.

According to one embodiment, the color conversion layer 73 comprises an array of pixels and each pixel comprises an array of light emitting materials 7.

According to one embodiment, the pixel pitch D is as described hereabove.

According to one embodiment, the pixel size is as described hereabove.

According to one embodiment, there may be discontinuities or irregularities along the color conversion layer 73.

In one embodiment, the light emitting materials 7 may be separated by at least one surrounding medium 72.

In one embodiment, the color conversion layer 73 comprises two light emitting materials 7 emitting different colors or wavelengths.

In one embodiment, the color conversion layer 73 comprises two light emitting materials 7, a first light emitting material 7 with a maximum emission wavelength between 500 nm and 560 nm, more preferably between 515 nm and 545 nm and a second light emitting material 7 with a maximum emission wavelength between 600 nm and 2500 nm, more preferably between 610 nm and 650 nm.

In one embodiment, the color conversion layer 73 comprises three light emitting materials 7 emitting different colors or wavelengths.

In one embodiment, the color conversion layer 73 comprises three light emitting materials 7, a first light emitting material 7 with a maximum emission wavelength between 440 and 499 nm, more preferably between 450 and 495 nm, a second light emitting material 7 with a maximum emission wavelength between 500 nm and 560 nm, more preferably between 515 nm and 545 nm and a third light emitting material 7 with a maximum emission wavelength between 600 nm and 2500 nm, more preferably between 610 nm and 650 nm.

In one embodiment, the color conversion layer 73 comprises a plurality of light emitting materials 7. In this embodiment, the light emitting materials 7 may emit secondary lights of the same color or wavelength.

In one embodiment, the color conversion layer 73 comprises a plurality of light emitting material 7. In this embodiment, the light emitting materials 7 may emit secondary lights of different colors or wavelengths.

In one embodiment, the color conversion layer 73 comprises at least one light emitting material 7 comprising only one population of aggregates 1.

In one embodiment, the color conversion layer 73 comprises at least one light emitting material 7, each comprising only one population of aggregates 1, the populations comprised in each light emitting material 7 emitting different colors or wavelengths.

In one embodiment, the color conversion layer 73 comprises at least one light emitting material 7, each comprising two populations of aggregates 1 emitting different colors or wavelengths.

In one embodiment, the color conversion layer 73 comprises at least one light emitting material 7 comprising three populations of aggregates 1 emitting different colors or wavelengths.

In one embodiment, the color conversion layer 73 comprises a plurality of light emitting materials 7 each comprising only one population of aggregates 1, the populations comprised in each light emitting material 7 emitting different colors or wavelengths.

In one embodiment, the concentration of the plurality of light emitting material 7 comprised in the color conversion layer 73 and emitting different colors or wavelengths, is controlled to predetermine the light intensity of each secondary light emitted by said plurality of light emitting material 7, after excitation of the aggregates 1 by a primary light.

In one embodiment, the color conversion layer 73 comprises at least one light emitting material 7 comprising aggregates 1 which emit green light and red light upon downconversion of a blue light source. In this embodiment, the color conversion layer 73 is configured to transmit a predetermined intensity of the primary blue light and to emit a predetermined intensity of secondary green and red lights, allowing to emit a resulting tri-chromatic white light.

In one embodiment, the color conversion layer 73 comprises at least one light emitting material 7 comprising at least one aggregate 1 which emits green light, and at least one light emitting material 7 comprising at least one aggregate 1 which emits red light upon downconversion of a blue light source. In this embodiment, the color conversion layer 73 is configured to transmit a predetermined intensity of the primary blue light and to emit a predetermined intensity of secondary green and red lights, allowing to emit a resulting tri-chromatic white light.In one embodiment, the color conversion layer 73 comprises at least one light emitting material 7 comprising at least one aggregate 1 which emits green light, at least one light emitting material 7 comprising at least one aggregate 1 which emits red light, and at least one light emitting material 7 comprising at least one aggregate 1 which emits blue light upon downconversion of a UV light source. In this embodiment, the color conversion layer 73 is configured to transmit a predetermined intensity of the primary UV light and to emit a predetermined intensity of secondary green, red and blue lights, allowing to emit a resulting tri-chromatic white light.

According to one embodiment, the color conversion layer 73 may comprises at least one zone comprising at least one light emitting material 7 and/or at least one zone free of light emitting material 7 and/or at least one empty zone and/or at least one optically transparent zone.

According to one embodiment, the at least one zone free of light emitting material 7 may comprise scattering particles.

According to one embodiment, the color conversion layer 73 may comprises at least one zone comprising at least one light emitting material 7 emitting red secondary light at least one light emitting material 7 emitting green secondary light. In this embodiment, said color conversion layer 73 is equivalent to a layer comprising a yellow phosphor.

According to one embodiment, the color conversion layer 73 may comprises at least one zone comprising at least one light emitting material 7, wherein said light emitting material 7 comprises scattering particles and does not comprise aggregates 1; and/or at least one zone comprising at least one light emitting material 7, wherein said light emitting material 7 comprises scattering particles and aggregates 1.

According to one embodiment, the color conversion layer 73 may comprises at least one zone comprising at least one light emitting material 7 having an emission peak ranging from 400 nm to 470 nm, preferably at about 450 nm; at least one zone comprising at least one light emitting material 7 having an emission peak ranging from 500 nm to 560 nm, preferably at about 540 nm; and at least one zone comprising at least one light emitting material 7 having an emission peak ranging from750 to 850 nm, preferably at about 750 nm. In this embodiment, the color conversion layer 73 can be excited with a primary light centered at 390 nm.

According to one embodiment, the color conversion layer 73 may comprises at least one zone comprising at least one light emitting material 7 having an emission peak ranging from 400 nm to 470 nm, preferably at about 450 nm; at least one zone comprising at least one light emitting material 7 having an emission peak ranging from 500 nm to 560 nm, preferably at about 540 nm; and at least one zone comprising at least one light emitting material 7 having an emission peak ranging from750 to 850 nm, preferably at about 750 nm. In this embodiment, the color conversion layer 73 can be excited with a primary light centered at 390 nm and/or at 450 nm.

According to one embodiment, the color conversion layer 73 may comprises at least one zone comprising at least one light emitting material 7 emitting a green secondary light, at least one zone comprising at least one light emitting material 7 emitting a red secondary light, and at least one zone free of light emitting material 7 or inorganic phosphor.

According to one embodiment, the at least one sub-pixel is free of light emitting material 7. In this embodiment, the at least one sub-pixel can comprise scattering particles.

According to one embodiment, the at least one sub-pixel comprises scattering particles.

According to one embodiment, at least one sub-pixel comprises a light emitting material 7, wherein said light emitting material 7 comprises scattering particles and does not comprise aggregates 1; and/or at least one sub-pixel comprises a light emitting material 7, wherein said light emitting material 7 comprises scattering particles and aggregates 1.

According to one embodiment illustrated in FIG. 20E, the first sub-pixel emits a green secondary light, the second sub-pixel emits a red secondary light, the third sub-pixel is free of light emitting material 7 or inorganic phosphor.

According to one embodiment, the color conversion layer 73 comprises an array of pixels and each pixel comprises at least one sub-pixel.

According to one embodiment, the at least one sub-pixel comprises at least one light emitting material 7.

According to one embodiment, the at least one sub-pixel is free of light emitting material 7.

According to one embodiment, the sub-pixel pitch d is as described hereabove.

According to one embodiment, the sub-pixel size is as described hereabove.

According to one embodiment, the color conversion layer 73 and/or light emitting material 7 do not comprise pixels.

According to one embodiment, the color conversion layer 73 and/or light emitting material 7 does not comprise sub-pixels.

According to one embodiment, the pixels are configured to emit a resulting monochromatic light or a polychromatic light. For example, the pixels may emit a mixture of a blue, green and/or red lights.

According to one embodiment, the sub-pixels are configured to emit a resulting monochromatic light or a polychromatic light. For example, the sub-pixels may emit a blue light, a green light and/or a red light.

In one embodiment, the color conversion layer 73 comprises an array of pixels, each pixel comprising 3 sub-pixels. The 3 sub-pixels are: i) free of light emitting material 7, red sub-pixel and green sub-pixel both comprising at least one light emitting material 7, when the laser source emits blue light.; or ii) blue sub-pixel, red sub-pixel and green sub-pixel all comprising at least one light emitting material, when the laser source emits UV light.

According to one embodiment, the color conversion layer 73 comprises an array of pixels, wherein at least one sub-pixel comprises a light emitting material 7 having an emission peak ranging from 400 nm to 470 nm, preferably at about 450 nm; at least one sub-pixel comprises a light emitting material 7 having an emission peak ranging from 500 nm to 560 nm, preferably at about 540 nm; and at least one sub-pixel comprises a light emitting material 7 having an emission peak ranging from750 to 850 nm, preferably at about 750 nm. In this embodiment, the color conversion layer 73 can be excited with a primary light centered at 390 nm.

According to one embodiment, the color conversion layer 73 comprises an array of pixels, wherein at least one sub-pixel comprises a light emitting material 7 having an emission peak ranging from 400 nm to 470 nm, preferably at about 450 nm; at least one sub-pixel comprises a light emitting material 7 having an emission peak ranging from 500 nm to 560 nm, preferably at about 540 nm; and at least one sub-pixel comprises a light emitting material 7 having an emission peak ranging from750 to 850 nm, preferably at about 750 nm. In this embodiment, the color conversion layer 73 can be excited with a primary light centered at 390 nm and/or at 450 nm.

According to one embodiment, the display apparatus 61 may further comprise at least one polarizer 6141 or polarizing filter to increase efficiency by repeatedly reflecting any unpolarized light back or block undesired light from the light guide to the light emitting material 7.

In one embodiment, the display apparatus 61 may further comprise at least one layer of liquid crystal material 6131 which is able to control the passage and the intensity of the light from the light source 6111 to the light emitting material 7.

In one embodiment, the display apparatus 61 may further comprise an active matrix 6132 and a layer of liquid crystal material 6131 to control the illumination of each light emitting material 7.

According to said embodiment, the display apparatus 61 further comprises a polarizer 6141 between the light emitting material 7 and the light source 6111.

According to one embodiment illustrated on FIG. 21, the display apparatus 61 comprises a color conversion layer 73 comprising an array of pixels, wherein each pixel comprises at least one of sub-pixels, wherein each sub-pixel comprises at least one light emitting material 7 or is free of light emitting material. Said display apparatus 61 comprises a light source 6111 configured to excite said light emitting material 7 comprised in said color conversion layer 73. At least one secondary light is emitted through a sub-pixel when the primary light excites the at least one light emitting material 7 comprised in said sub-pixel, while the primary light is transmitted through a sub-pixel without emission of a secondary light when said sub-pixel is free of light emitting material 7 and is illuminated by said primary light. The display apparatus 61 further comprises an active matrix 6132 and a layer of liquid crystal material 6131 to control the illumination of sub-pixel or each light emitting material 7. According to said embodiment, the display apparatus 61 further comprises at least one polarizer 6141 between the color conversion layer 73 and the light source 6111.

In another aspect, the invention relates to a display apparatus 61 comprising an array of light sources 6111 and at least one color conversion layer 73 according to the present invention. The light sources 6111 are configured to provide an excitation to the at least one light emitting material 7.

In one embodiment, each light source of the array of light sources is a light source 6111 as described hereabove.

According to one embodiment, the array of individual light sources 6111 forms an array of light source pixels or an array of light source sub-pixels.

According to one embodiment, the light source pixels and the light source sub-pixels are as described hereabove.

According to one embodiment, the light sources 6111 may be activated collectively.

According to one embodiment, the light sources 6111 may be activated independently from each other.

According to one embodiment, the light sources 6111 intensity may be controlled collectively.

According to one embodiment, the light sources 6111 intensity may be controlled independently from each other.

In one embodiment, the array of light sources 6111 is an array of LED.

In one embodiment, the array of light sources 6111 is an array of microsized LED.

In one embodiment, the array of light sources 6111 is a LED array or a microsized LED array comprising an array of GaN diodes, GaSb diodes, GaAs diodes, GaAsP diodes, GaP diodes, InP diodes, SiGe diodes, InGaN diodes, GaAlN diodes, GaAlPN diodes, MN diodes, AlGaAs diodes, AlGaP diodes, AlGaInP diodes, AlGaN diodes, AlGaInN diodes, ZnSe diodes, Si diodes, SiC diodes, diamond diodes, boron nitride diodes, organic light emitting diodes (OLED), quantum dot light emitting diodes (QLED), or a mixture thereof.

According to one embodiment, the color conversion layer 73 comprises an array of pixels.

According to one embodiment, the pixels are as described hereabove.

According to one embodiment, the color conversion layer 73 comprises an array of pixels and each pixel comprises at least one sub-pixel.

According to one embodiment, the at least one sub-pixel is as described hereabove.

According to one embodiment, the conversion layer 73 does not comprise pixels.

According to one embodiment, the conversion layer 73 does not comprise sub-pixels.

In one embodiment, each light source 6111 of the array of light sources 6111 is configured to illuminate and/or to excite at least one light emitting material 7 comprised in the at least one color conversion layer 73.

In one embodiment, each light source 6111 of the array of light sources 6111 is configured to illuminate and/or excite only one light emitting material 7 comprised in the at least one color conversion layer 73.

In one embodiment, each light source 6111 of the array of light sources 6111 is configured to illuminate and/or excite at least one pixel of the array of pixels.

In one embodiment, each light source 6111 of the array of light sources 6111 is configured to illuminate and/or excite only one pixel of the array of pixels. In this embodiment, each light source 6111 of the array of light sources 6111 is associated with only one pixel of the array of pixels.

In one embodiment, each pixel of the array of pixels is configured to be illuminated and/or excited by only one light source 6111 of the array of light sources 6111. In this embodiment, each pixel is associated with only one light source 6111 of the array of light sources 6111.

In one embodiment, each light source 6111 of the array of light sources 6111 is configured to illuminate and/or excite only one pixel of the array of pixels. In this embodiment, each light source 6111 of the array of light sources 6111 is associated with only one pixel of the array of pixels.

In one embodiment, each light source 6111 of the array of light sources 6111 is configured to illuminate and/or excite only one sub-pixel. In this embodiment, each light source 6111 of the array of light sources 6111 is associated with one sub-pixel of the array of pixels.

In one embodiment, each sub-pixel is configured to be illuminated and/or excited by only one light source 6111 of the array of light sources 6111. In this embodiment, each sub-pixel is associated with only one light source 6111 of the array of light sources 6111.

According to one embodiment, the pixels are configured to emit a resulting monochromatic light or a polychromatic light. For example, the pixels may emit a mixture of a blue, green and/or red lights.

According to one embodiment, the sub-pixels are configured to emit a resulting monochromatic light or a polychromatic light. For example, the sub-pixels may emit a blue light, a green light and/or a red light.

According to one embodiment, the active matrix 6132 is an active TFT (Thin-Film-Transistor) matrix or a CMOS (Complementary Metal-Oxide-Semiconductor) matrix. Active TFT matrix and CMOS matrix is well-known from the skilled artisan.

FIG. 22 illustrates a display apparatus 61 using such a conversion layer 73. Said display apparatus 61 comprises a bottom substrate 6122, a glass substrate 6121, a color conversion layer 73 comprising an array of pixels, wherein each pixel comprises at least one sub-pixels, wherein each sub-pixel comprises at least one light emitting material 7 or is free of light emitting material. Said display apparatus 61 comprises an array of light source 6111 for which each light source 6111 and each sub-pixel are associated two by two and, when activated, is configured to illuminate and/or excite said one sub-pixel. At least one secondary light is emitted through a sub-pixel when the primary light from the associated light source 6111 illuminates and/or excites the at least one light emitting material 7 comprised in said sub-pixel, while the primary light is transmitted through a sub-pixel without emission of a secondary light when said sub-pixel is free of light emitting material 7 and is illuminated by said primary light from the associated light source 6111. In this embodiment, the display apparatus 61 comprises an active matrix 6132 (preferably an active TFT matrix) in order to activate each light source sub-pixel. The active matrix 6132 may comprise at least one transistor and at least one capacitor per sub-pixel.

In another aspect, the invention relates to a display apparatus 61 comprising at least one laser source 6112 and at least one color conversion layer 73 according to the present invention comprising an array of light emitting material 7, wherein said at least one laser source 6112 is configured to provide an excitation for the at least one light emitting material 7, allowing said light emitting material 7 to emit at least one secondary light.

According to one embodiment, the at least one laser source 6112 is a laser diode or other type of laser device well known by the skilled artisan.

In one embodiment, the at least one laser source 6112 is a blue laser source with a wavelength ranging from 400 nm to 470 nm. In one embodiment, the laser source 6112 has an emission peak at about 405 nm. In one embodiment, the laser source 6112 has an emission peak at about 447 nm.

In one embodiment, the laser source 6112 has an emission peak at about 455 nm.

In one embodiment, the at least one laser source 6112 is a UV laser source with a wavelength ranging from 200 nm to 400 nm. In one embodiment, the laser source 6112 has an emission peak at about 253 nm. In one embodiment, the laser source 6112 has an emission peak at about 365 nm. In one embodiment, the laser source 6112 has an emission peak at about 395 nm.

In one embodiment, the at least one laser source 6112 is a green laser source with a wavelength ranging from 500 nm to 560 nm. In one embodiment, the laser source 6112 has an emission peak at about 515 nm. In one embodiment, the laser source 6112 has an emission peak at about 525 nm. In one embodiment, the laser source 6112 has an emission peak at about 540 nm.

In one embodiment, the at least one laser source 6112 is a red laser source with a wavelength ranging from 600 to 850 nm. In one embodiment, the laser source 6112 has an emission peak at about 620 nm. In one embodiment, the laser source 6112 has an emission peak at about 800 nm. In one embodiment, the laser source 6112 has an emission peak at about 850 nm.

According to one embodiment, the intensity of primary light exciting the color conversion layer 73 may be controlled by the intensity of the at least one laser source 6112 or by the presence of a color filter between the laser source and the directing optical system 6143 or between the directing optical system 6143 and the color conversion layer 73 or beyond the color conversion layer 73.

According to one embodiment, the intensity of primary light exciting the color conversion layer 73 may be controlled by the intensity of the at least one laser source 6112, by the pulsation frequency of the at least one laser source 6112, or by the presence of an optical attenuator.

According to one embodiment, the color conversion layer 73 comprises an array of pixels.

According to one embodiment, the pixels are as described hereabove.

According to one embodiment, the color conversion layer 73 comprises an array of pixels and each pixel comprises at least one sub-pixel.

According to one embodiment, the sub-pixel is as described hereabove.

According to one embodiment illustrated in FIG. 25, the display apparatus 61 comprises a color conversion layer 73 comprising an array of pixels, wherein each pixel comprises at least one sub-pixels, wherein each sub-pixel comprises at least one light emitting material 7 or is free of light emitting material. The display apparatus 61 further comprises a glass substrate 6121. The display apparatus 61 further comprises a laser source 6112, which produces a laser-ray as primary light which is pointed towards a directing optical system 6143. Said system 6143 redirects the laser-ray in the direction of pixels or sub-pixels. The directing optical system 6143 is configured to allow the primary light to be directed towards or to scan pixels or sub-pixels and to provide an illumination and/or an excitation for said pixels or sub-pixels. At least one secondary light is emitted through a sub-pixel when the primary light illuminates and/or excites the at least one light emitting material 7 comprised in said sub-pixel, while the primary light is transmitted through a sub-pixel without emission of a secondary light when said sub-pixel is free of light emitting material 7 and is illuminated by said primary light. The possible laser paths 61121 are illustrated on FIG. 25.

According to one embodiment, the directing optical system 6143 is configured to allow the primary light to be directed towards or to scan all the pixels or sub-pixels, a selection of pixels or sub-pixels, or none pixel or sub-pixel of the apparatus, allowing to produce different pictures when the resulting light is projected onto a screen. In this embodiment, some of the pixels or sub-pixels may be illuminated and some of the pixels or sub-pixels may not be illuminated so that images can be created and displayed.

According to one embodiment, the primary light scans pixels or sub-pixels fast enough to produce pictures visible for the human eye when the resulting light is projected onto a screen.

According to one embodiment, the resulting light projected onto a screen may form at least one image on said screen, and/or a succession of images, and/or a video.

According to one embodiment, the change of selection of pixels or sub-pixels on which the primary light is directed or scanned is fast enough to produce a serie of pictures which could be seen like a fluid video for the human eye when the resulting light is projected onto a screen. Typically, the change frequency of selection of pixels or sub-pixels on which the primary light is directed or scanned is at least of 24 Hz multiplied by the number of pixels or sub-pixels.

In another aspect, the invention further relates to a display apparatus 61, illustrated in FIG. 13, comprising at least one color conversion layer 73 deposited onto a solid support 6123 to produce images by reflection or backscattering when excited by the laser source 6112.

In one embodiment, the color conversion layer 73 and/or the light emitting material 7 is deposited onto the solid support by drop-casting, spin coating, dip coating, inkjet printing, lithography, spray, plating, electroplating, or any other means known by the person skilled in the art.

In one embodiment, the display apparatus 61 further comprises at least one laser source 6112 as described hereabove.

In one embodiment, the at least one laser source 6112 is a blue laser source or a UV laser source as described hereabove.

In one embodiment, the at least one laser source 6112 is configured to illuminate and/or excite the light emitting material 7 allowing said light emitting material 7 to emit at least one secondary light.

In one embodiment, the solid support 6123 comprises at least one empty zone or at least one optically transparent zone, at least one zone comprising at least one light emitting material 7 configured to emit a secondary red-light and at least one zone comprising at least one color conversion layer 73 configured to emit a secondary green-light.

In one embodiment, the laser source 6112 emits a primary blue light and the solid support 6123 comprises at least one zone free of light emitting material, at least one zone comprising at least one light emitting material 7 configured to emit a secondary red-light and at least one zone comprising at least one light emitting material 7 configured to emit a secondary green-light.

In one embodiment, the laser source 6112 emits a primary UV light and the solid support 6123 comprises at least one zone comprising at least one light emitting material 7 configured to emit a secondary blue-light, at least one zone comprising at least one light emitting material 7 configured to emit a secondary red-light and at least one zone comprising at least one light emitting material 7 configured to emit a secondary green-light.

According to one embodiment, the display apparatus comprises at least one cut-on filter layer. In this embodiment, said layer is a global cut-on filter, a local cut-on filter, or a mixture thereof. This embodiment is particularly advantageous as said cut-on filter layer prevents the excitation of the particles of the invention comprised in the ink by ambient light. A local cut-on filter blocks only a particular part of the optical spectrum. A local cut-on filter which blocks only this particular part of the optical spectrum can, in conjunction with a global cut-on filter, eliminate (or significantly reduce) the excitation of the particles of the invention by ambient light.

According to one embodiment, the cut-on filter layer is a resin that can filter blue light.

According to one embodiment, the cut-on filter layer comprises at least one organic material, such as at least one organic polymer as described herein, preferably said cut-on filter layer is configured to filter blue light.

According to one embodiment, the color conversion layer 73 comprises an array of pixels.

According to one embodiment, the color conversion layer 73 comprises an array of pixels and each pixel comprises at least one light emitting material 7.

According to one embodiment, the color conversion layer 73 comprises an array of pixels and each pixel comprises an array of light emitting material 7.

According to one embodiment, the pixel pitch D is as describes hereabove.

According to one embodiment, the pixel size is as describes hereabove.

According to one embodiment, the color conversion layer 73 comprises an array of pixels and each pixel comprises at least one sub-pixel.

According to one embodiment, the at least one sub-pixel comprises at least one light emitting material 7.

According to one embodiment, the at least one sub-pixel is free of light emitting material 7.

According to one embodiment, the sub-pixel pitch d is as describes hereabove.

According to one embodiment, the sub-pixel size is as describes hereabove.

According to one embodiment, the pixels are configured to emit a resulting monochromatic light or a polychromatic light. For example, the pixels may emit a mixture of a blue, green and red lights.

According to one embodiment, the sub-pixels are configured to emit a resulting monochromatic light or a polychromatic light. For example, the sub-pixels may emit a blue light, a green light or a red light.

According to one embodiment, the display apparatus 61 further comprises a directing optical system 6143 as described hereabove.

In one embodiment, the light emitted from at least one laser source 6112 is directed to the optical system 6143 as described hereabove.

In one embodiment, the display apparatus 61 further comprises a reflecting screen.

In one embodiment, the display apparatus 61 further comprises an optically transparent screen.

In one embodiment, the solid support 6123 is a reflecting solid support, preferably the solid support 6123 is a reflecting screen.

In one embodiment, the solid support 6123 is an optically transparent material.

In one embodiment, the solid support 6123 comprises a material configured to reflect the light emitted from the laser source 6112 and/or the light emitted from the color conversion layer 73 and/or the light emitting material 7. In this embodiment, the resulting light is partially or totally reflected by said material.

In one embodiment, the solid support 6123 comprises a material configured to backscatter the light emitted from the laser source 6112 and/or the light emitted from the color conversion layer 73 and/or the light emitting material 7. In this embodiment, a portion of the resulting light may be transmitted and a portion of the resulting light is reflected, scattered or backscattered by said material. Preferably, the amount of transmitted light is lower than the amount of reflected, scattered or backscattered light.

In one embodiment, examples of material configured to backscatter light include but are not limited to: Al₂O₃, SiO₂, MgO, ZnO, ZrO₂, IrO₂, SnO₂, TiO₂, BaO, BaSO₄, BeO, CaO, CeO₂, CuO, Cu₂O, DyO₃, Fe₂O₃, Fe₃O₄, GeO₂, HfO₂, Lu₂O₃, Nb₂O₅, Sc₂O₃, TaO₅, TeO₂, Y₂O₃ nanoparticles, or a mixture thereof.

In one embodiment, the at least one laser source 6112 is configured to scan the color conversion layer 73 and/or the solid support 6123 while selecting the sub-pixels to illuminate and/or excite, thus creating an image.

Therefore, in one embodiment, illustrated in FIG. 26A-B, the display apparatus 61 comprises a color conversion layer 73 deposited onto a solid support 6123 and comprising an array of pixels, wherein each pixel comprises at least one sub-pixels, wherein each sub-pixel comprises at least one light emitting material 7 or is free of light emitting material. The display apparatus 61 further comprises a laser source 6112 which is configured to allow the primary light to be directed towards or to scan pixels or sub-pixels and to provide an illumination and/or an excitation for said pixels or sub-pixels. At least one secondary light is emitted through a sub-pixel when the primary light illuminates and/or excites the at least one light emitting material 7 comprised in said sub-pixel, while the primary light is transmitted through a sub-pixel without emission of a secondary light when said sub-pixel is free of light emitting material 7 and is illuminated by said primary light.

The resulting light is reflected or backscattered by the solid support 6123 and can produce a clear picture for a normal human eye by itself or when it is projected onto a screen. The possible laser paths 61122 and 61111 are illustrated on FIG. 26A-B.

According to one embodiment, the resulting light projected onto a screen may form at least one image on said screen, or a succession of images, or a video.

According to one embodiment, the change of selection of pixels or sub-pixels on which the primary light is directed or scanned is fast enough to produce a serie of pictures which could be seen like a fluid video for the human eye when the resulting light is projected onto a screen. Typically, the change frequency of selection of pixels or sub-pixels on which the primary light is directed or scanned is at least of 24 Hz multiplied by the number of pixels or sub-pixels.

According to one embodiment, every display apparatus 61 described in the present specification may further comprise an optical enhancement film 6142 above the light emitting material 7 as illustrated in FIG. 24 and/or comprise a glass substrate 6121 on or under the at least one color conversion layer 73 in order to protect the light emitting material 7 as illustrated on FIG. 23, and/or comprise a screen located such that the picture produced by the apparatus is clear for a normal human eye.

In one embodiment, the optical enhancement film 6142 is a reflector, a scattering element, a light guide, a polarizer or a color filter.

In one embodiment, the color filter is a color filter well known from the skilled person.

In one embodiment, the color filter comprises at least one color conversion layer 73 of the invention.

While various embodiments have been described and illustrated, the detailed description is not to be construed as being limited hereto. Various modifications can be made to the embodiments by those skilled in the art without departing from the true spirit and scope of the disclosure as defined by the claims.

In another aspect, the invention relates to an illumination source 62 comprising at least one light source 6111 and at least one color conversion layer 73 of the invention.

The illumination source may permit to emit a light in the direction of at least one color filter of a display apparatus.

According to one embodiment, the light emitted by the illumination source 62 is monochromatic.

According to one embodiment, the illumination source 62 may comprise a plurality of color conversion layers 73 in order to emit several lights or a polychromatic light. In this embodiment, the color conversion layers 73 may be stacked, i.e. each conversion layer 73 may be on top of another color conversion layer 73. One color conversion layer 73 can be identical or different from the next color conversion layer 73.

In one embodiment, the illumination source 62 produces a light with a photon flux or average peak pulse power of at least 1 nW·cm⁻², 50 nW·cm⁻², 100 nW·cm⁻², 200 nW·cm⁻², 300 nW·cm⁻², 400 nW·cm⁻², 500 nW·cm⁻², 600 nW·cm⁻², 700 nW·cm⁻², 800 nW·cm⁻², 900 nW·cm⁻², 1 μW·cm⁻², 10 μW·cm⁻², 100 μW·cm⁻², 500 μW·cm⁻², 1 mW·cm⁻², 50 mW·cm⁻², 100 mW·cm⁻², 500 mW·cm⁻², 1 W·cm⁻², 5 W·cm⁻², 10 W·cm⁻², 20 W·cm⁻², 30 W·cm⁻², 40 W·cm⁻², 50 W·cm⁻², 60 W·cm⁻², 70 W·cm⁻², 80 W·cm⁻², 90 W·cm⁻², 100 W·cm⁻², 110 W·cm⁻², 120 W·cm⁻², 130 W·cm⁻², 140 W·cm⁻², 150 W·cm⁻², 160 W·cm⁻², 170 W·cm⁻², 180 W·cm⁻², 190 W·cm⁻², 200 W·cm⁻², 300 W·cm⁻², 400 W·cm⁻², 500 W·cm⁻², 600 W·cm⁻², 700 W·cm⁻², 800 W·cm⁻², 900 W·cm⁻², 1 kW·cm⁻², 50 kW·cm⁻², or 100 kW·cm⁻².

According to one embodiment illustrated FIG. 28, the illumination source 62 comprises a color conversion layer 73 and a light source 6111, and the color conversion layer 73 having a shape of a film is in contact with the light source 6111. The light source 6111 excites the color conversion layer 73 which emits a light at one specific wavelength or at different wavelengths.

According to one embodiment, the at least one color conversion layer 73 may be a film deposited on the light source 6111.

In one embodiment, the color conversion layer 73 is deposited onto the light source 6111 by drop-casting, spin coating, dip coating, inkjet printing, lithography, spray, plating, electroplating, or any other means known by the person skilled in the art.

According to one embodiment, the at least one color conversion layer 73 is deposited on the light source 6111, and the at least one color conversion layer 73 is in contact with said light source 6111.

According to one embodiment, the at least one color conversion layer 73 is deposited on the light source 6111, and the at least one color conversion layer 73 is not in contact with said light source 6111.

According to one embodiment, the illumination source 62 comprises a light guide 621.

According to one embodiment, the at least one color conversion layer 73 is located between the light source 6111 and said light guide 621.

According to one embodiment, the at least one color conversion layer 73 is deposited on the light guide 621, and the at least one color conversion layer 73 is in contact with said light guide 621.

According to one embodiment, the at least one color conversion layer 73 is deposited on the light guide 621, and the at least one color conversion layer 73 is not in contact with said light guide 621.

According to one embodiment, the light guide 621 distributes the light towards the color conversion layer 73.

According to one embodiment illustrated on FIG. 29, the color conversion layer 73 comprises an array of pixels, the light source 6111 comprises an array of light source pixels, and each pixel is illuminated and/or excited by at least one light source pixel of the light source 6111.

In one embodiment, each light source 6111 of the array of light sources 6111 is configured to illuminate and/or excite at least one sub-pixel.

According to one embodiment, the color conversion layer 73 comprises an array of pixels, each pixel comprising 3 sub-pixels. The 3 sub-pixels are: i) free of light emitting material 7, red sub-pixel and green sub-pixel both comprising at least one light emitting material 7, when the light source 6111 emits blue light.; or ii) blue sub-pixel, red sub-pixel and green sub-pixel all comprising at least one light emitting material, when the light source 6111 emits UV light.

According to one embodiment illustrated on FIG. 30, each pixel of the color conversion layer 73 is illuminated and/or excited by at least two light source pixels of the light source 6111, or by at least 3, 4, 5, 6, 7, 8, 9, 10, 11, 12, 13, 14, 15, 16, 17, 18, 19, 20, 21, 22, 23, 24, 25, 26, 27, 28, 29, 30, 40, 50, 60, 70, 80, 90, 100, 200, 300, 400, 500, 600, 700, 800, 900, 1000, 1500, 2000, 3500, 4000, 4500, 5000, 5500, 6000, 6500, 7000, 7500, 8000, 8500, 9000, 9500 or by at least 10000 light source pixels of the light source 6111.

According to one embodiment illustrated on FIG. 31, each light source pixel of the light source 6111 is able to illuminate and/or excite several pixels of the color conversion layer 73.

According to one embodiment, each light source pixel of the light source 6111 is able to illuminate and/or excite at least 2, 3, 4, 5, 6, 7, 8, 9, 10, 11, 12, 13, 14, 15, 16, 17, 18, 19, 20, 21, 22, 23, 24, 25, 26, 27, 28, 29, 30, 40, 50, 60, 70, 80, 90, 100, 200, 300, 400, 500, 600, 700, 800, 900, 1000, 1500, 2000, 3500, 4000, 4500, 5000, 5500, 6000, 6500, 7000, 7500, 8000, 8500, 9000, 9500 or by at least 10000 pixels of the color conversion layer 73.

As illustrated FIG. 32, FIG. 33 or FIG. 34, the illumination source 62 may be a backlight unit. In FIG. 32 and FIG. 33, the illumination source 62 comprises a space 622 between the light source 6111 and the light guide 621 that may be partially or completely void, an optically transparent substrate, or filled with gas such as for example air.

According to one embodiment, the illumination source 62 comprises a reflector 623.

According to one embodiment illustrated on FIG. 32, the light source 6111 illuminates a reflector 623 which redirects the light to the surface of the color conversion layer 73.

According to one embodiment, a light guide 621 may be added between the light source 6111 and the reflector 623 and/or between the reflector 623 and the color conversion layer 73 in order to improve the wave propagation by multiple reflections.

According to one embodiment illustrated on FIG. 33 and FIG. 34, the color conversion layer 73 is placed between the light source 6111 and the reflector 623. In said embodiment, the reflector 623 changes the direction of the light emitted by the color conversion layer 73, for example to a color display of an associated display apparatus.

According to one embodiment, the color conversion layer 73 is placed between the light source 6111 and the light guide 621.

According to one embodiment illustrated on FIG. 34, the color conversion layer 73 is deposited on the light source 6111.

In one embodiment, the color conversion layer 73 comprises a material configured to scatter the resulting light from said color conversion layer 73.

In one embodiment, examples of material configured to scatter the resulting light include but are not limited to: Al₂O₃, SiO₂, MgO, ZnO, ZrO₂, IrO₂, SnO₂, TiO₂, BaO, BaSO₄, BeO, CaO, CeO₂, CuO, Cu₂O, DyO₃, Fe₂O₃, Fe₃O₄, GeO₂, HfO₂, Lu₂O₃, Nb₂O₅, Sc₂O₃, TaO₅, TeO₂, Y₂O₃ particles, or a mixture thereof.

In another aspect, the present invention further relates to a display apparatus comprising an illumination source 62 as described hereabove.

FIG. 35 illustrates a display apparatus 61 comprising an illumination source 62 as described hereabove comprising a light source 6111 and at least one color conversion layer 73.

According to one embodiment, the display apparatus 61 further comprises at least one color filter 625 on a substrate 624.

According to one embodiment, the display apparatus 61 further comprises a color filter layer 625 on a substrate 624.

According to one embodiment, the display apparatus 61 comprises at least one layer of activation between the illumination source 62 and the at least one color filter 625.

According to one embodiment, the at least one layer of activation comprises a layer of liquid crystal material 6131 and/or an active matrix 6132, preferably an active thin-film-transistor matrix.

According to one embodiment, the display apparatus 61 may comprise a layer of active matrix 6132 such as a layer of liquid crystal material 6131 and at least one color filter 625.

According to one embodiment, the at least one color filter 625 is preferably fixed to a substrate 624.

According to one embodiment, the illumination source 62 is configured to provide light and an excitation to the at least one color filter 625.

In one embodiment, the at least one color filter 625 is a conventional color filter which is well-known by the skilled person.

In one embodiment, the at least one color filter 625 comprises at least one color conversion layer 73 of the invention.

In one embodiment, the at least one color filter 625 comprises at least one light emitting material 7 of the invention.

According to one embodiment, the display apparatus 61 comprises a plurality of color filters 625.

According to one embodiment, the plurality of color filters 625 are comprised in a plurality of pixels or a plurality of sub-pixels.

According to one embodiment, the display apparatus 61 may also comprise at least one polarizer 6141 and an additional light guide 621 between the illumination source 62 and the at least one layer of activation.

FIG. 36A and FIG. 36B illustrate another display apparatus 61 according to one embodiment of the present invention wherein the illumination source 62 comprises a light source 6111, at least one color conversion layer 73, a light guide 621 and a reflector 623. In FIG. 36A, the illumination source 62 comprises a space 622 between the light source 6111 and the color conversion layer 73. In FIG. 36B, the illumination source 62 comprises the light source 6111 coated by the color conversion layer 73.

FIG. 37 illustrates another display apparatus 61 according to one embodiment of the present invention wherein the illumination source 62 comprises a light source 6111, a color conversion layer 73, a light guide 621 and a reflector 623 reflecting the light from the light source 6111 to the color conversion layer 73. In FIG. 37, the light guide 621 is between the light source 6111 and the color conversion layer 73.

FIG. 38 illustrates a display apparatus 61 using such a conversion layer 73. Said display apparatus 61 comprises a glass substrate 6121, a color conversion layer 73 comprising an array of pixels, wherein each pixel comprises at least one sub-pixels, wherein each sub-pixel comprises at least one light emitting material 7 or is free of light emitting material. Said display apparatus 61 comprises an array of light sources 6111 for which each light source 6111 and each sub-pixel are associated two by two and, when activated, each light source 6111 is configured to illuminate and/or excite said one sub-pixel. At least one secondary light is emitted through a sub-pixel when the primary light from the associated light source 6111 illuminates and/or excites the at least one light emitting material 7 comprised in said sub-pixel, while the primary light is transmitted through a sub-pixel without emission of a secondary light when said sub-pixel is free of light emitting material 7 and is illuminated by said primary light from the associated light source 6111. In this embodiment, the display apparatus 61 comprises an active matrix 6132 (preferably an active TFT matrix) in order to activate each light source sub-pixel. The active matrix 6132 may comprise at least one transistor and at least one capacitor per sub-pixel.

According to one embodiment, the color conversion layer 73 comprises an array of pixels. Said embodiment avoids the illumination of the entire surface of the color conversion layer 73 saving energy.

In another aspect, illustrated on FIG. 39, the present invention further relates to a display apparatus 61 comprising at least one light source 6111 and a rotating wheel 63 comprising at least one color conversion layer 73 according to the present invention, wherein said at least one light source 6111 is configured to provide an illumination and/or an excitation for the at least one color conversion layer 73. The light of the light source 631 meet the rotating wheel 63 comprising the at least one color conversion layer 73. The at least one color conversion layer 73 comprises several zones including at least one zone comprising at least one light emitting material 7 or including at least two zones each comprising at least one light emitting material 7 able to emit secondary lights at different wavelengths. At least one zone may be free of at least one light emitting material 7, empty or optically transparent in order to permit the primary light to be transmitted through the rotating wheel 63 without emission of any secondary light.

In one embodiment, the light source 6111 is a laser source.

In one embodiment, the laser source is a blue laser source with a wavelength ranging from 400 nm to 470 nm. In one embodiment, the laser source has an emission peak at about 405 nm. In one embodiment, the laser source has an emission peak at about 447 nm. In one embodiment, the laser source has an emission peak at about 455 nm.

In one embodiment, the laser source is a UV laser source with a wavelength ranging from 200 nm to 400 nm. In one embodiment, the laser source has an emission peak at about 253 nm. In one embodiment, the laser source has an emission peak at about 365 nm. In one embodiment, the laser source has an emission peak at about 395 nm.

According to one embodiment, the laser source emits a blue-light or an UV-light and the rotating wheel 63 comprises at least one zone free of light emitting material 7, empty or optically transparent, at least one zone comprising at least one light emitting material 7 configured to emit red-light and at least one zone comprising at least one light emitting material 7 configured to emit green-light.

According to one embodiment, the laser source emits an UV-light and the rotating wheel 63 comprises at least one zone free of light emitting material 7, empty or optically transparent, at least one zone comprising at least one light emitting material 7 configured to emit red-light, at least one zone comprising at least one light emitting material 7 configured to emit green-light, at least one zone comprising at least one light emitting material 7 configured to emit orange-light, at least one zone comprising at least one light emitting material 7 configured to emit yellow-light, at least one zone comprising at least one light emitting material 7 configured to emit blue-light, and at least one zone comprising at least one light emitting material 7 configured to emit purple-light.

According to one embodiment, the light emitting material 7 emits red light with a maximum emission wavelength between 610 nm and 2500 nm, more preferably between 610 nm and 660 nm.

According to one embodiment, the light emitting material 7 emits green light with a maximum emission wavelength between 500 nm and 565 nm, more preferably between 510 nm and 545 nm.

According to one embodiment, the light emitting material 7 emits orange light with a maximum emission wavelength between 586 nm and 609 nm, more preferably between 590 nm and 605 nm.

According to one embodiment, the light emitting material 7 emits yellow light with a maximum emission wavelength between 566 nm and 585 nm, more preferably between 570 nm and 585 nm.

According to one embodiment, the light emitting material 7 emits blue light with a maximum emission wavelength between 440 nm and 499 nm, more preferably between 450 nm and 490 nm.

According to one embodiment, the light emitting material 7 emits purple light with a maximum emission wavelength between 380 nm and 439 nm, more preferably between 410 nm and 439 nm.

According to one embodiment, the rotating whee 63 has a shape of a disk, a ring, a square, a rectangle, a pentagon, a hexagon, a heptagon, a star or a triangle.

According to one embodiment, the center of mass of the rotating wheel 63 is at a distance of less than 100 cm, 90 cm, 80 cm, 70 cm, 60 cm, 50 cm, 40 cm, 30 cm, 20 cm, 10 cm, 5 cm, 1 cm, 9 mm, 8 mm, 7 mm, 6 mm, 5 mm, 4 mm, 3 mm, 2, or 1 mm to the farthest point in relation to said center of mass of the rotating wheel 63.

According to one embodiment, the rotating wheel 63 has a rough surface, for example, has a surface roughness value ranging from 10 nm to 300 nm.

According to one embodiment illustrated in FIG. 44A-B, the color conversion layer 73 forms a ring, or a ribbon centered around the center of the rotating wheel 63.

FIG. 44A-B illustrate a plane configuration of the rotating wheel 63. Said rotating wheel 63 comprises a reflective layer and a color conversion layer 73 that may be laminated in order on the surface of a thin plate having a circular planar shape.

According to one embodiment, the rotating wheel 63 comprises an opening at the center of the circular plate.

According to one embodiment, the color conversion layer 73 has a thickness ranging from 0 μm to 1 cm, from 10 μm to 1 mm or from 100 μm to 1000 μm.

According to one embodiment, the color conversion layer 73 has a rough surface, for example, has a surface roughness value ranging from 10 nm to 2000 nm, 50 nm to 1500 nm, 100 nm to 1000 nm, or 150 nm to 500 nm.

According to one embodiment, the color conversion layer 73 has a homogeneous thickness. In this embodiment, the thickness of the color conversion layer 73 does not vary and is the same all along said color conversion layer 73.

According to one embodiment, the color conversion layer 73 has a heterogeneous thickness. In this embodiment, the thickness of the color conversion layer 73 may vary and may be different in different zones of said color conversion layer 73.

According to one embodiment, the rotating whee 63 has a thickness ranging from 100 μm and 1 cm.

According to one embodiment, the rotating whee 63 and the color conversion layer 73 have a difference of refractive index lower than 1, lower than 0.8, lower than 0.6, lower than 0.4, lower than 0.2, lower than 0.1, lower than 0.08, lower than 0.06, lower than 0.04, lower than 0.02, lower than 0.01, lower than 0.005, lower than 0.001 or equal to 0 at 450 nm.

According to one embodiment, the rotating whee 63 has a thermal conductivity a thermal conductivity at standard conditions of at least 0.1 W/(m·K), 0.2 W/(m·K), 0.3 W/(m·K), 0.4 W/(m·K), 0.5 W/(m·K), 0.6 W/(m·K), 0.7 W/(m·K), 0.8 W/(m·K), 0.9 W/(m·K), 1.0 W/(m·K), 1.1 W/(m·K), 1.2 W/(m·K), 1.3 W/(m·K), 1.4 W/(m·K), 1.5 W/(m·K), 1.6 W/(m·K), 1.7 W/(m·K), 1.8 W/(m·K), 1.9 W/(m·K), 2 W/(m·K), 2.1 W/(m·K), 2.2 W/(m·K), 2.3 W/(m·K), 2.4 W/(m·K), 2.5 W/(m·K), 2.6 W/(m·K), 2.7 W/(m·K), 2.8 W/(m·K), 2.9 W/(m·K), 3.0 W/(m·K), 3.1 W/(m·K), 3.2 W/(m·K), 3.3 W/(m·K), 3.4 W/(m·K), 3.5 W/(m·K), 3.6 W/(m·K), 3.7 W/(m·K), 3.8 W/(m·K), 3.9 W/(m·K), 4.0 W/(m·K), 4.1 W/(m·K), 4.2 W/(m·K), 4.3 W/(m·K), 4.4 W/(m·K), 4.5 W/(m·K), 4.6 W/(m·K), 4.7 W/(m·K), 4.8 W/(m·K), 4.9 W/(m·K), 5.0 W/(m·K), 5.1 W/(m·K), 5.2 W/(m·K), 5.3 W/(m·K), 5.4 W/(m·K), 5.5 W/(m·K), 5.6 W/(m·K), 5.7 W/(m·K), 5.8 W/(m·K), 5.9 W/(m·K), 6.0 W/(m·K), 6.1 W/(m·K), 6.2 W/(m·K), 6.3 W/(m·K), 6.4 W/(m·K), 6.5 W/(m·K), 6.6 W/(m·K), 6.7 W/(m·K), 6.8 W/(m·K), 6.9 W/(m·K), 7.0 W/(m·K), 7.1 W/(m·K), 7.2 W/(m·K), 7.3 W/(m·K), 7.4 W/(m·K), 7.5 W/(m·K), 7.6 W/(m·K), 7.7 W/(m·K), 7.8 W/(m·K), 7.9 W/(m·K), 8.0 W/(m·K), 8.1 W/(m·K), 8.2 W/(m·K), 8.3 W/(m·K), 8.4 W/(m·K), 8.5 W/(m·K), 8.6 W/(m·K), 8.7 W/(m·K), 8.8 W/(m·K), 8.9 W/(m·K), 9.0 W/(m·K), 9.1 W/(m·K), 9.2 W/(m·K), 9.3 W/(m·K), 9.4 W/(m·K), 9.5 W/(m·K), 9.6 W/(m·K), 9.7 W/(m·K), 9.8 W/(m·K), 9.9 W/(m·K), 10.0 W/(m·K), 10.1 W/(m·K), 10.2 W/(m·K), 10.3 W/(m·K), 10.4 W/(m·K), 10.5 W/(m·K), 10.6 W/(m·K), 10.7 W/(m·K), 10.8 W/(m·K), 10.9 W/(m·K), 11.0 W/(m·K), 11.1 W/(m·K), 11.2 W/(m·K), 11.3 W/(m·K), 11.4 W/(m·K), 11.5 W/(m·K), 11.6 W/(m·K), 11.7 W/(m·K), 11.8 W/(m·K), 11.9 W/(m·K), 12.0 W/(m·K), 12.1 W/(m·K), 12.2 W/(m·K), 12.3 W/(m·K), 12.4 W/(m·K), 12.5 W/(m·K), 12.6 W/(m·K), 12.7 W/(m·K), 12.8 W/(m·K), 12.9 W/(m·K), 13.0 W/(m·K), 13.1 W/(m·K), 13.2 W/(m·K), 13.3 W/(m·K), 13.4 W/(m·K), 13.5 W/(m·K), 13.6 W/(m·K), 13.7 W/(m·K), 13.8 W/(m·K), 13.9 W/(m·K), 14.0 W/(m·K), 14.1 W/(m·K), 14.2 W/(m·K), 14.3 W/(m·K), 14.4 W/(m·K), 14.5 W/(m·K), 14.6 W/(m·K), 14.7 W/(m·K), 14.8 W/(m·K), 14.9 W/(m·K), 15.0 W/(m·K), 15.1 W/(m·K), 15.2 W/(m·K), 15.3 W/(m·K), 15.4 W/(m·K), 15.5 W/(m·K), 15.6 W/(m·K), 15.7 W/(m·K), 15.8 W/(m·K), 15.9 W/(m·K), 16.0 W/(m·K), 16.1 W/(m·K), 16.2 W/(m·K), 16.3 W/(m·K), 16.4 W/(m·K), 16.5 W/(m·K), 16.6 W/(m·K), 16.7 W/(m·K), 16.8 W/(m·K), 16.9 W/(m·K), 17.0 W/(m·K), 17.1 W/(m·K), 17.2 W/(m·K), 17.3 W/(m·K), 17.4 W/(m·K), 17.5 W/(m·K), 17.6 W/(m·K), 17.7 W/(m·K), 17.8 W/(m·K), 17.9 W/(m·K), 18.0 W/(m·K), 18.1 W/(m·K), 18.2 W/(m·K), 18.3 W/(m·K), 18.4 W/(m·K), 18.5 W/(m·K), 18.6 W/(m·K), 18.7 W/(m·K), 18.8 W/(m·K), 18.9 W/(m·K), 19.0 W/(m·K), 19.1 W/(m·K), 19.2 W/(m·K), 19.3 W/(m·K), 19.4 W/(m·K), 19.5 W/(m·K), 19.6 W/(m·K), 19.7 W/(m·K), 19.8 W/(m·K), 19.9 W/(m·K), 20.0 W/(m·K), 20.1 W/(m·K), 20.2 W/(m·K), 20.3 W/(m·K), 20.4 W/(m·K), 20.5 W/(m·K), 20.6 W/(m·K), 20.7 W/(m·K), 20.8 W/(m·K), 20.9 W/(m·K), 21.0 W/(m·K), 21.1 W/(m·K), 21.2 W/(m·K), 21.3 W/(m·K), 21.4 W/(m·K), 21.5 W/(m·K), 21.6 W/(m·K), 21.7 W/(m·K), 21.8 W/(m·K), 21.9 W/(m·K), 22.0 W/(m·K), 22.1 W/(m·K), 22.2 W/(m·K), 22.3 W/(m·K), 22.4 W/(m·K), 22.5 W/(m·K), 22.6 W/(m·K), 22.7 W/(m·K), 22.8 W/(m·K), 22.9 W/(m·K), 23.0 W/(m·K), 23.1 W/(m·K), 23.2 W/(m·K), 23.3 W/(m·K), 23.4 W/(m·K), 23.5 W/(m·K), 23.6 W/(m·K), 23.7 W/(m·K), 23.8 W/(m·K), 23.9 W/(m·K), 24.0 W/(m·K), 24.1 W/(m·K), 24.2 W/(m·K), 24.3 W/(m·K), 24.4 W/(m·K), 24.5 W/(m·K), 24.6 W/(m·K), 24.7 W/(m·K), 24.8 W/(m·K), 24.9 W/(m·K), 25.0 W/(m·K), 30 W/(m·K), 40 W/(m·K), 50 W/(m·K), 60 W/(m·K), 70 W/(m·K), 80 W/(m·K), 90 W/(m·K), 100 W/(m·K), 110 W/(m·K), 120 W/(m·K), 130 W/(m·K), 140 W/(m·K), 150 W/(m·K), 160 W/(m·K), 170 W/(m·K), 180 W/(m·K), 190 W/(m·K), 200 W/(m·K), 210 W/(m·K), 220 W/(m·K), 230 W/(m·K), 240 W/(m·K), 250 W/(m·K), 260 W/(m·K), 270 W/(m·K), 280 W/(m·K), 290 W/(m·K), 300 W/(m·K), 310 W/(m·K), 320 W/(m·K), 330 W/(m·K), 340 W/(m·K), 350 W/(m·K), 360 W/(m·K), 370 W/(m·K), 380 W/(m·K), 390 W/(m·K), 400 W/(m·K), 410 W/(m·K), 420 W/(m·K), 430 W/(m·K), 440 W/(m·K), or 450 W/(m·K). In this embodiment, the rotating whee 63 can evacuate the heat from the color converrsion layer 73.

According to one embodiment, the rotating whee 63 is a multi-layer material.

According to one embodiment, the multi-layer material is polymeric, as described hereabove.

According to one embodiment, the multi-layer material comprises an organic material and/or a polymer as described hereabove.

According to one embodiment, the multi-layer material is inorganic, as described hereabove.

According to one embodiment, the multi-layer material comprises an inorganic material as described hereabove.

According to another embodiment, the multi-layer material is a composite material comprising at least one inorganic material and at least one polymeric material, each being as described hereabove.

According to another embodiment, the multi-layer material is a mixture of at least one inorganic material and at least one polymeric material, each being as described hereabove.

According to one embodiment, the color conversion layer 73 is coated onto the surface of the rotating whee 63 for example by drop-casting, spin coating, dip coating, inkjet printing, lithography, spray, plating, electroplating, or any other means known by the person skilled in the art.

According to one embodiment, the rotating whee 63 is optically transparent. In this embodiment, the rotating whee 63 is configured to work in a transmission mode.

According to one embodiment, the rotating whee 63 comprises an optically transparent material allowing to transmit the light. In this embodiment, the rotating whee 63 is configured to work in a transmission mode.

According to one embodiment, the rotating whee 63 comprises a material allowing to reflect the light such as for example a metal like aluminium and silver, a glass, a polymer or a plastic. In this embodiment, the rotating whee 63 is configured to work in a reflective mode.

According to one embodiment, the rotating whee 63 is configured to work in a transmission mode. In such a mode, the rotating whee 63 transmits at least 50%, 60%, 70%, 80%, 85%, 90%, 95%, or 100% of the primary light, of the secondary light and/or of the resulting light. In this embodiment, said transmitted light is generally directed towards other components of a device to create and display pictures.

According to one embodiment, the rotating whee 63 is configured to work in a reflective mode. In such a mode, the rotating whee 63 reflects at least 50%, 60%, 70%, 80%, 85%, 90%, 95%, or 100% of the primary light, of the secondary light and/or of the resulting light. In this embodiment, said reflected light is generally directed towards other components of a device to create and display pictures.

According to one embodiment, the light reflected by the rotating whee 63 is reflected in another direction than the direction of the incident light.

According to one embodiment, the angle between the direction of the incident light and the direction of the light reflected by the rotating whee 63 is at least 1°, 2°, 3°, 4°, 5°, 6°, 7°, 8°, 9°, 10°, 11°, 12°, 13°, 14°, 15°, 16°, 17°, 18°, 19°, 20°, 21°, 22°, 23°, 24°, 25°, 26°, 27°, 28°, 29°, 30°, 31°, 32°, 33°, 34°, 35°, 36°, 37°, 38°, 39°, 40°, 41°, 42°, 43°, 44°, 45°, 46°, 47°, 48°, 49°, 50°, 51°, 52°, 53°, 54°, 55°, 56°, 57°, 58°, 59°, 60°, 61°, 62°, 63°, 64°, 65°, 66°, 67°, 68°, 69°, 70°, 71°, 72°, 73°, 74°, 75°, 76°, 77°, 78°, 79°, 80°, 81°, 82°, 83°, 84°, 85°, 86°, 87°, 88°, 89°, 90°, 91°, 92°, 93°, 94°, 95°, 96°, 97°, 98°, 99°, 100°, 101°, 102°, 103°, 104°, 105°, 106°, 107°, 108°, 109°, 110°, 111°, 112°, 113°, 114°, 115°, 116°, 117°, 118°, 119°, 120°, 121°, 122°, 123°, 124°, 125°, 126°, 127°, 128°, 129°, 130°, 131°, 132°, 133°, 134°, 135°, 136°, 137°, 138°, 139°, 140°, 141°, 142°, 143°, 144°, 145°, 146°, 147°, 148°, 149°, 150°, 151°, 152°, 153°, 154°, 155°, 156°, 157°, 158°, 159°, 160°, 161°, 162°, 163°, 164°, 165°, 166°, 167°, 168°, 169°, 170°, 171°, 172°, 173°, 174°, 175°, 176°, 177°, 178°, 179° or 180°.

According to one embodiment, the rotation of the whee 63 may be electronically controlled to select a zone of the rotating whee 63 to be illuminated and/or excited by the primary light from the light source 6111.

According to one embodiment, the rotation of the whee 63 may be electronically controlled to be a continuous rotation, such that the primary light from the light source 6111 illuminates and/or excites successively the at least one zone of said rotating whee 63 at a constant rotation speed.

According to one embodiment, the rotating whee 63 is connected to a motor configured to turn the whee 63 around its center of mass at a speed ranging from 50 to 10 000 000 turns per second.

According to one embodiment, the rotating whee 63 is connected to a motor configured to turn the whee 63 around its center of mass at a speed ranging of at least 50, 60, 70, 80, 90, 100, 200, 300, 400, 500, 600, 700, 800, 900, 1000, 2000, 3000, 4000, 5000, 6000, 7000, 8000, 9000, 10 000, 20 000, 30 000, 40 000, 50 000, 60 000, 70 000, 80 000, 90 000, 100 000, 200 000, 300 000, 400 000, 500 000, 600 000, 700 000, 800 000, 900 000, 1 000 000, 2 000 000, 3 000 000, 4 000 000, 5 000 000, 6 000 000, 7 000 000, 8 000 000, 9 000 000, or 10 000 000 turns per second.

According to one embodiment illustrated in FIG. 39 and FIG. 45B, the rotating whee 63 is configured to work in a transmission mode as described hereabove. If the at least one zone of the rotating whee 63 is illuminated and/or excited by a pimary light from the light source 6111 and includes at least one light emitting material 7, a secondary light is emitted and transmitted through the rotating wheel 63. If the at least one zone of the rotating whee 63 is illuminated by a pimary light from the light source 6111 and is free of light emitting material 7 or includes an optically transparent material or is empty, the primary light is transmitted through the rotating whee 63 without any emission of secondary light. The intensity of each colored light may be controlled by the frequency or the number of the pulsation laser, leading to different pictures after each complete rotation of the rotating wheel 63. In this embodiment, the rotating whee 63 preferably comprises a color conversion layer comprising: at least one zone comprising a light emitting material 7 emitting red secondary light; at least one zone comprising a light emitting material 7 emitting green secondary light; and at least one zone free of light emitting material 7, so that said zone transmits the primary light, preferably a blue primary light.

According to one embodiment illustrated in FIG. 41 and FIG. 45A, the rotating whee 63 is configured to work in a reflective mode as described hereabove. If the at least one zone of the rotating whee 63 is illuminated and/or excited by a pimary light from the light source 6111 and includes at least one light emitting material 7, a secondary light is emitted and reflected by the rotating wheel 63. If the at least one zone of the rotating whee 63 is illuminated by a pimary light from the light source 6111 and is free of light emitting material 7 or includes an optically transparent material or is empty, the primary light is reflected by the rotating wheel 63. The intensity of each colored light may be controlled by the frequency or the number of the pulsation laser, leading to different pictures after each complete rotation of the rotating wheel 63.

According to one embodiment, illustrated in FIG. 40, the display apparatus 61 further comprises at least one wavelength splitter system 6391, at least one wavelength combiner system 6392 and/or at least one mirror 6384. The resulting light may be guided towards different directions depending on their color or wavelength, for example with a wavelength splitter system 6391, and then recombinate with a wavelength combiner system 6392 after being reflected by mirrors 6384 or refracted by other wavelength splitter systems 6391, allowing to control the optical path length of each colored light. The intensity of each colored light may be controlled by the frequency or the number of the pulsation laser before the recombination of said colored lights, leading to different pictures after each complete rotation of the rotating wheel 63.

According to one embodiment, the display apparatus 61 comprises color filters.

According to one embodiment, the display apparatus 61 comprises an optical component 634 which permits to focalize the light produced by the rotating whee 63 comprising the color conversion layer 73 such as an optical lens or a succession of optical lenses.

According to one embodiment, the display apparatus 61 further comprises a modulating optical system 635 such as a digital micromirror device known by the skilled artisan to reflect the light in the direction of a screen 637.

According to one embodiment, the digital micromirror device has on its surface a few or several millions microscopic mirrors 6381 arranged in a rectangular array or a square array which corresponds to the pixels in the image to be displayed. The mirrors may be individually rotated at angles of ±10-12°, corresponding to an ON or OFF states. In the ON state, light from the digital micromirror device is reflected into the optical component 634 making the pixel appears bright on the screen. In the OFF state, the light is directed elsewhere (usually onto a heatsink), making the relative pixel appears dark. To produce greyscale, the mirrors are toggled ON and OFF very quickly, and the ratio of ON time to OFF time determines the shade produced.

According to one embodiment, the angle formed by the resulting light 632 from the rotating wheel 63 and the surface of the modulating optical system 635 is 10°, 15°, 20°, 25°, 30°, 35°, 40°, 45°, 50°, 55°, 60°, 65°, 70°, 75° or 80°.

According to one embodiment, the mirrors of the digital micromirror device may be made of aluminum or silver for example.

According to one embodiment, the display apparatus 61 further comprises at least one color filter between the rotating whee 63 and the modulating optical system 635.

According to one embodiment, the display apparatus 61 further comprise an electronic system configured to synchronize the rotating wheel 63, the light source 6111 and the modulating optical system 635 in order to display a picture, a succession of pictures or a video on the screen 637.

According to one embodiment, the display apparatus 61 further comprise an electronic system configured to synchronize the rotating whee 63 and the light source 6111 in order to display a picture, a succession of pictures or a video on the screen 637.

According to one embodiment, the display apparatus 61 further comprises an additional optical component 634 between the digital micromirror device and the screen 637.

Therefore, in one embodiment, the light source 6111 emits a primary light 631 which illuminate and/or excite the color conversion layer 73 of the invention on the rotating wheel 63. The at least one light emitting material 7 comprised in the color conversion layer 73 is excited and emits a secondary light at a different wavelength 632 with respect to the wavelength of the primary light. The resulting light is focalized on the optical component 634 and is reflected by the digital micromirror device. Then, the resulting light passes through a second optical component 634 and the beam of light 636 of the formed image thus illuminates the screen 637.

In another aspect, illustrated on FIG. 42A, the present invention further relates to a display apparatus 61 comprising at least one light source 6111 and a digital micromirror device 638 comprising at least one color conversion layer 73 according to the present invention, wherein said at least one light source 6111 is configured to provide an illumination and/or an excitation for the at least one color conversion layer 73. The primary light supplied by the light source 631 meet the digital micromirror device 638 comprising the at least one color conversion layer 73.

In one embodiment, the light source 6111 is as described hereabove.

In one embodiment, the at least one primary light supplied by the light source 6111 is as described hereabove.

According to one embodiment, the digital micromirror device 638 is known by the skilled artisan.

According to one embodiment, the digital micromirror device 638 has on its surface a few or several millions microscopic mirrors 6381 arranged in a rectangular array or a square array which corresponds to the sub-pixels in the image to be displayed. The mirrors may be individually rotated at angles of ±10-12°, corresponding to ON or OFF states. In the ON state, light from the digital micromirror device is reflected into the optical component 634 making the sub-pixel appear bright on the screen. In the OFF state, the light is directed elsewhere (usually onto a heatsink), making the relative sub-pixel appear dark. To produce greyscale, the mirrors are toggled ON and OFF very quickly, and the ratio of ON time to OFF time determines the shade produced.

According to one embodiment, the digital micromirror device 638 comprises a material allowing to reflect the light such as for example a metal like aluminium and silver, a glass, a polymer or a plastic.

According to one embodiment, the digital micromirror device 638 reflects at least 50%, 60%, 70%, 80%, 85%, 90%, 95%, or 100% of the primary light, the secondary light and/or the resulting light. In this embodiment, said reflected light is generally directed towards other components of a device to create and display pictures.

According to one embodiment, the light reflected by the digital micromirror device 638 is reflected in another direction than the direction of the incident light.

According to one embodiment, the digital micromirror device 638 is configured to reflect the light in the direction of a screen 637.

According to one embodiment, each microscopic mirror of the digital micromirror device 6381 corresponds to one pixel in the image to be displayed.

According to one embodiment, each microscopic mirror of the digital micromirror device 6381 corresponds to one sub-pixel in the image to be displayed.

According to one embodiment, each microscopic mirror of the digital micromirror device 6381 comprises at least one light emitting material 7, which emit a secondary light of only one color or wavelength.

According to one embodiment, each microscopic mirror of the digital micromirror device 6381 comprises at least one light emitting material 7, which emit a secondary light of different colors or wavelengths.

According to one embodiment, some microscopic mirror of the digital micromirror device 6381 comprise at least one light emitting material and some microscopic mirror 6382 are free of light emitting material 7, empty or optically transparent.

According to one embodiment, a microscopic mirror of the digital micromirror device 6382 being free of light emitting material 7, empty or optically transparent permits the primary light to be reflected by said microscopic mirrors 6381 without emission of any secondary light.

According to one embodiment illustrated in FIG. 42B, each pixel in the image to be displayed is formed by at least three sub-pixels: a first one corresponding to a microscopic mirror 6382 free of light emitting material 7, empty or optically transparent, a second one corresponding to a microscopic mirror 6381 comprising a red emitting light emitting material 7, and a third one corresponding to a microscopic mirror 6381 comprising a green emitting light emitting material 7. In this embodiment, monochromatic and polychromatic colors can be obtained for said pixel, depending on the ON and OFF states of said microscopic mirrors 6381. The digital micromirror device 638 comprises microscopic mirrors (6382, 6381) on a support 6383. The microscopic mirror of the digital micromirror device 6381 comprising at least one light emitting material 7, which emit a secondary light of only one color or wavelength, and the microscopic mirror of the digital micromirror device 6382 being free of light emitting material 7 (empty or optically transparent) permits the primary light to be reflected by said microscopic mirrors 6381 without emission of any secondary light. The possible light path from the light source and the possible light paths of secondary light or primary light are referenced as 631 and 632 respectively.

According to one embodiment, each pixel in the image to be displayed is formed by at least three sub-pixels: a first one corresponding to a microscopic mirror 6381 comprising a blue emitting light emitting material 7, empty or optically transparent, a second one corresponding to a microscopic mirror 6381 comprising a red emitting light emitting material 7, and a third one corresponding to a microscopic mirror 6381 comprising a green emitting light emitting material 7. In this embodiment, monochromatic and polychromatic colors can be obtained for said pixel, depending on the ON and OFF states of said microscopic mirrors 6381.

According to one embodiment, the light emitting material 7 has a thickness ranging from 1 μm to 1 cm, from 10 μm to 1 mm or from 100 μm to 1000 μm.

According to one embodiment, the digital micromirror device 638 and the color conversion layer 73 have a difference of refractive index lower than 1, lower than 0.8, lower than 0.6, lower than 0.4, lower than 0.2, lower than 0.1, lower than 0.08, lower than 0.06, lower than 0.04, lower than 0.02, lower than 0.01, lower than 0.005, lower than 0.001 or equal to 0 at 450 nm.

According to one embodiment, the digital micromirror device 638 is a multi-layer material as described hereabove.

According to one embodiment, the color conversion layer 73 is coated onto the surface of the digital micromirror device 638 for example by drop-casting, spin coating, dip coating, inkjet printing, lithography, spray, plating, electroplating, or any other means known by the person skilled in the art.

According to one embodiment, the display apparatus 61 comprises color filters.

According to one embodiment, the display apparatus 61 further comprise an electronic system configured to synchronize the digital micromirror device 638 and the light source 6111 in order to display a picture, a succession of pictures or a video on the screen 637.

According to one embodiment, the display apparatus 61 further comprises an additional optical component 634 between the digital micromirror device and the screen 637.

According to one embodiment, the additional optical component 634 permits to focalize the light produced by the digital micromirror device 638 comprising the color conversion layer 73 such as an optical lens or a succession of optical lenses.

According to one embodiment, the display apparatus 61 further comprises at least one color filter between the digital micromirror device 638 and the additional optical component 634.

Therefore, in one embodiment, the primary light 631 emitted by the light source 6111 through an optical component 634 may illuminate and/or excite the microscopic mirrors of the digital micromirror device 6381, where each microscopic mirror 6381 corresponds to one sub-pixel in the image to be displayed and comprises at least one light emitting material 7 of the color conversion layer 73 of the invention, or is free of light emitting material 7. At least one secondary light is emitted when the primary light excites the at least one light emitting material 7. The resulting light is then reflected onto the surface of said microscopic mirrors 6381, passes through a second optical component 634 and illuminates the screen 637 to form a clear image for a human eye.

While various embodiments have been described and illustrated, the detailed description is not to be construed as being limited hereto. Various modifications can be made to the embodiments by those skilled in the art without departing from the true spirit and scope of the disclosure as defined by the claims.

### BRIEF DESCRIPTION OF THE DRAWINGS

FIG. 1 illustrates an aggregate 1 comprising a material 11 and particles 12.

FIG. 2 illustrates an aggregate 1 comprising a material 11 and particles 12.

FIG. 3 illustrates an aggregate 1 comprising a plurality of spherical particles 128 encapsulated in a material 11.

FIG. 4 illustrates an aggregate 1 comprising a plurality of 2D particles 129 encapsulated in a material 11.

FIG. 5 illustrates an aggregate 1 comprising a plurality of spherical particles 128 and a plurality of 2D particles 129 encapsulated in a material 11.

FIG. 6 illustrates different particles 12.

FIG. 6A illustrates a core particle 123 without a shell.

FIG. 6B illustrates a core 123/shell 124 particle 12 with one shell 124.

FIG. 6C illustrates a core 123/shell (124, 125) particle 12 with two different shells (124, 125).

FIG. 6D illustrates a core 123/shell (124, 125, 126) particle 12 with two different shells (124, 125) surrounded by an oxide insulator shell 126.

FIG. 6E illustrates a core 123/crown 127 particle 129.

FIG. 6F illustrates a sectional view of a core 123/shell 124 particle 129 with one shell 124.

FIG. 6G illustrates a sectional view of a core 123/shell (124, 125) particle 129 with two different shells (124, 125).

FIG. 6H illustrates a sectional view of a core 123/shell (124, 125, 126) particle 129 with two different shells (124, 125) surrounded by an oxide insulator shell 126.

FIG. 7 illustrates an aggregate 1 having a core/shell structure.

FIG. 7A illustrates an aggregate 1 comprising a core 13 comprising a plurality of particles 129 encapsulated in a material, and a shell 14.

FIG. 7B illustrates an aggregate 1 comprising a core 13 comprising a plurality of particles 129 encapsulated in a material, and a shell 14 comprising a plurality of particles 128 encapsulated in a material.

FIG. 8 illustrates an aggregate 1 comprising a material 11 and particles 12, wherein the particle 12 comprises a material 121 and at least one nanoparticle 122, wherein said at least one nanoparticle 122 is dispersed in the material 121.

FIG. 9 illustrates a light emitting material 7.

FIG. 9A illustrates a light emitting material 7 comprising a host material 71 and at least one aggregate 1 of the invention.

FIG. 9B illustrates a light emitting material 7 comprising a host material 71; at least aggregate 1 of the invention; a plurality of particles comprising a material 121; and a plurality of 2D particles 129.

FIG. 10 illustrates an optoelectronic device.

FIG. 10A illustrates an optoelectronic device comprising a LED support 4, a LED chip 5 and light emitting material 7 deposited on said LED chip 5, wherein the light emitting material 7 covers the LED chip 5.

FIG. 10B illustrates an optoelectronic device comprising a LED support 4, a LED chip 5 and light emitting material 7 deposited on said LED chip 5 wherein the light emitting material 7 covers and surrounds the LED chip 5.

FIG. 11 illustrates a microsized LED 6 array comprising a LED support 4 and a plurality of microsized LED 6, wherein the pixel pitch D is the distance from the center of a pixel to the center of the next pixel.

FIG. 12 illustrates an optoelectronic device.

FIG. 12A illustrates an optoelectronic device comprising a LED support 4, a microsized LED 6 and light emitting material 7 deposited on said microsized LED 6, wherein the light emitting material 7 covers the microsized LED 6.

FIG. 12B illustrates an optoelectronic device comprising a LED support 4, a microsized LED 6 and light emitting material 7 deposited on said microsized LED 6 wherein the light emitting material 7 covers and surrounds the microsized LED 6.

FIG. 13 shows TEM images showing CdSe/CdZnS nanoplatelets dispersed in a material.

FIG. 13A is a TEM image showing CdSe/CdZnS nanoplatelets (dark contrast) dispersed in SiO₂ (bright contrast—@SiO₂).

FIG. 13B is a TEM image showing CdSe/CdZnS nanoplatelets (dark contrast) dispersed in SiO₂ (bright contrast—@SiO₂).

FIG. 13C is a TEM image showing CdSe/CdZnS nanoplatelets (dark contrast) dispersed in Al₂O₃ (bright contrast—@Al₂O₃).

FIG. 14 shows the N₂ adsorption isotherm of aggregates 1.

FIG. 14A shows the N₂ adsorption isotherm of aggregates 1 CdSe/CdZnS@SiO₂ prepared from a basic aqueous solution and from an acidic solution.

FIG. 14B shows the N₂ adsorption isotherm of aggregates 1 CdSe/CdZnS@Al₂O₃ obtained by heating droplets at 150° C., 300° C. and 550° C.

FIG. 15 illustrates the deposition of aggregates 1 on a support.

FIG. 16 shows TEM images of CdSe/CdS/ZnS@PMMA aggregates.

FIG. 16A is a TEM image of CdSe/CdS/ZnS @PMMA aggregates.

FIG. 16B is a TEM image of CdSe/CdS/ZnS@PMMA aggregates.

FIG. 16C is a TEM image of CdSe/CdS/ZnS@PMMA aggregates.

FIG. 16D is a TEM image of CdSe/CdS/ZnS@PMMA aggregates.

FIG. 17 illustrates a bead 3 comprising aggregates 1.

FIG. 18 illustrates an aggregate 1 comprising a material 11, dense particles 2 and particles 12.

FIG. 19 illustrates the energy barrier between a metastable state and a more stable state.

FIG. 20A illustrates a color conversion layer as described in the invention.

FIG. 20B illustrates a color conversion layer as described in the invention.

FIG. 20C illustrates a light emitting material comprising at least two host materials.

FIG. 20D illustrates a light emitting material comprising at least two host materials.

FIG. 20E illustrates a color conversion layer comprising three sub-pixels, wherein the first sub-pixel emits a green secondary light (G), the second sub-pixel emits a red secondary light (R), the third sub-pixel is free of light emitting material 7 or inorganic phosphor.

FIG. 21 illustrates a structure of a display apparatus as described in the invention comprising an active matrix to control the light intensity passing through the liquid crystal layer before said light excites a color conversion layer comprising an array of light emitting materials.

FIG. 22 illustrates a structure of a display apparatus as described in the invention comprising an optical enhancement film above the color conversion layer.

FIG. 23 illustrates a structure of a display apparatus as described in the invention comprising a glass substrate.

FIG. 24 illustrates a display apparatus comprising an individual light source for each light emitting material of the array of light emitting materials.

FIG. 25 illustrates a display apparatus comprising at least one laser source and an array of light emitting materials.

FIGS. 26A and 26B illustrate a display apparatus comprising at least one color conversion layer deposited onto a solid support.

FIGS. 27A and 27B illustrate a color conversion layer comprising an array of light emitting materials surrounded by a host material.

FIG. 28 illustrates an illumination source comprising a light source and a color conversion layer.

FIG. 29 illustrates an illumination source comprising an array of light source forming pixels and a color conversion layer comprising an array of light emitting materials.

FIG. 30 illustrates an illumination source wherein each pixel of the color conversion layer is illuminated by three light sources.

FIG. 31 illustrates an illumination source wherein each light source pixel of the light source is able to illuminate several pixels of the color conversion layer.

FIG. 32 illustrates an illumination source wherein the color conversion layer is upon a light guide, a reflector and a light source.

FIG. 33 illustrates an illumination source wherein the color conversion layer is between the light source and the reflector.

FIG. 34 illustrates an illumination source wherein the color conversion layer is deposited on the light source.

FIG. 35 illustrates a display apparatus comprising a light source, the color conversion layer, polarizers, an active matrix, a layer of liquid crystals material and a color filer layer.

FIGS. 36A and 36B illustrate a display apparatus wherein the light source is a backlight unit comprising a color conversion layer.

FIG. 37 illustrates a display apparatus wherein the light source is a backlight unit comprising a color conversion layer.

FIG. 38 illustrates a display apparatus comprising a light source and an active matrix.

FIG. 39 illustrates a display apparatus wherein the color conversion layer is deposited onto a rotation wheel and is excited by a light source.

FIG. 40 illustrates a display apparatus wherein the color conversion layer is deposited onto a rotation wheel and is excited by a light source.

FIG. 41 illustrates a display apparatus wherein the color conversion layer is deposited onto a rotation wheel and is excited by a light source. Said rotation wheel is configured to work in a reflective mode.

FIG. 42A illustrates a display apparatus comprising a digital micromirror device according to the invention.

FIG. 42B illustrates a digital micromirror device according to the invention.

FIG. 43 shows the absorbance spectra of CdSe/CdS/ZnS nanoplatelet (NPL in hexane) and CdSe/CdS/ZnS@PMMA in MMA. The absorption properties of the nanoplatelet are not deteriorated upon encapsulation.

FIG. 44 illustrates a a rotation wheel, wherein the color conversion layer forms a ring on said rotation wheel.

FIG. 45 illustrates a display apparatus wherein the color conversion layer is deposited onto a rotation wheel to form a ring and is excited by a light source.

### EXAMPLES

The present invention is further illustrated by the following examples.

### Example 1: Inorganic Nanoparticles Preparation

Nanoparticles used in the examples herein were prepared according to methods of the art (Lhuillier E. et al., Acc. Chem. Res., 2015, 48 (1), pp 22-30; Pedetti S. et al., J. Am. Chem. Soc., 2014, 136 (46), pp 16430-16438; Ithurria S. et al., J. Am. Chem. Soc., 2008, 130, 16504-16505; Nasilowski M. et al., Chem. Rev. 2016, 116, 10934-10982).

Nanoparticles used in the examples herein were selected in the group comprising CdSe/CdZnS, CdSe, CdS, CdTe, CdSe/CdS, CdSe/ZnS, CdSe/CdZnS, CdS/ZnS, CdS/CdZnS, CdTe/ZnS, CdTe/CdZnS, CdSeS/ZnS, CdSeS/CdS, CdSeS/CdZnS. CuInS₂/ZnS. CuInSe₂/ZnS. InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots.

### Example 2: Exchange Ligands for Phase Transfer in Acidic Aqueous Solution

100 μL of CdSe/CdZnS nanoplatelets suspended in a basic aqueous solution were mixed with ethanol and centrifugated. A PEG-based polymer was solubilized in water and added to the collected nanoplatelets. Acetic acid was dissolved in the colloidal suspension to control the acidic pH.

### Example 2bis: Exchange Ligands for Phase Transfer in Acidic Aqueous Solution

100 μL of CdSe/CdZnS nanoplatelets suspended in a basic aqueous solution were mixed with ethanol and centrifugated. Cysteamine-HCl was solubilized in water and added to the collected nanoplatelets and incubated at 60° C. for several hours. The dispersion was then centrifuged, washed, and resuspended into acetic acid solution to control the acidic pH.

### Example 3: Aggregates Preparation from a Basic Aqueous Solution—CdSe/CdZnS@SiO₂

100 μL of CdSe/CdZnS nanoplatelets suspended in a basic aqueous solution were mixed with a basic aqueous solution of TEOS at 0.13M previously hydrolyzed for 24 hours, then loaded on a spray-drying set-up. The liquid mixture was sprayed towards a tube furnace heated at a temperature ranging from the boiling point of the solvent to 1000° C. with a nitrogen flow. The aggregates were collected at the surface of a filter.

FIG. 13A-B show TEM images of the resulting aggregates.

FIG. 14A shows the N₂ adsorption isotherm of the resulting aggregates. Said resulting aggregates are porous.

The same procedure was carried out by replacing CdSe/CdZnS nanoplatelets with CdSe, CdS, CdTe, CdSe/CdS, CdSe/ZnS, CdSe/CdZnS, CdS/ZnS, CdS/CdZnS, CdTe/ZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing SiO₂ with ZnTe, Al₂O₃, HfO₂, ZnSe, ZnO, ZnS, TiO₂, MgO or a mixture thereof. Reaction temperature of the above procedure is adapted according to the inorganic material chosen.

The same procedure was carried out by replacing SiO₂ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 4: Aggregates Preparation from an Acidic Aqueous Solution—CdSe/CdZnS@SiO₂

100 μL of CdSe/CdZnS nanoplatelets suspended in an acidic aqueous solution were mixed with an acidic aqueous solution of TEOS at 0.13M previously hydrolyzed for 24 hours, then loaded on a spray-drying set-up. The liquid mixture was sprayed towards a tube furnace heated at a temperature ranging from the boiling point of the solvent to 1000° C. with a nitrogen flow. The aggregates were collected at the surface of a filter.

FIG. 14A shows the N₂ adsorption isotherm of the resulting aggregates. Said resulting aggregates are not porous.

The same procedure was carried out by replacing CdSe/CdZnS nanoplatelets with CdSe, CdS, CdTe, CdSe/CdS, CdSe/ZnS, CdSe/CdZnS, CdS/ZnS, CdS/CdZnS, CdTe/ZnS, CdTe/CdZnS, CdSeS/ZnS, CdSeS/CdS, CdSeS/CdZnS, CuInS2/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing SiO₂ with ZnTe, Al₂O₃, HfO₂, ZnSe, ZnO, ZnS, TiO₂, MgO or a mixture thereof. Reaction temperature of the above procedure is adapted according to the inorganic material chosen.

The same procedure was carried out by replacing SiO₂ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 5: Aggregates Preparation from a Basic Aqueous Solution with Hetero-Elements CdSe/CdZnS@SiₓCd_{y}Zn_{z}O_{w}

100 μL of CdSe/CdZnS nanoplatelets suspended in an acidic aqueous solution were mixed with an acidic aqueous solution of TEOS at 0.13M previously hydrolyzed for 24 hours in presence of cadmium acetate at 0.01M and zinc oxide at 0.01M, then loaded on a spray-drying set-up. The liquid mixture was sprayed towards a tube furnace heated at 150° C., 300° C. or 550° C. with a nitrogen flow. The aggregates were collected at the surface of a filter.

The same procedure was carried out by replacing CdSe/CdZnS nanoplatelets with CdSe, CdS, CdTe, CdSe/CdS, CdSe/ZnS, CdSe/CdZnS, CdS/ZnS, CdS/CdZnS, CdTe/ZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing SiₓCd_{y}Zn_{z}O_{w} with ZnTe, SiO₂, Al₂O₃, HfO₂, TiO₂, ZnSe, ZnO, ZnS, MgO or a mixture thereof. Reaction temperature of the above procedure is adapted according to the inorganic material chosen.

The same procedure was carried out by replacing SiₓCd_{y}Zn_{z}O_{w} with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 6: Aggregates Preparation from an Organic Solution and an Aqueous Solution—CdSe/CdZnS@Al₂O₃

100 μL of CdSe/CdZnS nanoplatelets suspended in heptane were mixed with aluminium tri-sec butoxide and 5 mL of pentane, then loaded on a spray-drying set-up. On another side, a basic aqueous solution was prepared and loaded the same spray-drying set-up, but at a different location than the first heptane solution. The two liquids were simultaneously sprayed towards a tube furnace heated at a temperature ranging from the boiling point of the solvent to 1000° C. with a nitrogen flow. The aggregates were collected at the surface of a filter.

FIG. 13C shows TEM images of the resulting aggregates.

FIG. 14B show N₂ adsorption isotherms for aggregates obtained after heating the droplets at 150° C., 300° C. and 550° C. Increasing the heating temperature results in a loss of the porosity. Thus aggregates obtained by heating at 150° C. are porous, whereas the aggregates obtained by heating at 300° C. and 550° C. are not porous.

The same procedure was carried out by replacing CdSe/CdZnS nanoplatelets with CdSe, CdS, CdTe, CdSe/CdS, CdSe/ZnS, CdSe/CdZnS, CdS/ZnS, CdS/CdZnS, CdTe/ZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing Al₂O₃ with ZnTe, SiO₂, HfO₂, ZnSe, ZnO, ZnS, TiO₂, MgO or a mixture thereof. Reaction temperature of the above procedure is adapted according to the inorganic material chosen.

The same procedure was carried out by replacing Al₂O₃ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 7: Aggregates Preparation from an Organic Solution and an Aqueous Solution—InP/ZnS@Al₂O₃

4 mL of InP/ZnS nanoparticles suspended in heptane were mixed with aluminium tri-sec butoxide and 400 mL of heptane, then loaded in a spray-drying set-up. On another side, an acidic aqueous solution was prepared and loaded in the same spray-drying set-up, but at a different location than the first hexane solution. The two liquids were simultaneously sprayed with two different means for forming droplets towards a tube furnace heated at a temperature ranging from the boiling point of the solvent to 1000° C. with a nitrogen flow. The aggregates were collected at the surface of a filter.

The same procedure was carried out by replacing InP/ZnS nanoparticles with CdSe, CdS, CdTe, CdSe/CdS, CdSe/ZnS, CdSe/CdZnS, CdS/ZnS, CdS/CdZnS, CdSe/CdZnS, CdTe/ZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing InP/ZnS nanoparticles with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing Al₂O₃ with ZnTe, SiO₂, HfO₂, ZnSe, ZnO, ZnS, TiO₂, MgO or a mixture thereof. Reaction temperature of the above procedure is adapted according to the inorganic material chosen.

The same procedure was carried out by replacing Al₂O₃ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 8: Aggregates Aggregates from an Organic Solution and an Aqueous Solution—CH₅N₂—PbBr₃@Al₂O₃

100 μL of CH₅N₂—PbBr₃ nanoparticles suspended in hexane were mixed with aluminium tri-sec butoxide and 5 mL of hexane, then loaded in a spray-drying set-up. On another side, an acidic aqueous solution was prepared and loaded in the same spray-drying set-up, but at a different location than the first hexane solution. The two liquids were simultaneously sprayed with two different means for forming droplets towards a tube furnace heated at a temperature ranging from the boiling point of the solvent to 1000° C. with a nitrogen flow. The aggregates were collected at the surface of a filter.

The same procedure was carried out by replacing CH₅N₂—PbBr₃ nanoparticles with CdSe, CdS, CdTe, CdSe/CdS, CdSe/ZnS, CdSe/CdZnS, CdS/ZnS, CdS/CdZnS, CdTe/ZnS, CdTe/CdZnS, CdSe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CH₅N₂—PbBr₃ nanoparticles with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing Al₂O₃ with ZnTe, SiO₂, HfO₂, ZnSe, ZnO, ZnS, TiO₂, MgO or a mixture thereof. Reaction temperature of the above procedure is adapted according to the inorganic material chosen.

The same procedure was carried out by replacing Al₂O₃ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 9: Aggregates Aggregates from an Organic Solution and an Aqueous Solution—CdSe/CdZnS—Au@SiO₂

On one side, 100 μL of gold nanoparticles and 100 μL of CdSe/CdZnS nanoplatelets suspended in heptane were mixed with aluminium tri-sec butoxide and 5 mL of heptane, then loaded in a spray-drying set-up. On another side, an acidic aqueous solution was prepared and loaded on the same spray-drying set-up, but at a different location than the first heptane solution. The two liquids were simultaneously sprayed towards a tube furnace heated at a temperature ranging from the boiling point of the solvent to 1000° C. with a nitrogen flow. The aggregates were collected at the surface of a GaN substrate. The GaN substrate with the deposited aggregates was then cut into pieces of 1 mm×1 mm and electricaly connected to get a LED emitting a mixture of the blue light and the light emitted by the fluorescent nanoparticles.

The same procedure was carried out by replacing CdSe/CdZnS nanoplatelets and/or Au nanoparticles with CdSe, CdS, CdTe, CdSe/CdS, CdSe/ZnS, CdSe/CdZnS, CdS/ZnS, CdS/CdZnS, CdTe/ZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdZnS nanoplatelets and/or Au nanoparticles with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing SiO₂with ZnTe, Al₂O₃, HfO₂, ZnSe, ZnO, ZnS, TiO₂, MgO or a mixture thereof. Reaction temperature of the above procedure is adapted according to the inorganic material chosen.

The same procedure was carried out by replacing SiO₂ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 10: Aggregates Aggregates from an Organic Solution and an Aqueous Solution Fe₃O₄@Al₂O₃—CdSe/CdZnS@SiO₂

On one side, 100 μL of Fe₃O₄ nanoparticles suspended in an acidic aqueous solution were mixed with an acidic aqueous solution of TEOS at 0.13M previously hydrolyzed for 24 hours. On another side, 100 μL of CdSe/CdZnS nanoplatelets suspended in heptane were mixed with aluminium tri-sec butoxide and 5 mL of heptane, then loaded on the same spray-drying set-up, but at a different location than the first aqueous solution. The two liquids were simultaneously sprayed with two different means for forming droplets towards a tube furnace heated at a temperature ranging from the boiling point of the solvent to 1000° C. with a nitrogen flow. The aggregates were collected at the surface of a filter. The aggregates comprise a core of silica containing Fe₃O₄ nanoparticles and a shell of alumina containing CdSe/CdZnS nanoplatelets.

The same procedure was carried out by replacing CdSe/CdZnS nanoplatelets and/or Fe₃O₄ nanoparticles with CdSe, CdS, CdTe, CdSe/CdS, CdSe/ZnS, CdSe/CdZnS, CdS/ZnS, CdS/CdZnS, CdTe/ZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdZnS nanoplatelets and/or Fe₃O₄ nanoparticles with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing SiO₂with ZnTe, Al₂O₃, HfO₂, ZnSe, ZnO, ZnS, TiO₂, MgO or a mixture thereof. Reaction temperature of the above procedure is adapted according to the inorganic material chosen.

The same procedure was carried out by replacing SiO₂ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 11: Preparation of Polymer Solubilized in an Aprotic Solvent

A solution of PEI (50 kDa-500 kDa) was prepared: 0.5 g of PEI was mixed with 20 mL of solvent and left to mix overnight.

A solution of PI (50 kDa-500 kDa) was prepared: 0.5 g of PI was mixed with 20 mL of solvent and left to mix overnight.

A solution of PiP (100 kDa-1000 kDa) was prepared: 0.5 g of PiP was mixed with 20 mL of solvent and left to mix overnight.

A solution of PVPy (50 kDa-800 kDa) was prepared: 0.5 g of PVPy was mixed with 20 mL of solvent and left to mix overnight.

A solution of PIB (50 kDa-800 kDa) was prepared: 0.5 g of PIB was mixed with 20 mL of solvent and left to mix overnight.

A solution of PMMA (60 kDa-1.3 MDa) was prepared: 0.4 g of PMMA was mixed with 20 mL of solvent and left to mix overnight.

A solution of PS (30 kDa to 1.3 MDa) was prepared: 0.5 g of PS was mixed with 20 mL of solvent and left to mix overnight.

A solution of PBMA (50-1000 kDa) was prepared: 0.5 g of PBMA was mixed with 20 mL of solvent and left to mix for several days.

A solution of PCL (10 kDa-800 kDa) was prepared: 0.5 g of PCL was mixed with 20 mL of solvent and left to mix overnight.

A solution of PGMA (10 kDa-800 kDa) was prepared: 0.3 g of PGMA was mixed with 20 mL of solvent and left to mix overnight.

A solution of PLA (10 kDa-800 kDa) was prepared: 0.5 g of PLA was mixed with 20 mL of solvent and left to mix overnight.

A solution of PVP (10 kDa-800 kDa) was prepared: 0.4 g of PVP was mixed with 20 mL of solvent and left to mix overnight.

A solution of PMMA (60 kDa-1.3 MDa) alongside a triblock-copolymer of Poly(ethylene oxide)-block-Poly(propylene oxide)-block-Poly(ethylene oxide) was prepared: 420 mg of PMMA with 0-400 mg of the block-copolymer was mixed with 20 mL of solvent and left to mix overnight.

A solution of PS (30 kDa to 1.3 MDa) alongside a triblock-copolymer of Poly(ethylene oxide)-block-Poly(propylene oxide)-block-Poly(ethylene oxide) was prepared: 400 mg of PS with 0-400 mg of the block-copolymer was mixed with 20 mL of solvent and left to mix overnight.

A 50% mass solution of PMMA (60 kDa-1.3 MDa) and 50% mass solution of PS (30 kDa to 1.3 MDa) was solubilized in an aprotic solvent: 210 mg of PMMA and 210 mg of PS was mixed with 20 mL of solvent and left to mix overnight.

A 80% mass solution of PMMA (60 kDa-1.3 MDa) and 20% mass solution of PS (30 kDa to 1.3 MDa) was solubilized in an aprotic solvent: 350 mg of PMMA and 80 mg of PS was mixed with 20 mL of solvent and left to mix overnight.

A solution of PBMA (50-1000 kDa) was prepared: 0.5 g of polymer was mixed with 20 mL of solvent and left to mix for several days.

### Example 12: Metastable Aggregates Preparation—CdSe/CdS/ZnS@PMMA

100 μL of CdSe/CdS/ZnS nanoplatelets suspended in heptane were mixed with a solution comprising 10 mL of toluene and 200 mg of PMMA (PolyMethylMethAcrylate, 120 kDa), then loaded on a spray-drying set-up. The liquid mixture was sprayed towards a tube furnace heated at 150 to 250° C. with a nitrogen flow. The aggregates were collected at the surface of a filter.

FIGS. 16A-D show TEM images of CdSe/CdS/ZnS @PMMA aggregates.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdSe/CdZnS, CdTe/ZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

### Example 13: Metastable Aggregates Dispersion in Monomeric Medium—CdSe/CdS/ZnS@PMMA in MMA

10 mg of CdSe/CdS/ZnS@PMMA were dispersed in 100 μL of MMA (MethylMethAcrylate) and sonicated. A transition occurs that lead to the deaggregation of CdSe/CdS/ZnS@PMMA aggregates. A transparent solution is finally obtained.

The same procedure was carried out by replacing CdSe/CdS/ZnS with CdSe, CdS, CdTe, CdSe/CdS, CdSe/ZnS, CdSe/CdZnS, CdS/ZnS, CdS/CdZnS, CdTe/ZnS, CdTe/CdZnS, CdSe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

### Example 14: Metastable Aggregates Preparation—CdSe/CdS/ZnS@PS

100 μL of CdSe/CdS/ZnS nanoplatelets suspended in heptane were mixed with a solution comprising 10 mL of toluene and 210 mg of PS (PolyStyrene, 280 kDa), then loaded on a spray-drying set-up. The liquid mixture was sprayed towards a tube furnace heated at 120 to 280° C. with a nitrogen flow. The aggregates were collected at the surface of a filter.

The same procedure was carried out by replacing PS with PMMA (Poly(methyl methacrylate)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdSe/CdZnS, CdTe/ZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

### Example 15: Metastable Aggregates Dispersion in Monomeric Medium—CdSe/CdS/ZnS@PS in Styrene

10 mg of CdSe/CdS/ZnS@PS were dispersed in 100 μL of styrene and sonicated. A transparent solution is finally obtained.

The same procedure was carried out by replacing CdSe/CdS/ZnS with CdSe, CdS, CdTe, CdSe/CdS, CdSe/ZnS, CdSe/CdZnS, CdS/ZnS, CdS/CdZnS, CdTe/ZnS, CdTe/CdZnS, CdSe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

### Example 16: Metastable Aggregates Preparation—CdSe/CdS/ZnS@PMMA

100 μL of CdSe/CdS/ZnS nanoplatelets suspended in heptane were mixed with a solution comprising 10 mL of THF and 200 mg of PMMA (PolyMethylMethAcrylate, 120 kDa), then loaded on a spray-drying set-up. The liquid mixture was sprayed towards a tube furnace heated at 150-250° C. with a nitrogen flow. The aggregates were collected at the surface of a filter.

The same procedure was carried out by replacing CdSe/CdS/ZnS nanoplatelets with CdSe, CdS, CdTe, CdSe/CdS, CdSe/ZnS, CdSe/CdZnS, CdSe/CdZnS, CdS/ZnS, CdS/CdZnS, CdTe/ZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

### Example 17: Metastable Aggregates Preparation—InP/ZnSe/ZnS@PMMA

100 μL of InP/ZnSe/ZnS nanocrystals suspended in heptane were mixed with a solution comprising 10 mL of toluene and 200 mg of PMMA (PolyMethylMethAcrylate, 120 kDa), then loaded on a spray-drying set-up. The liquid mixture was sprayed towards a tube furnace heated at 150-250° C. with a nitrogen flow. The aggregates were collected at the surface of a filter.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing InP/ZnSe/ZnS nanocrystals with CdSe, CdS, CdTe, CdSe/CdS, CdSe/ZnS, CdSe/CdZnS, CdS/ZnS, CdS/CdZnS, CdSe/CdZnS, CdTe/ZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing InP/ZnSe/ZnS nanocrystals with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

### Example 18: Metastable Aggregates Preparation—CdSe/CdS/ZnS@Al₂O₃@PMMA

30 mg of CdSe/CdS/ZnS@Al₂O₃ were dispersed in a solution comprising 10 mL of toluene and 900 mg of PMMA (PolyMethylMethAcrylate, 120 kDa), then loaded on a spray-drying set-up. The liquid mixture was sprayed towards a tube furnace heated at 150-250° C. with a nitrogen flow. The aggregates were collected at the surface of a filter.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing CdSe/CdS/ZnS with CdSe, CdS, CdTe, CdSe/CdS, CdSe/ZnS, CdSe/CdZnS, CdS/ZnS, CdS/CdZnS, CdTe/ZnS, CdTe/CdZnS, CdSe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing Al₂O₃ with ZnTe, SiO₂, HfO₂, ZnSe, ZnO, ZnS, TiO₂, MgO or a mixture thereof. Reaction temperature of the above procedure is adapted according to the inorganic material chosen.

The same procedure was carried out by replacing Al₂O₃ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 19: Metastable Aggregates Preparation—CdSe/CdS/ZnS@SiO₂

100 μL of CdSe/CdS/ZnS nanoplatelets suspended in heptane were mixed with a solution comprising 10 mL of THF and silica beads, then loaded on a spray-drying set-up. The liquid mixture was sprayed towards a tube furnace heated at a temperature ranging from the boiling point of the solvent to 1000° C. with a nitrogen flow. The aggregates were collected at the surface of a filter.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdTe/ZnS, CdTe/CdZnS, CdSe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing SiO₂ with ZnTe, Al₂O₃, HfO₂, ZnSe, ZnO, ZnS, TiO₂, MgO or a mixture thereof. Reaction temperature of the above procedure is adapted according to the inorganic material chosen.

The same procedure was carried out by replacing SiO₂ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 20: Metastable Aggregates Preparation—CdSe/CdS/ZnS@SiO₂

100 μL of CdSe/CdS/ZnS nanoplatelets suspended in heptane were mixed with a solution comprising 10 mL of toluene and silica beads, then loaded on a spray-drying set-up. The liquid mixture was sprayed towards a tube furnace heated at a temperature ranging from the boiling point of the solvent to 1000° C. with a nitrogen flow. The aggregates were collected at the surface of a filter.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdTe/ZnS, CdTe/CdZnS, CdSe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing SiO₂ with ZnTe, Al₂O₃, HfO₂, ZnSe, ZnO, ZnS, TiO₂, MgO or a mixture thereof. Reaction temperature of the above procedure is adapted according to the inorganic material chosen.

The same procedure was carried out by replacing SiO₂ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 21: Metastable Aggregates Preparation—CdSe/CdS/ZnS@Al₂O₃@SiO₂

30 mg of CdSe/CdS/ZnS@Al₂O₃ were dispersed in a solution comprising 10 mL of toluene and and silica beads, then loaded on a spray-drying set-up. The liquid mixture was sprayed towards a tube furnace heated at a temperature ranging from the boiling point of the solvent to 1000° C. with a nitrogen flow. The aggregates were collected at the surface of a filter.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdTe/ZnS, CdTe/CdZnS, CdSe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing Al₂O₃ and/or SiO₂with ZnTe, SiO₂, Al₂O₃, HfO₂, TiO₂, ZnSe, ZnO, ZnS, MgO or a mixture thereof. Reaction temperature of the above procedure is adapted according to the inorganic material chosen.

The same procedure was carried out by replacing Al₂O₃ and/or SiO₂with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 22: Metastable Aggregates Preparation—CdSe/CdS/ZnS@Al₂O₃@PMMA@SiO₂

30 mg of CdSe/CdS/ZnS@Al₂O₃@PMMA were dispersed in a solution comprising 10 mL of ethanol and silica beads, then loaded on a spray-drying set-up. The liquid mixture was sprayed towards a tube furnace heated at a temperature ranging from the boiling point of the solvent to 250° C. with a nitrogen flow. The aggregates were collected at the surface of a filter.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdTe/ZnS, CdTe/CdZnS, CdSe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing SiO₂ with ZnTe, HfO₂, Al₂O₃, ZnSe, ZnO, ZnS, TiO₂, MgO or a mixture thereof. Reaction temperature of the above procedure is adapted according to the inorganic material chosen.

The same procedure was carried out by replacing SiO₂ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 23: Metastable Aggregates Preparation—CdSe/CdS/ZnS@PMMA@SiO₂

30 mg of CdSe/CdS/ZnS@PMMA were dispersed in a solution comprising 10 mL of ethanol and silica beads, then loaded on a spray-drying set-up. The liquid mixture was sprayed towards a tube furnace heated at a temperature ranging from the boiling point of the solvent to 250° C. with a nitrogen flow. The aggregates were collected at the surface of a filter.

The same procedure was carried out by replacing with PS (Poly(Styrene)), PMMA (Poly(methyl methacrylate)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdTe/ZnS, CdTe/CdZnS, CdSe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing SiO₂ with ZnTe, HfO₂, Al₂O₃, ZnSe, ZnO, ZnS, TiO₂, MgO or a mixture thereof. Reaction temperature of the above procedure is adapted according to the inorganic material chosen.

The same procedure was carried out by replacing SiO₂ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 24: Metastable Aggregates—CdSe/CdS/ZnS@PMMA@SiO₂

30 mg of CdSe/CdS/ZnS@PMMA were dispersed in a solution comprising ethanol, TEOS, water and acetic acid, then loaded on a spray-drying set-up. The liquid mixture was sprayed towards a tube furnace heated at a temperature ranging from the boiling point of the solvent to 250° C. with a nitrogen flow. The aggregates were collected at the surface of a filter.

The same procedure was carried out by replacing PMMA with PS (Poly(Styrene)), PMMA (Poly(methyl methacrylate)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdTe/ZnS, CdTe/CdZnS, CdSe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing SiO₂ with ZnTe, HfO₂, Al₂O₃, ZnSe, ZnO, ZnS, TiO₂, MgO or a mixture thereof. Reaction temperature of the above procedure is adapted according to the inorganic material chosen.

The same procedure was carried out by replacing SiO₂ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 25: Metastable Aggregates Preparation—CdSe/CdS/ZnS@PMMA@SiO₂@PMMA

30 mg of CdSe/CdS/ZnS@PMMA@SiO₂ were dispersed in a solution comprising 10 mL of toluene and and 200 mg of PMMA (PolyMethylMethAcrylate, 120 kDa), then loaded on a spray-drying set-up. The liquid mixture was sprayed towards a tube furnace heated at 150-250° C. with a nitrogen flow. The aggregates were collected at the surface of a filter.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdTe/ZnS, CdTe/CdZnS, CdSe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing SiO₂ with ZnTe, HfO₂, Al₂O₃, ZnSe, ZnO, ZnS, TiO₂, MgO or a mixture thereof. Reaction temperature of the above procedure is adapted according to the inorganic material chosen.

The same procedure was carried out by replacing SiO₂ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 26: Metastable Aggregates Preparation—FAPbBr₃@PMMA@SiO₂@PMMA

30 mg of perovskite FAPbBr₃@PMMA@SiO₂ were dispersed in a solution comprising 10 mL of toluene and and 200 mg of PMMA (PolyMethylMethAcrylate, 120 kDa), then loaded on a spray-drying set-up. The liquid mixture was sprayed towards a tube furnace heated at 150-250° C. with a nitrogen flow. The aggregates were collected at the surface of a filter.

The same procedure was carried out by replacing FAPbBr₃ particles with Cs₃Bi₂I₉, Cs₃Bi₂Cl₉, Cs₃Bi₂Br₉, BFeO₃, KNbO₃, BaTiO₃, CH₃NH₃PbI₃, CH₃NH₃PbCl₃, CH₃NH₃PbBr₃, FAPbBr₃ (with FA formamidinium), FAPbCl₃, FAPbI₃, CsPbCl₃, CsPbBr₃, CsPbI₃, CsSnI₃, CsSnCl₃, CsSnBr₃, CsGeCl₃, CsGeBr₃, CsGeI₃, FAPbClₓBr_{y}I_{z} (with x, y and z independent decimal number from 0 to 5 and not simultaneously equal to 0), or a mixture thereof.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing SiO₂ with ZnTe, HfO₂, Al₂O₃, ZnSe, ZnO, ZnS, TiO₂, MgO or a mixture thereof. Reaction temperature of the above procedure is adapted according to the inorganic material chosen.

The same procedure was carried out by replacing SiO₂ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 27: Metastable Aggregates Preparation—InP/ZnS@PMMA@SiO₂@PMMA

30 mg of InP/ZnS@PMMA@SiO₂ were dispersed in a solution comprising 10 mL of toluene and and 200 mg of PMMA (PolyMethylMethAcrylate, 120 kDa), then loaded on a spray-drying set-up. The liquid mixture was sprayed towards a tube furnace heated at 150-250° C. with a nitrogen flow. The aggregates were collected at the surface of a filter.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing InP/ZnS with CdSe, CdS, CdTe, CdSe/CdS, CdSe/ZnS, CdSe/CdZnS, CdS/ZnS, CdS/CdZnS, CdTe/ZnS, CdTe/CdZnS, CdSeS /ZnS, CdSeS/CdS, CdSeS/CdZnS, CuInS₂/ZnS, CuInSe₂/ZnS, InP/CdS, InP/ZnS, InZnP/ZnS, CdSe/CdZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing InP/ZnS with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing SiO₂ with ZnTe, HfO₂, Al₂O₃, ZnSe, ZnO, ZnS, TiO₂, MgO or a mixture thereof. Reaction temperature of the above procedure is adapted according to the inorganic material chosen.

The same procedure was carried out by replacing SiO₂ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 28: Metastable Aggregates—CdSe/CdS/ZnS@PMMA@Al₂O₃

100 μL of CdSe/CdZnS@PMMA suspended in ethanol (10 mg/mL) were mixed with aluminium isopropoxide and 5 mL of ethanol, then loaded on a spray-drying set-up. On another side, an aqueous solution was prepared and loaded the same spray-drying set-up, but at a different location than the first ethanol solution. The two liquids were simultaneously sprayed towards a tube furnace heated at a temperature ranging from the boiling point of the solvent to 250° C. The resulting particles CdSe/CdZnS@PMMA@Al₂O₃ were collected at the surface of a filter.

The same procedure was carried out by replacing with PS (Poly(Styrene)), PMMA (Poly(methyl methacrylate)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

The same procedure was carried out by replacing CdSe/CdZnS nanoplatelets with CdSe, CdS, CdTe, CdSe/CdS, CdSe/ZnS, CdSe/CdZnS, CdS/ZnS, CdS/CdZnS, CdTe/ZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing Al₂O₃ with ZnTe, SiO₂, HfO₂, ZnSe, ZnO, ZnS, TiO₂, MgO or a mixture thereof. Reaction temperature of the above procedure is adapted according to the inorganic material chosen.

The same procedure was carried out by replacing Al₂O₃ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 29: Metastable Aggregates Preparation—CdSe/CdS/ZnS@PMMA@Al₂O₃@PMMA

30 mg of CdSe/CdS/ZnS@PMMA@Al₂O₃ were dispersed in a solution comprising 10 mL of toluene and and 200 mg of PMMA (PolyMethylMethAcrylate, 120 kDa), then loaded on a spray-drying set-up. The liquid mixture was sprayed towards a tube furnace heated at 150-250° C. with a nitrogen flow. The aggregates were collected at the surface of a filter.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdTe/ZnS, CdSe/CdZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing Al₂O₃ with ZnTe, SiO₂, HfO₂, ZnSe, ZnO, ZnS, TiO₂, MgO or a mixture thereof. Reaction temperature of the above procedure is adapted according to the inorganic material chosen.

The same procedure was carried out by replacing Al₂O₃ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 30: Metastable Aggregates Preparation—FAPbBr₃@PMMA@Al₂O₃@PMMA

30 mg of perovskite FAPbBr₃@PMMA@Al₂O₃ were dispersed in a solution comprising 10 mL of toluene and and 200 mg of PMMA (PolyMethylMethAcrylate, 120 kDa), then loaded on a spray-drying set-up. The liquid mixture was sprayed towards a tube furnace heated at 150-250° C. with a nitrogen flow. The aggregates were collected at the surface of a filter.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing FAPbBr₃ particles with Cs₃Bi₂I₉, Cs₃Bi₂Cl₉, Cs₃Bi₂Br₉, BFeO₃, KNbO₃, BaTiO₃, CH₃NH₃PbI₃, CH₃NH₃PbCl₃, CH₃NH₃PbBr₃, FAPbBr₃ (with FA formamidinium), FAPbCl₃, FAPbI₃, CsPbCl₃, CsPbBr₃, CsPbI₃, CsSnI₃, CsSnCl₃, CsSnBr₃, CsGeCl₃, CsGeBr₃, CsGeI₃, FAPbClₓBr_{y}I_{z} (with x, y and z independent decimal number from 0 to 5 and not simultaneously equal to 0), or a mixture thereof.

The same procedure was carried out by replacing Al₂O₃ with ZnTe, SiO₂, HfO₂, ZnSe, ZnO, ZnS, TiO₂, MgO or a mixture thereof. Reaction temperature of the above procedure is adapted according to the inorganic material chosen.

The same procedure was carried out by replacing Al₂O₃ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 31: Metastable Aggregates Preparation—InP/ZnS@PMMA@Al₂O₃@PMMA

30 mg of InP/ZnS@PMMA@ Al₂O₃ were dispersed in a solution comprising 10 mL of toluene and and 200 mg of PMMA (PolyMethylMethAcrylate, 120 kDa), then loaded on a spray-drying set-up. The liquid mixture was sprayed towards a tube furnace heated at 150-250° C. with a nitrogen flow. The aggregates were collected at the surface of a filter.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing InP/ZnS with CdSe, CdS, CdTe, CdSe/CdS, CdSe/ZnS, CdSe/CdZnS, CdS/ZnS, CdS/CdZnS, CdTe/ZnS, CdSe/CdZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing InP/ZnS with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing Al₂O₃ with ZnTe, SiO₂, HfO₂, ZnSe, ZnO, ZnS, TiO₂, MgO or a mixture thereof. Reaction temperature of the above procedure is adapted according to the inorganic material chosen.

The same procedure was carried out by replacing Al₂O₃ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 32: Metastable Aggregates Preparation—InP/ZnSe/ZnS@PMMA@SiO₂

30 mg of InP/ZnSe/ZnS@PMMA were dispersed in a solution comprising 10 mL of ethanol and silica beads, then loaded on a spray-drying set-up. The liquid mixture was sprayed towards a tube furnace heated at a temperature ranging from the boiling point of the solvent to 250° C. with a nitrogen flow. The aggregates were collected at the surface of a filter.

The same procedure was carried out by replacing with PS (Poly(Styrene)), PMMA (Poly(methyl methacrylate)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

The same procedure was carried out by replacing InP/ZnSe/ZnS with CdSe, CdS, CdTe, CdSe/CdS, CdSe/ZnS, CdSe/CdZnS, CdS/ZnS, CdS/CdZnS, CdTe/ZnS, CdSe/CdZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing InP/ZnSe/ZnS with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing SiO₂ with ZnTe, Al₂O₃, HfO₂, ZnSe, ZnO, ZnS, TiO₂, MgO or a mixture thereof. Reaction temperature of the above procedure is adapted according to the inorganic material chosen.

The same procedure was carried out by replacing SiO₂ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 33: Metastable Aggregates Preparation—CdSe/CdS/ZnS@Al₂O₃

100 μL of CdSe/CdS/ZnS nanoplatelets suspended in heptane were mixed with a solution comprising 10 mL of THF and alumina beads, then loaded on a spray-drying set-up. The liquid mixture was sprayed towards a tube furnace heated at a temperature ranging from the boiling point of the solvent to 1000° C. with a nitrogen flow. The aggregates were collected at the surface of a filter.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdTe/ZnS, CdSe/CdZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing Al₂O₃ with ZnTe, SiO₂, HfO₂, ZnSe, ZnO, ZnS, TiO₂, MgO or a mixture thereof. Reaction temperature of the above procedure is adapted according to the inorganic material chosen.

The same procedure was carried out by replacing Al₂O₃ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 34: Metastable Aggregates Preparation—Phosphor Particles @PMMA

100 μL of phosphor particles suspended in heptane were mixed with a solution comprising 10 mL of toluene and 200 mg of PMMA (PolyMethylMethAcrylate, 120 kDa), then loaded on a spray-drying set-up. The liquid mixture was sprayed towards a tube furnace heated at 150-250° C. with a nitrogen flow. The aggregates were collected at the surface of a filter.

Phosphor particles used for this example were: Yttrium aluminium garnet particles (YAG, Y₃Al₅O₁₂), (Ca,Y)-α-SiAlON:Eu particles, ((Y,Gd)₃(Al,Ga)₅O₁₂:Ce) particles, CaAlSiN₃:Eu particles, sulfide-based phosphor particles, PFS:Mn⁴⁺ particles (potassium fluorosilicate).

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

### Example 35: Metastable Aggregates Preparation from an Organic Solution with Polymeric Solution—CdSe/CdS/ZnS@PMMA

A solution of PMMA (Poly(methyl methacrylate), 60 kDa-1.3 MDa) solubilized in an aprotic solvent was prepared. Upon full solubilization, the sample was filtrated with a PTFE filter via a syringe. The sample solution was then mixed with 300 μL of CdSe/CdS/ZnS nanoparticles and was left to sonicate in an ultrasonic bath for several minutes. The sample was loaded on a spray-drying set-up. The liquid mixture was sprayed towards a tube furnace heated at a temperature of 150-250° C. with a continuous nitrogen flow. The aggregates were collected at the surface of a filter.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdTe/ZnS, CdSe/CdZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

### Example 36: Metastable Aggregates Preparation from an Organic Solution with Polymeric Solution—InP/ZnSeS/ZnS@PMMA

A solution of PMMA (60 kDa-1.3 MDa) solubilized in aprotic solvent was prepared (i.e. 0.4 g of polymer was mixed with 20 mL of solvent and left to mix overnight). Upon full solubilization, the sample was filtrated with a PTFE filter via a syringe. The sample solution was then mixed with 300 μL of InP/ZnSeS/ZnS nanoparticles and was left to sonicate in an ultrasonic bath for several minutes. The sample was loaded on a spray-drying set-up. The liquid mixture was sprayed towards a tube furnace heated at a temperature of 120-280° C. with a continuous nitrogen flow. The aggregates were collected at the surface of a filter.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing InP/ZnSeS/ZnS nanoparticles with CdSe, CdS, CdTe, CdSe/CdS, CdSe/ZnS, CdSe/CdZnS, CdS/ZnS, CdS/CdZnS, CdSe/CdS/ZnS, CdTe/ZnS, CdSe/CdZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing InP/ZnSeS/ZnS nanoparticles with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

### Example 37: Metastable Aggregates Preparation from an Organic Solution with Polymeric Solution—CdSe/CdS/ZnS@PMMA-PS (80/20)

A 80% mass solution of PMMA (60 kDa-1.3 MDa) and 20% mass solution of PS (30 kDa to 1.3 MDa) was solubilized in an aprotic solvent (i.e. 350 mg of PMMA and 80 mg of PS was mixed with 20 mL of solvent and left to mix overnight). Upon full solubilization, the sample was filtrated with a PTFE, filter via a syringe. The sample solution was then mixed with 300 μL of CdSe/CdS/ZnS nanoparticles and was left to sonicate in an ultrasonic bath for several minutes. The sample was loaded on a spray-drying set-up. The liquid mixture was sprayed towards a tube furnace heated at a temperature of 120-250° C. with a continuous nitrogen flow. The aggregates were collected at the surface of a filter.

The same procedure was carried out by replacing PMMA and/or PS with PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing CdSe/CdS/ZnS nanoparticles with CdSe, CdS, CdTe, CdSe/CdS, CdSe/ZnS, CdSe/CdZnS, CdS/ZnS, CdS/CdZnS, CdTe/ZnS, CdSe/CdZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoparticles with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

### Example 38: Metastable Aggregates Preparation from an Organic Solution with Polymeric Solution—CdSe/CdS/ZnS@PMMA-PS (50/50)

A 50% mass solution of PMMA (60 kDa-1.3 MDa) and 50% mass solution of PS (30 kDa to 1.3 MDa) was solubilized in an aprotic solvent (i.e. 210 mg of PMMA and 210 mg of PS was mixed with 20 mL of solvent and left to mix overnight). Upon full solubilization, the sample was filtrated with a filter via a syringe. The sample solution was then mixed with 300 μL of CdSe/CdS/ZnS nanoparticles and was left to sonicate in an ultrasonic bath for several minutes. The sample was loaded on a spray-drying set-up. The liquid mixture was sprayed towards a tube furnace heated at a temperature of 150-250° C. with a continuous nitrogen flow. The aggregates were collected at the surface of a filter.

The same procedure was carried out by replacing PMMA and/or PS with PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdTe/ZnS, CdSe/CdZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

### Example 39: Metastable Aggregates Preparation from an Organic Solution with Polymeric Solution—CdSe/CdS/ZnS@PMMA-Poly(ethylene oxide)-b-Poly(propylene oxide)-b-Poly(ethylene oxide)

A solution of PMMA (60 kDa-1.3 MDa) solubilized in an aprotic solvent alongside a triblock-copolymer of Poly(ethylene oxide)-block-Poly(propylene oxide)-block-Poly(ethylene oxide) was prepared (i.e. 420 mg of PMMA with 0-400 mg of the block-copolymer was mixed with 20 mL of solvent and left to mix overnight). Upon full solubilization, the sample was filtrated with a PTFE filter via a syringe. The sample solution was then mixed with 300 μL of CdSe/CdZnS/ZnS nanoparticles and was left to sonicate in an ultrasonic bath for several minutes. The sample was loaded on a spray-drying set-up. The liquid mixture was sprayed towards a tube furnace heated at a temperature of 120-280° C. with a continuous nitrogen flow. The aggregates were collected at the surface of a filter.

The same procedure was carried out by replacing PMMA and/or Poly(ethylene oxide)-b-Poly(propylene oxide)-b-Poly(ethylene oxide) with PS (Poly(Styrene)), PGMA (poly(glycidyl methacrylate)), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing CdSe/CdZnS/ZnS nanoplatelets with CdSe, CdS, CdTe, CdSe/CdS, CdSe/ZnS, CdSe/CdZnS, CdS/ZnS, CdS/CdZnS, CdTe/ZnS, CdSe/CdZnS, CdSe/CdS/ZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdZnS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

### Example 40: Metastable Aggregates Preparation from an Organic Solution with Polymeric Solution—CdSe/CdS/ZnS@PS-Poly(ethylene oxide)-b-Poly(propylene oxide)-b-Poly(ethylene oxide)

A solution of PS (30 kDa to 1.3 MDa) solubilized in an aprotic solvent alongside a triblock-copolymer of Poly(ethylene oxide)-block-Poly(propylene oxide)-block-Poly(ethylene oxide) was prepared (i.e. 400 mg of PS with 0-400 mg of the block-copolymer was mixed with 20 mL of solvent and left to mix overnight). Upon full solubilization, the sample was filtrated with a PTFE filter via a syringe. The sample solution was then mixed with 300 μL of CdSe/CdZnS/ZnS nanoparticles and was left to sonicate in an ultrasonic bath for several minutes. The sample was loaded on a spray-drying set-up. The liquid mixture was sprayed towards a tube furnace heated at a temperature of 120-280° C. with a continuous nitrogen flow. The aggregates were collected at the surface of a filter.

The same procedure was carried out by replacing PS and/or Poly(ethylene oxide)-b-Poly(propylene oxide)-b-Poly(ethylene oxide) with PMMA (Poly(methyl methacrylate)), PGMA (poly(glycidyl methacrylate)), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing CdSe/CdZnS/ZnS nanoplatelets with CdSe, CdS, CdTe, CdSe/CdS, CdSe/ZnS, CdSe/CdZnS, CdS/ZnS, CdS/CdZnS, CdTe/ZnS, CdSe/CdZnS, CdSe/CdS/ZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdZnS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

### Example 41: Metastable Aggregates Preparation from an Organic Solution with Polymeric Solution—CH₅N₂—PbBr₃@PMMA

A solution of PMMA (60 kDa-1.3 MDa) solubilized in an aprotic solvent was prepared. Upon full solubilization, the sample was filtrated with a PTFE filter via a syringe. The sample solution was then mixed with 100 μL of CH₅N₂—PbBr₃ nanoparticles suspended in hexane and was left to sonicate in an ultrasonic bath for several minutes. The sample was loaded on a spray-drying set-up. The liquid mixture was sprayed towards a tube furnace heated at a temperature of 150-250° C. with a continuous nitrogen flow. The aggregates were collected at the surface of a filter.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing CH₅N₂—PbBr₃ particles with Cs₃Bi₂I₉, Cs₃Bi₂Cl₉, Cs₃Bi₂Br₉, BFeO₃, KNbO₃, BaTiO₃, CH₃NH₃PbI₃, CH₃NH₃PbCl₃, CH₃NH₃PbBr₃, FAPbBr₃ (with FA formamidinium), FAPbCl₃, FAPbI₃, CsPbCl₃, CsPbBr₃, CsPbI₃, CsSnI₃, CsSnCl₃, CsSnBr₃, CsGeCl₃, CsGeBr₃, CsGeI₃, FAPbClₓBr_{y}I_{z} (with x, y and z independent decimal number from 0 to 5 and not simultaneously equal to 0), or a mixture thereof.

### Example 42: Metastable Aggregates Preparation from an Organic Solution with Polymeric Solution—CdSe/CdS/ZnS@Al₂O₃@PMMA

A solution of PMMA (60 kDa-1.3 MDa) solubilized in an aprotic solvent was prepared. Upon full solubilization, the sample was filtrated with a filter via a syringe. The sample solution was then mixed with 100 mg of CdSe/CdS/ZnS@Al₂O₃ aggregates and was left to sonicate in an ultrasonic bath for several minutes. The sample was loaded on a spray-drying set-up. The liquid mixture was sprayed towards a tube furnace heated at a temperature of 150-250° C. with a continuous nitrogen flow. The aggregates were collected at the surface of a filter.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdTe/ZnS, CdSe/CdZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing Al₂O₃ with ZnTe, SiO₂, HfO₂, ZnSe, ZnO, ZnS, TiO₂, MgO or a mixture thereof. Reaction temperature of the above procedure is adapted according to the inorganic material chosen.

The same procedure was carried out by replacing Al₂O₃ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 43: Metastable Aggregates Preparation from an Organic Solution with Polymeric Solution—CdSe/CdS/ZnS@PMMA@Al₂O₃

CdSe/CdS/ZnS@PMMA aggregates were dispersed in heptane were mixed with aluminium tri-sec butoxide and 100 ml of heptane, then loaded in a spray-drying set-up. On another side, an acidic aqueous solution was prepared and loaded in the same spray-drying set-up, but at a different location than the first heptane solution. The two liquids were sprayed simultaneously with two different means for forming droplets towards a tube furnace heated at a temperature ranging from the boiling point of the solvent to 250° C. with a nitrogen flow. The aggregates were collected at the surface of a filter.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdTe/ZnS, CdSe/CdZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing PMMA with PS (Poly(Styrene)), PMMA (Poly(methyl methacrylate)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

The same procedure was carried out by replacing Al₂O₃ with ZnTe, SiO₂, HfO₂, ZnSe, ZnO, ZnS, TiO₂, MgO or a mixture thereof. Reaction temperature of the above procedure is adapted according to the inorganic material chosen.

The same procedure was carried out by replacing Al₂O₃ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 44: Metastable Aggregates Preparation from an Organic Solution with Polymeric Solution—CdSe/CdS/ZnS@PMMA/Poly(ethylene oxide)-block-Poly(propylene oxide)-block-Poly(ethylene oxide)@SiO₂

100 mg of the CdSe/CdS/ZnS@PMMA/Poly(ethylene oxide)-block-Poly(propylene oxide)-block-Poly(ethylene oxide) aggregates were suspended in a basic aqueous solution were mixed with a basic aqueous solution of TEOS at 0.13M previously hydrolyzed for 24 hours. The sample was loaded on a spray-drying set-up. The liquid mixture was sprayed towards a tube furnace heated at a temperature of 150-250° C. with a continuous nitrogen flow. The aggregates were collected at the surface of a filter.

The same procedure was carried out by replacing PMMA and/or Poly(ethylene oxide)-block-Poly(propylene oxide)-block-Poly(ethylene oxide) with PS (Poly(Styrene)), PGMA (poly(glycidyl methacrylate)), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdTe/ZnS, CdSe/CdZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

The same procedure was carried out by replacing SiO₂ with ZnTe, Al₂O₃, HfO₂, ZnSe, ZnO, ZnS, TiO₂, MgO or a mixture thereof. Reaction temperature of the above procedure is adapted according to the inorganic material chosen.

The same procedure was carried out by replacing SiO₂ with a metal material, halide material, chalcogenide material, phosphide material, sulfide material, metalloid material, metallic alloy material, ceramic material such as for example oxide, carbide, nitride, glass, enamel, ceramic, stone, precious stone, pigment, cement and/or inorganic polymer, or a mixture thereof. Reaction temperature of the above procedure is adapted according to the inorganic material chosen.

### Example 45: Metastable Aggregates Preparation from an Organic Solution with Polymeric Solution—CdSe/CdS/ZnS@PS@PMMA

A solution of PMMA (60 kDa-1.3 MDa) solubilized in an aprotic solvent was prepared. Upon full solubilization, the sample was filtrated with a PTFE filter via a syringe. The sample solution was then mixed with 100 mg of CdSe/CdS/ZnS@PS aggregates and was left to sonicate in an ultrasonic bath for 5 minutes. The sample was loaded in the spray-drying set-up and the samples sprayed to formed droplets that moved towards a furnace preset at 150-250° C. with a continuous nitrogen flow. The sample aggregates were collected with the use of a filter.

The same procedure was carried out by replacing PMMA with PS (Poly(Styrene)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

The same procedure was carried out by replacing CdSe/CdS/ZnS nanoplatelets with CdSe, CdS, CdTe, CdSe/CdS, CdSe/ZnS, CdSe/CdZnS, CdS/ZnS, CdS/CdZnS, CdTe/ZnS, CdSe/CdZnS, CdTe/CdZnS, CdSeS/ZnS, CdSeS/CdS, CdSeS/CdZnS, CuInS₂/ZnS, CuInSe₂/ZnS, InP/CdS, InP/ZnS, InZnP/ZnS, InP/ZnSeS, InP/ZnSe, InP/CdZnS, CdSe/CdZnS/ZnS, CdSe/ZnS/CdZnS, CdSe/CdS/ZnS, CdSe/CdS/CdZnS, CdSe/ZnSe/ZnS, CdSeS/CdS/ZnS, CdSeS/CdS/CdZnS, CdSeS/CdZnS/ZnS, CdSeS/ZnSe/ZnS, CdSeS/ZnSe/CdZnS, CdSeS/ZnS/CdZnS, CdSe/ZnS/CdS, CdSeS/ZnS/CdS, CdSe/ZnSe/CdZnS, InP/ZnSe/ZnS, InP/CdS/ZnSe/ZnS, InP/CdS/ZnS, InP/ZnS/CdS, InP/GaP/ZnS, InP/GaP/ZnSe, InP/CdZnS/ZnS, InP/ZnS/CdZnS, InP/CdS/CdZnS, InP/ZnSe/CdZnS, InP/ZnS/ZnSe, InP/GaP/ZnSe/ZnS, InP/ZnS/ZnSe/ZnS, nanoplatelets or quantum dots, or a mixture thereof.

The same procedure was carried out by replacing CdSe/CdS/ZnS nanoplatelets with organic nanoparticles, inorganic nanoparticles such as metal nanoparticles, halide nanoparticles, chalcogenide nanoparticles, phosphide nanoparticles, sulfide nanoparticles, metalloid nanoparticles, metallic alloy nanoparticles, phosphor nanoparticles, perovskite nanoparticles, ceramic nanoparticles such as for example oxide nanoparticles, carbide nanoparticles, nitride nanoparticles, or a mixture thereof.

### Example 46: Metastable Aggregates Preparation from an Organic Solution with Polymeric Solution—CdSe/CdS/ZnS@PMMA@PS

A solution of PS (30 kDa to 1.3 MDa) solubilized in an aprotic solvent was prepared. Upon full solubilization, the sample was filtrated with a PTFE filter via a syringe. The sample solution was then mixed with 100 mg of CdSe/CdS/ZnS@PMMA aggregates and was left to sonicate in an ultrasonic bath for several minutes. The sample was loaded on a spray-drying set-up. The liquid mixture was sprayed towards a tube furnace heated at a temperature of 150-280° C. with a continuous nitrogen flow. The aggregates were collected at the surface of a filter.

The same procedure was carried out by replacing PS with PMMA (Poly(methyl methacrylate)), PGMA (poly(glycidyl methacrylate)), Poly(ethylene oxide)-b-Poly(propylene oxide)-b-Poly(ethylene oxide), PLA (Poly(L-Lactide)), PVP (Poly(vinyl pyrrolidone)), PCL (Poly(caprolactone)), PBMA (Poly(butyl methacrylate)), PIB (Polyisobutylene), PVPy Poly(Vinyl Pyridine), PiP (Polyisoprene), PI (Polyimide), PEI (Poly(etherimide)), or a mixture thereof.

In the case of PS, the reaction temperature ranges from 120 to 280° C.; in the case of PGMA, PLA, PVP, the reaction temperature ranges from 100 to 200° C.; in the case of PMMA-PS (80/20), PIB, PVPy, and PiP, the reaction temperature ranges from 120 to 250° C.; in the case of PMMA, PMMA-PS (80/20), the reaction temperature ranges from 150 to 250° C.; in the case of PCL, PBMA, the reaction temperature ranges from 100 to 150° C.; in the case of PI, PEI, the reaction temperature ranges from 200 to 350° C.

### Example 47: Dispersion of Aggregates in a Silicone and Deposition onto a LED

Aggregates containing fluorescent nanoparticles were prepared and collected according to the present invention and then dispersed in a polymer of silicone, with a mass concentration of 20%. The obtained material was deposited onto a LED of InGaN before annealing at 180° C. for 2 hours. The LED was then turned on to get a mixture of blue light and the light emitted by the fluorescent nanoparticles.

### Example 48: Dispersion of Aggregates in a ZnO Matrix and Deposition onto a LED

Aggregates containing fluorescent nanoparticles were prepared and collected according to the present invention and then dispersed in a ZnO matrix prepared by a sol-gel method. The material was then deposited onto a glass substrate by spin-coating and annealed at 100° C. for 24 hours. The glass substrate was then illuminated by a blue laser to get a mixture of blue light and the light emitted by the fluorescent nanoparticles.

### Example 49: Color Conversion Layer Preparation

Blue emitting aggregates, green emitting aggregates, and red emitting aggregates encapsulated in Al₂O₃ were dispersed separately in silicone and deposited onto a support, such that each film of aggregates was around 50-150 μm in thickness. The support was then annealed at 180° C. for 2 hours before it was introduced in the display apparatus described in the invention. The resulting lights were blue, green and red depending on the aggregates illuminated with the UV light from a light source.

The same procedure was carried out by replacing silicone with a resin, ZnO, MgO, PMMA, Polystyrene, Al₂O₃, TiO₂, HfO₂ or ZrO₂, or a mixture thereof.

The same procedure was carried out with aggregates prepared in the examples hereabove.

The same procedure was carried out using inkjet printing; or traditional lithography.

With traditional lithography: the entire surface was coated with blue emitting aggregates, followed by the subtractive photolithography patterning process. The process is then repeated for the red emitting aggregates and for the green emitting aggregates.

### Example 50: Color Conversion Layer Preparation

Green emitting core-shell CdSeS/CdZnS nanoplatelets and red emitting core-shell CdSe/CdZnS nanoplatelets were dispersed separately in silicone and deposited onto a support, such that each film of aggregates was around 50-150 μm in thickness. The support was then annealed at 180° C. for 2 hours before it was introduced in the display apparatus described in the invention. The resulting lights were green and red depending on the aggregates illuminated with the blue light from a light source.

The same procedure was carried out by replacing silicone with a resin, ZnO, MgO, PMMA, Polystyrene, Al₂O₃, TiO₂, HfO₂ or ZrO₂, or a mixture thereof.

The same procedure was carried out with aggregates prepared in the examples hereabove.

The same procedure was carried out using inkjet printing; or traditional lithography.

With traditional lithography: the entire surface was coated with blue emitting aggregates, followed by the subtractive photolithography patterning process. The process is then repeated for the red emitting aggregates and for the green emitting aggregates.

### Example 51: Color Conversion Layer Preparation

Green emitting aggregates, and red emitting aggregates were dispersed separately in a zinc oxide matrix and deposited onto a support, such that each film of aggregates was around 50-150 μm in thickness. The support was then annealed at 180° C. for 2 hours before it was introduced in the display apparatus described in the invention. The resulting lights were green and red depending on the aggregates illuminated with the blue light from a light source.

The same procedure was carried out by replacing ZnO, MgO, PMMA, Polystyrene, Al₂O₃, TiO₂, HfO₂ or ZrO₂, or a mixture thereof.

The same procedure was carried out with aggregates prepared in the examples hereabove.

The same procedure was carried out using inkjet printing; or traditional lithography.

With traditional lithography: the entire surface was coated with blue emitting aggregates, followed by the subtractive photolithography patterning process. The process is then repeated for the red emitting aggregates and for the green emitting aggregates.

### Example 52: Color Conversion Layer Preparation

Green emitting aggregates, and red emitting aggregates were dispersed separately in silicone and deposited onto a support, such that each film of aggregates was around 50-150 μm in thickness. The support was then annealed at 180° C. for 2 hours before it was introduced in the display apparatus described in the invention. The resulting lights were green and red depending on the aggregates illuminated with the blue light from a light source.

The same procedure was carried out by replacing silicone with a resin, ZnO, MgO, PMMA, Polystyrene, Al₂O₃, TiO₂, HfO₂ or ZrO₂, or a mixture thereof.

The same procedure was carried out with aggregates prepared in the examples hereabove.

The same procedure was carried out using inkjet printing; or traditional lithography.

With traditional lithography: the entire surface was coated with blue emitting aggregates, followed by the subtractive photolithography patterning process. The process is then repeated for the red emitting aggregates and for the green emitting aggregates.

### Example 53: Color Conversion Layer Preparation

Green emitting aggregates, and red emitting aggregates were dispersed separately in silicone and deposited onto a support, such that each film of aggregates was around 50-150 μm in thickness. The support was then annealed at 180° C. for 2 hours before it was introduced in the display apparatus described in the invention. The resulting lights were green and red depending on the aggregates illuminated with the blue light from a light source.

The same procedure was carried out by replacing silicone with a resin, ZnO, MgO, PMMA, Polystyrene, Al₂O₃, TiO₂, HfO₂ or ZrO₂, or a mixture thereof.

The same procedure was carried out with aggregates prepared in the examples hereabove.

The same procedure was carried out using inkjet printing; or traditional lithography.

With traditional lithography: the entire surface was coated with blue emitting aggregates, followed by the subtractive photolithography patterning process. The process is then repeated for the red emitting aggregates and for the green emitting aggregates.

### Example 54: Color Conversion Layer Preparation

Green emitting aggregates, and red emitting aggregates were dispersed separately in a resin matrix and deposited onto a support, such that each film of aggregates was around 50-150 μm in thickness. The support was then annealed at 180° C. for 3 hours before it was introduced in the display apparatus described in the invention. The resulting lights were green and red depending on the aggregates illuminated with the blue light from a light source.

The same procedure was carried out by replacing the resin with silicone, ZnO, MgO, PMMA, Polystyrene, Al₂O₃, TiO₂, HfO₂ or ZrO₂, or a mixture thereof.

The same procedure was carried out with aggregates prepared in the examples hereabove.

The same procedure was carried out using inkjet printing; or traditional lithography.

With traditional lithography: the entire surface was coated with blue emitting aggregates, followed by the subtractive photolithography patterning process. The process is then repeated for the red emitting aggregates and for the green emitting aggregates.

### Example 55: Color Conversion Layer Preparation

Green emitting aggregates and red emitting aggregates were dispersed separately in silicone and deposited onto a support, such that each film of aggregates was around 50-150 μm in thickness. The support was then annealed at 180° C. for 2 hours before it was introduced in the display apparatus described in the invention. The resulting lights were green and red depending on the aggregates illuminated with the blue light from a light source.

The same procedure was carried out by replacing silicone with a resin, ZnO, MgO, PMMA, Polystyrene, Al₂O₃, TiO₂, HfO₂ or ZrO₂, or a mixture thereof.

The same procedure was carried out with aggregates prepared in the examples hereabove.

The same procedure was carried out using inkjet printing; or traditional lithography.

With traditional lithography: the entire surface was coated with blue emitting aggregates, followed by the subtractive photolithography patterning process. The process is then repeated for the red emitting aggregates and for the green emitting aggregates.

### Example 56: Aggregates Dispersion in Monomeric Solution—CdSe/CdS/ZnS@PMMA in MMA

CdSe/CdS/ZnS@PMMA aggregates were mixed with 5 mL of MMA (methyl methacrylate) and left to solubilize overnight. The sample was filtered with a PTFE filter and observed.

FIG. 43 shows the absorbance spectra of CdSe/CdS/ZnS nanoplatelet (NPL in hexane) and CdSe/CdS/ZnS@PMMA in MMA. The absorption properties of the nanoplatelet are not deteriorated upon encapsulation.

### Example 57: Aggregates Dispersion in Monomeric Solution—CdSe/CdS/ZnS@PMMA in PMMA

A 20% weight solution of PMMA (60 kDa-1.3 MDa) was solubilized in an aprotic solution overnight. CdSe/CdS/ZnS@PMMA aggregates were mixed with the PMMA solution. The sample was then drop casted/deposited onto a LED of InGaN. The LED was then turned on to get a mixture of blue light and the light emitted by the fluorescent nanoparticles.

### Example 58: Aggregates Dispersion in Monomeric Solution—CdSe/CdS/ZnS@PS in Styrene

CdSe/CdS/ZnS @PS aggregates were mixed with 5 mL of styrene and left to solubilize overnight. The sample was filtered with a PTFE filter.

### Example 59: Aggregates Dispersion in Polymeric Matrix—CdSe/CdS/ZnS@PS in PolyStyrene Deposition onto a LED

A 20% weight solution of PS (35 kDa or 280 kDa) was solubilized in an aprotic solution overnight. CdSe/CdS/ZnS@PS aggregates were mixed with the PS solution. The sample was then drop casted/deposited onto a LED of InGaN. The LED was then turned on to get a mixture of blue light and the light emitted by the fluorescent nanoparticles.

### Example 60: Aggregates Dispersion in Polymeric Matrix—CdSe/CdS/ZnS@PS in PMMA Deposition onto a LED

A 20% weight solution of PMMA (60 kDa-1.3 MDa) was solubilized in an aprotic solution overnight. CdSe/CdS/ZnS @PS aggregates were mixed with the PMMA solution. The sample was then drop casted/deposited onto a LED of InGaN. The LED was then turned on to get a mixture of blue light and the light emitted by the fluorescent nanoparticles.

### Example 61: Aggregates Dispersion in Monomeric Solution that is Polymerized—CdSe/CdS/ZnS@PMMA in MMA with Temperature Initiator

A free-radical generator/initiator, such as AIBN (Azobisisobutyronitrile) was added to one previously prepared sample dispersion of CdSe/CdS/ZnS@PMMA aggregates in MMA. The sample was then mixed into a mould set to 80° C. for several hours before being cooled down to room temperature. The mould was subsequently removed.

### Example 62: Aggregates Dispersion in Monomeric Solution that is Polymerized—CdSe/CdS/ZnS@PMMA in MMA with UV-Initiator

A free-radical generator/initiator, such as 2,2-dimethyoxy-2-phenylacetophonone was added to the previously prepared sample dispersion of CdSe/CdS/ZnS@PMMA aggregates in MMA. The sample was then mixed into a mould and exposed to UV light for several hours before being cooled down to room temperature. The mould was subsequently removed.

### Example 63: Aggregates Dispersion in Monomeric Solution that is Polymerized—CdSe/CdS/ZnS@PS in Styrene with Temperature Initiator

A free-radical generator/initiator, such as AIBN (Azobisisobutyronitrile) was added to the previously prepared sample dispersion of CdSe/CdS/ZnS@PS aggregates in Styrene. The sample was then mixed into a mould set to 80° C. for several hours before being cooled down to room temperature. The mould was subsequently removed.

### Example 64: Aggregates Dispersion in Polymeric Matrix—CdSe/CdS/ZnS@PMMA in Silicone Deposition onto a LED

The previously prepared sample dispersion of CdSe/CdS/ZnS@PMMA aggregates was dispersed in a polymer of silicone, with a mass concentration of 20%. The obtained material was deposited onto a LED of InGaN before annealing at 150° C. for 2 hours. The LED was then turned on to get a mixture of blue light and the light emitted by the fluorescent nanoparticles.

### Example 65: Aggregates Dispersion in Polymeric Matrix—CdSe/CdS/ZnS@PS in Silicone Deposition onto a LED

The previously prepared sample dispersion of CdSe/CdS/ZnS@PS aggregates was dispersed in a polymer of silicone, with a mass concentration of 20%. The obtained material was deposited onto a LED of InGaN before annealing at 150° C. for 2 hours. The LED was then turned on to get a mixture of blue light and the light emitted by the fluorescent nanoparticles.

### Example 66: Aggregates Dispersion in Polymeric Matrix—InP/ZnSeS/ZnS@PS in Silicone Deposition onto a LED

The previously prepared sample dispersion of InP/ZnSeS/ZnS@PS aggregates was dispersed in a polymer of silicone, with a mass concentration of 20%. The obtained material was deposited onto a LED of InGaN before annealing at 150° C. for 2 hours. The LED was then turned on to get a mixture of blue light and the light emitted by the fluorescent nanoparticles.

### Example 67: Aggregates Dispersion in Polymeric Matrix—InP/ZnSeS/ZnS@PMMA in Silicone Deposition onto a LED

The previously prepared sample dispersion of InP/ZnSeS/ZnS@PMMA aggregates was dispersed in a polymer of silicone, with a mass concentration of 20%. The obtained material was deposited onto a LED of InGaN before annealing at 150° C. for 2 hours. The LED was then turned on to get a mixture of blue light and the light emitted by the fluorescent nanoparticles.

### Example 68: Aggregates Dispersion in Photolithographic Solution and Film Formation

The aggregates prepared in the examples hereabove were solubilized in various common solvents for lithographic applications: a negative photoresist in cyclopentanone, or PMMA positive resist in ethyl lactate. Additional solvent was then added to adjust the viscosity for final film formation thickness. The new mixture is desposited by spin-coating on circular wafers to form uniform films. Exposition to proper patterning system (by UV, DUV, EB etc.) with the assistance of mask, and post-processing development is then applied to form the final structure on the wafer.

### Example 69: Aggregates Dispersion in Photolithographic Solution and Film Formation

The aggregates prepared in the examples hereabove were solubilized in various common solvents for lithographic applications: a negative photoresist in cyclopentanone, or PMMA positive resist in ethyl lactate. Additional solvent was then added to adjust the viscosity for final film formation thickness. The new mixture was used to form a uniform film by the use of the doctor blade method, and subsequently exposed to proper patterning system (by UV, DUV, EB etc.) with the assistance of mask, and developed to form the final structure on a planar surface.

### Example 70: Aggregates Dispersion for Microcontact Printing Solution

The aggregates prepared in the examples hereabove were solubilized in common solvents for patterning applications (for example PGMEA, Cyclopentanone, Ethyl lactate etc.). Additional solvent was then added to adjust the viscosity for final film formation thickness. The new mixture was applied to a soft-mold preformed with a pattern (for example soft lithography patterning to form a PDMS stamp) that can be applied/stamped into various surfaces to emboss specified pattern.

### Example 71: Aggregates Dispersion for Nanoimprint Lithography Solution for Embossing Applications

The aggregates prepared in the examples hereabove were solubilized in various common solvents for lithographic applications: a negative photoresist in cyclopentanone, or PMMA positive resist in ethyl lactate and with a mixture of solvents (example: PGMEA, Cyclopentanone, Ethyl lactate) to help adjust the final viscosity. The final mixture was applied onto a compatible surface by spincoating or by doctor-blade method. A preformed, transparent mold can be applied directly over the formed layer with a pattern. The pattern was then developed (by UV, DUV, EB etc.) and the mold removed after the film was cured.

### Example 72: Aggregates Dispersion in Printable Solutions

The aggregates prepared in the examples hereabove were solubilized in various common solvents that can be printed (for example ethylene glycol, water based solvents, PGMEA (Propylene glycol monomethyl ether acetate) and formulated with other resins (such as, but not limited to, polystyrene, epoxy) that can be applied towards different patterning techniques (spraying, microprinting, dip-pen nanolithography). This mixture was applied to various compatible surfaces. The mixture can be used directly, or post-processed by heating the substrate from 50-150° C. for several minutes, and then baked in an oven ranging from several minutes to several hours at 60-100° C. The sample can then be cooled to room temperature and used directly.

### Example 73: Color Conversion Layer Preparation

Green emitting luminescent partricles as-prepared in the examples hereabove, and red emitting c luminescent partricles as-prepared in the examples hereabove were dispersed separately in a resin matrix and deposited onto a support, such that each film of aggregates was around 1-10 μm in thickness. The support was then annealed at 180° C. for 3 hours before it was introduced in the display apparatus described in the invention. The resulting lights were green and red depending on the aggregates illuminated with the blue light from a light source.

The same procedure was carried out by replacing the resin with silicone, ZnO, MgO, PMMA, Polystyrene, Al₂O₃, TiO₂, HfO₂ or ZrO₂, or a mixture thereof.

The same procedure was carried out with aggregates prepared in the examples hereabove.

The same procedure was carried out using inkjet printing; or traditional lithography.

With traditional lithography: the entire surface was coated with blue emitting aggregates, followed by the subtractive photolithography patterning process. The process is then repeated for the red emitting aggregates and for the green emitting aggregates.

### Example 74: Color Conversion Layer Preparation

Green emitting luminescent partricles as-prepared in the examples hereabove and red emitting luminescent partricles as-prepared in the examples hereabove were dispersed separately in silicone and deposited onto a support, such that each film of aggregates was around 1-10 μm in thickness. The support was then annealed at 180° C. for 2 hours before it was introduced in the display apparatus described in the invention. The resulting lights were green and red depending on the aggregates illuminated with the blue light from a light source.

The same procedure was carried out by replacing silicone with a resin, ZnO, MgO, PMMA, Polystyrene, Al₂O₃, TiO₂, HfO₂ or ZrO₂, or a mixture thereof.

The same procedure was carried out with aggregates prepared in the examples hereabove.

The same procedure was carried out using inkjet printing; or traditional lithography.

With traditional lithography: the entire surface was coated with blue emitting aggregates, followed by the subtractive photolithography patterning process. The process is then repeated for the red emitting aggregates and for the green emitting aggregates.

### Example 75: Color Conversion Layer Preparation

Green emitting luminescent partricles as-prepared in the examples hereabove and red emitting luminescent partricles as-prepared in the examples hereabove were dispersed separately in a MgO matrix and deposited onto a support, such that each film of aggregates was around 1-10 μm in thickness. The support was then annealed at 180° C. for 2 hours before it was introduced in the display apparatus described in the invention. The resulting lights were green and red depending on the aggregates illuminated with the blue light from a light source.

The same procedure was carried out by replacing MgO with a resin, ZnO, silicone, PMMA, Polystyrene, Al₂O₃, TiO₂, HfO₂ or ZrO₂, or a mixture thereof.

The same procedure was carried out with aggregates prepared in the examples hereabove.

The same procedure was carried out using inkjet printing; or traditional lithography: the entire surface was coated with blue emitting aggregates, followed by the subtractive photolithography patterning process. The process is then repeated for the red emitting aggregates and for the green emitting aggregates.

The same procedure was carried out using inkjet printing.

### Example 76: Color Conversion Layer Preparation

Blue emitting luminescent partricles as-prepared in the examples hereabove, green emitting luminescent partricles as-prepared in the examples hereabove, and red emitting luminescent partricles as-prepared in the examples hereabove were dispersed separately in silicone and successively deposited onto an optically transparent rotating wheel with a ring shape, such that the film of aggregates is around 100 μm in thickness and were equally distributed in three zones along the ring to obtain one zone coated with green emitting aggregates, one zone coated with blue emitting aggregates and one zone coated with red emitting aggregates. The rotating wheel was then annealed at 150° C. for 2 hours before it was introduced in the display apparatus described in the invention, wherein a UV laser source was used as excitation source. The resulting lights were blue, green and red depending on the zone illuminated with the UV light form the laser source.

The same procedure was carried out by replacing silicone with a resin, ZnO, MgO, PMMA, Polystyrene, Al₂O₃, TiO₂, HfO₂ or ZrO₂, or a mixture thereof.

The same procedure was carried out with aggregates prepared in the examples hereabove.

### Example 77: Color Conversion Layer Preparation

Green emitting core-shell CdSeS/CdZnS nanoplatelets and red emitting core-shell CdSe/CdZnS nanoplatelets were dispersed separately in silicone and successively deposited onto an optically transparent rotating wheel with a ring shape, such that the film of aggregates is around 100 μm in thickness and were equally distributed in three zones along the ring, to obtain one zone not coated, one zone coated with green emitting core-shell CdSe/CdZnS nanoplatelets and one zone coated with red emitting core-shell CdSe/CdZnS nanoplatelets. The rotating wheel was then annealed at 150° C. for 2 hours before it was introduced in the display apparatus described in the invention, where a blue laser source was used as excitation source. The resulting lights were blue, green and red depending on the zone illuminated with the blue light form the laser source.

The same procedure was carried out by replacing silicone with a resin, ZnO, MgO, PMMA, Polystyrene, Al₂O₃, TiO₂, HfO₂ or ZrO₂, or a mixture thereof.

The same procedure was carried out with aggregates prepared in the examples hereabove.

### Example 78: Color Conversion Layer Preparation

Green emitting luminescent partricles as-prepared in the examples hereabove, and red emitting luminescent partricles as-prepared in the examples hereabove were dispersed separately in a zinc oxide matrix and successively deposited onto an optically transparent rotating wheel with a ring shape, such that the film of aggregates is around 200 μm in thickness and were equally distributed in three zones along the ring, to obtain one zone not coated, one zone coated with green emitting aggregates and one zone coated with red emitting aggregates. The rotating wheel was then annealed at 150° C. for 2 hours before it was introduced in the display apparatus described in the invention, where a blue laser source was used as excitation source. The resulting lights were blue, green and red depending on the zone illuminated with the blue light form the laser source.

The same procedure was carried out by replacing ZnO with a resin, silicone, MgO, PMMA, Polystyrene, Al₂O₃, TiO₂, HfO₂ or ZrO₂, or a mixture thereof.

The same procedure was carried out with aggregates prepared in the examples hereabove.

### Example 79: Color Conversion Layer Preparation

Green emitting luminescent partricles as-prepared in the examples hereabove, and red emitting luminescent partricles as-prepared in the examples hereabove were dispersed separately in a resin matrix and successively deposited onto an optically transparent rotating wheel with a ring shape, such that the film of aggregates is around 200 μm in thickness and were equally distributed in three zones along the ring, to obtain one zone not coated, one zone coated with green emitting aggregates and one zone coated with red emitting aggregates. The rotating wheel was then annealed at 150° C. for 2 hours before it was introduced in the display apparatus described in the invention, where a blue laser source was used as excitation source. The resulting lights were blue, green and red depending on the zone illuminated with the blue light form the laser source.

The same procedure was carried out by replacing the resin with silicone, ZnO, MgO, PMMA, Polystyrene, Al₂O₃, TiO₂, HfO₂ or ZrO₂, or a mixture thereof.

The same procedure was carried out with aggregates prepared in the examples hereabove.

### Example 80: Color Conversion Layer Preparation

Green emitting luminescent partricles as-prepared in the examples hereabove, yellow emitting luminescent partricles as-prepared in the examples hereabove, orange emitting luminescent partricles as-prepared in the examples hereabove, and red emitting luminescent partricles as-prepared in the examples hereabove were dispersed separately in silicone and deposited onto an optically transparent rotating wheel with a ring shape, such that the film of aggregates is around 200 μm in thickness and were equally distributed in five zones along the ring, to obtain one zone not coated, one zone coated with green emitting aggregates, one zone coated with yellow emitting aggregates, one zone coated with orange emitting aggregates and one zone coated with red emitting aggregates. The rotating wheel was then annealed at 150° C. for 2 hours before it was introduced in the display apparatus described in the invention, where a blue laser source was used as excitation source. The resulting lights were blue, green, yellow, orange and red depending on the zone illuminated with the blue light form the laser source.

The same procedure was carried out by replacing silicone with a resin, ZnO, MgO, PMMA, Polystyrene, Al₂O₃, TiO₂, HfO₂ or ZrO₂, or a mixture thereof.

The same procedure was carried out with aggregates prepared in the examples hereabove.

### REFERENCES

1—Aggregate
11—Material
12—Particle
121—Material
122—Nanoparticle
123—Core of particle
124—Shell of particle
125—Shell of particle
126—Insulator shell of particle
127—Crown of particle
128—Spherical particle
129—2D particle
13—Core of aggregate
14—Shell of aggregate
2—Dense particle
3—Bead
31—Material
4—LED support
5—LED chip
6—Microsized LED
61—Display apparatus
6111—Light source
61111—Possible colored light paths
6112—Laser source
61121—Laser path
61122—Possible laser path
6121—Glass substrate
6122—Bottom substrate
6123—Solid support
6131—Layer of liquid crystal material
6132—Active matrix
6141—Polarizer
6142—Optical enhancement film
6143—Directing optical system
62—Illumination source
621—Light guide
622—Space
623—Reflector
624—Substrate
625—Color Filter
63—Rotating wheel comprising at least a zone comprising a color conversion layer
631—Possible light path of primary light from the light source
632—Possible light paths of secondary or primary light
634—Optical component
635—Modulating optical system
636—Possible path of the formed image
637—Screen
638—Digital micromirror device
6381—Microscopic mirror of the digital micromirror device
6382—Microscopic mirror of the digital micromirror device free of light emitting material, empty or optically transparent
6383—Support of a microscopic mirror
6391—Wavelength splitter system
6392—Wavelength combiner system
6384—Mirror
7—Light emitting material
71—Host material
72—Host material
73—Color conversion layer
d—Sub-pixel pitch
D—Pixel pitch
G—Green secondary light
R—Red secondary light

1-12. (canceled)

13. An aggregate comprising:
a material; and
at least one semiconductor nanoplatelet dispersed in said material;
wherein the material is an organic polymer.

14. The aggregate according to claim 13, wherein the organic polymer is selected from silicones, polyacrylates; polymethacrylates; polyacrylamides; polyamides; polyesters;
polyethers; polyolefins; polysaccharides; polyurethanes, polystyrenes; polyacrylonitrile-butadiene-styrene; polycarbonate; poly(styrene acrylonitrile); vinyl polymers; poly p-phenylene oxide; polysulfone; polyethersulfone; polyethylenimine; polyphenylsulfone; poly(acrylonitrile styrene acrylate); polyepoxides, polythiophenes, polypyrroles; polyanilines ; poly aryletherketones ; polyfurans ; polyimides ; polyimidazoles ; polyetherimides ; polyketones; polynucleotides; polystyrene sulfonates; polyetherimines; polyamic acid; or any combinations and/or derivatives and/or copolymers thereof.

15. The aggregate according to claim 14, wherein the organic polymer is selected from polystyrene, polymethylmethacrylate, polyglycidylmethacrylate, polyethylene oxide-b-polypropylene oxide-b-polyethylene oxide, poly L-Lactide, polyvinylpyrrolidone, polycaprolactone, polybutylmethacrylate, polyisobutylene, polyvinylpyridine, polyisoprene, polyimide, polyetherimide, or a mixture thereof.

16. The aggregate according to claim 13, wherein the at least one semiconductor nanoplatelet comprises a material of formula MₓN_{y}E_{z}A_{w}, wherein: M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; N is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; E is selected from the group consisting of O, S, Se, Te, C, N, P, As, Sb, F, Cl, Br, I, or a mixture thereof; A is selected from the group consisting of O, S, Se, Te, C, N, P, As, Sb, F, Cl, Br, I, or a mixture thereof; and x, y, z and w are independently a decimal number from 0 to 5; x, y, z and w are not simultaneously equal to 0; x and y are not simultaneously equal to 0; z and w may not be simultaneously equal to 0.

17. The aggregate according to claim 13, wherein the aggregate is selected from CdSe/CdS/ZnS@PMMA; CdSe/CdS/ZnS@PS; CdSe/CdS/ZnS@PMMA; InP/ZnSe/ZnS@PMMA; CdSe/CdS/ZnS@PMMA@SiO₂; CdSe/CdS/ZnS@PMMA@SiO₂; CdSe/CdS/ZnS@PMMA@SiO₂@PMMA; InP/ZnS@PMMA@SiO₂@PMMA; CdSe/CdS/ZnS@PMMA@Al₂O₃; CdSe/CdS/ZnS@PMMA@Al₂O₃@PMMA; InP/ZnS@PMMA@Al₂O₃@PMMA; InP/ZnSe/ZnS@PMMA@SiO₂; CdSe/CdS/ZnS@PMMA; InP/ZnSeS/ZnS@PMMA; CdSe/CdS/ZnS@PMMA-PS (80/20); CdSe/CdS/ZnS@PMMA-PS (50/50); CdSe/CdS/ZnS@PMMA-Poly(ethylene oxide)-b-Poly(propylene oxide)-b-Poly(ethylene oxide); CdSe/CdS/ZnS@PS-Poly(ethylene oxide)-b-Poly(propylene oxide)-b-Poly(ethylene oxide); CdSe/CdS/ZnS@PMMA@Al₂O₃; CdSe/CdS/ZnS@PMMA/Poly(ethylene oxide)-block-Poly(propylene oxide)-block-Poly(ethylene oxide)@SiO₂; CdSe/CdS/ZnS@PS@PMMA; or CdSe/CdS/ZnS@PMMA@PS.

18. A light emitting material comprising at least one host material and at least one aggregate comprising a material and at least one semiconductor nanoplatelet dispersed in said material, wherein the material is an organic polymer, wherein said at least one aggregate is dispersed in the at least one host material.

19. The light emitting material according to claim 18, wherein the host material is an inorganic material.

20. The light emitting material according to claim 19, wherein the host material is selected from ZnO, MgO, Al₂O₃, TiO₂, HfO₂ or ZrO₂, or a mixture thereof.

21. The light emitting material according to claim 18, wherein the host material comprises an organic polymer.

22. The light emitting material according to claim 21, wherein the host material is selected from silicone based polymers, polydimethylsiloxanes (PDMS), polyethylene terephthalate, polyesters, polyacrylates, polymethacrylates, polycarbonate, poly(vinyl alcohol), polyvinylpyrrolidone, polyvinylpyridine, polysaccharides, poly(ethylene glycol), melamine resins, a phenol resin, an alkyl resin, an epoxy resin, a polyurethane resin, a maleic resin, a polyamide resin, an alkyl resin, a maleic resin, terpenes resins, an acrylic resin or acrylate based resin such as PMMA, copolymers forming the resins, co-polymers, block co-polymers, polymerizable monomers comprising an UV initiator or thermic initiator, or a mixture thereof.

23. The light emitting material according to claim 18, wherein the host material is a monomer.

24. The light emitting material according to claim 23, wherein the aggregate comprises at least one semiconductor nanoplatelet encapsulated in a PMMA particle further dispersed in MMA.

25. The light emitting material according to claim 21, wherein the light emitting material is selected from CdSe/CdS/ZnS@PMMA in MMA; CdSe/CdS/ZnS@PS in styrene; CdSe/CdS/ZnS@PMMA in PMMA; CdSe/CdS/ZnS@PS in PolyStyrene; CdSe/CdS/ZnS@PMMA in Silicone; CdSe/CdS/ZnS@PS in Silicone; InP/ZnSeS/ZnS@PS in Silicone; InP/ZnSeS/ZnS@PMMA in Silicone.

26. An optoelectronic device comprising:
at least one aggregate comprising a material and at least one semiconductor nanoplatelet dispersed in said material, wherein the material is an organic polymer, and/or
at least one light emitting material comprising at least one host material and at least one aggregate comprising a material and at least one semiconductor nanoplatelet dispersed in said material, wherein the material is an organic polymer, wherein said at least one aggregate is dispersed in the at least one host material.
